(19) United States
(12) Patent Application Publication
(10) Pub. No.: US 2026/0052903 A1
(43) Pub. Date: Feb. 19, 2026

(54) HETEROCYCLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Display Co., Ltd., Yongin-si (KR)

(72) Inventors: Chaeyeong Kim, Yongin-si (KR); Dongjun Kim, Yongin-si (KR); Hwasook Ryu, Yongin-si (KR); Hankyu Pak, Yongin-si (KR); Sanghyun Han, Yongin-si (KR)

(21) Appl. No.: 19/285,397

(22) Filed: Jul. 30, 2025

(30) Foreign Application Priority Data
Aug. 13, 2024 (KR) 10-2024-0108498

(51) Int. Cl. H10K 85/60; C07B 59/00; C07F 5/02; H10K 50/12; H10K 85/30

(52) U.S. Cl. CPC H10K 85/658; C07B 59/004; C07F 5/027; H10K 85/346; H10K 85/615; H10K 85/626; H10K 85/654; C07B 2200/05; H10K 50/121

(57) ABSTRACT

A heterocyclic compound represented by Formula 1, an organic light-emitting device including the heterocyclic compound, and an electronic apparatus including the organic light-emitting device are provided:

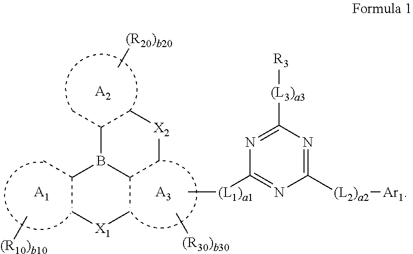

### CROSS-REFERENCE TO RELATED APPLICATION

The present application claims priority to and the benefit of Korean Patent Application No. 10-2024-0108498, filed on Aug. 13, 2024, in the Korean Intellectual Property Office, the entire disclosure of which is incorporated herein by reference.

### BACKGROUND

### 1. Field

One or more embodiments of the present disclosure relate to a heterocyclic compound, an organic light-emitting device including the heterocyclic compound, and an electronic apparatus including the organic light-emitting device.

### 2. Description of the Related Art

Organic light-emitting devices are self-emissive devices that, as compared to other devices of the related art, have relatively wide viewing angles, high contrast ratios, short response times, and enhanced (e.g., excellent or suitable) characteristics in terms of luminance, driving voltage, and response speed, and produce full-color images.

In an example, an organic light-emitting device may have a structure in which a first electrode is arranged on a substrate and followed sequentially by a hole transport region, an emission layer, an electron transport region, and a second electrode. Holes provided by the first electrode move toward the emission layer through the hole transport region, while electrons provided by the second electrode move toward the emission layer through the electron transport region. These carriers, namely holes and electrons, recombine in the emission layer to produce excitons. When the excitons transition and decay from an excited state to a ground state, light is emitted.

### SUMMARY

One or more aspects of embodiments of the present disclosure are directed toward a heterocyclic compound, and an organic light-emitting device including the heterocyclic compound, and an electronic apparatus including the organic light-emitting device.

Additional aspects will be set forth in part in the description which follows and, in part, will be apparent from the description, or may be learned by practice of the presented embodiments of the disclosure.

According to one or more embodiments of the present disclosure, there is provided a heterocyclic compound represented by Formula 1:

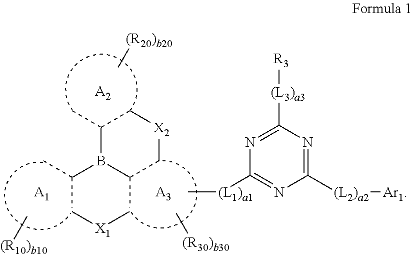

In Formula 1,
X₁ may be O, S, Se, or N(R₁),
X₂ may be O, S, Se, or N(R₂),
A₁ to A₃ may each independently be a C₅-C₃₀ carbocyclic group or a C₁-C₃₀ heterocyclic group,
L₁ to L₃ may each independently be a single bond, a C₅-C₆₀ carbocyclic group unsubstituted or substituted with at least one R₁₀ₐ, or a C₁-C₆₀ heterocyclic group unsubstituted or substituted with at least one R₁₀ₐ,
a1 to a3 may each independently be 1, 2, 3, 4, or 5, and
Ar₁ may be a group represented by Formula 2:

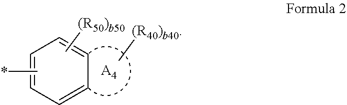

In Formula 2,
A₄ may be a C₃-C₁₀ non-aromatic carbocyclic group or a C₁-C₁₀ non-aromatic heterocyclic group, and
* indicates a binding site to a neighboring atom,

In Formula 1 and Formula 2,
R₁ to R₃, R₁₀, R₂₀, R₃₀, R₄₀, and R₅₀ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
at least two neighboring groups selected from among R₁ to R₃, R₁₀, R₂₀, R₃₀, R₄₀, and R₅₀ may optionally be bonded together to form a C₅-C₆₀ carbocyclic group unsubstituted or substituted with at least one R₁₀ₐ or a C₁-C₆₀ heterocyclic group unsubstituted or substituted with at least one R₁₀ₐ,
b10, b20, b30, and b40 may each independently be 1, 2, 3, 4, 5, 6, 7, or 8,
b50 may be 1, 2, or 3,
R₁₀ₐ may be:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆ alkoxy group, a phenyl group, a biphenyl group, or any combination thereof; a C₇-C₆₀ arylalkyl group; or a C₂-C₆₀ heteroarylalkyl group.

According to one or more embodiments of the present disclosure, an organic light-emitting device includes a first electrode, a second electrode, an interlayer between the first electrode and the second electrode and including an emission layer, and at least one of the heterocyclic compound.

According to one or more embodiments of the present disclosure, an electronic apparatus includes the organic light-emitting device.

According to one or more embodiments of the present disclosure, a consumer product includes the organic light-emitting device.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1-4 are each a schematic view of a structure of an organic light-emitting device according to one or more embodiments of the present disclosure;

FIG. 5 is a schematic view of a structure of a light-emitting apparatus according to one or more embodiments of the present disclosure;

FIG. 6 is a schematic view of a structure of a light-emitting apparatus according to one or more embodiments of the present disclosure;

FIG. 7 is a schematic perspective view of electronic equipment including an organic light-emitting device according to one or more embodiments of the present disclosure;

FIG. 8 is a schematic view of an exterior of a vehicle as electronic equipment including an organic light-emitting device according to one or more embodiments of the present disclosure; and

FIGS. 9A-9C are each a schematic view of an interior of a vehicle according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout the present disclosure, and duplicative descriptions thereof may not be provided for conciseness. In this regard, the presented embodiments may have different forms and should not be construed as being limited to the descriptions set forth herein. Accordingly, embodiments of the present disclosure are merely described in more detail, by referring to the drawings, to explain aspects of the present disclosure. As used herein, the term “and/or” or “or” includes any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

According to one or more embodiments of the present disclosure, there is provided a heterocyclic compound represented by Formula 1:

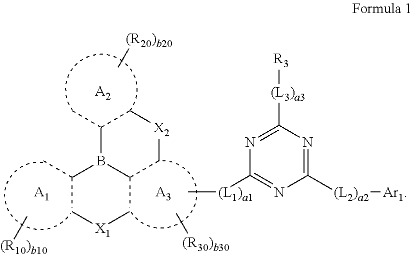

In Formula 1, X₁ may be O, S, Se, or N(R₁).

In Formula 1, X₂ may be O, S, Se, or N(R₂).

In one or more embodiments, X₁ and X₂ may be identical to each other.

In one or more embodiments, X₁ and X₂ may be different from each other.

In Formula 1, A₁ to A₃ may each independently be a C₅-C₆₀ carbocyclic group or a C₁-C₆₀ heterocyclic group.

In one or more embodiments, A₁ to A₃ may each independently be a benzene group, a naphthalene group, a phenanthrene group, a fluoranthene group, a triphenylene group, a pyrene group, a chrysene group, an indene group, a fluorene group, a spiro-bifluorene group, a benzofluorene group, a dibenzofluorene group, an indole group, a pyridine group, a pyrimidine group, a carbazole group, a benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, or a dinaphthothiophene group.

In Formula 1, Ar₁ may be a group represented by Formula 2:

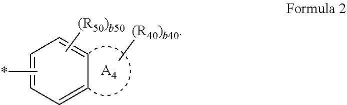

wherein, in Formula 2,
A₄ may be a C₃-C₁₀ non-aromatic carbocyclic group or a C₁-C₁₀ non-aromatic heterocyclic group, and
* indicates a binding site to a neighboring atom.

In one or more embodiments, A₄ may be a cyclopentane group, a cyclohexane group, a cycloheptane group, a cyclopentene group, a cyclohexene group, or a cycloheptene group.

In one or more embodiments, Ar₁ may be a group represented by Formula 2A or Formula 2B:

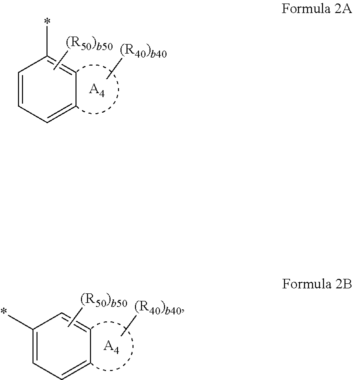

wherein, in Formula 2A and Formula 2B,
A₄, R₄₀, R₅₀, b40, and b50 may each be the same as described elsewhere herein, and
* indicates a binding site to a neighboring atom.

In one or more embodiments, Ar₁ may be a group represented by any one selected from among Formulae 3A to 3D:

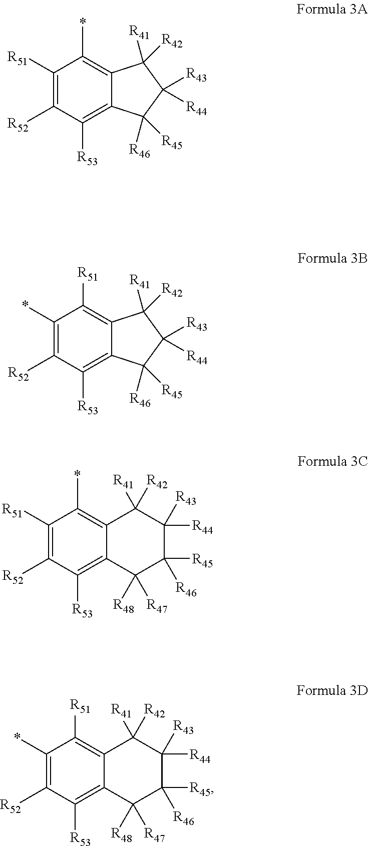

wherein, in Formulae 3A to 3D,
R₄₁ to R₄₈ may each independently be the same as described with respect to R₄₀,
R₅₁ to R₅₃ may each independently be the same as described with respect to R₅₀, and
* indicates a binding site to a neighboring atom.

In one or more embodiments, Ar₁ may be a group represented by any one selected from among Formulae 3-1 to 3-16:

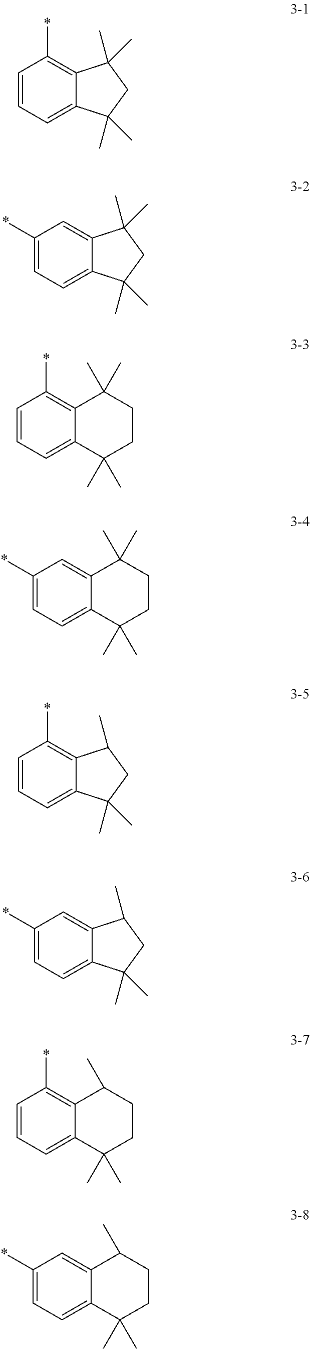

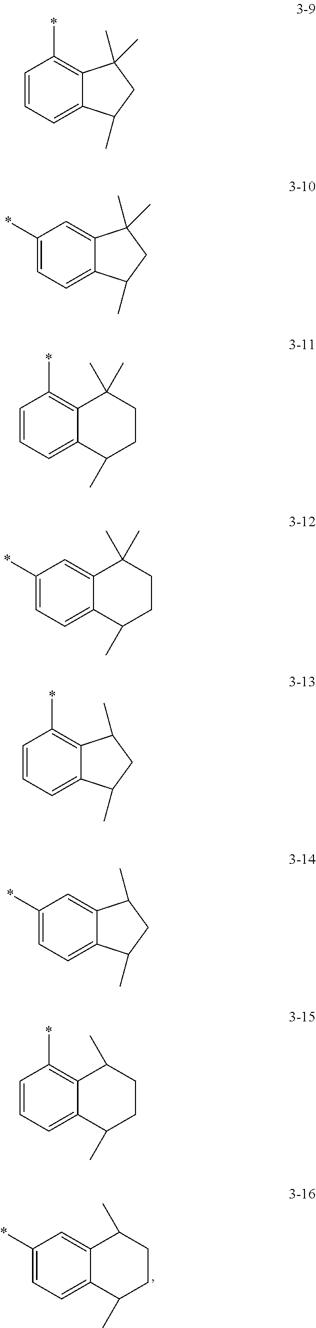

wherein, in Formulae 3-1 to 3-16,
* indicates a binding site to a neighboring atom.

In Formula 1, L₁ to L₃ may each independently be a single bond, or may each independently be a C₅-C₆₀ carbocyclic group unsubstituted or substituted with at least one R₁₀ₐ or a C₁-C₆₀ heterocyclic group unsubstituted or substituted with at least one R₁₀ₐ.

In one or more embodiments, L₁ to L₃ may each independently be: a single bond; or a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, an dibenzodihydrodisiline group, a dibenzodihydrosiline group, a dibenzodioxin group, a dibenzoxathiin group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

In one or more embodiments, L₁ to L₃ may each independently be a single bond or a group represented by any one selected from among Formulae 4-1 to 4-25:

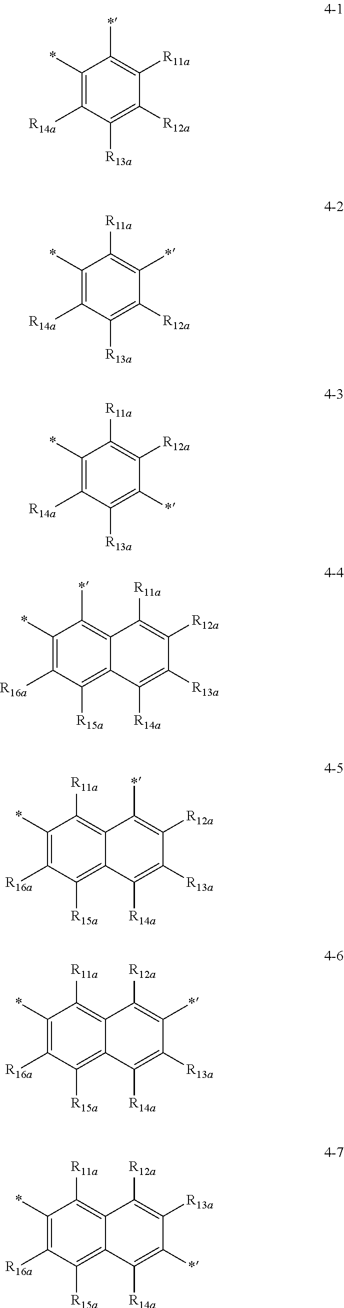

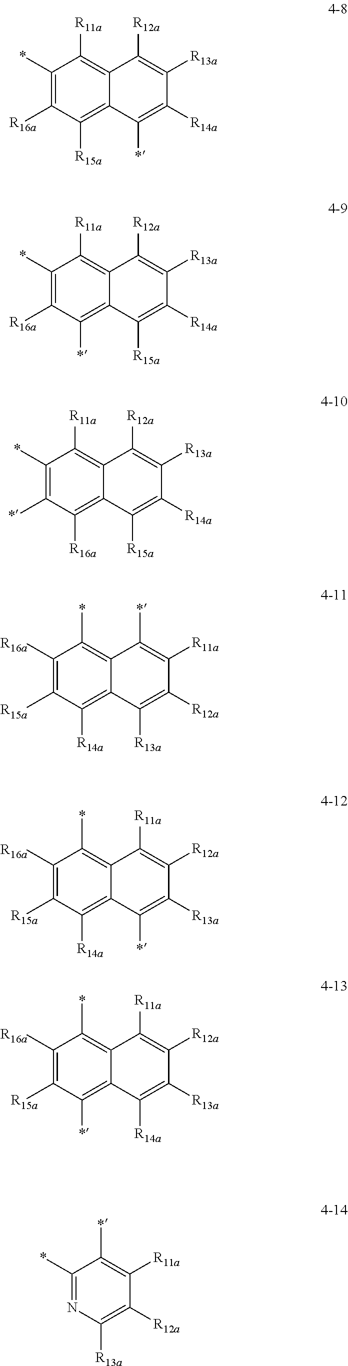

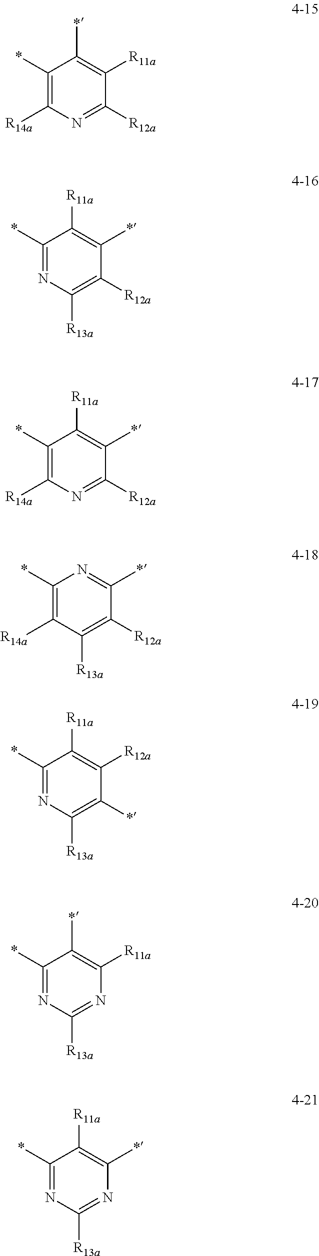

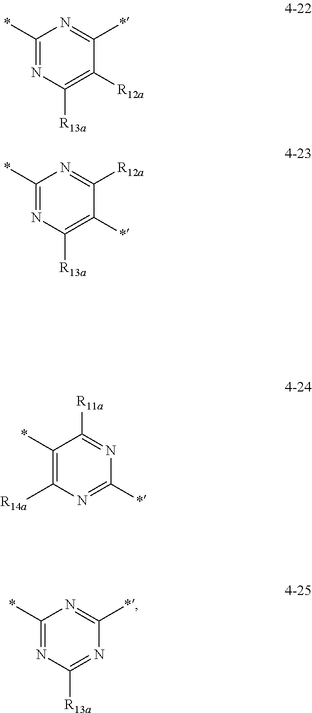

wherein, in Formulae 4-1 to 4-25,
R₁₁ₐ to R₁₆ₐ may each independently be the same as described with respected to R₁₀ₐ, and
* and *′ each indicate a binding site to a neighboring atom.

In Formula 1, a1 to a3 may each independently be 1, 2, 3, 4, or 5.

In one or more embodiments, a1 to a3 may each independently be 1, 2, or 3.

In one or more embodiments, R₁ to R₃, R₁₀, R₂₀, R₃₀, R₄₀, and R₅₀ may each independently be: hydrogen, deuterium, —F, —Cl, —Br, —I, a cyano group, a C₁-C₂₀ alkyl group, or a C₁-C₂₀ alkoxy group; or a group represented by any one selected from among Formulae 5-1 to 5-26 and Formulae 6-1 to 6-55:

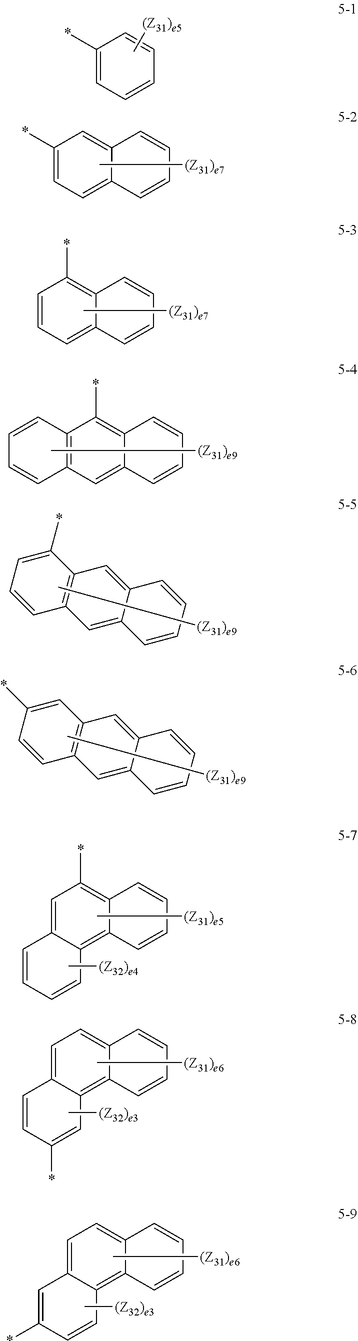

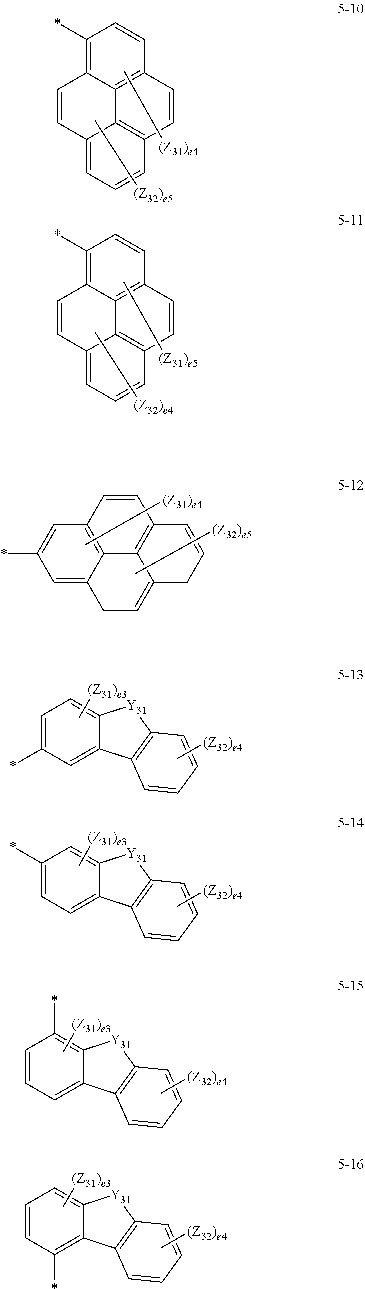

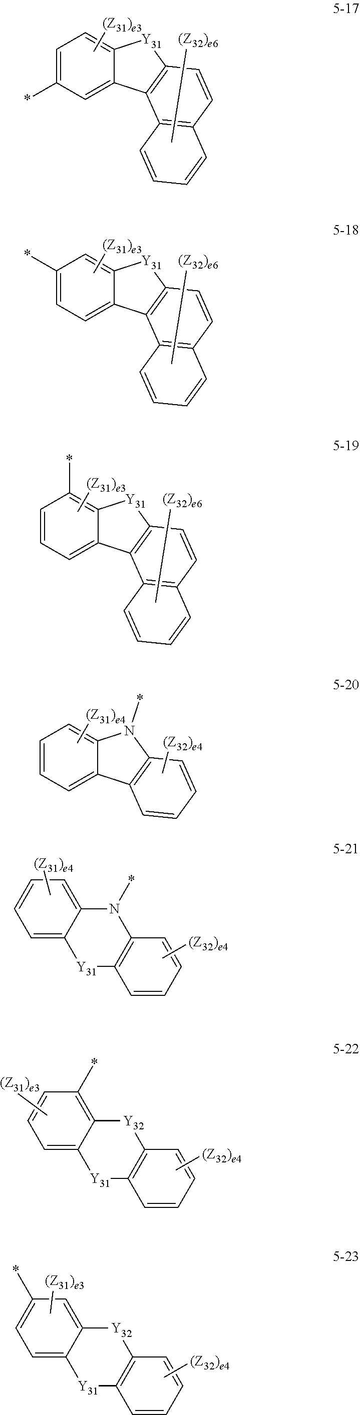

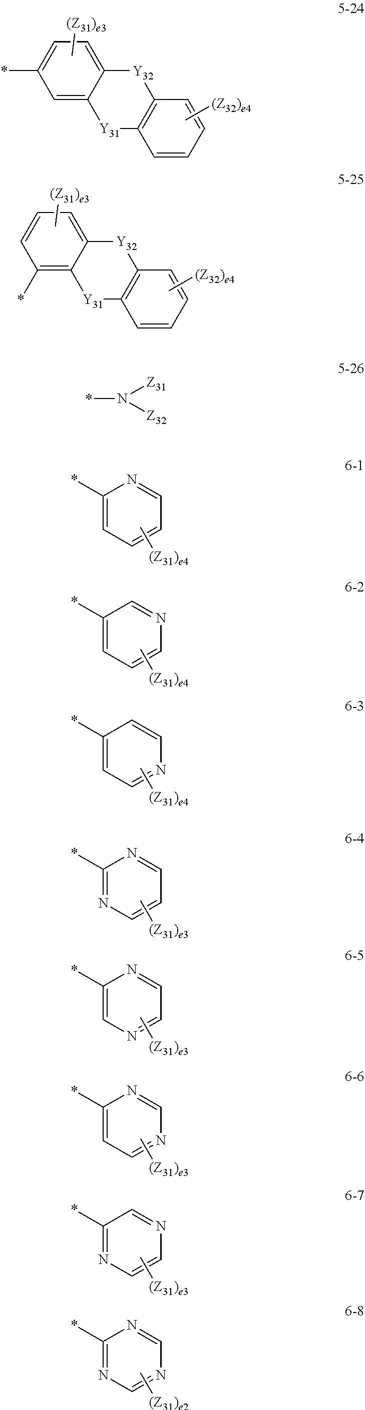

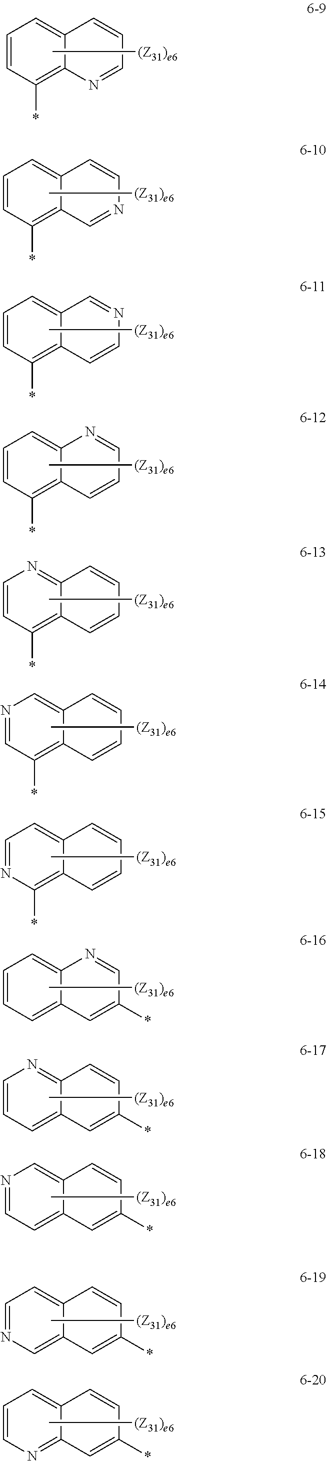

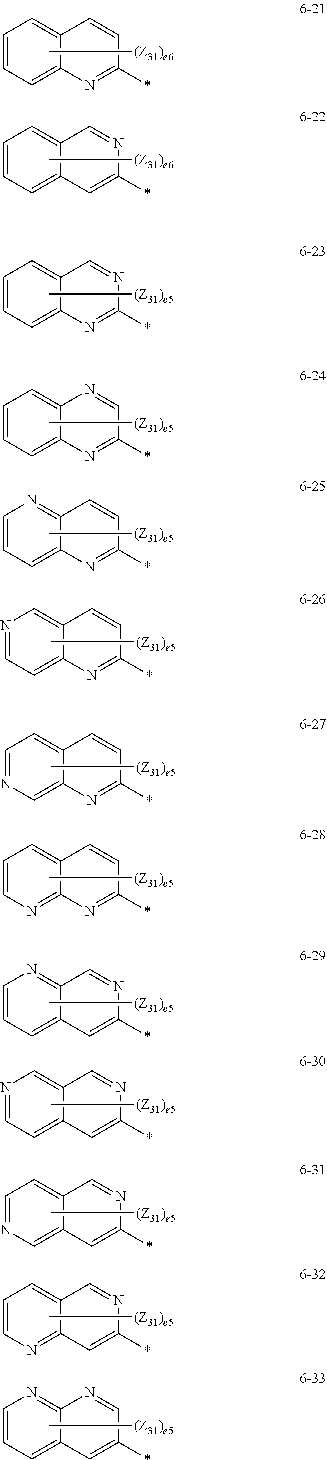

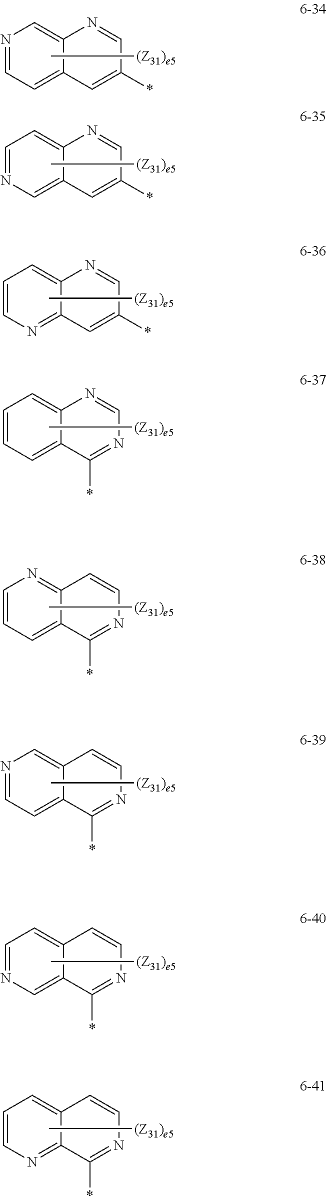

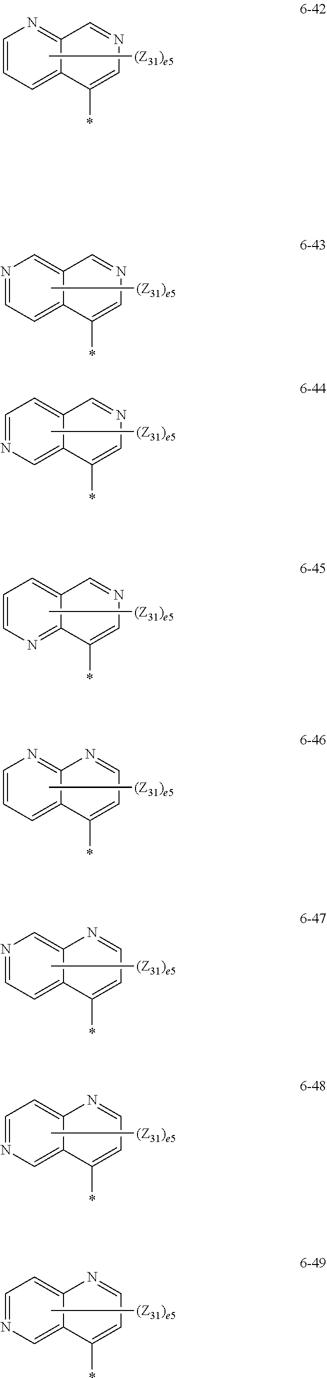

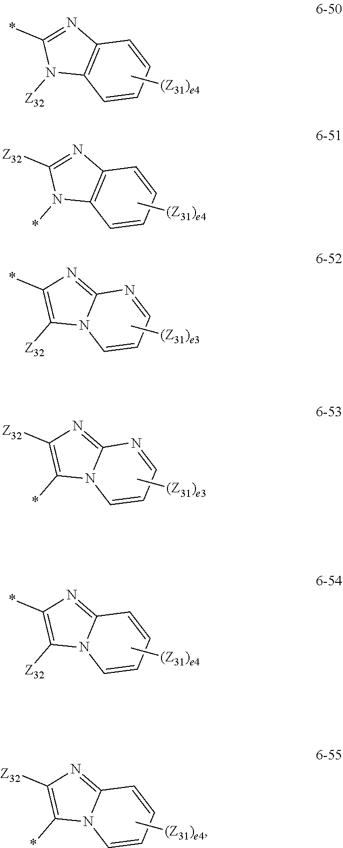

wherein, in Formulae 5-1 to 5-26 and 6-1 to 6-55,
Y₃₁ and Y₃₂ may each independently be O, S, C(Z₃₃)(Z₃₄), N(Z₃₃), or Si(Z₃₃) (Z₃₄),
Z₃₁ to Z₃₄ may each independently be selected from among hydrogen, deuterium, —F, —Cl, —Br, —I, a hydroxyl group, a cyano group, a nitro group, an amidino group, a hydrazino group, a hydrazono group, a C₁-C₂₀ alkyl group, a C₂-C₂₀ alkenyl group, a C₂-C₂₀ alkynyl group, a C₁-C₂₀ alkoxy group, a phenyl group, a biphenyl group, a terphenyl group, a naphthyl group, a fluorenyl group, a spiro-bifluorenyl group, a phenanthrenyl group, an anthracenyl group, a triphenylenyl group, a pyridinyl group, a pyrimidinyl group, a carbazolyl group, and a triazinyl group,
e2 may be 1 or 2,
e3 may be an integer from 1 to 3,
e4 may be an integer from 1 to 4,
e5 may be an integer from 1 to 5,
e6 may be an integer from 1 to 6,
e7 may be an integer from 1 to 7,
e9 may be an integer from 1 to 9, and
* indicates a binding site to a neighboring atom.

In Formula 1 and Formula 2, R₁ to R₃, R₁₀, R₂₀, R₃₀, R₄₀, and R₅₀ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂).

In one or more embodiments, R₁ to R₃, R₁₀, R₂₀, R₃₀, R₄₀, and R₅₀ may each independently be: hydrogen, deuterium, —F, —Cl, —Br, —I, a cyano group, a C₁-C₂₀ alkyl group, or a C₁-C₂₀ alkoxy group;
a C₁-C₂₀ alkyl group, a C₁-C₂₀ alkoxy group, or a C₃-C₁₀ cycloalkyl group, each substituted with deuterium, —F, —Cl, —Br, —I, —CDH₂, —CD₂H, —CD₃, a cyano group, a phenyl group, a biphenyl group, or any combination thereof;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, an isoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphthosilolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indenocarbazolyl group, or an indolocarbazolyl group;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, an isoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphthosilolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indenocarbazolyl group, or an indolocarbazolyl group, each substituted with deuterium, —F, —Cl, —Br, —I, —CDH₂, —CD₂H, —CD₃, a cyano group, a C₁-C₂₀ alkyl group, a C₁-C₂₀ alkoxy group, a C₃-C₁₀ cycloalkyl group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, an isoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphthosilolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indenocarbazolyl group, an indolocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)(Q₃₁), —S(═O)₂(Q₃₁), —P(═O)(Q₃₁)(Q₃₂), —P(═S)(Q₃₁)(Q₃₂), or any combination thereof; or
—Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂).

In one or more embodiments, R₁ to R₃, R₁₀, R₂₀, R₃₀, R₄₀, and R₅₀ may each independently be: hydrogen, deuterium, —F, —Cl, —Br, —I, a cyano group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, a cyano group, a phenyl group, a biphenyl group, or any combination thereof;
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a carbazolyl group, an acridinyl group, a dibenzofuranyl group, a dibenzothiophenyl group, a benzocarbazolyl group, or a dibenzocarbazolyl group; or
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a carbazolyl group, an acridinyl group, a dibenzofuranyl group, a dibenzothiophenyl group, a benzocarbazolyl group, or a dibenzocarbazolyl group, each substituted with deuterium, —F, —Cl, —Br, —I, a cyano group, a C₁-C₂₀ alkyl group, a C₁-C₂₀ alkoxy group, a phenyl group, a biphenyl group, or any combination thereof.

In Formula 1 and Formula 2, at least two neighboring groups selected from among R₁ to R₃, R₁₀, R₂₀, R₃₀, R₄₀, and R₅₀ may optionally be bonded together to form a C₅-C₆₀ carbocyclic group unsubstituted or substituted with at least one R₁₀ₐ or a C₁-C₆₀ heterocyclic group unsubstituted or substituted with at least one R₁₀ₐ.

In one or more embodiments, at least two neighboring groups selected from among R₁ to R₃, R₁₀, R₂₀, R₃₀, R₄₀, and R₅₀ may optionally be bonded together to form a cyclopentane group, a cyclohexane group, a cycloheptane group, a fluorene group, or a carbazole group, each unsubstituted or substituted with at least one R₁₀ₐ.

In Formulae 1 and 2, b10, b20, b30, and b40 may each independently be 1, 2, 3, 4, 5, 6, 7, or 8.

In Formula 2, b50 may be 1, 2, or 3.

In one or more embodiments, R₃ may be: a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclohexyl group, a phenyl group, or a naphthyl group; or
a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclohexyl group, a phenyl group, or a naphthyl group, each substituted with deuterium, —F, —Cl, —Br, —I, a cyano group, a C₁-C₂₀ alkyl group, a C₁-C₂₀ alkoxy group, a phenyl group, a biphenyl group, or any combination thereof.
R₁₀ₐ may be:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

In one or more embodiments, the heterocyclic compound represented by Formula 1 may be a heterocyclic compound represented by Formula 11 or Formula 12:

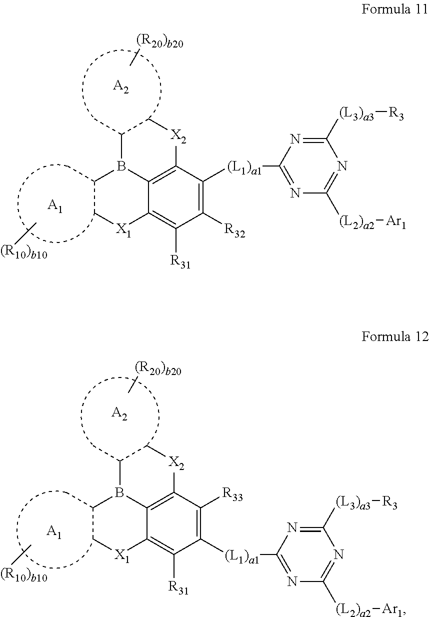

wherein, in Formulae 11 and 12,
X₁, X₂, A₁, A₂, L₁ to L₃, a1 to a3, Ar₁, R₃, b10, b20, R₁₀, R₂₀, R₄₀, and R₅₀ may each be the same as described elsewhere herein, and
R₃₁ to R₃₃ may each independently the same be as described with respect to R₃₀.

In one or more embodiments, the heterocyclic compound represented by Formula 1 may be a heterocyclic compound represented by Formula 21 or Formula 22:

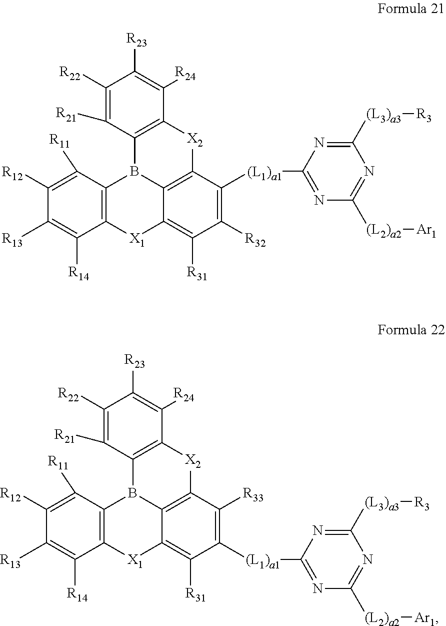

wherein, in Formula 21 and Formula 22,
X₁, X₂, L₁ to L₃, a1 to a3, Ar₁, and R₃, may each be the same as described elsewhere herein,
R₁₁ to R₁₄ may each independently be the same as described with respect to R₁₀,
R₂₁ to R₂₄ may each independently be the same as described with respect to R₂₀, and
R₃₁ to R₃₃ may each independently be the same as described with respect to R₃₀.

In one or more embodiments, the heterocyclic compound represented by Formula 1 may be any one selected from among Compounds 1 to 316, but embodiments of the present disclosure are not limited thereto:

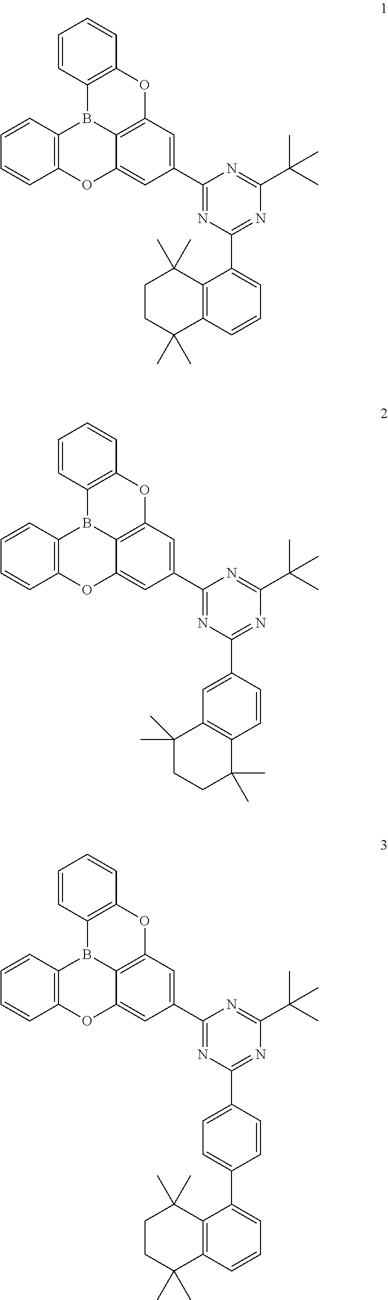 [SMILES: CC(C)(C)c1nc(-c2cc3c4c(c2)Oc2ccccc2B4c2ccccc2O3)nc(-c2cccc3c2C(C)(C)CCC3(C)C)n1 ; CC(C)(C)c1nc(-c2cc3c4c(c2)Oc2ccccc2B4c2ccccc2O3)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)Oc2ccccc2B4c2ccccc2O3)n1]

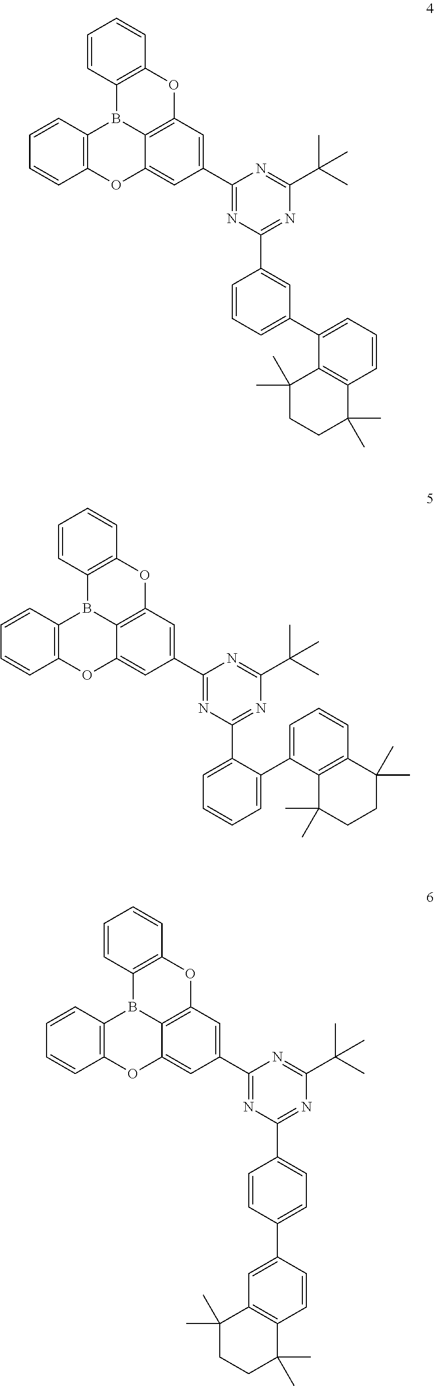 [SMILES: CC(C)(C)c1nc(-c2cccc(-c3cccc4c3C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2cccc3c2C(C)(C)CCC3(C)C)n1 ; CC(C)(C)c1nc(-c2ccc(-c3ccc4c(c3)C(C)(C)CCC4(C)C)cc2)nc(-c2cc3c4c(c2)Oc2ccccc2B4c2ccccc2O3)n1]

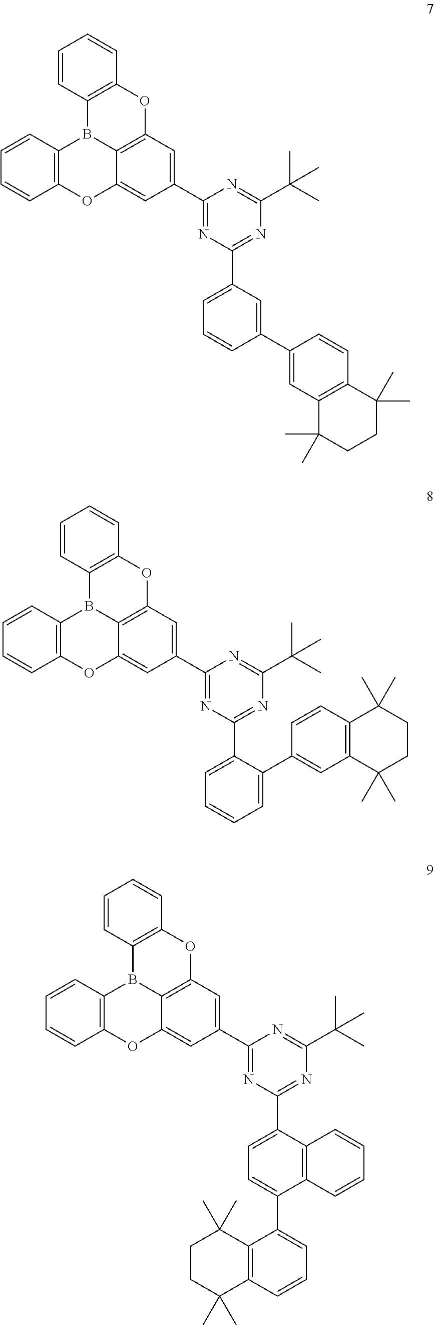 [SMILES: CC(C)(C)c1nc(-c2cccc(-c3ccc4c(c3)C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc3c(c2)C(C)(C)CCC3(C)C)n1 ; CC(C)(C)c1nc(-c2cc3c4c(c2)Oc2ccccc2B4c2ccccc2O3)nc(-c2ccc(-c3cccc4c3C(C)(C)CCC4(C)C)c3ccccc23)n1]

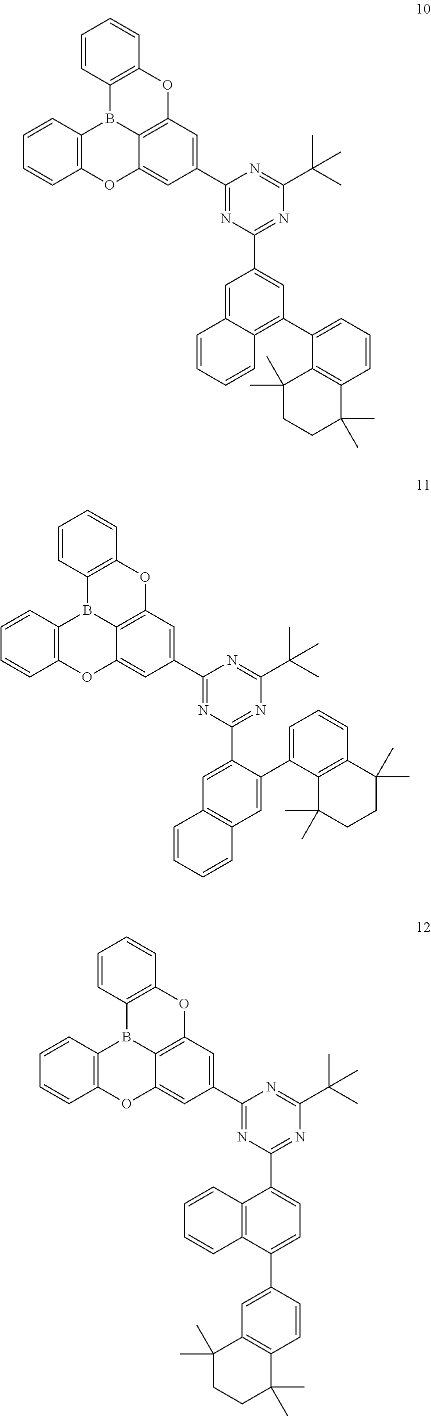 [SMILES: CC(C)(C)c1nc(-c2cc3c4c(c2)Oc2ccccc2B4c2ccccc2O3)nc(-c2cc(-c3cccc4c3C(C)(C)CCC4(C)C)c3ccccc3c2)n1 ; CC(C)(C)c1nc(-c2cc3c4c(c2)Oc2ccccc2B4c2ccccc2O3)nc(-c2cc3ccccc3cc2-c2cccc3c2C(C)(C)CCC3(C)C)n1 ; CC(C)(C)c1nc(-c2cc3c4c(c2)Oc2ccccc2B4c2ccccc2O3)nc(-c2ccc(-c3ccc4c(c3)C(C)(C)CCC4(C)C)c3ccccc23)n1]

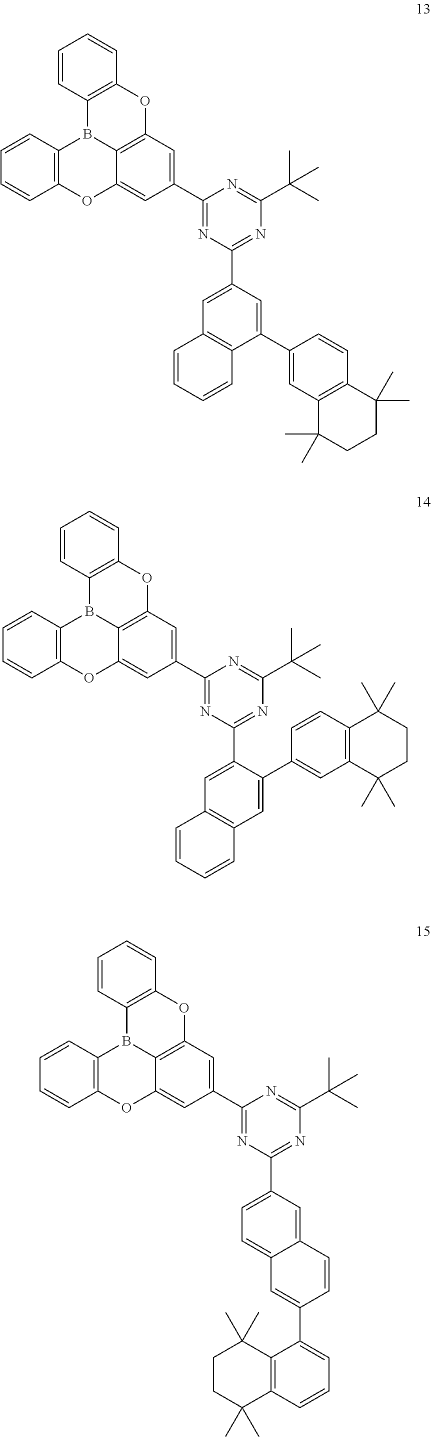 [SMILES: CC(C)(C)c1nc(-c2cc3c4c(c2)Oc2ccccc2B4c2ccccc2O3)nc(-c2cc(-c3ccc4c(c3)C(C)(C)CCC4(C)C)c3ccccc3c2)n1 ; CC(C)(C)c1nc(-c2cc3c4c(c2)Oc2ccccc2B4c2ccccc2O3)nc(-c2cc3ccccc3cc2-c2ccc3c(c2)C(C)(C)CCC3(C)C)n1 ; CC(C)(C)c1nc(-c2cc3c4c(c2)Oc2ccccc2B4c2ccccc2O3)nc(-c2ccc3cc(-c4cccc5c4C(C)(C)CCC5(C)C)ccc3c2)n1]

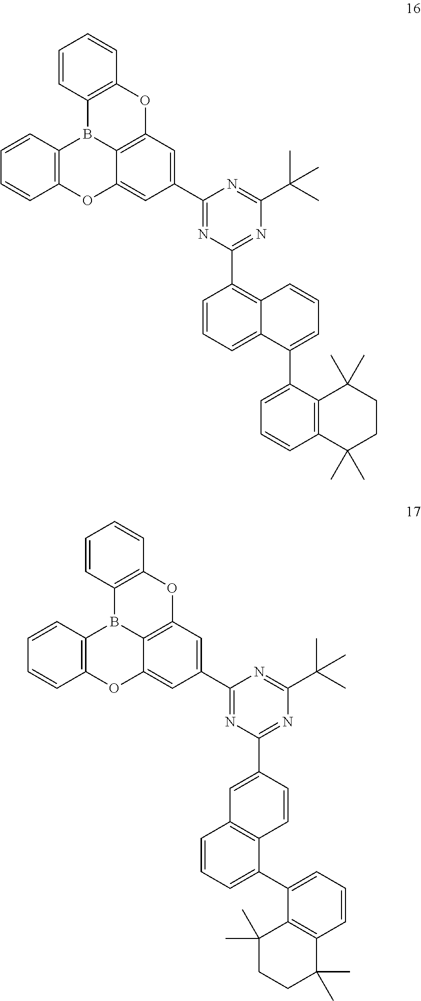 [SMILES: CC(C)(C)c1nc(-c2cc3c4c(c2)Oc2ccccc2B4c2ccccc2O3)nc(-c2cccc3c(-c4cccc5c4C(C)(C)CCC5(C)C)cccc23)n1 ; CC(C)(C)c1nc(-c2cc3c4c(c2)Oc2ccccc2B4c2ccccc2O3)nc(-c2ccc3c(-c4cccc5c4C(C)(C)CCC5(C)C)cccc3c2)n1]

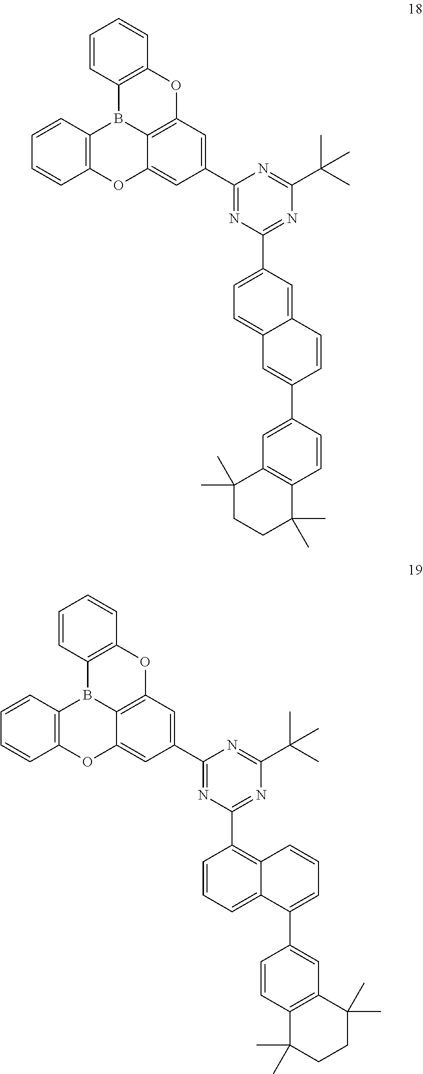 [SMILES: CC(C)(C)c1nc(-c2cc3c4c(c2)Oc2ccccc2B4c2ccccc2O3)nc(-c2ccc3cc(-c4ccc5c(c4)C(C)(C)CCC5(C)C)ccc3c2)n1 ; CC(C)(C)c1nc(-c2cc3c4c(c2)Oc2ccccc2B4c2ccccc2O3)nc(-c2cccc3c(-c4ccc5c(c4)C(C)(C)CCC5(C)C)cccc23)n1]

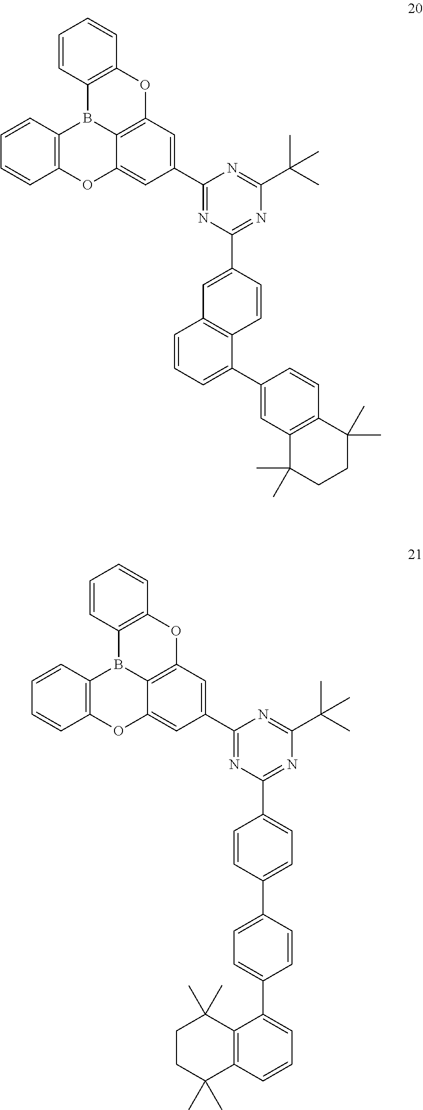 [SMILES: CC(C)(C)c1nc(-c2cc3c4c(c2)Oc2ccccc2B4c2ccccc2O3)nc(-c2ccc3c(-c4ccc5c(c4)C(C)(C)CCC5(C)C)cccc3c2)n1 ; CC(C)(C)c1nc(-c2ccc(-c3ccc(-c4cccc5c4C(C)(C)CCC5(C)C)cc3)cc2)nc(-c2cc3c4c(c2)Oc2ccccc2B4c2ccccc2O3)n1]

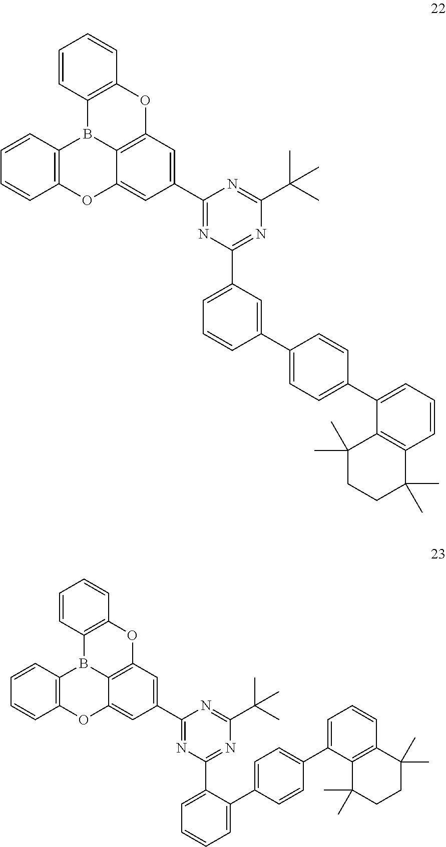 [SMILES: CC(C)(C)c1nc(-c2cccc(-c3ccc(-c4cccc5c4C(C)(C)CCC5(C)C)cc3)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc(-c3cccc4c3C(C)(C)CCC4(C)C)cc2)n1]

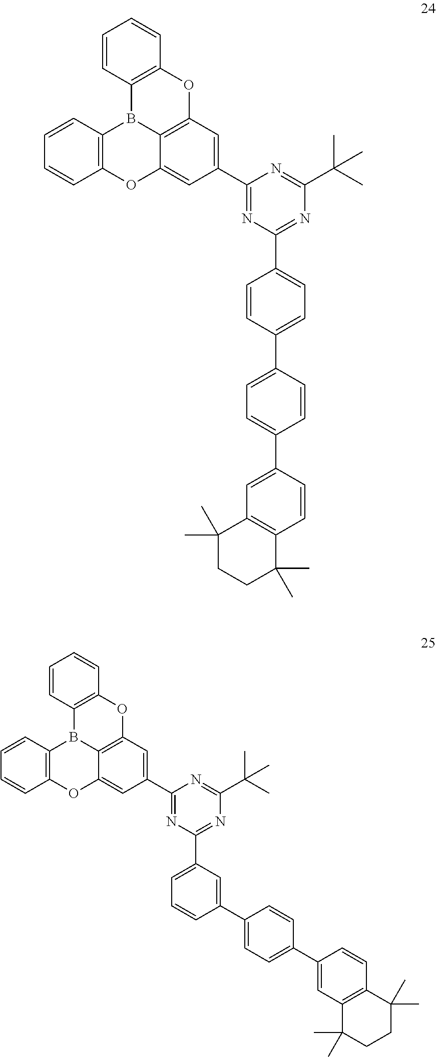 [SMILES: CC(C)(C)c1nc(-c2ccc(-c3ccc(-c4ccc5c(c4)C(C)(C)CCC5(C)C)cc3)cc2)nc(-c2cc3c4c(c2)Oc2ccccc2B4c2ccccc2O3)n1 ; CC(C)(C)c1nc(-c2cccc(-c3ccc(-c4ccc5c(c4)C(C)(C)CCC5(C)C)cc3)c2)nc(-c2cc3c4c(c2)Oc2ccccc2B4c2ccccc2O3)n1]

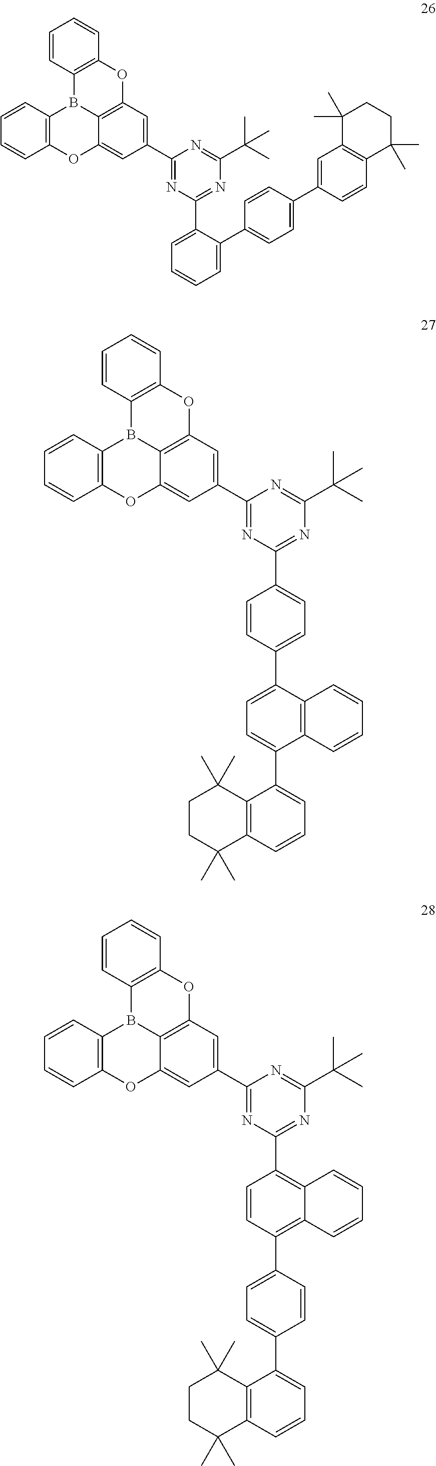 [SMILES: CC(C)(C)c1nc(-c2cc3c4c(c2)Oc2ccccc2B4c2ccccc2O3)nc(-c2ccccc2-c2ccc(-c3ccc4c(c3)C(C)(C)CCC4(C)C)cc2)n1 ; CC(C)(C)c1nc(-c2ccc(-c3ccc(-c4cccc5c4C(C)(C)CCC5(C)C)c4ccccc34)cc2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(-c3ccc(-c4cccc5c4C(C)(C)CCC5(C)C)cc3)c3ccccc23)n1]

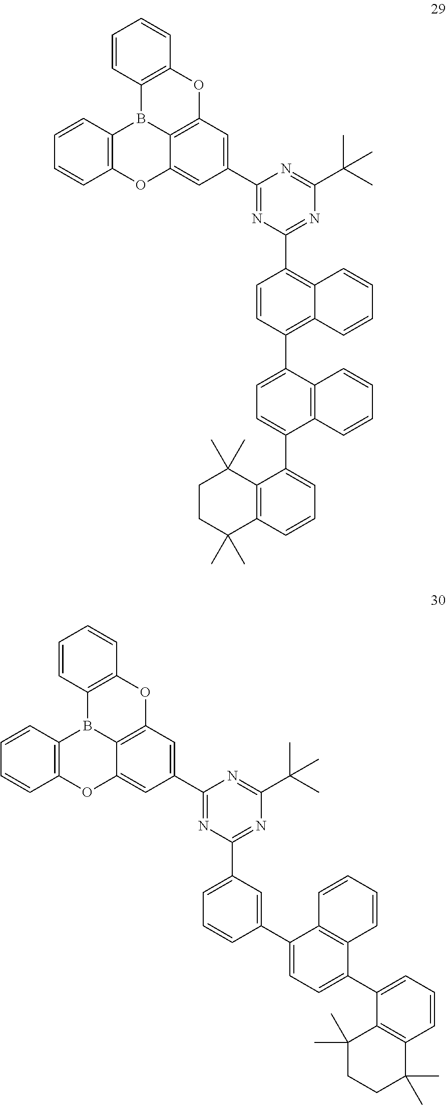 [SMILES: CC(C)(C)c1nc(-c2cc3c4c(c2)Oc2ccccc2B4c2ccccc2O3)nc(-c2ccc(-c3ccc(-c4cccc5c4C(C)(C)CCC5(C)C)c4ccccc34)c3ccccc23)n1 ; CC(C)(C)c1nc(-c2cccc(-c3ccc(-c4cccc5c4C(C)(C)CCC5(C)C)c4ccccc34)c2)nc(-c2cc3c4c(c2)Oc2ccccc2B4c2ccccc2O3)n1]

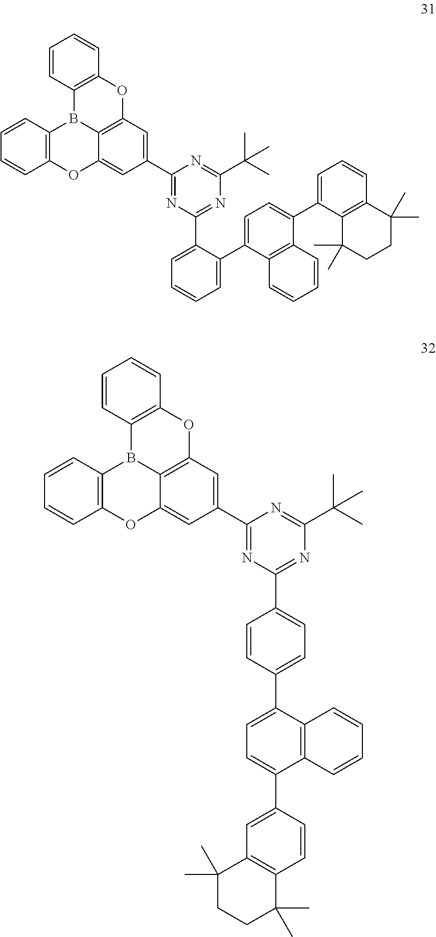 [SMILES: CC(C)(C)c1nc(-c2cc3c4c(c2)Oc2ccccc2B4c2ccccc2O3)nc(-c2ccccc2-c2ccc(-c3cccc4c3C(C)(C)CCC4(C)C)c3ccccc23)n1 ; CC(C)(C)c1nc(-c2ccc(-c3ccc(-c4ccc5c(c4)C(C)(C)CCC5(C)C)c4ccccc34)cc2)nc(-c2cc3c4c(c2)Oc2ccccc2B4c2ccccc2O3)n1]

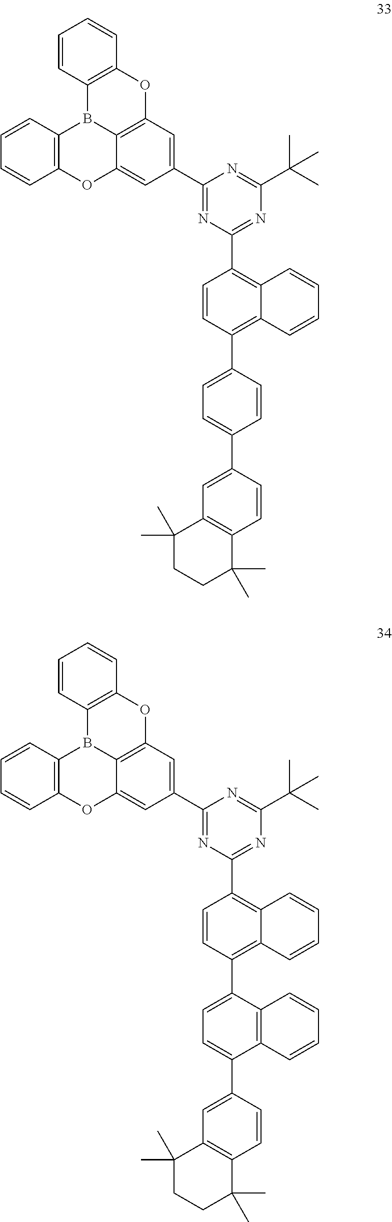 [SMILES: CC(C)(C)c1nc(-c2cc3c4c(c2)Oc2ccccc2B4c2ccccc2O3)nc(-c2ccc(-c3ccc(-c4ccc5c(c4)C(C)(C)CCC5(C)C)cc3)c3ccccc23)n1 ; CC(C)(C)c1nc(-c2cc3c4c(c2)Oc2ccccc2B4c2ccccc2O3)nc(-c2ccc(-c3ccc(-c4ccc5c(c4)C(C)(C)CCC5(C)C)c4ccccc34)c3ccccc23)n1]

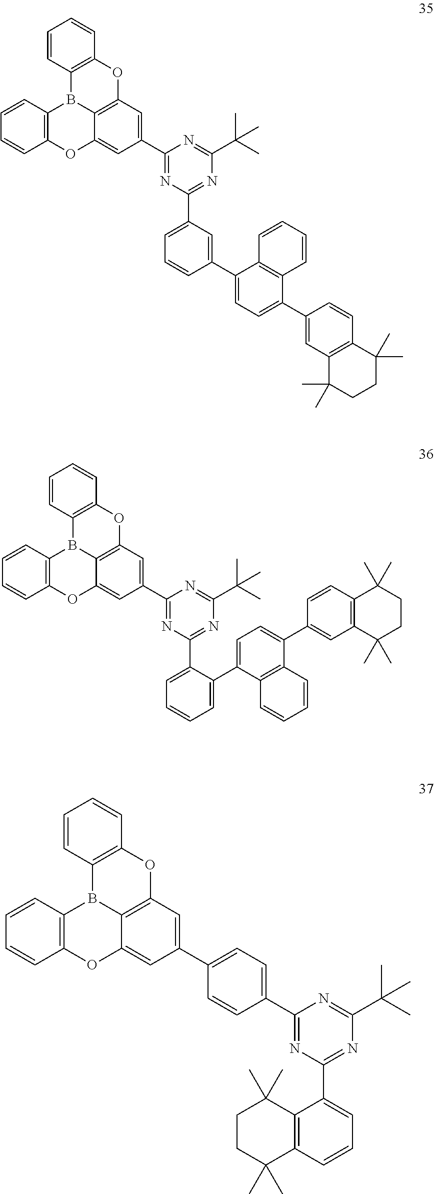 [SMILES: CC(C)(C)c1nc(-c2cccc(-c3ccc(-c4ccc5c(c4)C(C)(C)CCC5(C)C)c4ccccc34)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc(-c3ccc4c(c3)C(C)(C)CCC4(C)C)c3ccccc23)n1 ; CC(C)(C)c1nc(-c2ccc(-c3cc4c5c(c3)Oc3ccccc3B5c3ccccc3O4)cc2)nc(-c2cccc3c2C(C)(C)CCC3(C)C)n1]

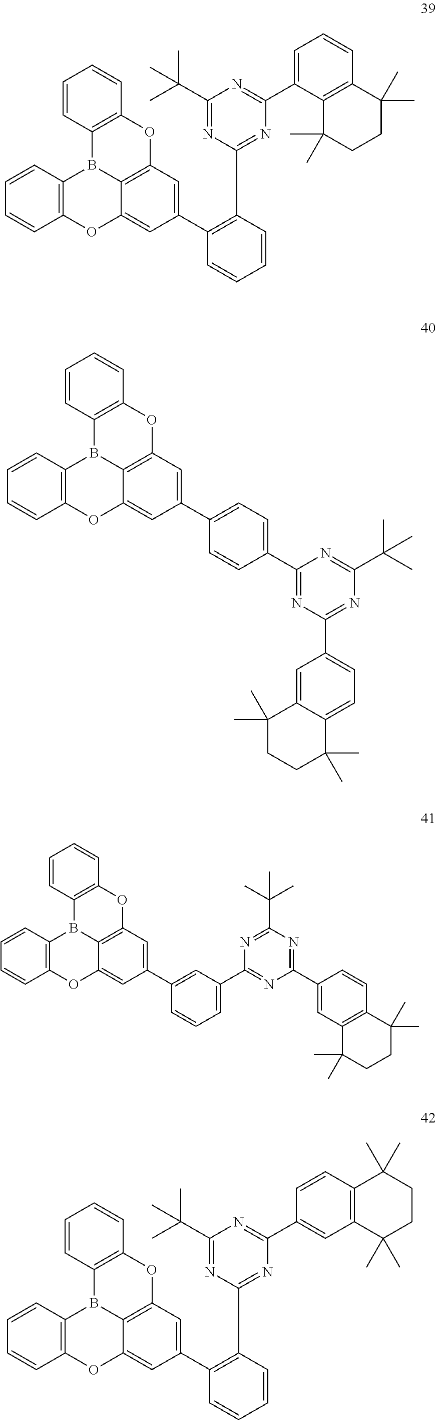 [SMILES: CC(C)(C)c1nc(-c2ccccc2-c2cc3c4c(c2)Oc2ccccc2B4c2ccccc2O3)nc(-c2cccc3c2C(C)(C)CCC3(C)C)n1 ; CC(C)(C)c1nc(-c2ccc(-c3cc4c5c(c3)Oc3ccccc3B5c3ccccc3O4)cc2)nc(-c2ccc3c(c2)C(C)(C)CCC3(C)C)n1 ; CC(C)(C)c1nc(-c2cccc(-c3cc4c5c(c3)Oc3ccccc3B5c3ccccc3O4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Oc2ccccc2B4c2ccccc2O3)n1]

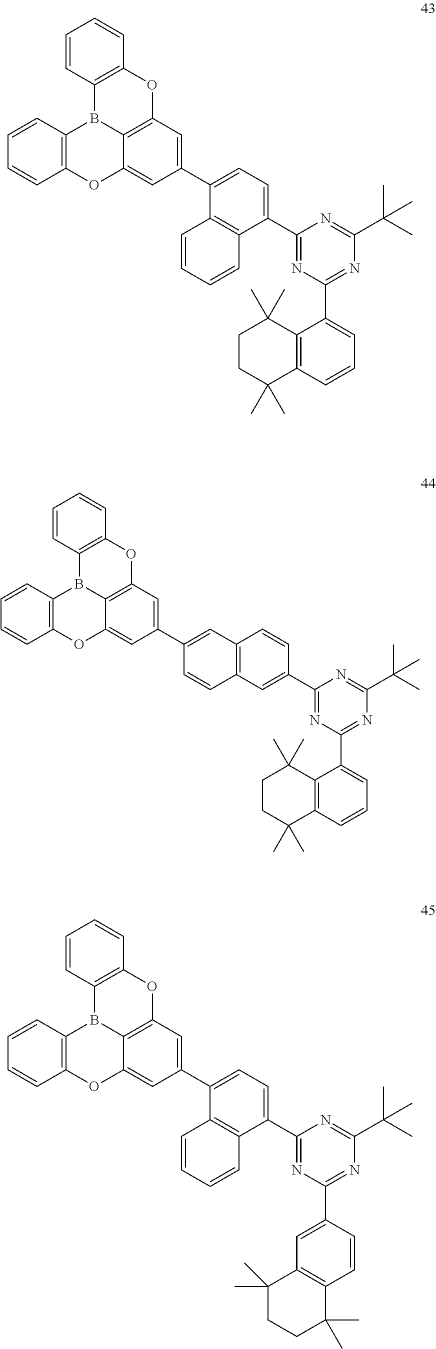 [SMILES: CC(C)(C)c1nc(-c2cccc3c2C(C)(C)CCC3(C)C)nc(-c2ccc(-c3cc4c5c(c3)Oc3ccccc3B5c3ccccc3O4)c3ccccc23)n1 ; CC(C)(C)c1nc(-c2ccc3cc(-c4cc5c6c(c4)Oc4ccccc4B6c4ccccc4O5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Oc3ccccc3B5c3ccccc3O4)c3ccccc23)n1]

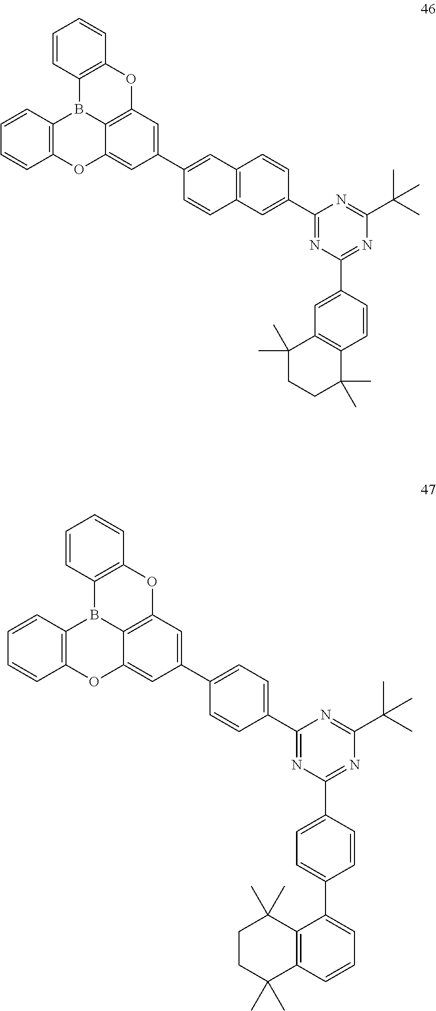 [SMILES: CC(C)(C)c1nc(-c2ccc3c(c2)C(C)(C)CCC3(C)C)nc(-c2ccc3cc(-c4cc5c6c(c4)Oc4ccccc4B6c4ccccc4O5)ccc3c2)n1 ; CC(C)(C)c1nc(-c2ccc(-c3cc4c5c(c3)Oc3ccccc3B5c3ccccc3O4)cc2)nc(-c2ccc(-c3cccc4c3C(C)(C)CCC4(C)C)cc2)n1]

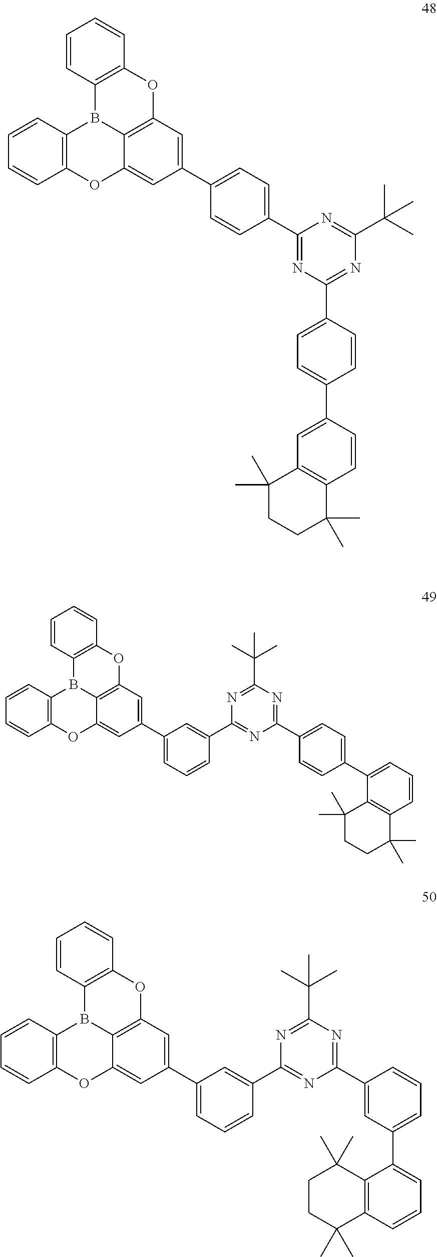 [SMILES: CC(C)(C)c1nc(-c2ccc(-c3cc4c5c(c3)Oc3ccccc3B5c3ccccc3O4)cc2)nc(-c2ccc(-c3ccc4c(c3)C(C)(C)CCC4(C)C)cc2)n1 ; CC(C)(C)c1nc(-c2ccc(-c3cccc4c3C(C)(C)CCC4(C)C)cc2)nc(-c2cccc(-c3cc4c5c(c3)Oc3ccccc3B5c3ccccc3O4)c2)n1 ; CC(C)(C)c1nc(-c2cccc(-c3cc4c5c(c3)Oc3ccccc3B5c3ccccc3O4)c2)nc(-c2cccc(-c3cccc4c3C(C)(C)CCC4(C)C)c2)n1]

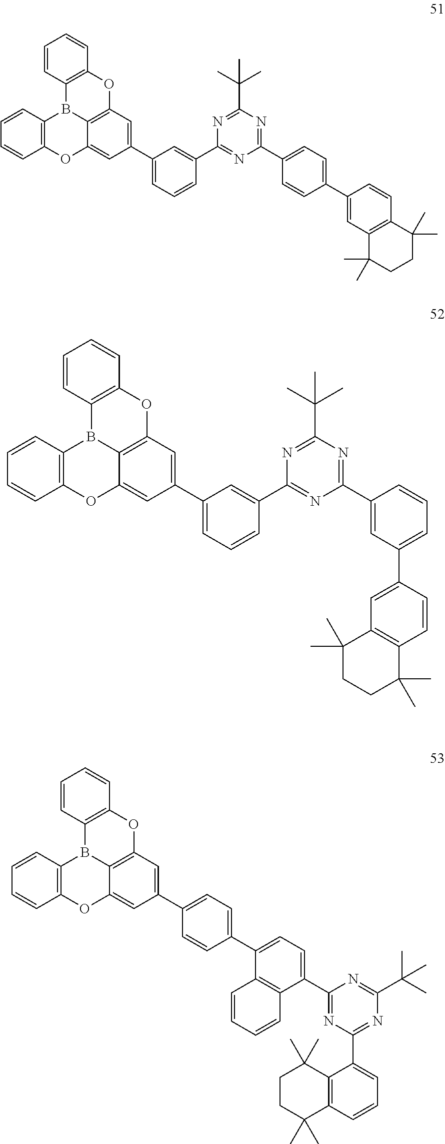 [SMILES: CC(C)(C)c1nc(-c2ccc(-c3ccc4c(c3)C(C)(C)CCC4(C)C)cc2)nc(-c2cccc(-c3cc4c5c(c3)Oc3ccccc3B5c3ccccc3O4)c2)n1 ; CC(C)(C)c1nc(-c2cccc(-c3cc4c5c(c3)Oc3ccccc3B5c3ccccc3O4)c2)nc(-c2cccc(-c3ccc4c(c3)C(C)(C)CCC4(C)C)c2)n1 ; CC(C)(C)c1nc(-c2cccc3c2C(C)(C)CCC3(C)C)nc(-c2ccc(-c3ccc(-c4cc5c6c(c4)Oc4ccccc4B6c4ccccc4O5)cc3)c3ccccc23)n1]

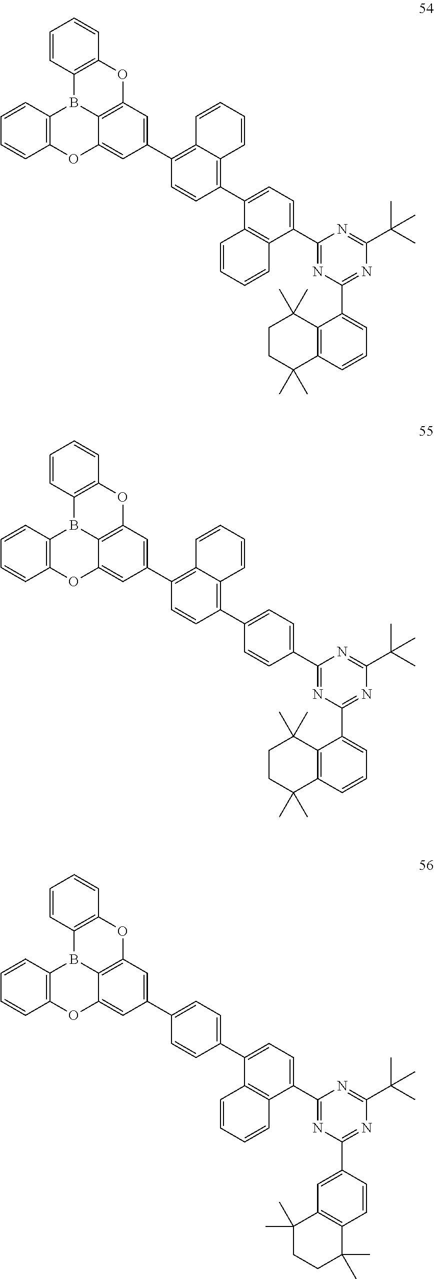 [SMILES: CC(C)(C)c1nc(-c2cccc3c2C(C)(C)CCC3(C)C)nc(-c2ccc(-c3ccc(-c4cc5c6c(c4)Oc4ccccc4B6c4ccccc4O5)c4ccccc34)c3ccccc23)n1 ; CC(C)(C)c1nc(-c2ccc(-c3ccc(-c4cc5c6c(c4)Oc4ccccc4B6c4ccccc4O5)c4ccccc34)cc2)nc(-c2cccc3c2C(C)(C)CCC3(C)C)n1 ; CC(C)(C)c1nc(-c2ccc3c(c2)C(C)(C)CCC3(C)C)nc(-c2ccc(-c3ccc(-c4cc5c6c(c4)Oc4ccccc4B6c4ccccc4O5)cc3)c3ccccc23)n1]

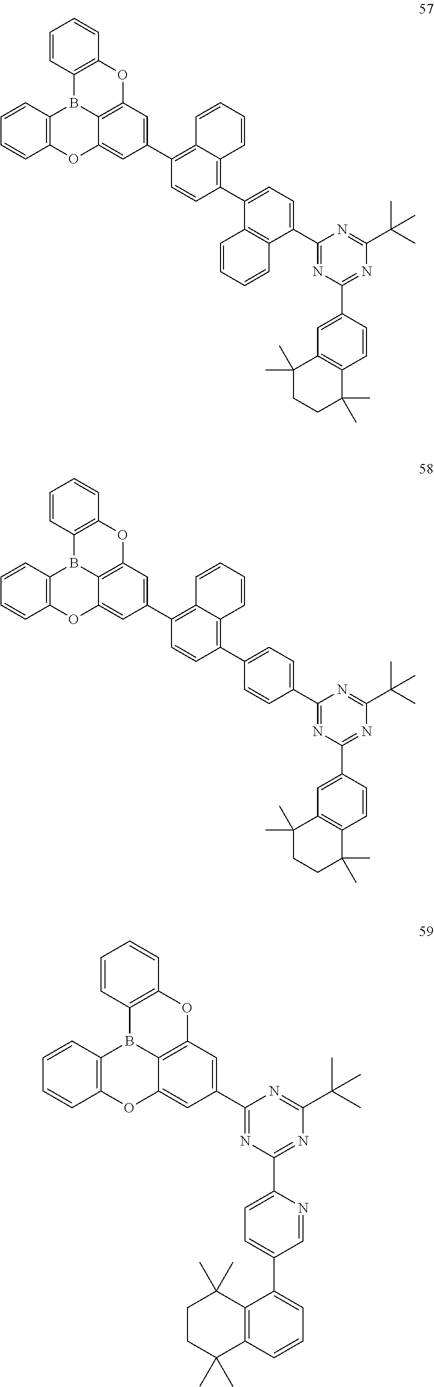 [SMILES: CC(C)(C)c1nc(-c2ccc3c(c2)C(C)(C)CCC3(C)C)nc(-c2ccc(-c3ccc(-c4cc5c6c(c4)Oc4ccccc4B6c4ccccc4O5)c4ccccc34)c3ccccc23)n1 ; CC(C)(C)c1nc(-c2ccc(-c3ccc(-c4cc5c6c(c4)Oc4ccccc4B6c4ccccc4O5)c4ccccc34)cc2)nc(-c2ccc3c(c2)C(C)(C)CCC3(C)C)n1 ; CC(C)(C)c1nc(-c2cc3c4c(c2)Oc2ccccc2B4c2ccccc2O3)nc(-c2ccc(-c3cccc4c3C(C)(C)CCC4(C)C)cn2)n1]

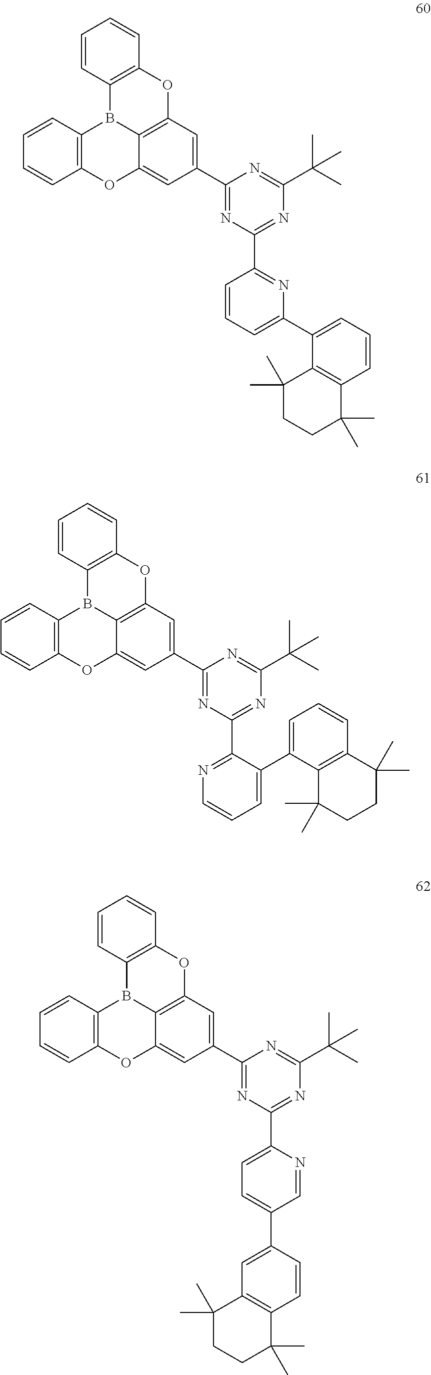 [SMILES: CC(C)(C)c1nc(-c2cc3c4c(c2)Oc2ccccc2B4c2ccccc2O3)nc(-c2cccc(-c3cccc4c3C(C)(C)CCC4(C)C)n2)n1 ; CC(C)(C)c1nc(-c2cc3c4c(c2)Oc2ccccc2B4c2ccccc2O3)nc(-c2ncccc2-c2cccc3c2C(C)(C)CCC3(C)C)n1 ; CC(C)(C)c1nc(-c2cc3c4c(c2)Oc2ccccc2B4c2ccccc2O3)nc(-c2ccc(-c3ccc4c(c3)C(C)(C)CCC4(C)C)cn2)n1]

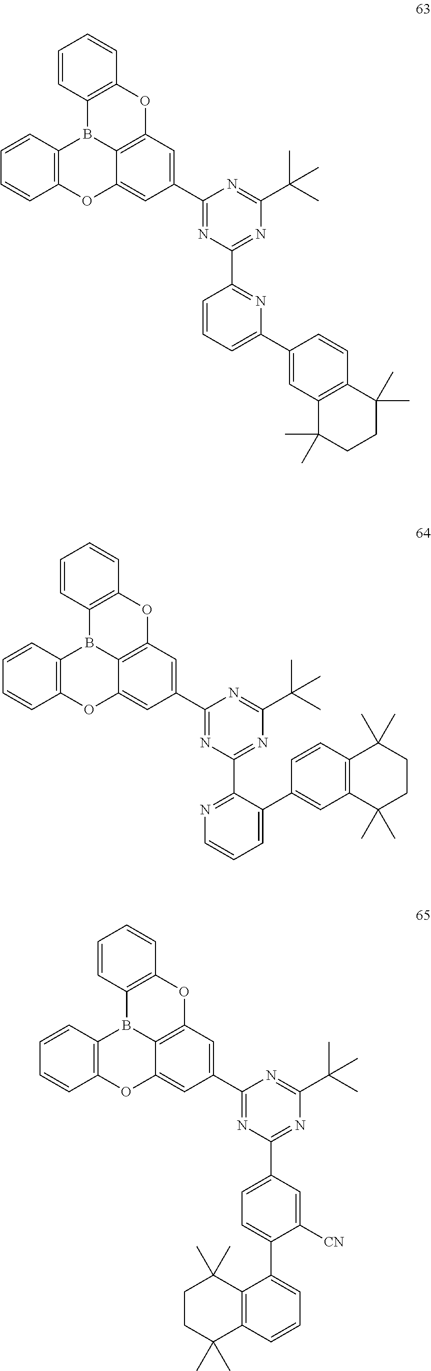 [SMILES: CC(C)(C)c1nc(-c2cc3c4c(c2)Oc2ccccc2B4c2ccccc2O3)nc(-c2cccc(-c3ccc4c(c3)C(C)(C)CCC4(C)C)n2)n1 ; CC(C)(C)c1nc(-c2cc3c4c(c2)Oc2ccccc2B4c2ccccc2O3)nc(-c2ncccc2-c2ccc3c(c2)C(C)(C)CCC3(C)C)n1 ; CC(C)(C)c1nc(-c2ccc(-c3cccc4c3C(C)(C)CCC4(C)C)c(C#N)c2)nc(-c2cc3c4c(c2)Oc2ccccc2B4c2ccccc2O3)n1]

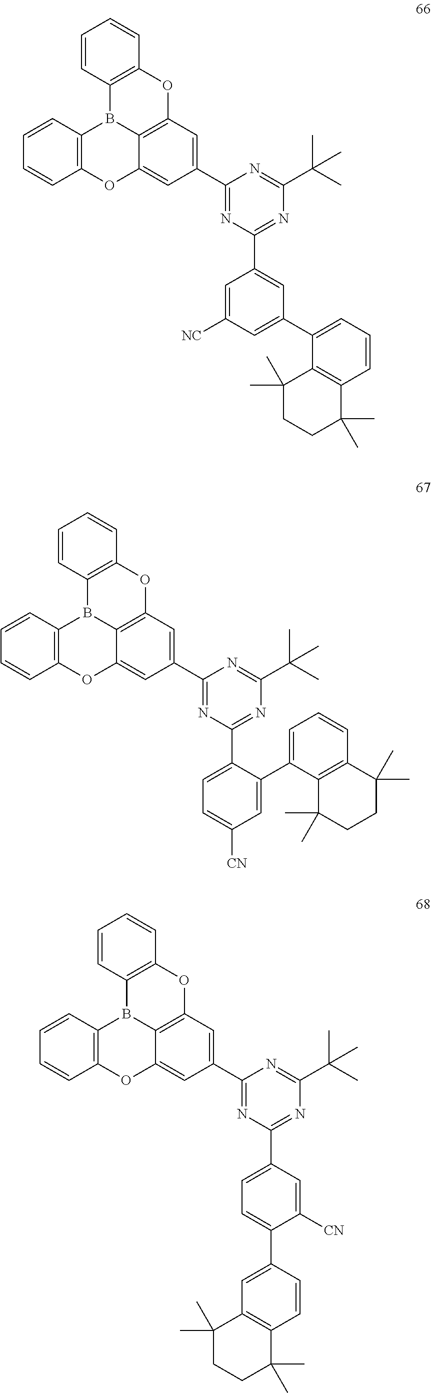 [SMILES: CC(C)(C)c1nc(-c2cc(C#N)cc(-c3cccc4c3C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(C#N)cc2-c2cccc3c2C(C)(C)CCC3(C)C)n1 ; CC(C)(C)c1nc(-c2ccc(-c3ccc4c(c3)C(C)(C)CCC4(C)C)c(C#N)c2)nc(-c2cc3c4c(c2)Oc2ccccc2B4c2ccccc2O3)n1]

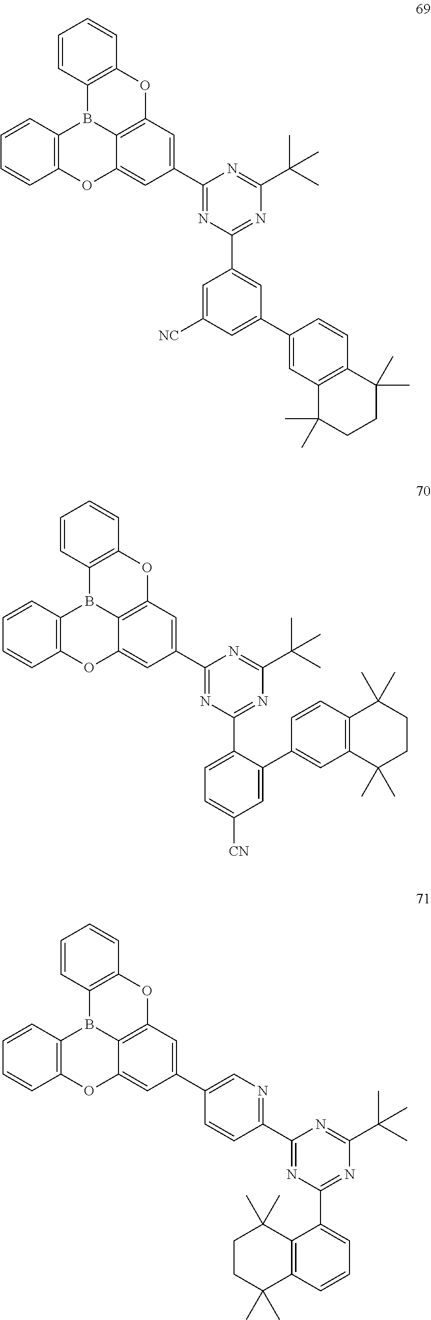 [SMILES: CC(C)(C)c1nc(-c2cc(C#N)cc(-c3ccc4c(c3)C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(C#N)cc2-c2ccc3c(c2)C(C)(C)CCC3(C)C)n1 ; CC(C)(C)c1nc(-c2ccc(-c3cc4c5c(c3)Oc3ccccc3B5c3ccccc3O4)cn2)nc(-c2cccc3c2C(C)(C)CCC3(C)C)n1]

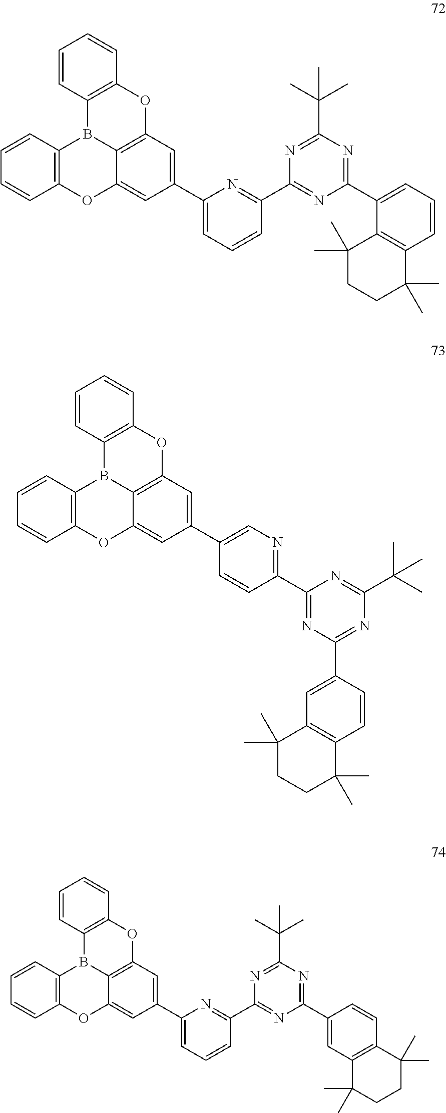 [SMILES: CC(C)(C)c1nc(-c2cccc(-c3cc4c5c(c3)Oc3ccccc3B5c3ccccc3O4)n2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Oc3ccccc3B5c3ccccc3O4)cn2)n1 ; CC(C)(C)c1nc(-c2ccc3c(c2)C(C)(C)CCC3(C)C)nc(-c2cccc(-c3cc4c5c(c3)Oc3ccccc3B5c3ccccc3O4)n2)n1]

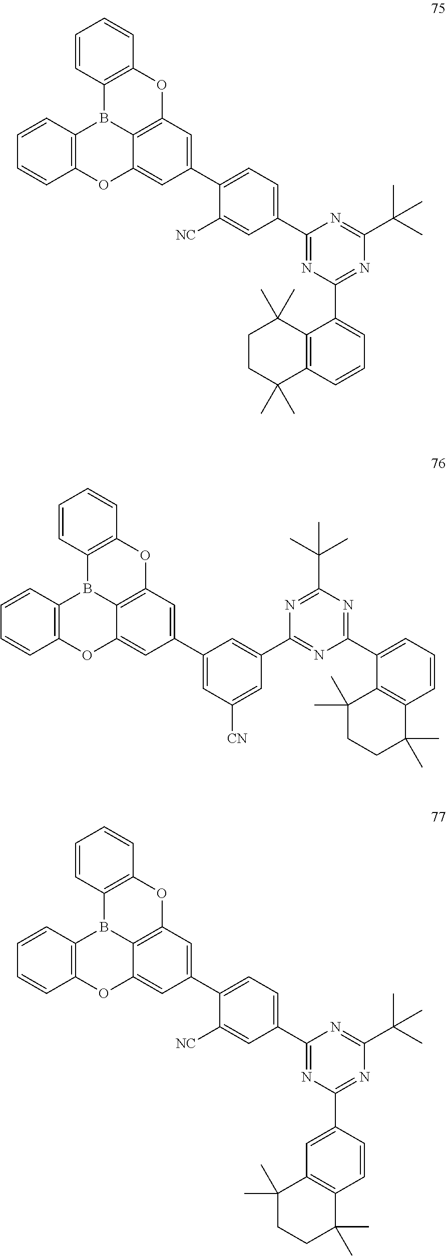 [SMILES: CC(C)(C)c1nc(-c2ccc(-c3cc4c5c(c3)Oc3ccccc3B5c3ccccc3O4)c(C#N)c2)nc(-c2cccc3c2C(C)(C)CCC3(C)C)n1 ; CC(C)(C)c1nc(-c2cc(C#N)cc(-c3cc4c5c(c3)Oc3ccccc3B5c3ccccc3O4)c2)nc(-c2cccc3c2C(C)(C)CCC3(C)C)n1 ; CC(C)(C)c1nc(-c2ccc(-c3cc4c5c(c3)Oc3ccccc3B5c3ccccc3O4)c(C#N)c2)nc(-c2ccc3c(c2)C(C)(C)CCC3(C)C)n1]

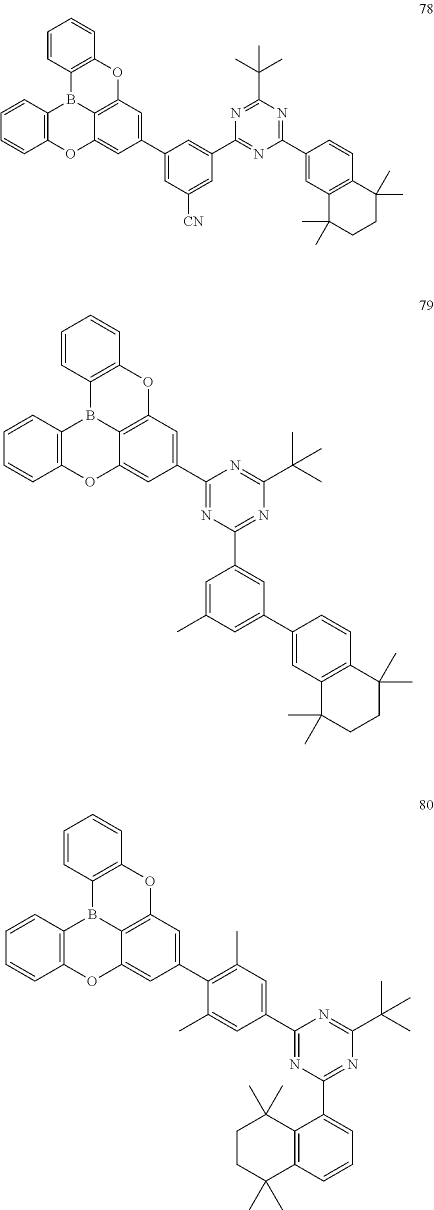 [SMILES: CC(C)(C)c1nc(-c2cc(C#N)cc(-c3cc4c5c(c3)Oc3ccccc3B5c3ccccc3O4)c2)nc(-c2ccc3c(c2)C(C)(C)CCC3(C)C)n1 ; Cc1cc(-c2ccc3c(c2)C(C)(C)CCC3(C)C)cc(-c2nc(-c3cc4c5c(c3)Oc3ccccc3B5c3ccccc3O4)nc(C(C)(C)C)n2)c1 ; Cc1cc(-c2nc(-c3cccc4c3C(C)(C)CCC4(C)C)nc(C(C)(C)C)n2)cc(C)c1-c1cc2c3c(c1)Oc1ccccc1B3c1ccccc1O2]

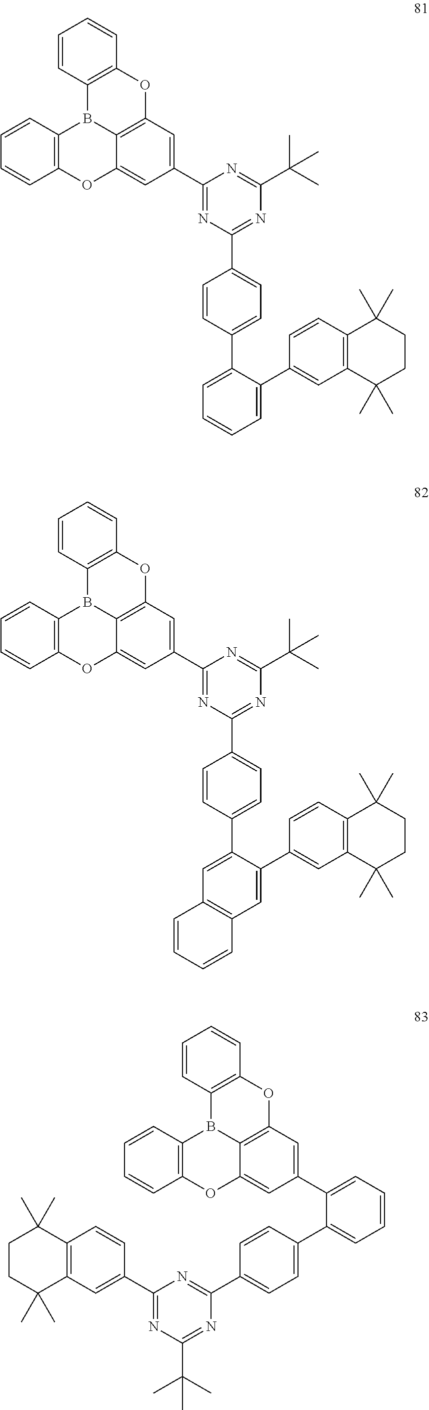 [SMILES: CC(C)(C)c1nc(-c2ccc(-c3ccccc3-c3ccc4c(c3)C(C)(C)CCC4(C)C)cc2)nc(-c2cc3c4c(c2)Oc2ccccc2B4c2ccccc2O3)n1 ; CC(C)(C)c1nc(-c2ccc(-c3cc4ccccc4cc3-c3ccc4c(c3)C(C)(C)CCC4(C)C)cc2)nc(-c2cc3c4c(c2)Oc2ccccc2B4c2ccccc2O3)n1 ; CC(C)(C)c1nc(-c2ccc(-c3ccccc3-c3cc4c5c(c3)Oc3ccccc3B5c3ccccc3O4)cc2)nc(-c2ccc3c(c2)C(C)(C)CCC3(C)C)n1]

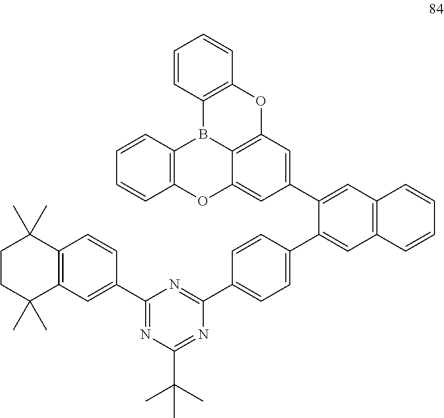 [SMILES: CC(C)(C)c1nc(-c2ccc(-c3cc4ccccc4cc3-c3cc4c5c(c3)Oc3ccccc3B5c3ccccc3O4)cc2)nc(-c2ccc3c(c2)C(C)(C)CCC3(C)C)n1]

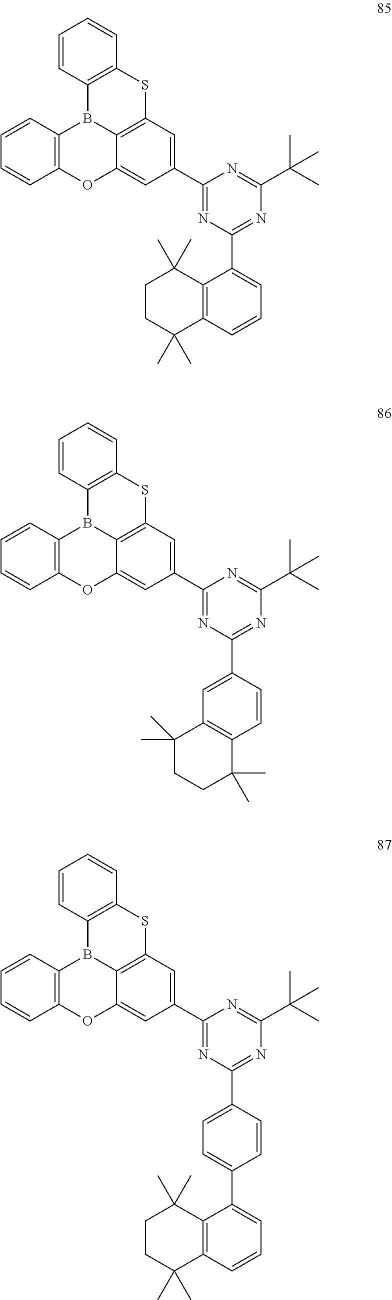 [SMILES: CC(C)(C)c1nc(-c2cc3c4c(c2)Sc2ccccc2B4c2ccccc2O3)nc(-c2cccc3c2C(C)(C)CCC3(C)C)n1 ; CC(C)(C)c1nc(-c2cc3c4c(c2)Sc2ccccc2B4c2ccccc2O3)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)Sc2ccccc2B4c2ccccc2O3)n1]

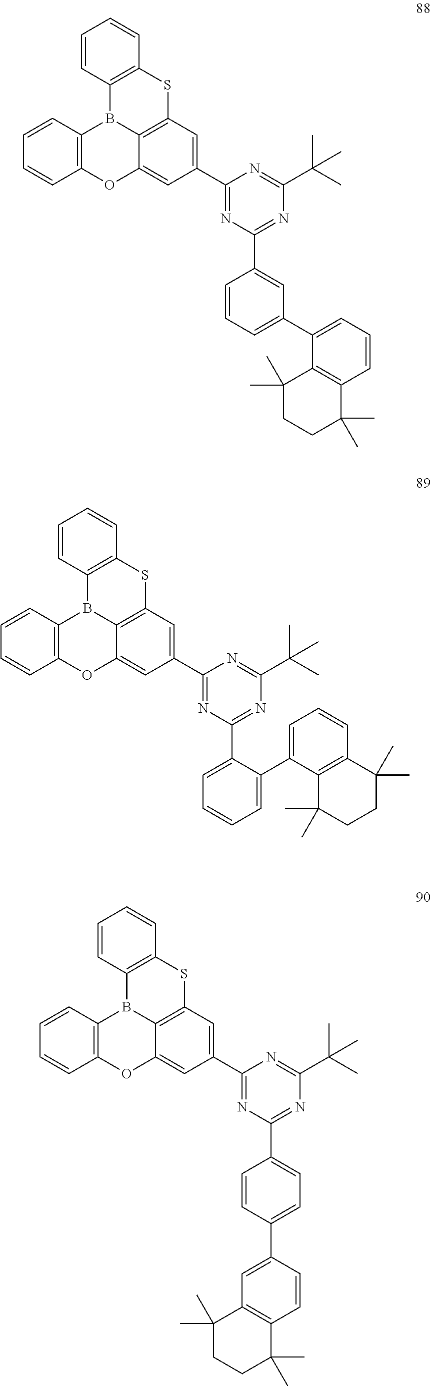 [SMILES: CC(C)(C)c1nc(-c2cccc(-c3cccc4c3C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2cccc3c2C(C)(C)CCC3(C)C)n1 ; CC(C)(C)c1nc(-c2ccc(-c3ccc4c(c3)C(C)(C)CCC4(C)C)cc2)nc(-c2cc3c4c(c2)Sc2ccccc2B4c2ccccc2O3)n1]

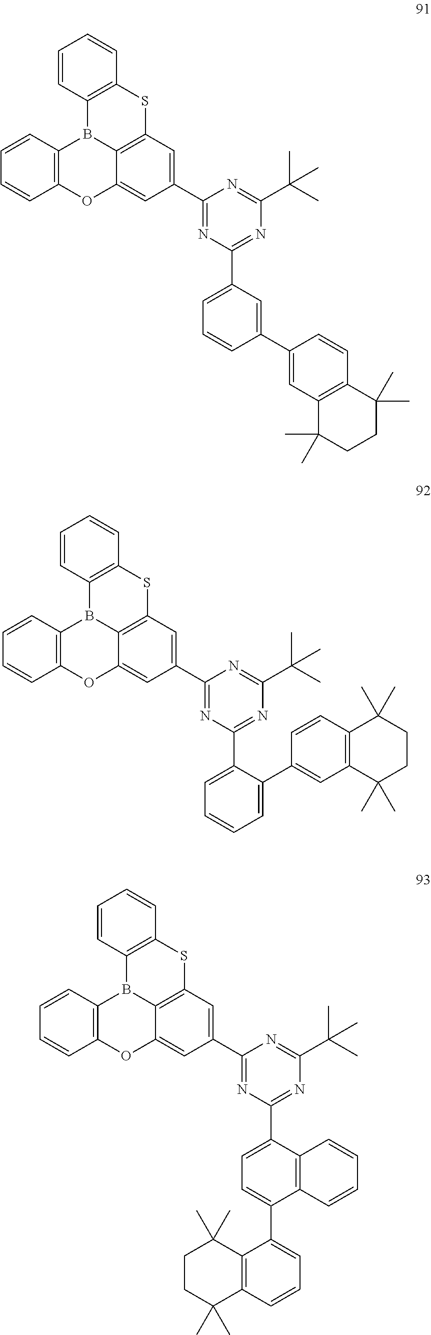 [SMILES: CC(C)(C)c1nc(-c2cccc(-c3ccc4c(c3)C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc3c(c2)C(C)(C)CCC3(C)C)n1 ; CC(C)(C)c1nc(-c2cc3c4c(c2)Sc2ccccc2B4c2ccccc2O3)nc(-c2ccc(-c3cccc4c3C(C)(C)CCC4(C)C)c3ccccc23)n1]

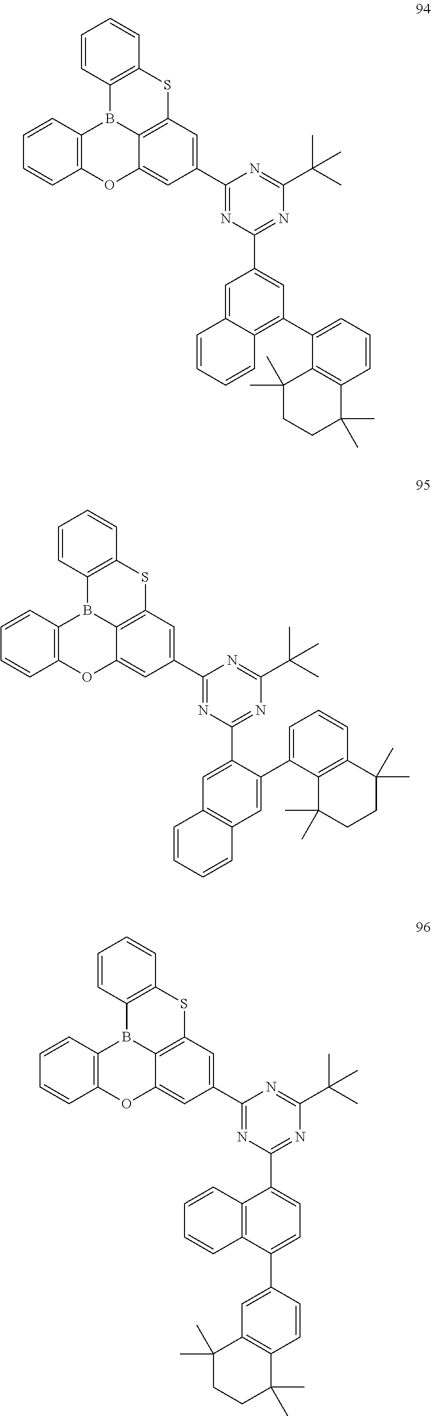 [SMILES: CC(C)(C)c1nc(-c2cc3c4c(c2)Sc2ccccc2B4c2ccccc2O3)nc(-c2cc(-c3cccc4c3C(C)(C)CCC4(C)C)c3ccccc3c2)n1 ; CC(C)(C)c1nc(-c2cc3c4c(c2)Sc2ccccc2B4c2ccccc2O3)nc(-c2cc3ccccc3cc2-c2cccc3c2C(C)(C)CCC3(C)C)n1 ; CC(C)(C)c1nc(-c2cc3c4c(c2)Sc2ccccc2B4c2ccccc2O3)nc(-c2ccc(-c3ccc4c(c3)C(C)(C)CCC4(C)C)c3ccccc23)n1]

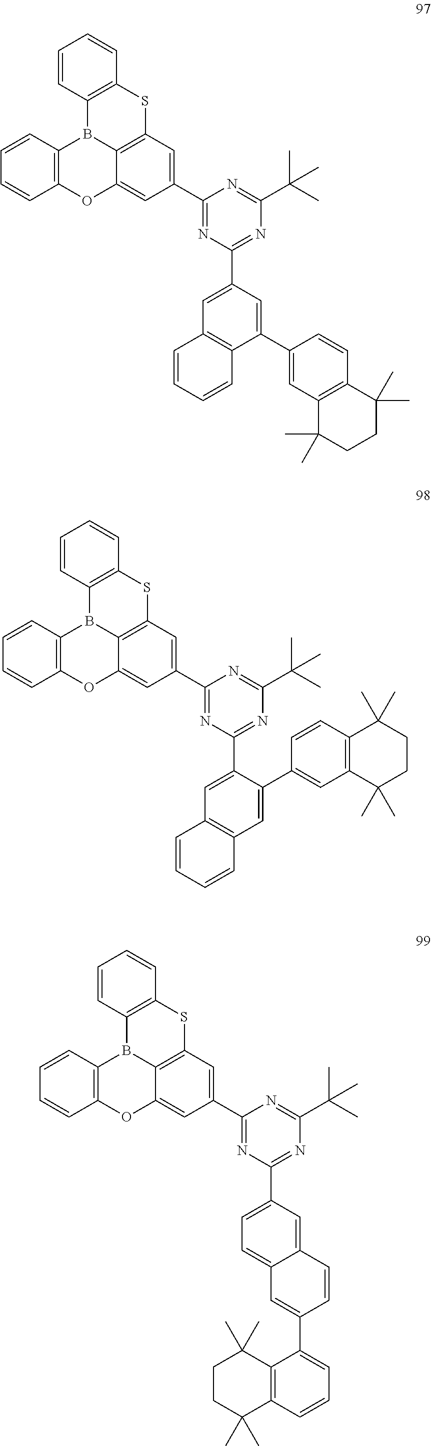 [SMILES: CC(C)(C)c1nc(-c2cc3c4c(c2)Sc2ccccc2B4c2ccccc2O3)nc(-c2cc(-c3ccc4c(c3)C(C)(C)CCC4(C)C)c3ccccc3c2)n1 ; CC(C)(C)c1nc(-c2cc3c4c(c2)Sc2ccccc2B4c2ccccc2O3)nc(-c2cc3ccccc3cc2-c2ccc3c(c2)C(C)(C)CCC3(C)C)n1 ; CC(C)(C)c1nc(-c2cc3c4c(c2)Sc2ccccc2B4c2ccccc2O3)nc(-c2ccc3cc(-c4cccc5c4C(C)(C)CCC5(C)C)ccc3c2)n1]

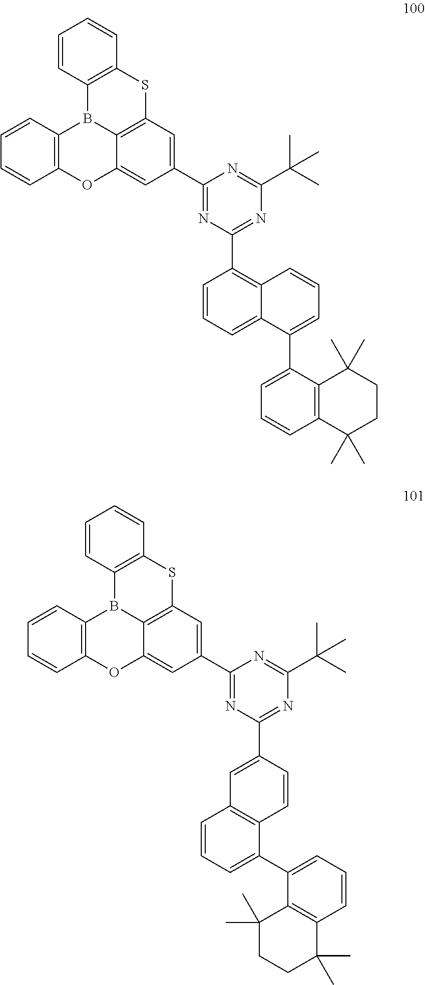 [SMILES: CC(C)(C)c1nc(-c2cc3c4c(c2)Sc2ccccc2B4c2ccccc2O3)nc(-c2cccc3c(-c4cccc5c4C(C)(C)CCC5(C)C)cccc23)n1 ; CC(C)(C)c1nc(-c2cc3c4c(c2)Sc2ccccc2B4c2ccccc2O3)nc(-c2ccc3c(-c4cccc5c4C(C)(C)CCC5(C)C)cccc3c2)n1]

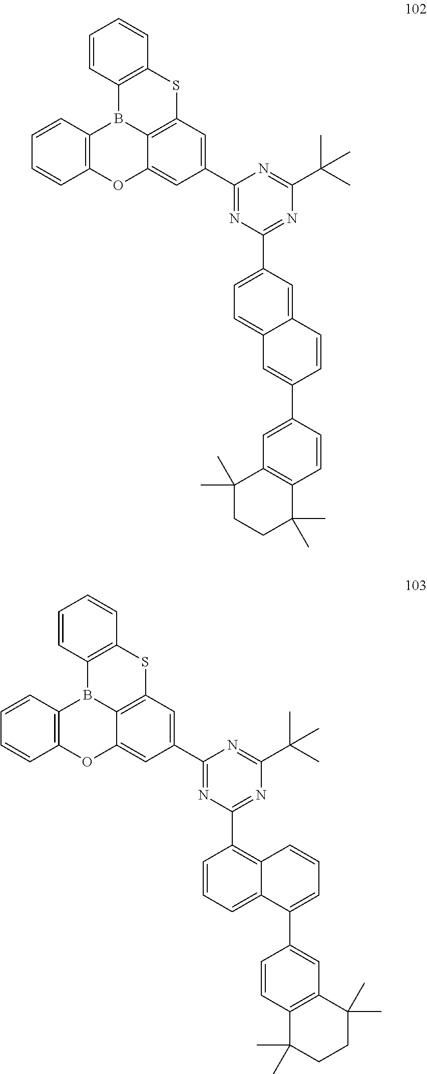 [SMILES: CC(C)(C)c1nc(-c2cc3c4c(c2)Sc2ccccc2B4c2ccccc2O3)nc(-c2ccc3cc(-c4ccc5c(c4)C(C)(C)CCC5(C)C)ccc3c2)n1 ; CC(C)(C)c1nc(-c2cc3c4c(c2)Sc2ccccc2B4c2ccccc2O3)nc(-c2cccc3c(-c4ccc5c(c4)C(C)(C)CCC5(C)C)cccc23)n1]

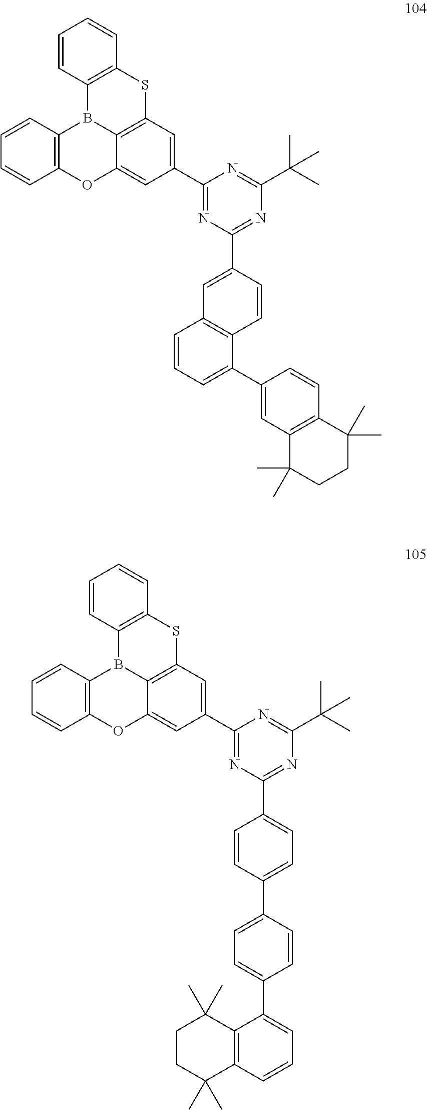 [SMILES: CC(C)(C)c1nc(-c2cc3c4c(c2)Sc2ccccc2B4c2ccccc2O3)nc(-c2ccc3c(-c4ccc5c(c4)C(C)(C)CCC5(C)C)cccc3c2)n1 ; CC(C)(C)c1nc(-c2ccc(-c3ccc(-c4cccc5c4C(C)(C)CCC5(C)C)cc3)cc2)nc(-c2cc3c4c(c2)Sc2ccccc2B4c2ccccc2O3)n1]

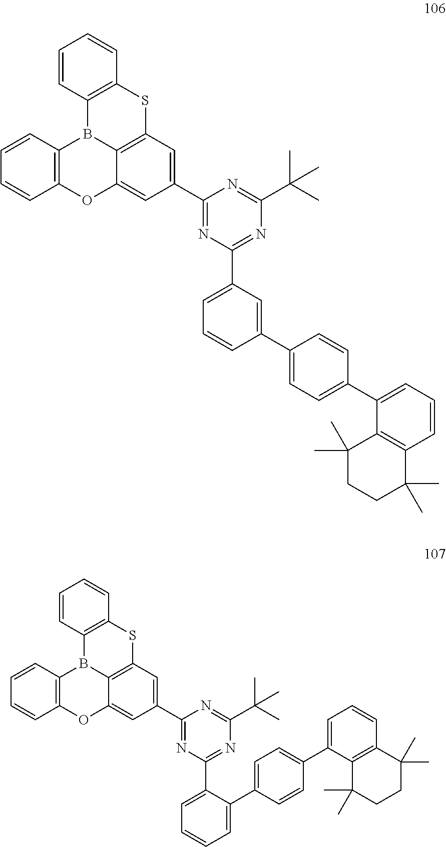 [SMILES: CC(C)(C)c1nc(-c2cccc(-c3ccc(-c4cccc5c4C(C)(C)CCC5(C)C)cc3)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc(-c3cccc4c3C(C)(C)CCC4(C)C)cc2)n1]

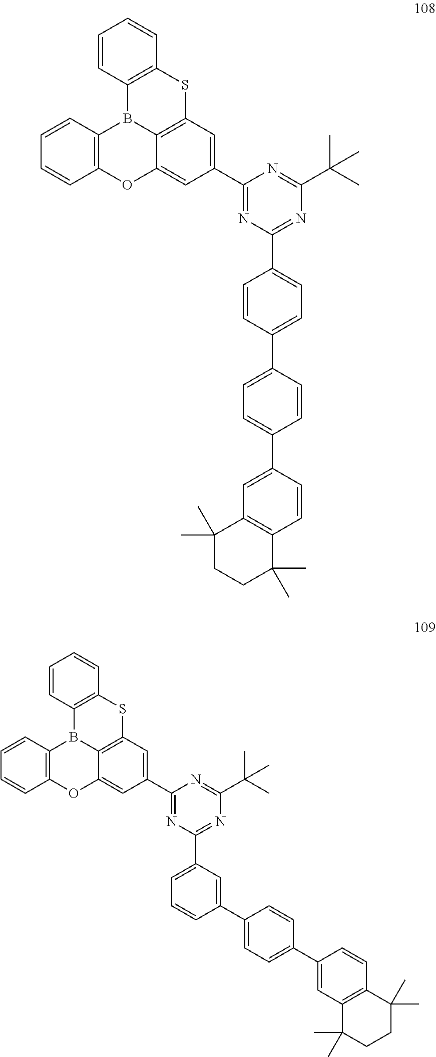 [SMILES: CC(C)(C)c1nc(-c2ccc(-c3ccc(-c4ccc5c(c4)C(C)(C)CCC5(C)C)cc3)cc2)nc(-c2cc3c4c(c2)Sc2ccccc2B4c2ccccc2O3)n1 ; CC(C)(C)c1nc(-c2cccc(-c3ccc(-c4ccc5c(c4)C(C)(C)CCC5(C)C)cc3)c2)nc(-c2cc3c4c(c2)Sc2ccccc2B4c2ccccc2O3)n1]

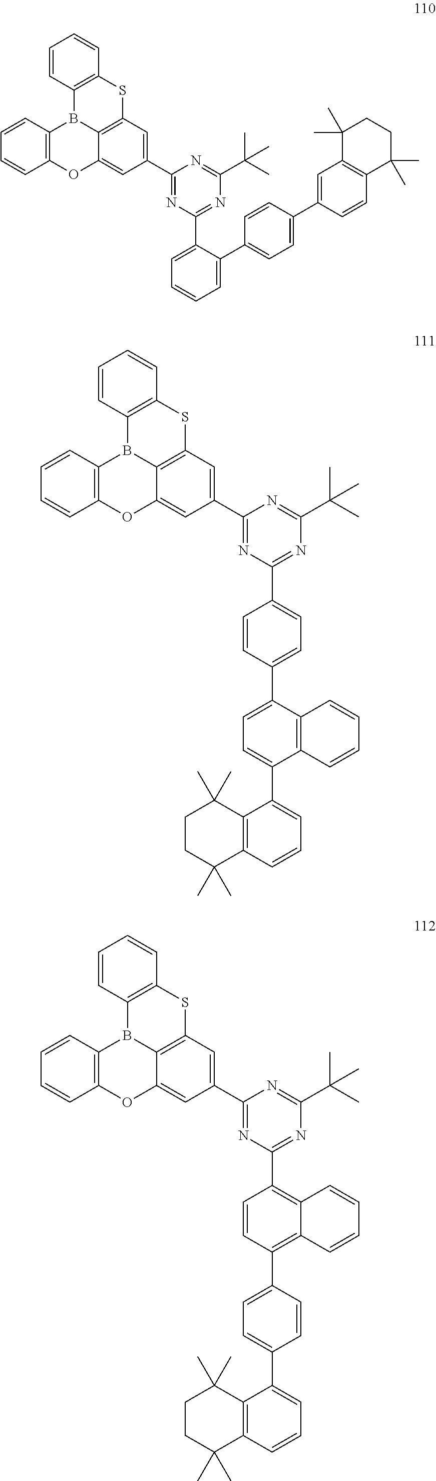 [SMILES: CC(C)(C)c1nc(-c2cc3c4c(c2)Sc2ccccc2B4c2ccccc2O3)nc(-c2ccccc2-c2ccc(-c3ccc4c(c3)C(C)(C)CCC4(C)C)cc2)n1 ; CC(C)(C)c1nc(-c2ccc(-c3ccc(-c4cccc5c4C(C)(C)CCC5(C)C)c4ccccc34)cc2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(-c3ccc(-c4cccc5c4C(C)(C)CCC5(C)C)cc3)c3ccccc23)n1]

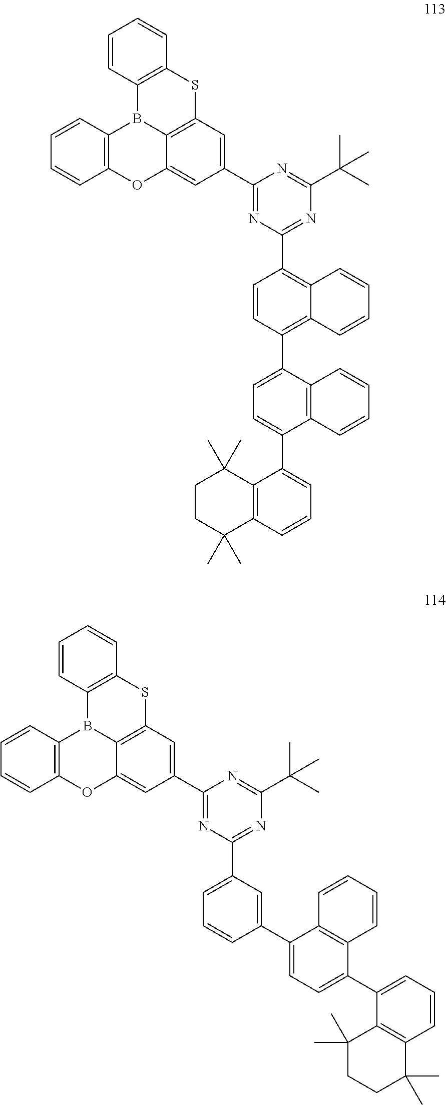 [SMILES: CC(C)(C)c1nc(-c2cc3c4c(c2)Sc2ccccc2B4c2ccccc2O3)nc(-c2ccc(-c3ccc(-c4cccc5c4C(C)(C)CCC5(C)C)c4ccccc34)c3ccccc23)n1 ; CC(C)(C)c1nc(-c2cccc(-c3ccc(-c4cccc5c4C(C)(C)CCC5(C)C)c4ccccc34)c2)nc(-c2cc3c4c(c2)Sc2ccccc2B4c2ccccc2O3)n1]

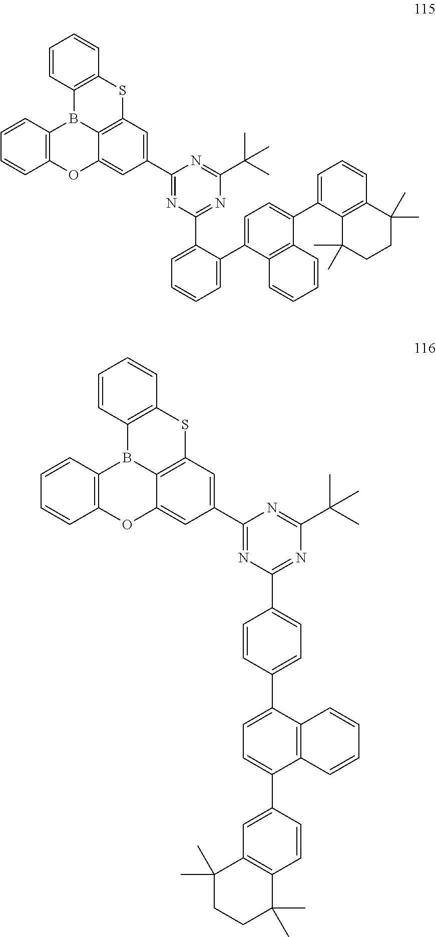 [SMILES: CC(C)(C)c1nc(-c2cc3c4c(c2)Sc2ccccc2B4c2ccccc2O3)nc(-c2ccccc2-c2ccc(-c3cccc4c3C(C)(C)CCC4(C)C)c3ccccc23)n1 ; CC(C)(C)c1nc(-c2ccc(-c3ccc(-c4ccc5c(c4)C(C)(C)CCC5(C)C)c4ccccc34)cc2)nc(-c2cc3c4c(c2)Sc2ccccc2B4c2ccccc2O3)n1]

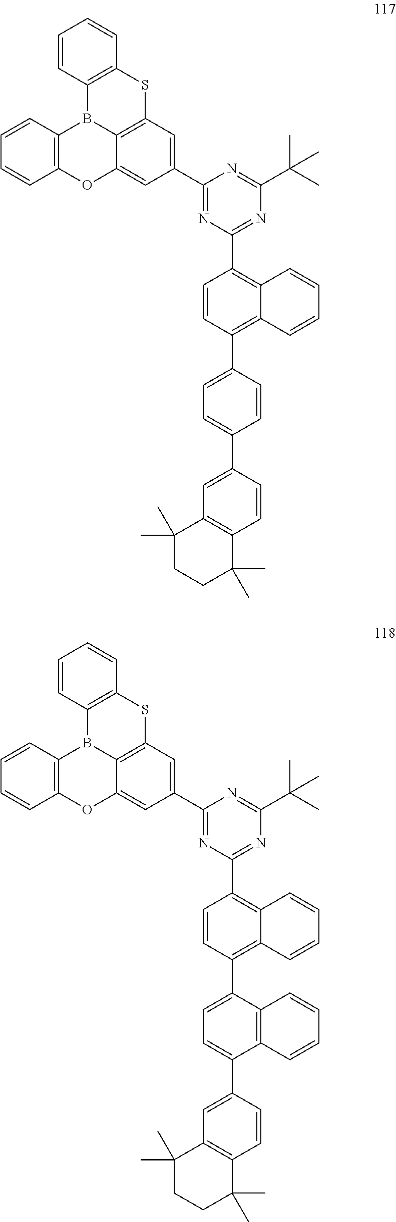 [SMILES: CC(C)(C)c1nc(-c2cc3c4c(c2)Sc2ccccc2B4c2ccccc2O3)nc(-c2ccc(-c3ccc(-c4ccc5c(c4)C(C)(C)CCC5(C)C)cc3)c3ccccc23)n1 ; CC(C)(C)c1nc(-c2cc3c4c(c2)Sc2ccccc2B4c2ccccc2O3)nc(-c2ccc(-c3ccc(-c4ccc5c(c4)C(C)(C)CCC5(C)C)c4ccccc34)c3ccccc23)n1]

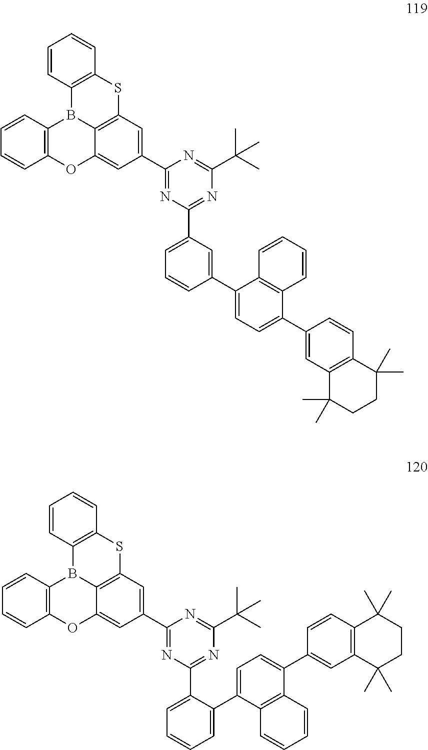 [SMILES: CC(C)(C)c1nc(-c2cccc(-c3ccc(-c4ccc5c(c4)C(C)(C)CCC5(C)C)c4ccccc34)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc(-c3ccc4c(c3)C(C)(C)CCC4(C)C)c3ccccc23)n1]

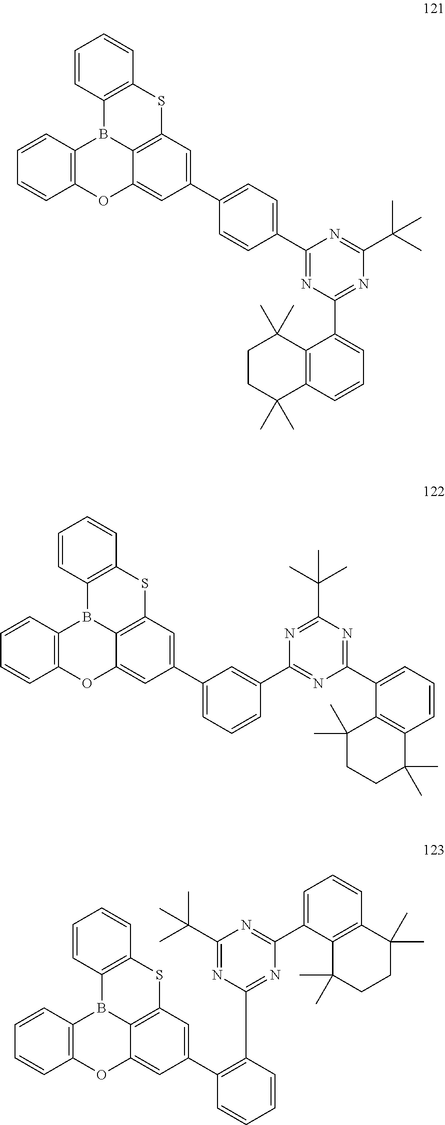 [SMILES: CC(C)(C)c1nc(-c2ccc(-c3cc4c5c(c3)Sc3ccccc3B5c3ccccc3O4)cc2)nc(-c2cccc3c2C(C)(C)CCC3(C)C)n1 ; CC(C)(C)c1nc(-c2cccc(-c3cc4c5c(c3)Sc3ccccc3B5c3ccccc3O4)c2)nc(-c2cccc3c2C(C)(C)CCC3(C)C)n1 ; CC(C)(C)c1nc(-c2ccccc2-c2cc3c4c(c2)Sc2ccccc2B4c2ccccc2O3)nc(-c2cccc3c2C(C)(C)CCC3(C)C)n1]

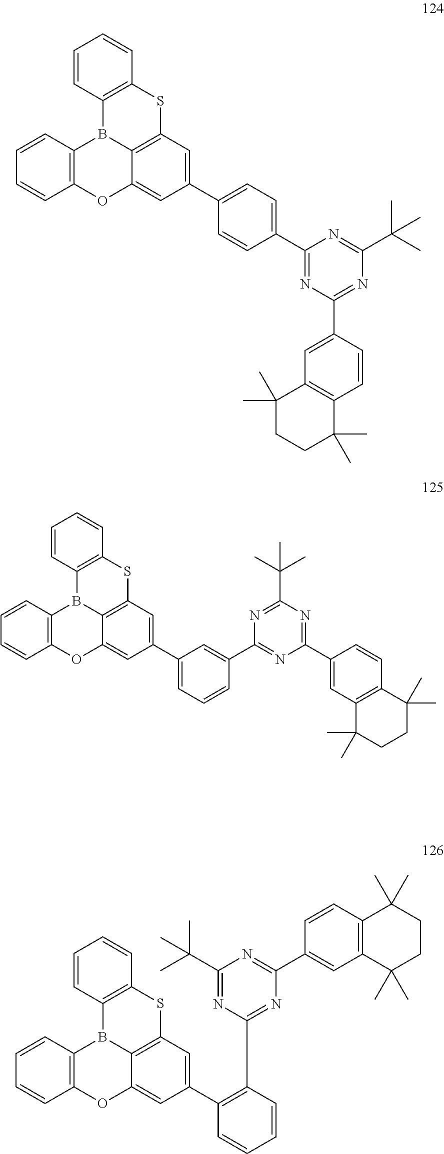 [SMILES: CC(C)(C)c1nc(-c2ccc(-c3cc4c5c(c3)Sc3ccccc3B5c3ccccc3O4)cc2)nc(-c2ccc3c(c2)C(C)(C)CCC3(C)C)n1 ; CC(C)(C)c1nc(-c2cccc(-c3cc4c5c(c3)Sc3ccccc3B5c3ccccc3O4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Sc2ccccc2B4c2ccccc2O3)n1]

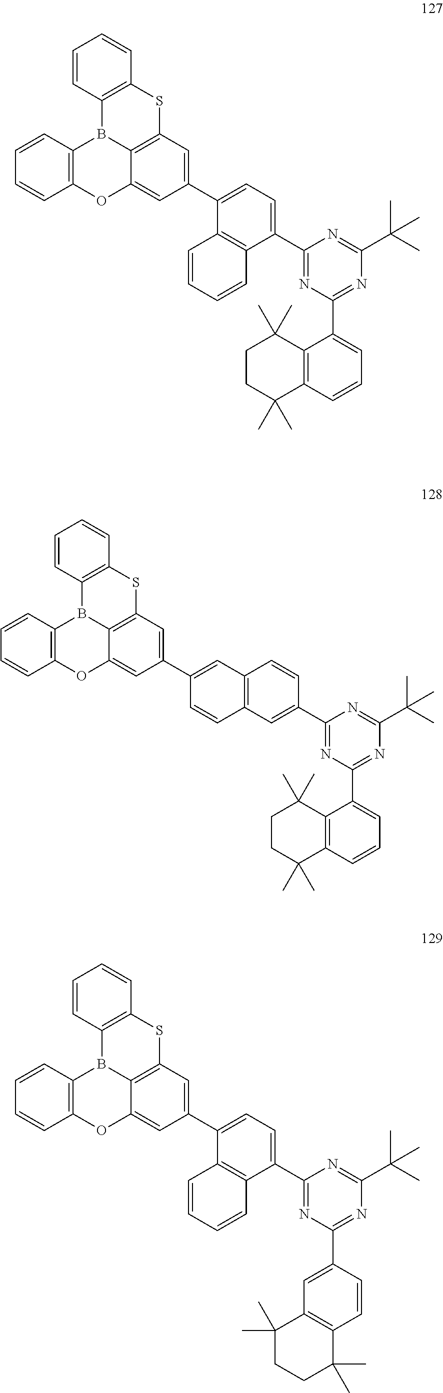 [SMILES: CC(C)(C)c1nc(-c2cccc3c2C(C)(C)CCC3(C)C)nc(-c2ccc(-c3cc4c5c(c3)Sc3ccccc3B5c3ccccc3O4)c3ccccc23)n1 ; CC(C)(C)c1nc(-c2ccc3cc(-c4cc5c6c(c4)Sc4ccccc4B6c4ccccc4O5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Sc3ccccc3B5c3ccccc3O4)c3ccccc23)n1]

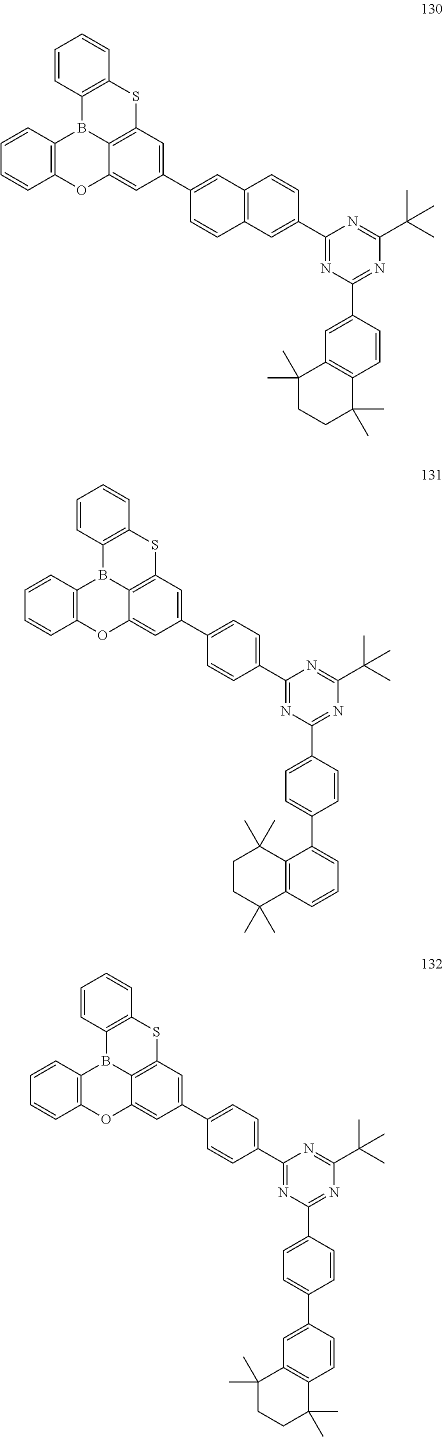 [SMILES: CC(C)(C)c1nc(-c2ccc3c(c2)C(C)(C)CCC3(C)C)nc(-c2ccc3cc(-c4cc5c6c(c4)Sc4ccccc4B6c4ccccc4O5)ccc3c2)n1 ; CC(C)(C)c1nc(-c2ccc(-c3cc4c5c(c3)Sc3ccccc3B5c3ccccc3O4)cc2)nc(-c2ccc(-c3cccc4c3C(C)(C)CCC4(C)C)cc2)n1 ; CC(C)(C)c1nc(-c2ccc(-c3cc4c5c(c3)Sc3ccccc3B5c3ccccc3O4)cc2)nc(-c2ccc(-c3ccc4c(c3)C(C)(C)CCC4(C)C)cc2)n1]

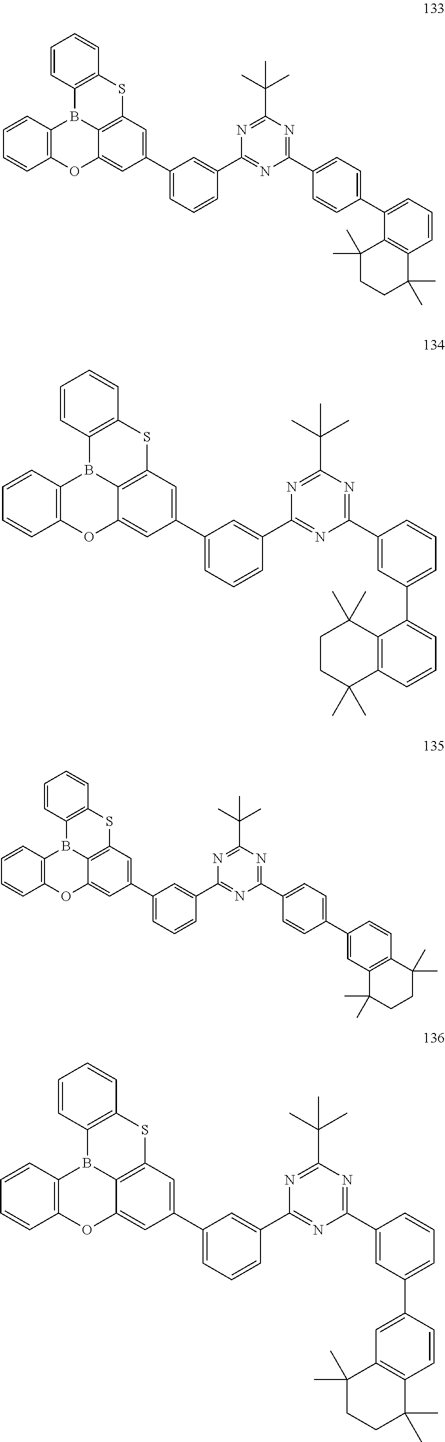 [SMILES: CC(C)(C)c1nc(-c2ccc(-c3cccc4c3C(C)(C)CCC4(C)C)cc2)nc(-c2cccc(-c3cc4c5c(c3)Sc3ccccc3B5c3ccccc3O4)c2)n1 ; CC(C)(C)c1nc(-c2cccc(-c3cc4c5c(c3)Sc3ccccc3B5c3ccccc3O4)c2)nc(-c2cccc(-c3cccc4c3C(C)(C)CCC4(C)C)c2)n1 ; CC(C)(C)c1nc(-c2ccc(-c3ccc4c(c3)C(C)(C)CCC4(C)C)cc2)nc(-c2cccc(-c3cc4c5c(c3)Sc3ccccc3B5c3ccccc3O4)c2)n1 ; CC(C)(C)c1nc(-c2cccc(-c3cc4c5c(c3)Sc3ccccc3B5c3ccccc3O4)c2)nc(-c2cccc(-c3ccc4c(c3)C(C)(C)CCC4(C)C)c2)n1]

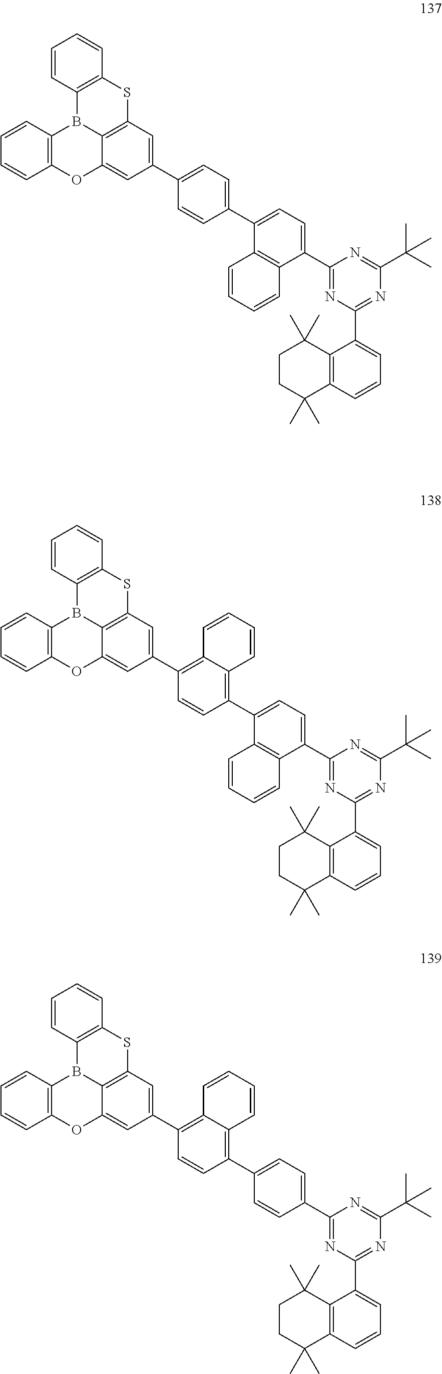 [SMILES: CC(C)(C)c1nc(-c2cccc3c2C(C)(C)CCC3(C)C)nc(-c2ccc(-c3ccc(-c4cc5c6c(c4)Sc4ccccc4B6c4ccccc4O5)cc3)c3ccccc23)n1 ; CC(C)(C)c1nc(-c2cccc3c2C(C)(C)CCC3(C)C)nc(-c2ccc(-c3ccc(-c4cc5c6c(c4)Sc4ccccc4B6c4ccccc4O5)c4ccccc34)c3ccccc23)n1 ; CC(C)(C)c1nc(-c2ccc(-c3ccc(-c4cc5c6c(c4)Sc4ccccc4B6c4ccccc4O5)c4ccccc34)cc2)nc(-c2cccc3c2C(C)(C)CCC3(C)C)n1]

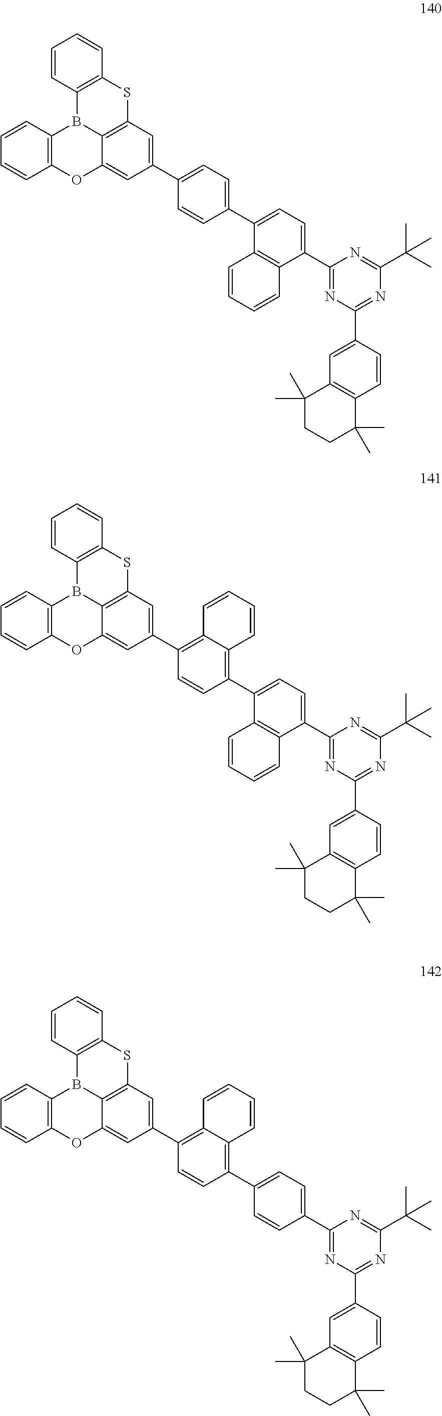 [SMILES: CC(C)(C)c1nc(-c2ccc3c(c2)C(C)(C)CCC3(C)C)nc(-c2ccc(-c3ccc(-c4cc5c6c(c4)Sc4ccccc4B6c4ccccc4O5)cc3)c3ccccc23)n1 ; CC(C)(C)c1nc(-c2ccc3c(c2)C(C)(C)CCC3(C)C)nc(-c2ccc(-c3ccc(-c4cc5c6c(c4)Sc4ccccc4B6c4ccccc4O5)c4ccccc34)c3ccccc23)n1 ; CC(C)(C)c1nc(-c2ccc(-c3ccc(-c4cc5c6c(c4)Sc4ccccc4B6c4ccccc4O5)c4ccccc34)cc2)nc(-c2ccc3c(c2)C(C)(C)CCC3(C)C)n1]

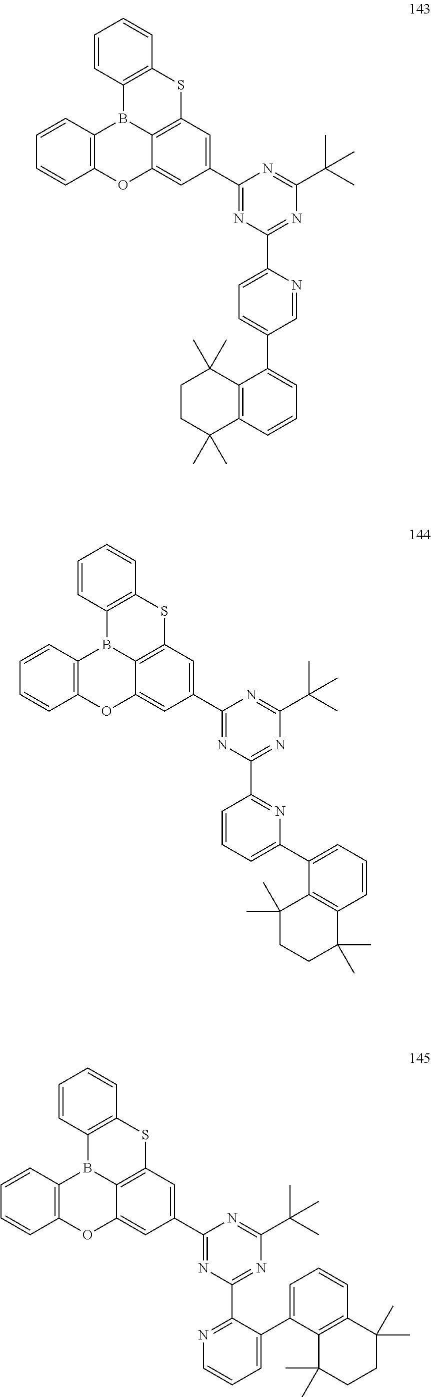 [SMILES: CC(C)(C)c1nc(-c2cc3c4c(c2)Sc2ccccc2B4c2ccccc2O3)nc(-c2ccc(-c3cccc4c3C(C)(C)CCC4(C)C)cn2)n1 ; CC(C)(C)c1nc(-c2cc3c4c(c2)Sc2ccccc2B4c2ccccc2O3)nc(-c2cccc(-c3cccc4c3C(C)(C)CCC4(C)C)n2)n1 ; CC(C)(C)c1nc(-c2cc3c4c(c2)Sc2ccccc2B4c2ccccc2O3)nc(-c2ncccc2-c2cccc3c2C(C)(C)CCC3(C)C)n1]

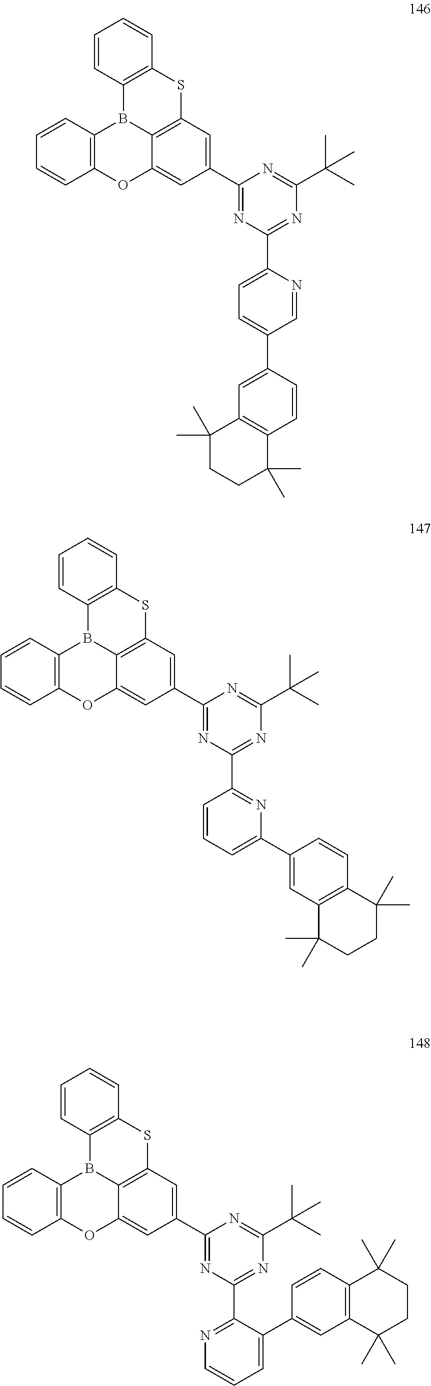 [SMILES: CC(C)(C)c1nc(-c2cc3c4c(c2)Sc2ccccc2B4c2ccccc2O3)nc(-c2ccc(-c3ccc4c(c3)C(C)(C)CCC4(C)C)cn2)n1 ; CC(C)(C)c1nc(-c2cc3c4c(c2)Sc2ccccc2B4c2ccccc2O3)nc(-c2cccc(-c3ccc4c(c3)C(C)(C)CCC4(C)C)n2)n1 ; CC(C)(C)c1nc(-c2cc3c4c(c2)Sc2ccccc2B4c2ccccc2O3)nc(-c2ncccc2-c2ccc3c(c2)C(C)(C)CCC3(C)C)n1]

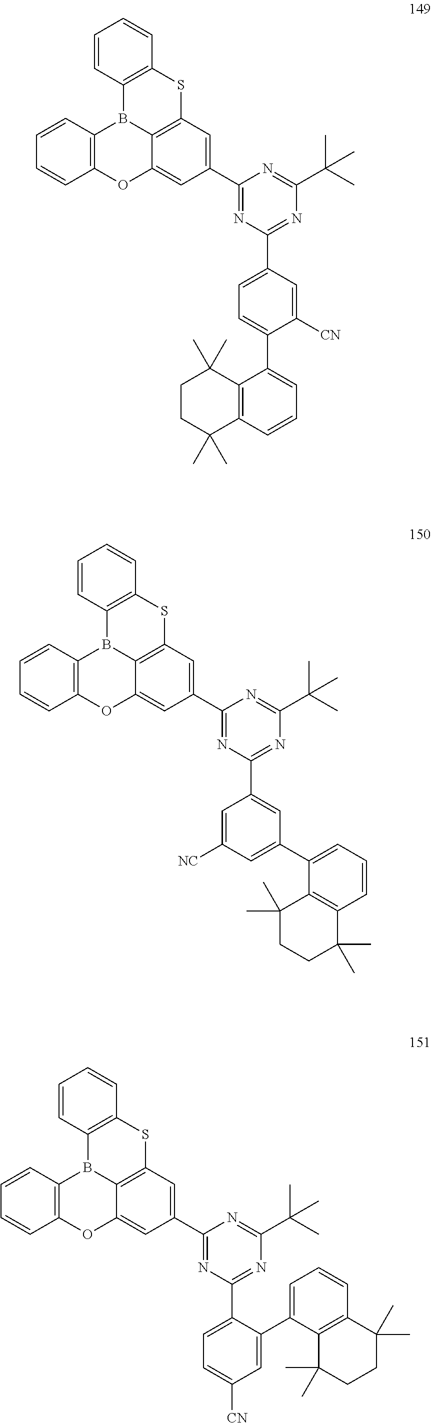 [SMILES: CC(C)(C)c1nc(-c2ccc(-c3cccc4c3C(C)(C)CCC4(C)C)c(C#N)c2)nc(-c2cc3c4c(c2)Sc2ccccc2B4c2ccccc2O3)n1 ; CC(C)(C)c1nc(-c2cc(C#N)cc(-c3cccc4c3C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(C#N)cc2-c2cccc3c2C(C)(C)CCC3(C)C)n1]

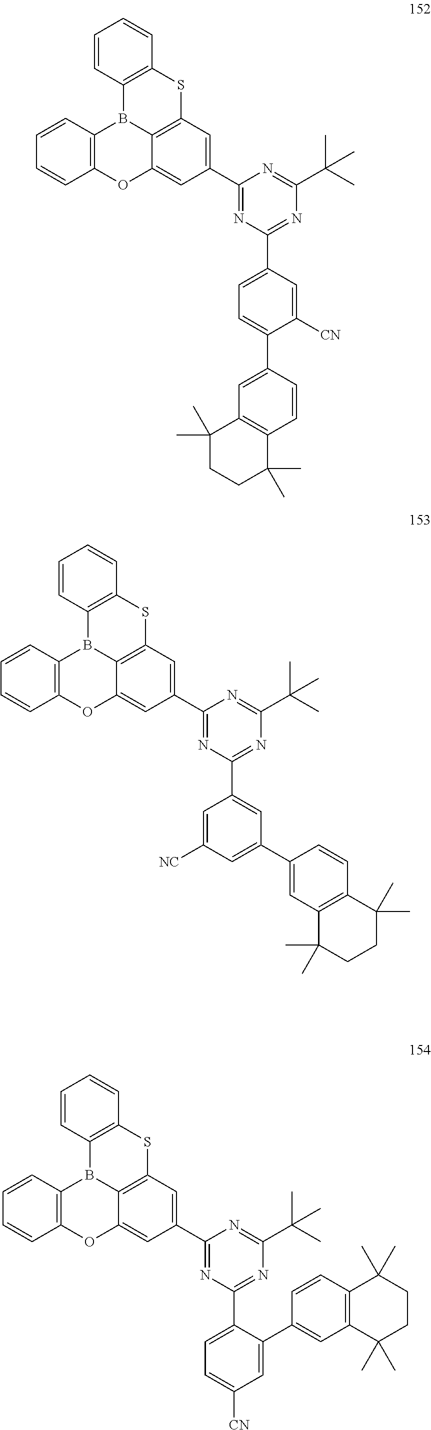 [SMILES: CC(C)(C)c1nc(-c2ccc(-c3ccc4c(c3)C(C)(C)CCC4(C)C)c(C#N)c2)nc(-c2cc3c4c(c2)Sc2ccccc2B4c2ccccc2O3)n1 ; CC(C)(C)c1nc(-c2cc(C#N)cc(-c3ccc4c(c3)C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(C#N)cc2-c2ccc3c(c2)C(C)(C)CCC3(C)C)n1]

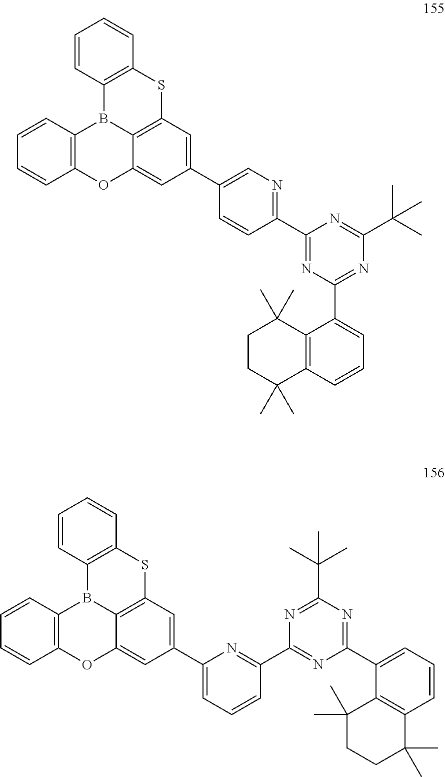 [SMILES: CC(C)(C)c1nc(-c2ccc(-c3cc4c5c(c3)Sc3ccccc3B5c3ccccc3O4)cn2)nc(-c2cccc3c2C(C)(C)CCC3(C)C)n1 ; CC(C)(C)c1nc(-c2cccc(-c3cc4c5c(c3)Sc3ccccc3B5c3ccccc3O4)n2)nc(-c2cccc3c2C(C)(C)CCC3(C)C)n1]

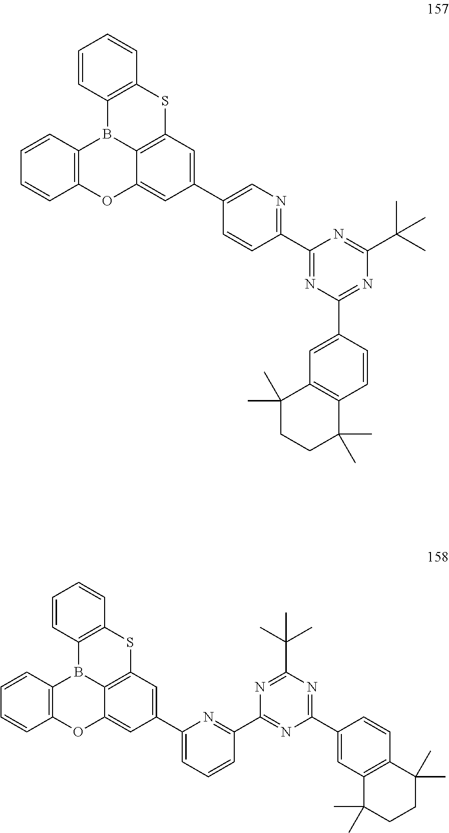 [SMILES: CC(C)(C)c1nc(-c2ccc3c(c2)C(C)(C)CCC3(C)C)nc(-c2ccc(-c3cc4c5c(c3)Sc3ccccc3B5c3ccccc3O4)cn2)n1 ; CC(C)(C)c1nc(-c2ccc3c(c2)C(C)(C)CCC3(C)C)nc(-c2cccc(-c3cc4c5c(c3)Sc3ccccc3B5c3ccccc3O4)n2)n1]

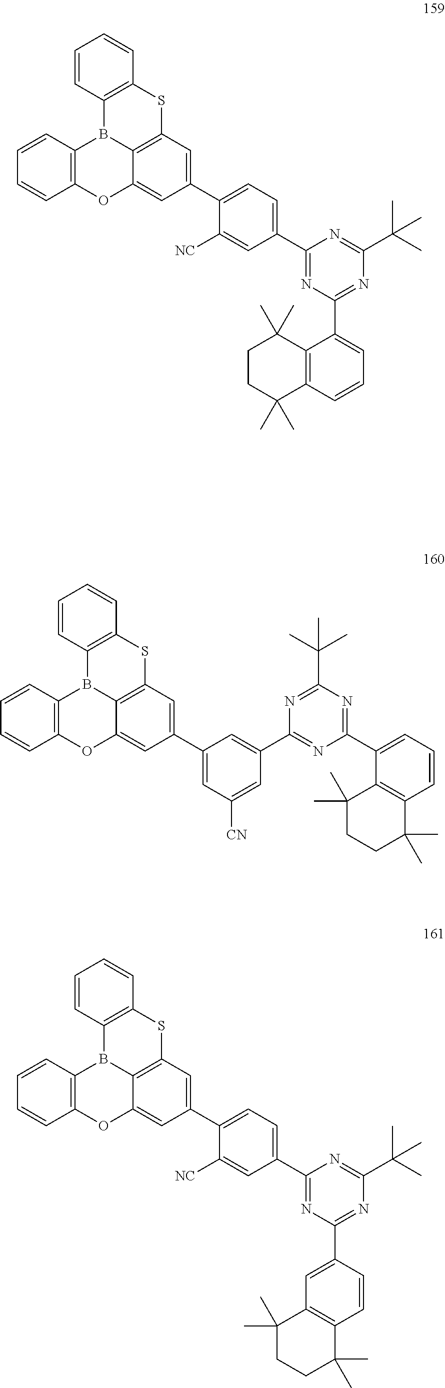 [SMILES: CC(C)(C)c1nc(-c2ccc(-c3cc4c5c(c3)Sc3ccccc3B5c3ccccc3O4)c(C#N)c2)nc(-c2cccc3c2C(C)(C)CCC3(C)C)n1 ; CC(C)(C)c1nc(-c2cc(C#N)cc(-c3cc4c5c(c3)Sc3ccccc3B5c3ccccc3O4)c2)nc(-c2cccc3c2C(C)(C)CCC3(C)C)n1 ; CC(C)(C)c1nc(-c2ccc(-c3cc4c5c(c3)Sc3ccccc3B5c3ccccc3O4)c(C#N)c2)nc(-c2ccc3c(c2)C(C)(C)CCC3(C)C)n1]

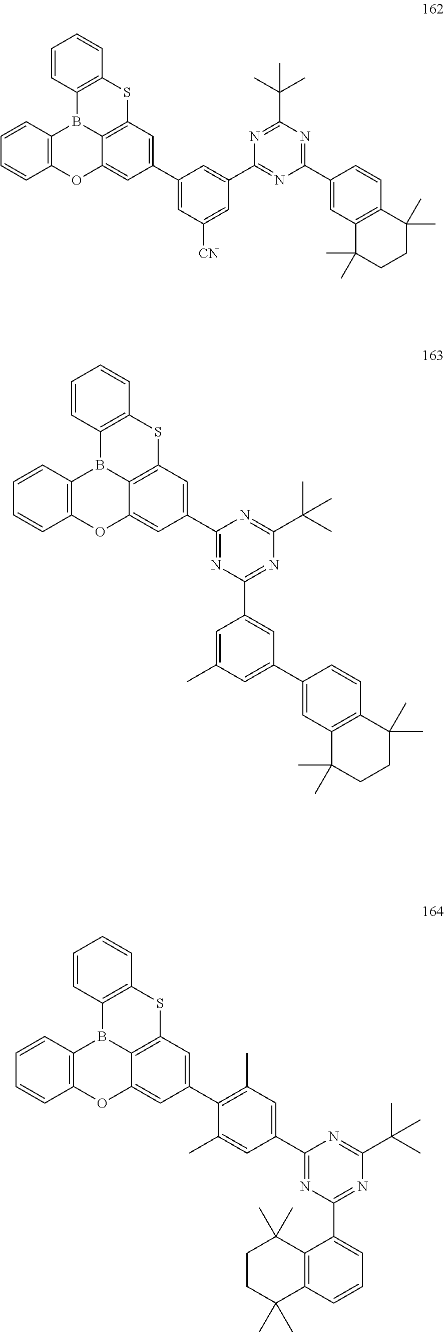 [SMILES: CC(C)(C)c1nc(-c2cc(C#N)cc(-c3cc4c5c(c3)Sc3ccccc3B5c3ccccc3O4)c2)nc(-c2ccc3c(c2)C(C)(C)CCC3(C)C)n1 ; Cc1cc(-c2ccc3c(c2)C(C)(C)CCC3(C)C)cc(-c2nc(-c3cc4c5c(c3)Sc3ccccc3B5c3ccccc3O4)nc(C(C)(C)C)n2)c1 ; Cc1cc(-c2nc(-c3cccc4c3C(C)(C)CCC4(C)C)nc(C(C)(C)C)n2)cc(C)c1-c1cc2c3c(c1)Sc1ccccc1B3c1ccccc1O2]

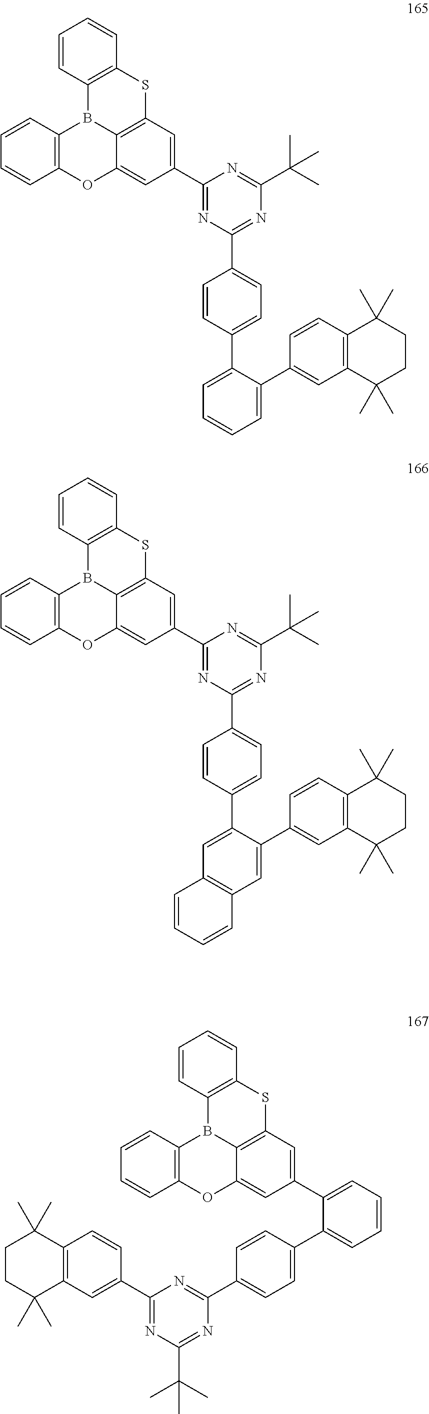 [SMILES: CC(C)(C)c1nc(-c2ccc(-c3ccccc3-c3ccc4c(c3)C(C)(C)CCC4(C)C)cc2)nc(-c2cc3c4c(c2)Sc2ccccc2B4c2ccccc2O3)n1 ; CC(C)(C)c1nc(-c2ccc(-c3cc4ccccc4cc3-c3ccc4c(c3)C(C)(C)CCC4(C)C)cc2)nc(-c2cc3c4c(c2)Sc2ccccc2B4c2ccccc2O3)n1 ; CC(C)(C)c1nc(-c2ccc(-c3ccccc3-c3cc4c5c(c3)Sc3ccccc3B5c3ccccc3O4)cc2)nc(-c2ccc3c(c2)C(C)(C)CCC3(C)C)n1]

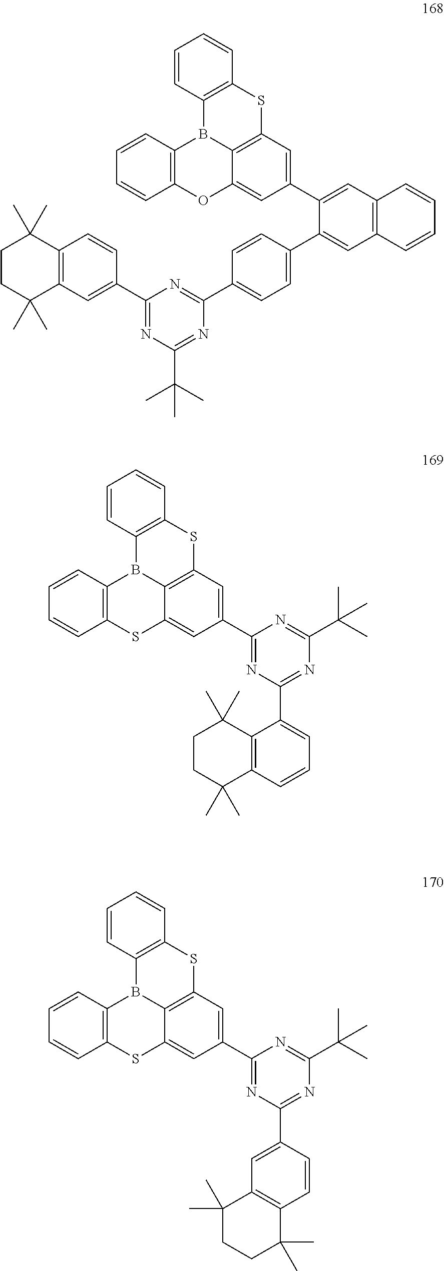 [SMILES: CC(C)(C)c1nc(-c2ccc(-c3cc4ccccc4cc3-c3cc4c5c(c3)Sc3ccccc3B5c3ccccc3O4)cc2)nc(-c2ccc3c(c2)C(C)(C)CCC3(C)C)n1 ; CC(C)(C)c1nc(-c2cc3c4c(c2)Sc2ccccc2B4c2ccccc2S3)nc(-c2cccc3c2C(C)(C)CCC3(C)C)n1 ; CC(C)(C)c1nc(-c2cc3c4c(c2)Sc2ccccc2B4c2ccccc2S3)nc(-c2ccc3c(c2)C(C)(C)CCC3(C)C)n1]

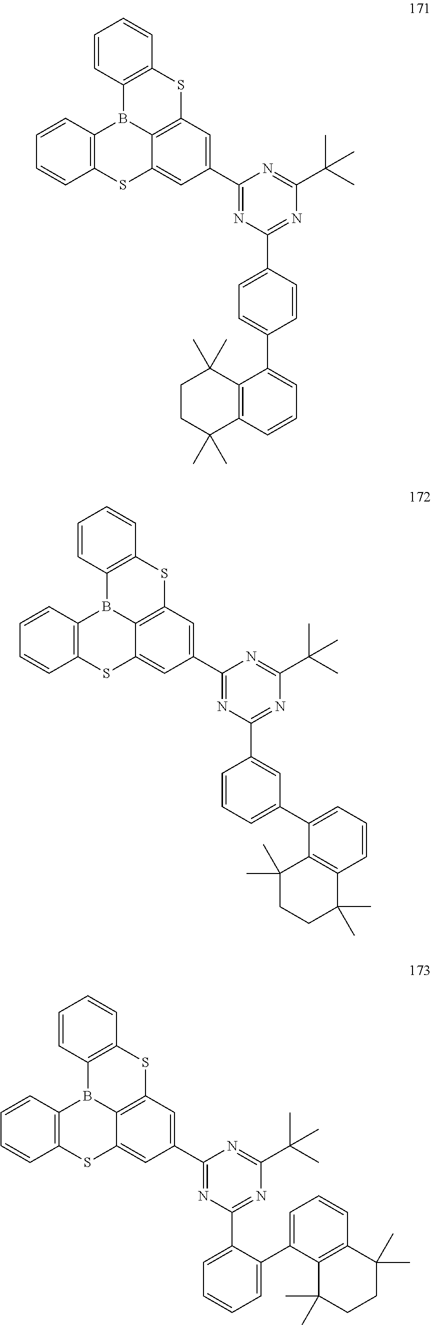 [SMILES: CC(C)(C)c1nc(-c2ccc(-c3cccc4c3C(C)(C)CCC4(C)C)cc2)nc(-c2cc3c4c(c2)Sc2ccccc2B4c2ccccc2S3)n1 ; CC(C)(C)c1nc(-c2cccc(-c3cccc4c3C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2cccc3c2C(C)(C)CCC3(C)C)n1]

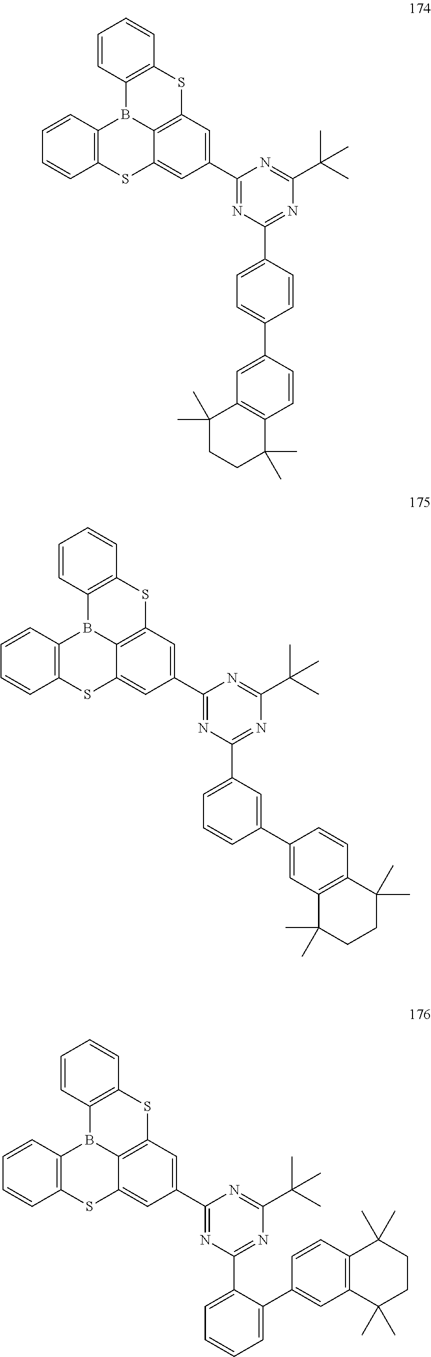 [SMILES: CC(C)(C)c1nc(-c2ccc(-c3ccc4c(c3)C(C)(C)CCC4(C)C)cc2)nc(-c2cc3c4c(c2)Sc2ccccc2B4c2ccccc2S3)n1 ; CC(C)(C)c1nc(-c2cccc(-c3ccc4c(c3)C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc3c(c2)C(C)(C)CCC3(C)C)n1]

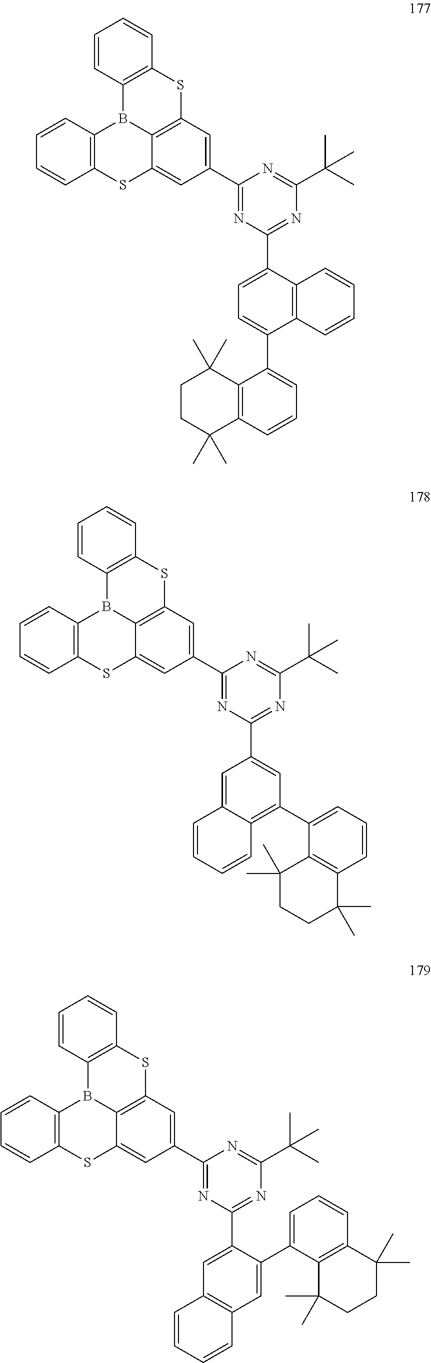 [SMILES: CC(C)(C)c1nc(-c2cc3c4c(c2)Sc2ccccc2B4c2ccccc2S3)nc(-c2ccc(-c3cccc4c3C(C)(C)CCC4(C)C)c3ccccc23)n1 ; CC(C)(C)c1nc(-c2cc3c4c(c2)Sc2ccccc2B4c2ccccc2S3)nc(-c2cc(-c3cccc4c3C(C)(C)CCC4(C)C)c3ccccc3c2)n1 ; CC(C)(C)c1nc(-c2cc3c4c(c2)Sc2ccccc2B4c2ccccc2S3)nc(-c2cc3ccccc3cc2-c2cccc3c2C(C)(C)CCC3(C)C)n1]

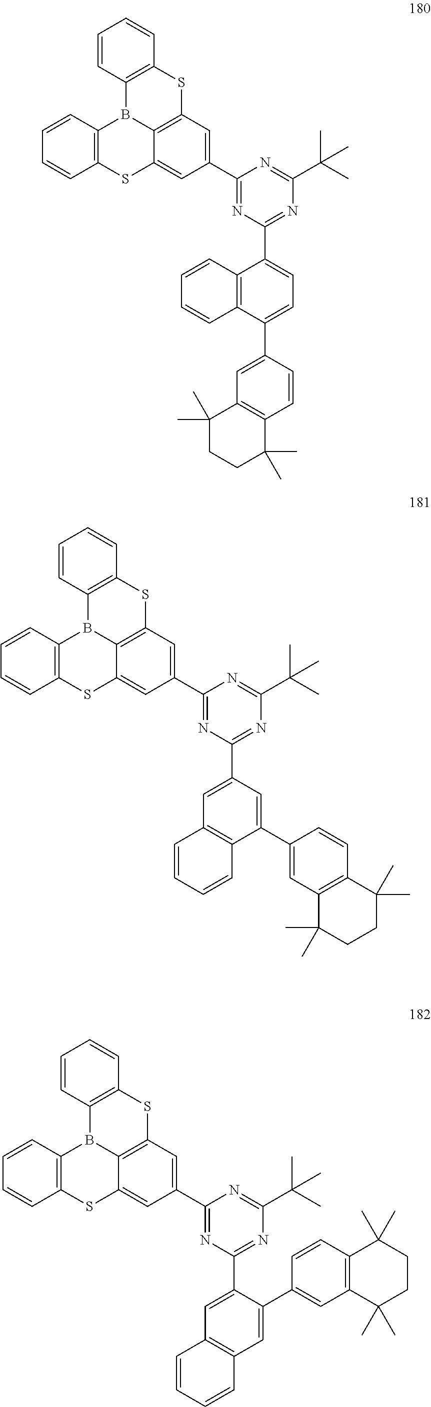 [SMILES: CC(C)(C)c1nc(-c2cc3c4c(c2)Sc2ccccc2B4c2ccccc2S3)nc(-c2ccc(-c3ccc4c(c3)C(C)(C)CCC4(C)C)c3ccccc23)n1 ; CC(C)(C)c1nc(-c2cc3c4c(c2)Sc2ccccc2B4c2ccccc2S3)nc(-c2cc(-c3ccc4c(c3)C(C)(C)CCC4(C)C)c3ccccc3c2)n1 ; CC(C)(C)c1nc(-c2cc3c4c(c2)Sc2ccccc2B4c2ccccc2S3)nc(-c2cc3ccccc3cc2-c2ccc3c(c2)C(C)(C)CCC3(C)C)n1]

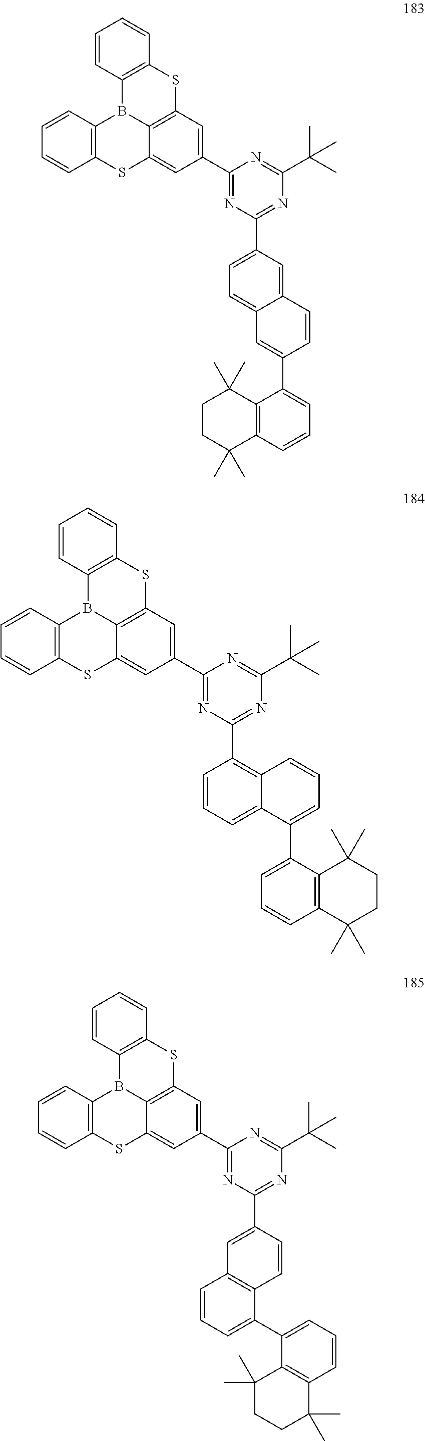 [SMILES: CC(C)(C)c1nc(-c2cc3c4c(c2)Sc2ccccc2B4c2ccccc2S3)nc(-c2ccc3cc(-c4cccc5c4C(C)(C)CCC5(C)C)ccc3c2)n1 ; CC(C)(C)c1nc(-c2cc3c4c(c2)Sc2ccccc2B4c2ccccc2S3)nc(-c2cccc3c(-c4cccc5c4C(C)(C)CCC5(C)C)cccc23)n1 ; CC(C)(C)c1nc(-c2cc3c4c(c2)Sc2ccccc2B4c2ccccc2S3)nc(-c2ccc3c(-c4cccc5c4C(C)(C)CCC5(C)C)cccc3c2)n1]

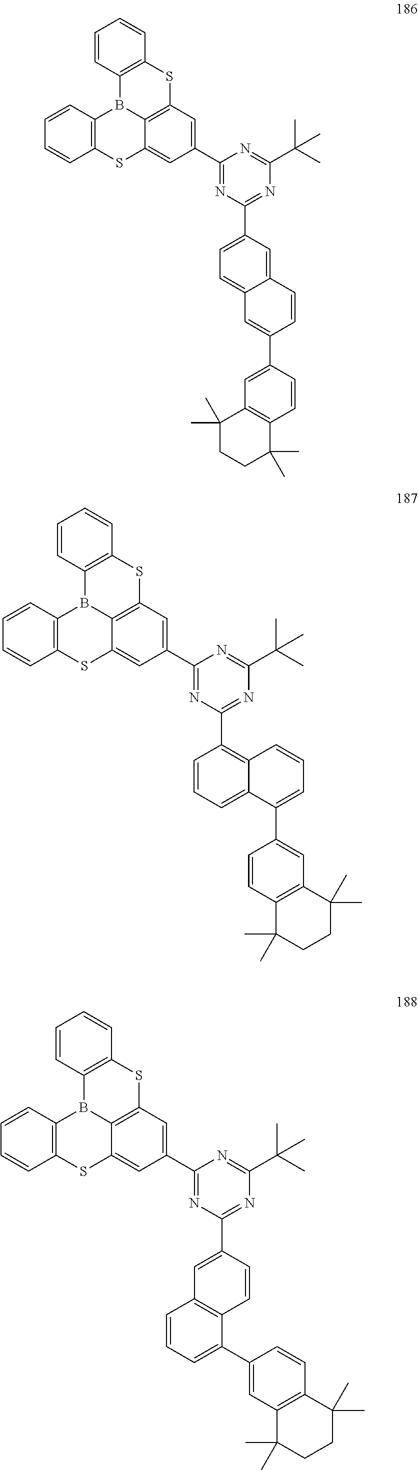 [SMILES: CC(C)(C)c1nc(-c2cc3c4c(c2)Sc2ccccc2B4c2ccccc2S3)nc(-c2ccc3cc(-c4ccc5c(c4)C(C)(C)CCC5(C)C)ccc3c2)n1 ; CC(C)(C)c1nc(-c2cc3c4c(c2)Sc2ccccc2B4c2ccccc2S3)nc(-c2cccc3c(-c4ccc5c(c4)C(C)(C)CCC5(C)C)cccc23)n1 ; CC(C)(C)c1nc(-c2cc3c4c(c2)Sc2ccccc2B4c2ccccc2S3)nc(-c2ccc3c(-c4ccc5c(c4)C(C)(C)CCC5(C)C)cccc3c2)n1]

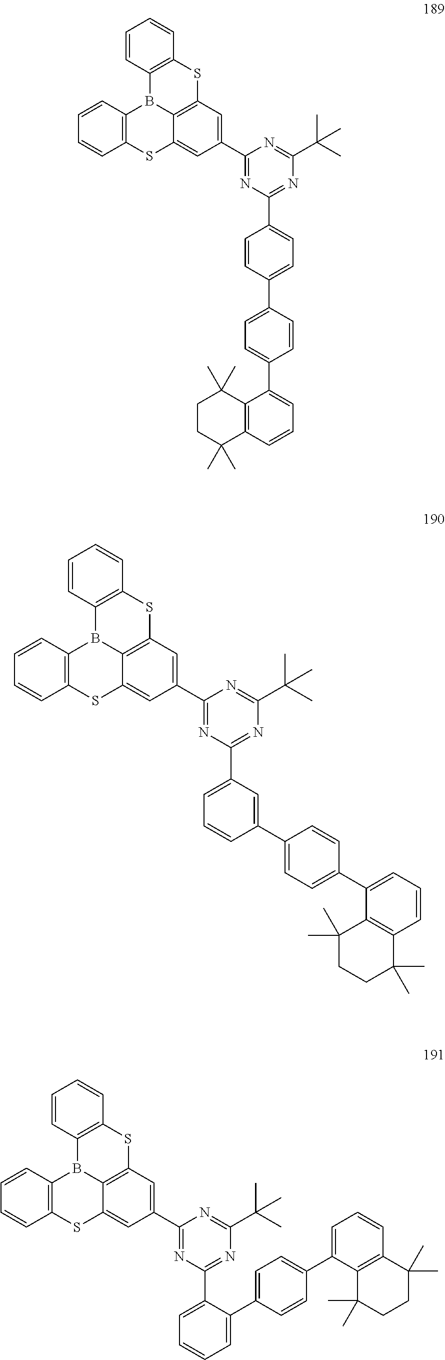 [SMILES: CC(C)(C)c1nc(-c2ccc(-c3ccc(-c4cccc5c4C(C)(C)CCC5(C)C)cc3)cc2)nc(-c2cc3c4c(c2)Sc2ccccc2B4c2ccccc2S3)n1 ; CC(C)(C)c1nc(-c2cccc(-c3ccc(-c4cccc5c4C(C)(C)CCC5(C)C)cc3)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3cccc4c3C(C)(C)CCC4(C)C)cc2)n1]

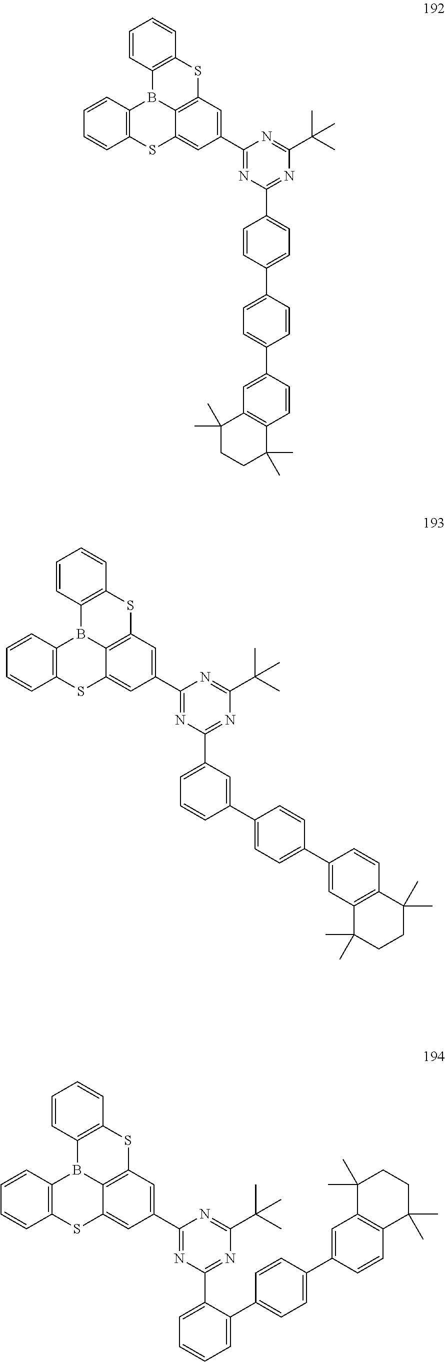 [SMILES: CC(C)(C)c1nc(-c2ccc(-c3ccc(-c4ccc5c(c4)C(C)(C)CCC5(C)C)cc3)cc2)nc(-c2cc3c4c(c2)Sc2ccccc2B4c2ccccc2S3)n1 ; CC(C)(C)c1nc(-c2cccc(-c3ccc(-c4ccc5c(c4)C(C)(C)CCC5(C)C)cc3)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3ccc4c(c3)C(C)(C)CCC4(C)C)cc2)n1]

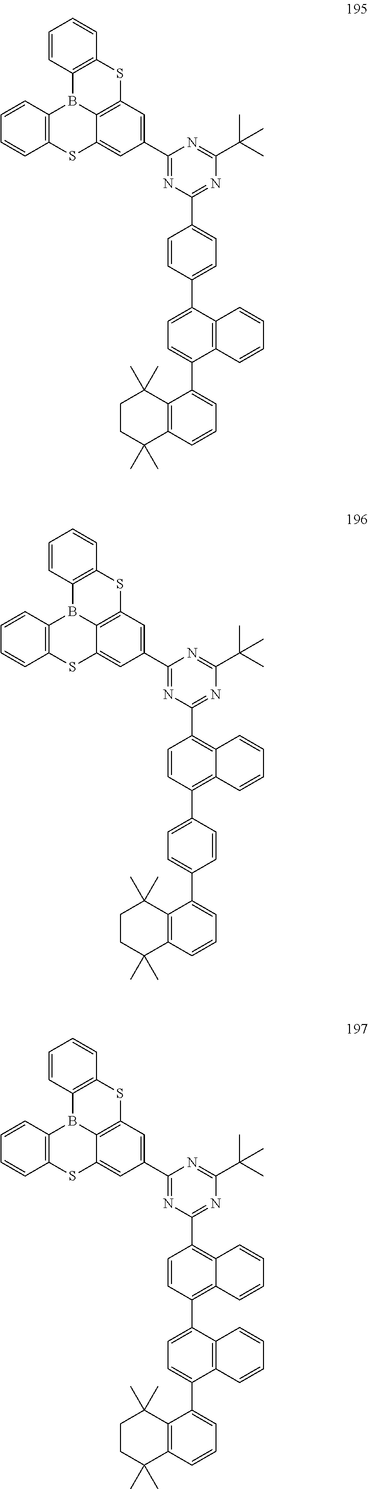 [SMILES: CC(C)(C)c1nc(-c2ccc(-c3ccc(-c4cccc5c4C(C)(C)CCC5(C)C)c4ccccc34)cc2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(-c3ccc(-c4cccc5c4C(C)(C)CCC5(C)C)cc3)c3ccccc23)n1 ; CC(C)(C)c1nc(-c2cc3c4c(c2)Sc2ccccc2B4c2ccccc2S3)nc(-c2ccc(-c3ccc(-c4cccc5c4C(C)(C)CCC5(C)C)c4ccccc34)c3ccccc23)n1]

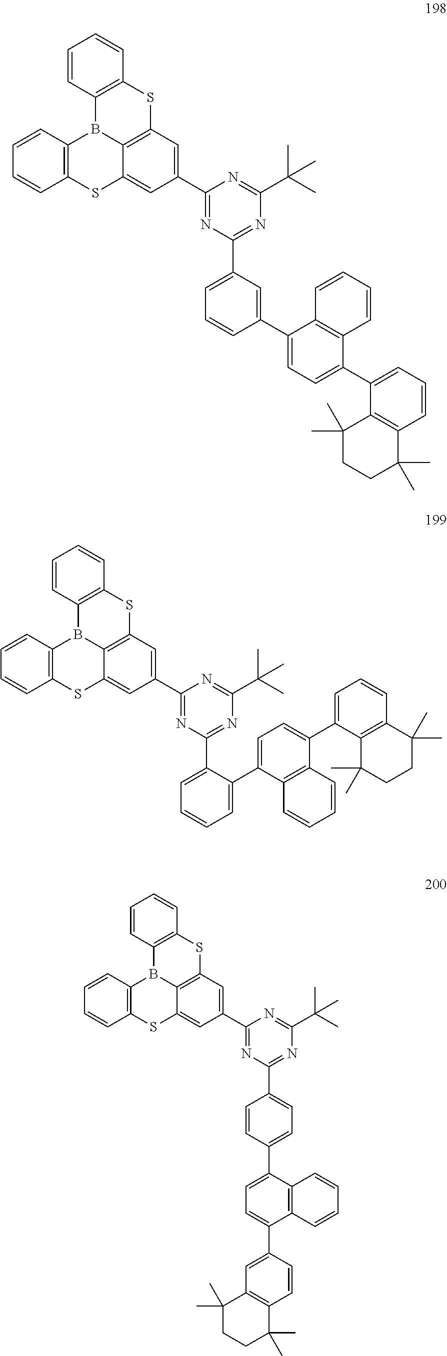 [SMILES: CC(C)(C)c1nc(-c2cccc(-c3ccc(-c4cccc5c4C(C)(C)CCC5(C)C)c4ccccc34)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3cccc4c3C(C)(C)CCC4(C)C)c3ccccc23)n1 ; CC(C)(C)c1nc(-c2ccc(-c3ccc(-c4ccc5c(c4)C(C)(C)CCC5(C)C)c4ccccc34)cc2)nc(-c2cc3c4c(c2)Sc2ccccc2B4c2ccccc2S3)n1]

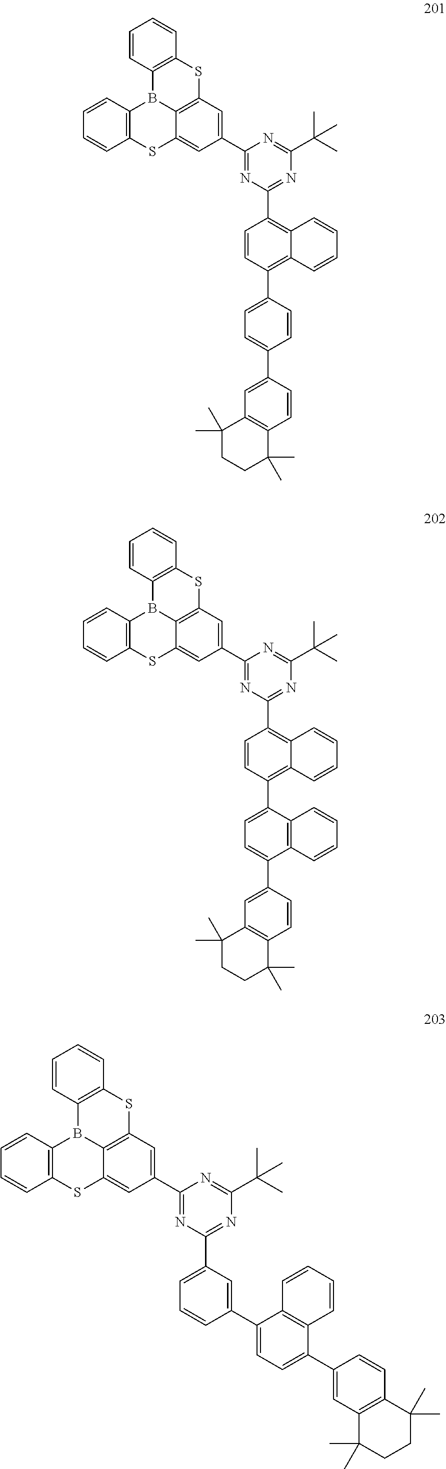 [SMILES: CC(C)(C)c1nc(-c2cc3c4c(c2)Sc2ccccc2B4c2ccccc2S3)nc(-c2ccc(-c3ccc(-c4ccc5c(c4)C(C)(C)CCC5(C)C)cc3)c3ccccc23)n1 ; CC(C)(C)c1nc(-c2cc3c4c(c2)Sc2ccccc2B4c2ccccc2S3)nc(-c2ccc(-c3ccc(-c4ccc5c(c4)C(C)(C)CCC5(C)C)c4ccccc34)c3ccccc23)n1 ; CC(C)(C)c1nc(-c2cccc(-c3ccc(-c4ccc5c(c4)C(C)(C)CCC5(C)C)c4ccccc34)c2)nc(-c2cc3c4c(c2)Sc2ccccc2B4c2ccccc2S3)n1]

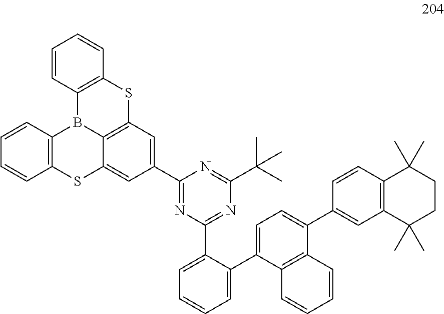 [SMILES: CC(C)(C)c1nc(-c2cc3c4c(c2)Sc2ccccc2B4c2ccccc2S3)nc(-c2ccccc2-c2ccc(-c3ccc4c(c3)C(C)(C)CCC4(C)C)c3ccccc23)n1]

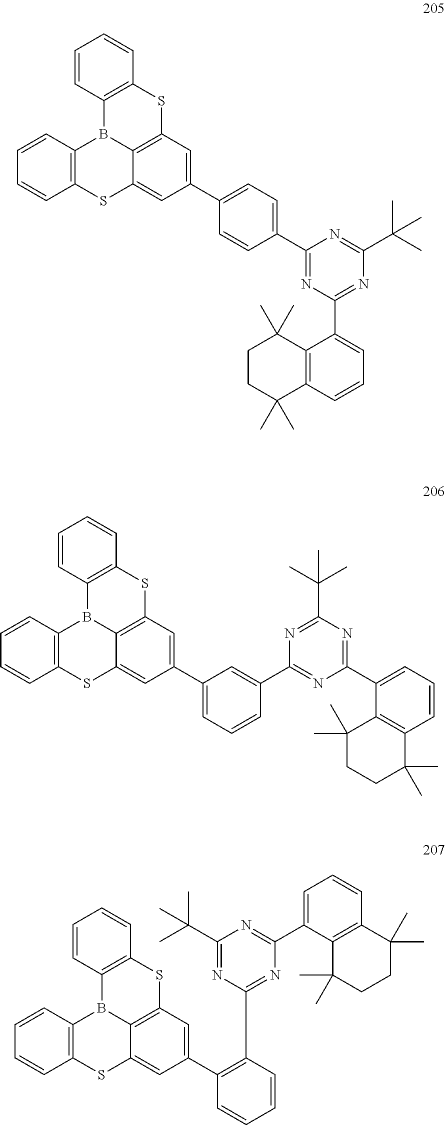 [SMILES: CC(C)(C)c1nc(-c2ccc(-c3cc4c5c(c3)Sc3ccccc3B5c3ccccc3S4)cc2)nc(-c2cccc3c2C(C)(C)CCC3(C)C)n1 ; CC(C)(C)c1nc(-c2cccc(-c3cc4c5c(c3)Sc3ccccc3B5c3ccccc3S4)c2)nc(-c2cccc3c2C(C)(C)CCC3(C)C)n1 ; CC(C)(C)c1nc(-c2ccccc2-c2cc3c4c(c2)Sc2ccccc2B4c2ccccc2S3)nc(-c2cccc3c2C(C)(C)CCC3(C)C)n1]

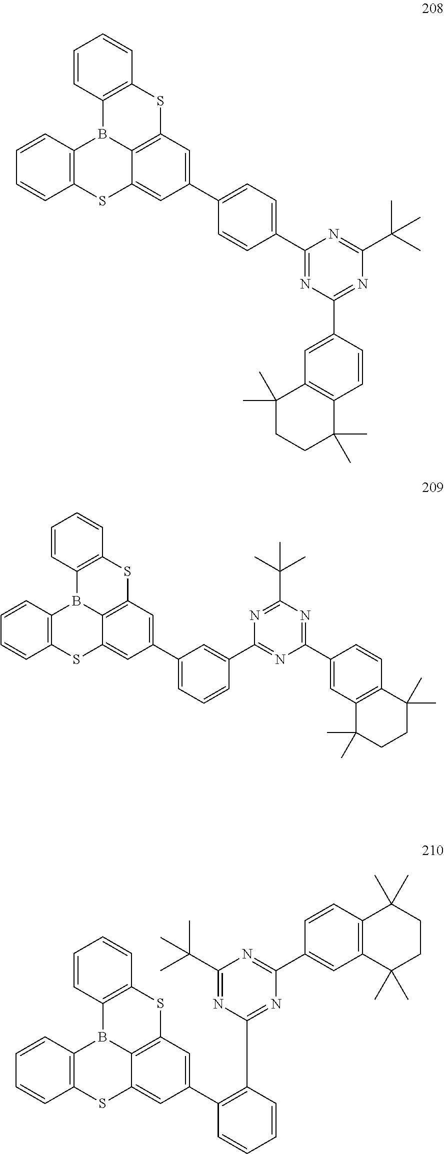 [SMILES: CC(C)(C)c1nc(-c2ccc(-c3cc4c5c(c3)Sc3ccccc3B5c3ccccc3S4)cc2)nc(-c2ccc3c(c2)C(C)(C)CCC3(C)C)n1 ; CC(C)(C)c1nc(-c2cccc(-c3cc4c5c(c3)Sc3ccccc3B5c3ccccc3S4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Sc2ccccc2B4c2ccccc2S3)n1]

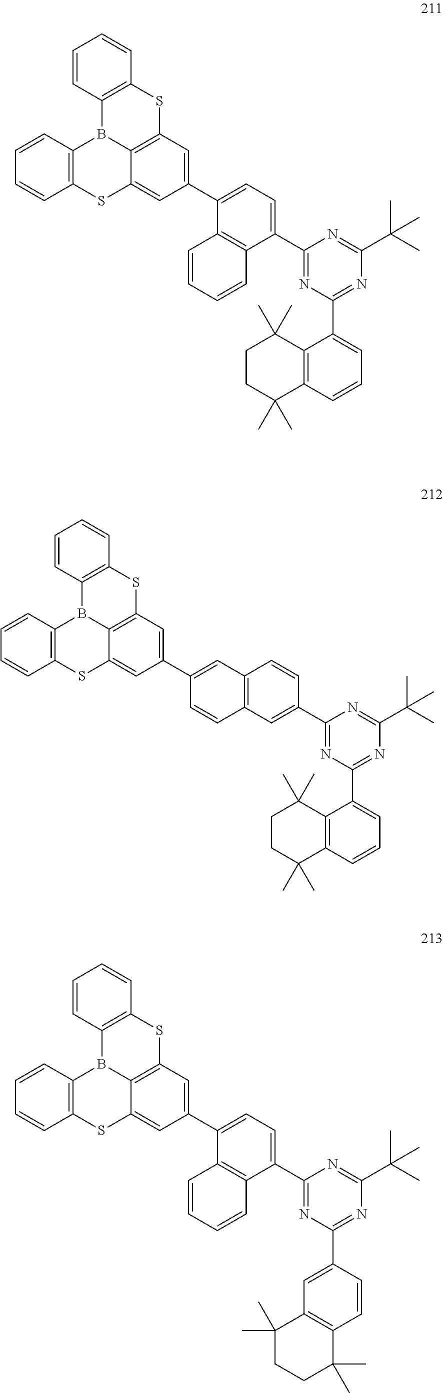 [SMILES: CC(C)(C)c1nc(-c2cccc3c2C(C)(C)CCC3(C)C)nc(-c2ccc(-c3cc4c5c(c3)Sc3ccccc3B5c3ccccc3S4)c3ccccc23)n1 ; CC(C)(C)c1nc(-c2ccc3cc(-c4cc5c6c(c4)Sc4ccccc4B6c4ccccc4S5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Sc3ccccc3B5c3ccccc3S4)c3ccccc23)n1]

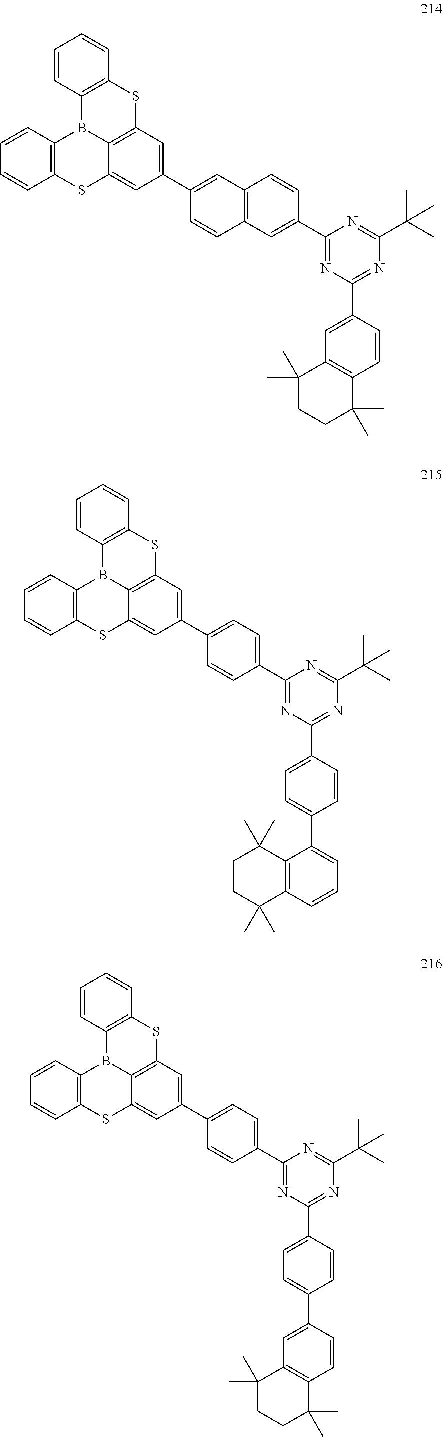 [SMILES: CC(C)(C)c1nc(-c2ccc3c(c2)C(C)(C)CCC3(C)C)nc(-c2ccc3cc(-c4cc5c6c(c4)Sc4ccccc4B6c4ccccc4S5)ccc3c2)n1 ; CC(C)(C)c1nc(-c2ccc(-c3cc4c5c(c3)Sc3ccccc3B5c3ccccc3S4)cc2)nc(-c2ccc(-c3cccc4c3C(C)(C)CCC4(C)C)cc2)n1 ; CC(C)(C)c1nc(-c2ccc(-c3cc4c5c(c3)Sc3ccccc3B5c3ccccc3S4)cc2)nc(-c2ccc(-c3ccc4c(c3)C(C)(C)CCC4(C)C)cc2)n1]

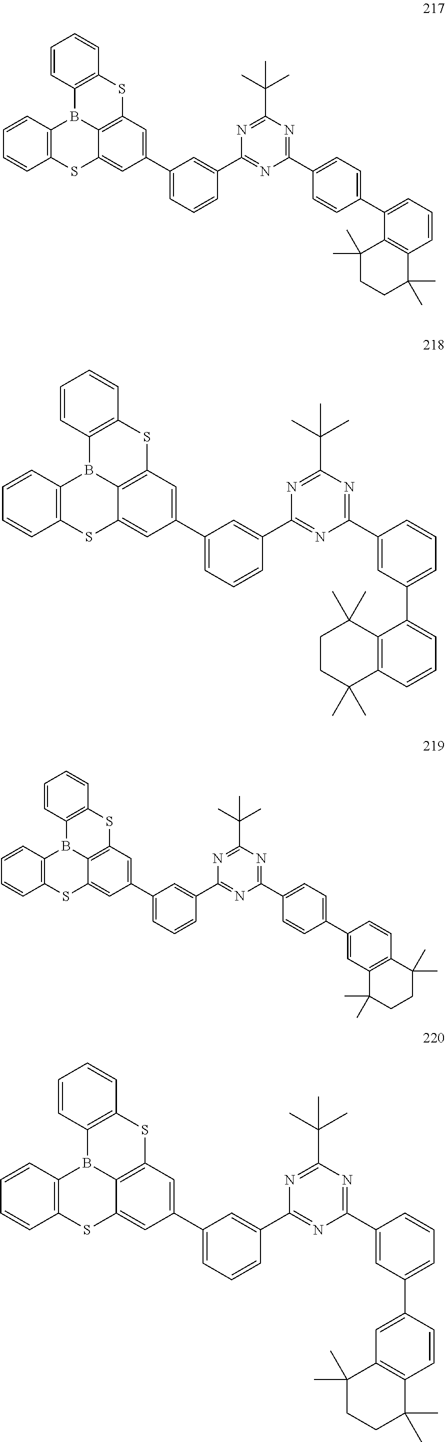 [SMILES: CC(C)(C)c1nc(-c2ccc(-c3cccc4c3C(C)(C)CCC4(C)C)cc2)nc(-c2cccc(-c3cc4c5c(c3)Sc3ccccc3B5c3ccccc3S4)c2)n1 ; CC(C)(C)c1nc(-c2cccc(-c3cc4c5c(c3)Sc3ccccc3B5c3ccccc3S4)c2)nc(-c2cccc(-c3cccc4c3C(C)(C)CCC4(C)C)c2)n1 ; CC(C)(C)c1nc(-c2ccc(-c3ccc4c(c3)C(C)(C)CCC4(C)C)cc2)nc(-c2cccc(-c3cc4c5c(c3)Sc3ccccc3B5c3ccccc3S4)c2)n1 ; CC(C)(C)c1nc(-c2cccc(-c3cc4c5c(c3)Sc3ccccc3B5c3ccccc3S4)c2)nc(-c2cccc(-c3ccc4c(c3)C(C)(C)CCC4(C)C)c2)n1]

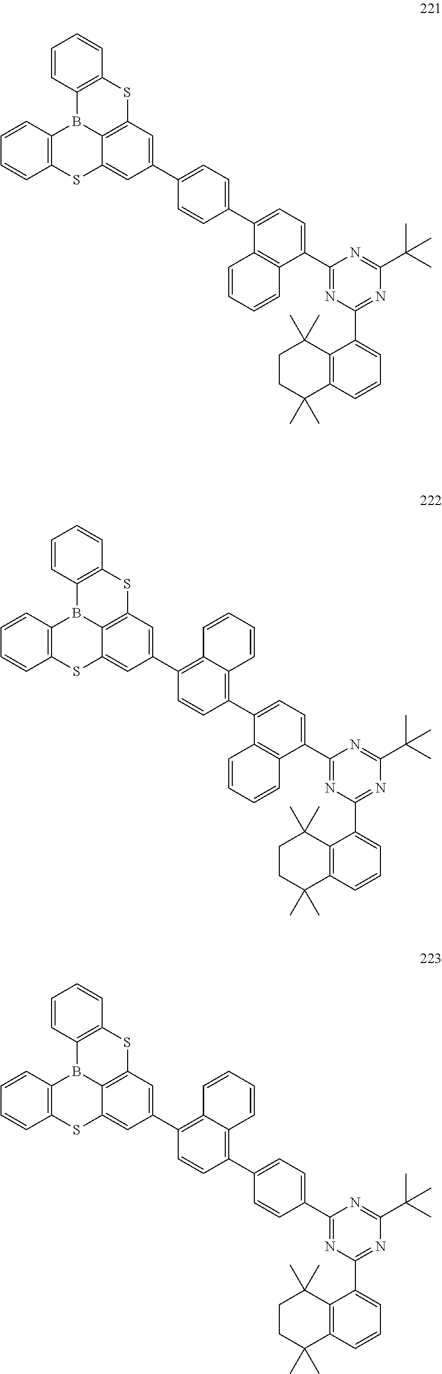 [SMILES: CC(C)(C)c1nc(-c2cccc3c2C(C)(C)CCC3(C)C)nc(-c2ccc(-c3ccc(-c4cc5c6c(c4)Sc4ccccc4B6c4ccccc4S5)cc3)c3ccccc23)n1 ; CC(C)(C)c1nc(-c2cccc3c2C(C)(C)CCC3(C)C)nc(-c2ccc(-c3ccc(-c4cc5c6c(c4)Sc4ccccc4B6c4ccccc4S5)c4ccccc34)c3ccccc23)n1 ; CC(C)(C)c1nc(-c2ccc(-c3ccc(-c4cc5c6c(c4)Sc4ccccc4B6c4ccccc4S5)c4ccccc34)cc2)nc(-c2cccc3c2C(C)(C)CCC3(C)C)n1]

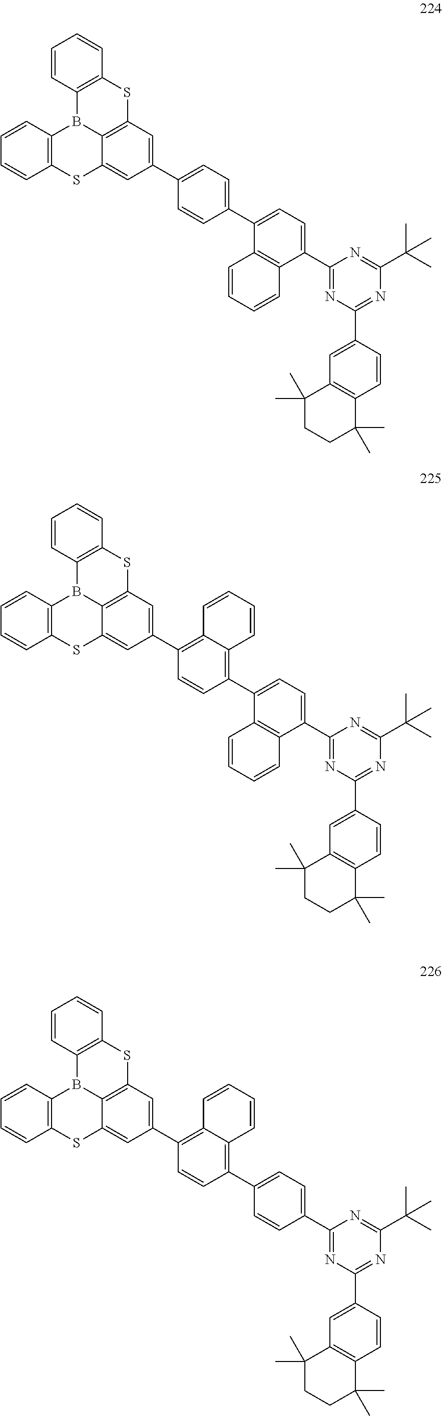 [SMILES: CC(C)(C)c1nc(-c2ccc3c(c2)C(C)(C)CCC3(C)C)nc(-c2ccc(-c3ccc(-c4cc5c6c(c4)Sc4ccccc4B6c4ccccc4S5)cc3)c3ccccc23)n1 ; CC(C)(C)c1nc(-c2ccc3c(c2)C(C)(C)CCC3(C)C)nc(-c2ccc(-c3ccc(-c4cc5c6c(c4)Sc4ccccc4B6c4ccccc4S5)c4ccccc34)c3ccccc23)n1 ; CC(C)(C)c1nc(-c2ccc(-c3ccc(-c4cc5c6c(c4)Sc4ccccc4B6c4ccccc4S5)c4ccccc34)cc2)nc(-c2ccc3c(c2)C(C)(C)CCC3(C)C)n1]

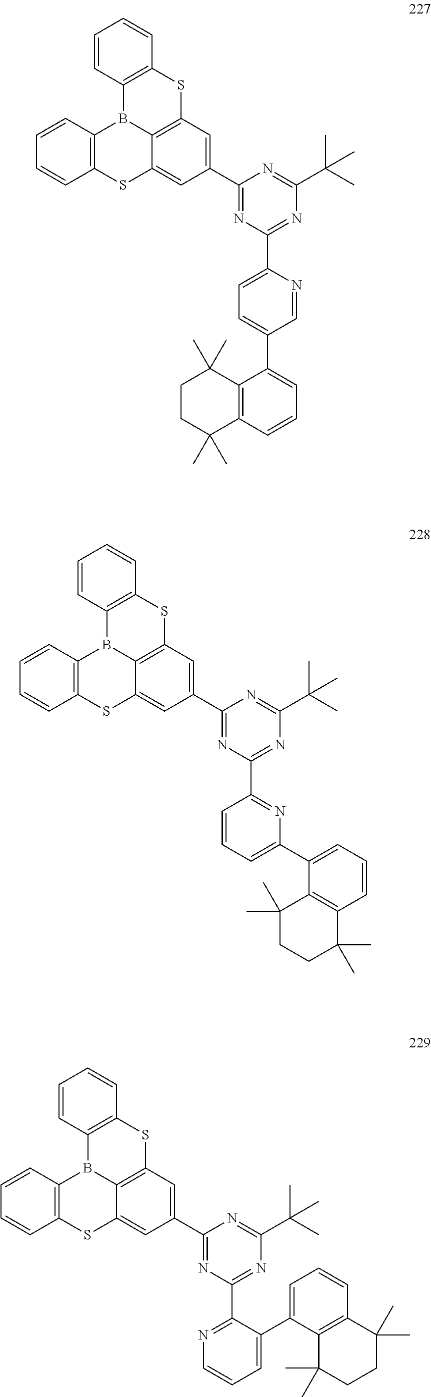 [SMILES: CC(C)(C)c1nc(-c2cc3c4c(c2)Sc2ccccc2B4c2ccccc2S3)nc(-c2ccc(-c3cccc4c3C(C)(C)CCC4(C)C)cn2)n1 ; CC(C)(C)c1nc(-c2cc3c4c(c2)Sc2ccccc2B4c2ccccc2S3)nc(-c2cccc(-c3cccc4c3C(C)(C)CCC4(C)C)n2)n1 ; CC(C)(C)c1nc(-c2cc3c4c(c2)Sc2ccccc2B4c2ccccc2S3)nc(-c2ncccc2-c2cccc3c2C(C)(C)CCC3(C)C)n1]

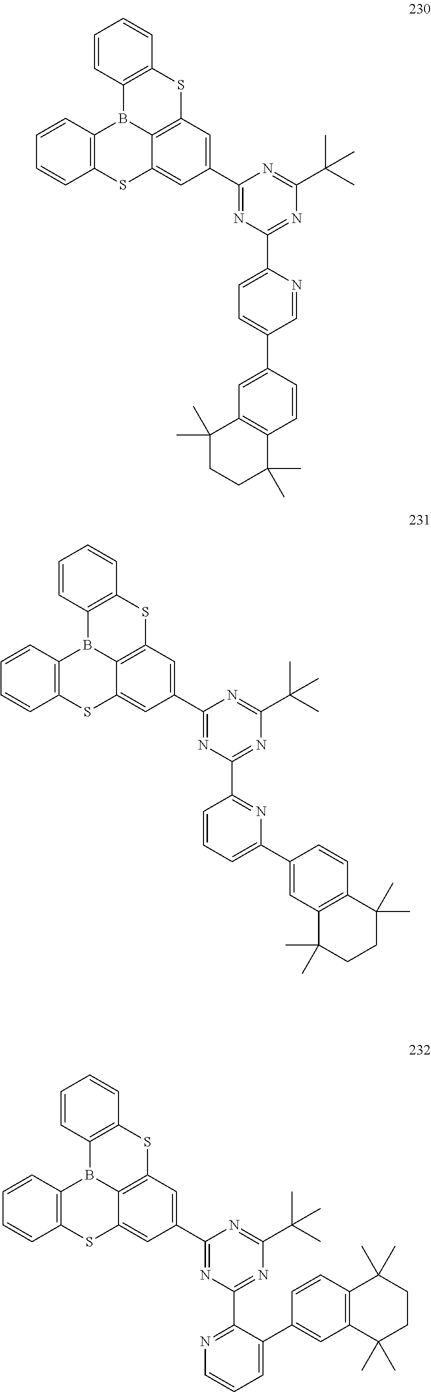 [SMILES: CC(C)(C)c1nc(-c2cc3c4c(c2)Sc2ccccc2B4c2ccccc2S3)nc(-c2ccc(-c3ccc4c(c3)C(C)(C)CCC4(C)C)cn2)n1 ; CC(C)(C)c1nc(-c2cc3c4c(c2)Sc2ccccc2B4c2ccccc2S3)nc(-c2cccc(-c3ccc4c(c3)C(C)(C)CCC4(C)C)n2)n1 ; CC(C)(C)c1nc(-c2cc3c4c(c2)Sc2ccccc2B4c2ccccc2S3)nc(-c2ncccc2-c2ccc3c(c2)C(C)(C)CCC3(C)C)n1]

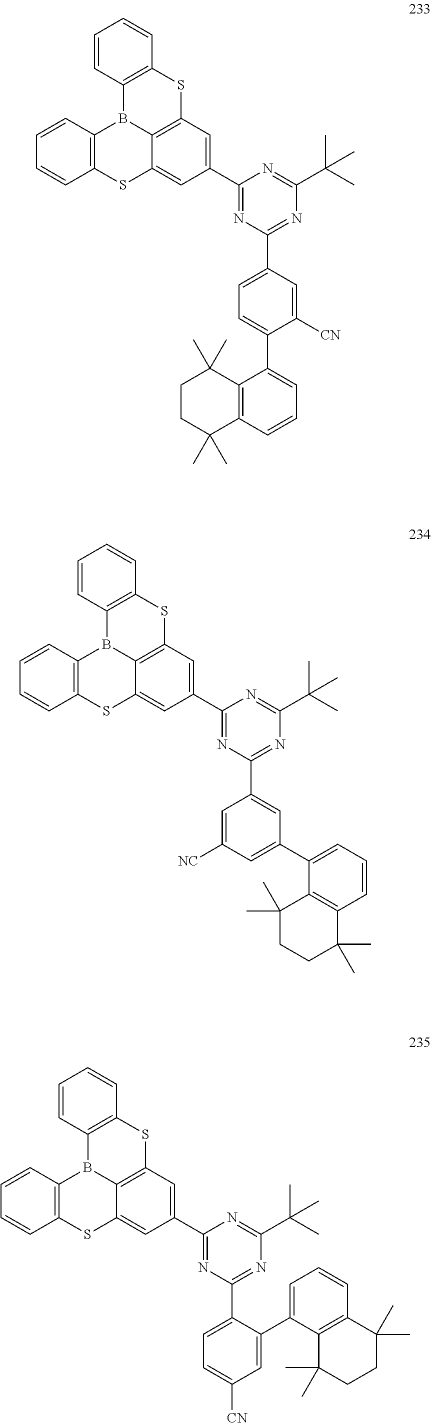 [SMILES: CC(C)(C)c1nc(-c2ccc(-c3cccc4c3C(C)(C)CCC4(C)C)c(C#N)c2)nc(-c2cc3c4c(c2)Sc2ccccc2B4c2ccccc2S3)n1 ; CC(C)(C)c1nc(-c2cc(C#N)cc(-c3cccc4c3C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(C#N)cc2-c2cccc3c2C(C)(C)CCC3(C)C)n1]

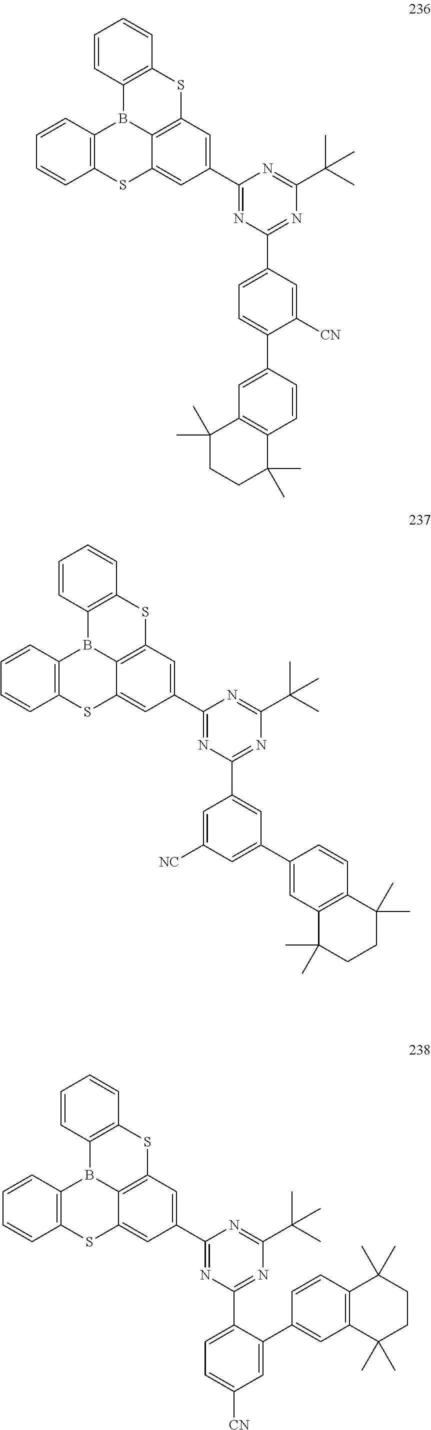 [SMILES: CC(C)(C)c1nc(-c2ccc(-c3ccc4c(c3)C(C)(C)CCC4(C)C)c(C#N)c2)nc(-c2cc3c4c(c2)Sc2ccccc2B4c2ccccc2S3)n1 ; CC(C)(C)c1nc(-c2cc(C#N)cc(-c3ccc4c(c3)C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(C#N)cc2-c2ccc3c(c2)C(C)(C)CCC3(C)C)n1]

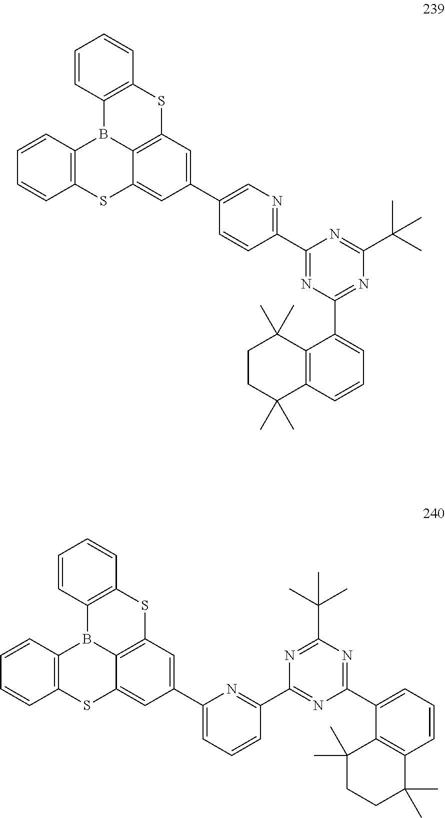 [SMILES: CC(C)(C)c1nc(-c2ccc(-c3cc4c5c(c3)Sc3ccccc3B5c3ccccc3S4)cn2)nc(-c2cccc3c2C(C)(C)CCC3(C)C)n1 ; CC(C)(C)c1nc(-c2cccc(-c3cc4c5c(c3)Sc3ccccc3B5c3ccccc3S4)n2)nc(-c2cccc3c2C(C)(C)CCC3(C)C)n1]

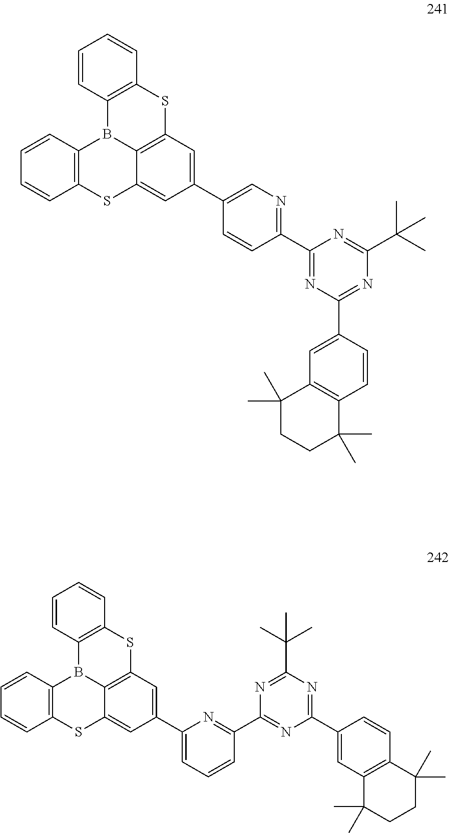 [SMILES: CC(C)(C)c1nc(-c2ccc3c(c2)C(C)(C)CCC3(C)C)nc(-c2ccc(-c3cc4c5c(c3)Sc3ccccc3B5c3ccccc3S4)cn2)n1 ; CC(C)(C)c1nc(-c2ccc3c(c2)C(C)(C)CCC3(C)C)nc(-c2cccc(-c3cc4c5c(c3)Sc3ccccc3B5c3ccccc3S4)n2)n1]

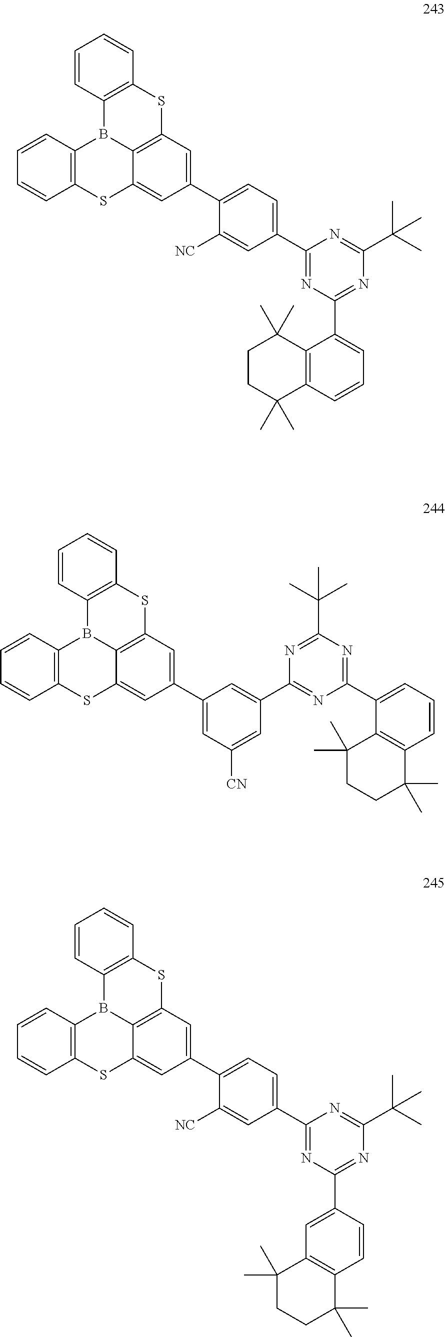 [SMILES: CC(C)(C)c1nc(-c2ccc(-c3cc4c5c(c3)Sc3ccccc3B5c3ccccc3S4)c(C#N)c2)nc(-c2cccc3c2C(C)(C)CCC3(C)C)n1 ; CC(C)(C)c1nc(-c2cc(C#N)cc(-c3cc4c5c(c3)Sc3ccccc3B5c3ccccc3S4)c2)nc(-c2cccc3c2C(C)(C)CCC3(C)C)n1 ; CC(C)(C)c1nc(-c2ccc(-c3cc4c5c(c3)Sc3ccccc3B5c3ccccc3S4)c(C#N)c2)nc(-c2ccc3c(c2)C(C)(C)CCC3(C)C)n1]

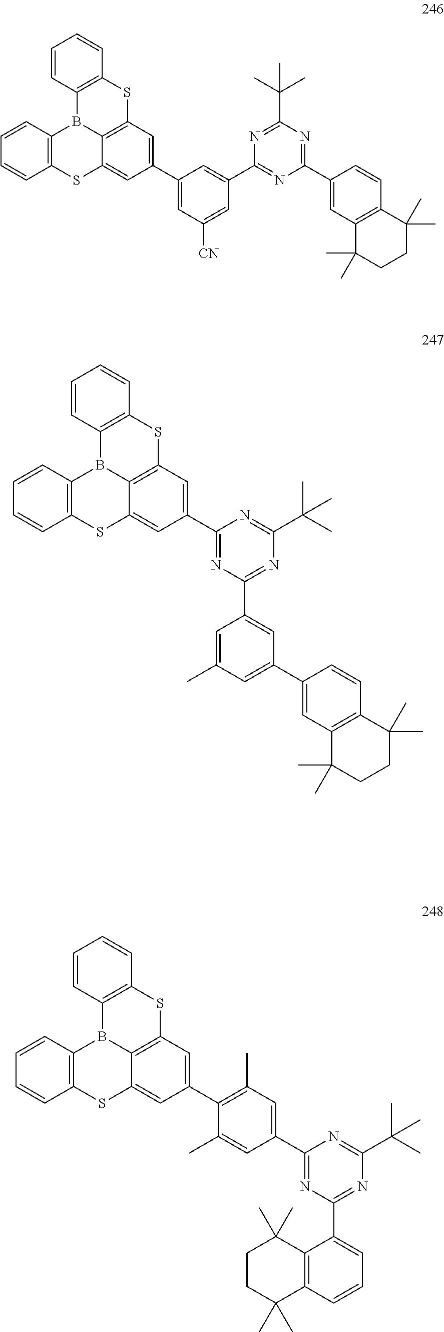 [SMILES: CC(C)(C)c1nc(-c2cc(C#N)cc(-c3cc4c5c(c3)Sc3ccccc3B5c3ccccc3S4)c2)nc(-c2ccc3c(c2)C(C)(C)CCC3(C)C)n1 ; Cc1cc(-c2ccc3c(c2)C(C)(C)CCC3(C)C)cc(-c2nc(-c3cc4c5c(c3)Sc3ccccc3B5c3ccccc3S4)nc(C(C)(C)C)n2)c1 ; Cc1cc(-c2nc(-c3cccc4c3C(C)(C)CCC4(C)C)nc(C(C)(C)C)n2)cc(C)c1-c1cc2c3c(c1)Sc1ccccc1B3c1ccccc1S2]

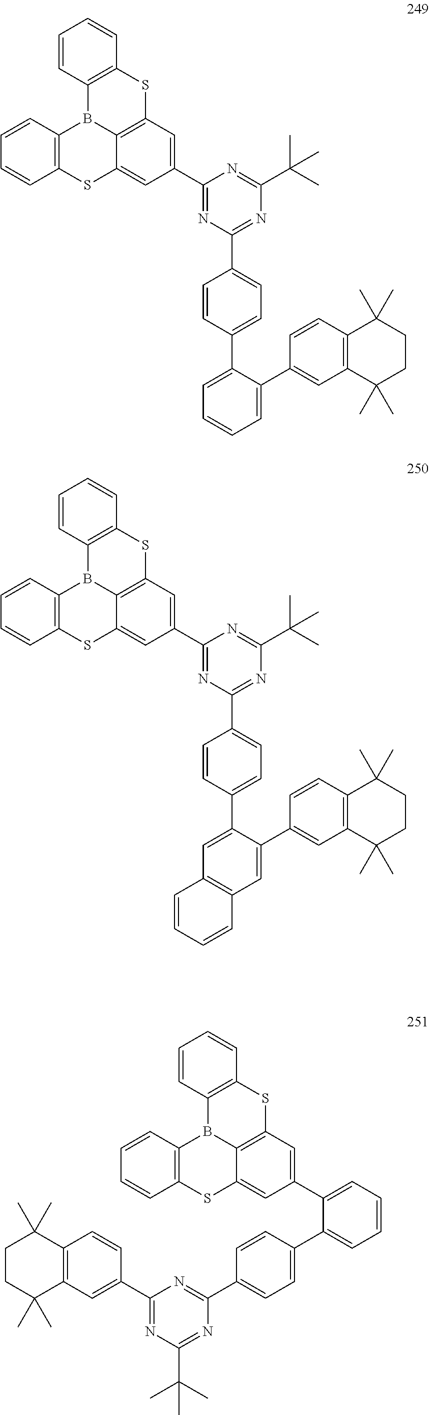 [SMILES: CC(C)(C)c1nc(-c2ccc(-c3ccccc3-c3ccc4c(c3)C(C)(C)CCC4(C)C)cc2)nc(-c2cc3c4c(c2)Sc2ccccc2B4c2ccccc2S3)n1 ; CC(C)(C)c1nc(-c2ccc(-c3cc4ccccc4cc3-c3ccc4c(c3)C(C)(C)CCC4(C)C)cc2)nc(-c2cc3c4c(c2)Sc2ccccc2B4c2ccccc2S3)n1 ; CC(C)(C)c1nc(-c2ccc(-c3ccccc3-c3cc4c5c(c3)Sc3ccccc3B5c3ccccc3S4)cc2)nc(-c2ccc3c(c2)C(C)(C)CCC3(C)C)n1]

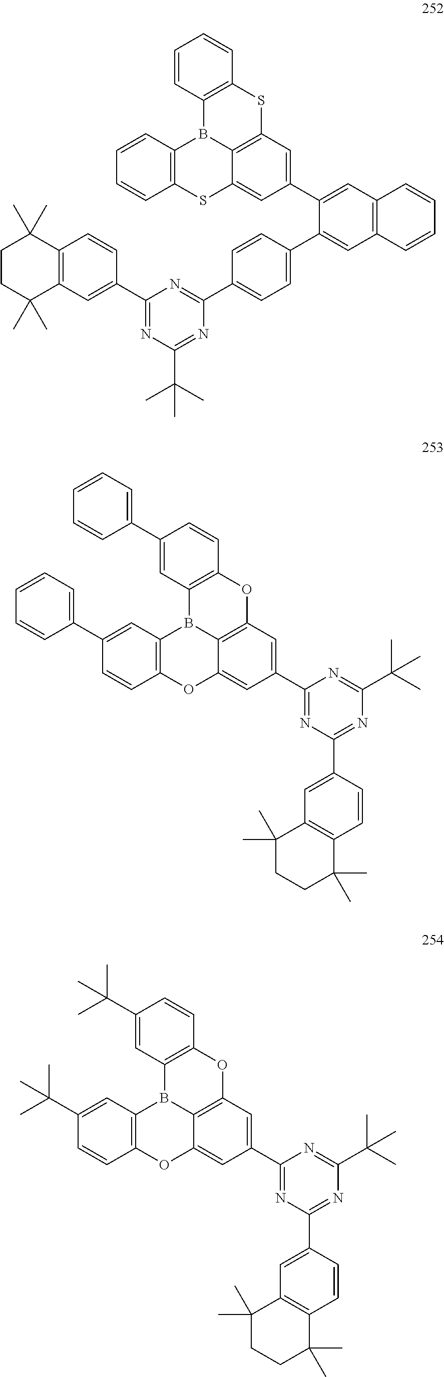

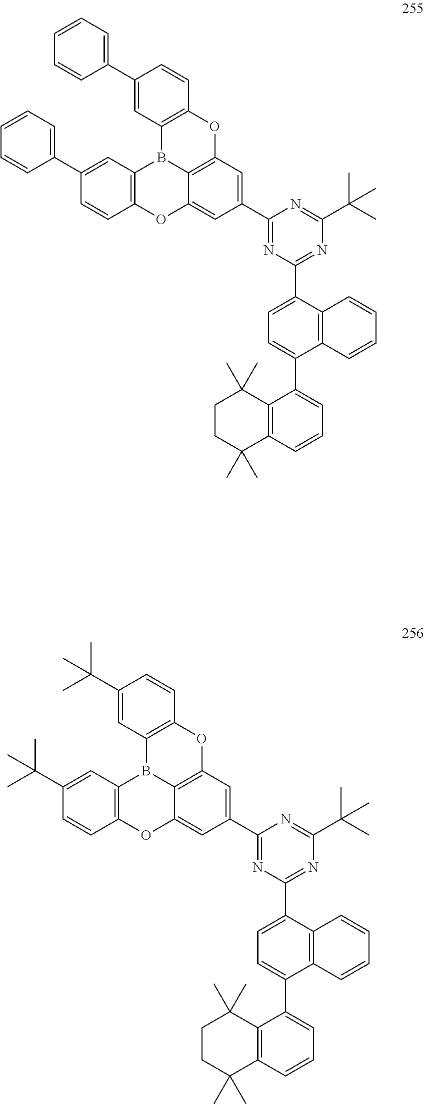 [SMILES: CC(C)(C)c1nc(-c2cc3c4c(c2)Oc2ccc(-c5ccccc5)cc2B4c2cc(-c4ccccc4)ccc2O3)nc(-c2ccc(-c3cccc4c3C(C)(C)CCC4(C)C)c3ccccc23)n1 ; CC(C)(C)c1ccc2c(c1)B1c3cc(C(C)(C)C)ccc3Oc3cc(-c4nc(-c5ccc(-c6cccc7c6C(C)(C)CCC7(C)C)c6ccccc56)nc(C(C)(C)C)n4)cc(c31)O2]

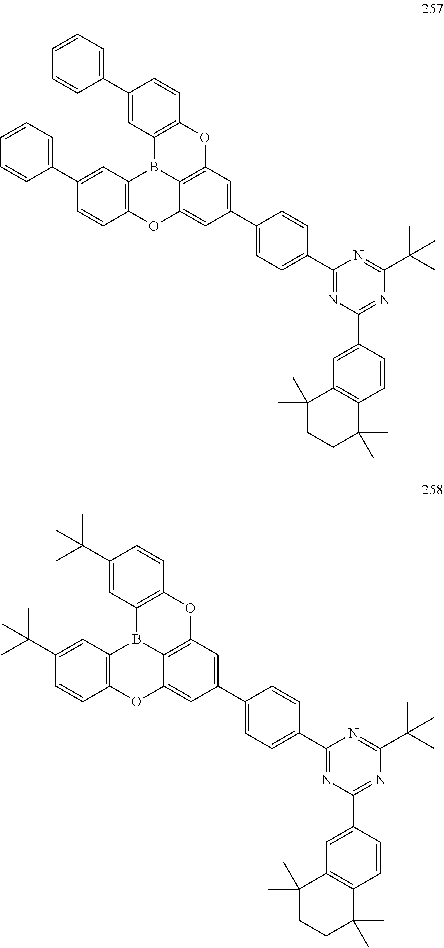

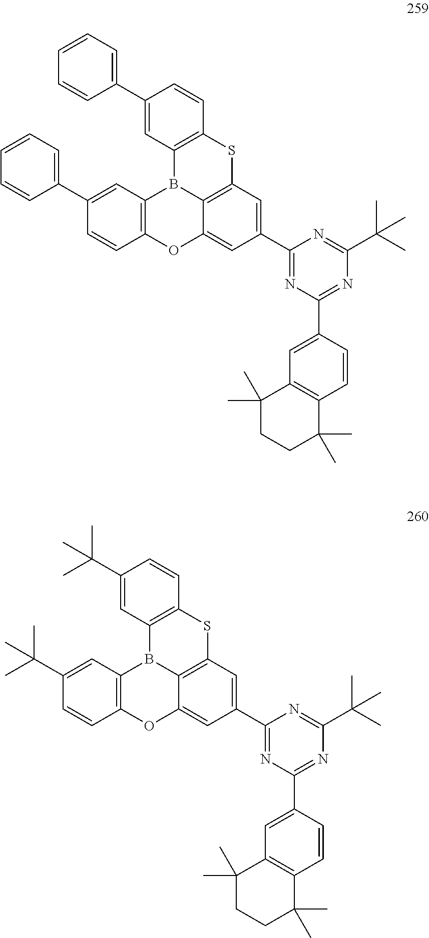

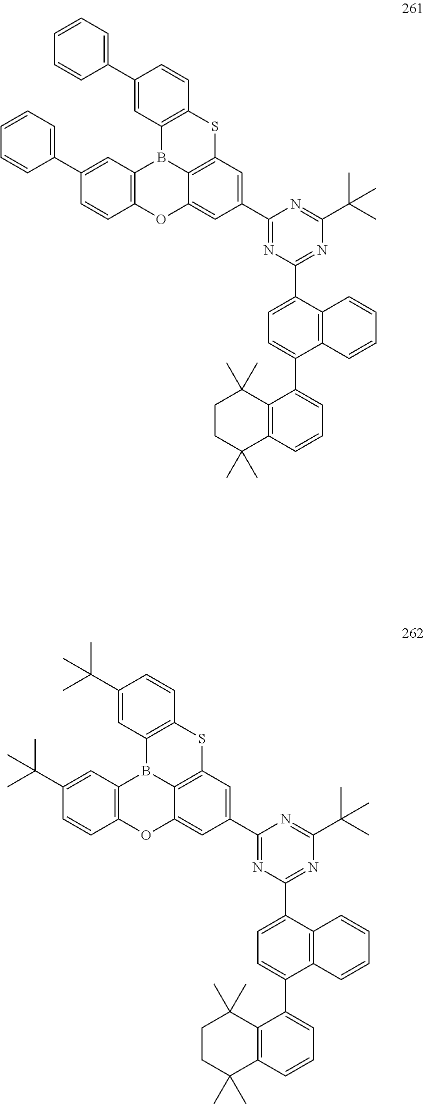 [SMILES: CC(C)(C)c1nc(-c2cc3c4c(c2)Sc2ccc(-c5ccccc5)cc2B4c2cc(-c4ccccc4)ccc2O3)nc(-c2ccc(-c3cccc4c3C(C)(C)CCC4(C)C)c3ccccc23)n1 ; CC(C)(C)c1ccc2c(c1)B1c3cc(C(C)(C)C)ccc3Sc3cc(-c4nc(-c5ccc(-c6cccc7c6C(C)(C)CCC7(C)C)c6ccccc56)nc(C(C)(C)C)n4)cc(c31)O2]

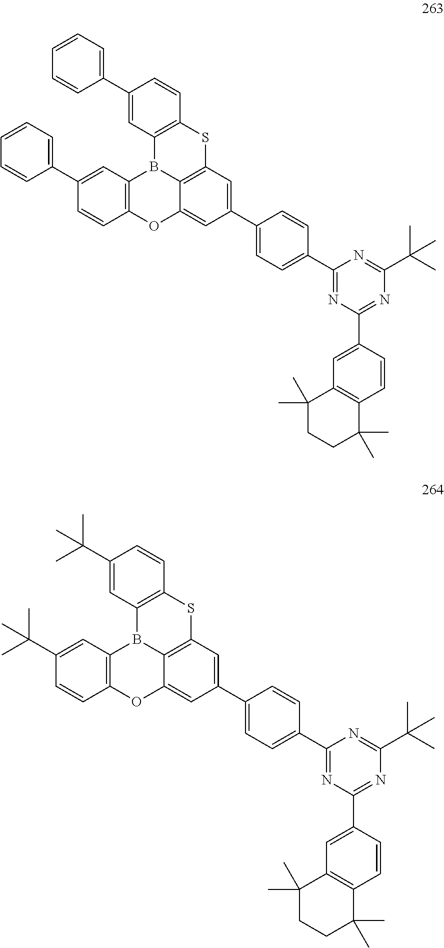

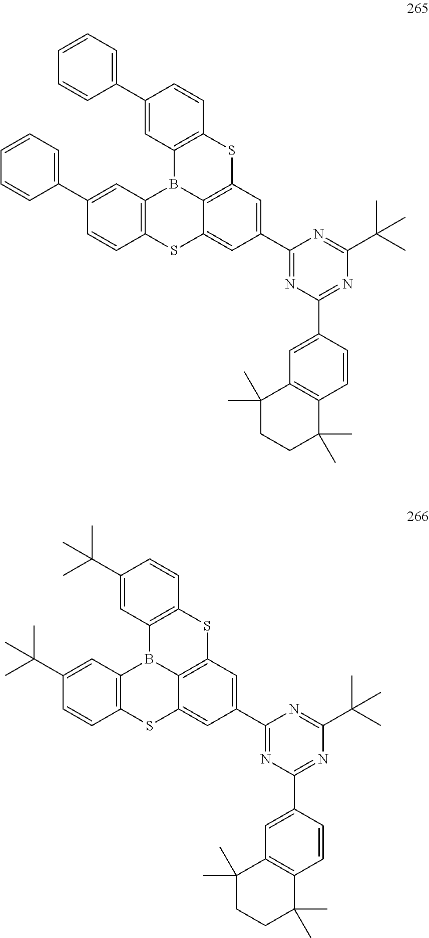

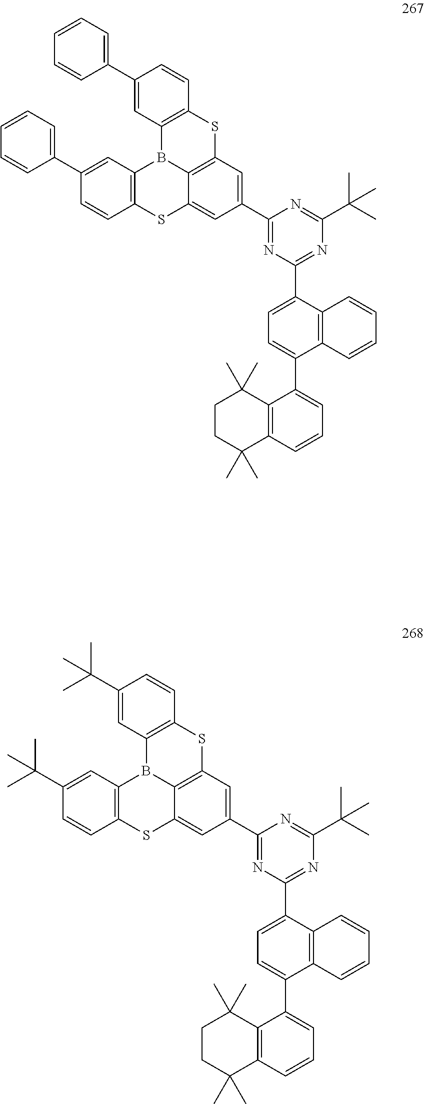 [SMILES: CC(C)(C)c1nc(-c2cc3c4c(c2)Sc2ccc(-c5ccccc5)cc2B4c2cc(-c4ccccc4)ccc2S3)nc(-c2ccc(-c3cccc4c3C(C)(C)CCC4(C)C)c3ccccc23)n1 ; CC(C)(C)c1ccc2c(c1)B1c3cc(C(C)(C)C)ccc3Sc3cc(-c4nc(-c5ccc(-c6cccc7c6C(C)(C)CCC7(C)C)c6ccccc56)nc(C(C)(C)C)n4)cc(c31)S2]

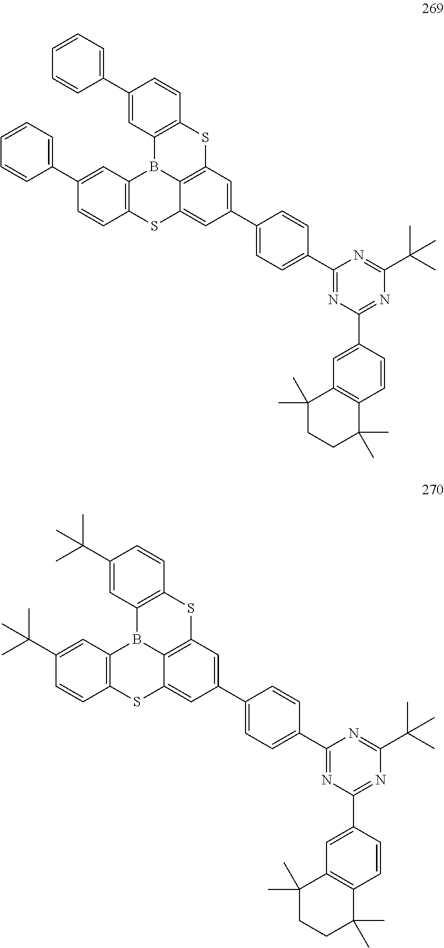

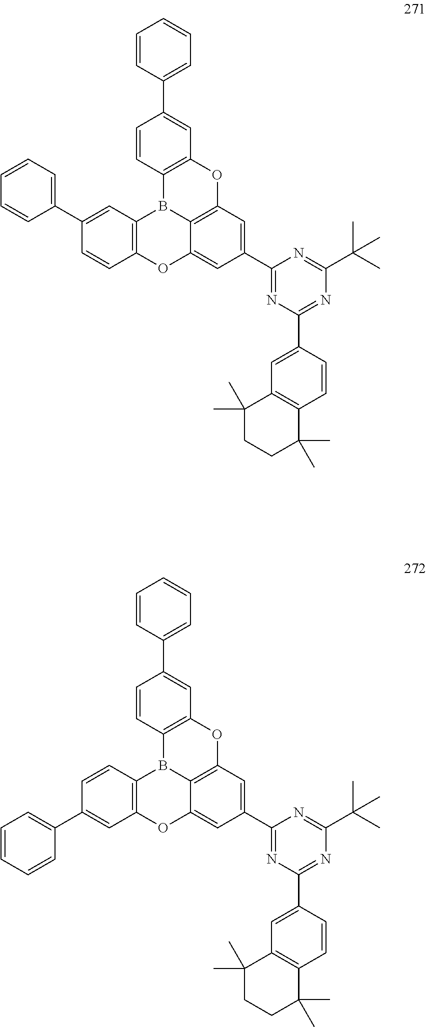 [SMILES: CC(C)(C)c1nc(-c2cc3c4c(c2)Oc2ccc(-c5ccccc5)cc2B4c2ccc(-c4ccccc4)cc2O3)nc(-c2ccc3c(c2)C(C)(C)CCC3(C)C)n1 ; CC(C)(C)c1nc(-c2cc3c4c(c2)Oc2cc(-c5ccccc5)ccc2B4c2ccc(-c4ccccc4)cc2O3)nc(-c2ccc3c(c2)C(C)(C)CCC3(C)C)n1]

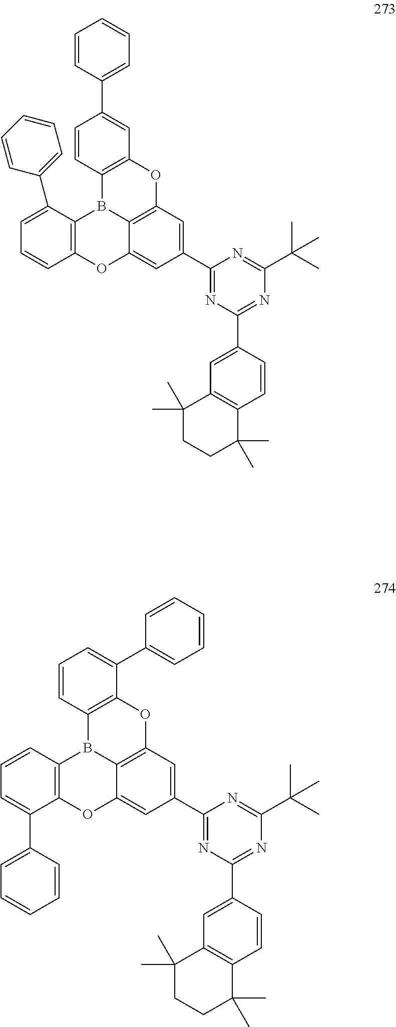 [SMILES: CC(C)(C)c1nc(-c2cc3c4c(c2)Oc2cccc(-c5ccccc5)c2B4c2ccc(-c4ccccc4)cc2O3)nc(-c2ccc3c(c2)C(C)(C)CCC3(C)C)n1 ; CC(C)(C)c1nc(-c2cc3c4c(c2)Oc2c(cccc2-c2ccccc2)B4c2cccc(-c4ccccc4)c2O3)nc(-c2ccc3c(c2)C(C)(C)CCC3(C)C)n1]

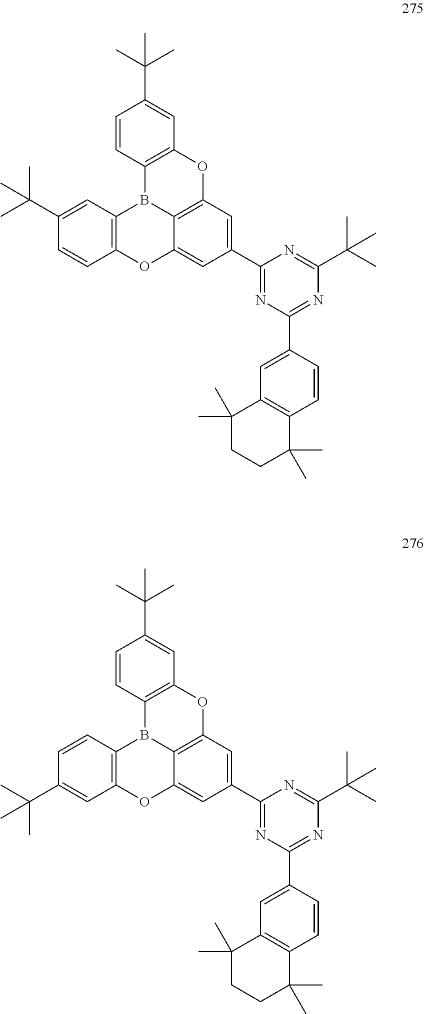

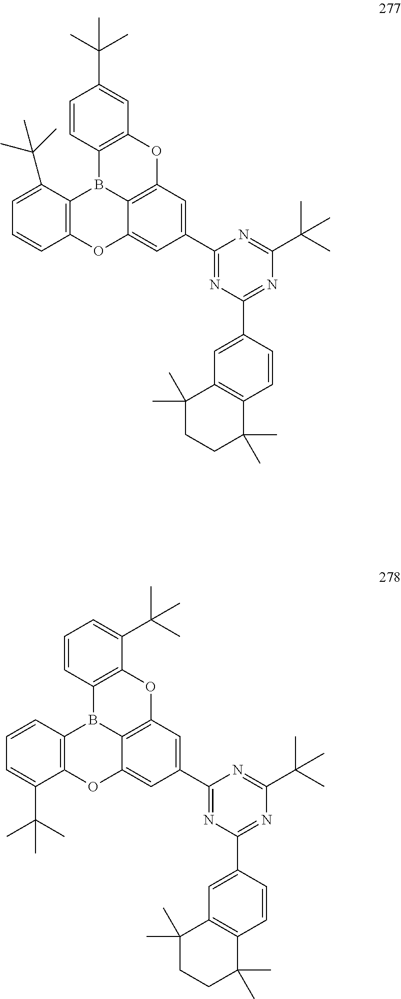 [SMILES: CC(C)(C)c1ccc2c(c1)Oc1cc(-c3nc(-c4ccc5c(c4)C(C)(C)CCC5(C)C)nc(C(C)(C)C)n3)cc3c1B2c1c(cccc1C(C)(C)C)O3 ; CC(C)(C)c1nc(-c2cc3c4c(c2)Oc2c(cccc2C(C)(C)C)B4c2cccc(C(C)(C)C)c2O3)nc(-c2ccc3c(c2)C(C)(C)CCC3(C)C)n1]

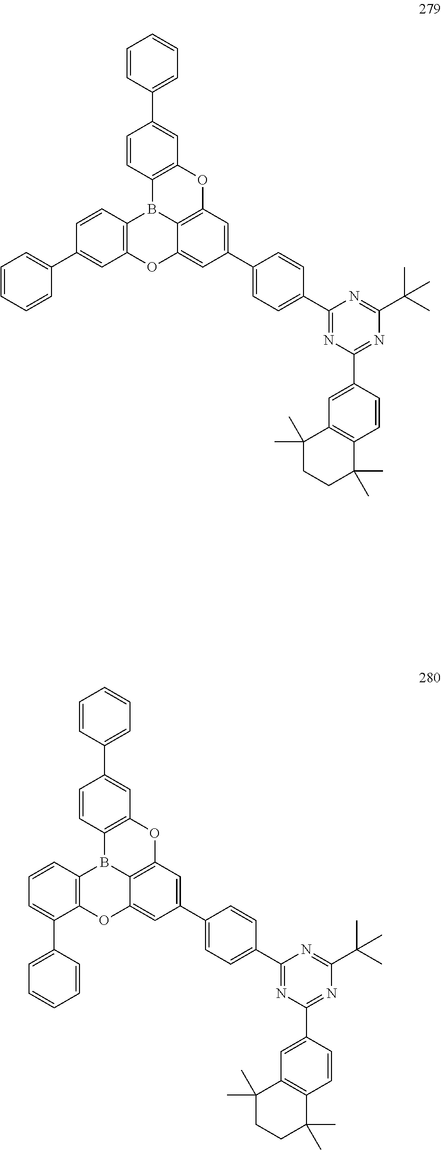 [SMILES: CC(C)(C)c1nc(-c2ccc(-c3cc4c5c(c3)Oc3cc(-c6ccccc6)ccc3B5c3ccc(-c5ccccc5)cc3O4)cc2)nc(-c2ccc3c(c2)C(C)(C)CCC3(C)C)n1 ; CC(C)(C)c1nc(-c2ccc(-c3cc4c5c(c3)Oc3c(cccc3-c3ccccc3)B5c3ccc(-c5ccccc5)cc3O4)cc2)nc(-c2ccc3c(c2)C(C)(C)CCC3(C)C)n1]

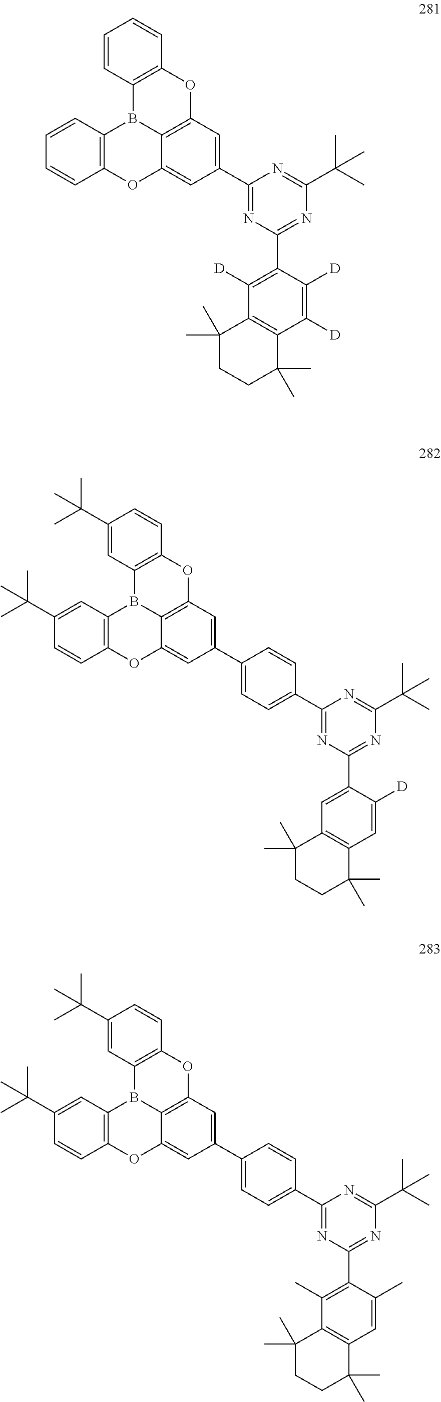

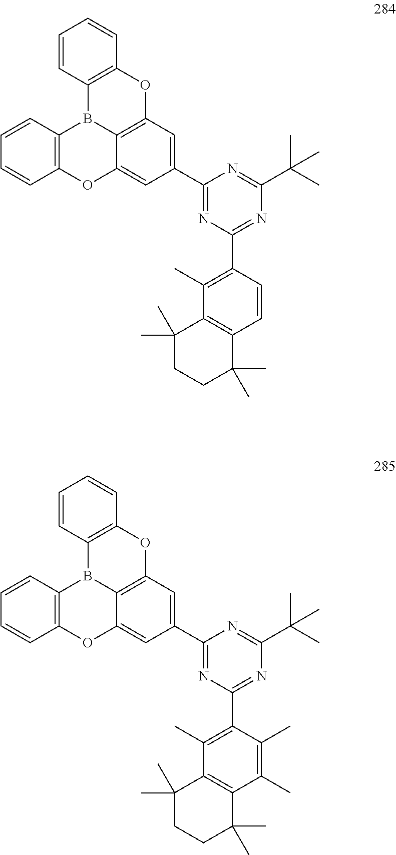 [SMILES: Cc1c(-c2nc(-c3cc4c5c(c3)Oc3ccccc3B5c3ccccc3O4)nc(C(C)(C)C)n2)ccc2c1C(C)(C)CCC2(C)C ; Cc1c(C)c2c(c(C)c1-c1nc(-c3cc4c5c(c3)Oc3ccccc3B5c3ccccc3O4)nc(C(C)(C)C)n1)C(C)(C)CCC2(C)C]

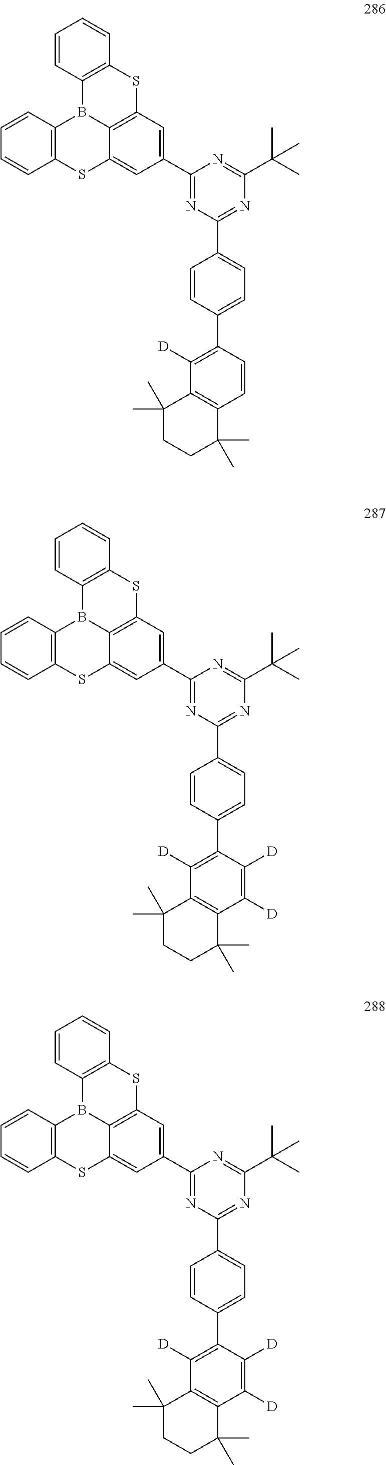 [SMILES: [2H]c1c(-c2ccc(-c3nc(-c4cc5c6c(c4)Sc4ccccc4B6c4ccccc4S5)nc(C(C)(C)C)n3)cc2)ccc2c1C(C)(C)CCC2(C)C ; [2H]c1c([2H])c2c(c([2H])c1-c1ccc(-c3nc(-c4cc5c6c(c4)Sc4ccccc4B6c4ccccc4S5)nc(C(C)(C)C)n3)cc1)C(C)(C)CCC2(C)C ; [2H]c1c([2H])c2c(c([2H])c1-c1ccc(-c3nc(-c4cc5c6c(c4)Sc4ccccc4B6c4ccccc4S5)nc(C(C)(C)C)n3)cc1)C(C)(C)CCC2(C)C]

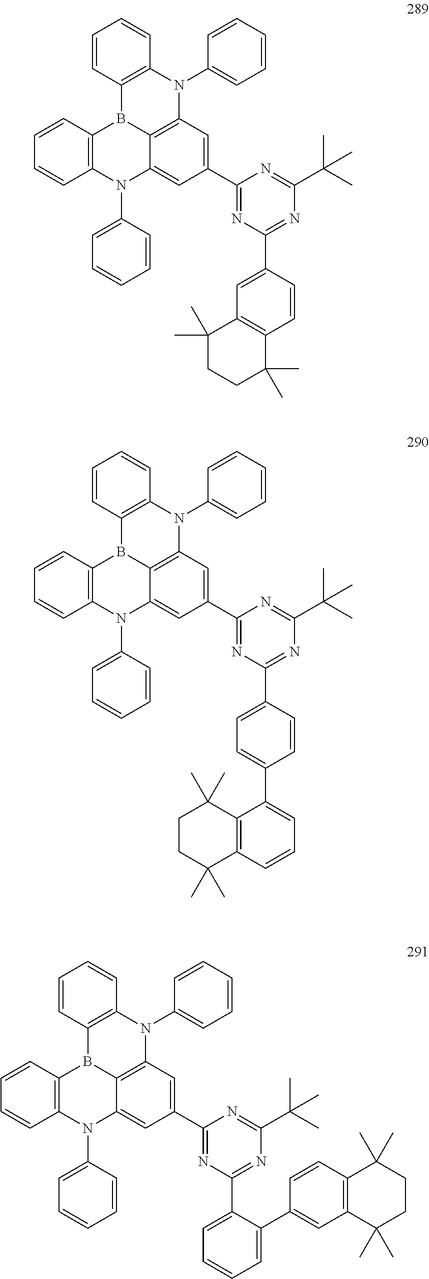 [SMILES: CC(C)(C)c1nc(-c2cc3c4c(c2)N(c2ccccc2)c2ccccc2B4c2ccccc2N3c2ccccc2)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)N(c2ccccc2)c2ccccc2B4c2ccccc2N3c2ccccc2)n1 ; CC(C)(C)c1nc(-c2cc3c4c(c2)N(c2ccccc2)c2ccccc2B4c2ccccc2N3c2ccccc2)nc(-c2ccccc2-c2ccc3c(c2)C(C)(C)CCC3(C)C)n1]

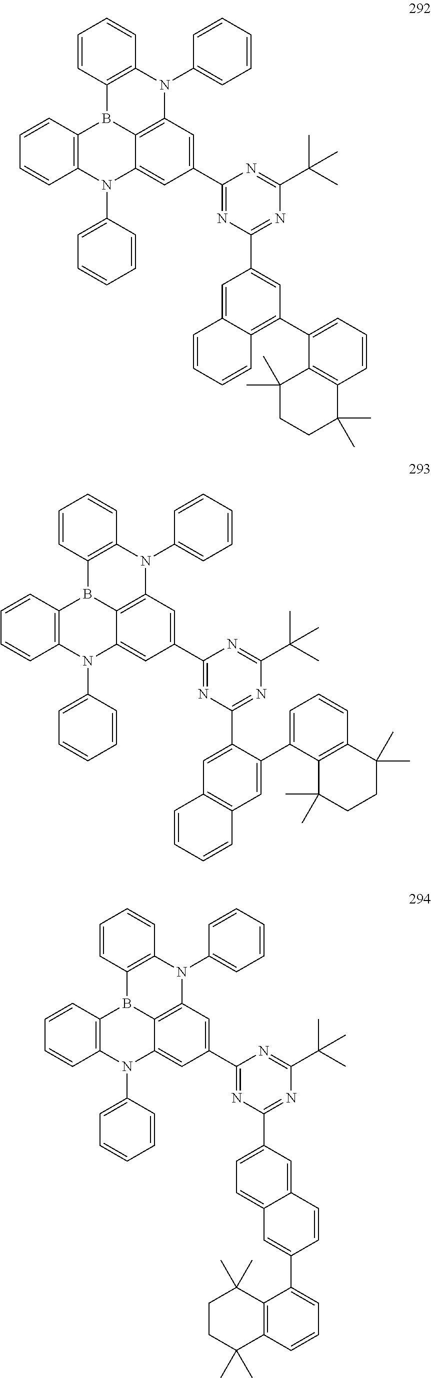 [SMILES: CC(C)(C)c1nc(-c2cc3c4c(c2)N(c2ccccc2)c2ccccc2B4c2ccccc2N3c2ccccc2)nc(-c2cc(-c3cccc4c3C(C)(C)CCC4(C)C)c3ccccc3c2)n1 ; CC(C)(C)c1nc(-c2cc3c4c(c2)N(c2ccccc2)c2ccccc2B4c2ccccc2N3c2ccccc2)nc(-c2cc3ccccc3cc2-c2cccc3c2C(C)(C)CCC3(C)C)n1 ; CC(C)(C)c1nc(-c2cc3c4c(c2)N(c2ccccc2)c2ccccc2B4c2ccccc2N3c2ccccc2)nc(-c2ccc3cc(-c4cccc5c4C(C)(C)CCC5(C)C)ccc3c2)n1]

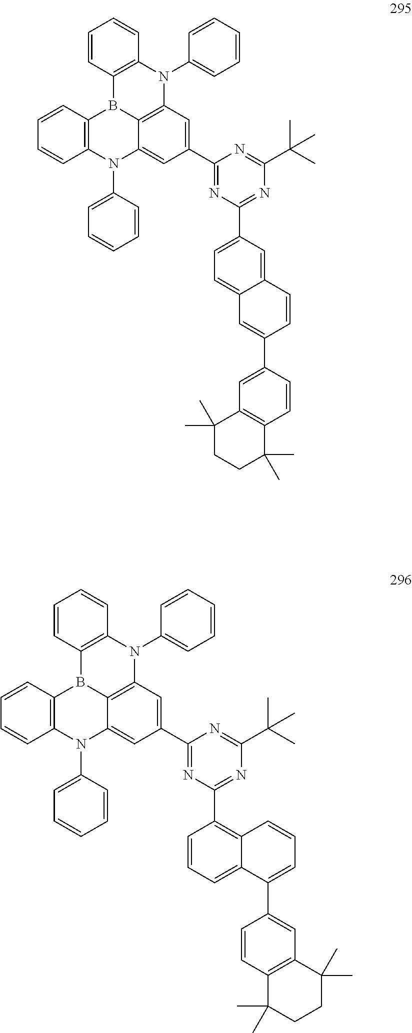 [SMILES: CC(C)(C)c1nc(-c2cc3c4c(c2)N(c2ccccc2)c2ccccc2B4c2ccccc2N3c2ccccc2)nc(-c2ccc3cc(-c4ccc5c(c4)C(C)(C)CCC5(C)C)ccc3c2)n1 ; CC(C)(C)c1nc(-c2cc3c4c(c2)N(c2ccccc2)c2ccccc2B4c2ccccc2N3c2ccccc2)nc(-c2cccc3c(-c4ccc5c(c4)C(C)(C)CCC5(C)C)cccc23)n1]

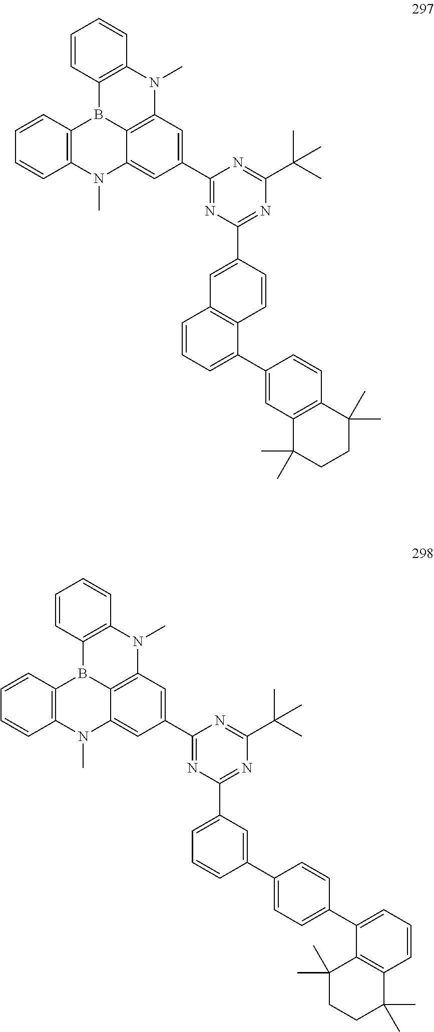 [SMILES: CN1c2ccccc2B2c3ccccc3N(C)c3cc(-c4nc(-c5ccc6c(-c7ccc8c(c7)C(C)(C)CCC8(C)C)cccc6c5)nc(C(C)(C)C)n4)cc1c32 ; CN1c2ccccc2B2c3ccccc3N(C)c3cc(-c4nc(-c5cccc(-c6ccc(-c7cccc8c7C(C)(C)CCC8(C)C)cc6)c5)nc(C(C)(C)C)n4)cc1c32]

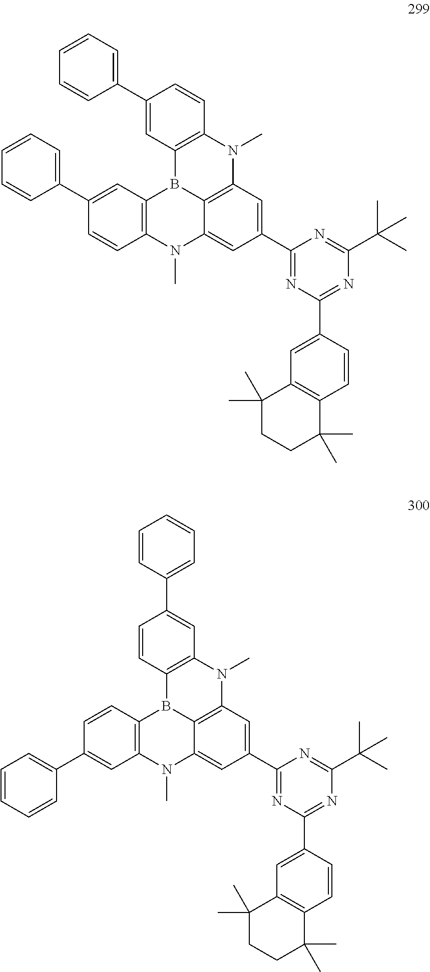 [SMILES: CN1c2ccc(-c3ccccc3)cc2B2c3cc(-c4ccccc4)ccc3N(C)c3cc(-c4nc(-c5ccc6c(c5)C(C)(C)CCC6(C)C)nc(C(C)(C)C)n4)cc1c32 ; CN1c2cc(-c3ccccc3)ccc2B2c3ccc(-c4ccccc4)cc3N(C)c3cc(-c4nc(-c5ccc6c(c5)C(C)(C)CCC6(C)C)nc(C(C)(C)C)n4)cc1c32]

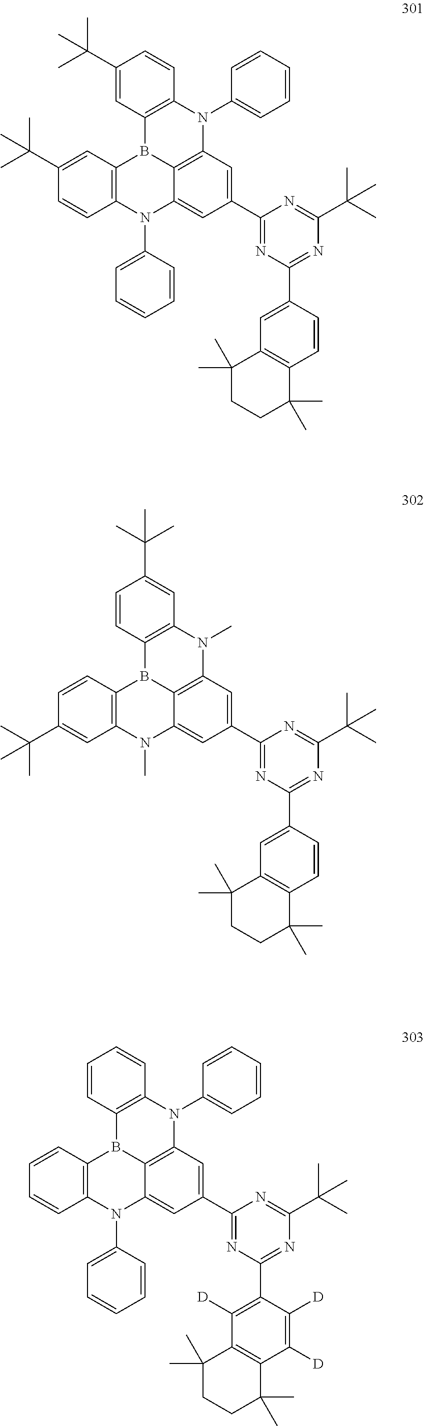

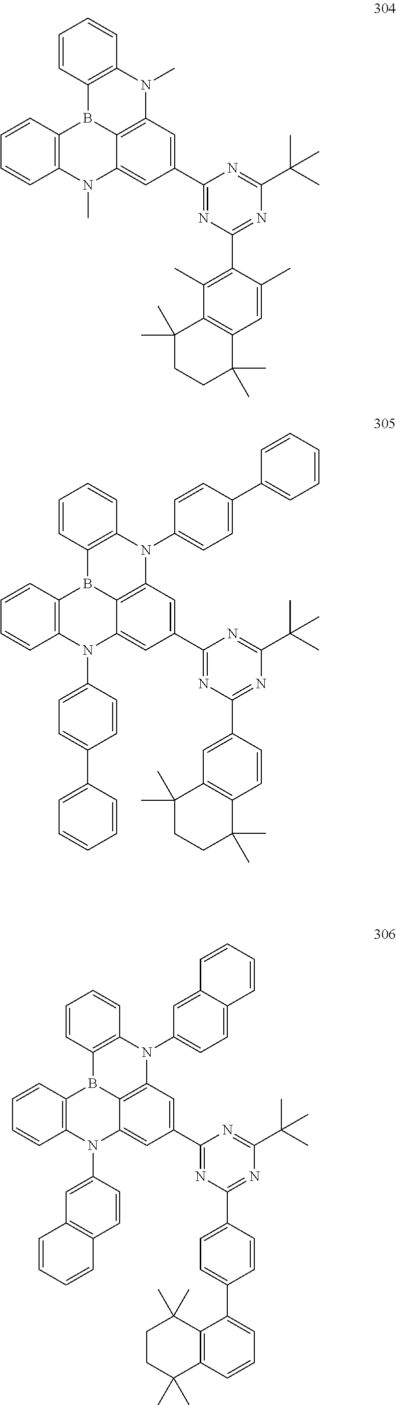 [SMILES: Cc1cc2c(c(C)c1-c1nc(-c3cc4c5c(c3)N(C)c3ccccc3B5c3ccccc3N4C)nc(C(C)(C)C)n1)C(C)(C)CCC2(C)C ; CC(C)(C)c1nc(-c2cc3c4c(c2)N(c2ccc(-c5ccccc5)cc2)c2ccccc2B4c2ccccc2N3c2ccc(-c3ccccc3)cc2)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)N(c2ccc5ccccc5c2)c2ccccc2B4c2ccccc2N3c2ccc3ccccc3c2)n1]

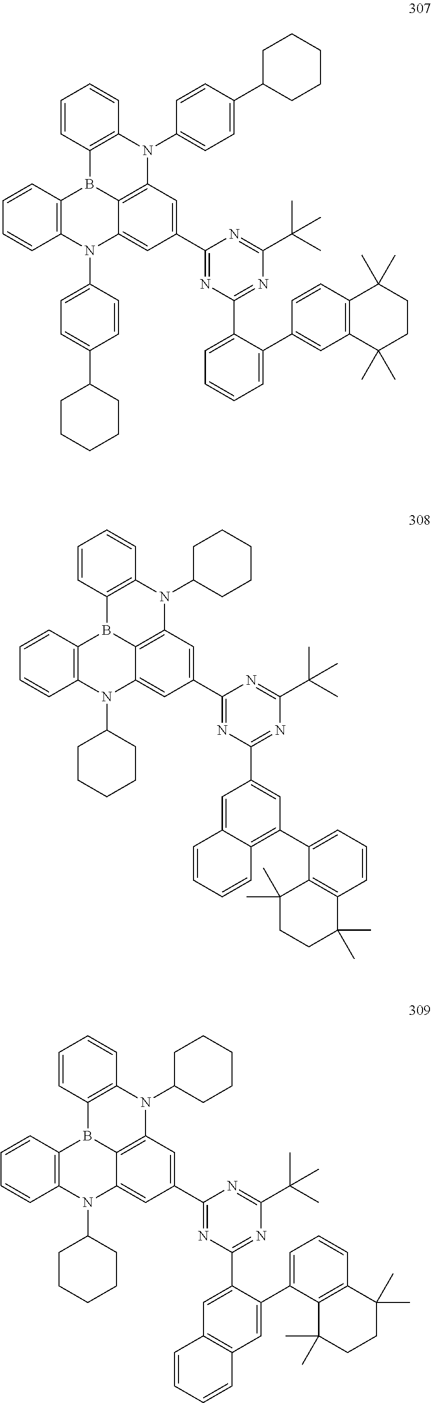 [SMILES: CC(C)(C)c1nc(-c2cc3c4c(c2)N(c2ccc(C5CCCCC5)cc2)c2ccccc2B4c2ccccc2N3c2ccc(C3CCCCC3)cc2)nc(-c2ccccc2-c2ccc3c(c2)C(C)(C)CCC3(C)C)n1 ; CC(C)(C)c1nc(-c2cc3c4c(c2)N(C2CCCCC2)c2ccccc2B4c2ccccc2N3C2CCCCC2)nc(-c2cc(-c3cccc4c3C(C)(C)CCC4(C)C)c3ccccc3c2)n1 ; CC(C)(C)c1nc(-c2cc3c4c(c2)N(C2CCCCC2)c2ccccc2B4c2ccccc2N3C2CCCCC2)nc(-c2cc3ccccc3cc2-c2cccc3c2C(C)(C)CCC3(C)C)n1]

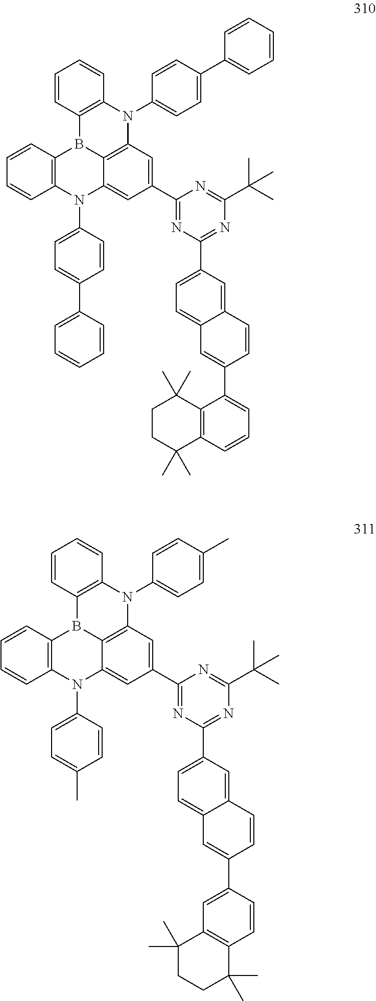 [SMILES: CC(C)(C)c1nc(-c2cc3c4c(c2)N(c2ccc(-c5ccccc5)cc2)c2ccccc2B4c2ccccc2N3c2ccc(-c3ccccc3)cc2)nc(-c2ccc3cc(-c4cccc5c4C(C)(C)CCC5(C)C)ccc3c2)n1 ; Cc1ccc(N2c3ccccc3B3c4ccccc4N(c4ccc(C)cc4)c4cc(-c5nc(-c6ccc7cc(-c8ccc9c(c8)C(C)(C)CCC9(C)C)ccc7c6)nc(C(C)(C)C)n5)cc2c43)cc1]

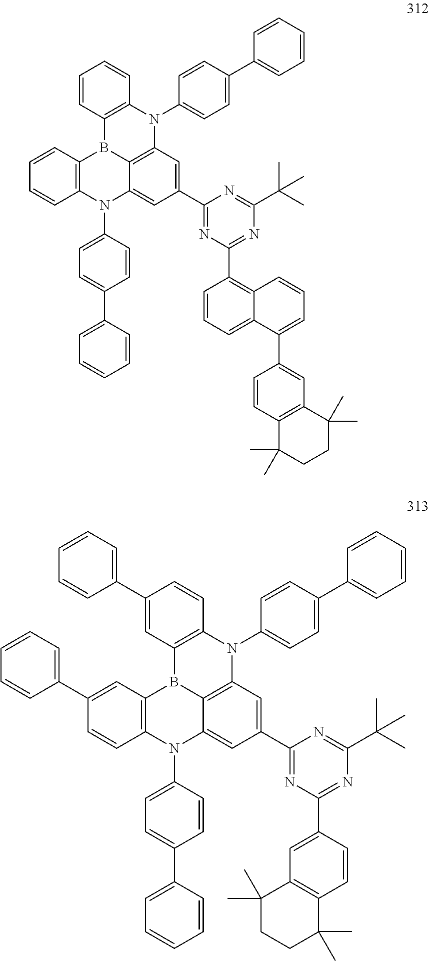 [SMILES: CC(C)(C)c1nc(-c2cc3c4c(c2)N(c2ccc(-c5ccccc5)cc2)c2ccccc2B4c2ccccc2N3c2ccc(-c3ccccc3)cc2)nc(-c2cccc3c(-c4ccc5c(c4)C(C)(C)CCC5(C)C)cccc23)n1 ; CC(C)(C)c1nc(-c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)nc(-c2ccc3c(c2)C(C)(C)CCC3(C)C)n1]

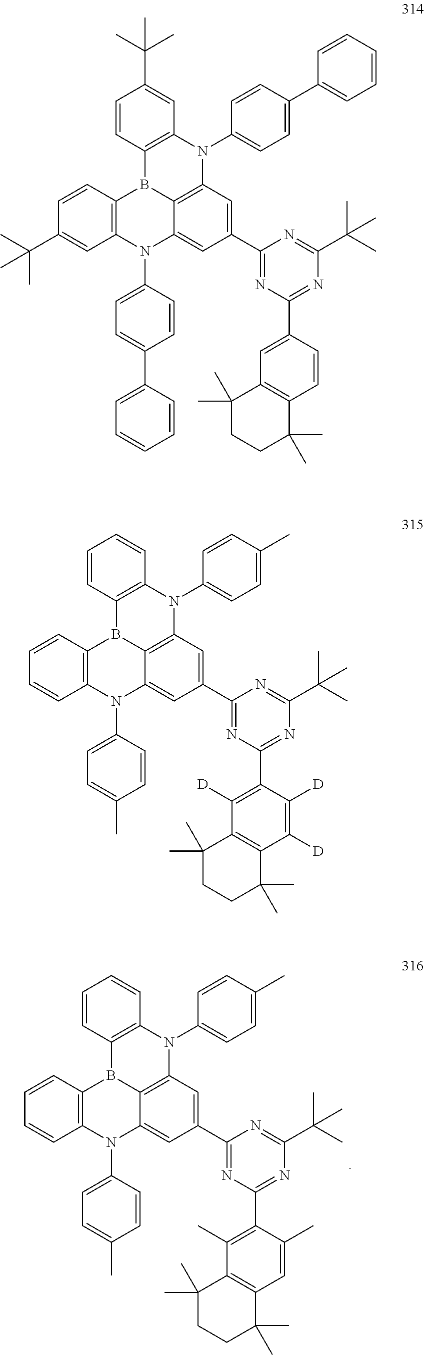 [SMILES: CC(C)(C)c1ccc2c(c1)N(c1ccc(-c3ccccc3)cc1)c1cc(-c3nc(-c4ccc5c(c4)C(C)(C)CCC5(C)C)nc(C(C)(C)C)n3)cc3c1B2c1ccc(C(C)(C)C)cc1N3c1ccc(-c2ccccc2)cc1 ; [2H]c1c([2H])c2c(c([2H])c1-c1nc(-c3cc4c5c(c3)N(c3ccc(C)cc3)c3ccccc3B5c3ccccc3N4c3ccc(C)cc3)nc(C(C)(C)C)n1)C(C)(C)CCC2(C)C ; Cc1ccc(N2c3ccccc3B3c4ccccc4N(c4ccc(C)cc4)c4cc(-c5nc(-c6c(C)cc7c(c6C)C(C)(C)CCC7(C)C)nc(C(C)(C)C)n5)cc2c43)cc1]

The heterocyclic compound represented by Formula 1 satisfies a structure in which a triazine is substituted with (i) a heterocycle including a boron atom and (ii) Ani as the group represented by Formula 2. Due to this structure, the heterocyclic compound may have excellent or suitable charge transportability, a narrow full width at half maximum of emission, high color purity, and high luminescence efficiency.

Accordingly, if (e.g., when) the heterocyclic compound represented by Formula 1 is applied to an organic light-emitting device, the organic light-emitting device may have lowered driving voltage and improved characteristics in terms of color purity, luminescence efficiency, and lifespan. For example, if (e.g., when) an emission layer of an organic light-emitting device includes the heterocyclic compound represented by Formula 1, the organic light-emitting device with low driving voltage, high color purity, high luminescence efficiency, and long lifespan may be implemented.

For example, the heterocyclic compound represented by Formula 1, which includes a triazine group substituted with a boron-containing heterocycle and Ar₁, exhibits excellent charge transportability, narrow emission width, high color purity, and high luminescence efficiency. When applied to an organic light-emitting device, this compound can lower driving voltage and enhance color purity, luminescence efficiency, and lifespan. Specifically, an emission layer containing this compound may result in a light-emitting device with low driving voltage, high color purity, high luminescence efficiency, and long lifespan.

Synthesis methods of the heterocyclic compound represented by Formula 1 may be recognizable by one of ordinary skill in the art by referring to Examples provided herein.

According to one or more embodiments of the present disclosure, an organic light-emitting device includes: a first electrode; a second electrode opposite to the first electrode; an interlayer between the first electrode and the second electrode and including an emission layer; and the heterocyclic compound represented by Formula 1.

In one or more embodiments,
the first electrode of the organic light-emitting device may be an anode,
the second electrode of the organic light-emitting device may be a cathode, and
the interlayer may further include a hole transport region between the first electrode and the emission layer and an electron transport region between the emission layer and the second electrode,
wherein the hole transport region may include a hole injection layer, a hole transport layer, a buffer layer, an emission auxiliary layer, an electron blocking layer, or any combination thereof, and
the electron transport region may include a hole blocking layer, an electron transport layer, an electron injection layer, or any combination thereof.

In one or more embodiments, the electron transport region may include the heterocyclic compound represented by Formula 1.

For example, the hole blocking layer, the electron transport layer, the electron injection layer, or any combination thereof included in the electron transport region may include the heterocyclic compound.

In one or more embodiments, the emission layer may include the heterocyclic compound represented by Formula 1.

In one or more embodiments, the emission layer of the organic light-emitting device may further include a dopant and a host, and the dopant may include the heterocyclic compound represented by Formula 1. For example, the heterocyclic compound may act as a dopant. In one or more embodiments, the emission layer may be to emit blue light. The blue light may have, for example, a maximum emission wavelength (e.g., the wavelength of maximum emission intensity) in a range of about 400 nanometers (nm) to about 490 nm. In one or more embodiments, the emission layer may be to emit green light. The green light may have, for example, a maximum emission wavelength in a range of about 490 nm to about 570 nm. In one or more embodiments, the emission layer may be to emit red light. The red light may have, for example, a maximum emission wavelength in a range of about 600 nm to about 780 nm.

In one or more embodiments, the emission layer may be to emit deep blue light having a maximum emission wavelength in a range of about 410 nm to about 465 nm.

In one or more embodiments, the host may include a first host compound and a second host compound.

In one or more embodiments, the first host compound may be a hole-transporting host.

In one or more embodiments, the second host compound may be an electron-transporting host.

In one or more embodiments, the host may be understood by referring to the description of the host described herein.

In one or more embodiments, the dopant may be understood by referring to the description of the dopant described herein.

In one or more embodiments, the dopant may be a boron-containing compound. In one or more embodiments, the boron-containing compound may be the heterocyclic compound represented by Formula 1, or may be a compound represented by Formula 511 in which Y₅₃ is B, which will be described later.

In one or more embodiments, the emission layer may further include a sensitizer.

The organic light-emitting device including the heterocyclic compound represented by Formula 1 may have high color purity, high luminescence efficiency, low driving voltage, and long lifespan characteristics.

In one or more embodiments, the emission layer may be to emit blue light. In one or more embodiments, the emission layer may be to emit blue light having a maximum emission wavelength in a range of about 390 nm to about 500 nm, about 410 nm to about 500 nm, about 400 nm to about 490 nm, about 410 nm to about 490 nm, about 430 nm to about 480 nm, about 440 nm to about 475 nm, or about 455 nm to about 470 nm.

In one or more embodiments, the emission layer may have color purity with a CIEx coordinate for bottom emission in a range of about 0.12 to about 0.15 or about 0.13 to about 0.14 and a CIEy coordinate for bottom emission in a range of about 0.06 to about 0.25, about 0.10 to about 0.20, or about 0.13 to about 0.20.

The term “interlayer” as used herein refers to a single layer and/or all of multiple layers arranged between the first electrode and the second electrode of the organic light-emitting device.

According to one or more embodiments of the present disclosure, an electronic apparatus includes the organic light-emitting device. The electronic apparatus may further include a thin-film transistor. For example, in one or more embodiments, the electronic apparatus may further include a thin-film transistor including a source electrode and a drain electrode, wherein the first electrode of the organic light-emitting device may be electrically connected to the source electrode or the drain electrode of the thin-film transistor. In one or more embodiments, the electronic apparatus may further include a color filter, a color conversion layer, a touch screen layer, a polarizing layer, or any combination thereof. More details on the electronic apparatus may be referred to the descriptions provided herein.

According to one or more embodiments of the present disclosure, an electronic equipment (e.g., a consumer product) includes the organic light-emitting device.

For example, the electronic equipment (e.g., the consumer product) may be at least of a flat panel display, a curved display, a computer monitor, a medical monitor, a TV, a billboard, an indoor light, an outdoor light, a signal light, a head-up display, a fully transparent display, a partially transparent display, a flexible display, a rollable display, a foldable display, a stretchable display, a laser printer, a phone, a cell phone, a tablet, a phablet, a personal digital assistant (PDA), a wearable device, a laptop computer, a digital camera, a camcorder, a viewfinder, a micro display, a three-dimension (3D) display, a virtual reality display, an augmented reality display, a vehicle, a video wall including multiple displays tiled together, a theater screen, a stadium screen, a phototherapy device, or a signboard.

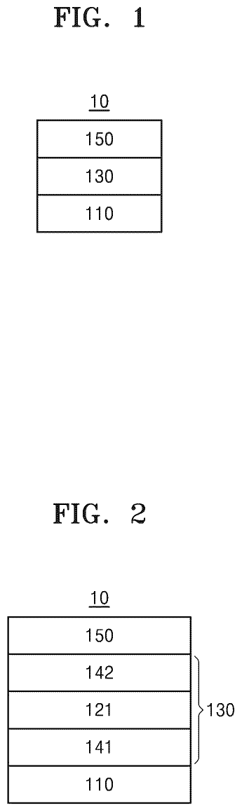

### Descriptions of FIGS. 1 to 4

FIG. 1 is a schematic cross-sectional view of an organic light-emitting device 10 according to one or more embodiments of the present disclosure. The organic light-emitting device 10 includes a first electrode 110, an interlayer 130, and a second electrode 150.

Referring to FIG. 2, in one or more embodiments, the organic light-emitting device 10 may include the first electrode 110, the interlayer 130, and the second electrode 150, wherein the interlayer 130 includes: m emitting units; and (m−1) charge generation units between adjacent emitting units among the m emitting units, m may be an integer of 2 or more. At least one of the m emitting units may comprise an electron transport region. For example, in one or more embodiments, the m emitting units may include a first emitting unit 141 and a second emitting unit 142, and the (m−1) charge generation unit may include a first charge generation unit 121.

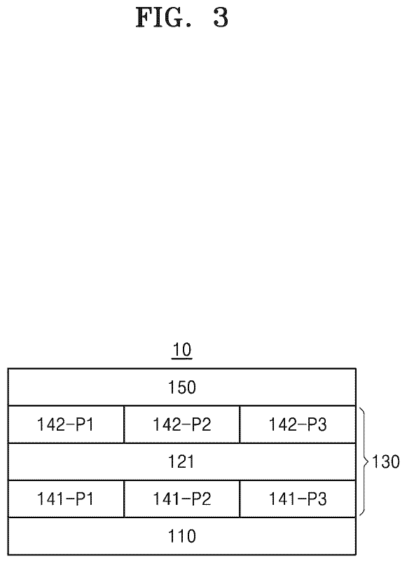

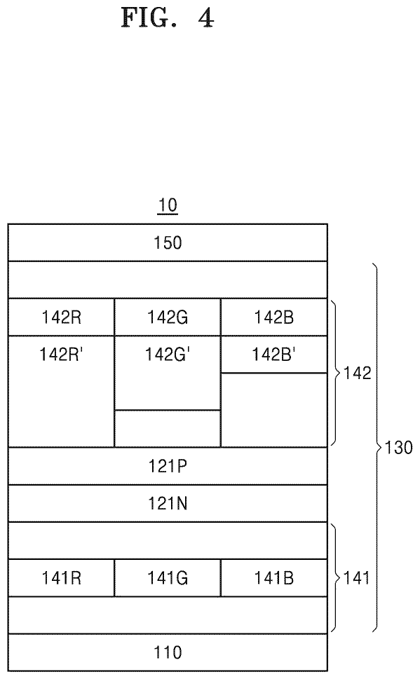

Referring to FIGS. 3 and 4, in one or more embodiments, in the organic light-emitting device 10, the first emitting unit 141 may include: a first red subpixel 141-P1 including a first red emission layer 141R; a first green subpixel 141-P2 including a green emission layer 141G; and a first blue subpixel 141-P3 including a first blue emission layer 141B, and the second emitting unit 142 may include: a second red subpixel 142-P1 including a second red emission layer 142R; a second green subpixel 142-P2 including a second green emission layer 142G; and a second blue subpixel 142-P3 including a second blue emission layer 142B. At least one of the first emitting unit 141 and the second emitting unit 142 comprises the electron transport region.

In addition, additional layers may be arranged on each subpixel. For example, referring to FIG. 4, in one or more embodiments, a red emission auxiliary layer 142R′ may be arranged on a second red subpixel area, a green emission auxiliary layer 142G′ may be arranged on a second green subpixel area, and a blue emission auxiliary layer 142B′ may be arranged on a second blue subpixel area.

In one or more embodiments, a first charge generation unit may be arranged between the first emitting unit 141 and the second emitting unit 142, wherein the first charge generation unit may include a first p-type (kind) charge (e.g., P-charge) generation layer 121P and a first n-type (kind) charge (e.g., N-charge) generation layer 121N.

Here, the positions and arrangements of the first emitting unit 141, the second emitting unit 142, and the first charge generation unit 121 are not limited to those shown in FIGS. 1 to 4. For example, the positions and arrangements of the first emitting unit 141 and the second emitting unit 142 may be switched.

In addition to one or more embodiments shown in FIGS. 1 to 4, other layers may be additionally arranged between the aforementioned layers. For example, in one or more embodiments, a red emission auxiliary layer 141R′ may be arranged on the first red subpixel 141-P1, a green emission auxiliary layer 141G′ may be arranged on the first green subpixel 141-P2, and a blue emission auxiliary layer 1411B′ may be arranged on the first blue subpixel 141-P3.

In one or more embodiments, a first hole transport region may be additionally provided between the first electrode 110 and the first emitting unit 141, wherein the first hole transport region may include at least one of a hole injection layer, a hole transport layer, a buffer layer, an emission auxiliary layer, or an electron blocking layer.

In one or more embodiments, a first electron transport region may be additionally provided between the first emitting unit 141 and the first charge generation unit 121, wherein the first electron transport region may include at least one of a hole blocking layer, an electron transport layer, or an electron injection layer.

In one or more embodiments, a second hole transport region may be additionally provided between the first charge generation unit 121 and the second emitting unit 142, wherein the second hole transport region may include at least one of a hole injection layer, a hole transport layer, a buffer layer, an emission auxiliary layer, or an electron blocking layer.

In one or more embodiments, a second electron transport region may be additionally provided between the second emitting unit 142 and the second electrode 150, wherein the second electron transport region may include at least one of a hole blocking layer, an electron transport layer, or an electron injection layer.

In one or more embodiments, at least one of the first electron transport region or the second electron transport region may include the heterocyclic compound represented by Formula 1. In one or more embodiments, at least three of the layers included in the interlayer of the organic light-emitting device may include a boron-containing compound, e.g., the heterocyclic compound. The boron-containing compound may be the heterocyclic compound represented by Formula 1, or the boron-containing compound may be a compound other than the heterocyclic compound represented by Formula 1.

For example, in one or more embodiments, in the organic light-emitting device, at least one of the first electron transport region or the second electron transport region may include the heterocyclic compound, and at least one of the first blue emission layer or the second blue emission layer may include the boron-containing compound, e.g., the heterocyclic compound.

Hereinafter, a structure of the organic light-emitting device 10 according to one or more embodiments and a method of manufacturing the light-emitting device 10 may be described in more detail with reference to FIGS. 1 to 4.

### First Electrode 110

In FIGS. 1 to 4, according to one or more embodiments, a substrate may be additionally provided and arranged under the first electrode 110 and/or on the second electrode 150. As the substrate, a glass substrate or a plastic substrate may be used. In one or more embodiments, the substrate may be a flexible substrate and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. In one or more embodiments, if (e.g., when) the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, if (e.g., when) the first electrode 110 is a transflective electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multilayer structure including a plurality of layers. In one or more embodiments, the first electrode 110 may have a three-layer structure of ITO/Ag/ITO.

### Interlayer 130

The interlayer 130 may be arranged above (e.g., on) the first electrode 110. The interlayer 130 includes an emission layer.

The interlayer 130 may further include a hole transport region provided between the first electrode 110 and the emission layer, and an electron transport region provided between the emission layer and the second electrode 150.

In one or more embodiments, the interlayer 130 may further include, in addition to one or more suitable organic materials, a metal-containing compound such as an organometallic compound, an inorganic material such as a quantum dot, and/or the like.

In one or more embodiments, the interlayer 130 may include i) two or more emitting units sequentially stacked between the first electrode 110 and the second electrode 150, and ii) a charge generation layer between adjacent emitting units among the two or more emitting units. When the interlayer 130 includes the two or more emitting units and the charge generation layer as described herein, the organic light-emitting device 10 may be a tandem organic light-emitting device.

### Hole Transport Region in Interlayer 130

The hole transport region may have: i) a single-layer structure including (e.g., consisting of) a single layer including (e.g., consisting of) a single material, ii) a single-layer structure including (e.g., consisting of) a single layer including (e.g., consisting of) a plurality of materials that are different from each other, or iii) a multilayer structure including a plurality of layers including a plurality of materials that are different from each other.

The hole transport region may include a hole injection layer, a hole transport layer, an emission auxiliary layer, an electron blocking layer, or any combination thereof.

For example, in one or more embodiments, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein constituent layers in each structure are sequentially stacked from the first electrode 110 in the stated layer.

In one or more embodiments, the hole transport region may include a compound represented by Formula 201, a compound represented by Formula 202, or any combination thereof:

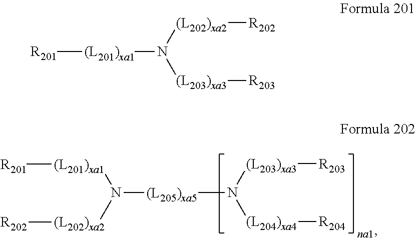

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group (for example, a carbazole group) that is unsubstituted or substituted with at least one R₁₀ₐ (for example, see Compound HT16),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In one or more embodiments, each of Formulae 201 and 202 may include at least one selected from among groups represented by Formulae CY201 to CY217:

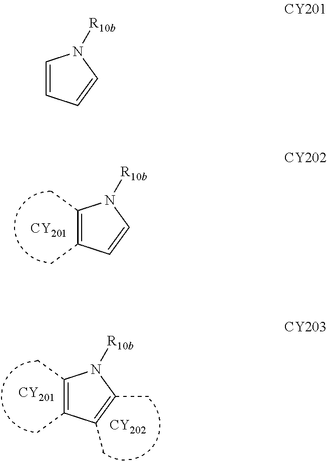

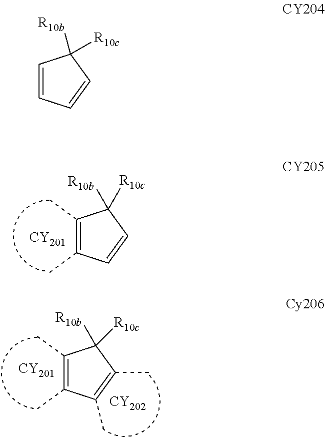

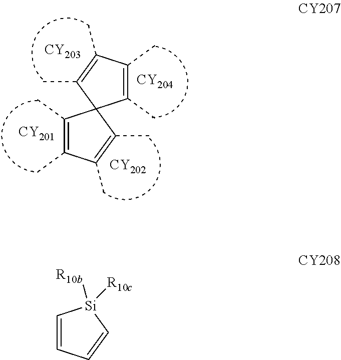

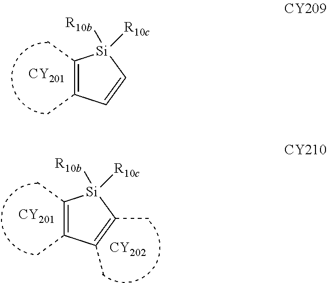

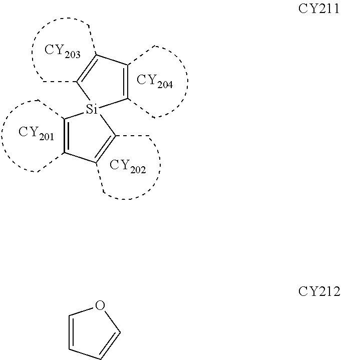

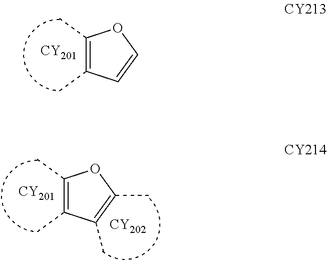

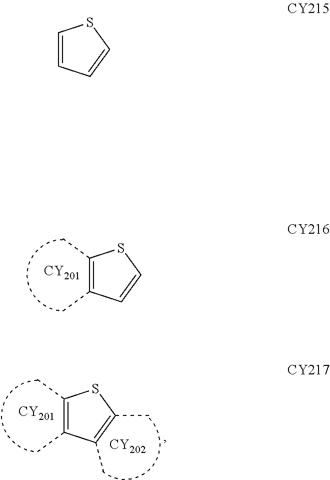

wherein, in Formulae CY201 to CY217, R_{10b} and R_{10c} may each be the same as described with respect to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY₂₀₁ to ring CY₂₀₄ may each independently be a benzene group, a naphthalene group, a phenanthrene group, or an anthracene group.

In one or more embodiments, each of Formulae 201 and 202 may include at least one selected from among the groups represented by Formulae CY201 to CY203.

In one or more embodiments, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by any one selected from among Formulae CY201 to CY203, xa2 may be 0, and R₂₀₂ may be a group represented by any one selected from among Formulae CY204 to CY207.

In one or more embodiments, each of Formulae 201 and 202 may not include (e.g., may exclude) any of the groups represented by Formulae CY201 to CY203.

In one or more embodiments, each of Formulae 201 and 202 may not include (e.g., may exclude) any of the groups represented by Formulae CY201 to CY203 and may include at least one selected from among the groups represented by Formulae CY204 to CY217.

In one or more embodiments, each of Formulae 201 and 202 may not include (e.g., may exclude) any of the groups represented by Formulae CY201 to CY217.

In one or more embodiments, the hole transport region may include one of (e.g., one or more selected from among) Compounds HT1 to HT46, 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), N,N′-di(naphthalen-1-yl)-N,N′-diphenyl-benzidine (NPB(NPD)), β-NPB, N,N′-bis(3-methylphenyl)-N,N′-diphenyl-[1,1′-biphenyl]-4,4′-diamine (TPD), Spiro-TPD, Spiro-NPB, methylated NPB, 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

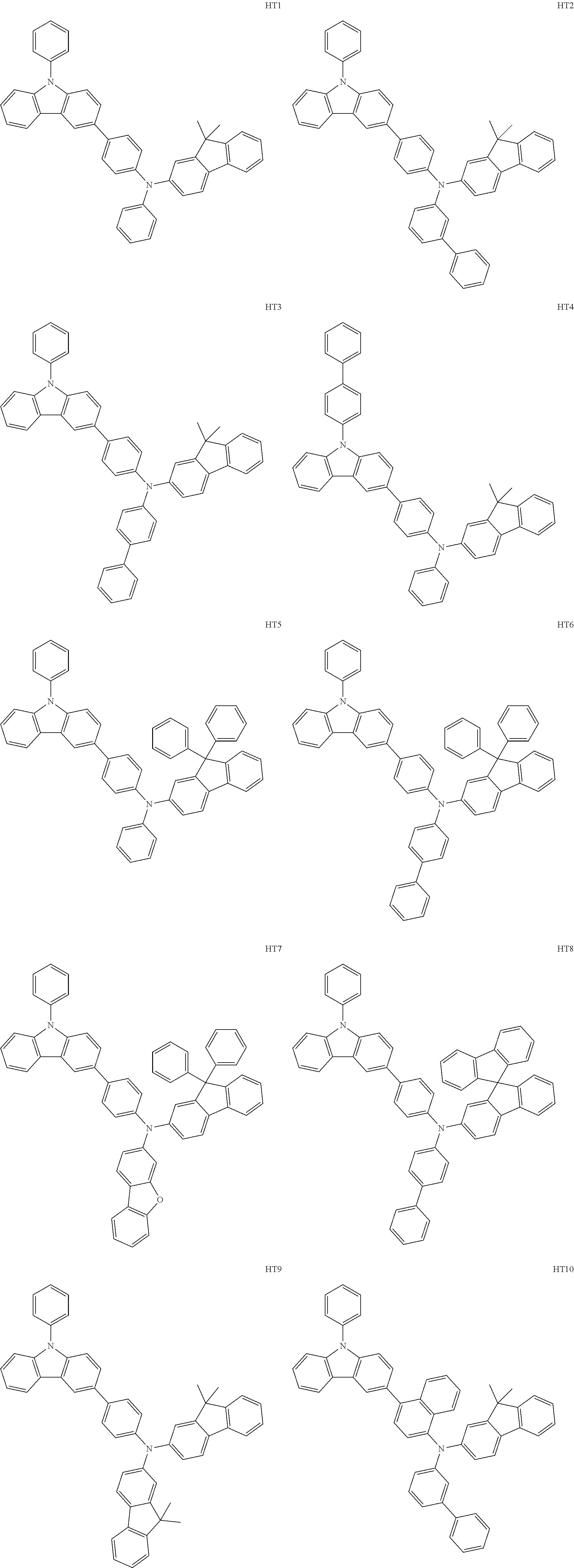

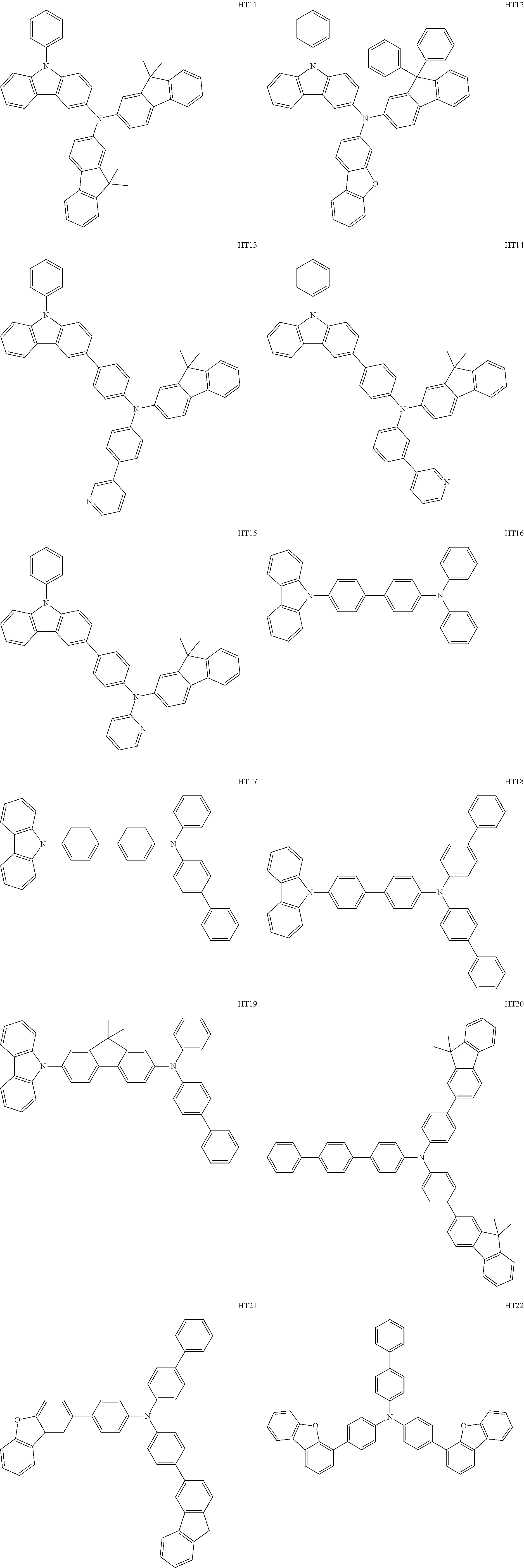

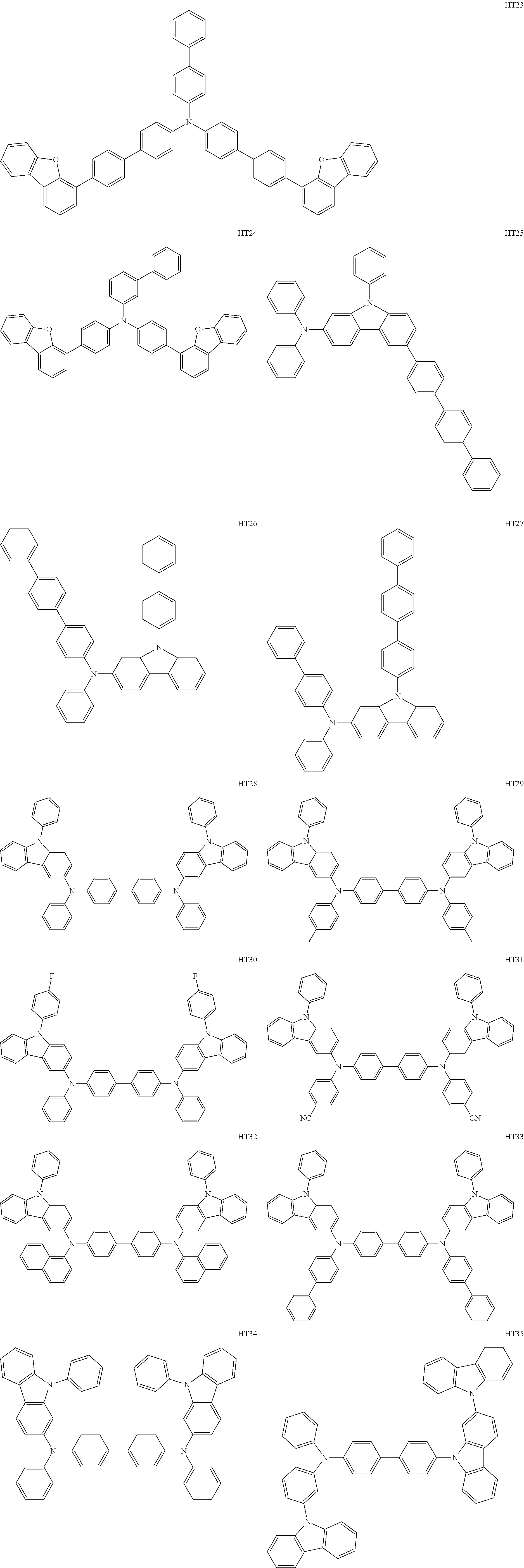

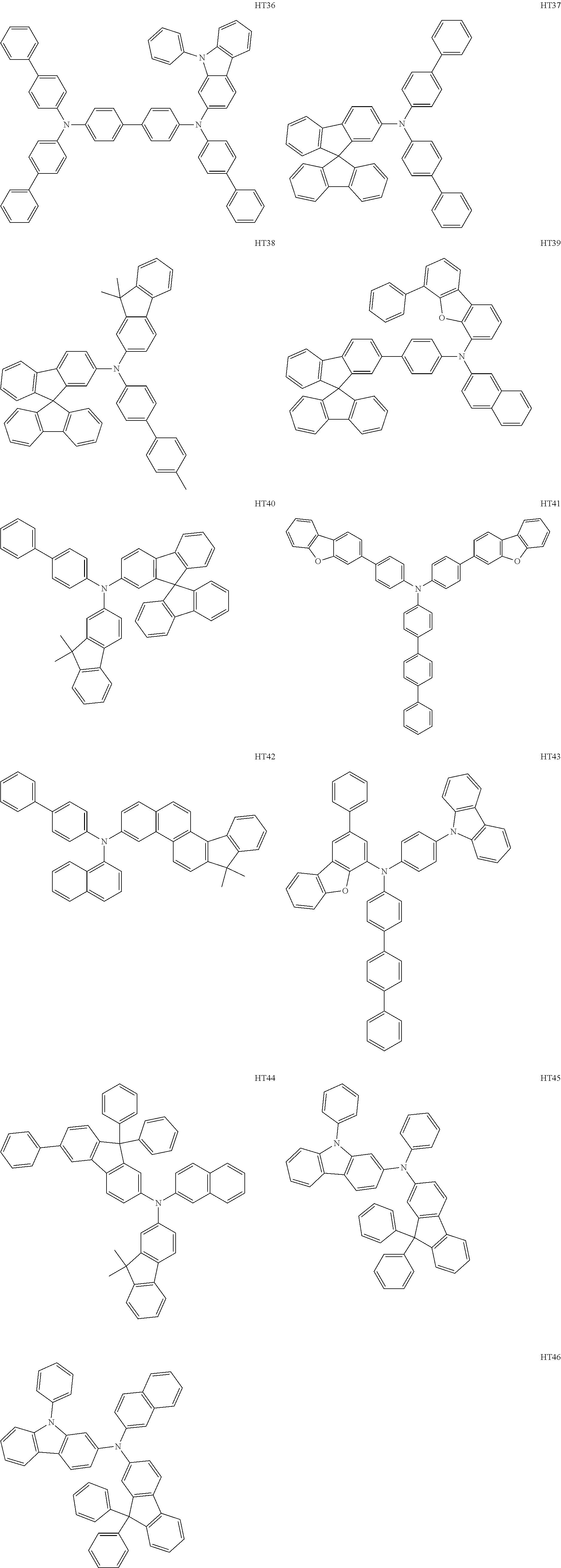

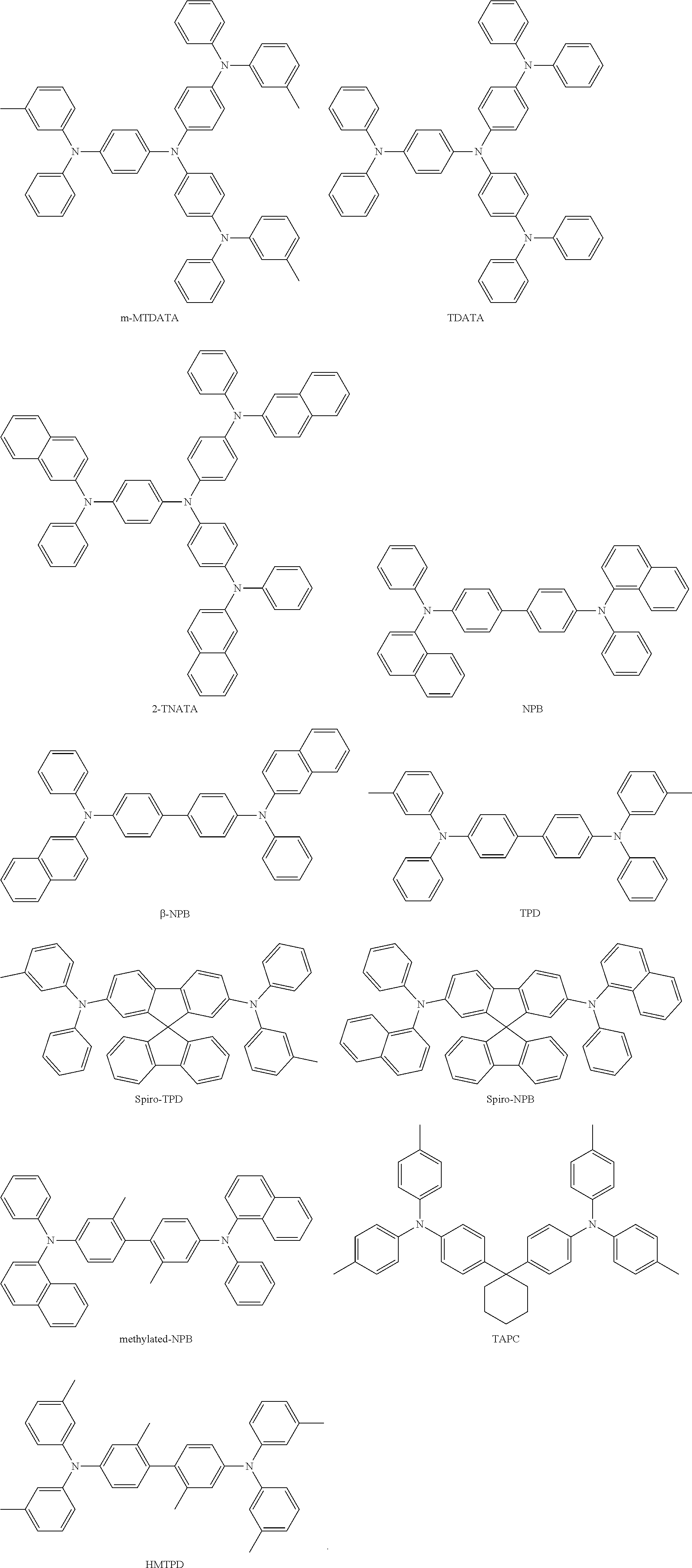

A thickness of the hole transport region may be in a range of about 50 Angstroms (Å) to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within the ranges described above, satisfactory hole transporting characteristics may be obtained without a substantial increase in driving voltage.

The emission auxiliary layer may increase light emission efficiency by compensating for an optical resonance distance according to the wavelength of light emitted by the emission layer, and the electron blocking layer may block the leakage of electrons from the emission layer to the hole transport region. Materials that may be included in the hole transport region may be included in the emission auxiliary layer and the electron blocking layer. A thickness of the emission auxiliary layer may be in a range of about 50 Å to about 9,000 Å, for example, about 50 Å to about 2,000 Å, or about 100 Å to about 1,500 Å, or about 100 Å to about 1,000 Å.

p-Dopant

In one or more embodiments, the hole transport region may further include, in addition to one or more of these aforementioned materials, a charge-generation material for the improvement of conductive properties. The charge-generation material may be uniformly (e.g., substantially uniformly) or non-uniformly dispersed in the hole transport region (for example, in the form of a single layer including (e.g., consisting of) a charge-generation material).

The charge-generation material may be, for example, a p-dopant.

For example, the p-dopant may have a lowest unoccupied molecular orbital (LUMO) energy level of −3.5 eV or less.

In one or more embodiments, the p-dopant may include a quinone derivative, a cyano group-containing compound, a compound including an element EL1 and an element EL2, or any combination thereof.

Non-limiting examples of the quinone derivative may include tetracyanoquinodimethane (TCNQ) and 2,3,5,6-tetrafluoro-7,7,8,8-tetracyanoquinodimethane (F4-TCNQ).

Examples of the cyano group-containing compound may include dipyrazino[2,3-f: 2′,3′-h]quinoxaline-2,3,6,7,10,11-hexacarbonitrile (HAT-CN) and a compound represented by Formula 221:

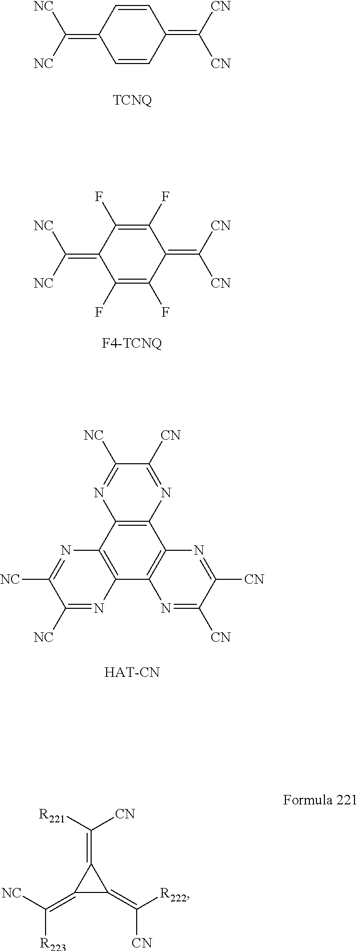

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, the element EL1 may be a metal, a metalloid, or any combination thereof, and the element EL2 may be a non-metal, a metalloid, or any combination thereof.

Non-limiting examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Non-limiting examples of the metalloid may include silicon (Si), antimony (Sb), tellurium (Te), and/or the like.

Non-limiting examples of the non-metal may include oxygen (O), a halogen (e.g., F, Cl, Br, I, and/or the like), and/or the like.

For example, the compound including element EL1 and element EL2 may include metal oxides, metal halides (e.g., metal fluorides, metal chlorides, metal bromides, metal iodides, and/or the like), metalloid halides (e.g., metalloid fluorides, metalloid chlorides, metalloid bromides, metalloid iodides, and/or the like), metal tellurides, or any combination thereof.

Non-limiting examples of the metal oxide may include tungsten oxides (e.g., WO, W₂O₃, WO₂, WO₃, W₂O₅, and/or the like), vanadium oxides (e.g., VO, V₂O₃, VO₂, V₂O₅, and/or the like), molybdenum oxides (e.g., MoO, Mo₂O₃, MoO₂, MoO₃, Mo₂O₅, and/or the like), rhenium oxides (e.g., ReO₃, and/or the like.), and/or the like.

Non-limiting examples of the metal halide may include alkali metal halides, alkaline earth metal halides, transition metal halides, post-transition metal halides, lanthanide metal halides, and/or the like.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Non-limiting examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and/or the like.

Non-limiting examples of the transition metal halide may include a titanium halide (e.g., TiF₄, TiC₄, TiBr₄, TiI₄, and/or the like), a zirconium halide (e.g., ZrF₄, ZrCl₄, ZrBr₄, ZrI₄, and/or the like), a hafnium halide (e.g., HfF₄, HfCl₄, HfBr₄, HfI₄, and/or the like), a vanadium halide (e.g., VF₃, VCl₃, VBr₃, VI₃, and/or the like), a niobium halide (e.g., NbF₃, NbCl₃, NbBr₃, NbI₃, and/or the like), a tantalum halide (e.g., TaF₃, TaCl₃, TaBr₃, TaI₃, and/or the like), a chromium halide (e.g., CrF₃, CrCl₃, CrBr₃, CrI₃, and/or the like), a molybdenum halide (e.g., MoF₃, MoCl₃, MoBr₃, MoI₃, and/or the like), a tungsten halide (e.g., WF₃, WCl₃, WBr₃, WI₃, and/or the like), a manganese halide (e.g., MnF₂, MnCl₂, MnBr₂, MnI₂, and/or the like), a technetium halide (e.g., TcF₂, TcCl₂, TcBr₂, TcI₂, and/or the like), a rhenium halide (e.g., ReF₂, ReCl₂, ReBr₂, ReI₂, and/or the like), an iron(II) halide (e.g., FeF₂, FeCl₂, FeBr₂, FeI₂, and/or the like), a ruthenium halide (e.g., RuF₂, RuCl₂, RuBr₂, RuI₂, and/or the like), an osmium halide (e.g., OsF₂, OsCl₂, OsBr₂, OsI₂, and/or the like), a cobalt halide (e.g., CoF₂, COCl₂, CoBr₂, CoI₂, and/or the like), a rhodium halide (e.g., RhF₂, RhCl₂, RhBr₂, RhI₂, and/or the like), an iridium halide (e.g., IrF₂, IrCl₂, IrBr₂, IrI₂, and/or the like), a nickel halide (e.g., NiF₂, NiCl₂, NiBr₂, NiI₂, and/or the like), a palladium halide (e.g., PdF₂, PdCl₂, PdBr₂, PdI₂, and/or the like), a platinum halide (e.g., PtF₂, PtCl₂, PtBr₂, PtI₂, and/or the like), a copper(I) halide (e.g., CuF, CuCl, CuBr, CuI, and/or the like), a silver halide (e.g., AgF, AgCl, AgBr, AgI, and/or the like), a gold halide (e.g., AuF, AuCl, AuBr, AuI, and/or the like), and/or the like.

Non-limiting examples of the post-transition metal halide may include a zinc halide (for example, ZnF₂, ZnCl₂, ZnBr₂, ZnI₂, and/or the like), an indium halide (for example, InI₃, and/or the like), a tin halide (for example, SnI₂, and/or the like), and/or the like.

Non-limiting examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Non-limiting examples of the metalloid halide may include an antimony halide (e.g., SbCl₅, and/or the like) and/or the like.

Non-limiting examples of the metal telluride may include an alkali metal telluride (for example, Li₂Te, Na₂Te, K₂Te, Rb₂Te, Cs₂Te, and/or the like), an alkaline earth metal telluride (for example, BeTe, MgTe, CaTe, SrTe, BaTe, and/or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (for example, ZnTe, and/or the like), a lanthanide metal telluride (for example, LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the organic light-emitting device 10 is a full-color organic light-emitting device, the emission layer may be patterned into a red emission layer, a green emission layer, and/or a blue emission layer, according to a subpixel. In one or more embodiments, the emission layer may have a stacked structure of two or more layers selected from among a red emission layer, a green emission layer, and a blue emission layer, in which the two or more layers contact each other or are separated from each other, to emit white light (e.g., combined white light). In one or more embodiments, the emission layer may include two or more materials selected from among a red light-emitting material, a green light-emitting material, and a blue light-emitting material, in which the two or more materials are mixed with each other in a single layer, to emit white light (e.g., combined white light).

The emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight, based on 100 parts by weight of the host.

In one or more embodiments, the emission layer may include quantum dots.

In one or more embodiments, the emission layer may include a delayed fluorescence material. The delayed fluorescence material may serve as a host or a dopant in the emission layer.

In one or more embodiments, the emission layer may further include a host, an auxiliary dopant, a sensitizer, a delayed fluorescence material, or any combination thereof, in addition to the aforementioned heterocyclic compound. Each of the host, the auxiliary dopant, the sensitizer, the delayed fluorescence material, or any combination thereof may include at least one deuterium.

For example, in one or more embodiments, the emission layer may include the heterocyclic compound and the host. The host may be different from the heterocyclic compound, and the host may include an electron-transporting compound, a hole-transporting compound, a bipolar compound, or any combination thereof. The host may not include (e.g., may exclude) a (e.g., any) metal. The electron-transporting compound, the hole-transporting compound, and the bipolar compound may be different from each other.

In one or more embodiments, the emission layer may include the heterocyclic compound and the host, and the host may include an electron-transporting compound and a hole-transporting compound.

In one or more embodiments, the electron transporting compound and the hole transporting compound may form an exciplex.

A thickness of the emission layer may be in a range of about 100 Å to about 1,000 Å, for example, about 200 Å to about 600 Å. When the thickness of the emission layer is within the ranges described herein, excellent or suitable luminescence characteristics may be obtained without a substantial increase in driving voltage.

### Host

In one or more embodiments, the host may include a compound represented by Formula 301:

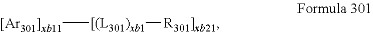

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described with respect to Q₁.

For example, if (e.g., when) xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

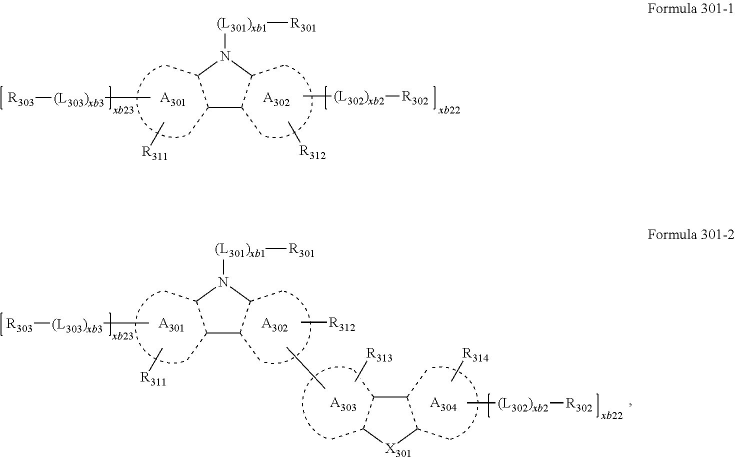

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described elsewhere herein,
L₃₀₂ to L₃₀₄ may each independently be the same as described with respect to L₃₀₁,
xb2 to xb4 may each independently be the same as described with respect to xb1, and
R₃₀₂ to R₃₀₅ and R₃₁₁ to R₃₁₄ may each independently be the same as described with respect to R₃₀₁.

In one or more embodiments, the host may include an alkaline earth metal complex, a post-transition metal complex, or any combination thereof. In one or more embodiments, the host may include a Be complex (e.g., Compound H55), an Mg complex, a Zn complex, or any combination thereof.

In one or more embodiments, the host may include: one of (e.g., be any one or include one or more selected from among) Compounds H1 to H124; 9,10-di(2-naphthyl)anthracene (ADN); 2-methyl-9,10-bis(naphthalen-2-yl)anthracene (MADN); 9,10-di(2-naphthyl)-2-t-butyl-anthracene (TBADN); 4,4′-bis(N-carbazolyl)-1,1′-biphenyl (CBP); 1,3-di(carbazol-9-yl)benzene (mCP); 1,3,5-tri(carbazol-9-yl)benzene (TCP); or any combination thereof:

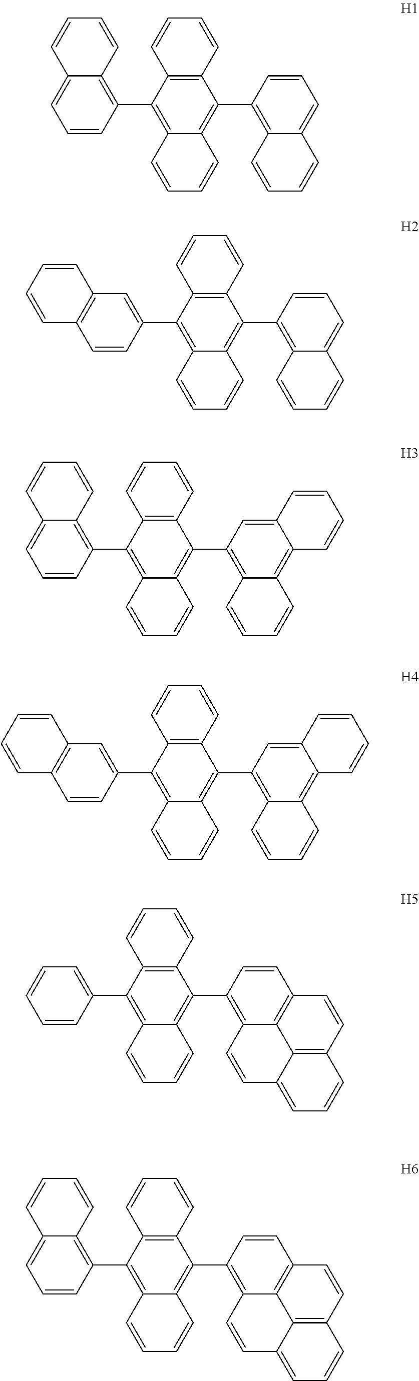

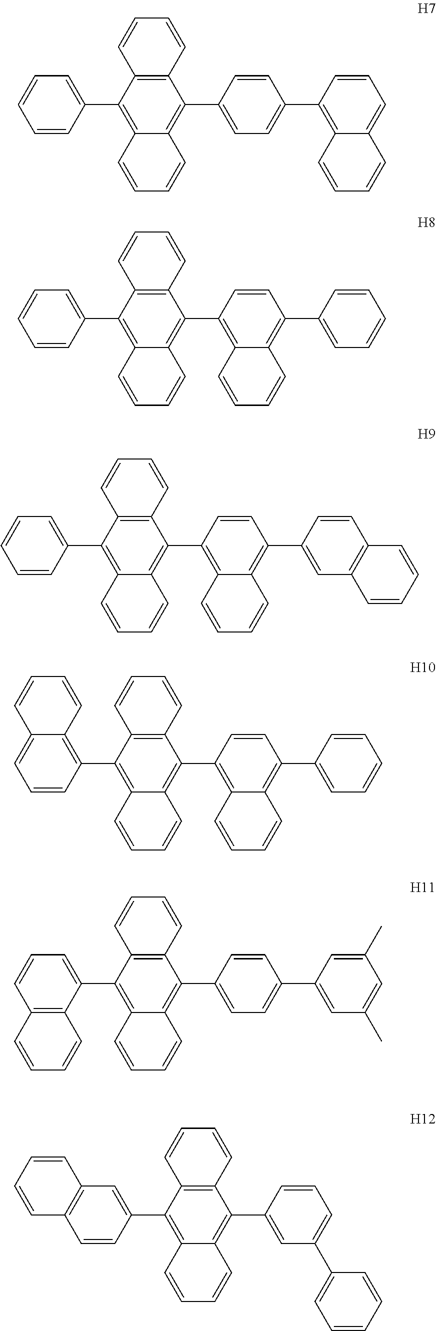

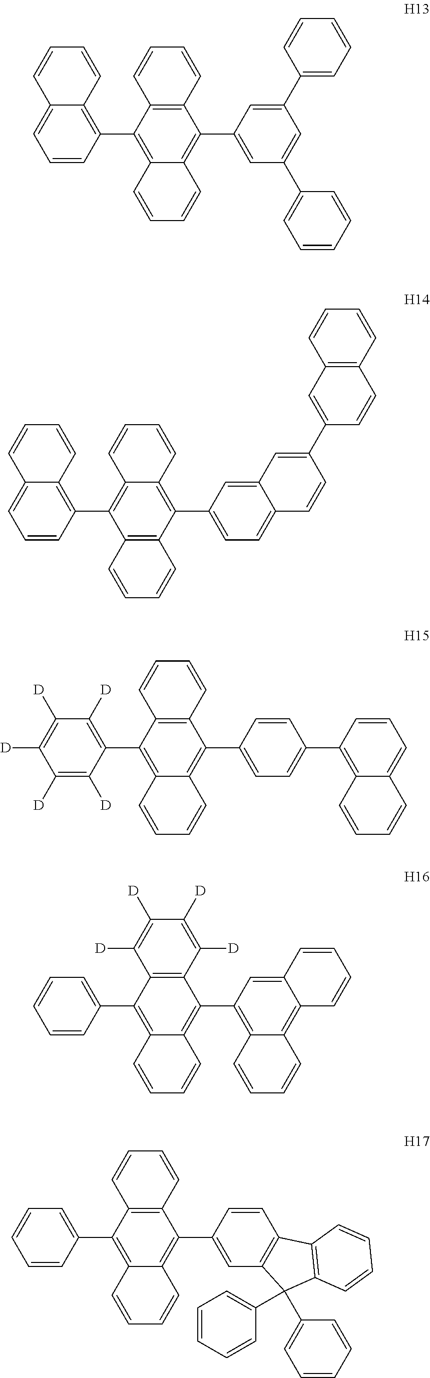

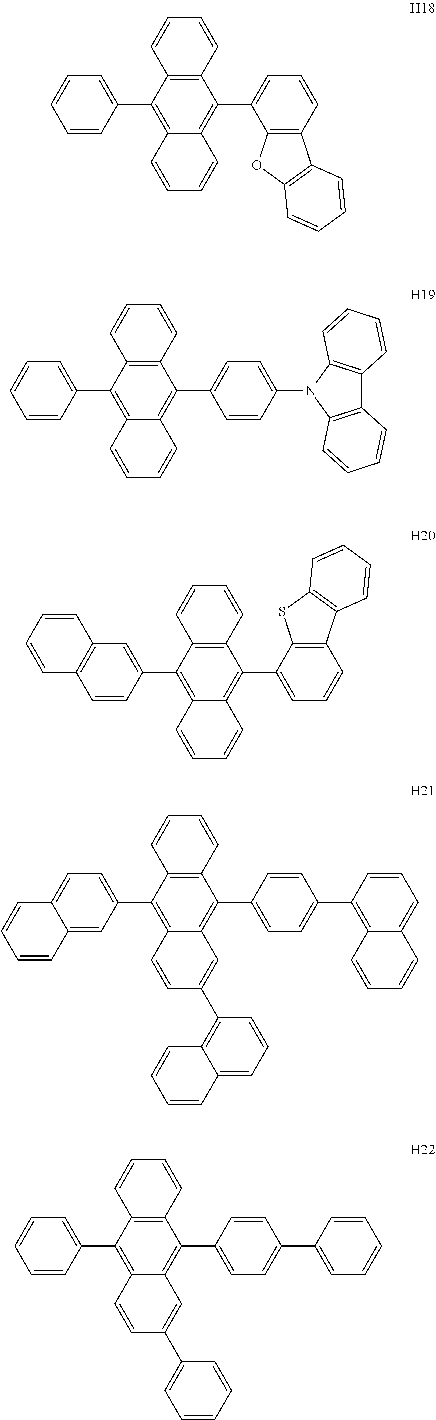

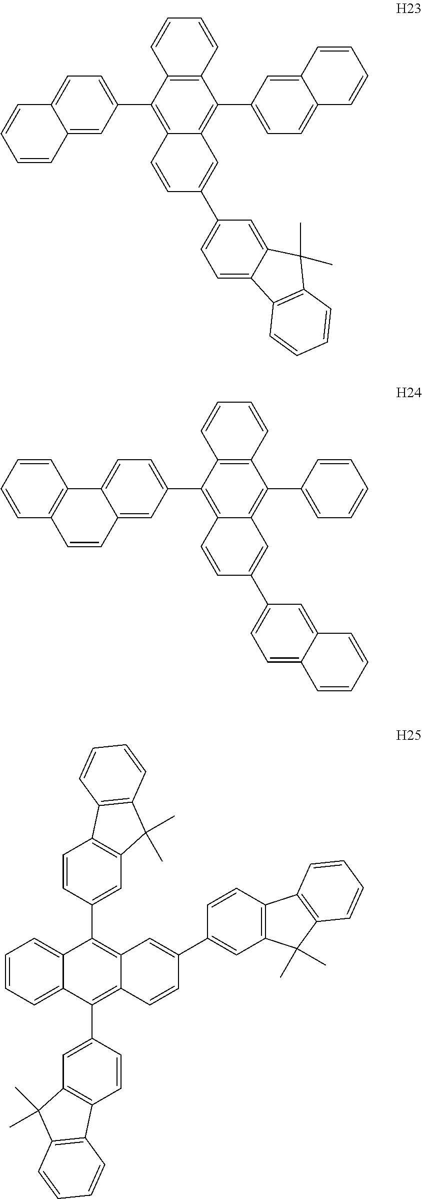

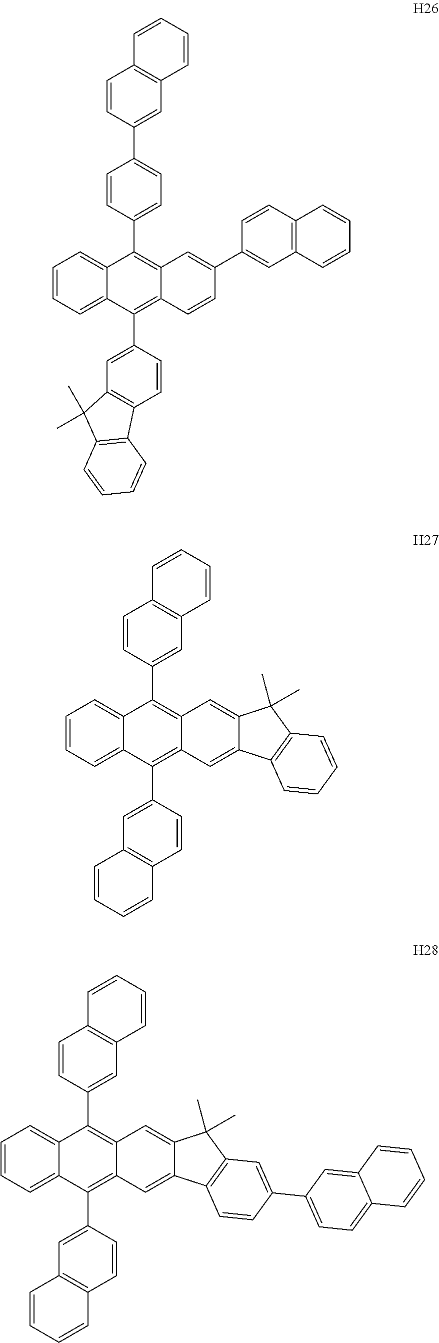

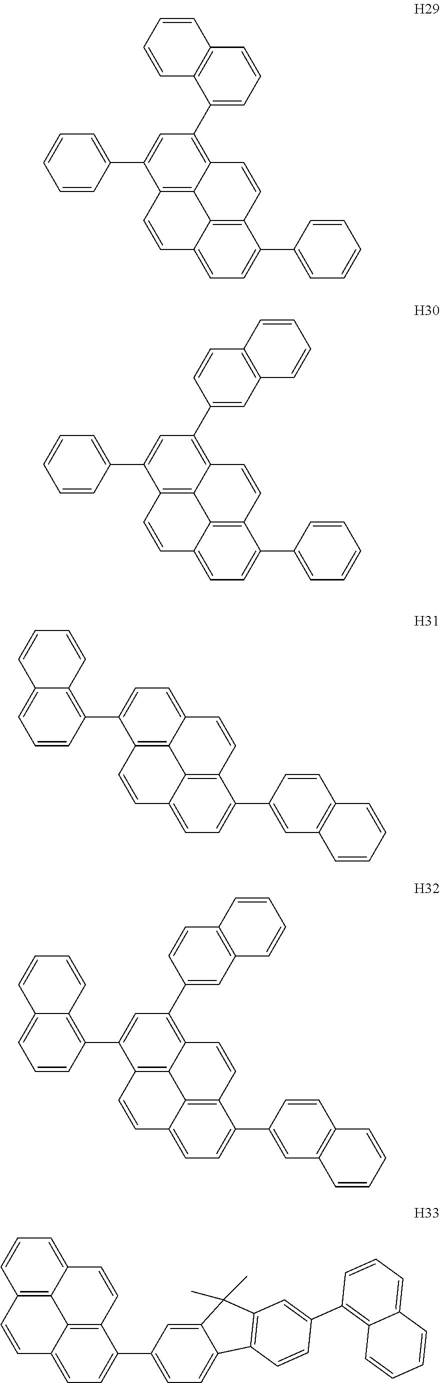

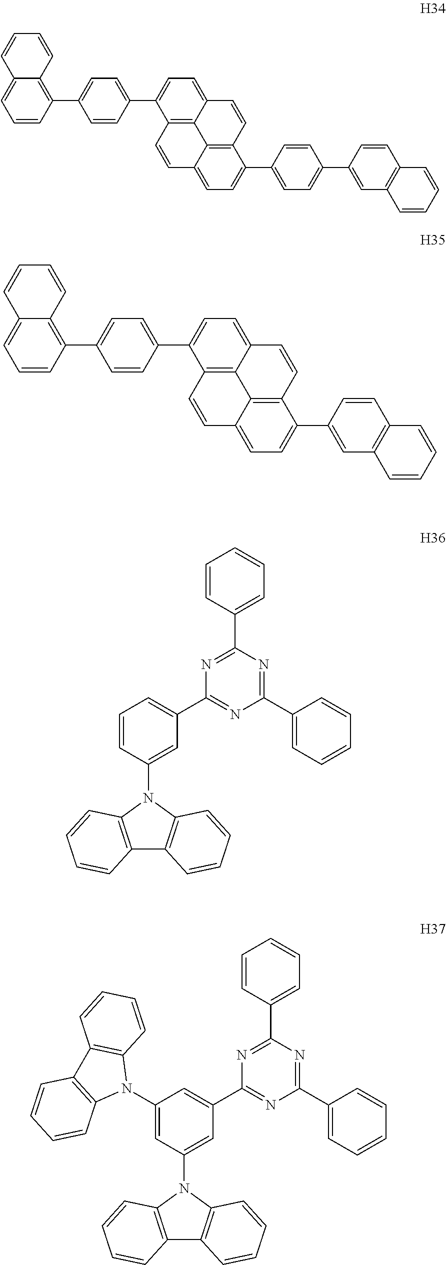

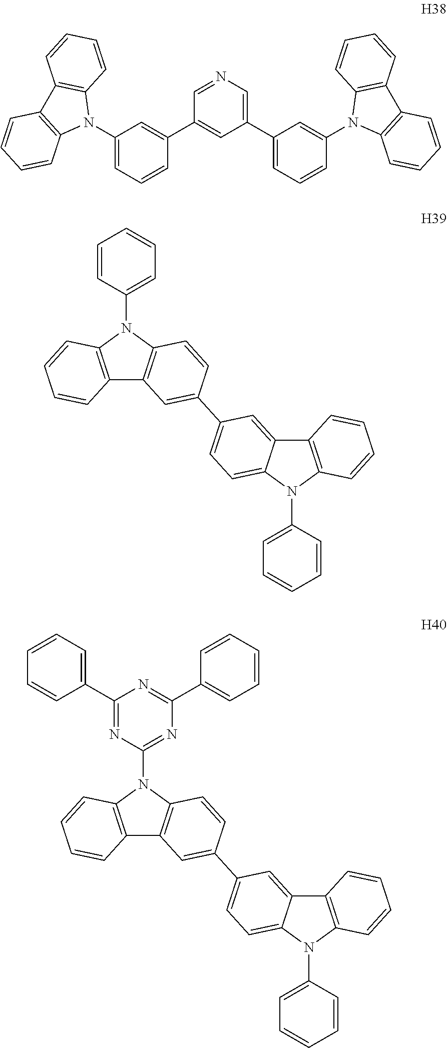 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

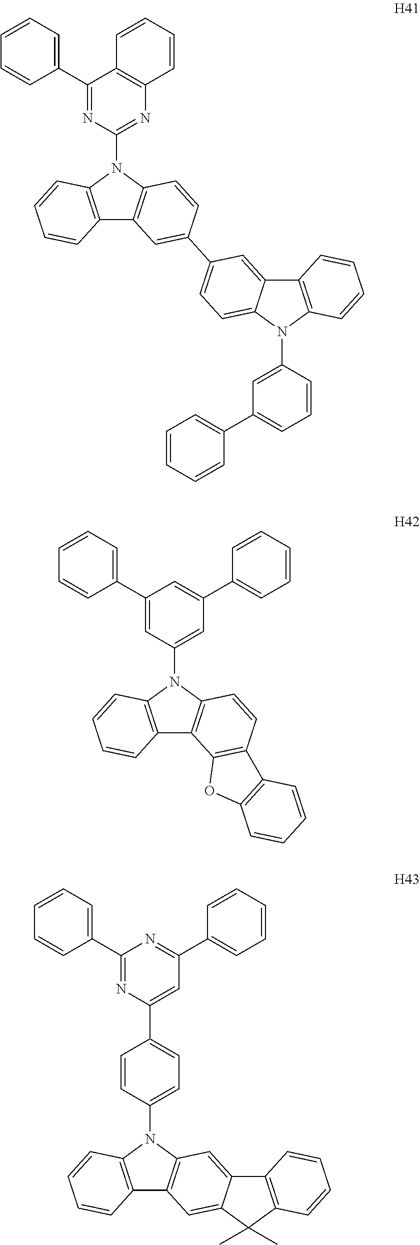 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

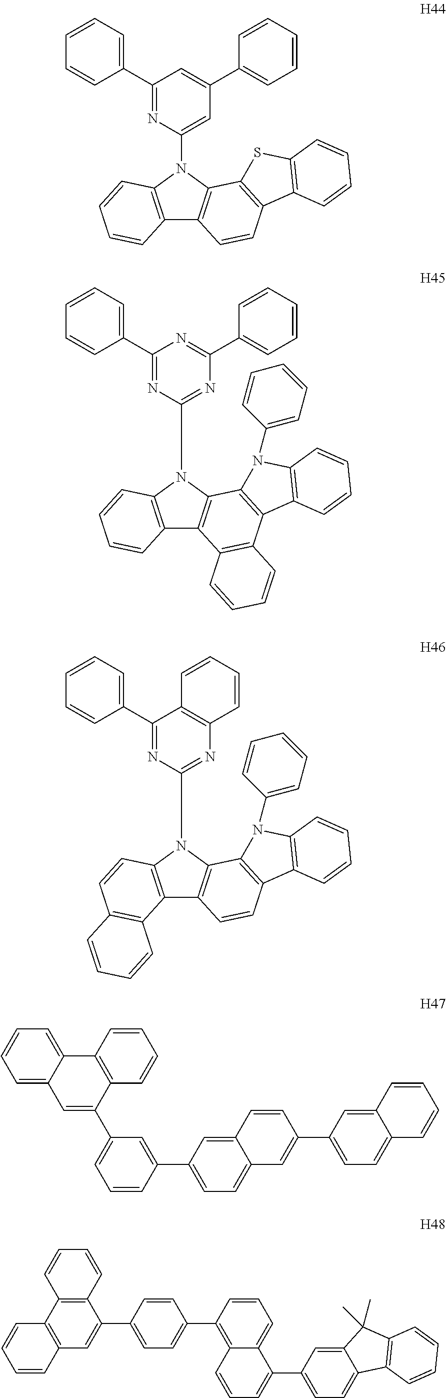

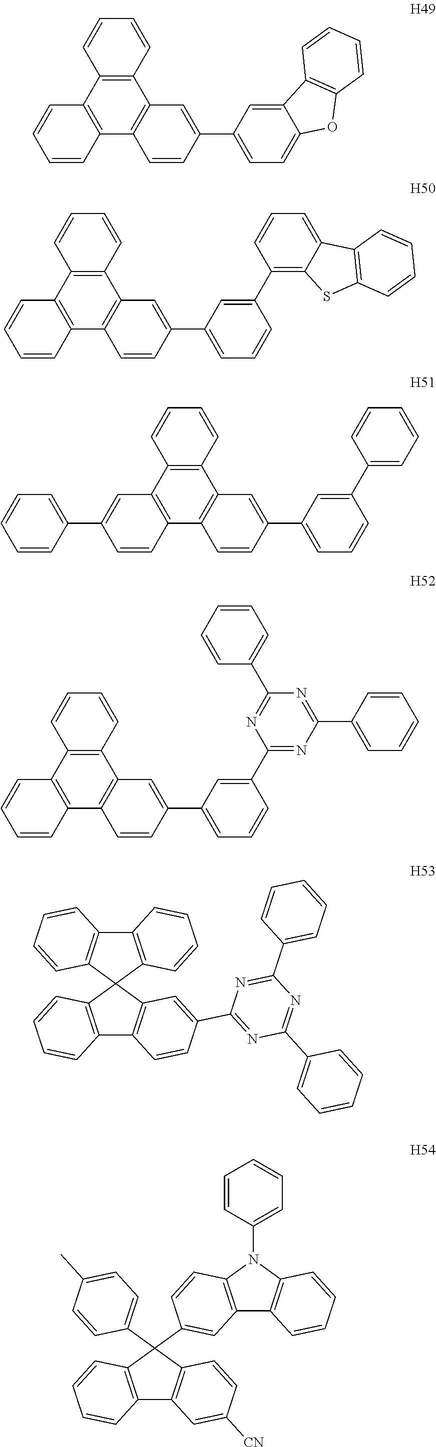

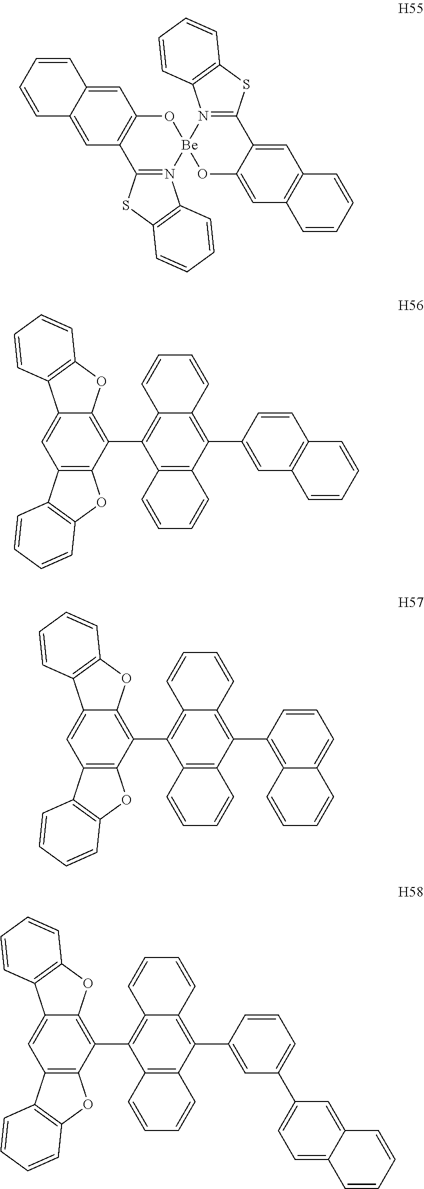

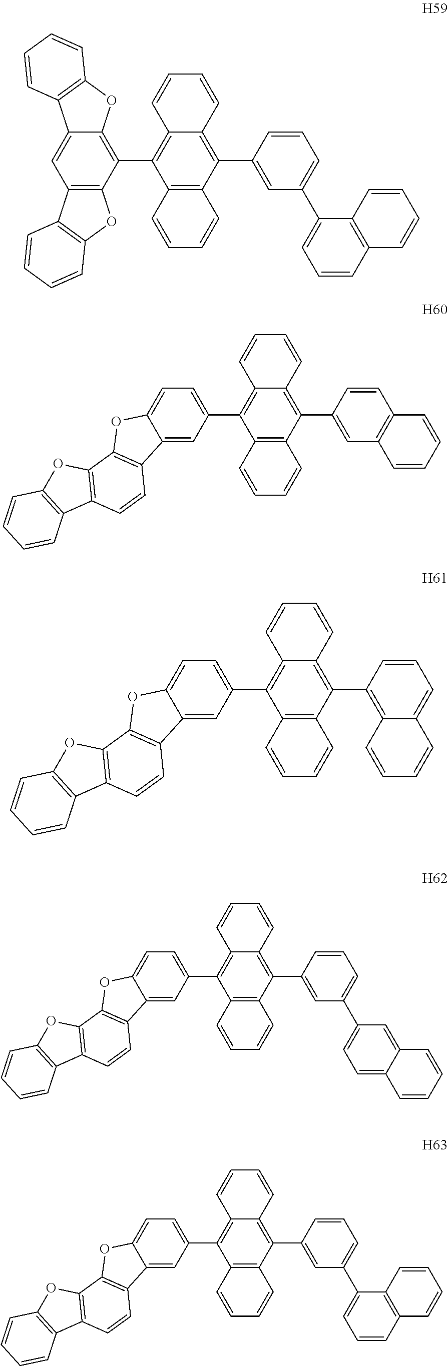 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1]

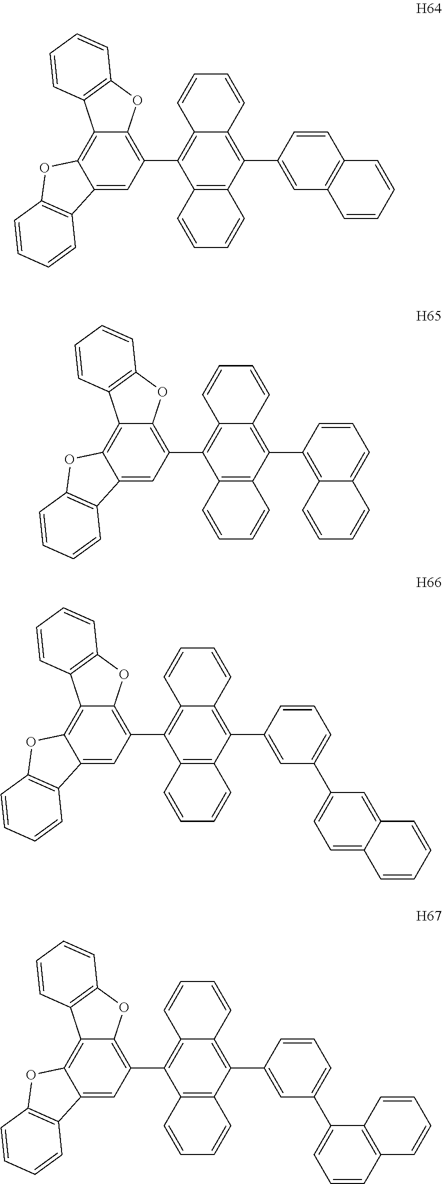 [SMILES: c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

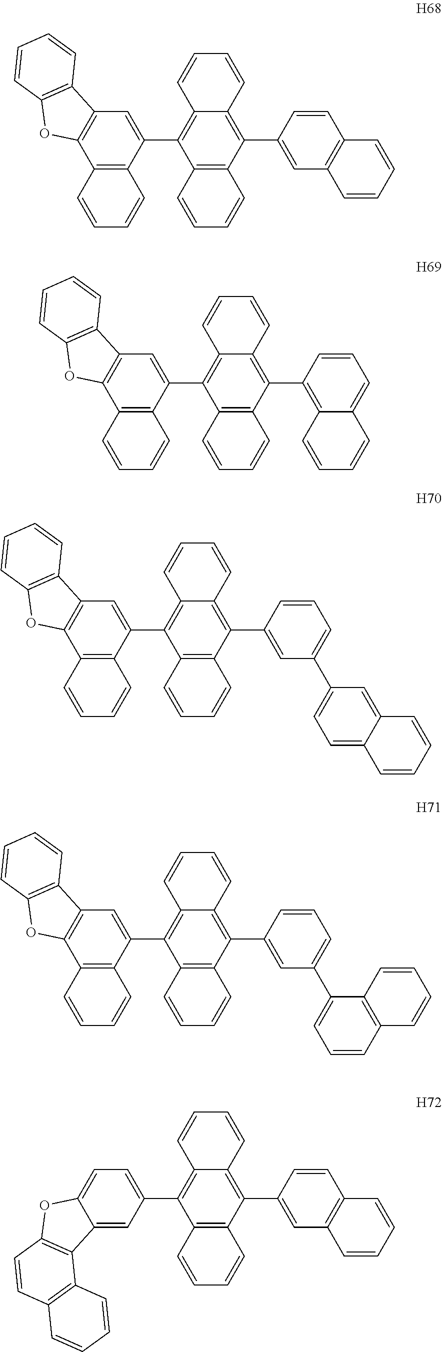 [SMILES: c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

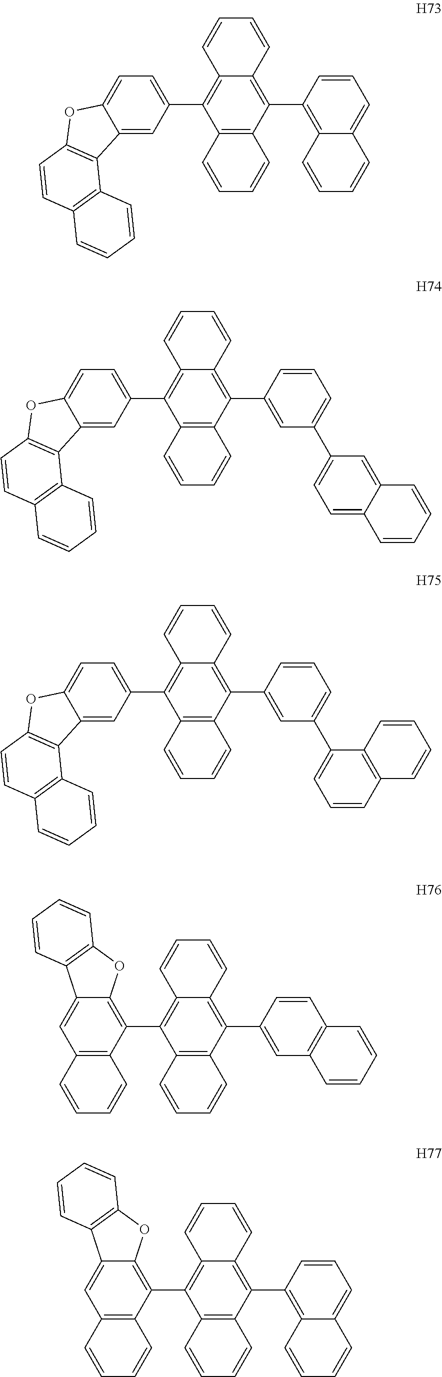 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1]

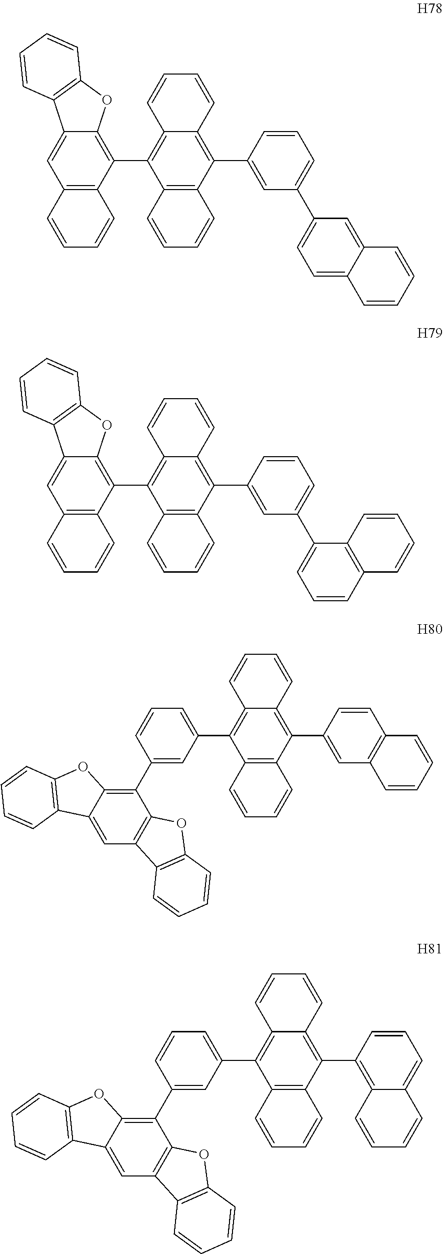 [SMILES: c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1]

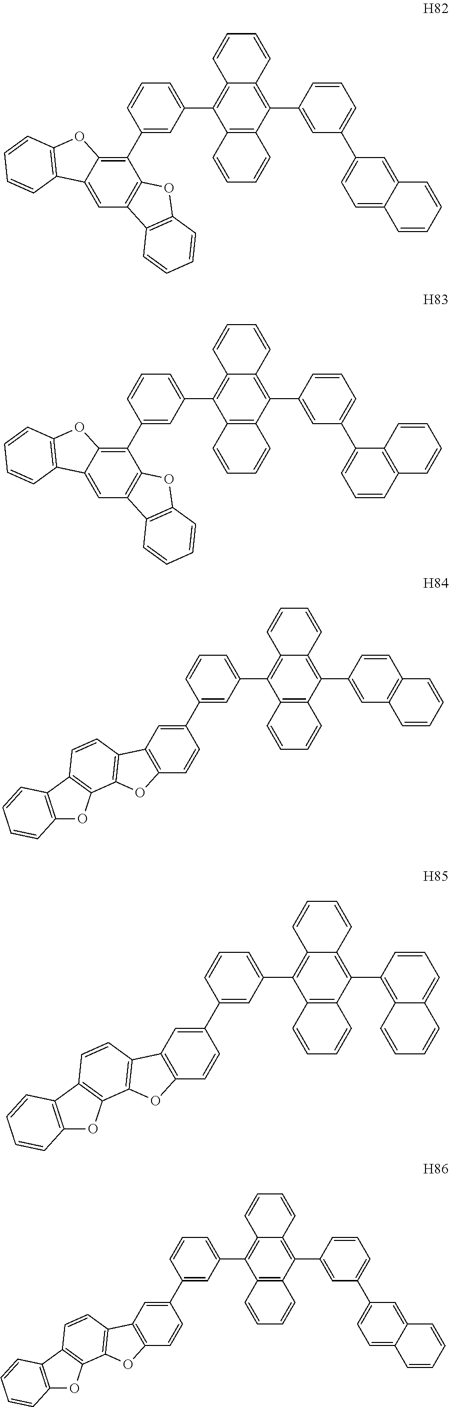 [SMILES: c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

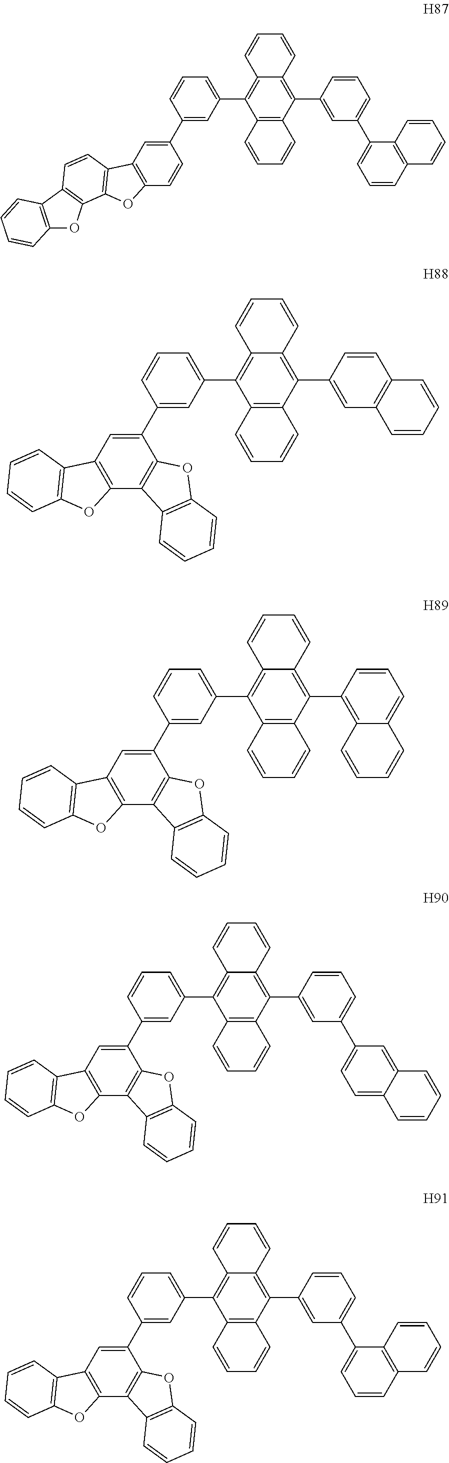 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

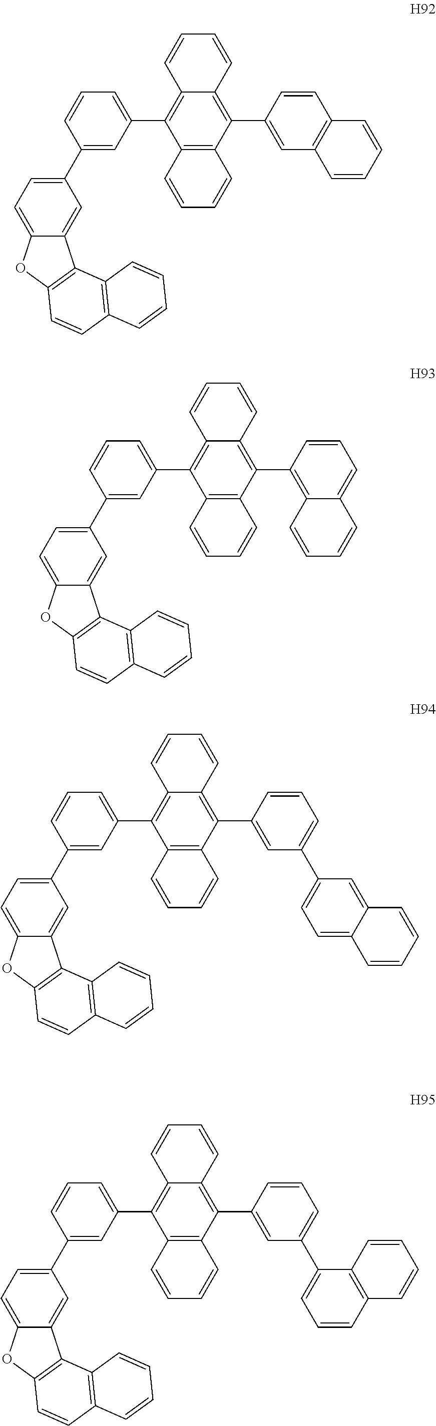 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

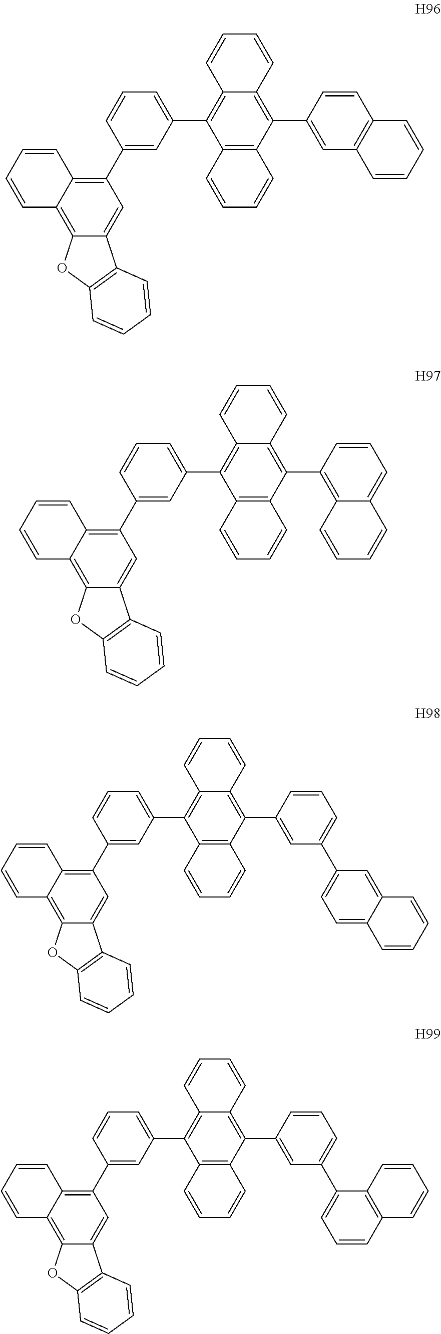 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

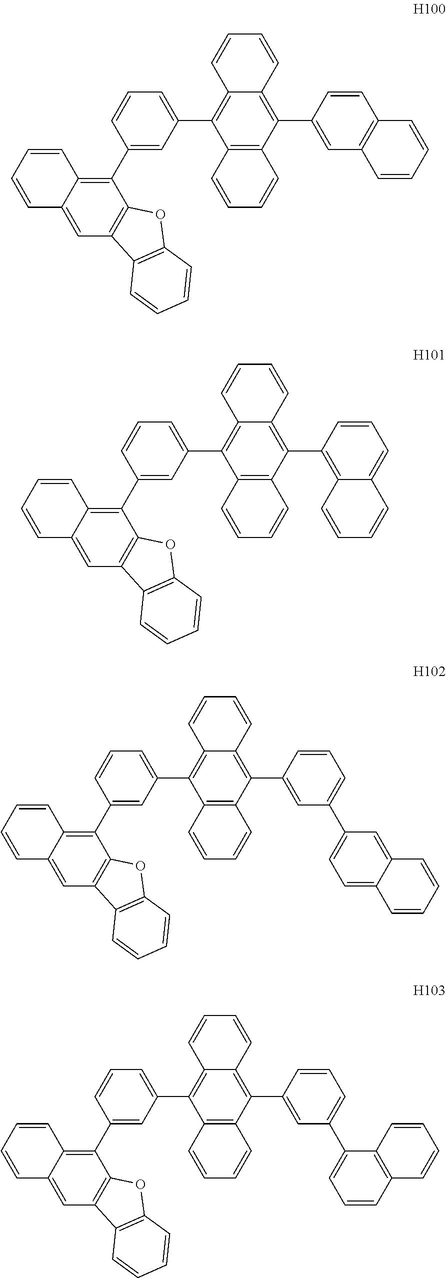 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

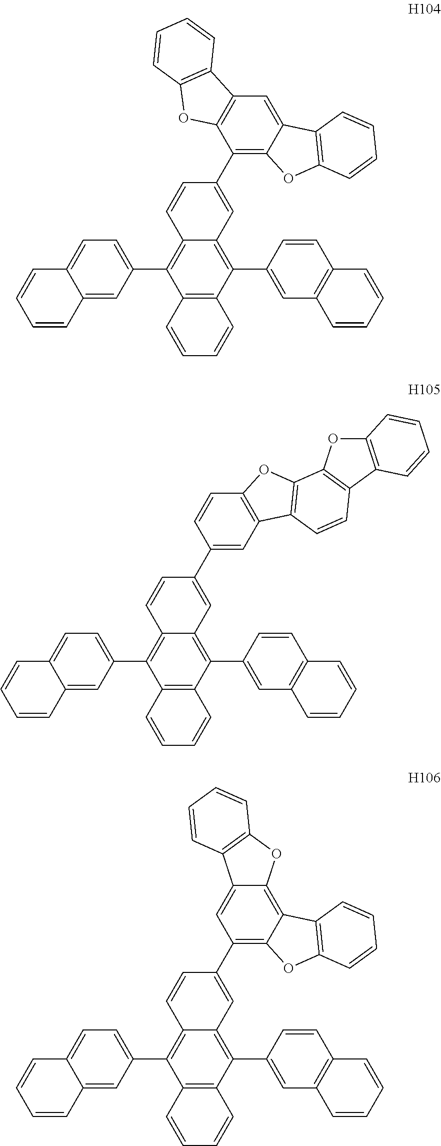 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

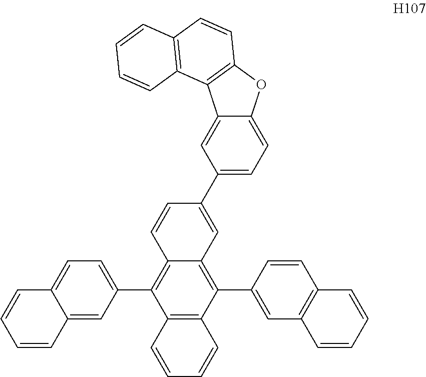 [SMILES: c1ccc2cc(-c3c4ccccc4c(-c4ccc5ccccc5c4)c4cc(-c5ccc6oc7ccc8ccccc8c7c6c5)ccc34)ccc2c1]

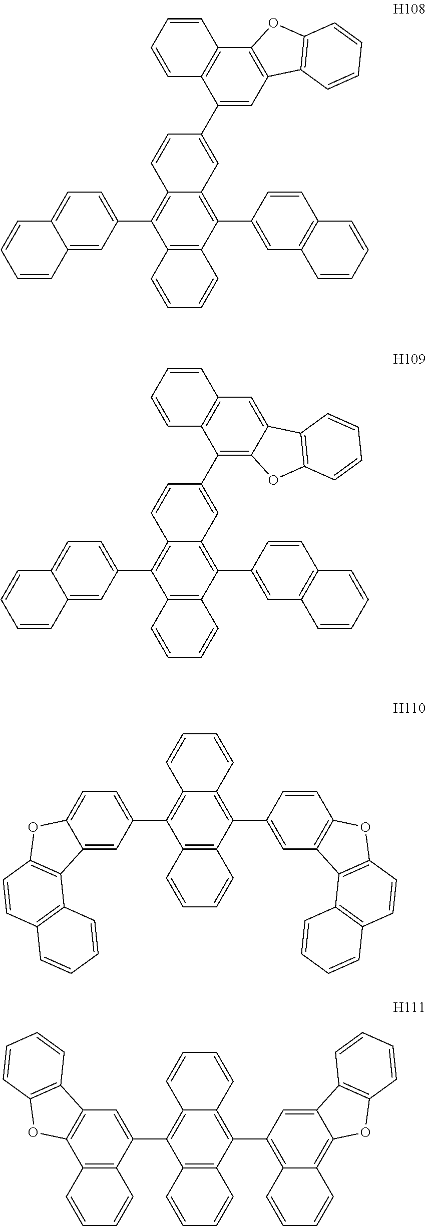 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

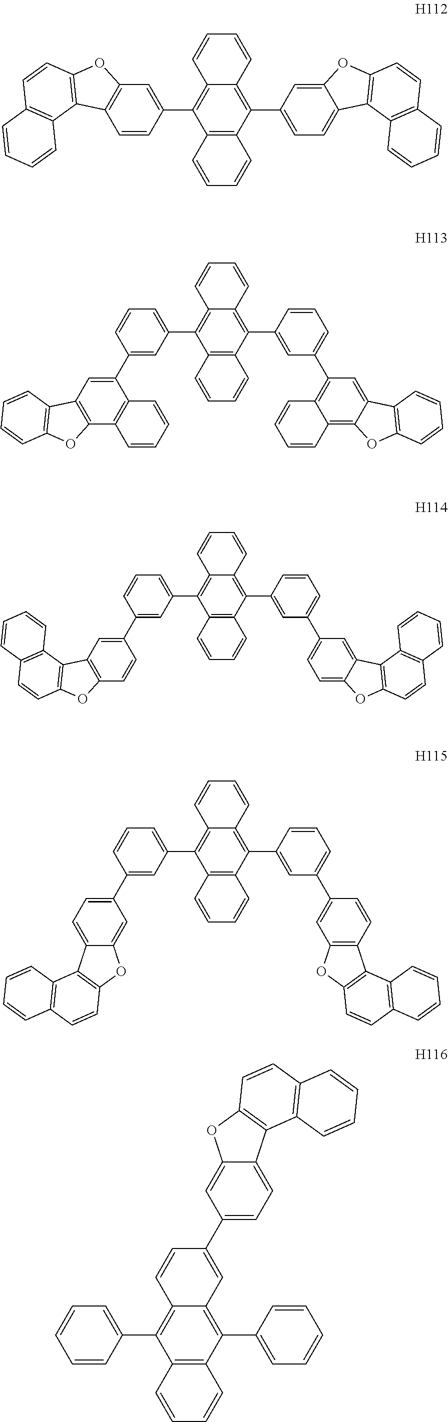 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

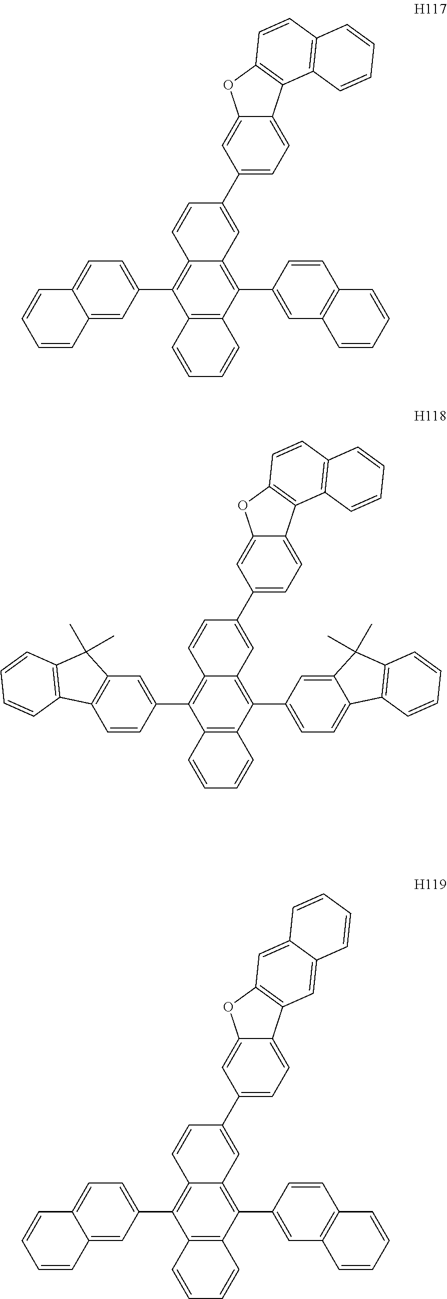 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

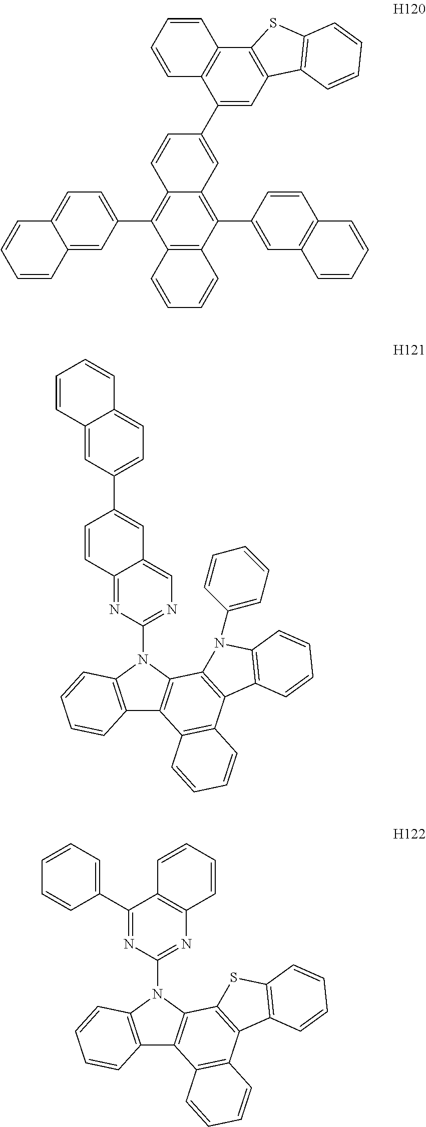 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

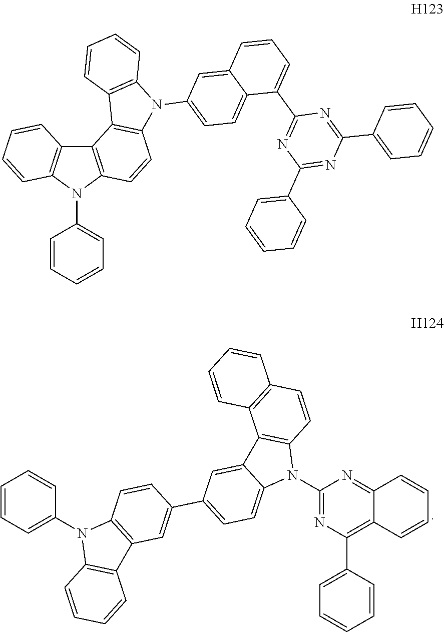 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

In one or more embodiments, the host may include a first host compound and a second host compound.

In one or more embodiments, the first host compound may be a hole transporting host.

In one or more embodiments, the second host compound may be an electron transporting host.

In one or more embodiments, the term “hole-transporting host” as used herein may be a compound including a hole-transporting moiety.

In one or more embodiments, the term “electron-transporting host” as used herein may be a compound not only including an electron-transporting moiety but also having bipolar properties.

Herein, the terms “hole-transporting host” and “electron-transporting host” may each be understood according to the relative difference between hole mobility and electron mobility in the hole-transporting host and the electron-transporting host. For example, even if (e.g., when) the electron-transporting host does not include an electron-transporting moiety, a bipolar compound exhibiting relatively higher electron mobility than the hole-transporting host may be also understood as the electron-transporting host.

In one or more embodiments, the hole-transporting host may be represented by any one selected from among Formulae 311-1 to 311-6, and the electron-transporting host may be represented by any one selected from among Formulae 312-1 to 312-4 and 313:

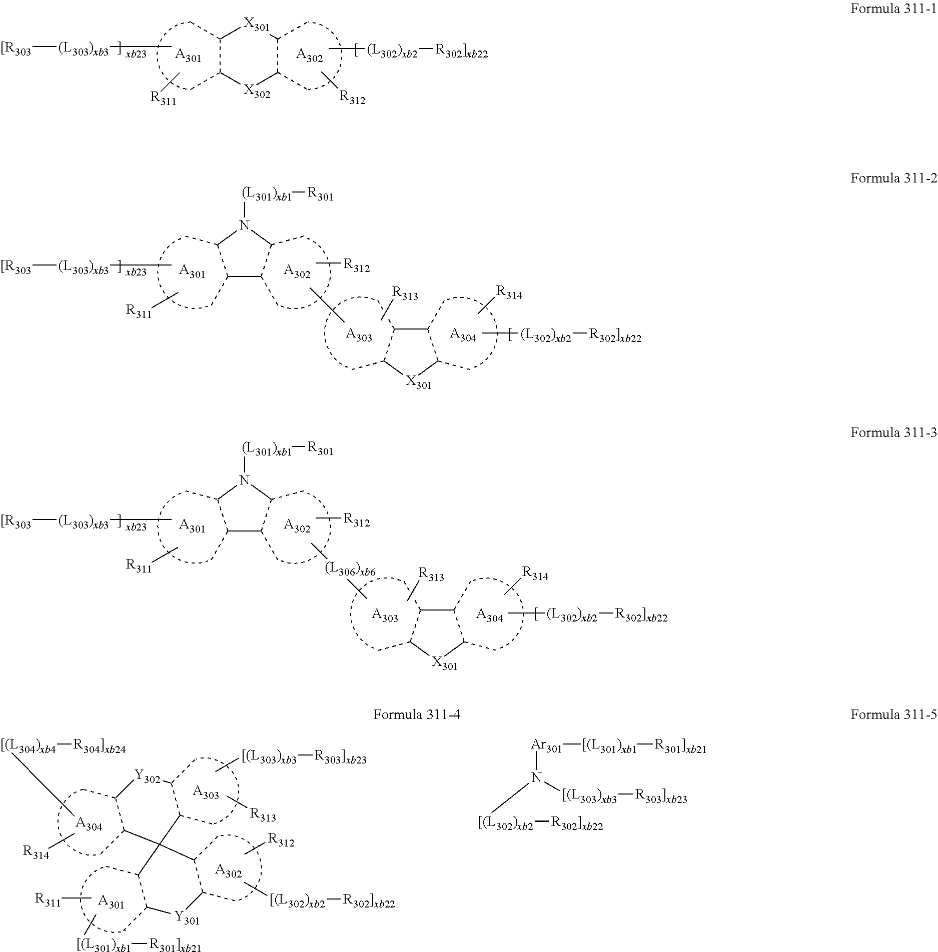

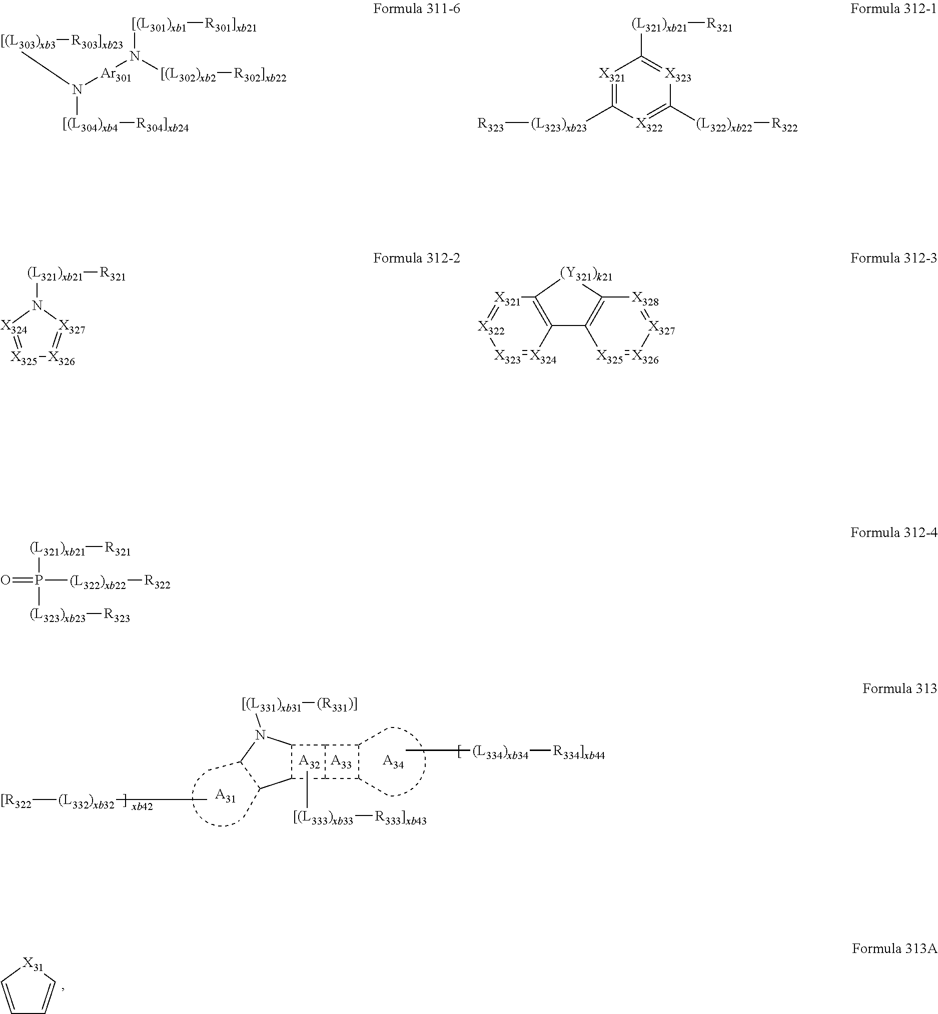

wherein, in Formulae 311-1 to 311-6, 312-1 to 312-4, 313, and 313A,
Ar₃₀₁ may be a C₃-C₆₀ carbocyclic group unsubstituted or substituted with at least one R₁₀ₐ or a C₁-C₆₀ heterocyclic group unsubstituted or substituted with at least one R₁₀ₐ,
A₃₀₁ to A₃₀₄ may each independently be a C₃-C₆₀ carbocyclic group or a C₁-C₆₀ heterocyclic group,
X₃₀₁ may be O, S, N[(L₃₀₄)_{xb4}-R₃₀₄], C[(L₃₀₄)_{xb4}-R₃₀₄][(L₃₀₅)_{xb5}-R₃₀₅], or Si[(L₃₀₄)_{xb4}-R₃₀₄][(L₃₀₅)_{xb5}-R₃₀₅],
X₃₀₂, Y₃₀₁, and Y₃₀₂ may each independently be a single bond, O, S, N[(L₃₀₅)_{xb5}-R₃₀₅], C[(L₃₀₄)_{xb4}-R₃₀₄][(L₃₀₅)_{xb5}-R₃₀₅], Si[(L₃₀₄)_{xb4}-R₃₀₄][(L₃₀₅)_{xb5}-R₃₀₅], or S(═O)₂,
xb1 to xb5 may each be 0, 1, 2, 3, 4, or 5,
xb6 may be 1, 2, 3, 4, or 5,
X₃₂₁ to X₃₂₈ may each independently be N or C[(L₃₂₄)_{xb24}-R₃₂₄],
Y₃₂₁ may be *—O—*′, *—S—*′, *—N[(L₃₂₅)_{xb25}-R₃₂₅]—*′, *—C[(L₃₂₅)_{xb25}-R₃₂₅][(L₃₂₆)_{xb26}-R₃₂₆]—*′, *—C[(L₃₂₅)_{xb25}-R₃₂₅]═C[(L₃₂₆)_{xb26}-R₃₂₆]—*′, *—C[(L₃₂₅)_{xb25}-R₃₂₅]═N—*′, or *—N═C[(L₃₂₆)_{xb26}-R₃₂₆]—*′,
k21 may be 0, 1, or 2, wherein Y₃₂₁ is not present if (e.g., when) k21 is 0,
xb21 to xb26 may each independently be 0, 1, 2, 3, 4, or 5,
A₃₁, A₃₂, and A₃₄ may each independently be a C₃-C₆₀ carbocyclic group or a C₁-C₃₀ heterocyclic group,
A₃₃ may be a group represented by Formula 313A,
X₃₁ may be N[(L₃₃₅)_{xb35}-(R₃₃₅)], O, S, Se, C[(L₃₃₅)_{xb35}-(R₃₃₅)][(L₃₃₆)_{xb36}-(R₃₃₆)], or Si[(L₃₃₅)_{xb35}-(R₃₃₅)][(L₃₃₆)_{xb36}-(R₃₃₆)],
xb31 to xb36 may each independently be 0, 1, 2, 3, 4, or 5,
xb42 to xb44 may each independently be 0, 1, 2, 3, 4, 5, 6, 7, 8, 9, or 10,
L₃₀₁ to L₃₀₆, L₃₂₁ to L₃₂₆, and L₃₃₁ to L₃₃₆ may each independently be a single bond, a C₁-C₂₀ alkylene group unsubstituted or substituted with at least one R₁₀ₐ, a C₁-C₂₀ alkenylene group unsubstituted or substituted with at least one R₁₀ₐ, a C₁-C₂₀ alkynylene group unsubstituted or substituted with at least one R₁₀ₐ, a C₃-C₁₀ cycloalkylene group unsubstituted or substituted with at least one R₁₀ₐ, a C₁-C₁₀ heterocycloalkylene group unsubstituted or substituted with at least one R₁₀ₐ, a C₃-C₁₀ cycloalkenylene group unsubstituted or substituted with at least one R₁₀ₐ, a C₁-C₁ heterocycloalkenylene group unsubstituted or substituted with at least one R₁₀ₐ, a C₆-C₆₀ arylene group unsubstituted or substituted with at least one R₁₀ₐ, a C₁-C₆₀ heteroarylene group unsubstituted or substituted with at least one R₁₀ₐ, a divalent non-aromatic condensed polycyclic group unsubstituted or substituted with at least one R₁₀ₐ, or a divalent non-aromatic condensed heteropolycyclic group unsubstituted or substituted with at least one R₁₀ₐ,
R₃₀₁ to R₃₀₅, R₃₁₁ to R₃₁₄, R₃₂₁ to R₃₂₆, and R₃₃₁ to R₃₃₆ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁ heterocycloalkyl group unsubstituted or substituted with at least one R₁₀ₐ, a C₃-C₁₀ cycloalkenyl group unsubstituted or substituted with at least one R₁₀ₐ, a C₁-C₁ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
two or more neighboring groups selected from among R₃₂₁ to R₃₂₆ may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ may be:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

In one or more embodiments, the first host compound and the second host compound may form an exciplex.

In one or more embodiments, the first host compound may include one of (e.g., be any one or include one or more selected from among) Compounds HTH1 to HTH56 and/or a (e.g., any suitable) combination thereof:

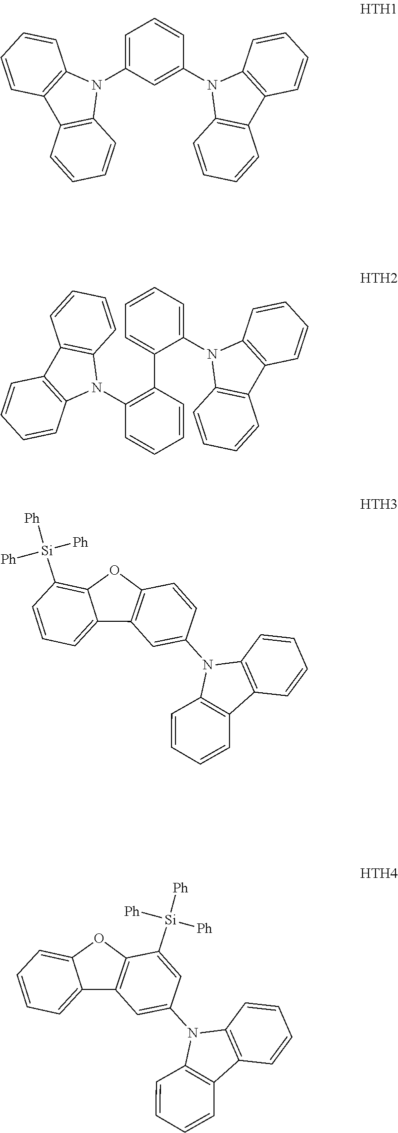 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

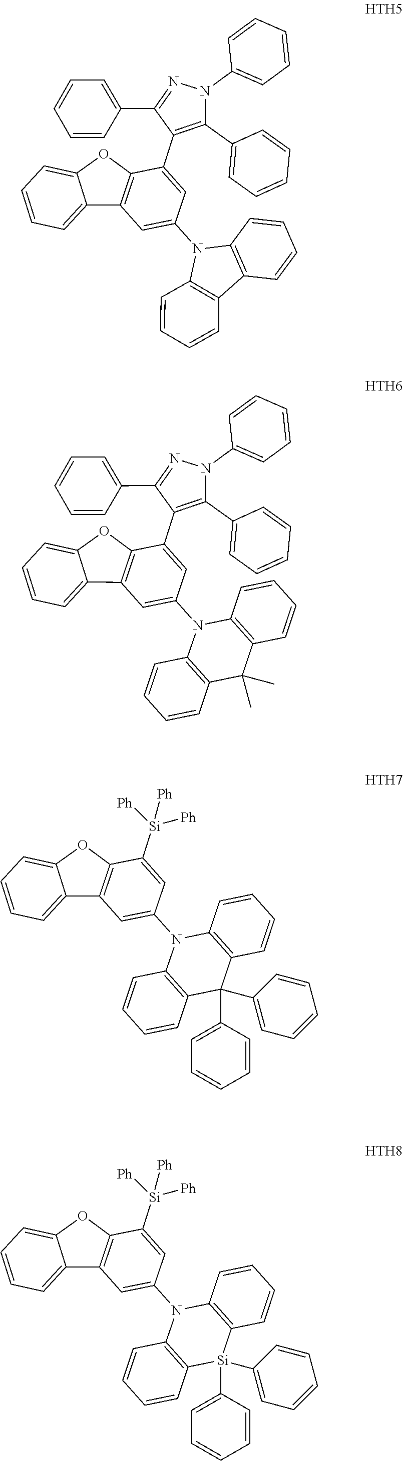 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

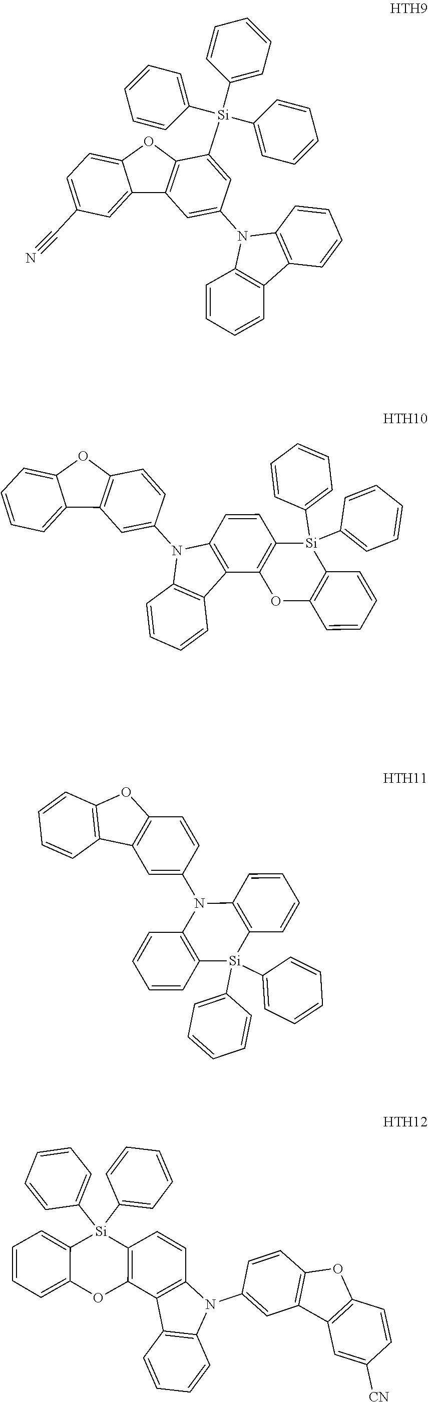 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

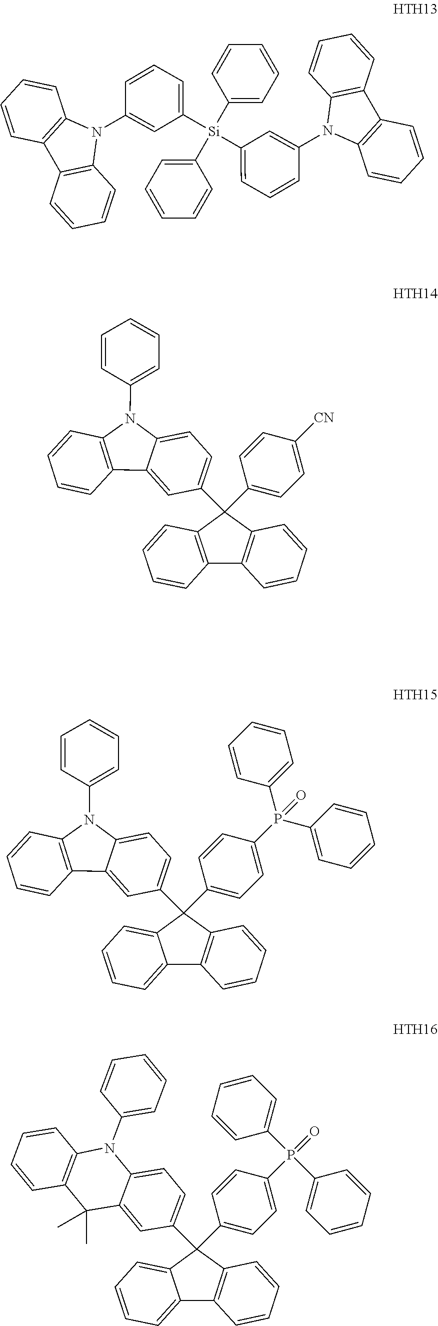 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

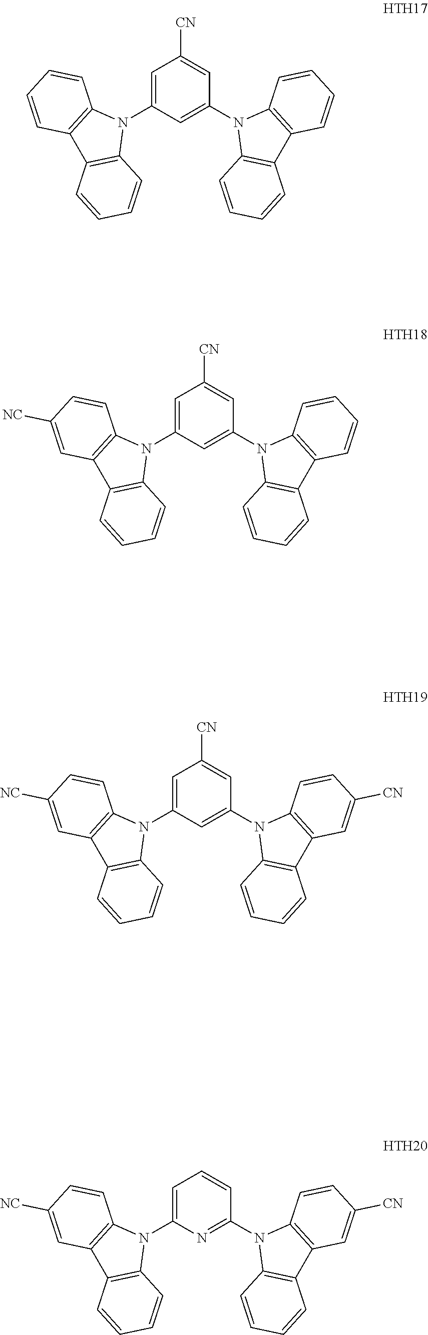 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

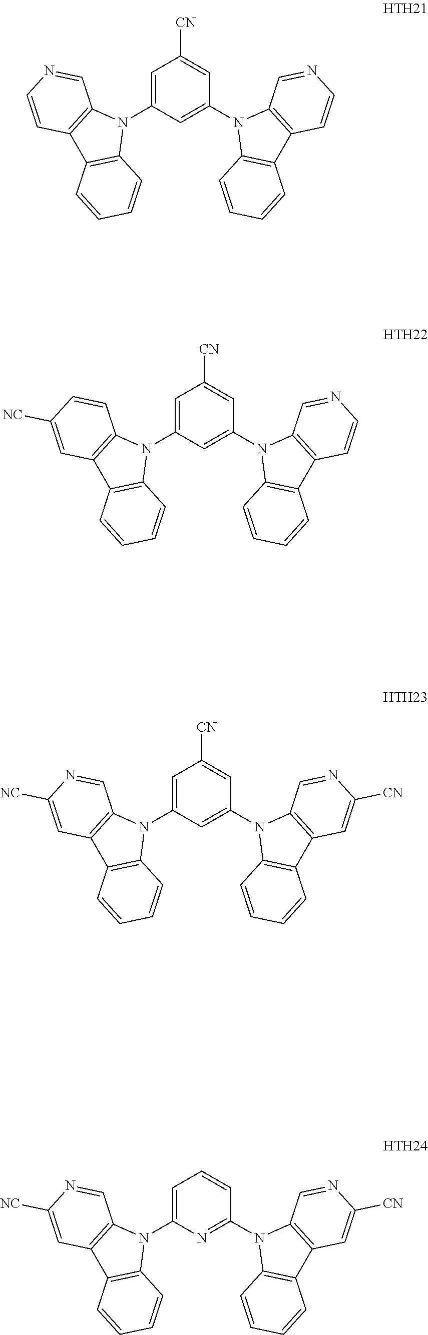 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

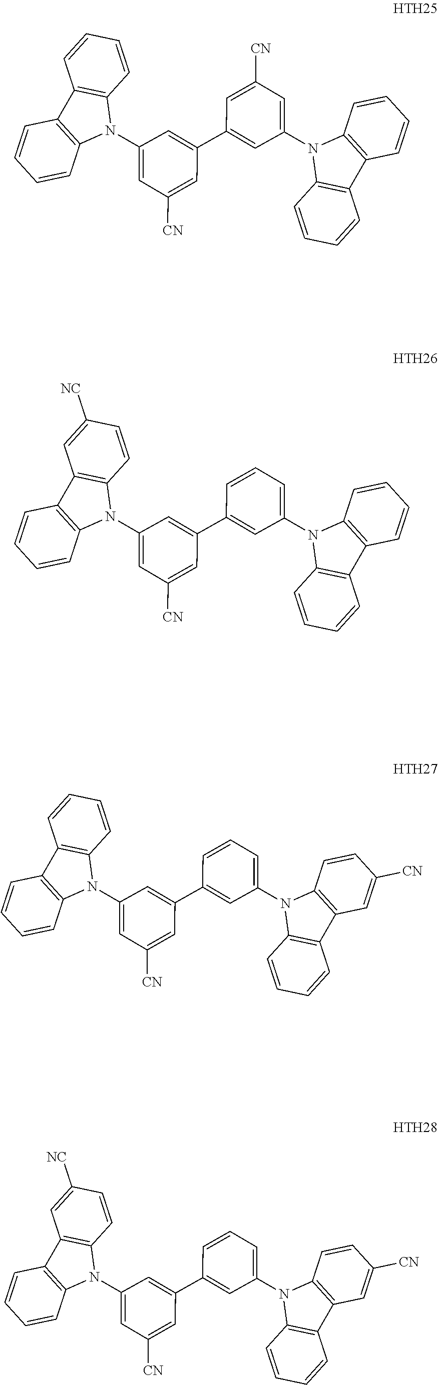 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

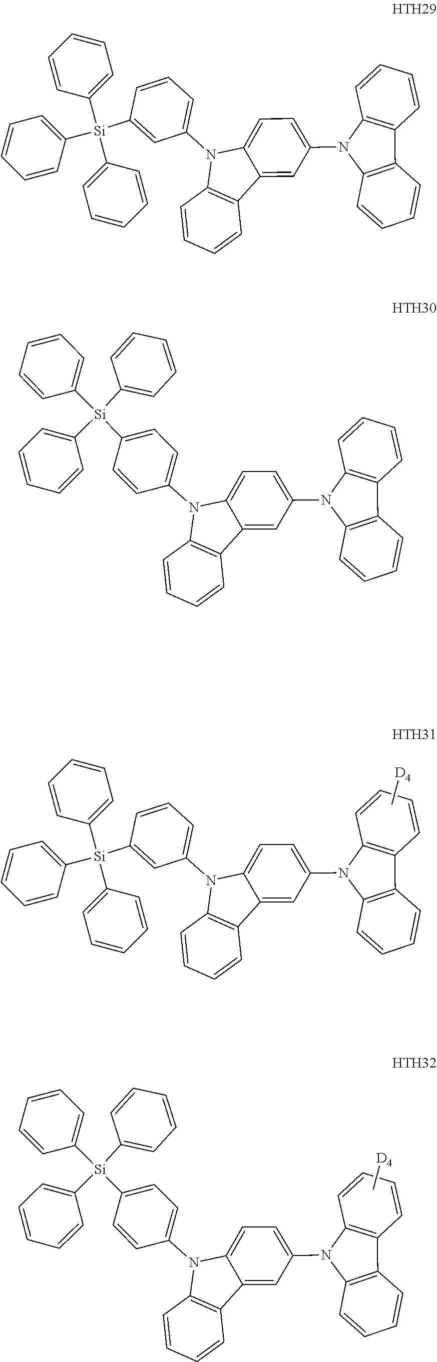

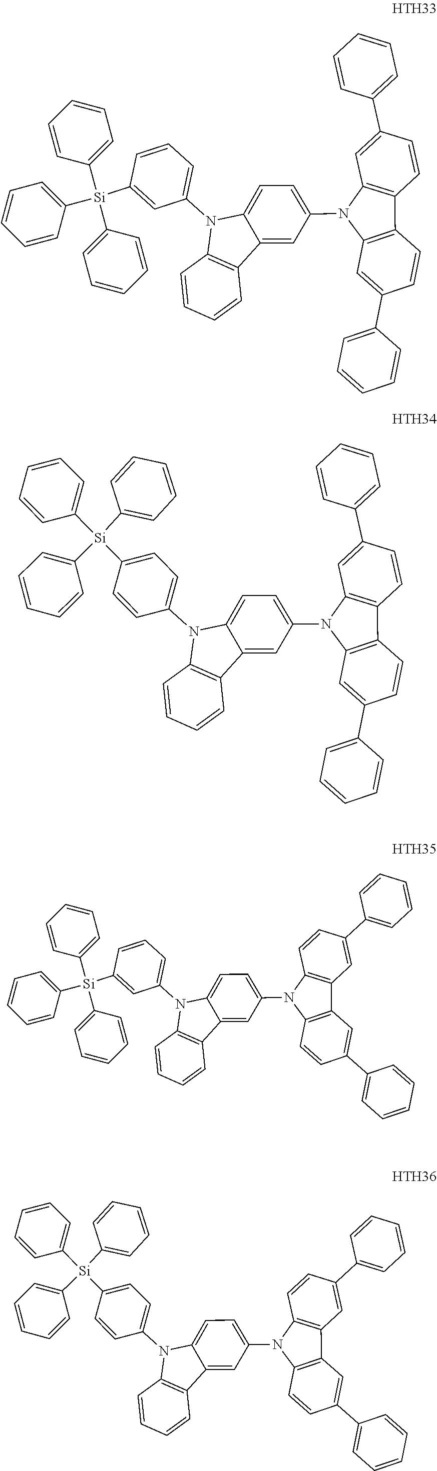 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

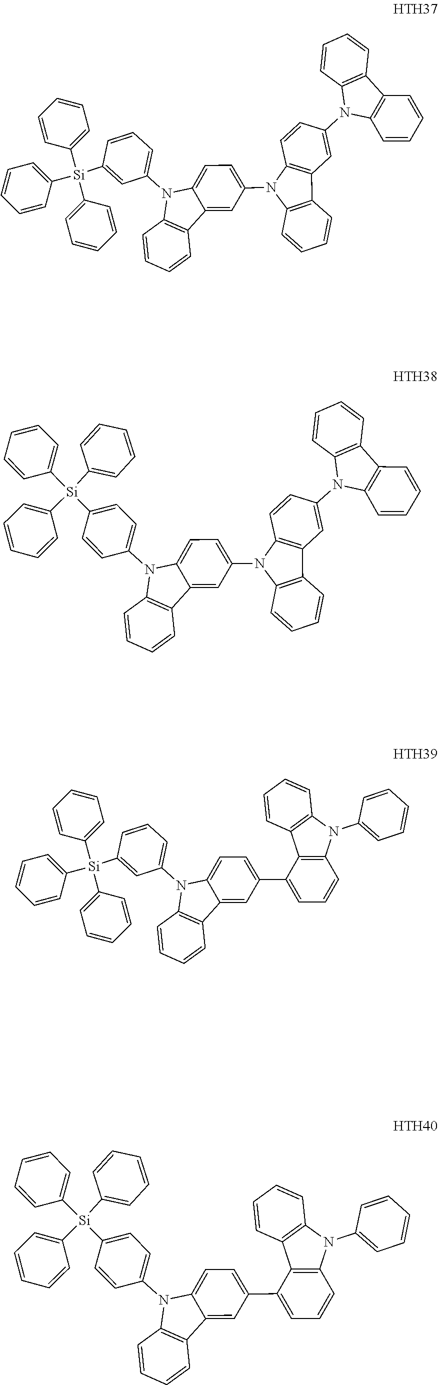 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

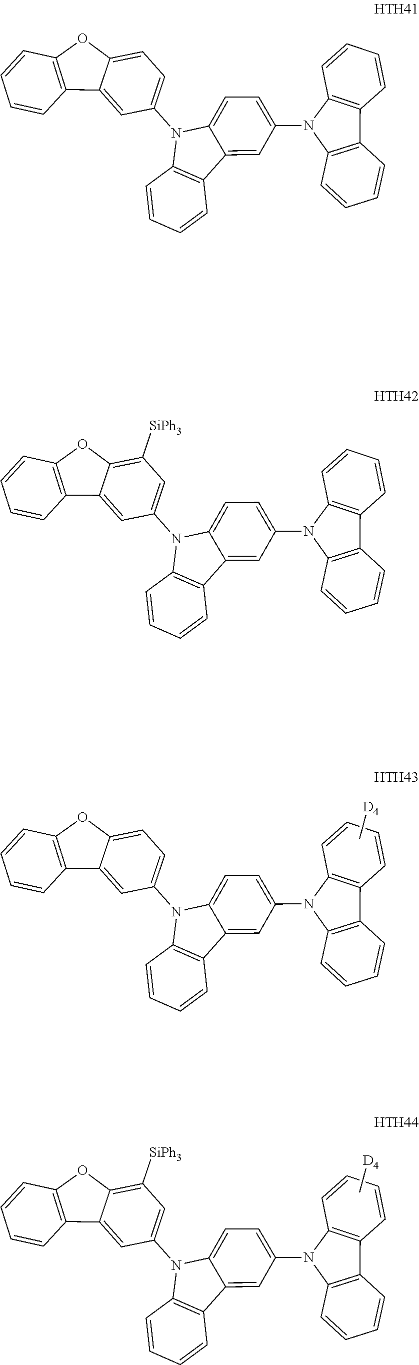

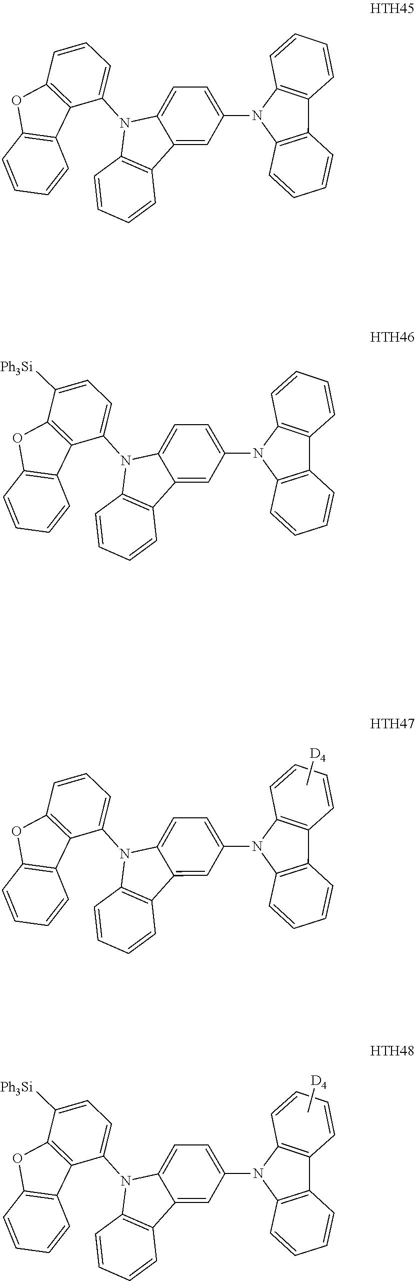

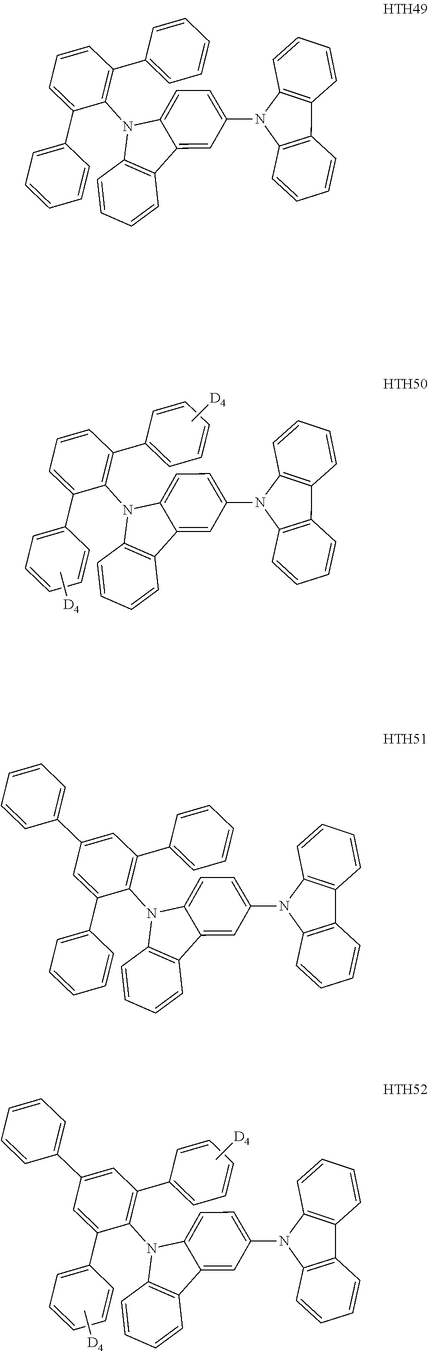

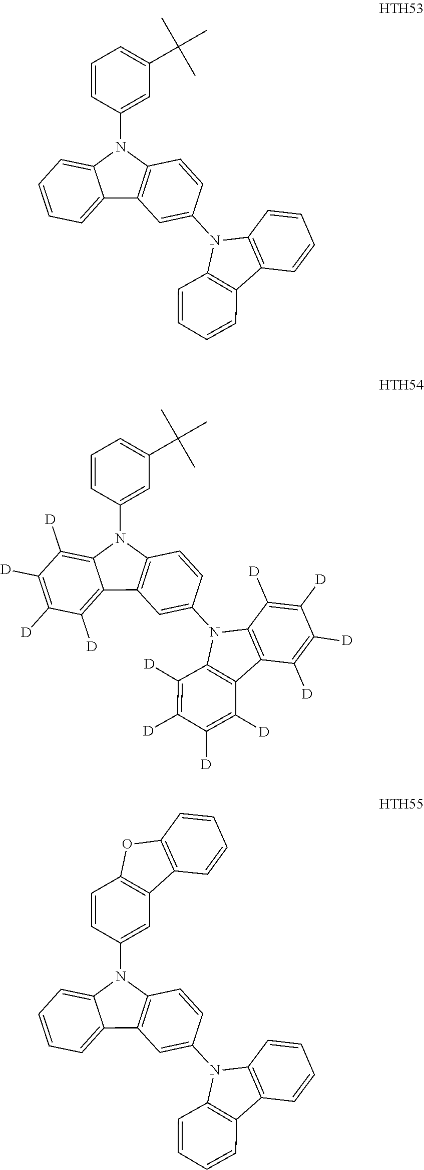 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

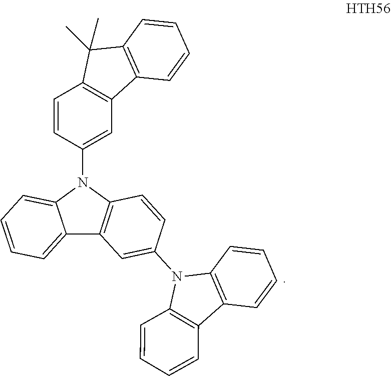 [SMILES: CC1(C)c2ccccc2-c2cc(-n3c4ccccc4c4cc(-n5c6ccccc6c6ccccc65)ccc43)ccc21]

In one or more embodiments, the second host compound may include one of (e.g., one or more selected from among) Compounds ETH1 to ETH86 and/or a (e.g., any suitable) combination thereof:

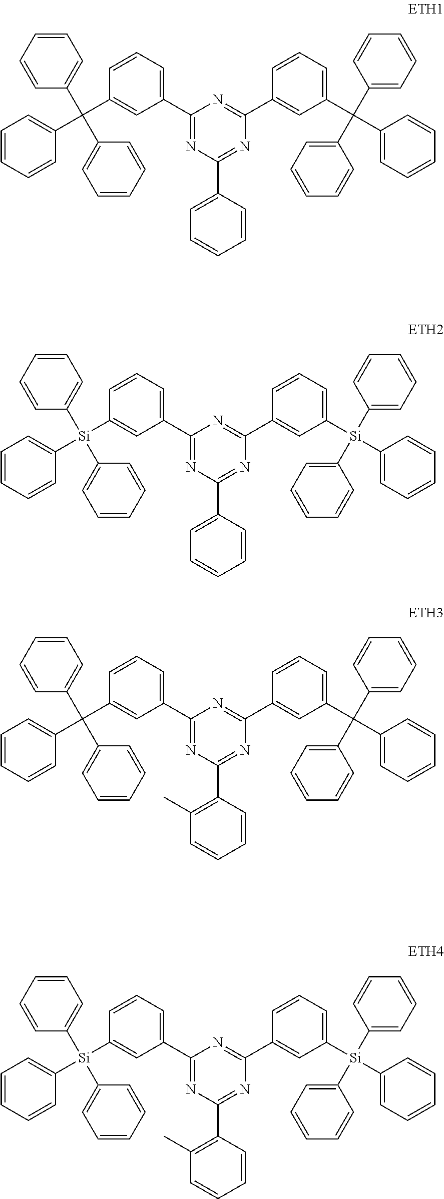 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

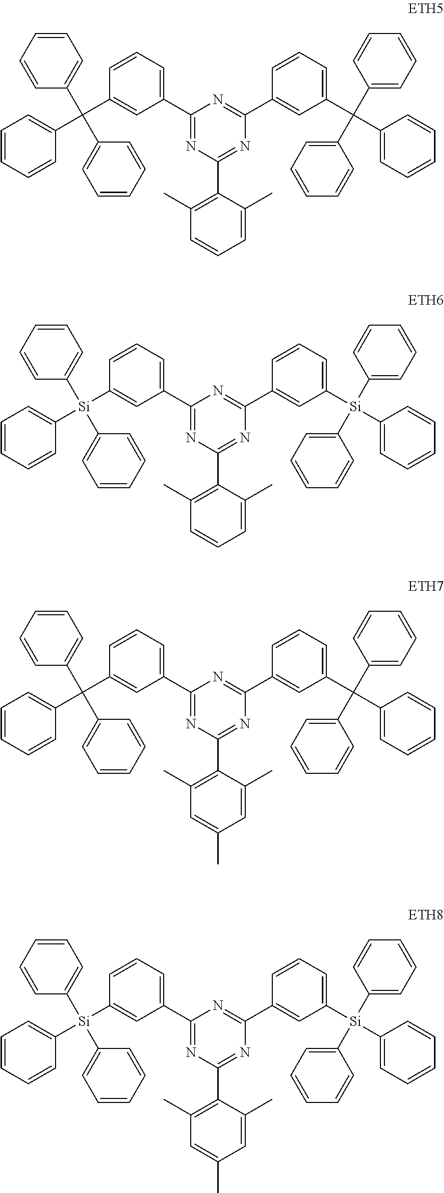 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

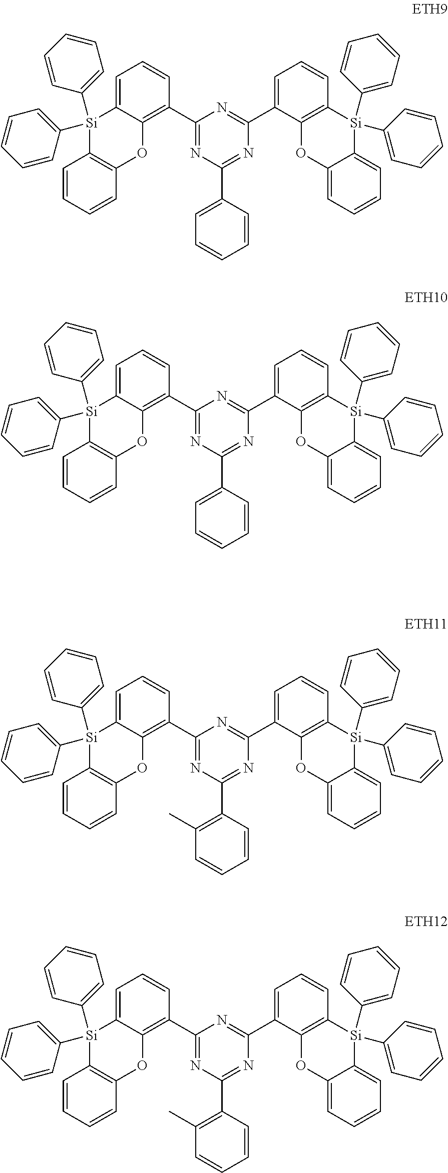 [SMILES: c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

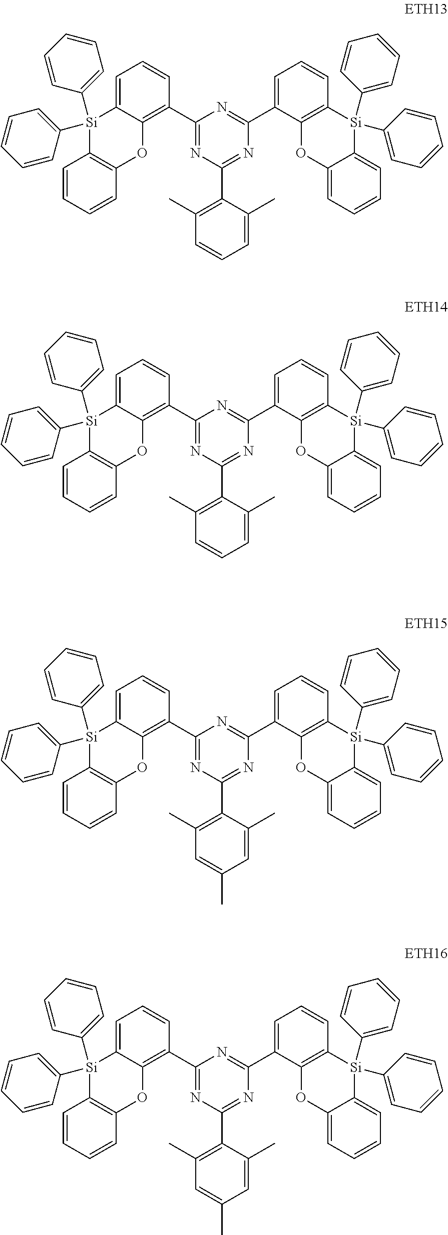 [SMILES: Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

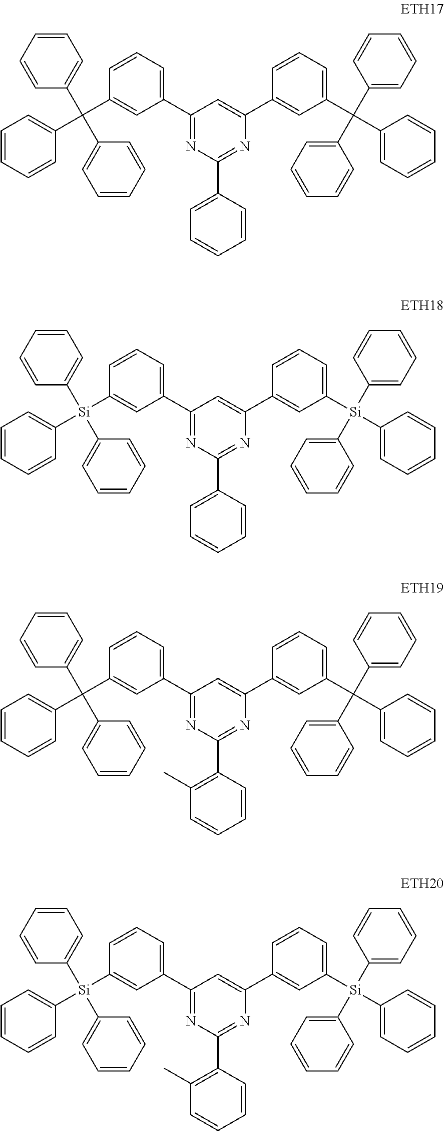 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

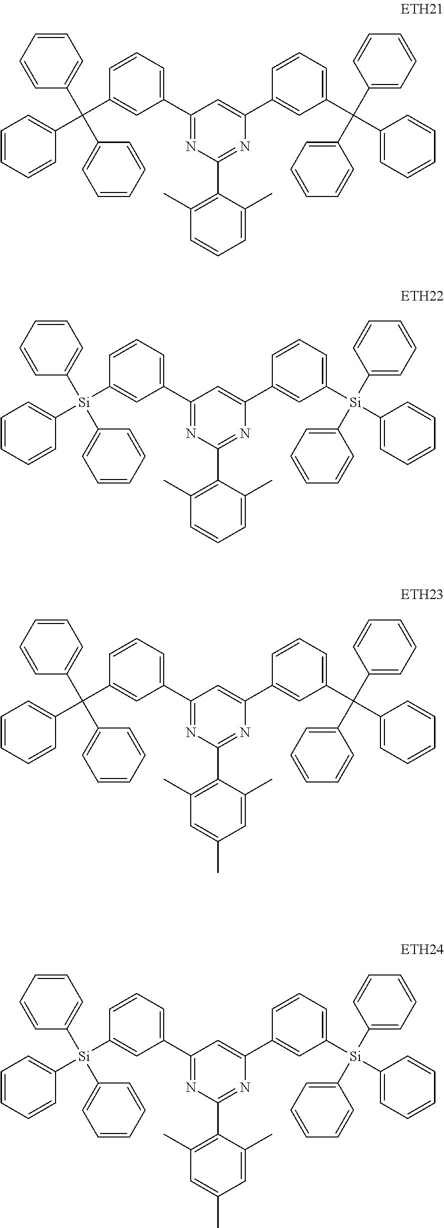 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

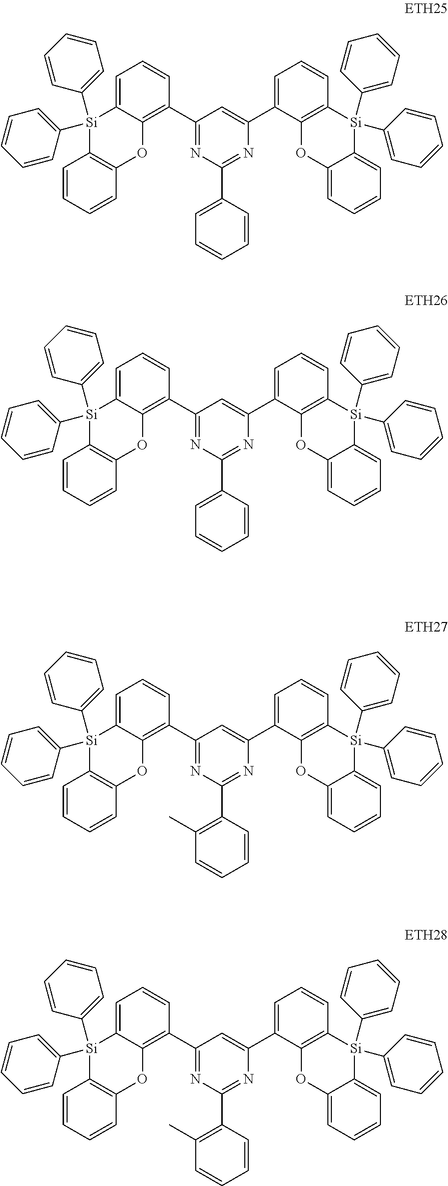 [SMILES: c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

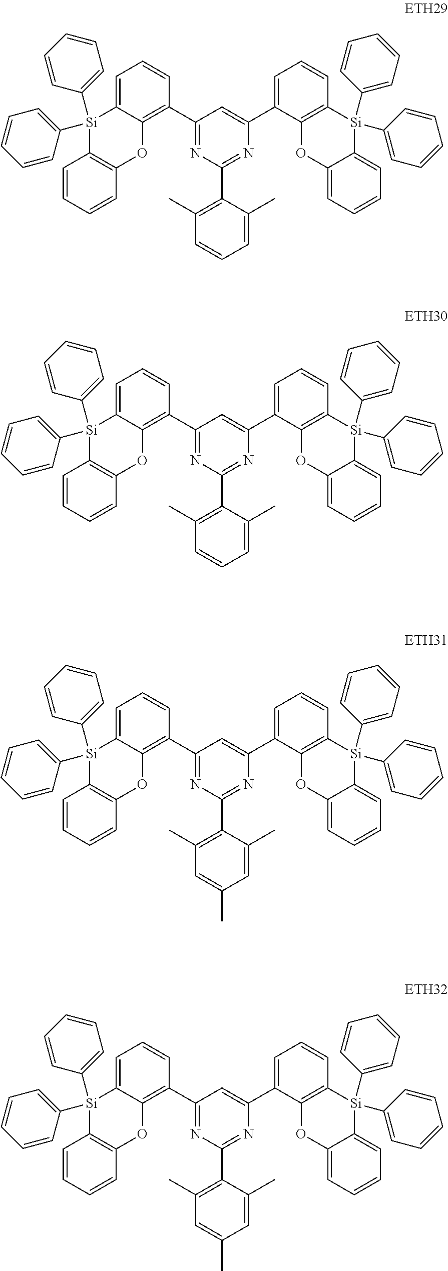 [SMILES: Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

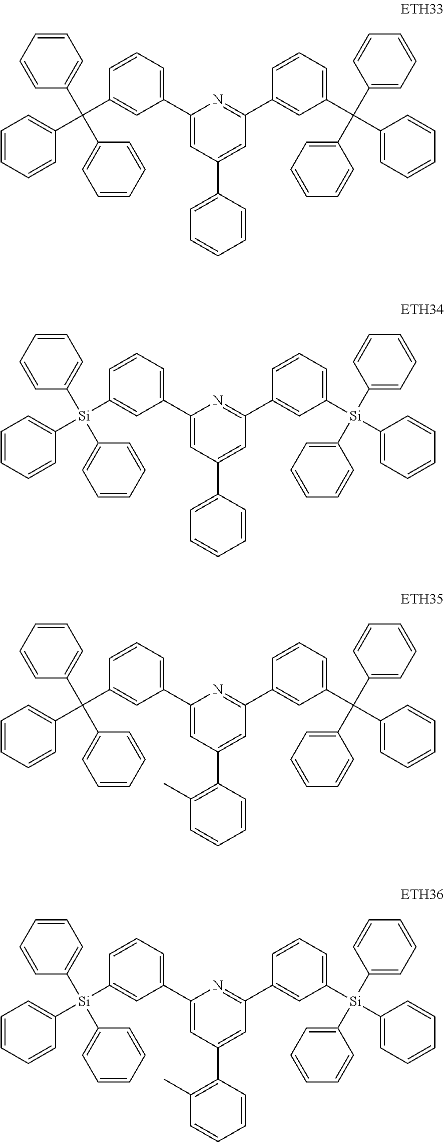 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

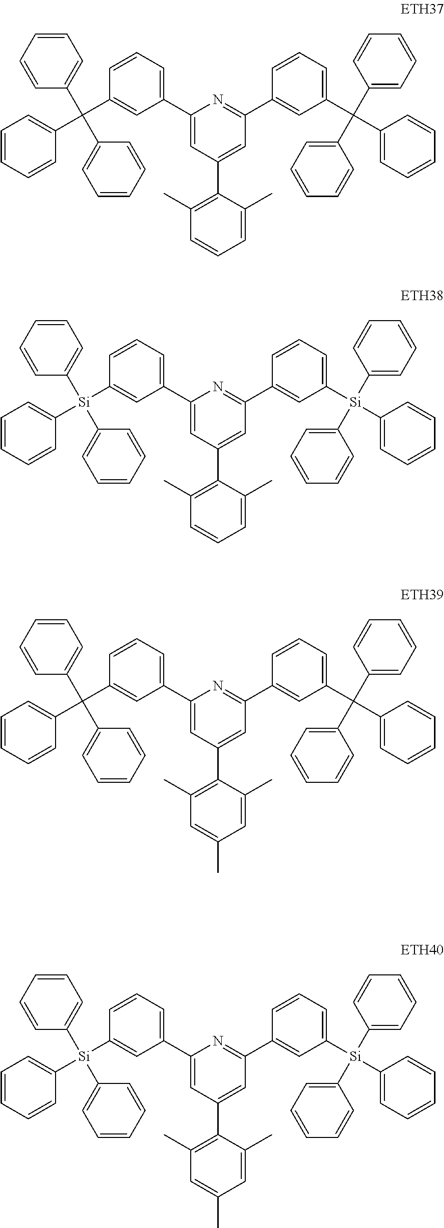 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

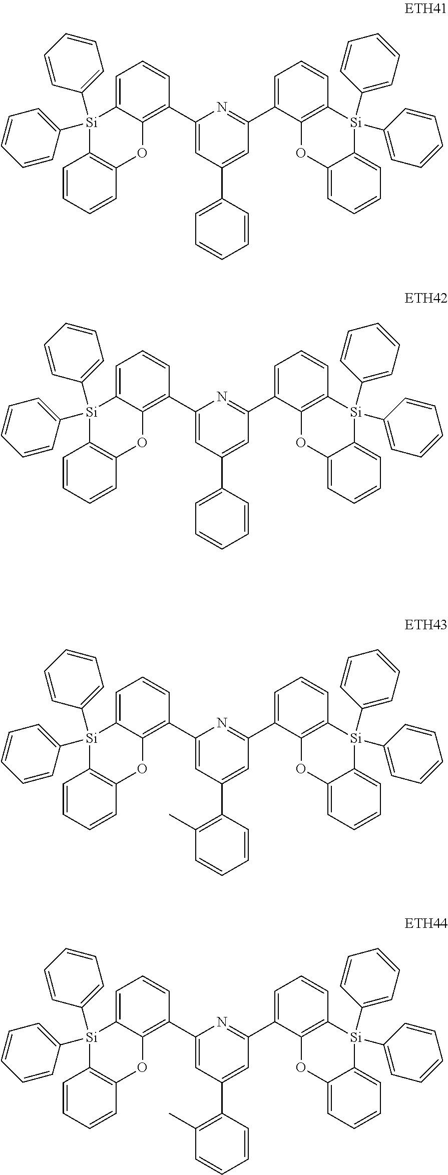 [SMILES: c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

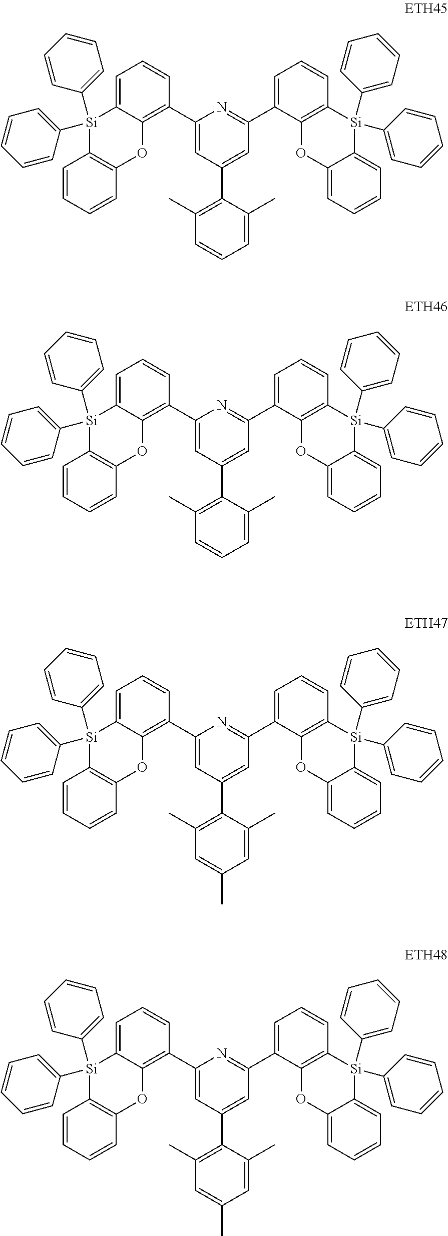 [SMILES: Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

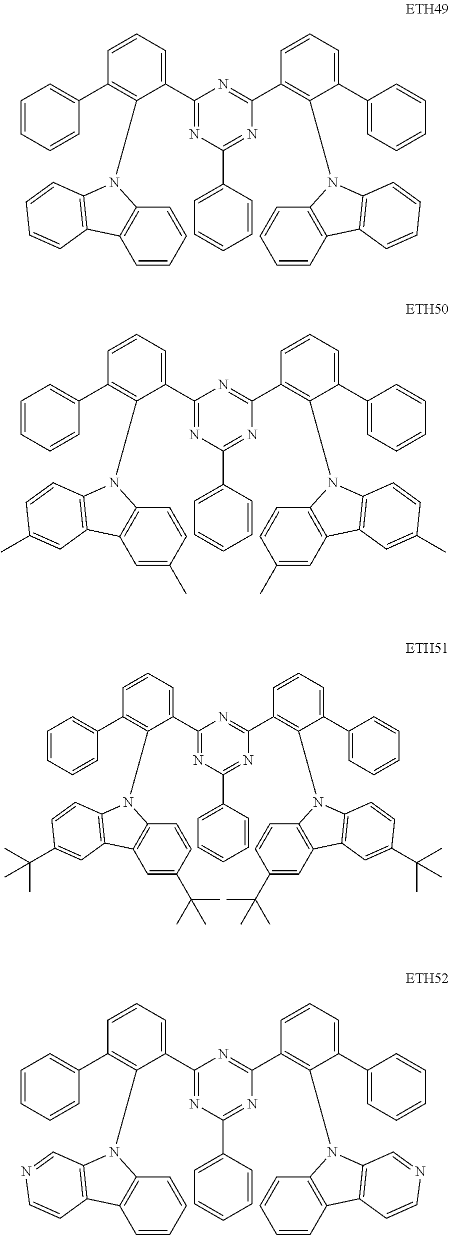

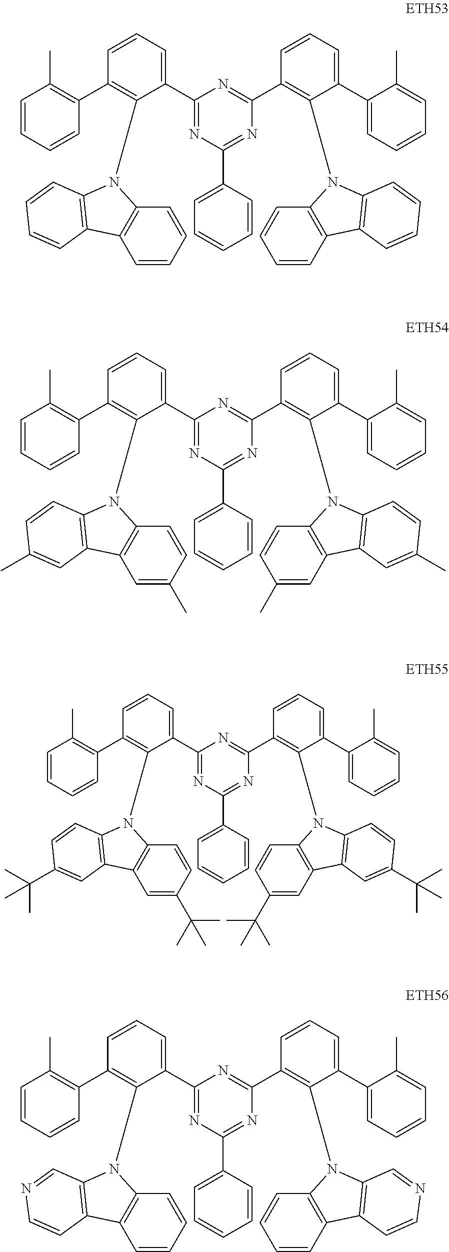

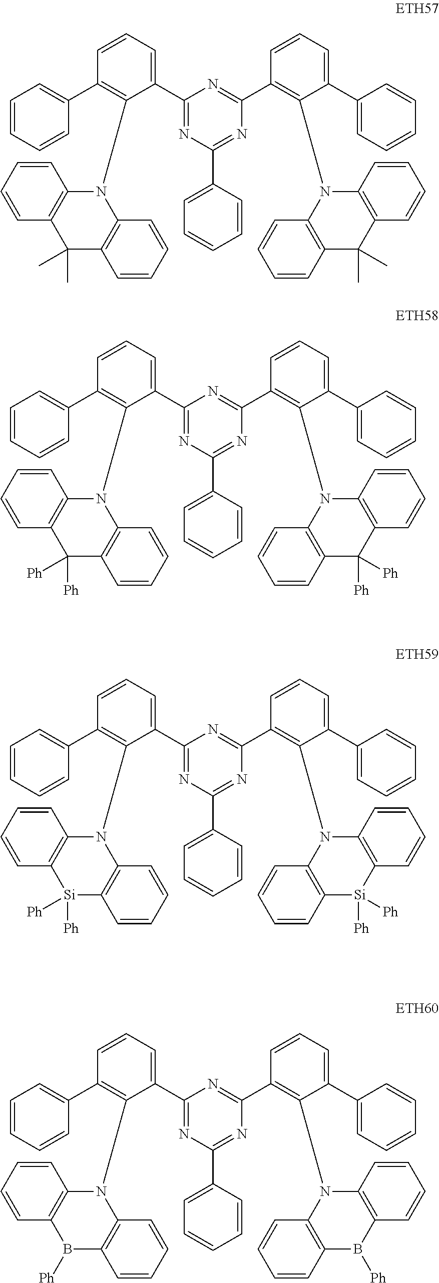

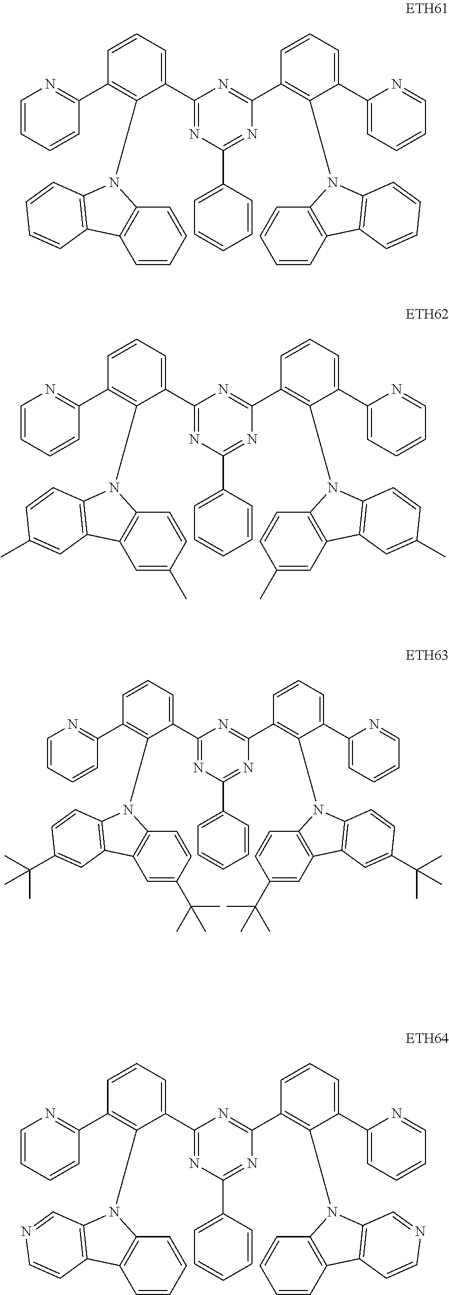

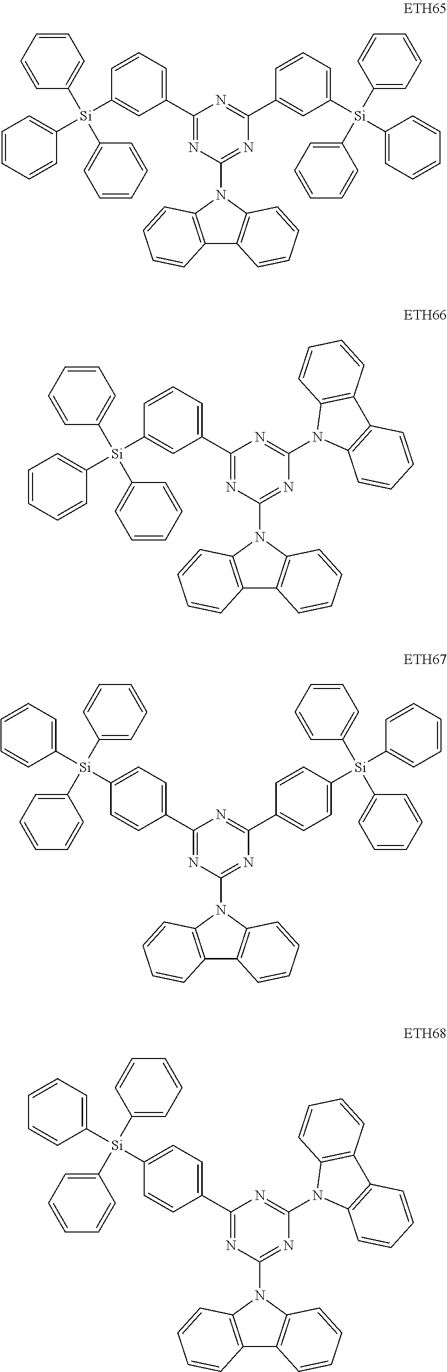 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

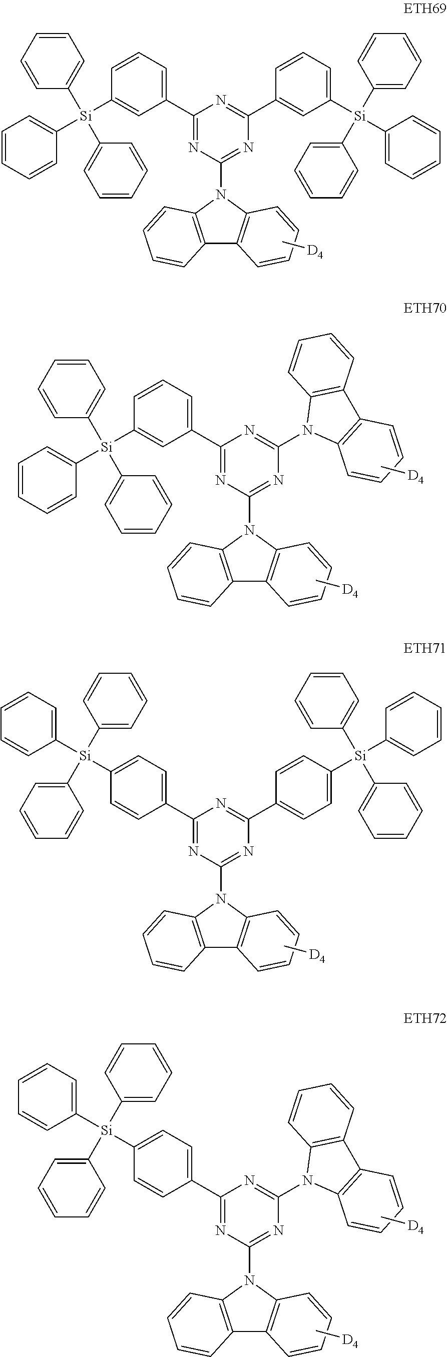

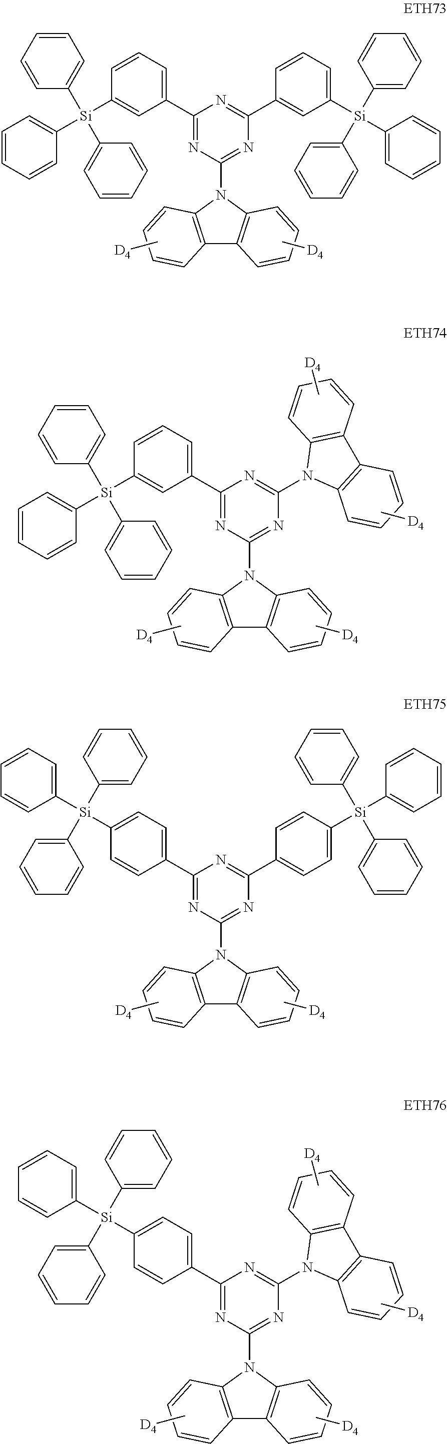

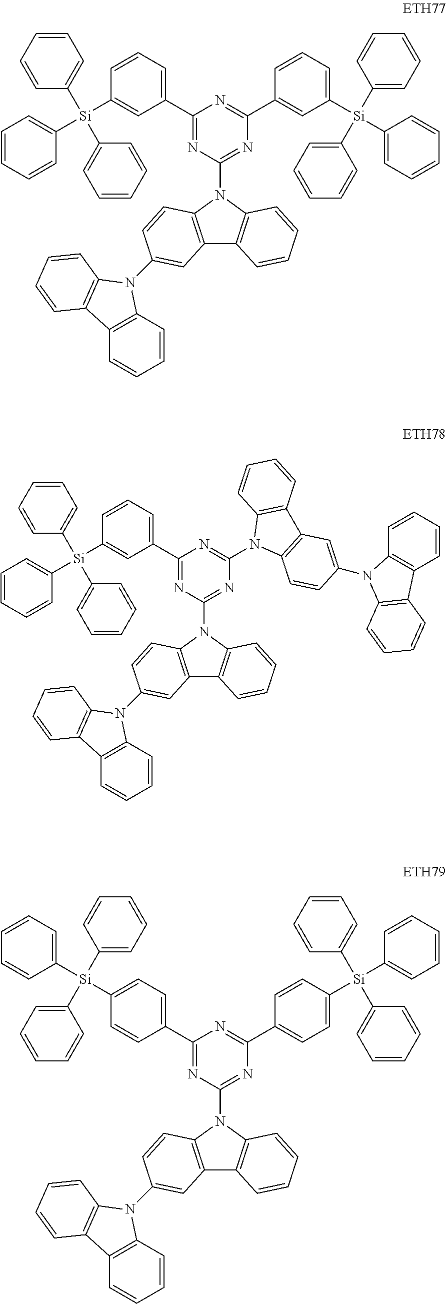 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

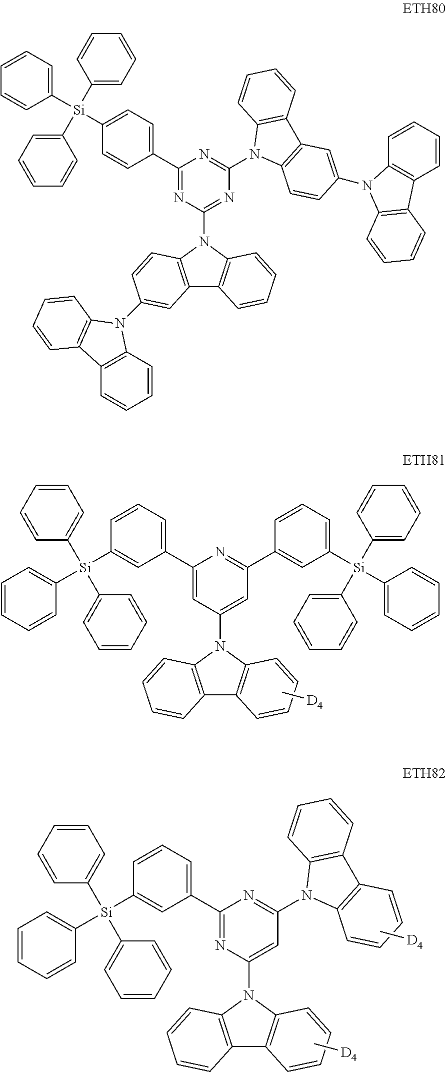

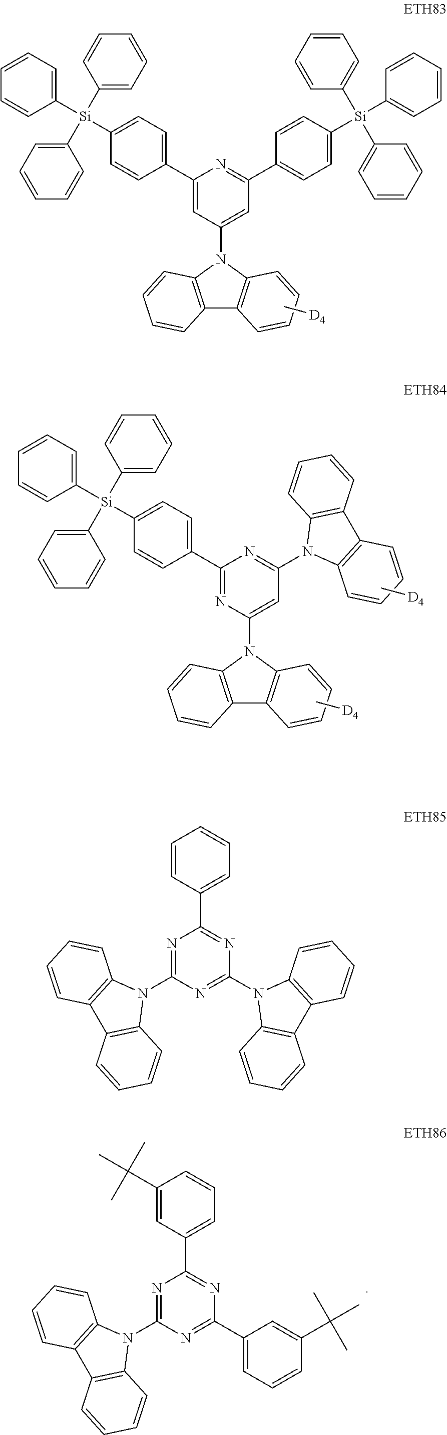

### Phosphorescent Dopant

In one or more embodiments, the emission layer may further include a phosphorescent dopant.

For example, in one or more embodiments, the emission layer may further include a phosphorescent dopant, and the phosphorescent dopant may act as a sensitizer.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may be an organometallic compound.

In one or more embodiments, the phosphorescent dopant may include an organometallic compound represented by Formula 401:

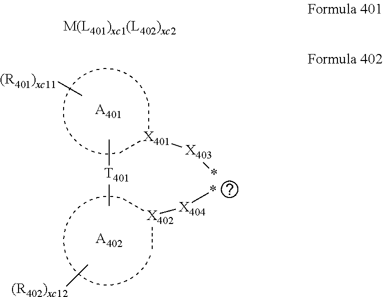

wherein, in Formulae 401 and 402,
M may be a transition metal (e.g., Ir, Pt, Pd, Os, Ti, Au, Hf, Eu, Tb, Rh, Re, or Tm),
L₄₀₁ may be a ligand represented by Formula 402, and xc1 may be 1, 2, or 3, wherein, if (e.g., when) xc1 is 2 or more, two or more of L₄₀₁(s) may be identical to or different from each other,
L₄₀₂ may be an organic ligand, and xc2 may be 0, 1, 2, 3, or 4, wherein, if (e.g., when) xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃) (Q₄₁₄),
Q₄₁₁ to Q₄₁₄ may each independently be the same as described with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described with respect to Q₁,
xc11 and xc12 may each independently be an integer from 0 to 10, and
* and *′ in Formula 402 each indicates a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two ring A₄₀₁(s) among two or more L₄₀₁(s) may optionally be linked to each other via T₄₀₂, which is a linking group, and/or two ring A₄₀₂(s) among two or more L₄₀₁(s) may optionally be linked to each other via T₄₀₃, which is a linking group (see Compounds PD1 to PD4 and PD7). T₄₀₂ and T₄₀₃ may each be the same as described with respect to T₄₀₁.

L₄₀₂ in Formula 401 may be an organic ligand. In one or more embodiments, L₄₀₂ may include a halogen, a diketone group (for example, an acetylacetonate group), a carboxylic acid group (for example, a picolinate group), —C(═O), an isonitrile group, a —CN group, a phosphorus-containing group (for example, a phosphine group, a phosphite group, and/or the like.), or any combination thereof.

In one or more embodiments, the phosphorescent dopant may include, for example, one of (e.g., be any one or include one or more selected from among) Compounds PD1 to PD41, or any combination thereof:

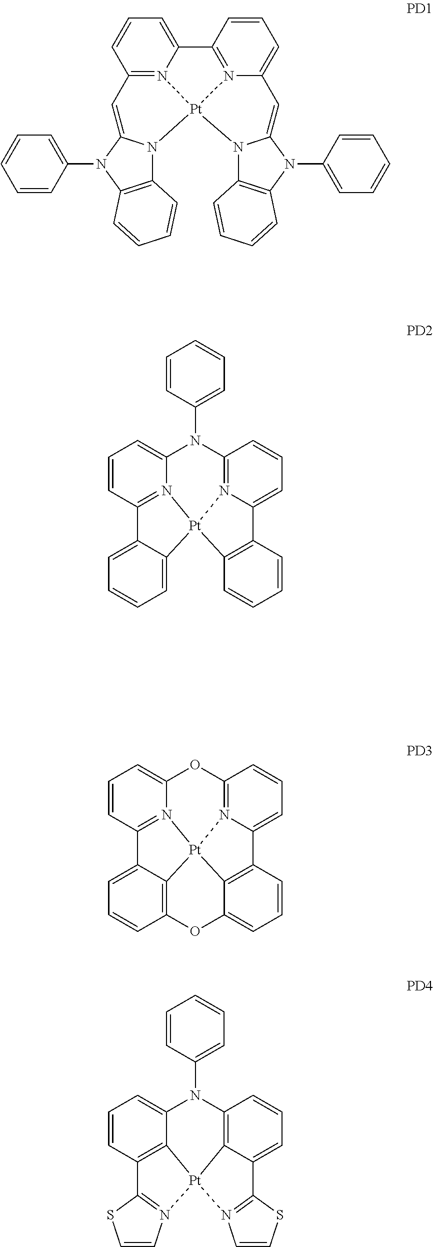

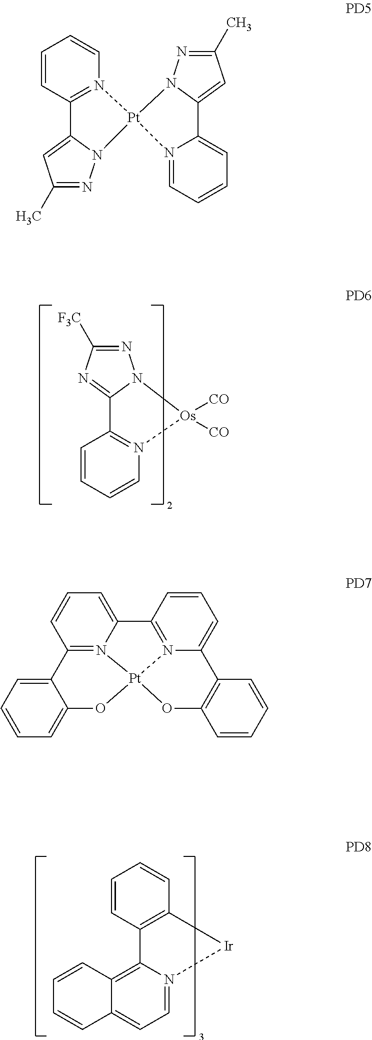

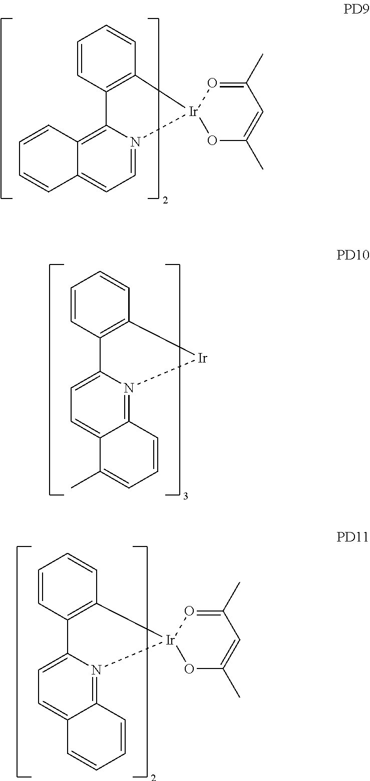

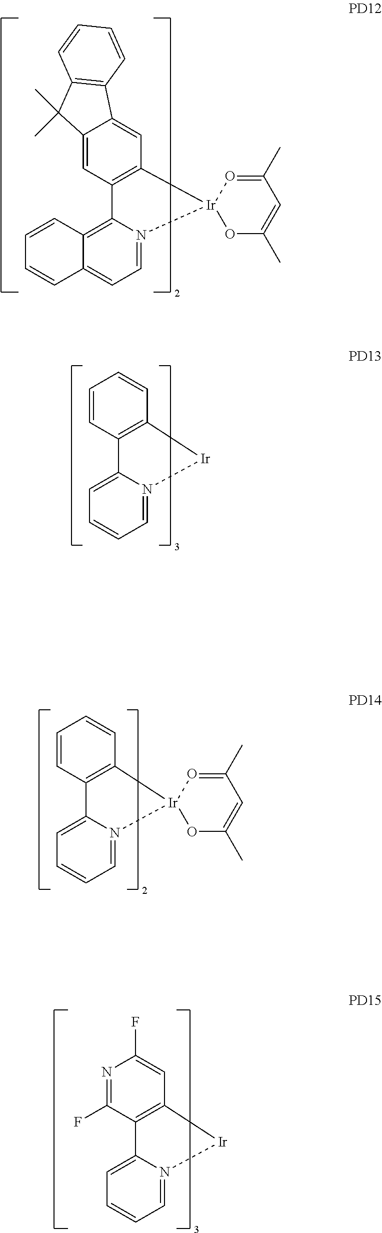

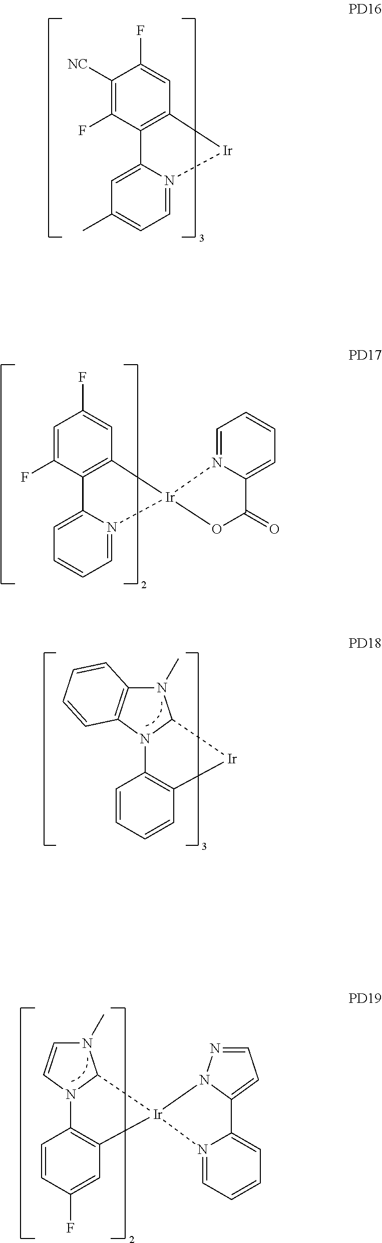

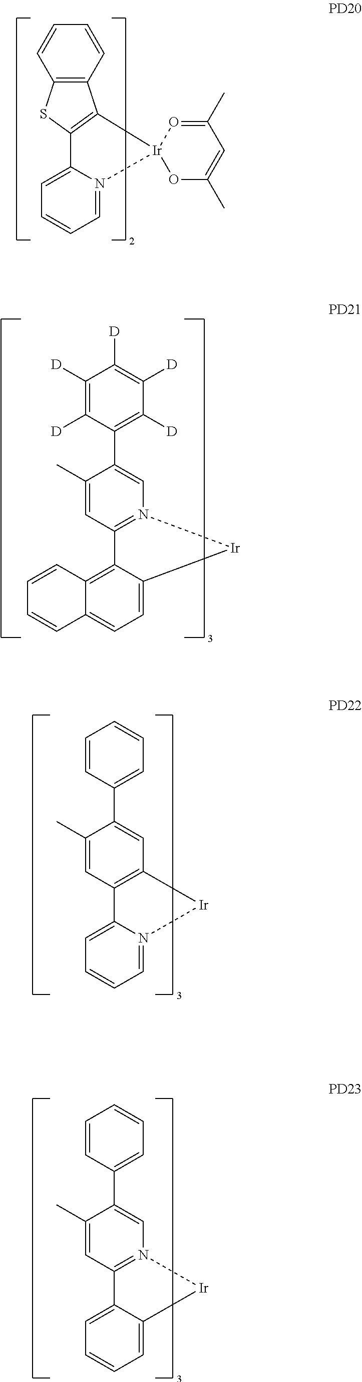

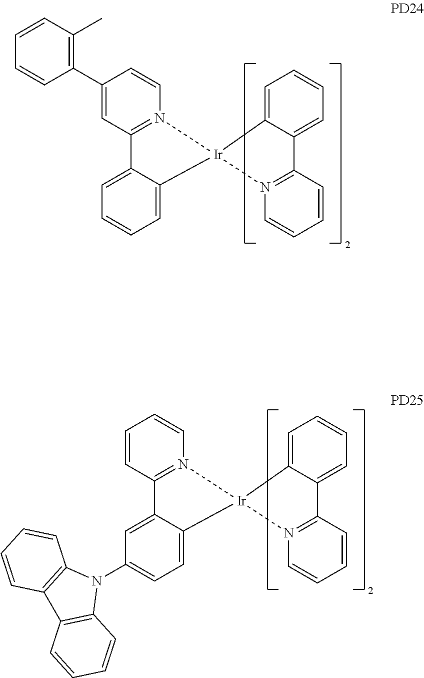

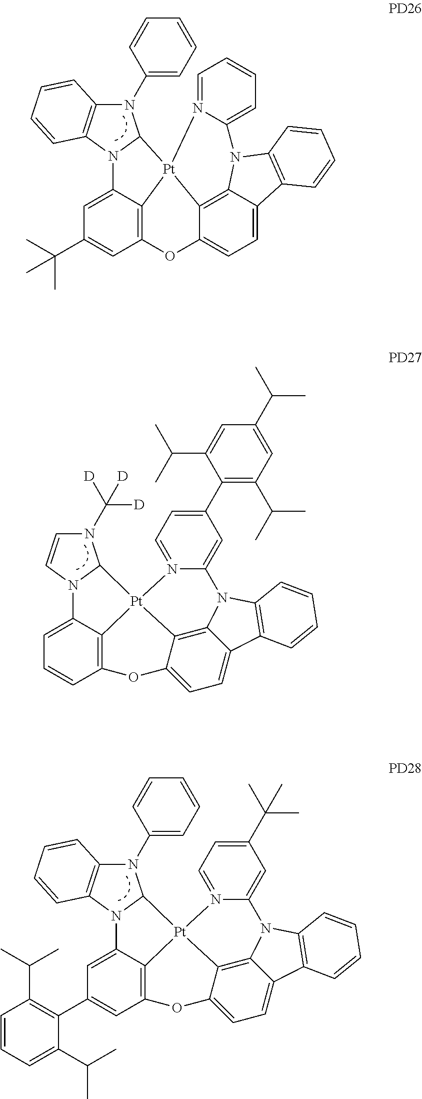

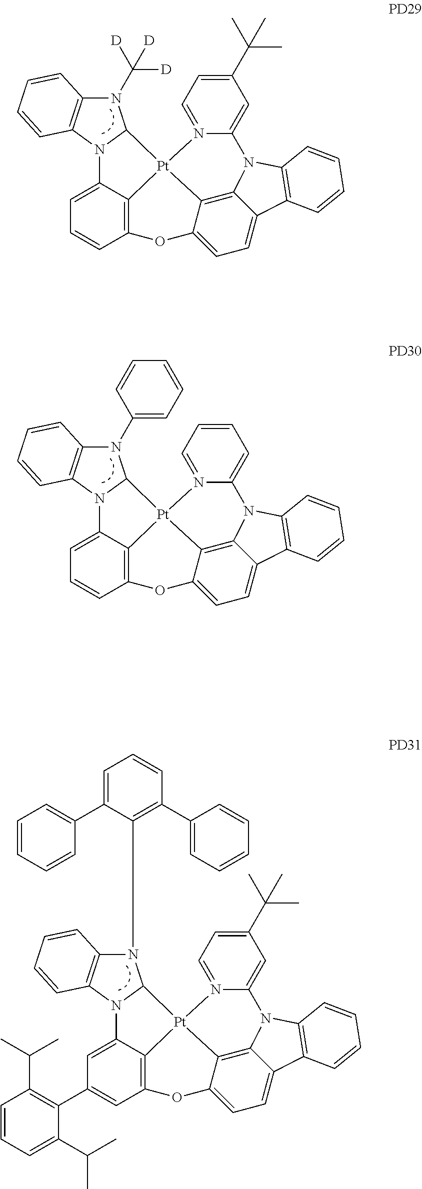

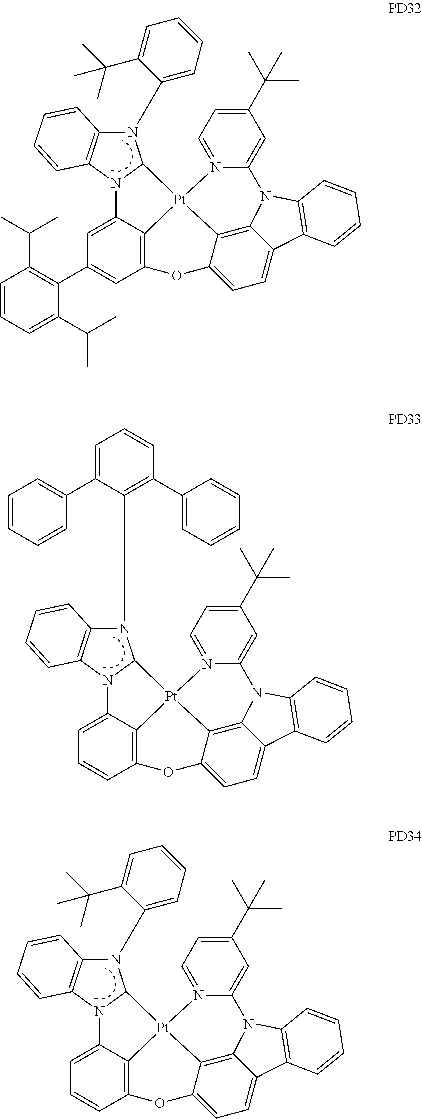

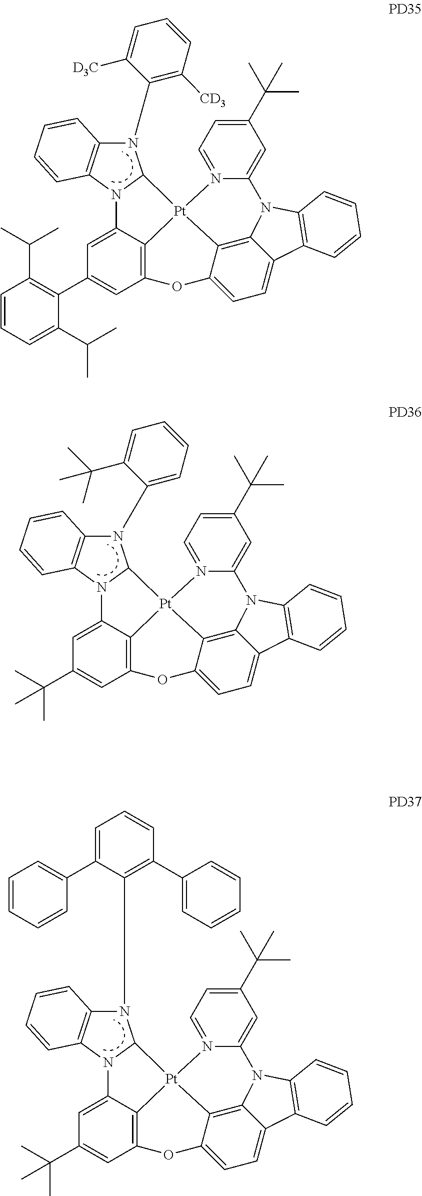

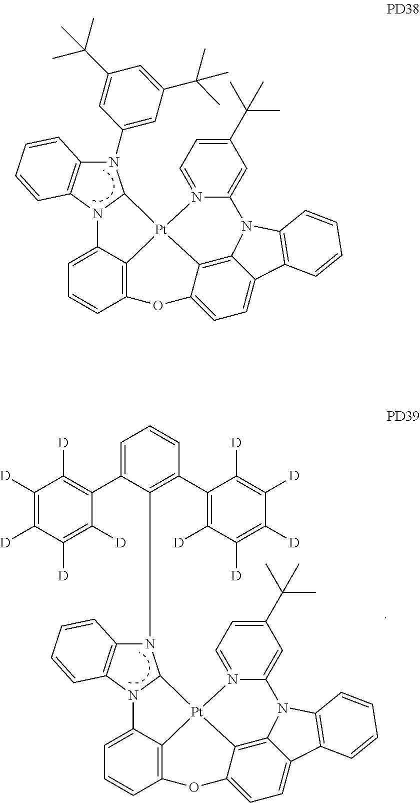

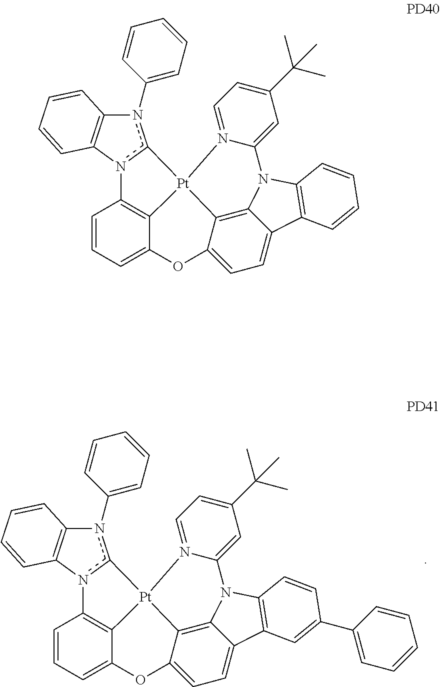

### Fluorescent Dopant

In one or more embodiments, the emission layer may further include a fluorescent dopant.

The fluorescent dopant may include an amine group-containing compound, a styryl group-containing compound, or any combination thereof.

For example, in one or more embodiments, the fluorescent dopant may include a compound represented by Formula 501:

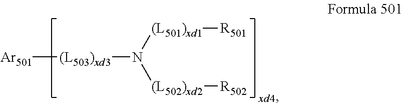

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (for example, an anthracene group, a chrysene group, a pyrene group, and/or the like) in which three or more monocyclic groups are condensed together.

In one or more embodiments, xd4 in Formula 501 may be 2.

In one or more embodiments, the fluorescent dopant may include: one of (e.g., be any one or include one or more selected from among) Compounds FD1 to FD36; 4,4′-bis(2,2-diphenylvinyl)-1,1′-biphenyl (DPVBi); 4,4′-bis[4-(N,N-diphenylamino)styryl]biphenyl (DPAVBi); or any combination thereof:

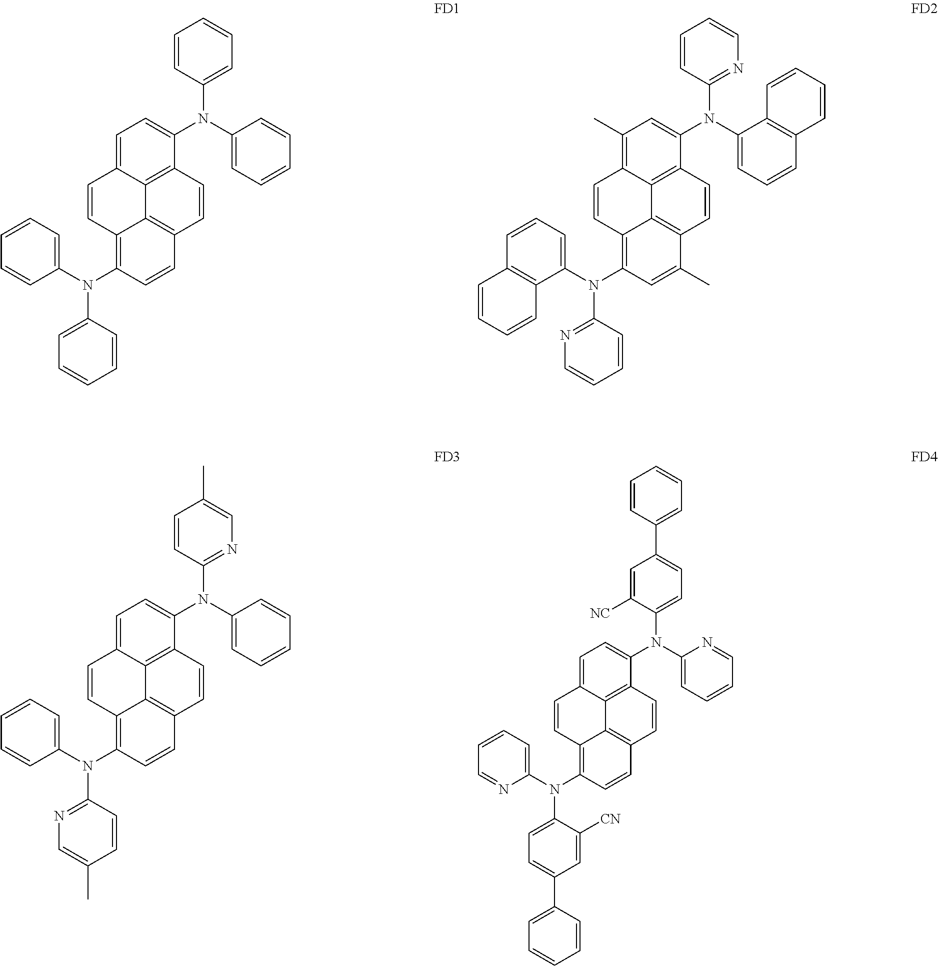 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1 ; N#Cc1cc(-c2ccccc2)ccc1N(c1ccccn1)c1ccc2ccc3c(N(c4ccccn4)c4ccc(-c5ccccc5)cc4C#N)ccc4ccc1c2c43]

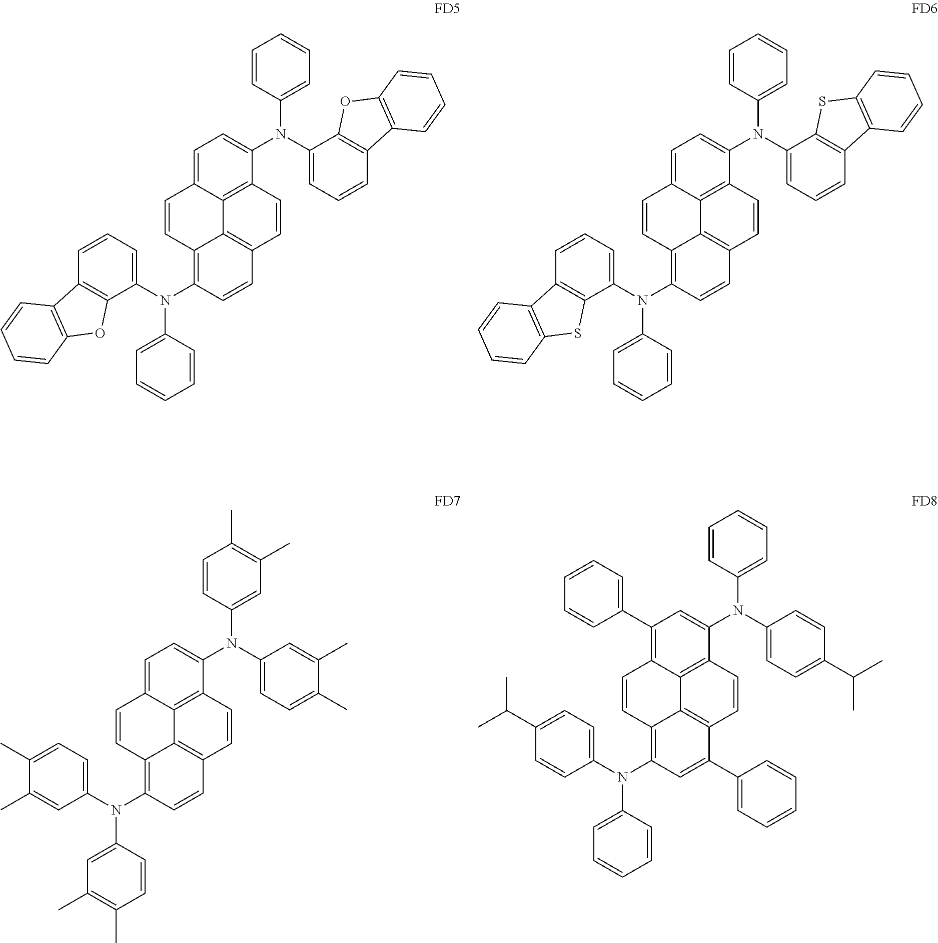

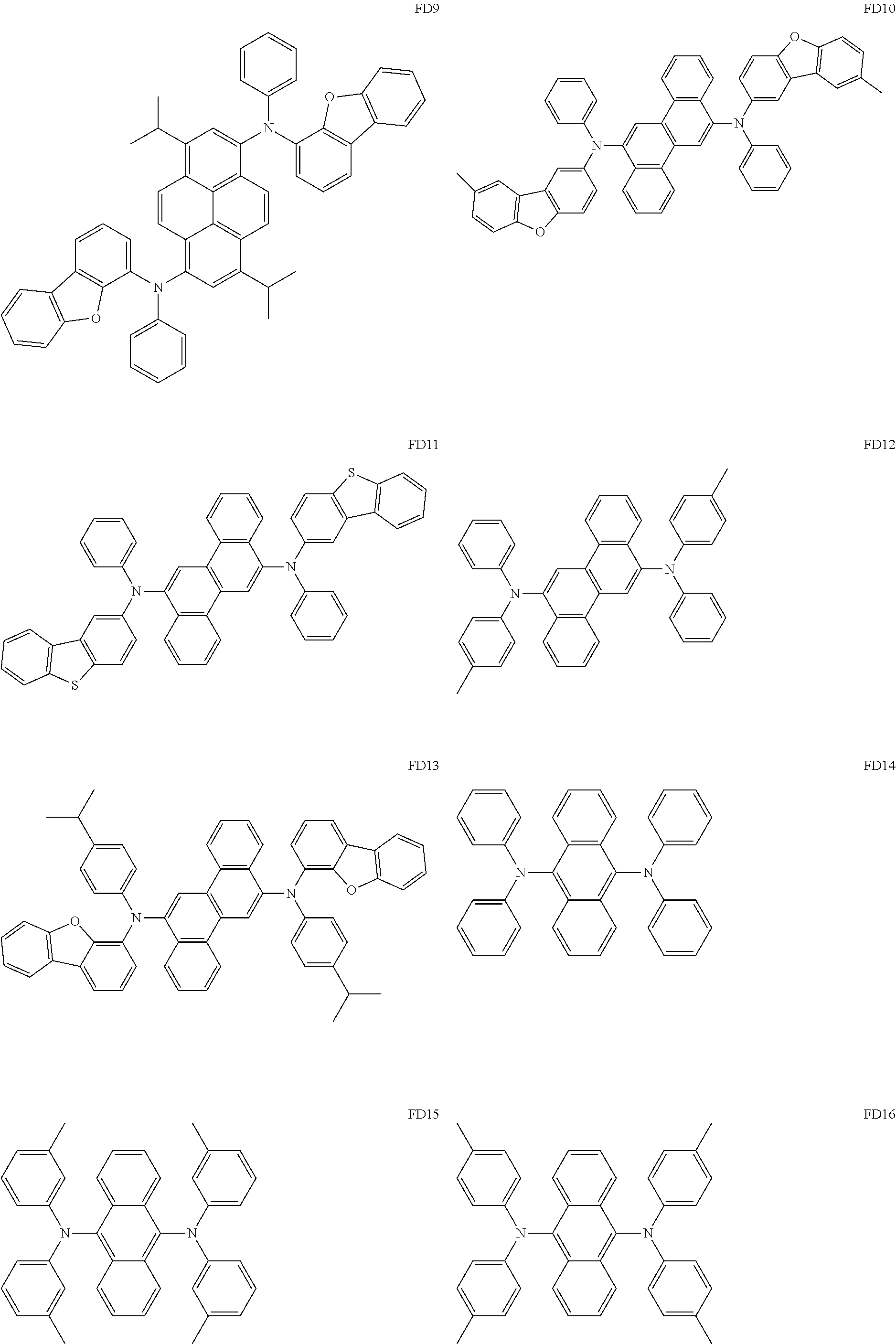

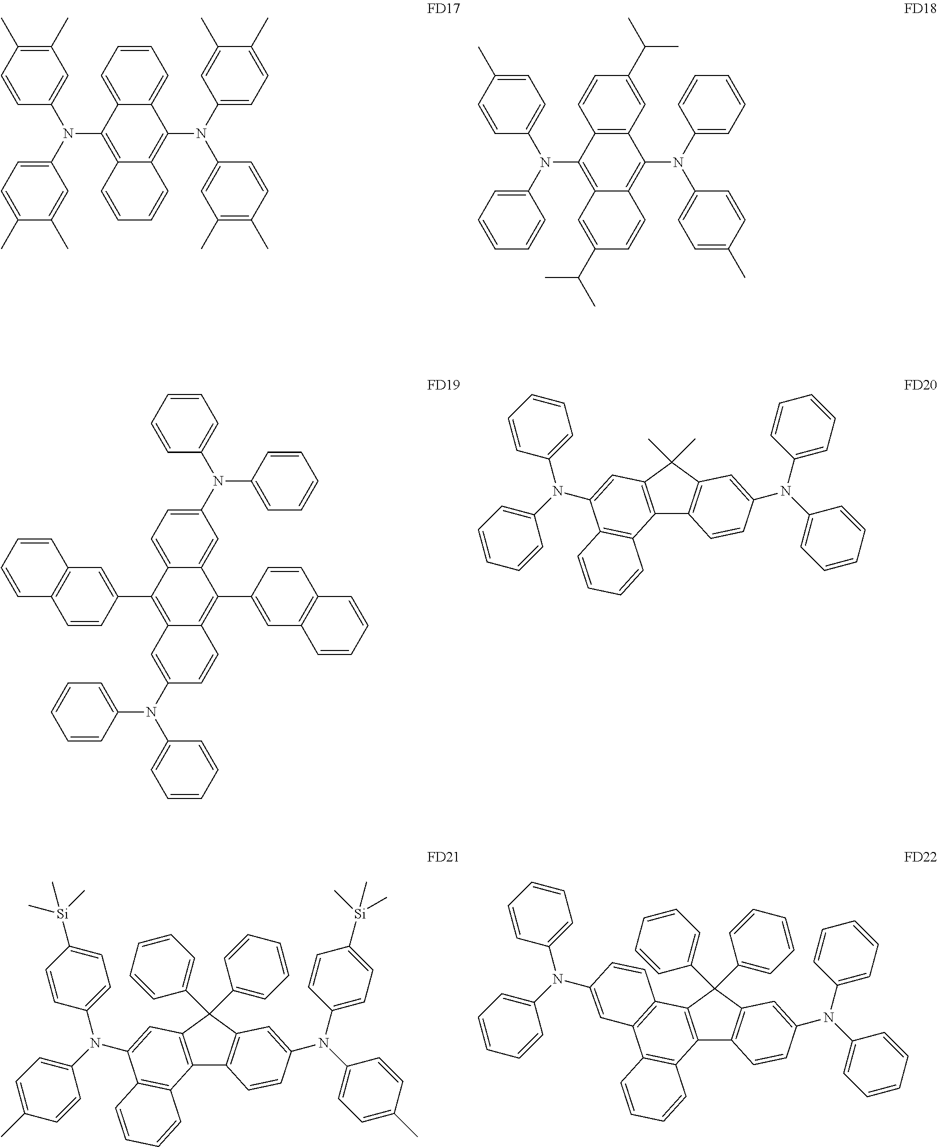

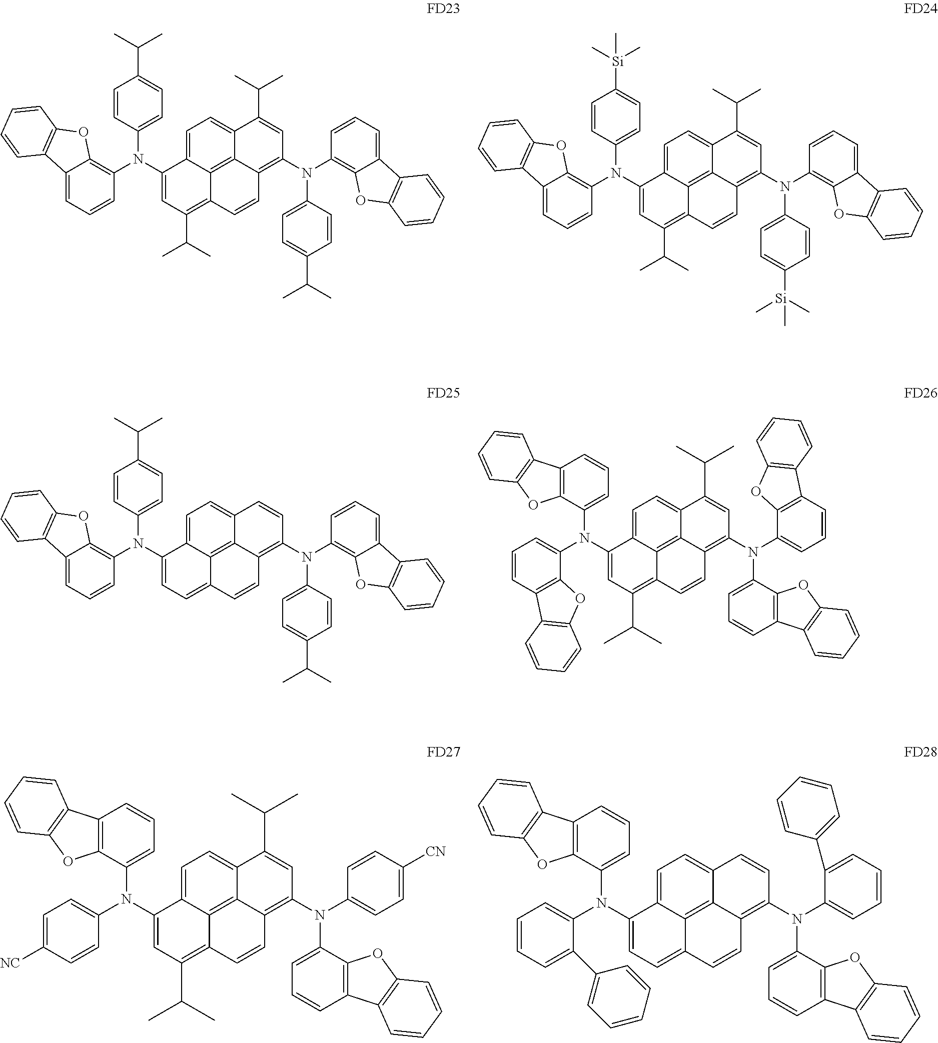

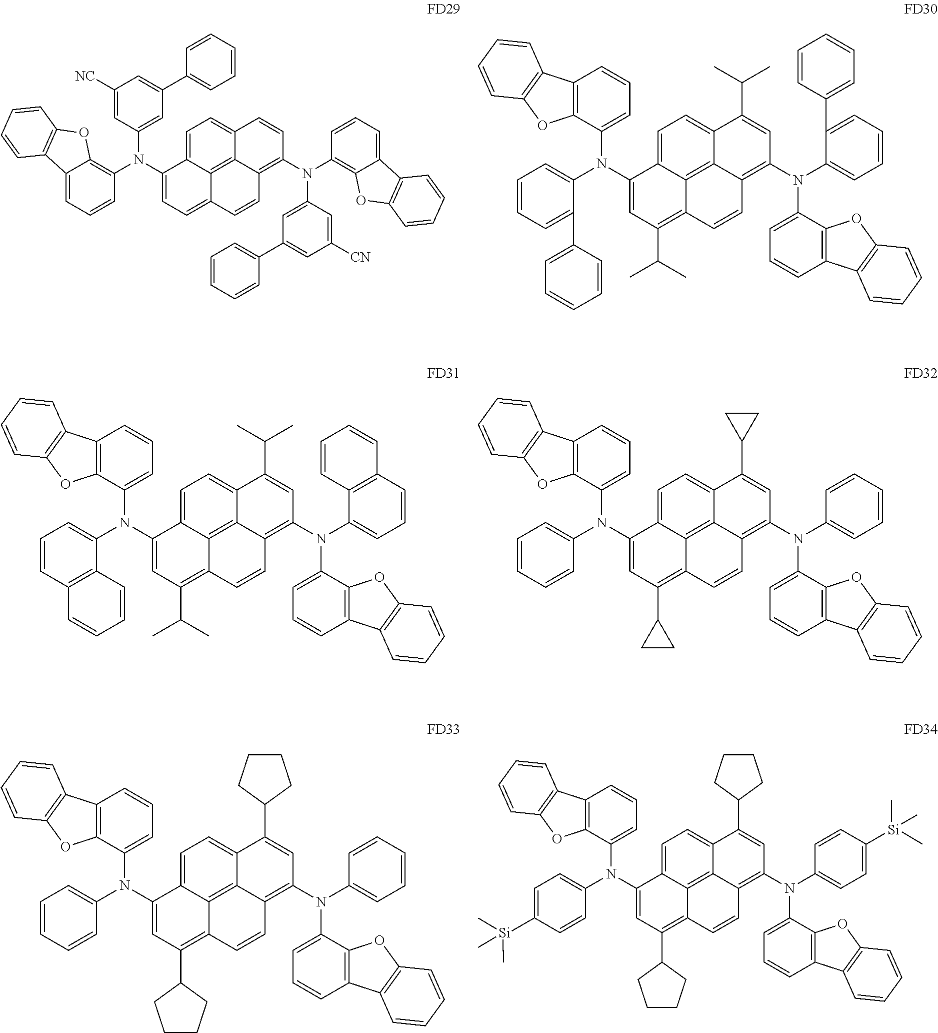

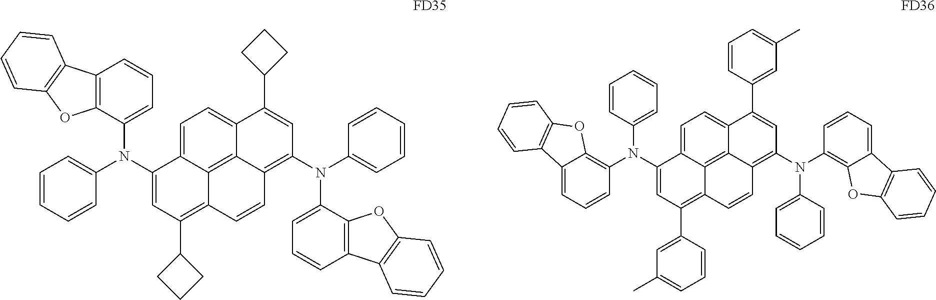 [SMILES: c1ccc(N(c2cc(C3CCC3)c3ccc4c(N(c5ccccc5)c5cccc6c5oc5ccccc56)cc(C5CCC5)c5ccc2c3c54)c2cccc3c2oc2ccccc23)cc1 ; "FD35" ; Cc1cccc(-c2cc(N(c3ccccc3)c3cccc4c3oc3ccccc34)c3ccc4c(-c5cccc(C)c5)cc(N(c5ccccc5)c5cccc6c5oc5ccccc56)c5ccc2c3c45)c1 ; "FD36"]

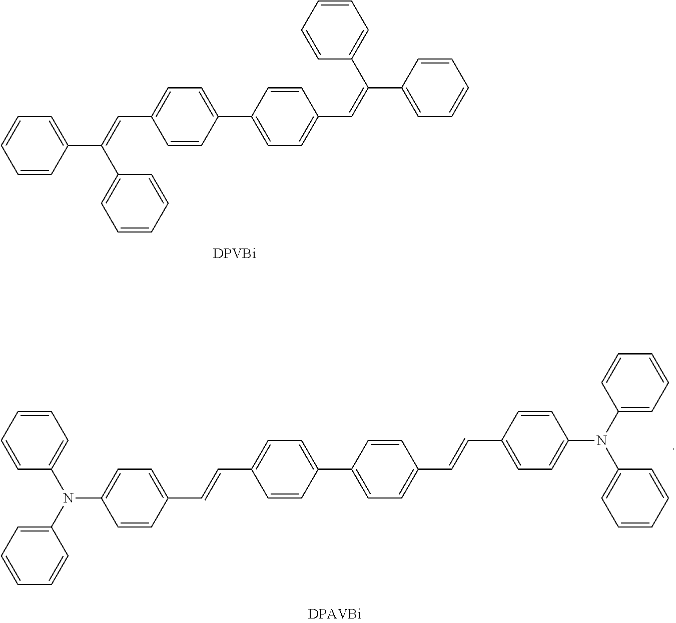

### Delayed Fluorescence Material

In one or more embodiments, the emission layer may further include a delayed fluorescence material.

The delayed fluorescence material described herein may be selected from among compounds capable of emitting delayed fluorescence based on a delayed fluorescence emission mechanism.

The delayed fluorescence material included in the emission layer may act as a host or a dopant, depending on the type (kind) of other materials included in the emission layer.

In one or more embodiments, a difference (e.g., an absolute value of the difference) between a triplet energy level (eV) of the delayed fluorescence material and a singlet energy level (eV) of the delayed fluorescence material may be in a range of about 0 eV to about 0.5 eV. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively occur, and thus, the organic light-emitting device 10 may have improved luminescence efficiency.

For example, in one or more embodiments, the delayed fluorescence material may include i) a material including at least one electron donor (e.g., a π electron-rich C₃-C₆₀ cyclic group, such as a carbazole group, and/or the like) and at least one electron acceptor (e.g., a sulfoxide group, a cyano group, a π electron-deficient nitrogen-containing C₁-C₆₀ cyclic group, and/or the like), and/or ii) a material including a C₈-C₆₀ polycyclic group in which two or more cyclic groups are condensed with each other while sharing boron (B).

In one or more embodiments, the delayed fluorescence compound may be represented by Formula 511:

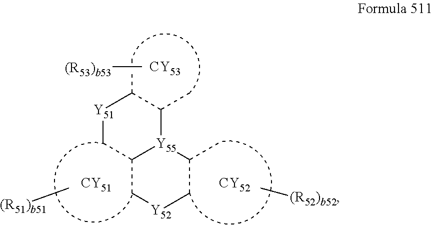

wherein, in Formula 511,
Y₅₁ and Y₅₂ may each independently be selected from among a single bond, —O—, —S—, —C(R₅₇)(R₅₈)—, —N(R₅₇)—, Si(R₅₇)(R₅₈)—, —C(═O)₂—, —S(═O)₂—, —B(R₅₇)—, —P(R₅₇)—, and —P(═O)(R₅₇)—,
Y₅₃ may be N, B, P, P(═O), or P(═S),
A₅₁ to A₅₃ may each independently be a C₅-C₆₀ carbocyclic group or a C₁-C₆₀ heterocyclic group,
R₅₁ to R₅₃, R₅₇, and R₅₈ may each independently be hydrogen, deuterium, —F, —Cl, —Br, —I, a hydroxyl group, a cyano group, a nitro group, an amidino group, a hydrazino group, a hydrazono group, a substituted or unsubstituted C₁-C₂₀ alkyl group, a C₁-C₂₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₄₁)(Q₄₂)(Q₄₃), —N(Q₄₁)(Q₄₂), —B(Q₄₁)(Q₄₂), —C(═O)(Q₄₁), —S(═O)₂(Q₄₁), or —P(═O)(Q₄₁)(Q₄₂),
b51 to b53 may each independently be 1, 2, 3, 4, 5, 6, 7, or 8,
R₁₀ₐ may be:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁ to Q₃₃, and Q₄₁ to Q₄₃ may each independently be: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

Non-limiting examples of the delayed fluorescence material may include at least one of (e.g., one or more selected from among) Compounds DF1 to DF9:

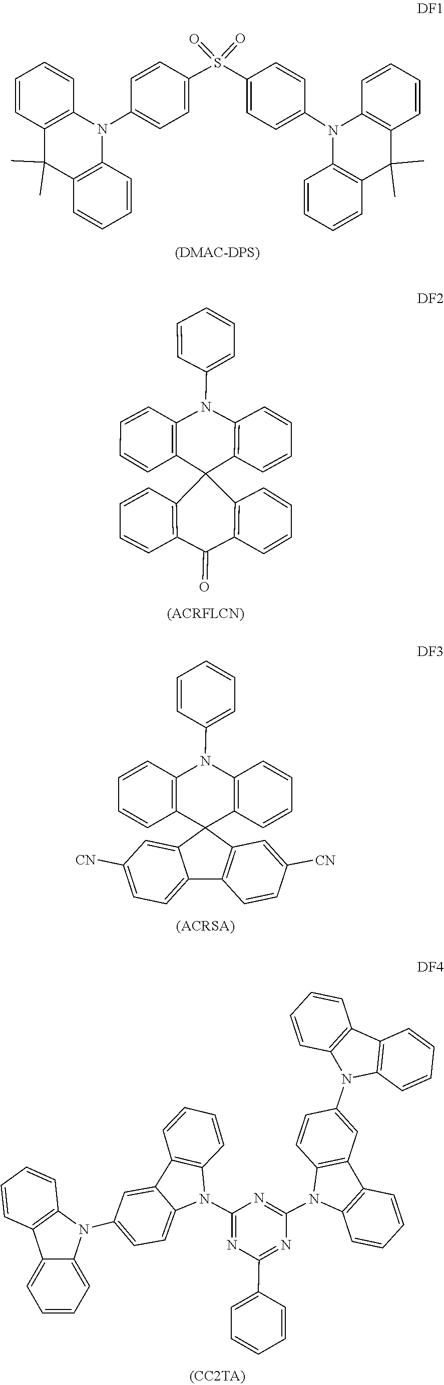

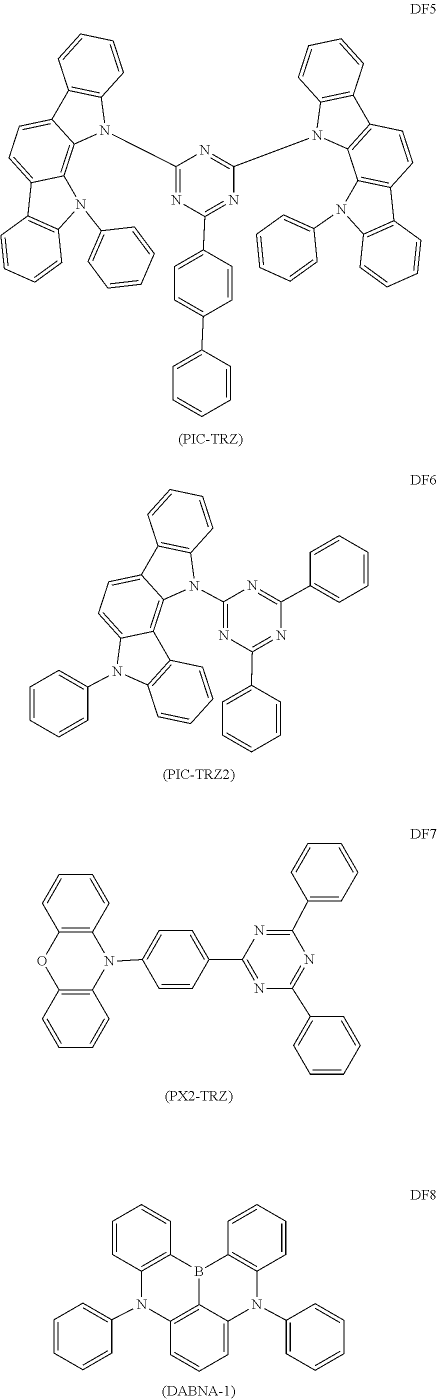

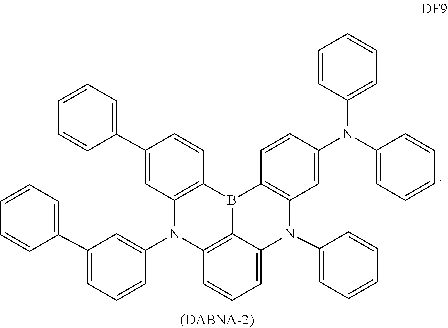

### Quantum Dots

In one or more embodiments, the emission layer may include quantum dots.

The term “quantum dots” as used herein refers to crystals of a semiconductor compound, and may include any material capable of emitting light of one or more suitable emission wavelengths according to the size of the crystals.

A diameter of the quantum dots may be, for example, in a range of about 1 nm to about 10 nm. In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dots may be synthesized by a wet chemical process, a metal organic chemical vapor deposition process, a molecular beam epitaxy process, or any process similar thereto.

The wet chemical process is a method including mixing a precursor material of a quantum dot with an organic solvent and then growing quantum dot particle crystals. When the crystals grow, the organic solvent naturally acts as a dispersant coordinated on the surface of the quantum dot crystal and controls the growth of the crystals so that the growth of quantum dot particles may be controlled or selected through a process which costs lower and is easier than vapor deposition methods, such as metal organic chemical vapor deposition (MOCVD) or molecular beam epitaxy (MBE).

The quantum dots may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Non-limiting examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

Non-limiting examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and/or the like; or any combination thereof. In one or more embodiments, the Group III-V semiconductor compound may further include a Group II element. Non-limiting examples of the Group III-V semiconductor compound further including a Group II element may include InZnP, InGaZnP, InAlZnP, and/or the like.

Non-limiting examples of the Group III-VI semiconductor compound may include: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; or any combination thereof.

Non-limiting examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and/or the like; a quaternary compound, such as AgInGaS, AgInGaS₂, AgInGaSe, AgInGaSe₂, CuInGaS, CuInGaS₂, and/or the like; or any combination thereof.

Non-limiting examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

The Group IV element or compound may include: a single element compound, such as Si, Ge, and/or the like; a binary compound, such as SiC, SiGe, and/or the like; or any combination thereof.

Each element included in a multi-element compound, such as the binary compound, the ternary compound, and the quaternary compound, may be present at a substantially uniform concentration or non-uniform concentration in a particle.

In one or more embodiments, the quantum dots may have a single structure in which the concentration of each element in the quantum dots is substantially uniform, or a core-shell dual structure. For example, materials included in the core and materials included in the shell may be different from each other.

The shell of the quantum dots may act as a protective layer that prevents chemical degeneration of the core to maintain semiconductor characteristics, and/or as a charging layer that imparts electrophoretic characteristics to the quantum dots. The shell may be single-layered or multi-layered. An interface between the core and the shell may have a concentration gradient in which the concentration of an element existing in the shell decreases toward the center of the core.

Examples of the shell of the quantum dots may include: an oxide of metal, metalloid, or non-metal; a semiconductor compound: or any combination thereof. Non-limiting examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or any combination thereof. Examples of the semiconductor compound may include: as described above, a Group II-VI semiconductor compound; a Group III-V semiconductor compound; a Group III-VI semiconductor compound; a Group I-III-VI semiconductor compound; a Group IV-VI semiconductor compound; or any combination thereof. Non-limiting examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width of half maximum (FWHM) of an emission spectrum of the quantum dots may be about 45 nm or less, for example, about 40 nm or less, or for example, about 30 nm or less, and within these ranges, the color purity or color reproducibility of the quantum dots may be improved. In addition, because light emitted through the quantum dots is emitted in all directions, the wide viewing angle may be improved.

In addition, the quantum dots may be nanoparticles, nanotubes, nanowires, nanofibers, nanoplates, and/or the like, for example, in the form of spherical particles, pyramidal particles, multi-arm particles, or cubic particles.

By controlling the size of the quantum dots, the energy band gap of the quantum dots may be adjustable so that light having one or more suitable wavelength bands may be obtained from the emission layer including the quantum dots. Accordingly, by using quantum dots of different sizes, the organic light-emitting device that emits light of one or more suitable wavelengths may be implemented. In one or more embodiments, the size of quantum dots may be selected to enable the quantum dots to emit red light, green light, and/or blue light. In addition, the quantum dots with suitable size may be configured to emit white light by combining light of one or more suitable colors.

### Electron Transport Region in Interlayer 130

The electron transport region may have: i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The electron transport region may include a buffer layer, a hole blocking layer, an electron control layer, an electron transport layer, an electron injection layer, or any combination thereof.

For example, in one or more embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers in each structure may be sequentially stacked from the emission layer in the stated order.

In one or more embodiments, the electron transport region (e.g., the buffer layer, the hole blocking layer, the electron control layer, or the electron transport layer in the electron transport region) may include a metal-free compound including at least one π electron-deficient nitrogen-containing C₁-C₆₀ cyclic group.

For example, in one or more embodiments, the electron transport region may include a compound represented by Formula 601:

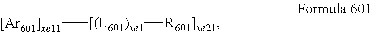

wherein, in Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, if (e.g., when) xe11 in Formula 601 is 2 or more, two or more of Ar₆₀₁(s) may be linked together via a single bond.

In one or more embodiments, Ar₆₀₁ in Formula 601 may be an anthracene group unsubstituted or substituted with at least one R₁₀ₐ.

In one or more embodiments, the electron transport region may include a compound represented by Formula 601-1:

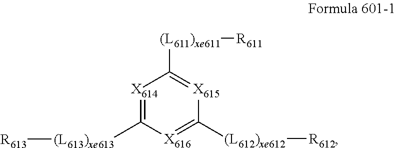

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each be the same as described with respect to L₆₀₁,
xe611 to xe613 may each be the same as described with respect to xe1,
R₆₁₁ to R₆₁₃ may each be the same as described with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, xe1 and xe611 to xe613 in Formulae 601 and 601-1 may each independently be 0, 1, or 2.

In one or more embodiments, the electron transport region may include at least one of (e.g., one or more selected from among) Compounds ET1 to ET45, 2,9-dimethyl-4,7-diphenyl-1,10-phenanthroline (BCP), 4,7-diphenyl-1,10-phenanthroline (Bphen), tris(8-hydroxyquinolinato)aluminum (Alq₃), bis(2-methyl-8-quinolinolato-N1,O8)-(1,1′-biphenyl-4-olato)aluminum (BAlq), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), or any combination thereof:

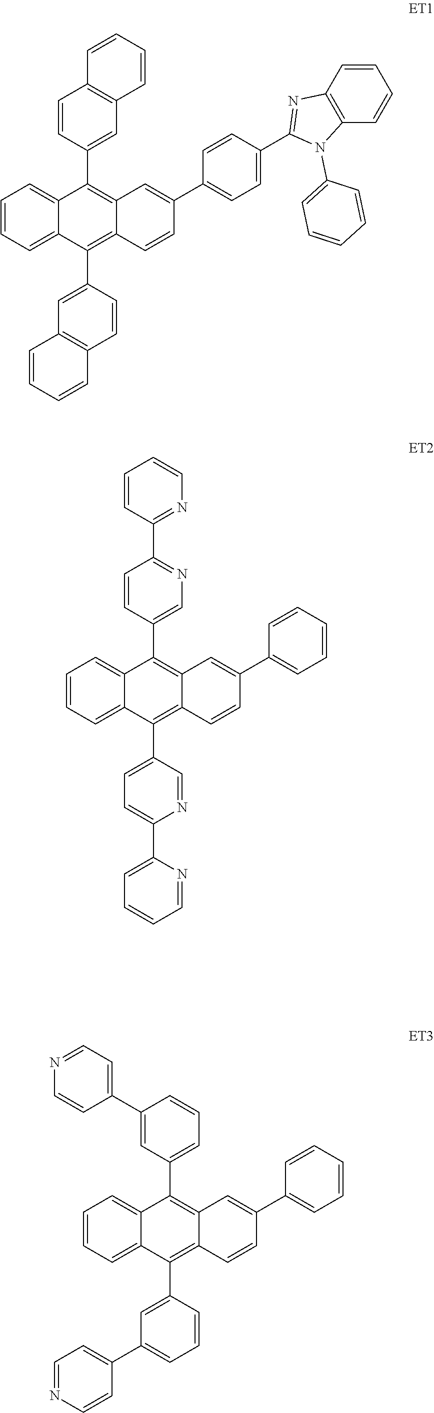 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

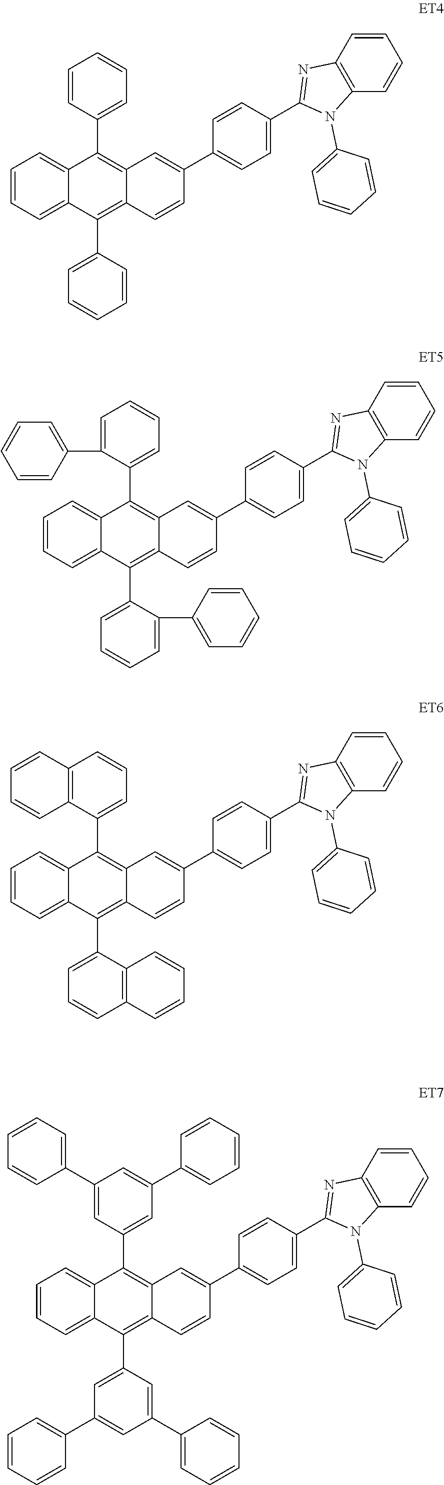 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

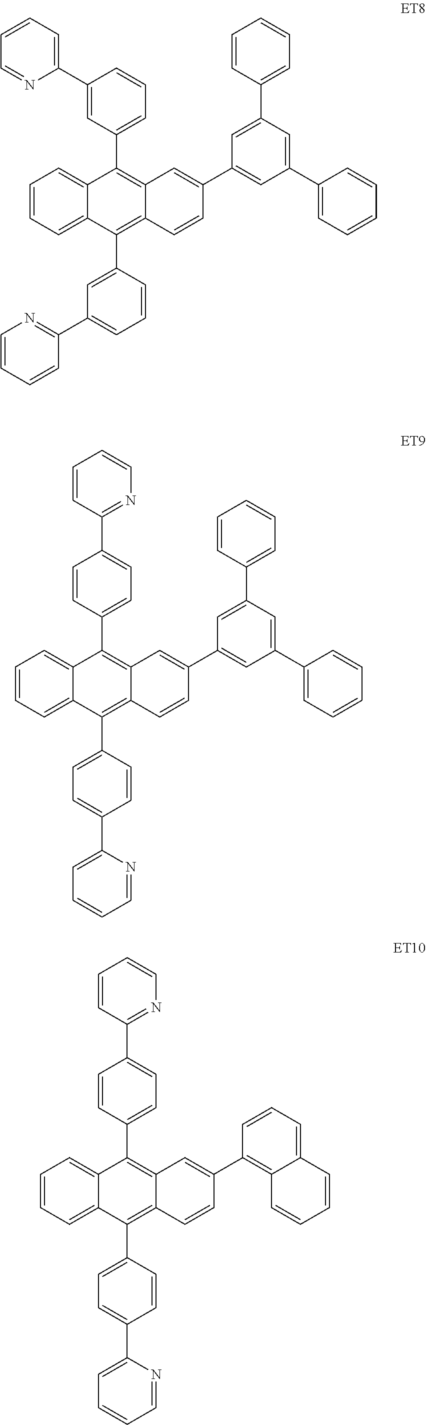 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

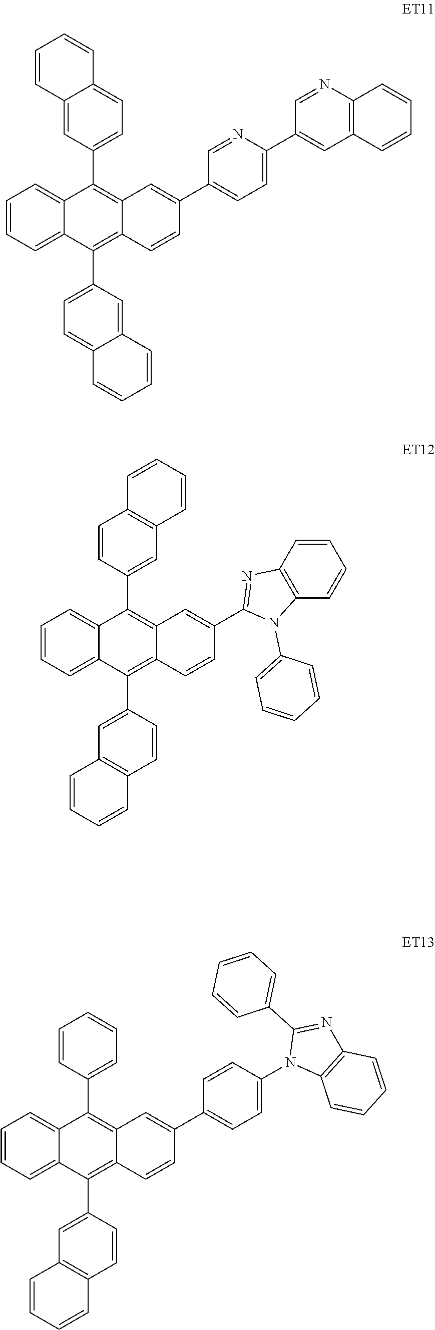 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

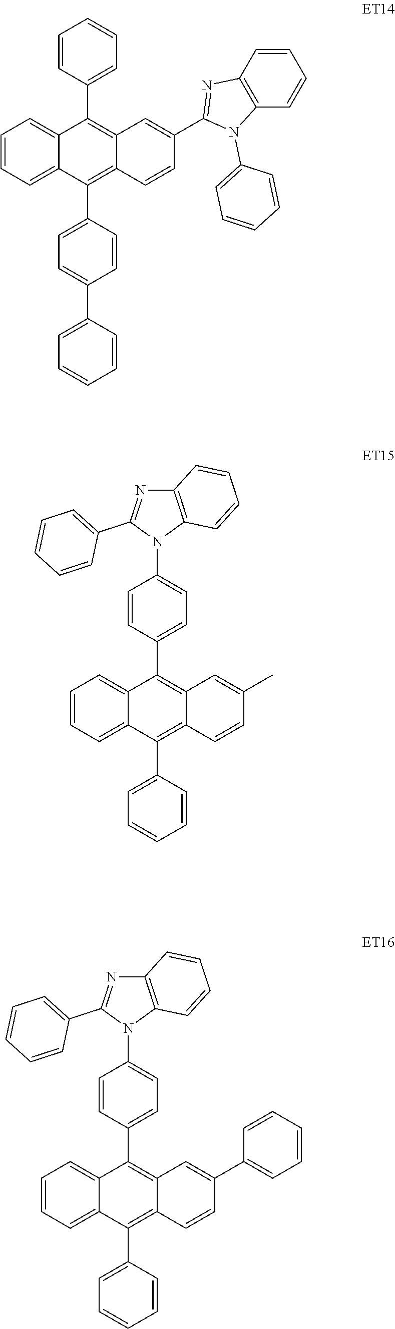 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

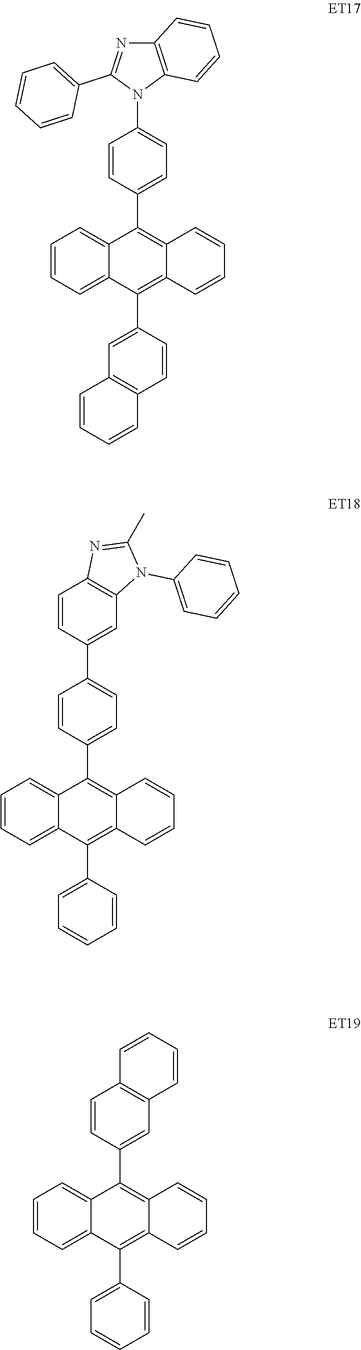

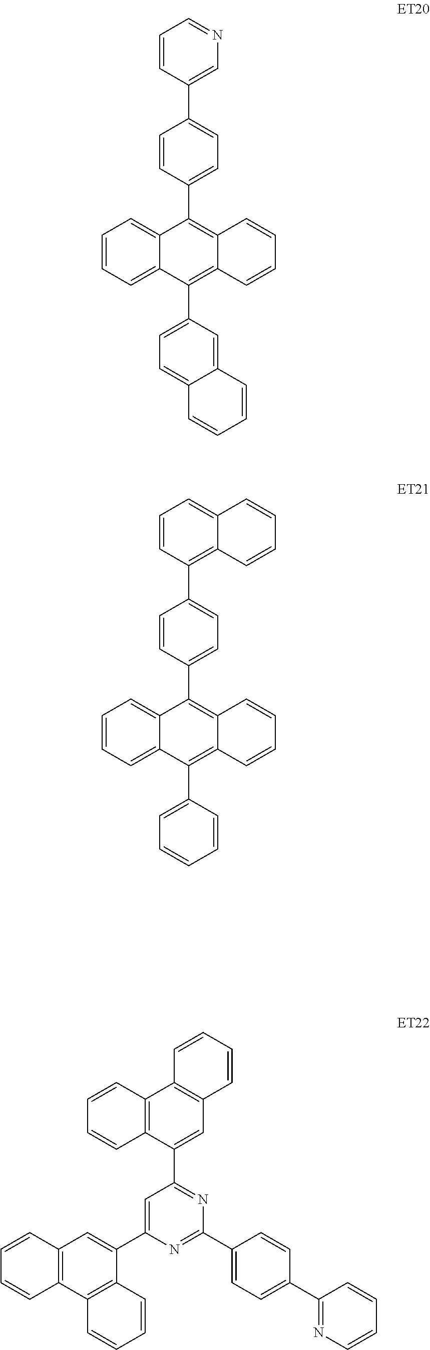

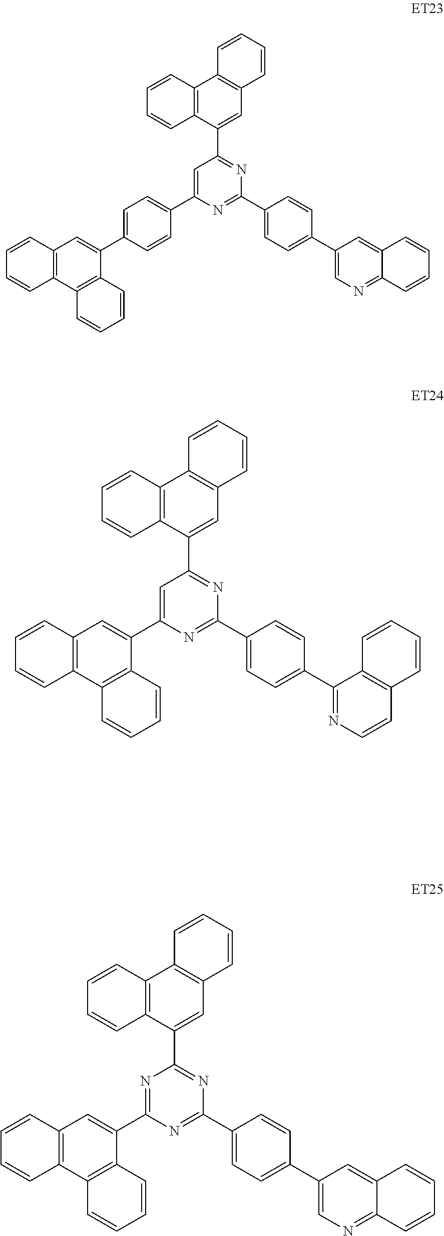 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

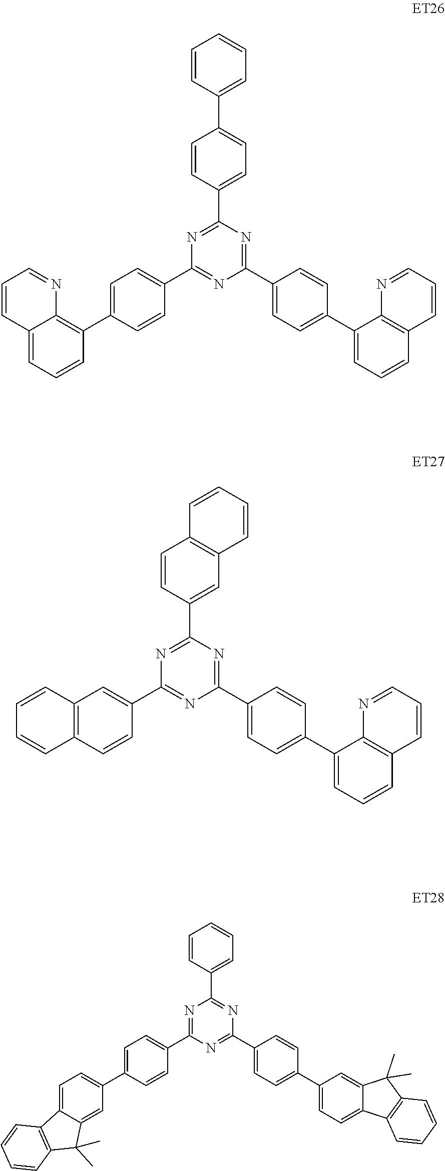 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

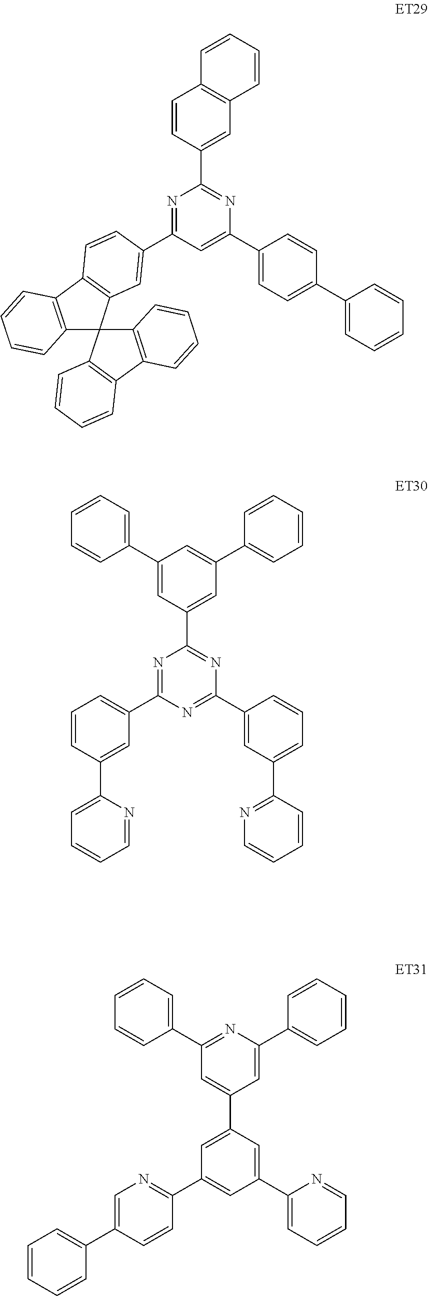 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

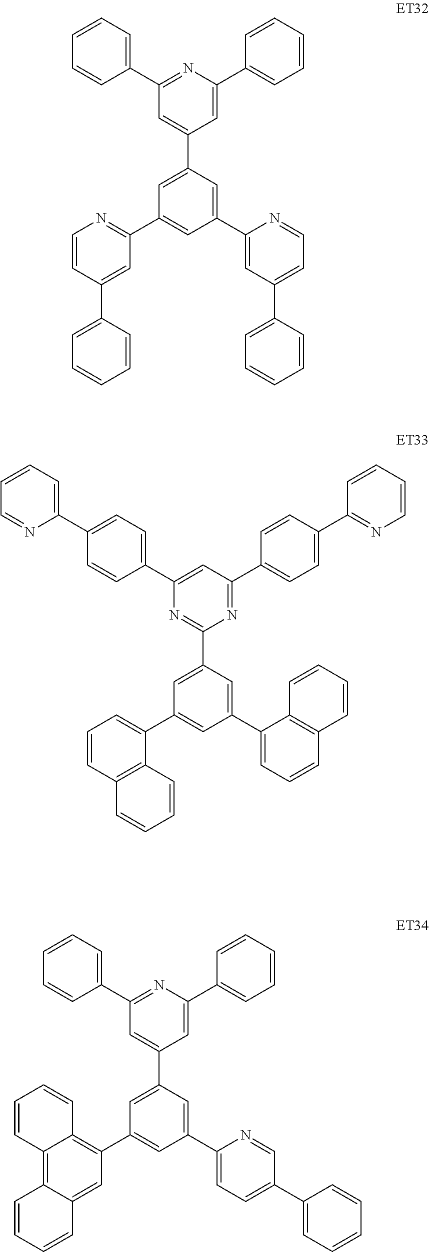 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

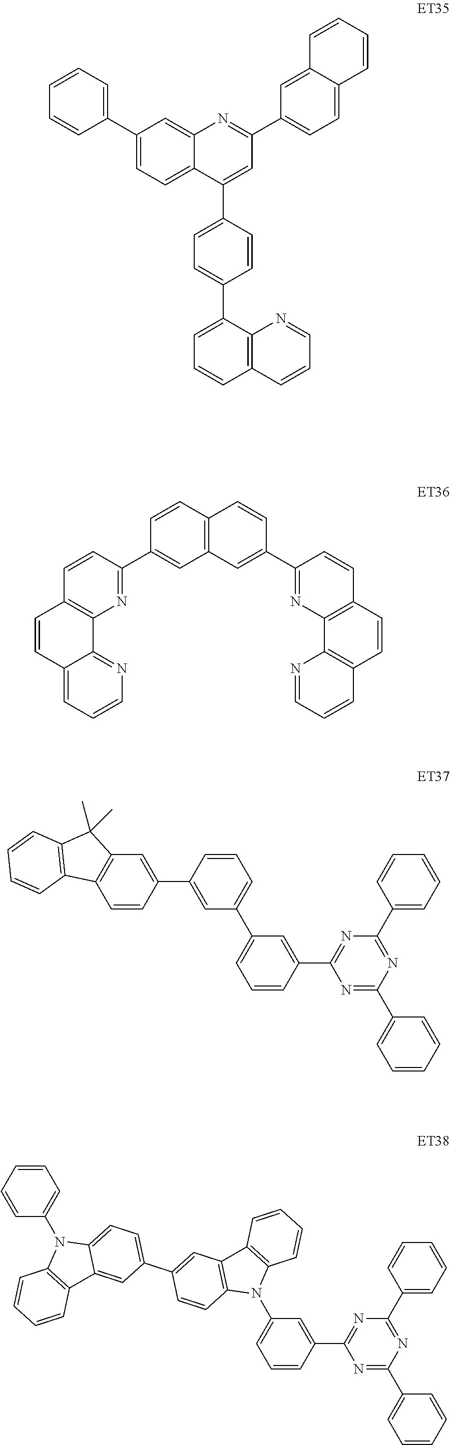 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

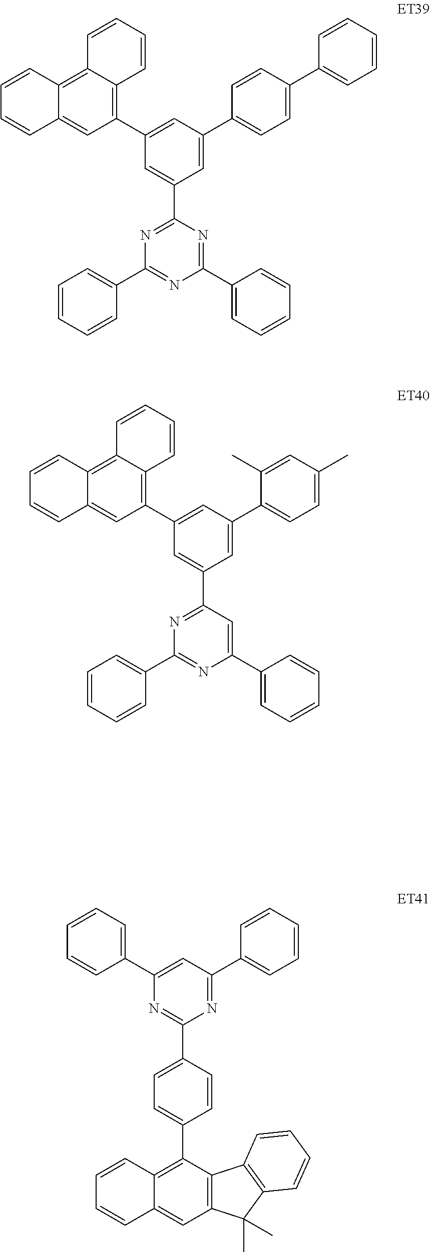 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

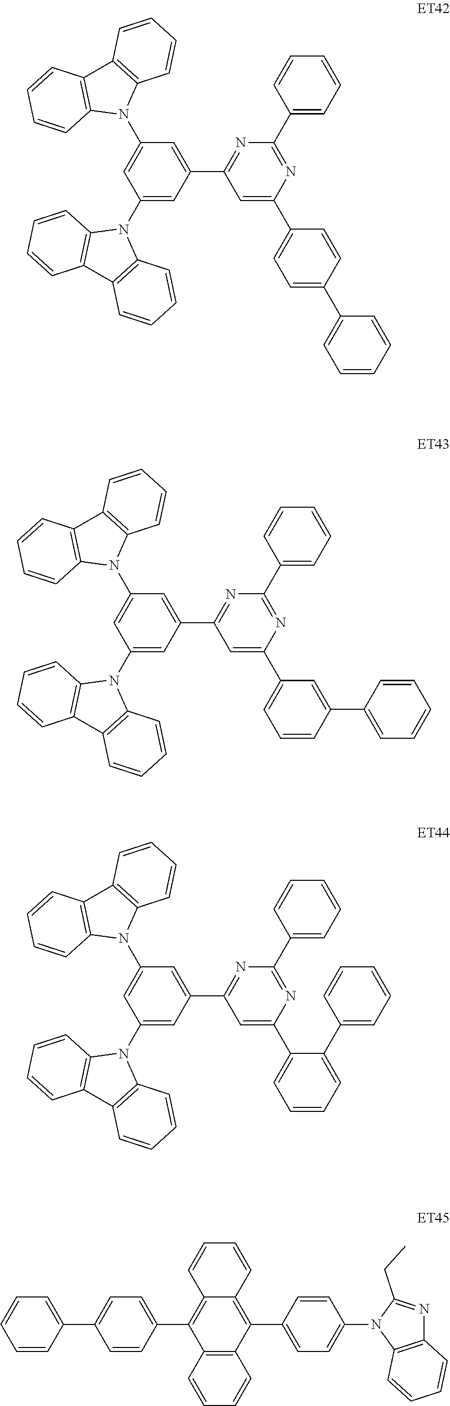 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

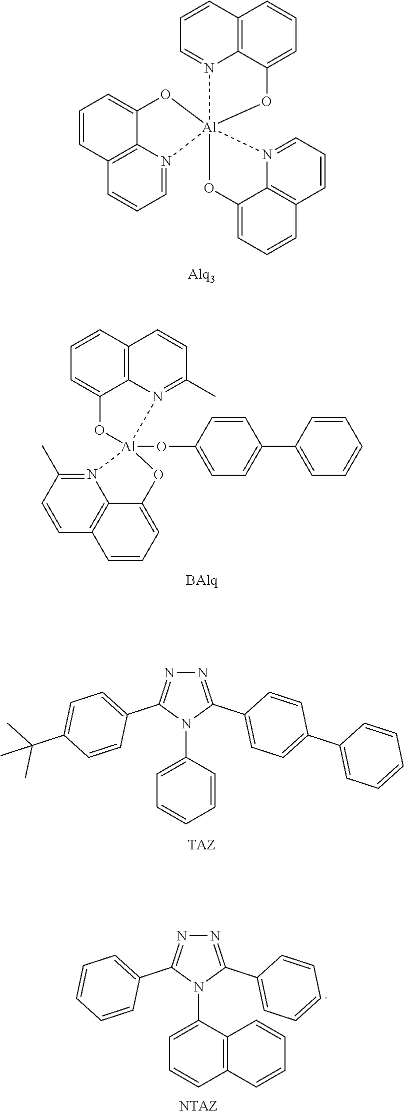

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport region are within the ranges described above, satisfactory electron transporting characteristics may be obtained without a substantial increase in driving voltage.

In one or more embodiments, the electron transport region (e.g., an electron transport layer in the electron transport region) may further include, in addition to one or more of the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In one or more embodiments, the metal-containing material may include a L₁ complex. The Li complex may include, for example, Compound ET-D1 (LiQ) or ET-D2:

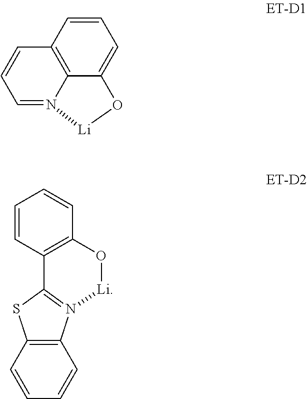

In one or more embodiments, the electron transport region may include an electron injection layer that facilitates the injection of electrons from the second electrode 150. The electron injection layer may directly contact the second electrode 150.

The electron injection layer may have: i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, and/or the like.), or tellurides of the alkali metal, the alkaline earth metal, and the rare earth metal, respectively, or any combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or any combination thereof. The alkaline earth metal-containing compound may include an alkaline earth metal oxide, such as BaO, SrO, CaO, BaₓSr₁₋ₓO (x is a real number satisfying 0<x<1), and/or BaₓCa₁₋ₓO (x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the metal ions (e.g., the respective metal ion), for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (e.g., a compound represented by Formula 601).

In one or more embodiments, the electron injection layer may include (e.g., consist of) i) an alkali metal-containing compound (e.g., an alkali metal halide), or ii) a) an alkali metal-containing compound (e.g., an alkali metal halide), and b) an alkali metal, an alkaline earth metal, a rare earth metal, or any combination thereof. In one or more embodiments, the electron injection layer may be a KI:Yb co-deposited layer, an RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly (e.g., substantially uniformly) or non-uniformly dispersed in a matrix including the organic material.

A thickness of the electron injection layer may be in a range of about 1 Å to about 100 Å, for example, about 3 Å to about 90 Å. When the thickness of the electron injection layer is within these ranges, satisfactory electron injection characteristics may be obtained without a substantial increase in driving voltage.

### Second Electrode 150

The second electrode 150 may be arranged on the interlayer 130. The second electrode 150 may be a cathode, which is an electron injection electrode, and as a material for forming the second electrode 150, a metal, an alloy, an electrically conductive compound, or any combination thereof, each having a low-work function, may be used.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multilayer structure including a plurality of layers.

### Capping Layer

In one or more embodiments, a first capping layer may be arranged outside (e.g., on) the first electrode 110, and/or a second capping layer may be arranged outside (e.g., on) the second electrode 150. In more detail, the organic light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In one or more embodiments, light generated in the emission layer of the interlayer 130 of the organic light-emitting device 10 may be extracted toward the outside through the first electrode 110, which is a transflective electrode or a transmissive electrode, and the first capping layer. In one or more embodiments, light generated in the emission layer of the interlayer 130 of the organic light-emitting device 10 may be extracted toward the outside through the second electrode 150, which is a transflective electrode or a transmissive electrode, and the second capping layer.

The first capping layer and the second capping layer may increase external emission efficiency according to the principle of constructive interference. Accordingly, the light extraction efficiency of the organic light-emitting device 10 is increased, so that the luminescence efficiency of the organic light-emitting device 10 may be improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and/or the second capping layer may (e.g., the first capping layer and the second capping layer may each independently) include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof.

In one or more embodiments, at least one of the first capping layer and/or the second capping layer may (e.g., the first capping layer and the second capping layer may each independently) include an amine group-containing compound.

In one or more embodiments, at least one of the first capping layer and/or the second capping layer may (e.g., the first capping layer and the second capping layer may each independently) include a compound represented by Formula 201, a compound represented by Formula 202, or any combination thereof.

In one or more embodiments, at least one of the first capping layer and/or the second capping layer may (e.g., the first capping layer and the second capping layer may each independently) include at least one of (e.g., one or more selected from among) Compounds HT28 to HT33, at least one of (e.g., one or more selected from among) Compounds CP1 to CP6, β-NPB, or any combination thereof:

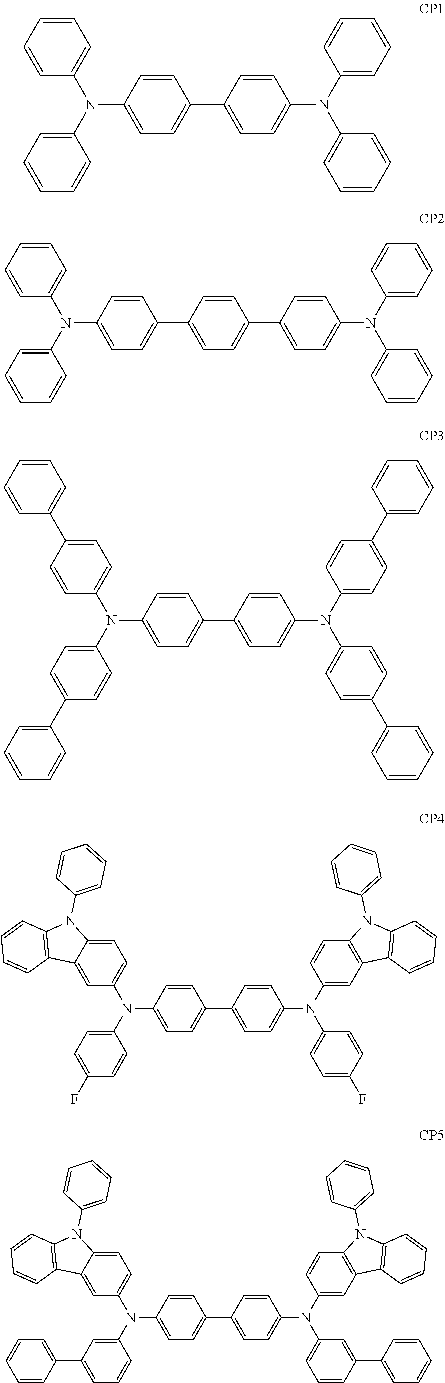 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

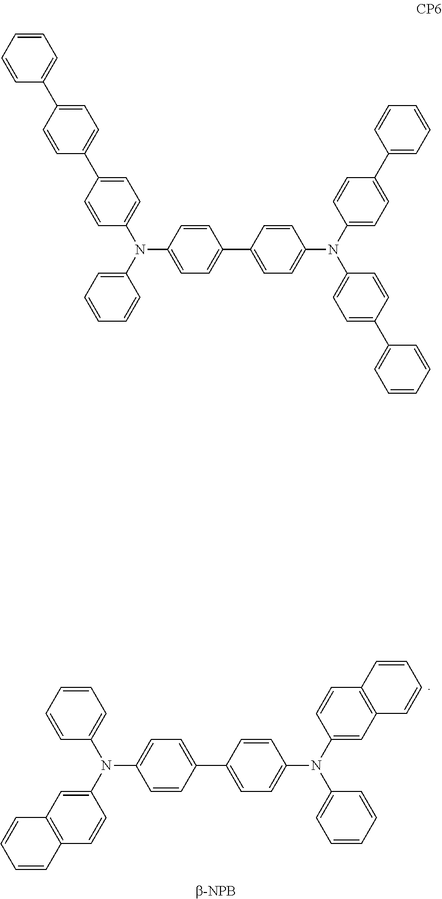 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The heterocyclic compound represented by Formula 1 may be included in one or more suitable films. Thus, one or more aspects of embodiments of the disclosure are directed toward a film including the heterocyclic compound represented by Formula 1. The film may be, for example, an optical member (or a light control element) (e.g., a color filter, a color conversion member, a capping layer, a light extraction efficiency enhancement layer, a selective light absorbing layer, a polarizing layer, a quantum dot-containing layer, and/or the like), a light blocking member (e.g., a light reflective layer, a light absorbing layer, and/or the like), a protective member (e.g., an insulating layer, a dielectric layer, and/or the like), and/or the like.

### Electronic Apparatus

The organic light-emitting device may be included in one or more suitable electronic apparatuses. For example, the electronic apparatus including the organic light-emitting device may be a light-emitting apparatus, an authentication apparatus, and/or the like.

In one or more embodiments, the electronic apparatus (e.g., a light-emitting apparatus) may further include, in addition to the organic light-emitting device, i) a color filter, ii) a color conversion layer, or iii) a color filter and a color conversion layer. The color filter and/or the color conversion layer may be arranged in at least one travel direction of light emitted from the organic light-emitting device. For example, in one or more embodiments, the light emitted from the organic light-emitting device may be blue light or white light (e.g., combined white light). The light-emitting device may be understood by referring to the description of the organic light-emitting device described herein. In one or more embodiments, the color conversion layer may include quantum dots. The quantum dots may be, for example, the aforementioned quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area configured to emit first color light, a second area configured to emit second color light, and/or a third area configured to emit third color light, wherein the first color light, the second color light, and/or the third color light may have different maximum emission wavelengths. In one or more embodiments, the first color light may be red light, the second color light may be green light, and the third color light may be blue light. In one or more embodiments, the plurality of color filter areas (or the plurality of color conversion areas) may include quantum dots. In more detail, the first area may include red quantum dots to emit red light, the second area may include green quantum dots to emit green light, and the third area may not include (e.g., may exclude) quantum dots. The quantum dots may be understood by referring to the description of the quantum dots described herein. The first area, the second area, and/or the third area may each further include a scatterer.

In one or more embodiments, the organic light-emitting device may be to emit first light, the first area may be to absorb the first light to emit first-first color light, the second area may be to absorb the first light to emit second-first color light, and the third area may be to absorb the first light to emit third-first color light. Here, the first-first color light, the second-first color light, and the third-first color light may have different maximum emission wavelengths from one another. For example, the first light may be blue light, the first-first color light may be red light, the second-first color light may be green light, and the third-first color light may be blue light.

In one or more embodiments, the electronic apparatus may further include a thin-film transistor in addition to the aforementioned organic light-emitting device. The thin-film transistor may include a source electrode, a drain electrode, and an active layer, wherein one selected from among the source electrode and the drain electrode may be electrically connected to the first electrode 110 or the second electrode 150 of the organic light-emitting device 10.

The thin-film transistor may further include a gate electrode, a gate insulating film, and/or the like.

The active layer may include crystalline silicon, amorphous silicon, an organic semiconductor, an oxide semiconductor, and/or the like.

In one or more embodiments, the electronic apparatus may further include a sealing portion for sealing the organic light-emitting device. The sealing portion may be arranged between the color filter and/or the color conversion layer and the organic light-emitting device. The sealing portion allows light from the organic light-emitting device to be extracted to the outside, and concurrently (e.g., simultaneously) prevents ambient air and moisture from penetrating into the organic light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

In one or more embodiments, various functional layers may be additionally arranged on the sealing portion, in addition to the color filter and/or the color conversion layer, according to the use of the electronic apparatus. The functional layers may include a touch screen layer, a polarizing layer, and/or the like. The touch screen layer may be a pressure-sensitive touch screen layer, a capacitive touch screen layer, or an infrared touch screen layer.

The authentication apparatus may further include, in addition to the organic light-emitting device as described above, a biometric information collector. The authentication apparatus may be, for example, a biometric authentication apparatus that authenticates an individual by using biometric information of a living body (e.g., fingertips, pupils, and/or the like).

The electronic apparatus may be applied to one or more of displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, and/or the like.

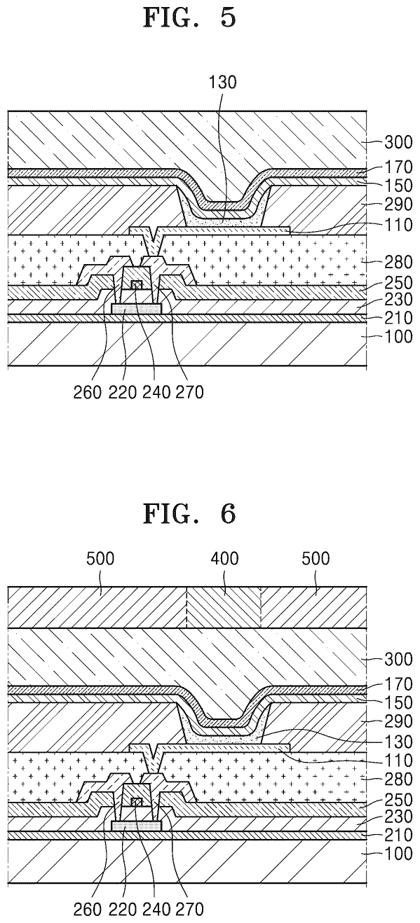

### Description of FIG. 5 and FIG. 6

FIG. 5 is a cross-sectional view showing a light-emitting apparatus according to one or more embodiments of the present disclosure.

The light-emitting apparatus of FIG. 5 may include a substrate 100, a thin-film transistor (TFT), an organic light-emitting device, and an encapsulation portion 300 that encapsulates the organic light-emitting device.

The substrate 100 may be a flexible substrate, a glass substrate, or a metal substrate. A buffer layer 210 may be on (e.g., arranged on) the substrate 100. The buffer layer 210 may prevent or reduce penetration of impurities through the substrate 100 and may provide a flat surface on the substrate 100.

The TFT may be on (e.g., arranged on) the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be on (e.g., arranged on) the active layer 220, and the gate electrode 240 may be on (e.g., arranged on) the gate insulating film 230.

An interlayer insulating film 250 may be on (e.g., arranged on) the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be on (e.g., arranged on) the interlayer insulating film 250. The interlayer insulating film 250 and the gate insulating film 230 may be formed to expose the source region and the drain region of the active layer 220, and the source electrode 260 and the drain electrode 270 may be arranged in contact with the exposed portions of the source region and the drain region of the active layer 220, respectively.

The TFT may be electrically connected to the organic light-emitting device to drive the organic light-emitting device, and may be covered and protected by a passivation layer 280. The passivation layer 280 may include an inorganic insulating film, an organic insulating film, or any combination thereof. The organic light-emitting device may be provided on the passivation layer 280. The organic light-emitting device may include a first electrode 110, an interlayer 130, and a second electrode 150.

The first electrode 110 may be on (e.g., arranged on) the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be on (e.g., arranged on) the first electrode 110. The pixel-defining film 290 may expose a certain region of the first electrode 110, and the interlayer 130 may be formed in the exposed region of the first electrode 110. The pixel-defining film 290 may be a polyimide-based organic film or a polyacrylic-based organic film. In one or more embodiments, at least some layers of the interlayer 130 may extend beyond the upper portion of the pixel-defining film 290 to be arranged in the form of a common layer.

The second electrode 150 may be on (e.g., arranged on) the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be arranged on the organic light-emitting device to protect the organic light-emitting device from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (e.g., polymethyl methacrylate, polyacrylic acid, and/or the like), an epoxy-based resin (e.g., aliphatic glycidyl ether (AGE), and/or the like), or any combination thereof; or any combination of the inorganic films and the organic films.

FIG. 6 shows a cross-sectional view showing a light-emitting apparatus according to one or more embodiments of the present disclosure.

The light-emitting apparatus of FIG. 6 is substantially the same as the light-emitting apparatus of FIG. 5, except that light-shielding patterns 500 and a functional region 400 are additionally arranged on the encapsulation portion 300. The functional region 400 may include i) a color filter area, ii) a color conversion area, or iii) a combination of a color filter area and a color conversion area. In one or more embodiments, an organic light-emitting device included in the light-emitting apparatus of FIG. 6 may be a tandem organic light-emitting device.

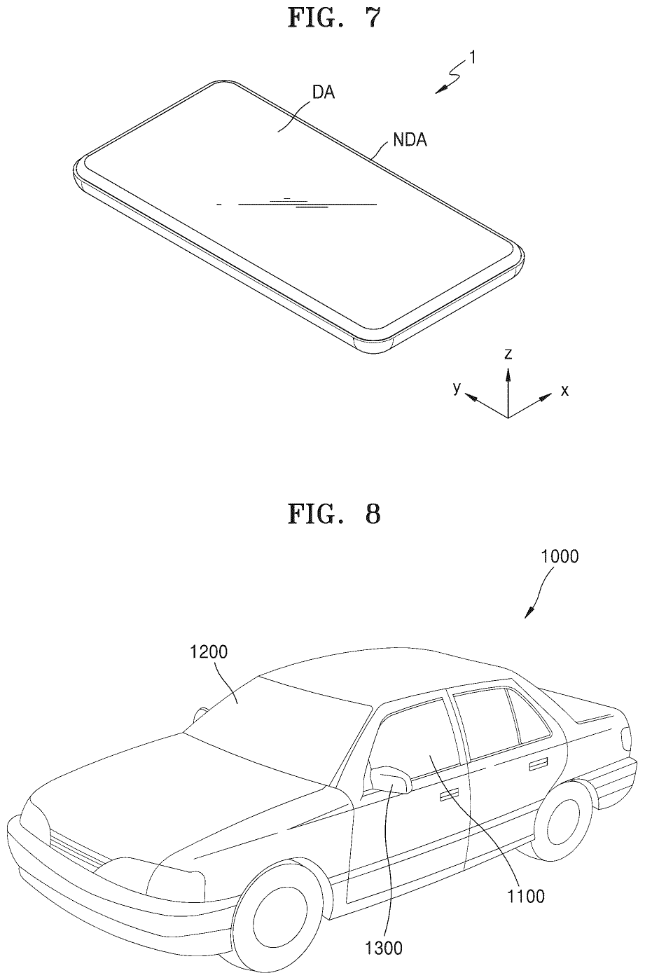

### Description of FIG. 7

FIG. 7 is a schematic perspective view of electronic equipment 1 including the organic light-emitting device according to one or more embodiments of the present disclosure. The electronic equipment 1 may be, as an electronic apparatus that displays a moving image or a still image, a portable electronic equipment, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as one or more suitable products or a part thereof, such as a television, a laptop, a monitor, a billboard, or an Internet of things (IOT). In one or more embodiments, the electronic equipment 1 may be a wearable device or a part thereof, such as a smart watch, a watch phone, a glasses-type (kind) display, or a head mounted display (HMD). However, embodiments of the present disclosure are not limited thereto. For example, the electron equipment 1 may include a dashboard of a vehicle, a center information display on a center fascia or dashboard of a vehicle, a room mirror display replacing a side-view mirror of a vehicle, an entertainment display arranged for a rear seat of a vehicle or arranged on the back of a front seat thereof, a head-up display (HUD) installed at the front of a vehicle or projected on a front window glass thereof, or a computer generated hologram augmented reality head up display (CGH AR HUD). FIG. 7 illustrates one or more embodiments in which the electronic equipment 1 is a smart phone for convenience of description.

The electronic equipment 1 may include a display area DA and a non-display area NDA outside the display area DA. A display apparatus of the electronic equipment 1 may implement an image through an array of a plurality of pixels that are two-dimensionally arranged in the display area DA.

The non-display area NDA is an area that does not display an image, and may entirely be around (e.g., surround) the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

In the electronic equipment 1, a length in an x-axis direction and a length (e.g., a width) in a y-axis direction may be different from each other. In one or more embodiments, as shown in FIG. 7, the length in the x-axis direction may be shorter than the length (e.g., the width) in the y-axis direction. In one or more embodiments, the length in the x-axis direction may be substantially the same as the length (e.g., the width) in the y-axis direction. In one or more embodiments, the length in the x-axis direction may be greater than the length (e.g., the width) in the y-axis direction.

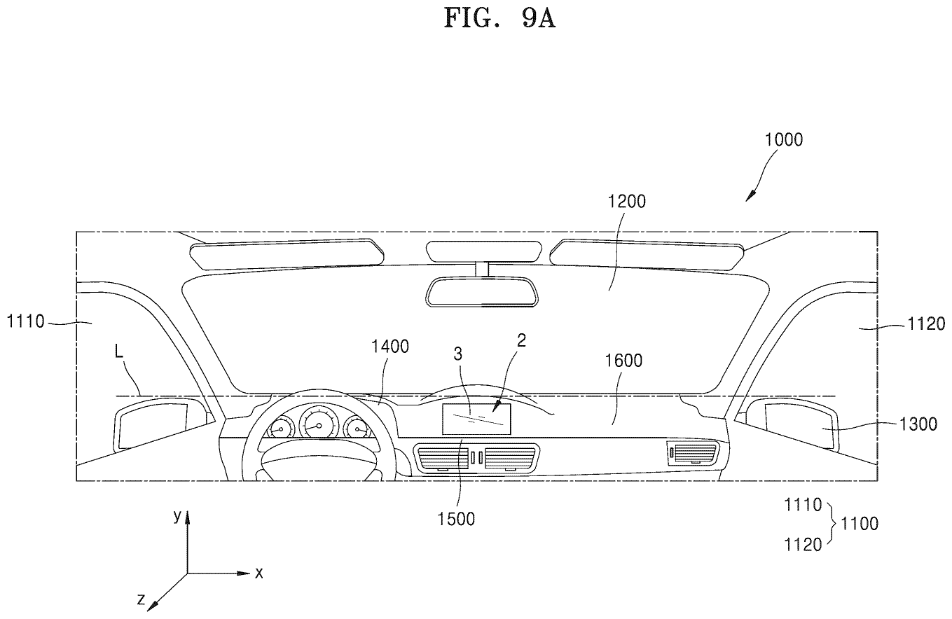

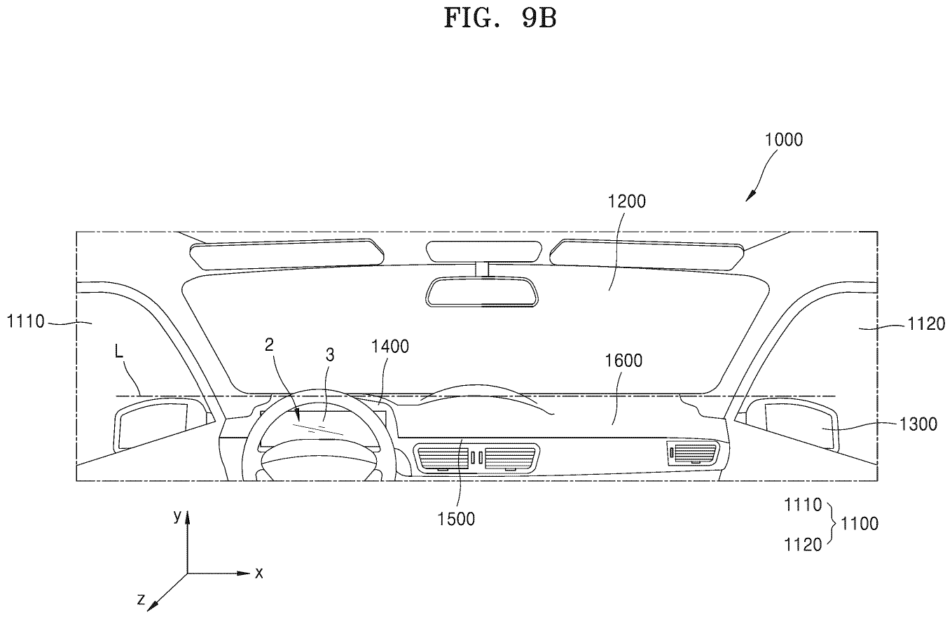

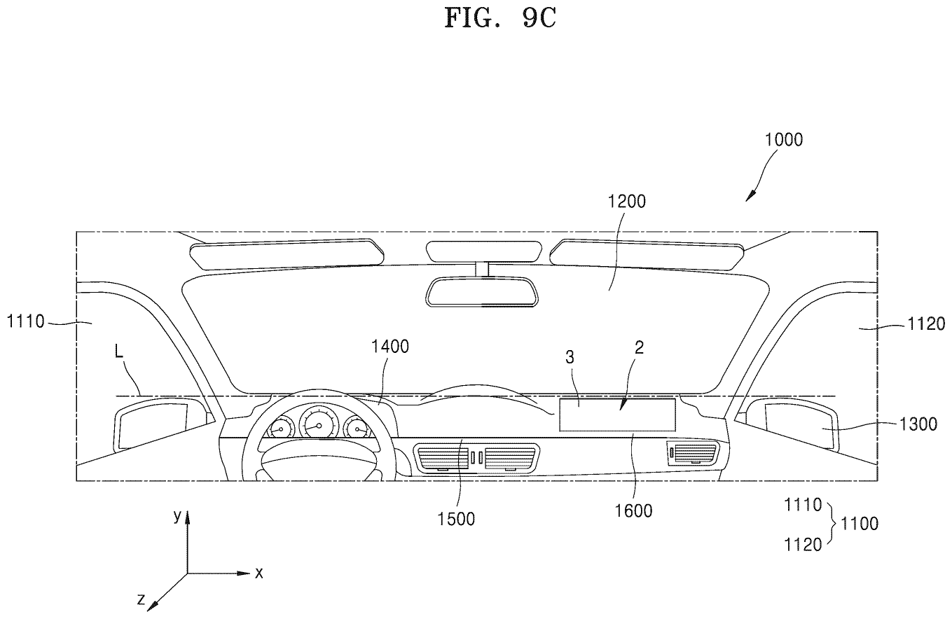

### Descriptions of FIGS. 8 and 9A to 9C

FIG. 8 is a schematic view of an exterior of a vehicle 1000 as electronic equipment including the organic light-emitting device according to one or more embodiments of the present disclosure. FIGS. 9A to 9C are each a schematic view of an interior of the vehicle 1000 according to one or more embodiments.

Referring to FIGS. 8, 9A, 9B, and 9C, the vehicle 1000 may refer to one or more suitable apparatuses for moving an object to be transported, such as a human, an object, or an animal, from a departure point to a destination point. The vehicle 1000 may include a vehicle traveling on a road or a track, a vessel moving over the sea or a river, an airplane flying in the sky using the action of air, and/or the like.

In one or more embodiments, the vehicle 1000 may travel on a road or a track. The vehicle 1000 may move in a certain direction according to rotation of at least one wheel thereof. In one or more embodiments, the vehicle 1000 may include a three-wheeled or four-wheeled vehicle, a construction machine, a two-wheeled vehicle, a prime mover device, a bicycle, or a train running on a track.

The vehicle 1000 may include a body having an interior and an exterior, and a chassis in which mechanical apparatuses necessary for driving are installed as other parts except for the body of the vehicle 1000. The exterior of the body of the vehicle may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in an x direction or a −x direction (the direction opposite the x-direction). In one or more embodiments, the first side window glass 1110 and the second side window glass 1120 may be spaced and/or apart (e.g., spaced apart or separated) from each other in the x direction or the −x direction. For example, an imaginary straight line L connecting the side window glasses 1100 may extend in the x direction or the −x direction. In one or more embodiments, an imaginary straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 opposite to (e.g., facing) each other.

The side-view mirror 1300 may provide a rear view of the vehicle 1000. The side-view mirror 1300 may be installed on the exterior of the body of the vehicle. In one or more embodiments, a plurality of side-view mirrors 1300 may be provided. One of the plurality of side-view mirrors 1300 may be arranged outside the first side window glass 1110. Another of the plurality of side-view mirrors 1300 may be arranged outside the second side window glass 1120.

The cluster 1400 may be arranged in front of the steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and/or a seat heater are arranged. The center fascia 1500 may be arranged on one side of the cluster 1400.

The passenger seat dashboard 1600 may be spaced and/or apart (e.g., spaced apart or separated) from the cluster 1400, and the center fascia 1500 may be arranged between the cluster 1400 and the passenger seat dashboard 1600. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 opposite to (e.g., facing) each other. The display apparatus 2 may be arranged on at least one of the cluster 1400, the center fascia 1500, or the passenger seat dashboard 1600.

The display apparatus 2 may include an organic light-emitting display device, an inorganic light-emitting display device, a quantum dot display device, and/or the like. Hereinafter, as the display apparatus 2 according to one or more embodiments of the disclosure, an organic light-emitting display device including the organic light-emitting device according to the disclosure will be described as an example, but one or more suitable types (kinds) of display devices as described above may be used in embodiments of the disclosure.

Referring to FIG. 9A, in one or more embodiments, the display apparatus 2 may be arranged on the center fascia 1500. In one or more embodiments, the display apparatus 2 may display navigation information. In one or more embodiments, the display apparatus 2 may display information regarding audio settings, video setting, and/or vehicle settings.

Referring to FIG. 9B, in one or more embodiments, the display apparatus 2 may be arranged on the cluster 1400. In these embodiments, the cluster 1400 may display driving information and/or the like through the display apparatus 2. For example, the cluster 1400 may digitally implement driving information and/or the like. The cluster 1400 may digitally implement vehicle information and driving information as images. In one or more embodiments, a needle and a gauge of a tachometer and one or more suitable warning light icons may be displayed by a digital signal.

Referring to FIG. 9C, in one or more embodiments, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information different from information displayed on the cluster 1400 and/or information displayed on the center fascia 1500.

### Manufacturing Method

Layers constituting the hole transport region, the emission layer, and layers constituting the electron transport region may be formed in a certain region by using one or more suitable methods such as vacuum deposition, spin coating, casting, Langmuir-Blodgett (LB) deposition, ink-jet printing, laser-printing, laser-induced thermal imaging, and/or the like.

When layers constituting the hole transport region, the emission layer, and the layers constituting the electron transport region are each formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definition of Terms

The term “C₃-C₆₀ carbocyclic group” as used herein refers to a cyclic group including (e.g., consisting of) carbon atoms as the only ring-forming atoms and having three to sixty carbon atoms, and the term “C₁-C₆₀ heterocyclic group” as used herein refers to a cyclic group that has one to sixty carbon atoms and further includes, in addition to carbon atom(s), a heteroatom as a ring-forming atom. The C₃-C₆₀ carbocyclic group and the C₁-C₆₀ heterocyclic group may each be a monocyclic group including (e.g., consisting of) one (e.g., exactly one) ring or a polycyclic group in which two or more rings are condensed with each other. In one or more embodiments, the number of ring-forming atoms of the C₁-C₆₀ heterocyclic group may be 3 to 61.

The term “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

In one or more embodiments,
the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

Group T3 may be a furan group, a thiophene group, a 1H-pyrrole group, a silole group, or a borole group, and

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may refer to a group condensed to any cyclic group or a group not condensed to any cyclic group, and may each be a monovalent group, or a polyvalent group (for example, a divalent group, a trivalent group, a tetravalent group, and/or the like) according to the structure of a formula for which the corresponding term is used. In one or more embodiments, “a benzene group” may be a benzo group, a phenyl group, a phenylene group, and/or the like, which may be easily understand by one of ordinary skill in the art according to the structure of a formula including the “benzene group.”

Non-limiting examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and non-limiting examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has one to sixty carbon atoms, and non-limiting examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of a C₂-C₆₀ alkyl group, and non-limiting examples thereof include an ethenyl group, a propenyl group, and a butenyl group. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of a C₂-C₆₀ alkyl group, and non-limiting examples thereof include an ethynyl group and a propynyl group. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is a C₁-C₆₀ alkyl group), and non-limiting examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and non-limiting examples thereof may include a cyclopropyl group, a cyclobutyl group, a cyclopentyl group, a cyclohexyl group, a cycloheptyl group, a cyclooctyl group, an adamantanyl (i.e., adamantyl) group, a norbornanyl (i.e., norbornyl) group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group that has one to ten carbon atoms and further includes, in addition to the carbon atoms, at least one heteroatom as a ring-forming atom, and non-limiting examples thereof include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has three to ten carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group that has one to ten carbon atoms, further includes, in addition to the carbon atoms, at least one heteroatom as a ring-forming atom, and has at least one double bond in the ring thereof. Non-limiting examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system of six to sixty carbon atoms, and the term “C₆-C₆₀ arylene group” as used herein refers to a divalent group having a carbocyclic aromatic system of six to sixty carbon atoms. Non-limiting examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system that has one to sixty carbon atoms and further includes, in addition to the carbon atoms, at least one heteroatom as a ring-forming atom. The term “C₁-C₆₀ heteroarylene group” as used herein refers to a divalent group having a heterocyclic aromatic system that has one to sixty carbon atoms and further includes, in addition to the carbon atoms, at least one heteroatom as a ring-forming atom. non-limiting examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group having two or more rings condensed with each other, only carbon atoms (for example, eight to sixty carbon atoms) as ring-forming atoms, and no aromaticity in its molecular structure if (e.g., when) considered as a whole. Non-limiting examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group that has two or more rings condensed with each other, further includes, in addition to carbon atoms (for example, one to sixty carbon atoms), at least one heteroatom as a ring-forming atom, and has no aromaticity in its molecular structure if (e.g., when) considered as a whole. Non-limiting examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein refers to —OA₁₀₂ (wherein A₁₀₂ is a C₆-C₆₀ aryl group), and the term “C₆-C₆₀ arylthio group” as used herein refers to —SA₁₀₃ (wherein A₁₀₃ is a C₆-C₆₀ aryl group). The term “C₁-C₆₀ heteroaryloxy group” as used herein may be a group represented by —O(A₁₀₈) (wherein A₁₀₈ may be a C₁-C₆₀ heteroaryl group), and the term “C₁-C₆₀ heteroarylthio group” as used herein may be a group represented by —S(A₁₀₉) (wherein A₁₀₉ may be a C₁-C₆₀ heteroaryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein refers to:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ as used herein may each independently be: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any atom other than a carbon atom or a hydrogen atom. Non-limiting examples of the heteroatom include O, S, N, P, Si, B, Ge, Se, or any combination thereof.

The term “Ph” as used herein refers to a phenyl group, the term “Me” as used herein refers to a methyl group, the term “Et” as used herein refers to an ethyl group, the term “tert-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” For example, the “biphenyl group” is a substituted phenyl group having a C₆-C₆₀ aryl group as a substituent.

The term “terphenyl group” as used herein refers to “a phenyl group substituted with a biphenyl group”. For example, the “terphenyl group” is a substituted phenyl group having, as a substituent, a C₆-C₆₀ aryl group substituted with a C₆-C₆₀ aryl group.

The terms “x-axis”, “y-axis”, and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

* and *′ as used herein, unless defined otherwise, each refer to a binding site to a neighboring atom in a corresponding formula or moiety.

Hereinafter, a compound according to one or more embodiments and an organic light-emitting device according to one or more embodiments will be described in more detail with reference to Synthesis Examples and Examples. The wording “B was used instead of A” used in describing Synthesis Examples refers to that a substantially identical molar equivalent of B was used in place of A.

### SYNTHESIS EXAMPLES

### Synthesis Example 1: Synthesis of Compound 2

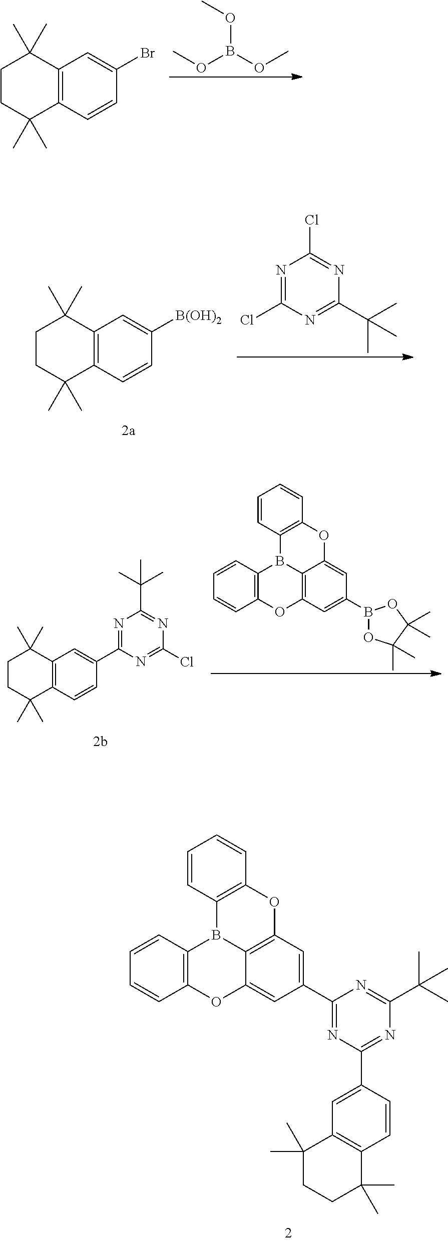

### (1) Synthesis of Intermediate 2a

6-bromo-1,1,4,4-tetramethyl-1,2,3,4-tetrahydronaphthalene (1.0 eq.) and Bu-Li (2.5 M) (1.1 eq) were dissolved in tetrahydrofuran (THF), and the mixed solution was stirred at −76° C. for 1 hour in a nitrogen atmosphere. Next, trimethyl borate (1.2 eq.) was added thereto and stirred at room temperature for 24 hours. After completion of the reaction, HCl and water were added to the reaction product and then stirred, and an organic layer obtained by a washing process using diethyl ether three times was dried over anhydrous MgSO₄ first and dried again under reduced pressure. By column chromatography, Intermediate 2a was obtained. (yield: 65%).

### (2) Synthesis of Intermediate 2b

Intermediate 2a (1.0 eq.), 2-(tert-butyl)-4,6-dichloro-1,3,5-triazine (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Intermediate 2b was obtained. (yield: 75%).

### (3) Synthesis of Compound 2

Intermediate 2b (1.0 eq.), 7-(4,4,5,5-tetramethyl-1,3,2-dioxaborolan-2-yl)-5,9-dioxa-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 2 was obtained. (yield: 80%)

### Synthesis Example 2: Synthesis of Compound 18

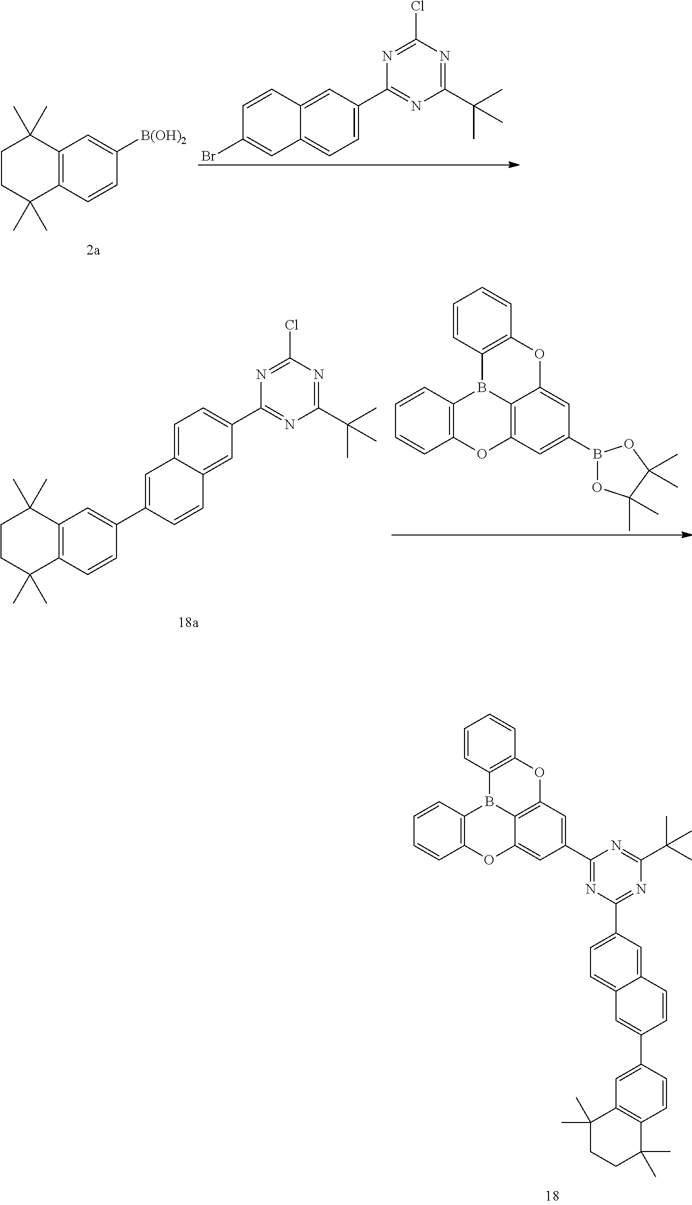

### (1) Synthesis of Intermediate 18a

Intermediate 2a (1.0 eq.), 2-(6-bromonaphthalen-2-yl)-4-(tert-butyl)-6-chloro-1,3,5-triazine (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Intermediate 18a was obtained. (yield: 50%)

### (2) Synthesis of Compound 18

Intermediate 18a (1.0 eq.), 7-(4,4,5,5-tetramethyl-1,3,2-dioxaborolan-2-yl)-5,9-dioxa-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 18 was obtained. (yield: 72%)

### Synthesis Example 3: Synthesis of Compound 40

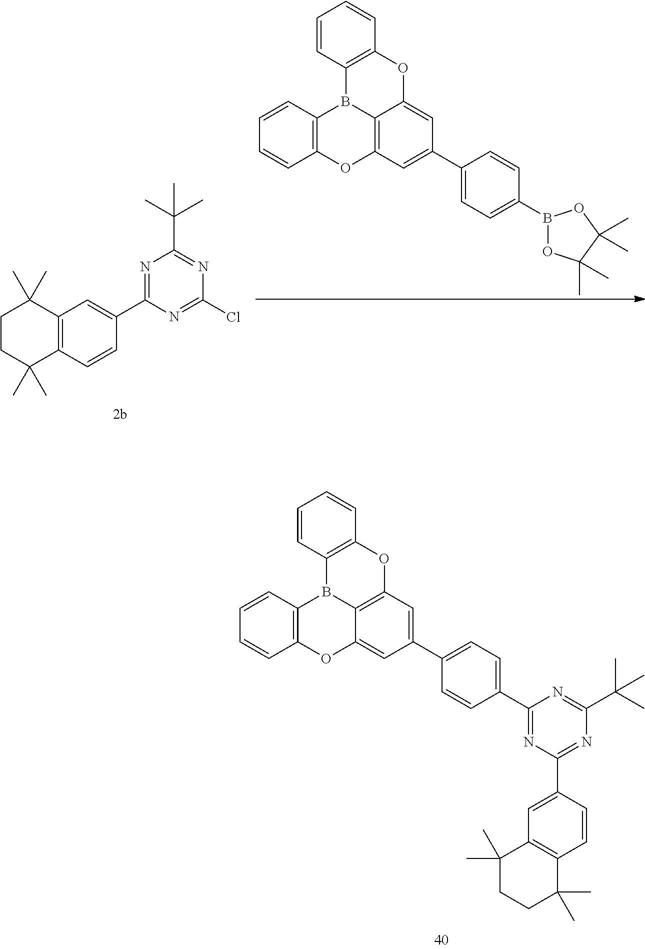 [SMILES: CC(C)(C)c1nc(Cl)nc(-c2ccc3c(c2)C(C)(C)CCC3(C)C)n1 ; CC1(C)OB(c2ccc(-c3cc4c5c(c3)Oc3ccccc3B5c3ccccc3O4)cc2)OC1(C)C ; CC(C)(C)c1nc(-c2ccc(-c3cc4c5c(c3)Oc3ccccc3B5c3ccccc3O4)cc2)nc(-c2ccc3c(c2)C(C)(C)CCC3(C)C)n1]

Intermediate 2b (1.0 eq.), 7-(4-(4,4,5,5-tetramethyl-1,3,2-dioxaborolan-2-yl)phenyl)-5,9-dioxa-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 40 was obtained. (yield: 61%)

### Synthesis Example 4: Synthesis of Compound 49

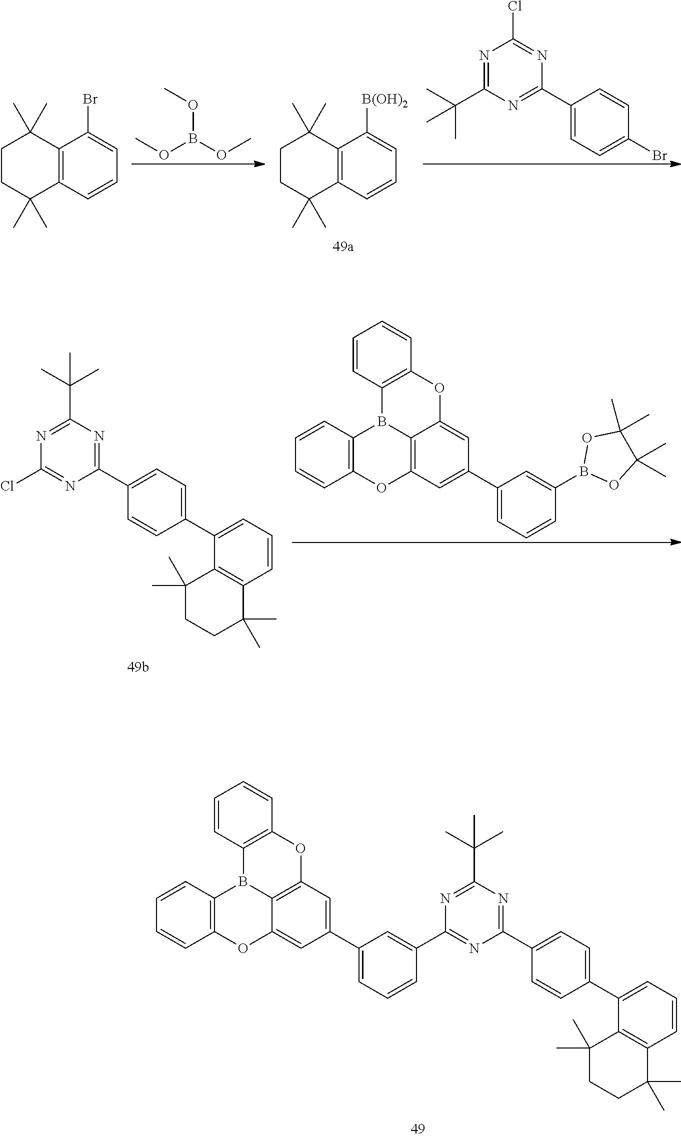

### (1) Synthesis of Intermediate 49a

5-bromo-1,1,4,4-tetramethyl-1,2,3,4-tetrahydronaphthalene (1.0 eq.) and Bu-Li (2.5 M) (1.1 eq) were dissolved in THF, and the mixed solution was stirred at −76° C. for 1 hour in a nitrogen atmosphere. Next, trimethyl borate (1.2 eq.) was added thereto and stirred at room temperature for 24 hours. After completion of the reaction, HCl and water were added to the reaction product and then stirred, and an organic layer obtained by a washing process using diethyl ether three times was dried over anhydrous MgSO₄ first and dried again under reduced pressure. By column chromatography, Intermediate 49a was obtained. (yield: 72%).

### (2) Synthesis of Intermediate 49b

Intermediate 49a (1.0 eq.), 2-(4-bromophenyl)-4-(tert-butyl)-6-chloro-1,3,5-triazine (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Intermediate 49b was obtained. (yield: 58%)

### (3) Synthesis of Compound 49

Intermediate 49b (1.0 eq.), 7-(3-(4,4,5,5-tetramethyl-1,3,2-dioxaborolan-2-yl)phenyl)-5,9-dioxa-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 49 was obtained. (yield: 70%).

### Synthesis Example 5: Synthesis of Compound 78

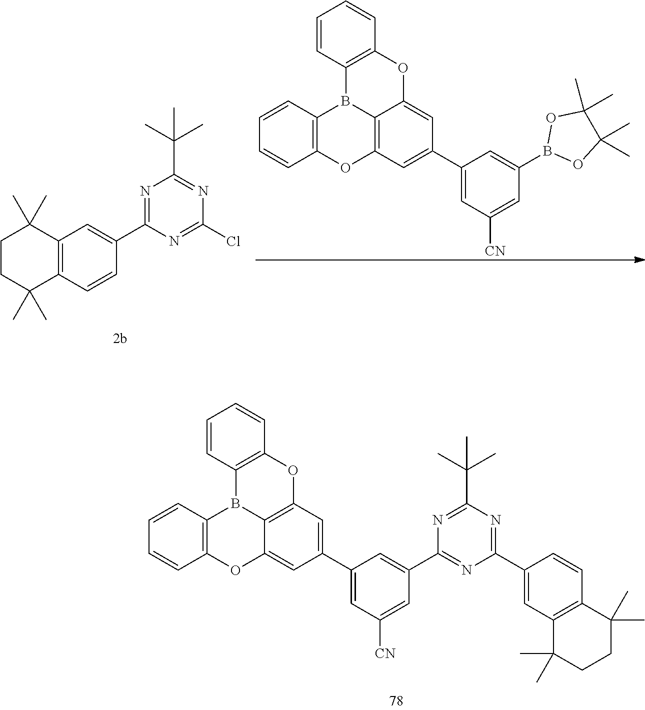 [SMILES: CC(C)(C)c1nc(Cl)nc(-c2ccc3c(c2)C(C)(C)CCC3(C)C)n1 ; CC1(C)OB(c2cc(C#N)cc(-c3cc4c5c(c3)Oc3ccccc3B5c3ccccc3O4)c2)OC1(C)C ; CC(C)(C)c1nc(-c2cc(C#N)cc(-c3cc4c5c(c3)Oc3ccccc3B5c3ccccc3O4)c2)nc(-c2ccc3c(c2)C(C)(C)CCC3(C)C)n1]

Intermediate 2b (1.0 eq.), 3-(5,9-dioxa-13b-boranaphtho[3,2,1-de]anthracen-7-yl)-5-(4,4,5,5-tetramethyl-1,3,2-dioxaborolan-2-yl)benzonitrile (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 78 was obtained. (yield: 62%)

### Synthesis Example 6: Synthesis of Compound 85

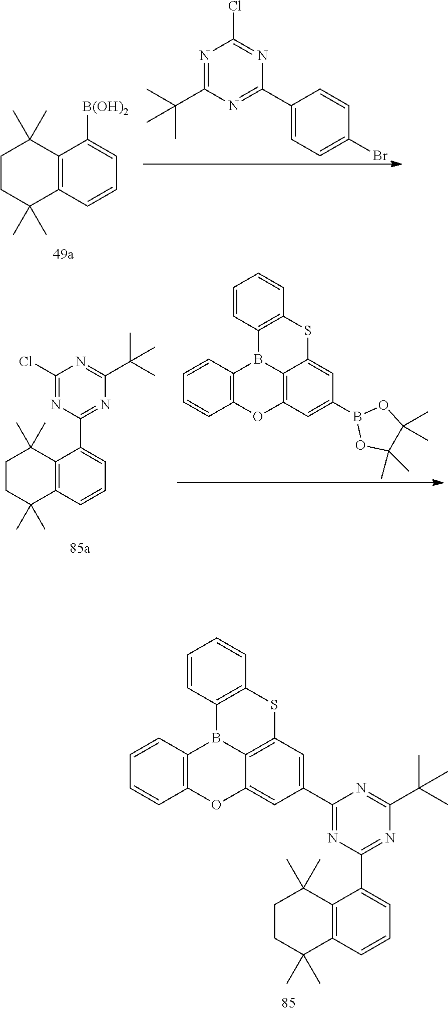

### (1) Synthesis of Intermediate 85a

Intermediate 49a (1.0 eq.), 2-(4-bromophenyl)-4-(tert-butyl)-6-chloro-1,3,5-triazine (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Intermediate 85a was obtained. (yield: 54%)

### (2) Synthesis of Compound 85

Intermediate 85a (1.0 eq.), 7-(4,4,5,5-tetramethyl-1,3,2-dioxaborolan-2-yl)-5-oxa-9-thia-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 85 was obtained. (yield: 66%)

### Synthesis Example 7: Synthesis of Compound 170

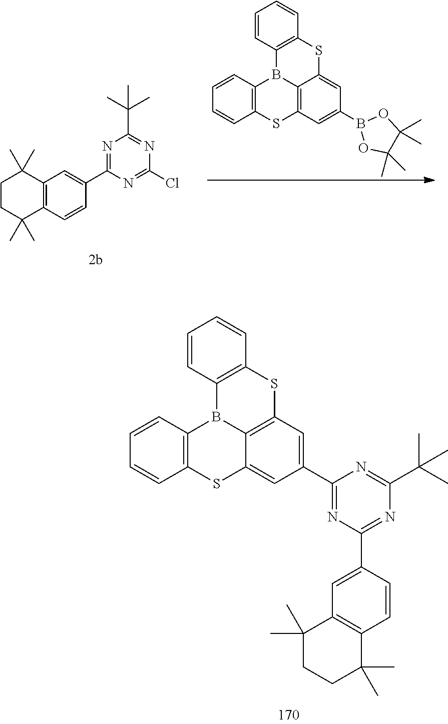 [SMILES: CC(C)(C)c1nc(Cl)nc(-c2ccc3c(c2)C(C)(C)CCC3(C)C)n1 ; CC1(C)OB(c2cc3c4c(c2)Sc2ccccc2B4c2ccccc2S3)OC1(C)C ; CC(C)(C)c1nc(-c2cc3c4c(c2)Sc2ccccc2B4c2ccccc2S3)nc(-c2ccc3c(c2)C(C)(C)CCC3(C)C)n1]

Intermediate 2b (1.0 eq.), 2-(5,9-dithia-13b-boranaphtho[3,2,1-de]anthracen-7-yl)-4,4,5,5-tetramethyl-1,3,2-dioxaborolane (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After the reaction was completed, the reaction product was washed three times using diethyl ether and water, and the obtained organic layer was dried over anhydrous MgSO₄ and then dried under reduced pressure. By column chromatography, Compound 170 was obtained. (yield: 48%)

### Synthesis Example 8: Synthesis of Compound 182

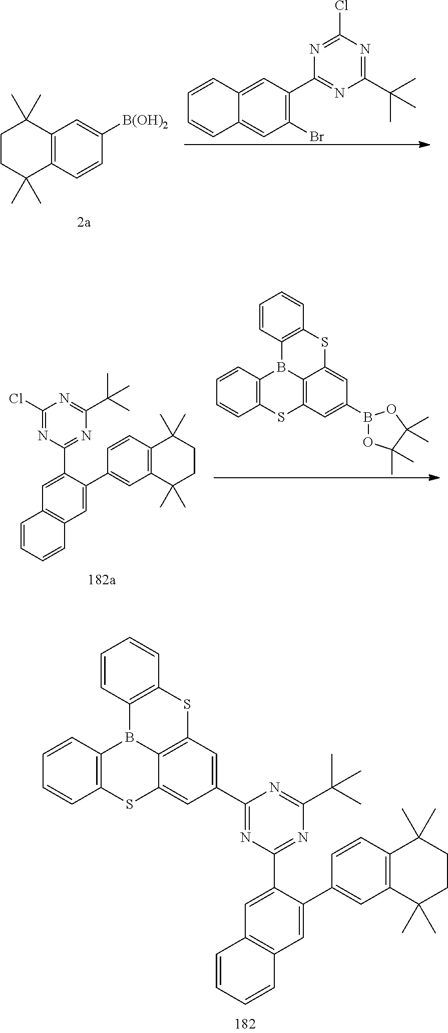

### (1) Synthesis of Intermediate 182a

Intermediate 2a (1.0 eq.), 2-(3-bromonaphthalen-2-yl)-4-(tert-butyl)-6-chloro-1,3,5-triazine (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Intermediate 182a was obtained. (yield: 63%)

### (2) Synthesis of Compound 182

Intermediate 182a (1.0 eq.), 2-(5,9-dithia-13b-boranaphtho[3,2,1-de]anthracen-7-yl)-4,4,5,5-tetramethyl-1,3,2-dioxaborolane (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 182 was obtained. (yield: 58%)

### Synthesis Example 9: Synthesis of Compound 258

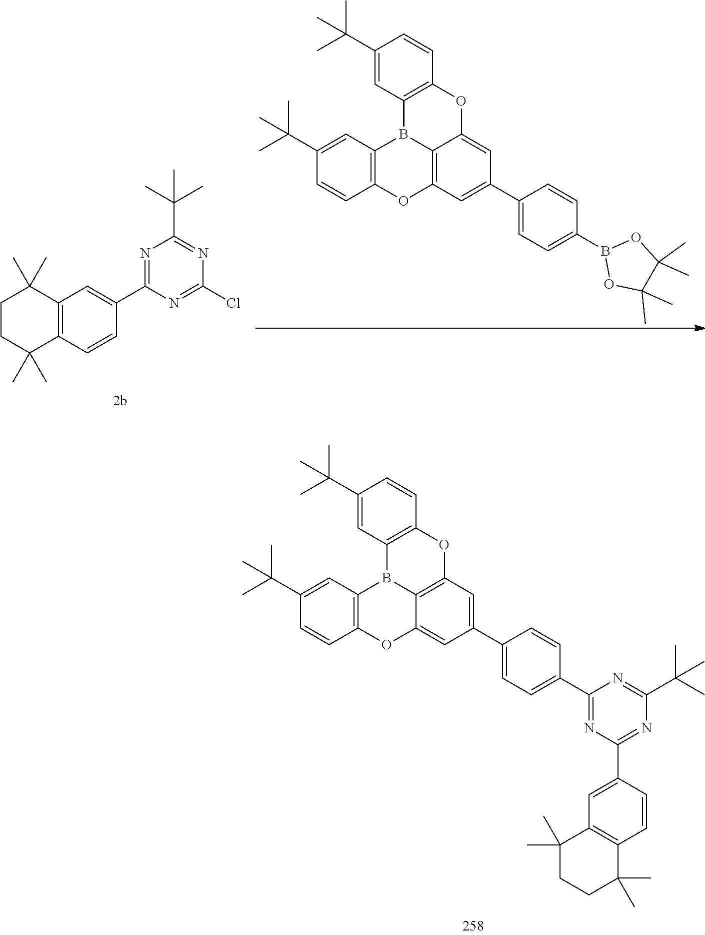

Intermediate 2b (1.0 eq.), 2,12-di-tert-butyl-7-(4-(4,4,5,5-tetramethyl-1,3,2-dioxaborolan-2-yl)phenyl)-5,9-dioxa-13b-boranaphtho[3,2,1-de]anthracene (1.0 eq.), tetrakis(triphenylphosphine)palladium (0.1 eq.), and potassium carbonate (3.0 eq.) were dissolved in 200 mL of toluene, 40 mL of ethanol, and 80 mL of water, and the mixed solution was stirred at 110° C. for 24 hours in a nitrogen atmosphere. After completion of the reaction, an organic layer obtained by a washing process using water and diethyl ether three times was dried over anhydrous MgSO₄ first and dried again under reduced pressure. By column chromatography, Compound 258 was obtained. (yield: 51%)

The proton nuclear magnetic resonance (¹H NMR) data and mass spectroscopy/fast atom bombardment (MS/FAB) data of each of the compounds synthesized according to Synthesis Examples are shown in Table 1. Synthesis methods of other compounds in addition to the compounds synthesized in Synthesis Examples may be easily recognized by those skilled in the art by referring to the synthesis paths and source materials.

TABLE 1

| | | MS/FAB | |
|---|---|---|---|
| Compound | ¹H NMR (δ) | Calc | found |
| Compound | 7.71 (d, 2H), 7.33-7.27 (m, 4H), 7.11-7.00 (m, 7H), | 591.31 | 591.02 |
| 2 | 1.48 (s, 4H), 1.35 (s, 9H), 0.91 (s, 12H) | | |
| Compound | 9.15 (s, 1H), 8.51 (d, 1H), 7.99 (d, 1H), 7.71 (d, 2H), | 717.35 | 716.96 |
| 18 | 7.55 (s, 1H), 7.38-7.27 (m, 6H), 7.11-7.00 (m, 7H), | | |
| | 1.48 (s, 4H), 1.35 (s, 9H), 0.91 (s, 12H) | | |
| Compound | 8.25 (d, 2H), 7.71 (d, 2H), 7.35-7.25 (m, 6H), 7.11- | 743.37 | 743.21 |
| 40 | 7.00 (m, 7H), 1.48 (s, 4H), 1.35 (s, 9H), 0.91 (s, 12H) | | |
| Compound | 8.38 (d, 1H), 8.25 (d, 2H), 7.94 (s, 1H), 7.71 (d, 3H), | 667.34 | 667.12 |
| 49 | 7.61 (d, 1H), 7.33-7.25 (m, 5H), 7.11-7.00 (m, 8H), | | |
| | 1.48 (s, 4H), 1.35 (s, 9H), 0.91 (s, 12H) | | |
| Compound | 8.22 (s, 1H), 8.04 (s, 2H), 7.71 (d, 2H), 7.35-7.27 (m, | 692.33 | 692.34 |
| 78 | 4H), 7.11-7.00 (m, 7H), 1.48 (s, 4H), 1.35 (s, 9H), | | |
| | 0.91 (s, 12H) | | |
| Compound | 7.71 (d, 1H), 7.55 (d, 1H), 7.33-7.27 (m, 3H), 7.20 (d, | 607.28 | 606.93 |
| 85 | 1H), 7.11-7.00 (m, 7H), 1.48 (s, 4H), 1.35 (s, 9H), | | |
| | 0.91 (s, 12H) | | |
| Compound | 7.55 (d, 2H), 7.35 (s, 3H), 7.27 (d, 1H), 7.20 (d, 2H), | 623.26 | 623.18 |
| 170 | 7.11-7.06 (m, 5H), 1.48 (s, 4H), 1.35 (s, 9H), 0.91 (s, | | |
| | 12H) | | |
| Compound | 8.71 (s, 1H), 8.51 (s, 1H), 8.17 (d, 1H), 8.09 (d, 1H), | 749.31 | 749.12 |
| 182 | 7.63-7.62 (t, 2H), 7.55 (d, 2H), 7.35 (s, 3H), 7.27 (d, | | |
| | 1H), 7.20 (d, 2H), 7.11-7.06 (m, 5H), 1.48 (s, 4H), | | |
| | 1.35 (s, 9H), 0.91 (s, 12H) | | |
| Compound | 8.25 (d, 2H), 7.50 (d, 2H), 7.35-7.32 (m, 3H), 7.27- | 779.46 | 779.35 |
| 258 | 7.25 (m, 3H), 7.11 (d, 1H), 7.05 (s, 2H), 6.92 (d, 2H), | | |
| | 1.48 (s, 4H), 1.35 (s, 9H), 1.32 (s, 18H), 0.91 (s, | | |
| | 12H) | | |

### EXAMPLES

### Comparative Example 1

As an anode, a glass substrate (product of Corning Inc.) with a 15 Ω/cm² (1,200 Å) ITO electrode formed thereon was cut to a size of 50 mm×50 mm×0.7 mm, sonicated with isopropyl alcohol and (then with) pure water for 5 minutes each, cleaned by irradiation of ultraviolet rays and exposure of ozone thereto for 30 minutes, and then mounted on a vacuum deposition apparatus.

NPD was deposited on the anode to form a hole injection layer having a thickness of 300 Å, HT3 was deposited on the hole injection layer to form a hole transport layer having a thickness of 200 Å, and CzSi was deposited on the hole transport layer to form an emission auxiliary layer having a thickness of 100 Å.

A host in which HTH55 and ETH66 were mixed at a weight ratio of 1:1, PD41 (as a phosphorescent sensitizer), and t-DABNA (as a dopant) were co-deposited at a weight ratio of 84:15:1 on the emission auxiliary layer to form an emission layer having a thickness of 200 Å, and TSPO1 was deposited on the emission layer to form a hole blocking layer having a thickness of 200 Å. Afterwards, TPBi was deposited on the hole blocking layer to form an electron transport layer having a thickness of 300 Å, and LiF was deposited on the electron transport layer to form an electron injection layer having a thickness of 10 Å. Al was deposited on the electron injection layer to form a cathode having a thickness of 3,000 Å, thereby completing the manufacture of an organic light-emitting device.

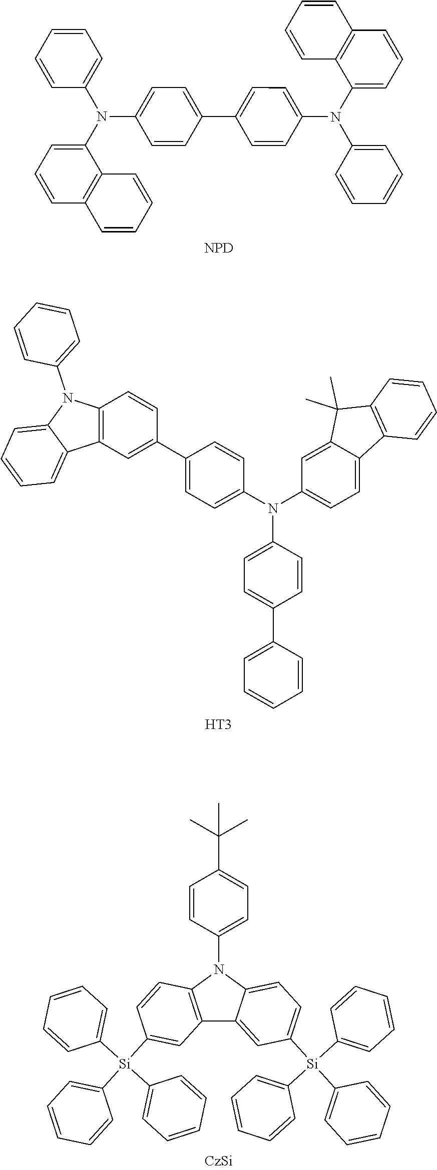

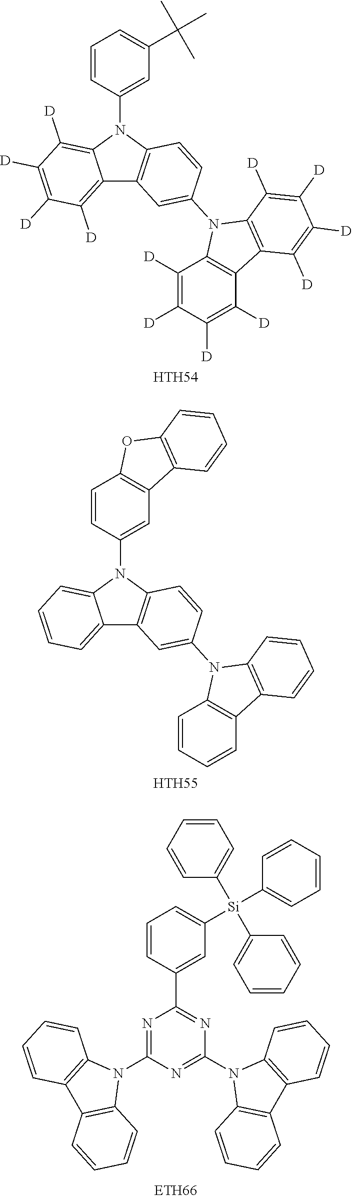

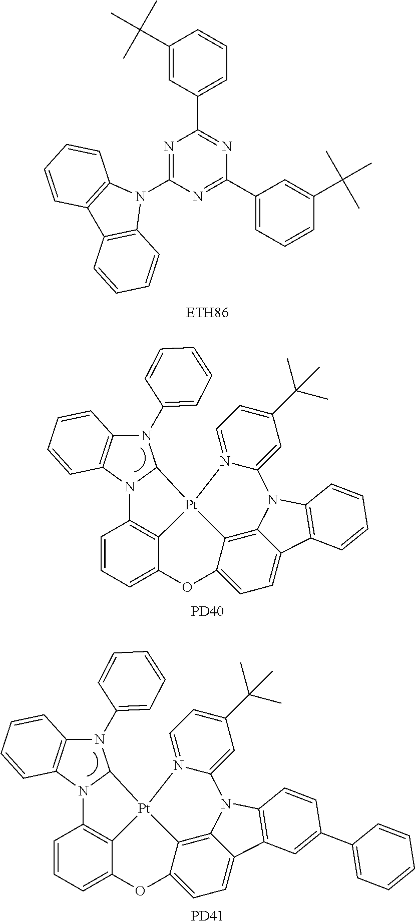

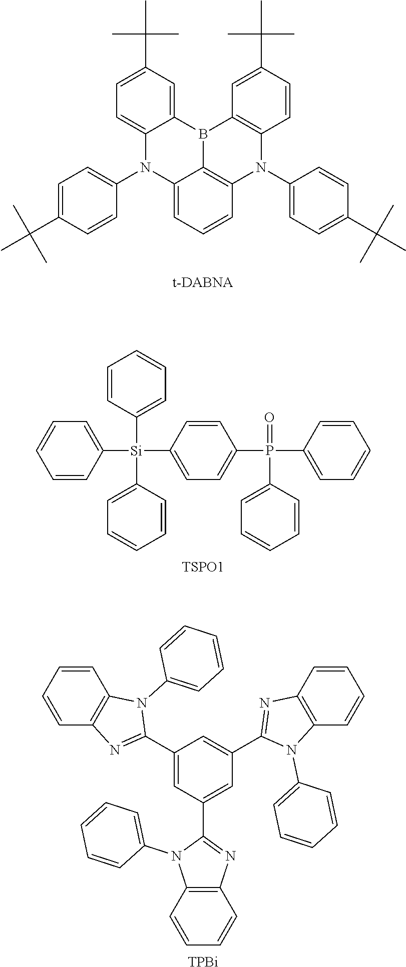

### Examples 1 to 9 and Comparative Examples 2 to 5

Organic light-emitting devices were each manufactured in substantially the same manner as in Comparative Example 1, except that compounds shown in Table 2 were each respectively used instead of TPBi when forming an electron transport layer.

### Evaluation Example 1: Evaluation of Properties of Organic Light-Emitting Device

For each of the organic light-emitting devices of Examples 1 to 9 and Comparative Examples 1 to 5, the driving voltage at 1,000 cd/m², luminescence efficiency (measured at a current density of 50 mA/cm²), and lifespan (T₉₅, measured at a current density of 100 mA/cm²) were each measured by using Keithley MU 236 and a luminance meter PR650. The results are shown in Table 2. In Table 2, the lifespan (T₉₅) is a measure of the time (hr) expressed as a relative value to Comparative Example 1, taken for the luminance to reach 95% of the initial luminance, i.e., lifespan ratio (T₉₅).

TABLE 2

| | | Phospho- | | | | | |
|---|---|---|---|---|---|---|---|
| | Host in | rescent | | | | | |
| | emission | sensitizer | Dopant | | | | |
| | layer | in | in | Electron | Driving | Luminescence | Lifespan |
| | (at weight | emission | emission | transport | voltage | efficiency | ratio |
| | ratio of 5:5) | layer | layer | layer | (V) | (cd/A) | (T₉₅) |
| Example | HTH55, | PD41 | t- | Compound 2 | 3.94 | 28.2 | 5.4 |
| 1 | ETH66 | | DABNA | | | | |
| Example | HTH55, | PD41 | t- | Compound | 3.86 | 27.3 | 5.1 |
| 2 | ETH66 | | DABNA | 18 | | | |
| Example | HTH55, | PD41 | t- | Compound | 3.96 | 27.7 | 5.2 |
| 3 | ETH66 | | DABNA | 40 | | | |
| Example | HTH55, | PD41 | t- | Compound | 4.05 | 24.2 | 4.8 |
| 4 | ETH66 | | DABNA | 49 | | | |
| Example | HTH55, | PD41 | t- | Compound | 4.15 | 24.8 | 4.2 |
| 5 | ETH66 | | DABNA | 78 | | | |
| Example | HTH55, | PD41 | t- | Compound | 4.33 | 22.1 | 3.7 |
| 6 | ETH66 | | DABNA | 85 | | | |
| Example | HTH55, | PD41 | t- | Compound | 4.01 | 27.9 | 5.0 |
| 7 | ETH66 | | DABNA | 170 | | | |
| Example | HTH54, | PD40 | t- | Compound | 3.99 | 27.0 | 4.9 |
| 8 | ETH86 | | DABNA | 182 | | | |
| Example | HTH54, | PD40 | t- | Compound | 4.42 | 26.8 | 4.5 |
| 9 | ETH86 | | DABNA | 258 | | | |
| Comparative | HTH55, | PD41 | t- | TPBi | 5.61 | 18.2 | 1 |
| Example | ETH66 | | DABNA | | | | |
| 1 | | | | | | | |
| Comparative | HTH55, | PD41 | t- | Compound A | 5.02 | 20.1 | 1.5 |
| Example | ETH66 | | DABNA | | | | |
| 2 | | | | | | | |
| Comparative | HTH55, | PD41 | t- | Compound B | 6.01 | 17.7 | 0.9 |
| Example | ETH66 | | DABNA | | | | |
| 3 | | | | | | | |
| Comparative | HTH55, | PD41 | t- | Compound C | 5.21 | 16.5 | 1.1 |
| Example | ETH66 | | DABNA | | | | |
| 4 | | | | | | | |
| Comparative | HTH55, | PD41 | t- | Compound D | 6.15 | 18.2 | 0.8 |
| Example | ETH66 | | DABNA | | | | |
| 5 | | | | | | | |

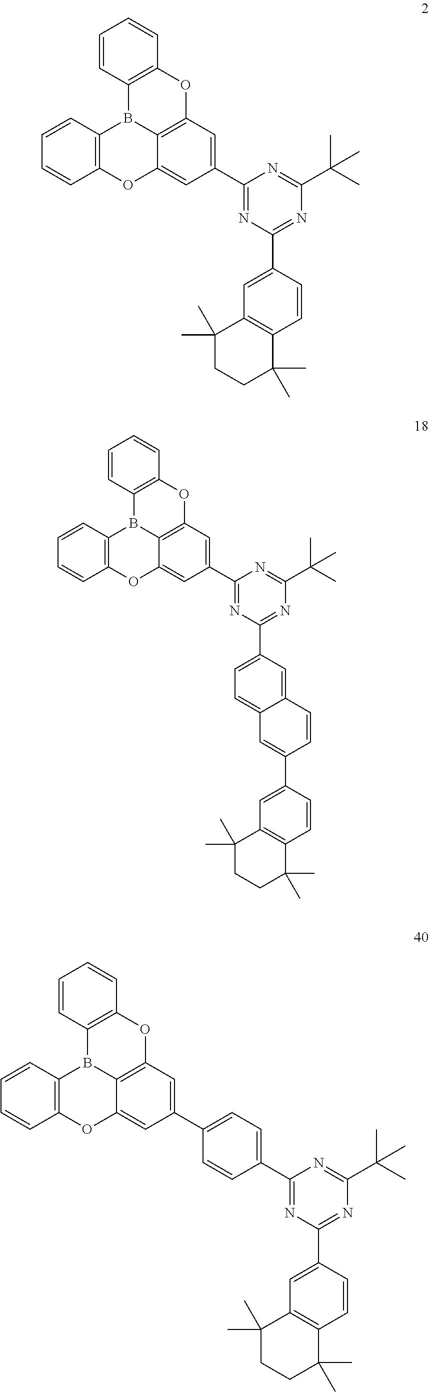 [SMILES: CC(C)(C)c1nc(-c2cc3c4c(c2)Oc2ccccc2B4c2ccccc2O3)nc(-c2ccc3c(c2)C(C)(C)CCC3(C)C)n1 ; CC(C)(C)c1nc(-c2cc3c4c(c2)Oc2ccccc2B4c2ccccc2O3)nc(-c2ccc3cc(-c4ccc5c(c4)C(C)(C)CCC5(C)C)ccc3c2)n1 ; CC(C)(C)c1nc(-c2ccc(-c3cc4c5c(c3)Oc3ccccc3B5c3ccccc3O4)cc2)nc(-c2ccc3c(c2)C(C)(C)CCC3(C)C)n1]

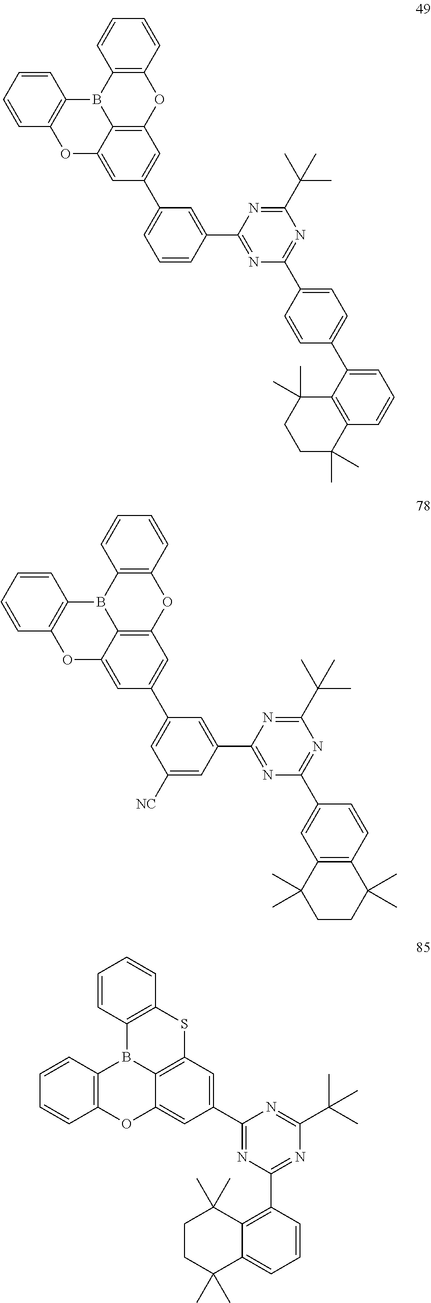 [SMILES: CC(C)(C)c1nc(-c2ccc(-c3cccc4c3C(C)(C)CCC4(C)C)cc2)nc(-c2cccc(-c3cc4c5c(c3)Oc3ccccc3B5c3ccccc3O4)c2)n1 ; CC(C)(C)c1nc(-c2cc(C#N)cc(-c3cc4c5c(c3)Oc3ccccc3B5c3ccccc3O4)c2)nc(-c2ccc3c(c2)C(C)(C)CCC3(C)C)n1 ; CC(C)(C)c1nc(-c2cc3c4c(c2)Sc2ccccc2B4c2ccccc2O3)nc(-c2cccc3c2C(C)(C)CCC3(C)C)n1]

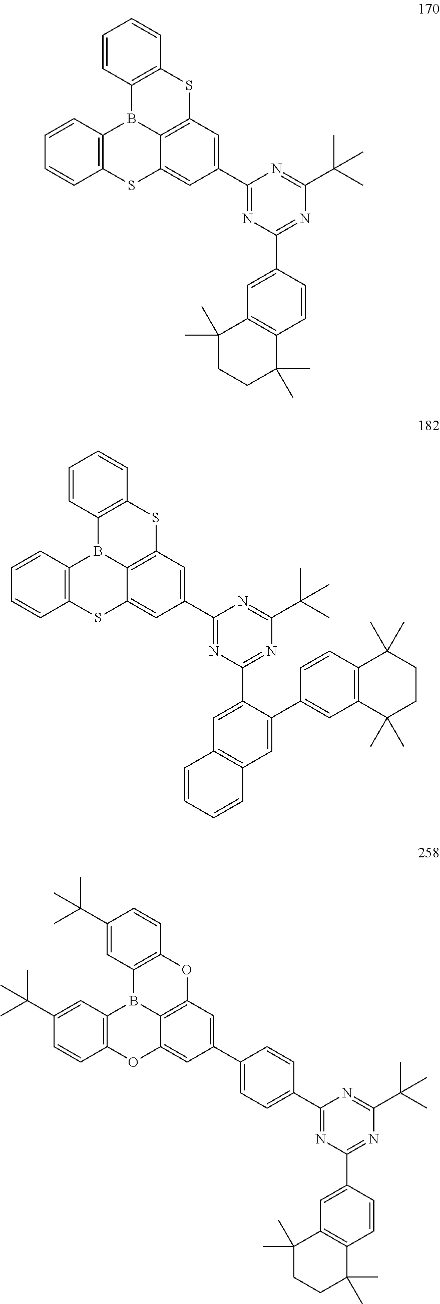

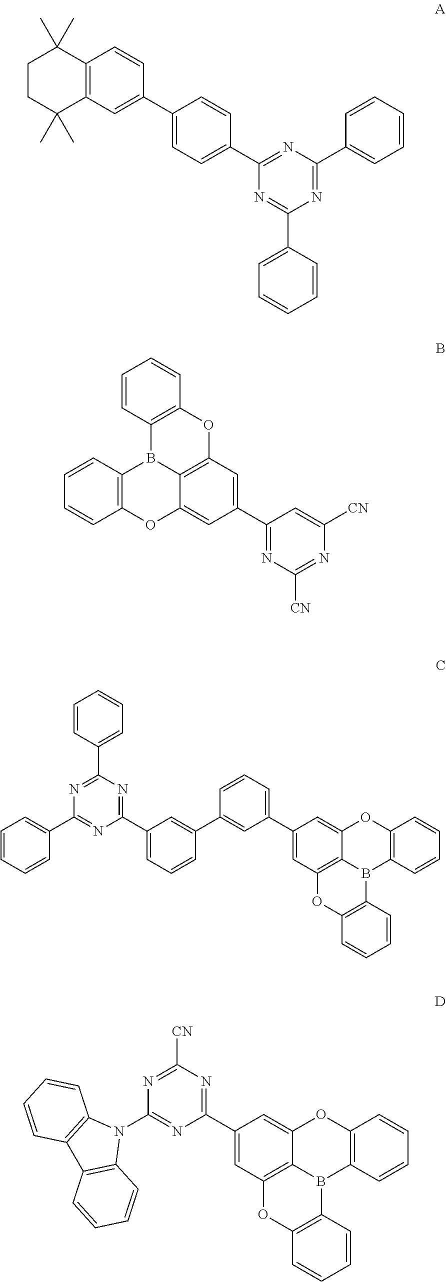 [SMILES: CC1(C)CCC(C)(C)c2cc(-c3ccc(-c4nc(-c5ccccc5)nc(-c5ccccc5)n4)cc3)ccc21 ; N#Cc1cc(-c2cc3c4c(c2)Oc2ccccc2B4c2ccccc2O3)nc(C#N)n1 ; c1ccc(-c2nc(-c3ccccc3)nc(-c3cccc(-c4cccc(-c5cc6c7c(c5)Oc5ccccc5B7c5ccccc5O6)c4)c3)n2)cc1 ; N#Cc1nc(-c2cc3c4c(c2)Oc2ccccc2B4c2ccccc2O3)nc(-n2c3ccccc3c3ccccc32)n1]

Referring to Table 2, it was confirmed that each of the organic light-emitting devices of Examples 1 to 9 had low driving voltage, high luminescence efficiency, and significantly improved lifespan characteristics, compared to the organic light-emitting devices of Comparative Examples 1 to 5.

According to one or more embodiments of the present disclosure, an organic light-emitting device including a heterocyclic compound represented by Formula 1 may have low driving voltage, high efficiency, high color purity, and long lifespan. In addition, a high-quality electronic apparatus and consumer product may be manufactured by using the organic light-emitting device.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light-emitting device, the light-emitting apparatus, the display apparatus/device, the electronic apparatus, the electronic equipment/consumer product, the manufacturing apparatus thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A heterocyclic compound represented by Formula 1: 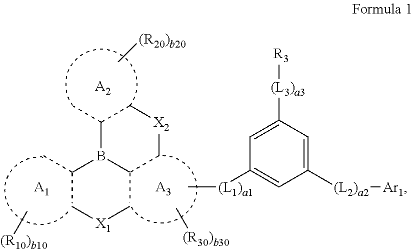
wherein, in Formula 1,
X₁ is O, S, Se, or N(R₁),
X₂ is O, S, Se, or N(R₂),
A₁ to A₃ are each independently a C₅-C₃₀ carbocyclic group or a C₁-C₃₀ heterocyclic group,
L₁ to L₃ are each independently a single bond, a C₅-C₆₀ carbocyclic group unsubstituted or substituted with at least one R₁₀ₐ, or a C₁-C₆₀ heterocyclic group unsubstituted or substituted with at least one R₁₀ₐ,
a1 to a3 are each independently 1, 2, 3, 4, or 5, and
Ar₁ is a group represented by Formula 2, 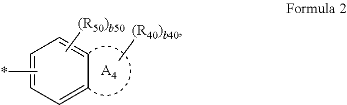
in Formula 2,
A₄ is a C₃-C₁₀ non-aromatic carbocyclic group or a C₁-C₁₀ non-aromatic heterocyclic group, and
* indicates a binding site to a neighboring atom,
in Formula 1 and Formula 2,
R₁ to R₃, R₁₀, R₂₀, R₃₀, R₄₀, and R₅₀ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
at least two neighboring groups selected from among R₁ to R₃, R₁₀, R₂₀, R₃₀, R₄₀, and R₅₀ are optionally bonded together to form a C₅-C₆₀ carbocyclic group unsubstituted or substituted with at least one R₁₀ₐ or a C₁-C₆₀ heterocyclic group unsubstituted or substituted with at least one R₁₀ₐ,
b10, b20, b30, and b40 are each independently 1, 2, 3, 4, 5, 6, 7, or 8,
b50 is 1, 2, or 3,
R₁₀ₐ is:
deuterium, —F, —Cl, —Br, —I, a hydroxyl group, a cyano group, a nitro group, an amidino group, a hydrazino group, or a hydrazono group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; an amidino group; a hydrazino group; a hydrazono group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

2. The heterocyclic compound of claim 1, wherein
A₁ to A₃ are each independently a benzene group, a naphthalene group, a phenanthrene group, a fluoranthene group, a triphenylene group, a pyrene group, a chrysene group, an indene group, a fluorene group, a spiro-bifluorene group, a benzofluorene group, a dibenzofluorene group, an indole group, a pyridine group, a pyrimidine group, a carbazole group, a benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, or a dinaphthothiophene group, and
A₄ is a cyclopentane group, a cyclohexane group, a cycloheptane group, a cyclopentene group, a cyclohexene group, or a cycloheptene group.

3. The heterocyclic compound of claim 1, wherein
Ar₁ is a group represented by Formula 2A or Formula 2B: 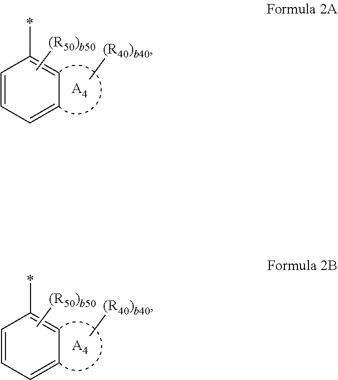
in Formula 2A and Formula 2B,
A₄, R₄₀, R₅₀, b40, and b50 being each the same as defined in Formula 2, and
* indicating a binding site to a neighboring atom.

4. The heterocyclic compound of claim 1, wherein
Ar₁ is a group represented by any one selected from among Formulae 3A to 3D: 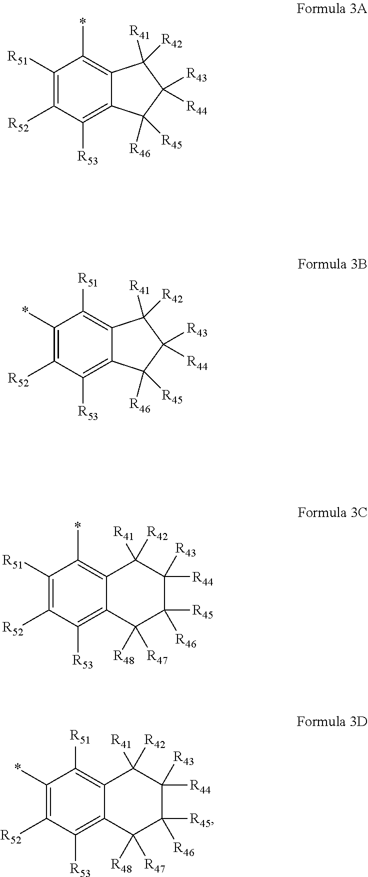
in Formulae 3A to 3D,
R₄₁ to R₄₈ being each independently the same as defined with respect to R₄₀ in Formula 2,
R₅₁ to R₅₃ being each independently the same as defined with respect to R₅₀ in Formula 2, and
* indicating a binding site to a neighboring atom.

5. The heterocyclic compound of claim 1, wherein L₁ to L₃ are each independently a single bond, a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, a dibenzodihydrodisiline group, a dibenzodihydrosiline group, a dibenzodioxin group, a dibenzoxathiin group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

6. The heterocyclic compound of claim 1, wherein L₁ to L₃ are each independently a single bond or a group represented by any one selected from among Formulae 4-1 to 4-25: 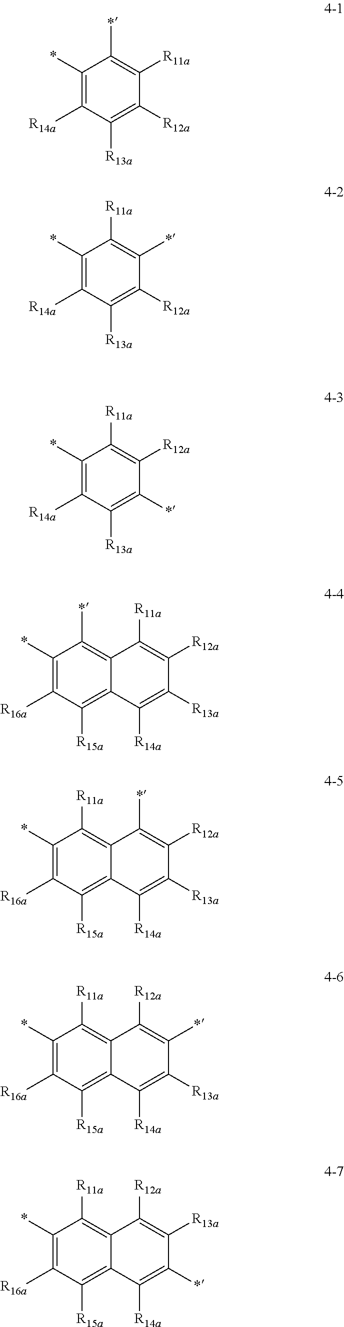 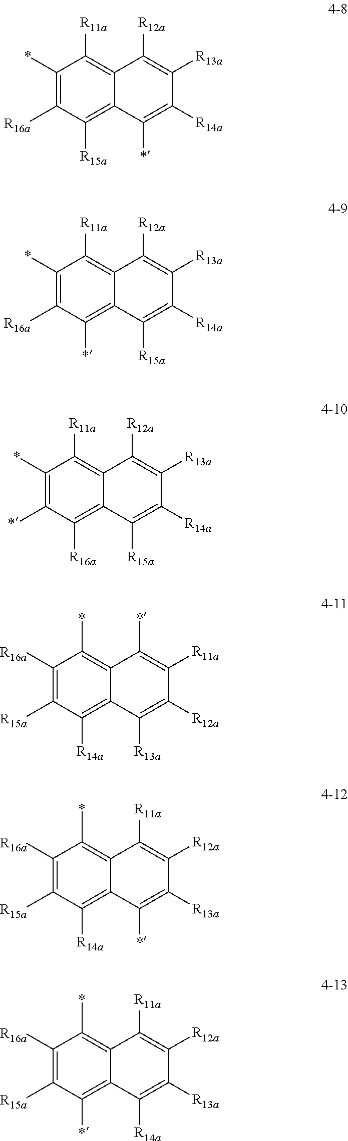 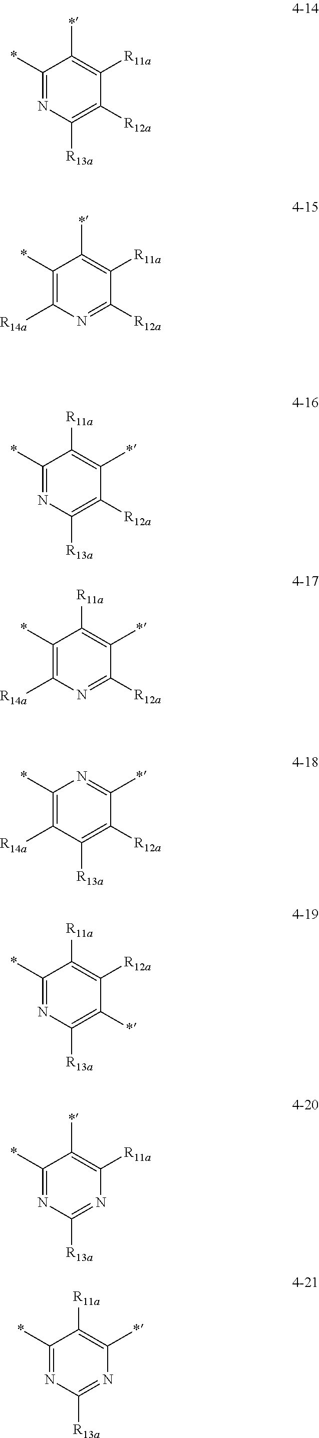 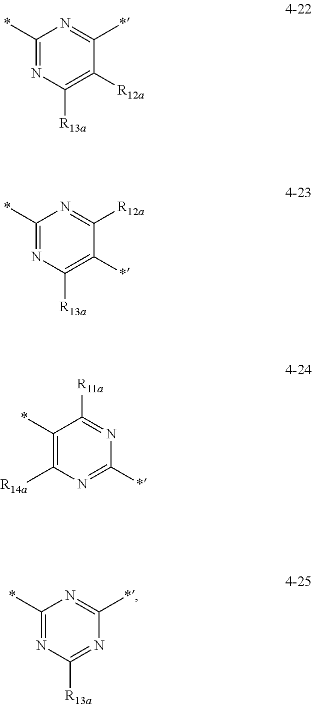
in Formulae 4-1 to 4-25,
R₁₁ₐ to R₁₆ₐ being each independently the same as defined with respect to R₁₀ₐ in Formula 1, and
* and *′ each indicating a binding site to a neighboring atom.

7. The heterocyclic compound of claim 1, wherein R₁ to R₃, R₁₀, R₂₀, R₃₀, R₄₀, and R₅₀ are each independently: hydrogen, deuterium, —F, —Cl, —Br, —I, a cyano group, a C₁-C₂₀ alkyl group, or a C₁-C₂₀ alkoxy group; or a group represented by any one selected from among Formulae 5-1 to 5-26 and Formulae 6-1 to 6-55: 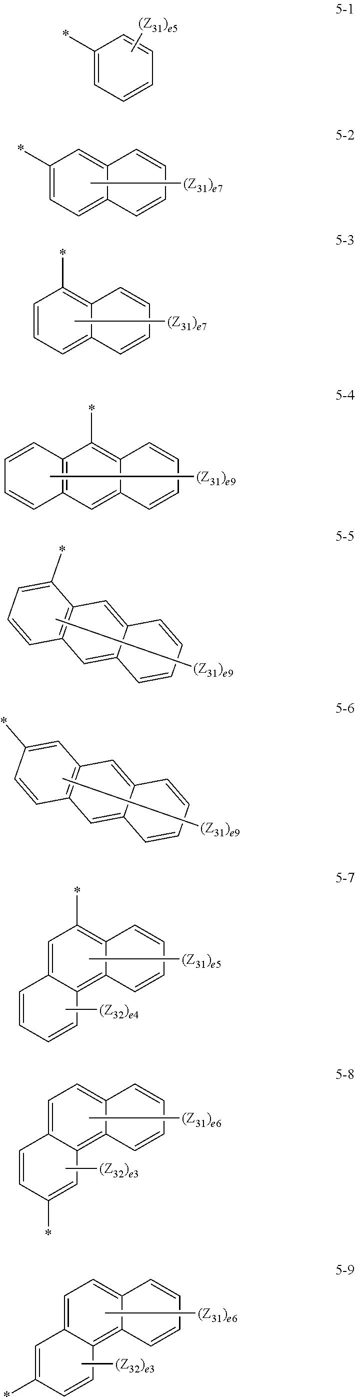 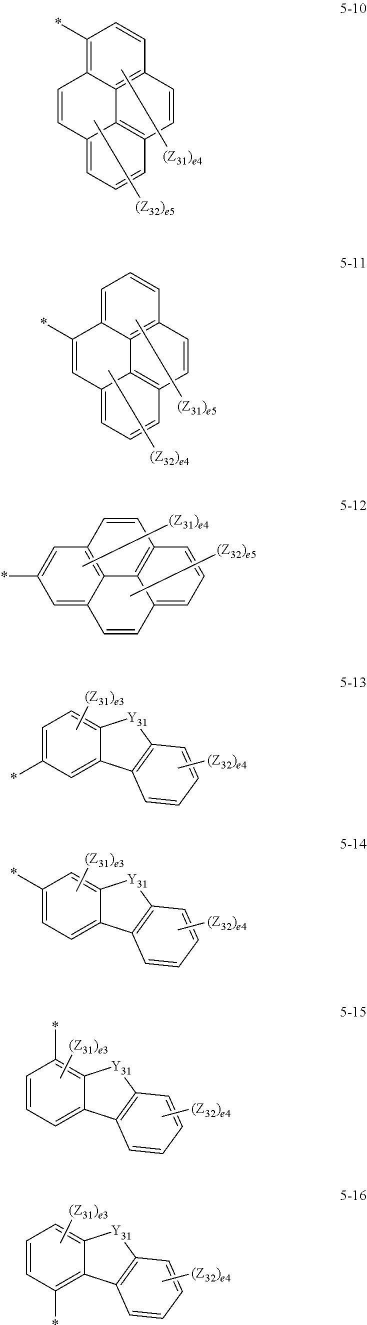 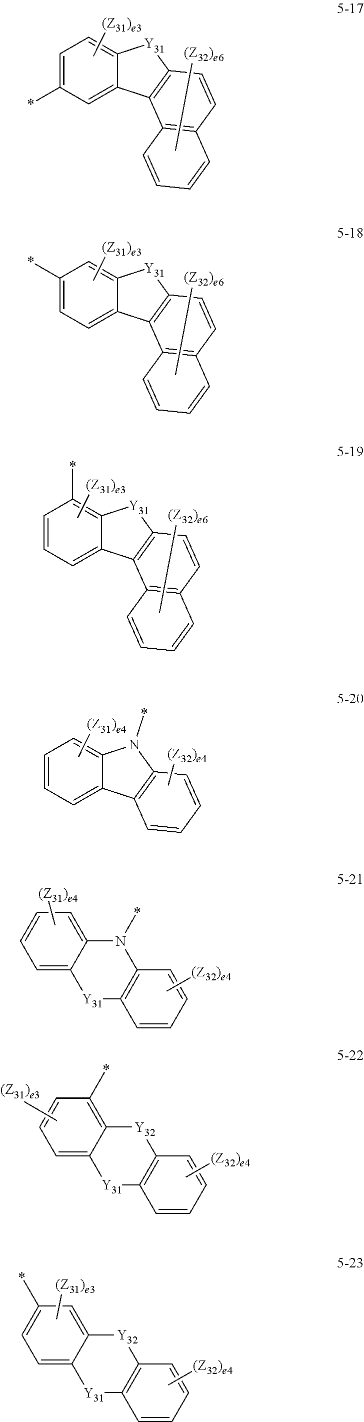 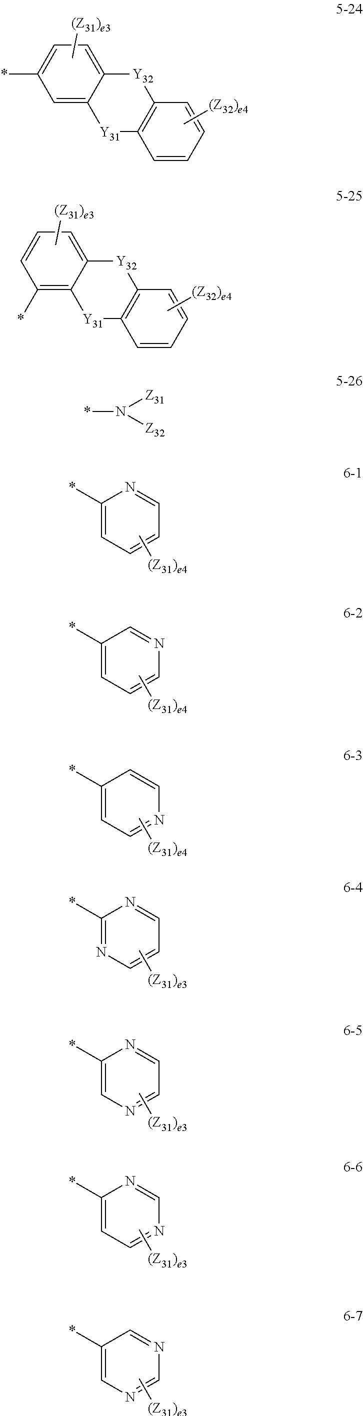 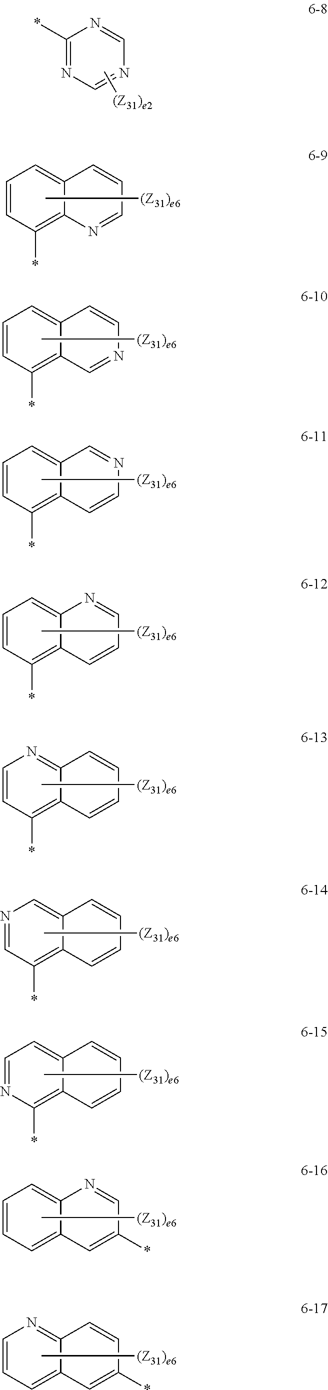 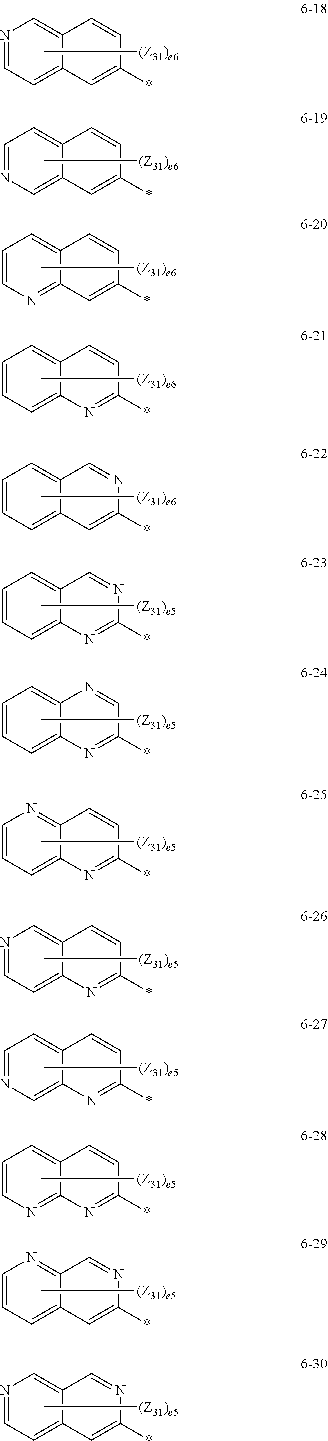 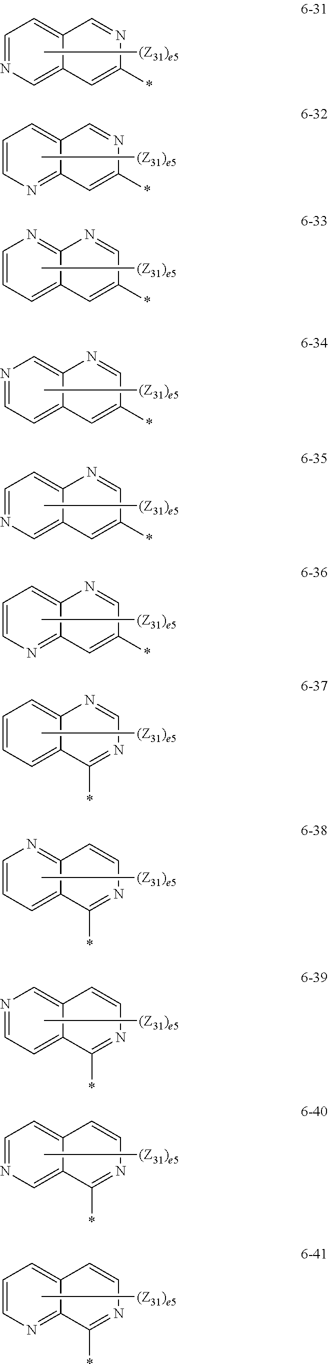 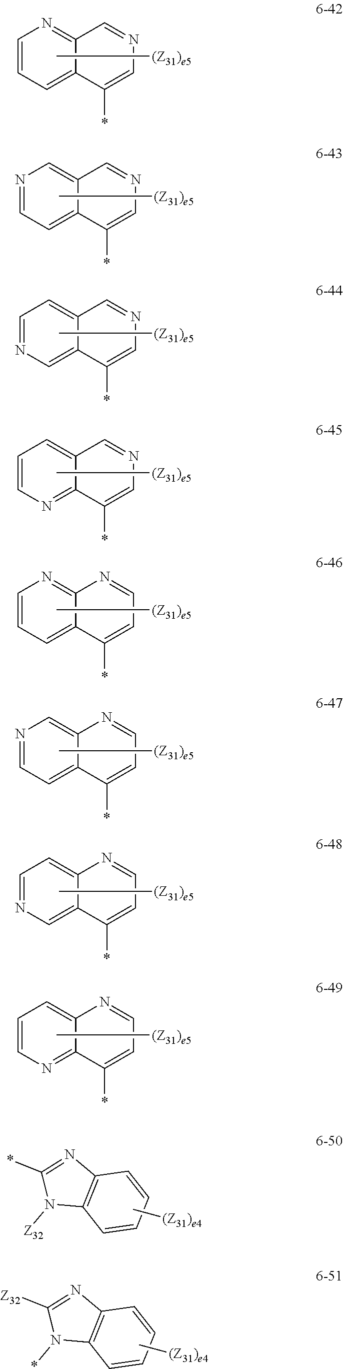 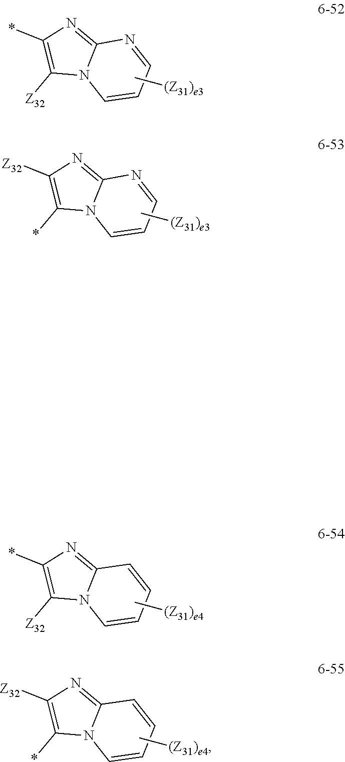
and
wherein, in Formulae 5-1 to 5-26 and 6-1 to 6-55,
Y₃₁ and Y₃₂ are each independently O, S, C(Z₃₃)(Z₃₄), N(Z₃₃), or Si(Z₃₃)(Z₃₄),
Z₃₁ to Z₃₄ are each independently selected from among hydrogen, deuterium, —F, —Cl, —Br, —I, a hydroxyl group, a cyano group, a nitro group, an amidino group, a hydrazino group, a hydrazono group, a C₁₋₂₀ alkyl group, a C₂₋₂₀ alkenyl group, a C₂-C₂₀ alkynyl group, a C₁₋₂₀ alkoxy group, a phenyl group, a biphenyl group, a terphenyl group, a naphthyl group, a fluorenyl group, a spiro-bifluorenyl group, a phenanthrenyl group, an anthracenyl group, a triphenylenyl group, a pyridinyl group, a pyrimidinyl group, a carbazolyl group, and a triazinyl group,
e2 is 1 or 2,
e3 is an integer from 1 to 3,
e4 is an integer from 1 to 4,
e5 is an integer from 1 to 5,
e6 is an integer from 1 to 6,
e7 is an integer from 1 to 7,
e9 is an integer from 1 to 9, and
* indicates a binding site to a neighboring atom.

8. The heterocyclic compound of claim 1, wherein the heterocyclic compound represented by Formula 1 is a heterocyclic compound represented by Formula 11 or Formula 12: 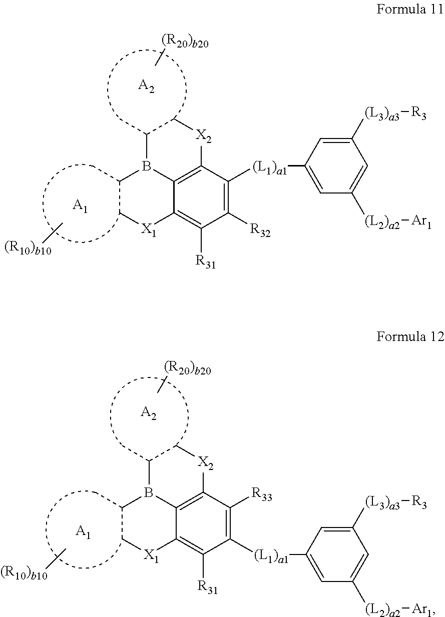
in Formula 11 and Formula 12,
X₁, X₂, A₁, A₂, L₁ to L₃, a1 to a3, Ar₁, R₃, b10, b20, R₁₀, and R₂₀ being each the same as defined in Formula 1, and
R₃₁ to R₃₃ being each independently the same as defined with respect to R₃₀ in Formula 1.

9. The heterocyclic compound of claim 1, wherein the heterocyclic compound represented by Formula 1 is a heterocyclic compound represented by Formula 21 or Formula 22: 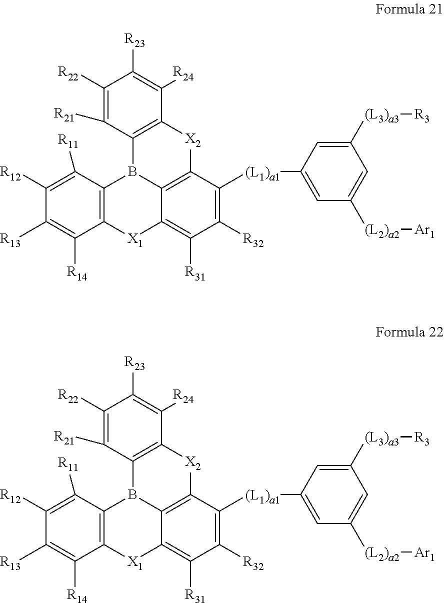
in Formulae 21 and 22,
X₁, X₂, L₁ to L₃, a1 to a3, Ar₁, and R₃, being each the same as defined in Formula 1,
R₁₁ to R₁₄ being each the same as defined with respect to R₁₀ in Formula 1,
R₂₁ to R₂₄ being each the same as defined with respect to R₂₀ in Formula 1, and
R₃₁ to R₃₃ being each the same as defined with respect to R₃₀ in Formula 1.

10. The heterocyclic compound of claim 1, wherein the heterocyclic compound represented by Formula 1 is any one selected from among Compounds 1 to 316:

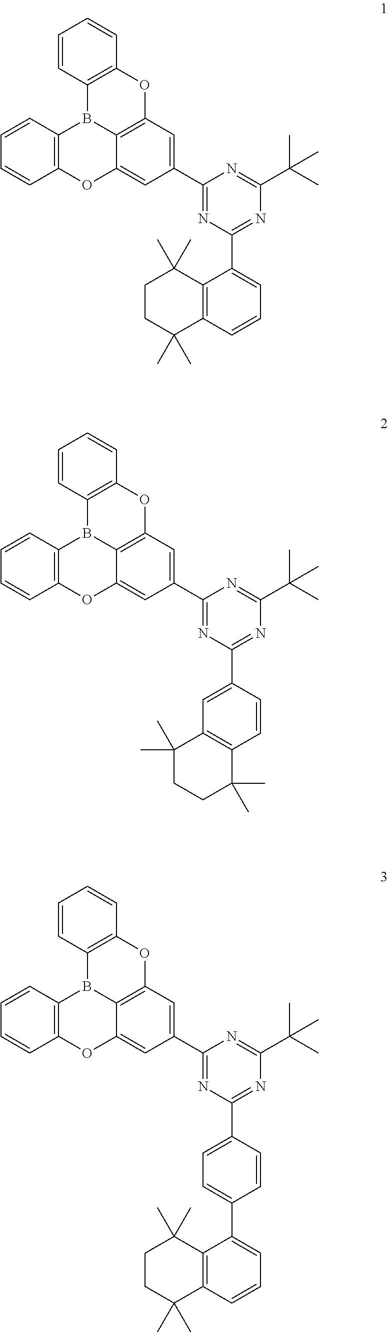 [SMILES: CC(C)(C)c1nc(-c2cc3c4c(c2)Oc2ccccc2B4c2ccccc2O3)nc(-c2cccc3c2C(C)(C)CCC3(C)C)n1 ; CC(C)(C)c1nc(-c2cc3c4c(c2)Oc2ccccc2B4c2ccccc2O3)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)Oc2ccccc2B4c2ccccc2O3)n1]

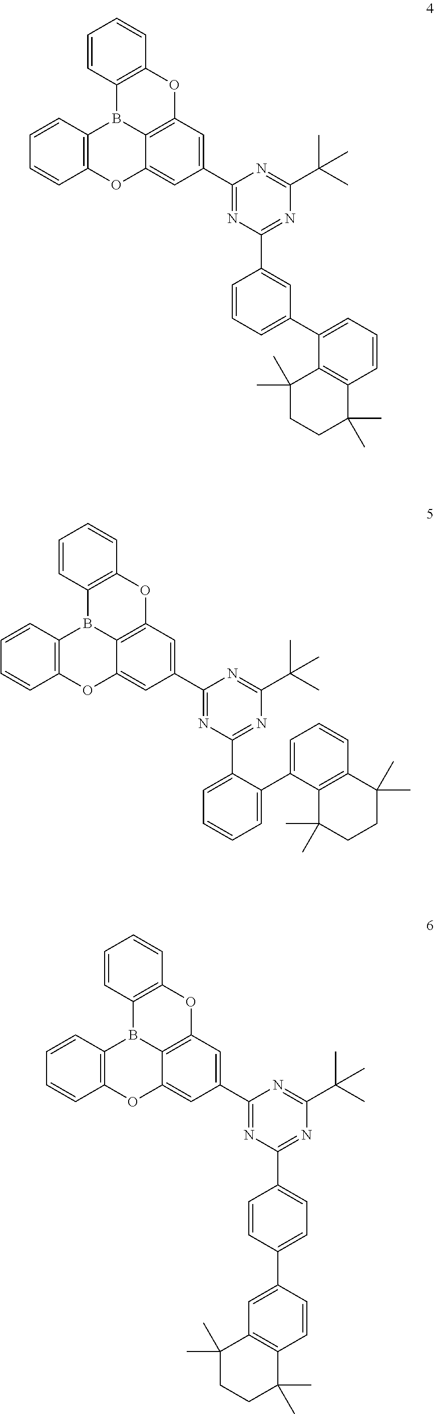 [SMILES: CC(C)(C)c1nc(-c2cccc(-c3cccc4c3C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2cccc3c2C(C)(C)CCC3(C)C)n1 ; CC(C)(C)c1nc(-c2ccc(-c3ccc4c(c3)C(C)(C)CCC4(C)C)cc2)nc(-c2cc3c4c(c2)Oc2ccccc2B4c2ccccc2O3)n1]

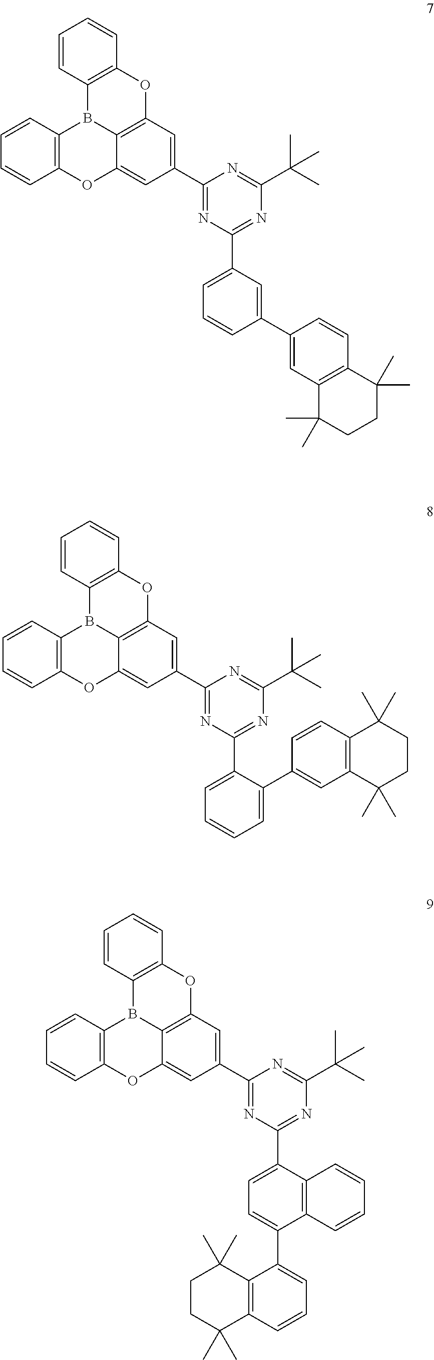 [SMILES: CC(C)(C)c1nc(-c2cccc(-c3ccc4c(c3)C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc3c(c2)C(C)(C)CCC3(C)C)n1 ; CC(C)(C)c1nc(-c2cc3c4c(c2)Oc2ccccc2B4c2ccccc2O3)nc(-c2ccc(-c3cccc4c3C(C)(C)CCC4(C)C)c3ccccc23)n1]

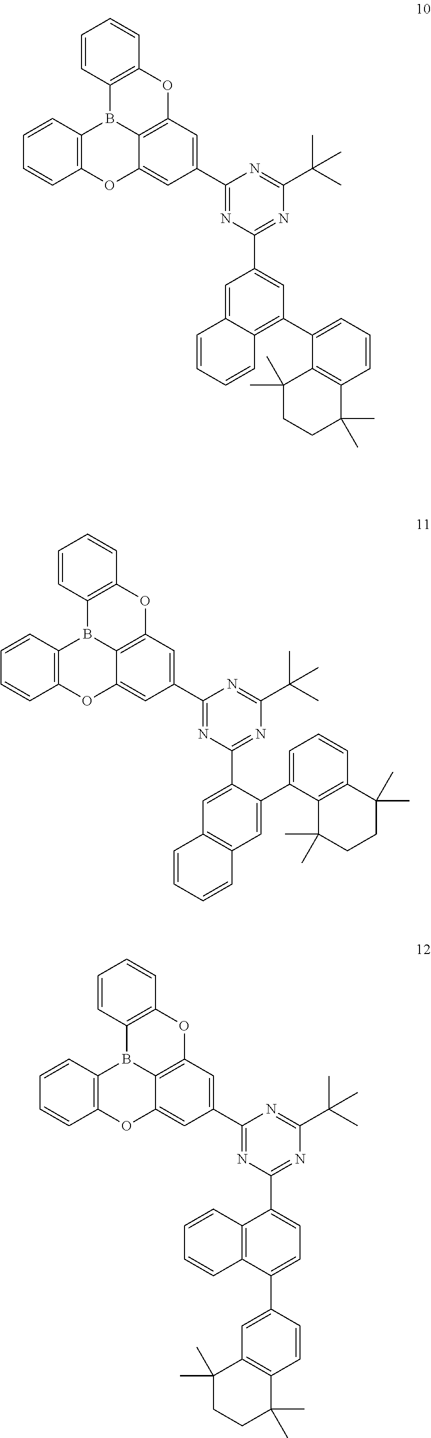 [SMILES: CC(C)(C)c1nc(-c2cc3c4c(c2)Oc2ccccc2B4c2ccccc2O3)nc(-c2cc(-c3cccc4c3C(C)(C)CCC4(C)C)c3ccccc3c2)n1 ; CC(C)(C)c1nc(-c2cc3c4c(c2)Oc2ccccc2B4c2ccccc2O3)nc(-c2cc3ccccc3cc2-c2cccc3c2C(C)(C)CCC3(C)C)n1 ; CC(C)(C)c1nc(-c2cc3c4c(c2)Oc2ccccc2B4c2ccccc2O3)nc(-c2ccc(-c3ccc4c(c3)C(C)(C)CCC4(C)C)c3ccccc23)n1]

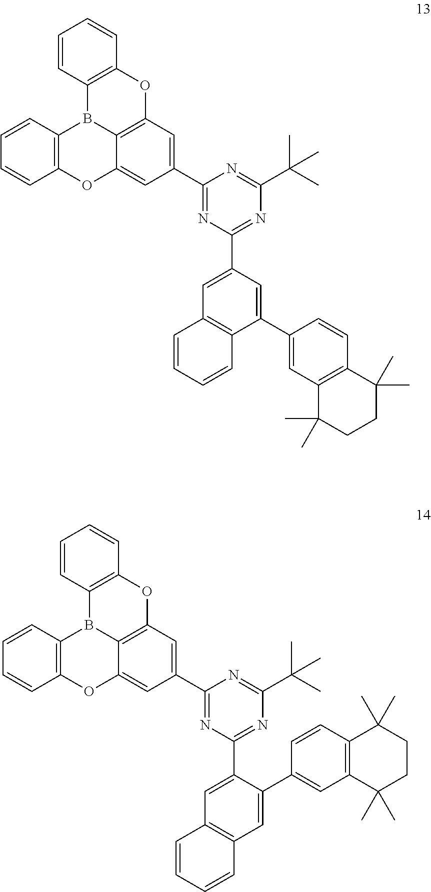 [SMILES: CC(C)(C)c1nc(-c2cc3c4c(c2)Oc2ccccc2B4c2ccccc2O3)nc(-c2cc(-c3ccc4c(c3)C(C)(C)CCC4(C)C)c3ccccc3c2)n1 ; CC(C)(C)c1nc(-c2cc3c4c(c2)Oc2ccccc2B4c2ccccc2O3)nc(-c2cc3ccccc3cc2-c2ccc3c(c2)C(C)(C)CCC3(C)C)n1]

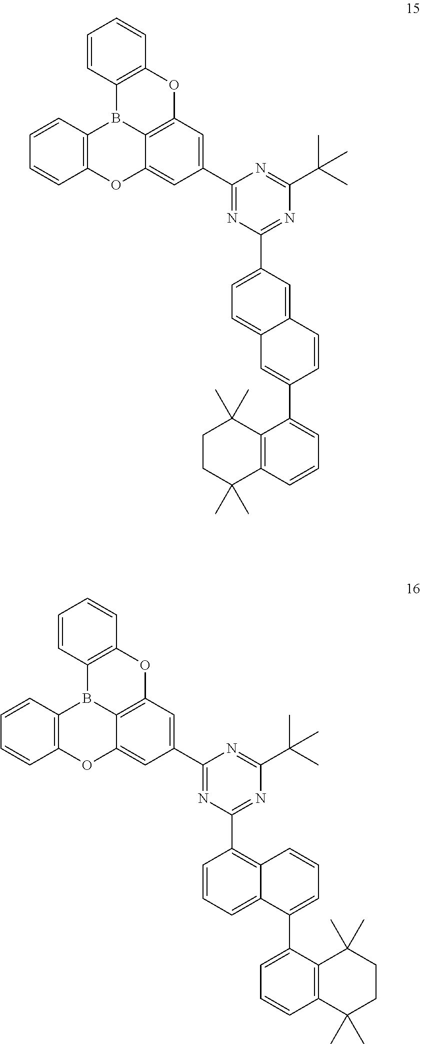 [SMILES: CC(C)(C)c1nc(-c2cc3c4c(c2)Oc2ccccc2B4c2ccccc2O3)nc(-c2ccc3cc(-c4cccc5c4C(C)(C)CCC5(C)C)ccc3c2)n1 ; CC(C)(C)c1nc(-c2cc3c4c(c2)Oc2ccccc2B4c2ccccc2O3)nc(-c2cccc3c(-c4cccc5c4C(C)(C)CCC5(C)C)cccc23)n1]

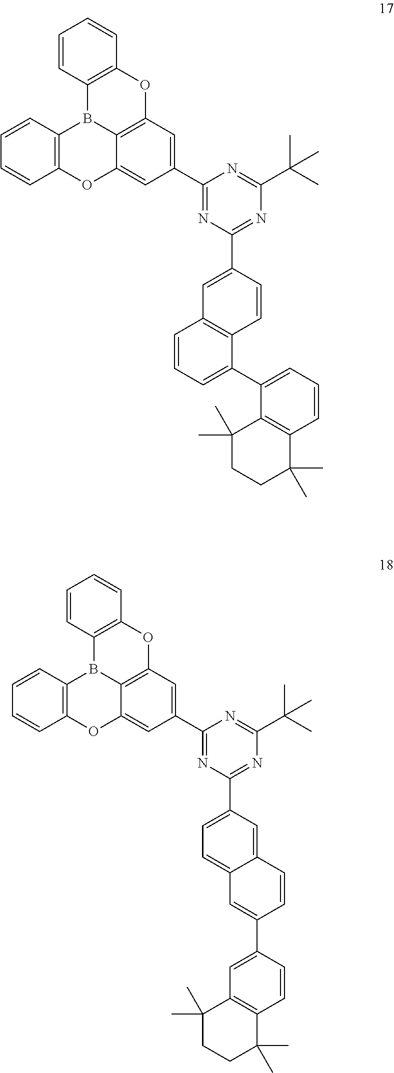 [SMILES: CC(C)(C)c1nc(-c2cc3c4c(c2)Oc2ccccc2B4c2ccccc2O3)nc(-c2ccc3c(-c4cccc5c4C(C)(C)CCC5(C)C)cccc3c2)n1 ; CC(C)(C)c1nc(-c2cc3c4c(c2)Oc2ccccc2B4c2ccccc2O3)nc(-c2ccc3cc(-c4ccc5c(c4)C(C)(C)CCC5(C)C)ccc3c2)n1]

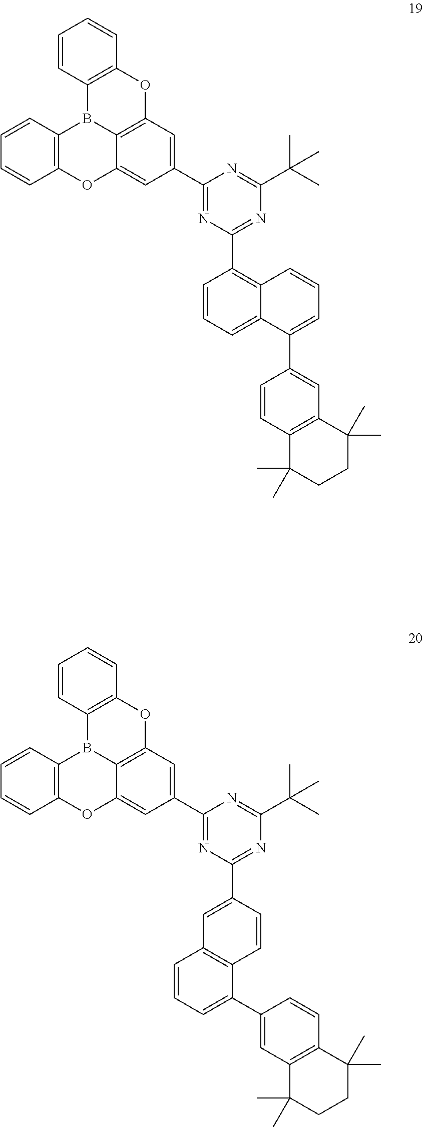 [SMILES: CC(C)(C)c1nc(-c2cc3c4c(c2)Oc2ccccc2B4c2ccccc2O3)nc(-c2cccc3c(-c4ccc5c(c4)C(C)(C)CCC5(C)C)cccc23)n1 ; CC(C)(C)c1nc(-c2cc3c4c(c2)Oc2ccccc2B4c2ccccc2O3)nc(-c2ccc3c(-c4ccc5c(c4)C(C)(C)CCC5(C)C)cccc3c2)n1]

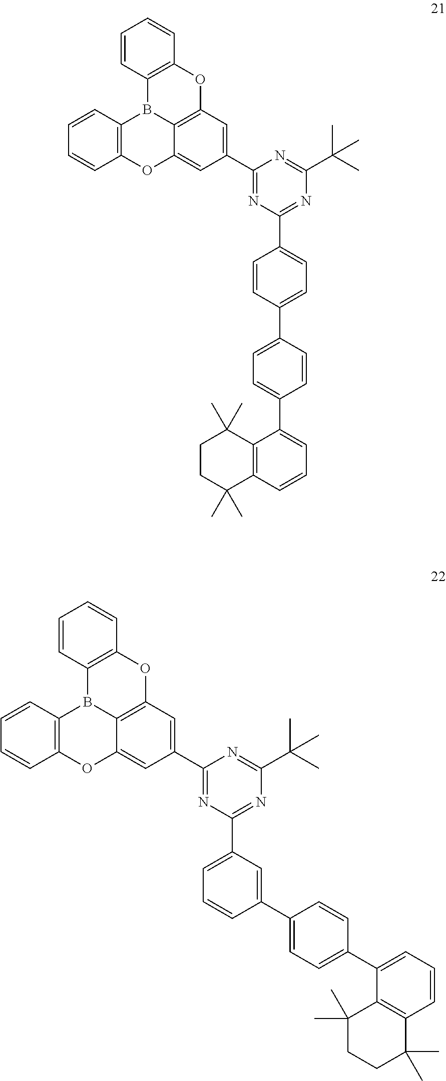 [SMILES: CC(C)(C)c1nc(-c2ccc(-c3ccc(-c4cccc5c4C(C)(C)CCC5(C)C)cc3)cc2)nc(-c2cc3c4c(c2)Oc2ccccc2B4c2ccccc2O3)n1 ; CC(C)(C)c1nc(-c2cccc(-c3ccc(-c4cccc5c4C(C)(C)CCC5(C)C)cc3)c2)nc(-c2cc3c4c(c2)Oc2ccccc2B4c2ccccc2O3)n1]

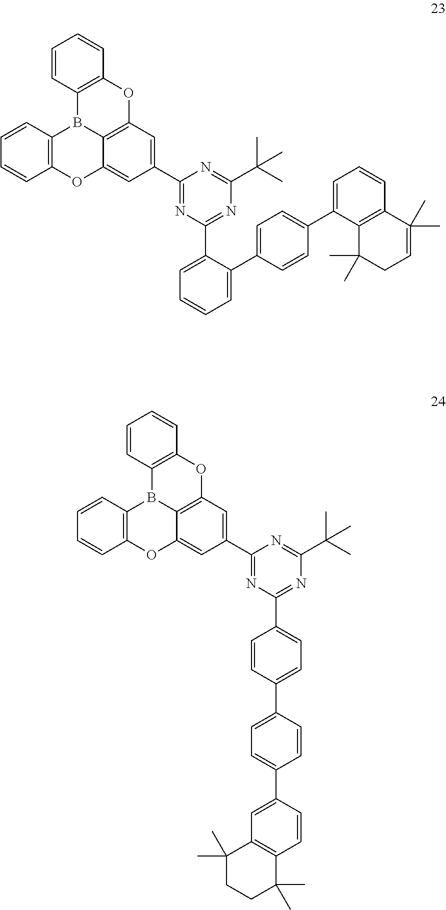

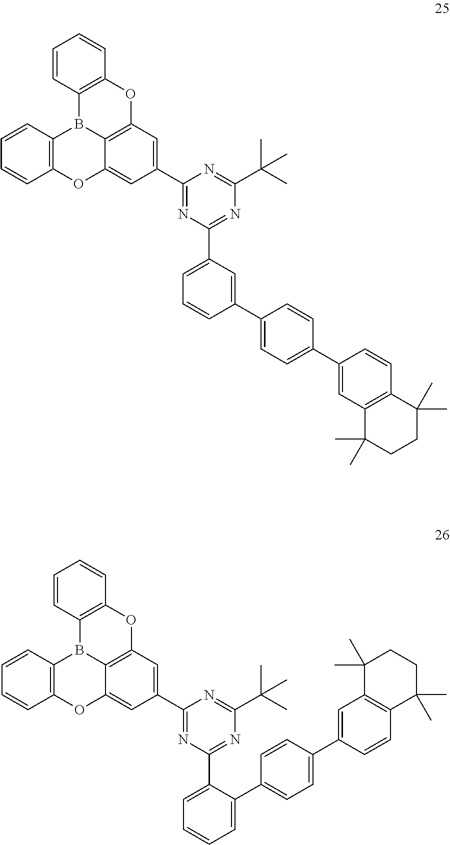 [SMILES: CC(C)(C)c1nc(-c2cccc(-c3ccc(-c4ccc5c(c4)C(C)(C)CCC5(C)C)cc3)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc(-c3ccc4c(c3)C(C)(C)CCC4(C)C)cc2)n1]

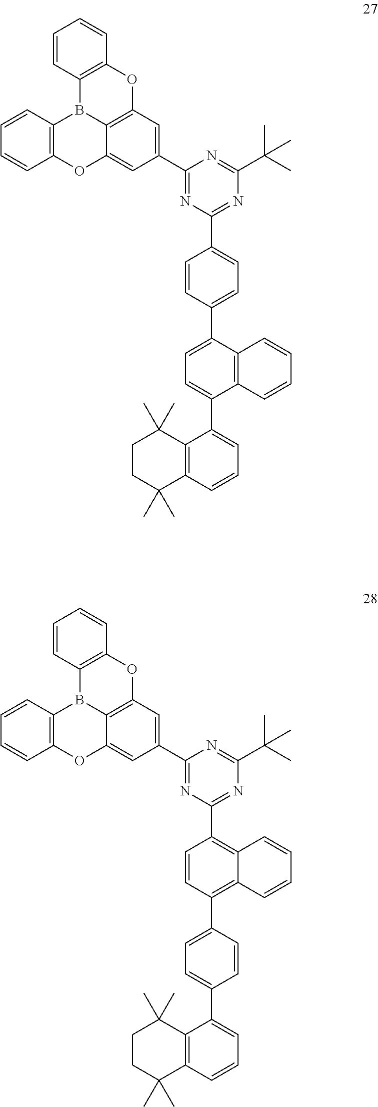 [SMILES: CC(C)(C)c1nc(-c2ccc(-c3ccc(-c4cccc5c4C(C)(C)CCC5(C)C)c4ccccc34)cc2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(-c3ccc(-c4cccc5c4C(C)(C)CCC5(C)C)cc3)c3ccccc23)n1]

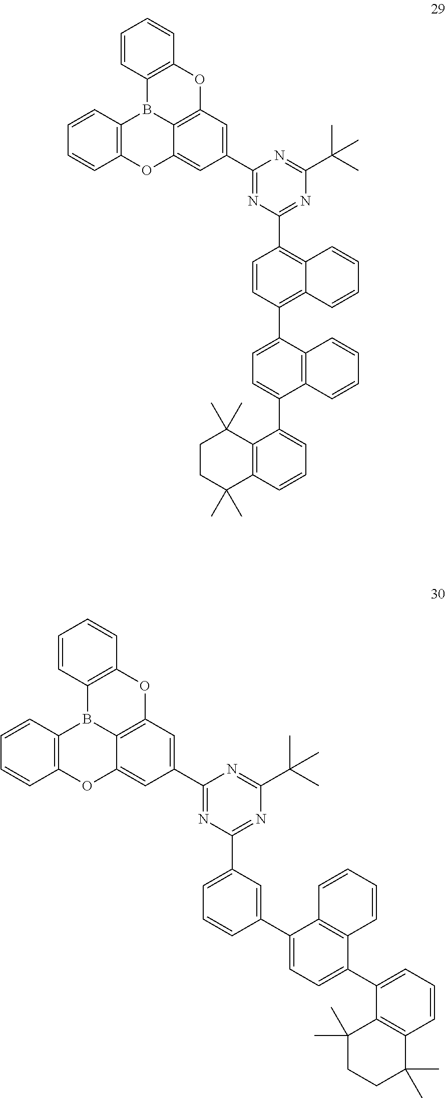 [SMILES: CC(C)(C)c1nc(-c2cc3c4c(c2)Oc2ccccc2B4c2ccccc2O3)nc(-c2ccc(-c3ccc(-c4cccc5c4C(C)(C)CCC5(C)C)c4ccccc34)c3ccccc23)n1 ; CC(C)(C)c1nc(-c2cccc(-c3ccc(-c4cccc5c4C(C)(C)CCC5(C)C)c4ccccc34)c2)nc(-c2cc3c4c(c2)Oc2ccccc2B4c2ccccc2O3)n1]

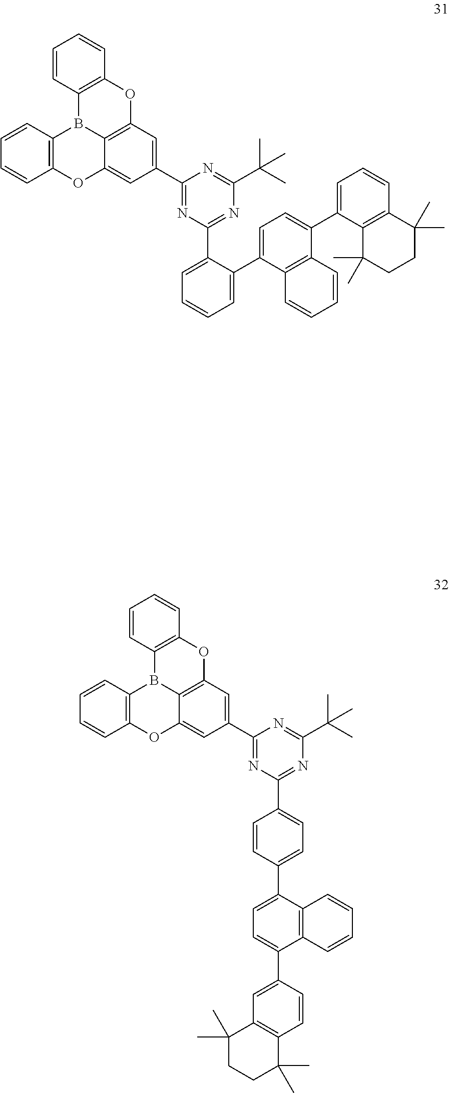 [SMILES: CC(C)(C)c1nc(-c2cc3c4c(c2)Oc2ccccc2B4c2ccccc2O3)nc(-c2ccccc2-c2ccc(-c3cccc4c3C(C)(C)CCC4(C)C)c3ccccc23)n1 ; CC(C)(C)c1nc(-c2ccc(-c3ccc(-c4ccc5c(c4)C(C)(C)CCC5(C)C)c4ccccc34)cc2)nc(-c2cc3c4c(c2)Oc2ccccc2B4c2ccccc2O3)n1]

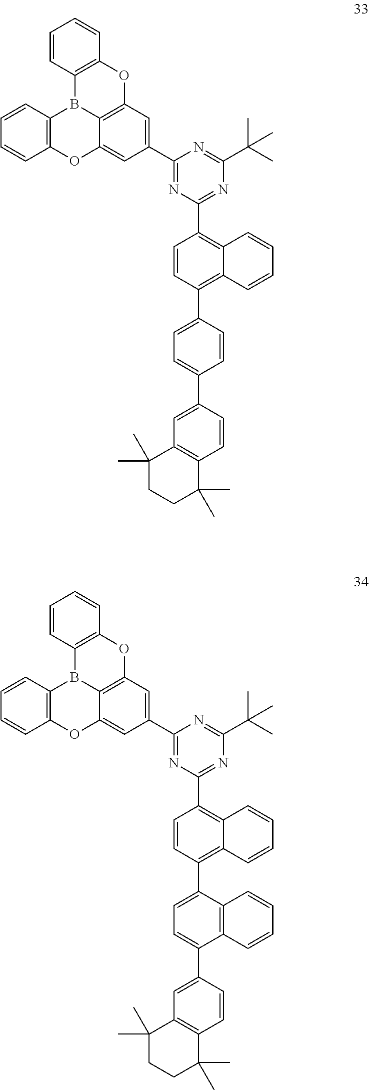 [SMILES: CC(C)(C)c1nc(-c2cc3c4c(c2)Oc2ccccc2B4c2ccccc2O3)nc(-c2ccc(-c3ccc(-c4ccc5c(c4)C(C)(C)CCC5(C)C)cc3)c3ccccc23)n1 ; CC(C)(C)c1nc(-c2cc3c4c(c2)Oc2ccccc2B4c2ccccc2O3)nc(-c2ccc(-c3ccc(-c4ccc5c(c4)C(C)(C)CCC5(C)C)c4ccccc34)c3ccccc23)n1]

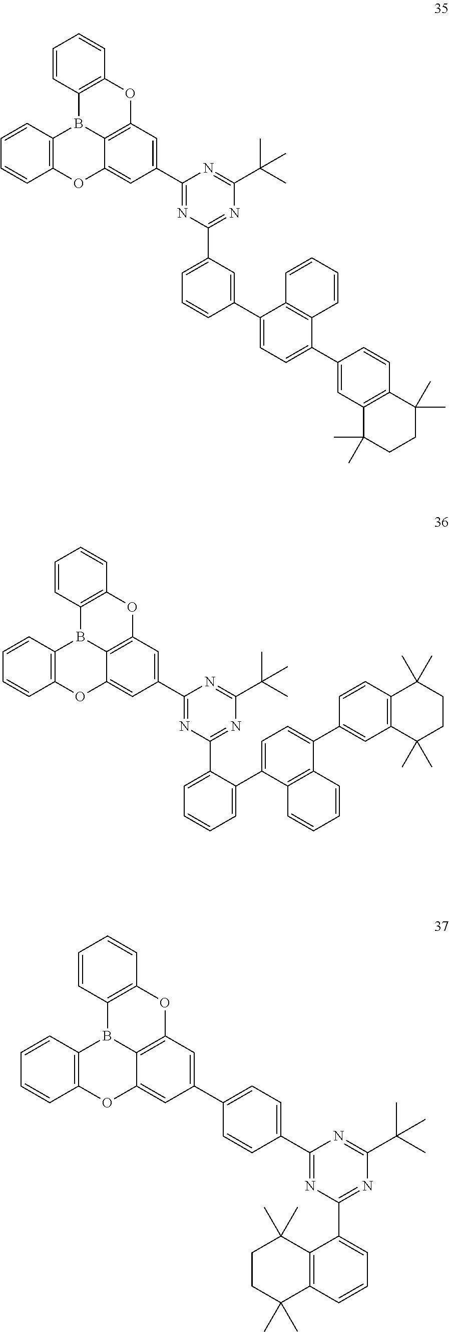 [SMILES: CC(C)(C)c1nc(-c2cccc(-c3ccc(-c4ccc5c(c4)C(C)(C)CCC5(C)C)c4ccccc34)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccccc2-c2ccc(-c3ccc4c(c3)C(C)(C)CCC4(C)C)c3ccccc23)n1 ; CC(C)(C)c1nc(-c2ccc(-c3cc4c5c(c3)Oc3ccccc3B5c3ccccc3O4)cc2)nc(-c2cccc3c2C(C)(C)CCC3(C)C)n1]

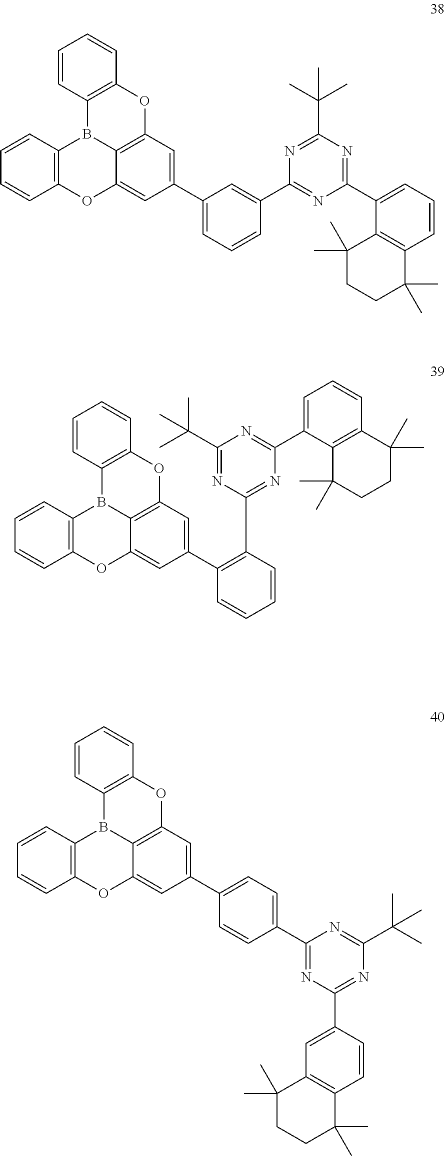 [SMILES: CC(C)(C)c1nc(-c2cccc(-c3cc4c5c(c3)Oc3ccccc3B5c3ccccc3O4)c2)nc(-c2cccc3c2C(C)(C)CCC3(C)C)n1 ; CC(C)(C)c1nc(-c2ccccc2-c2cc3c4c(c2)Oc2ccccc2B4c2ccccc2O3)nc(-c2cccc3c2C(C)(C)CCC3(C)C)n1 ; CC(C)(C)c1nc(-c2ccc(-c3cc4c5c(c3)Oc3ccccc3B5c3ccccc3O4)cc2)nc(-c2ccc3c(c2)C(C)(C)CCC3(C)C)n1]

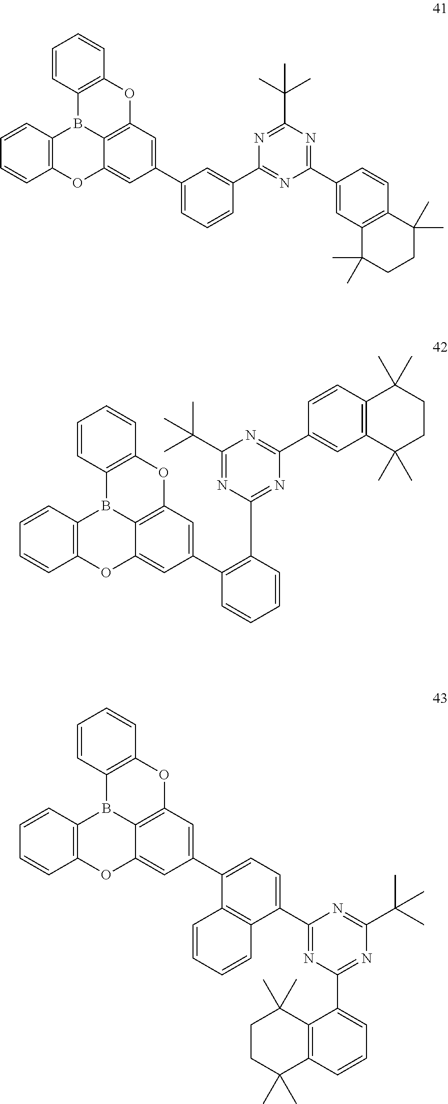 [SMILES: CC(C)(C)c1nc(-c2cccc(-c3cc4c5c(c3)Oc3ccccc3B5c3ccccc3O4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Oc2ccccc2B4c2ccccc2O3)n1 ; CC(C)(C)c1nc(-c2cccc3c2C(C)(C)CCC3(C)C)nc(-c2ccc(-c3cc4c5c(c3)Oc3ccccc3B5c3ccccc3O4)c3ccccc23)n1]

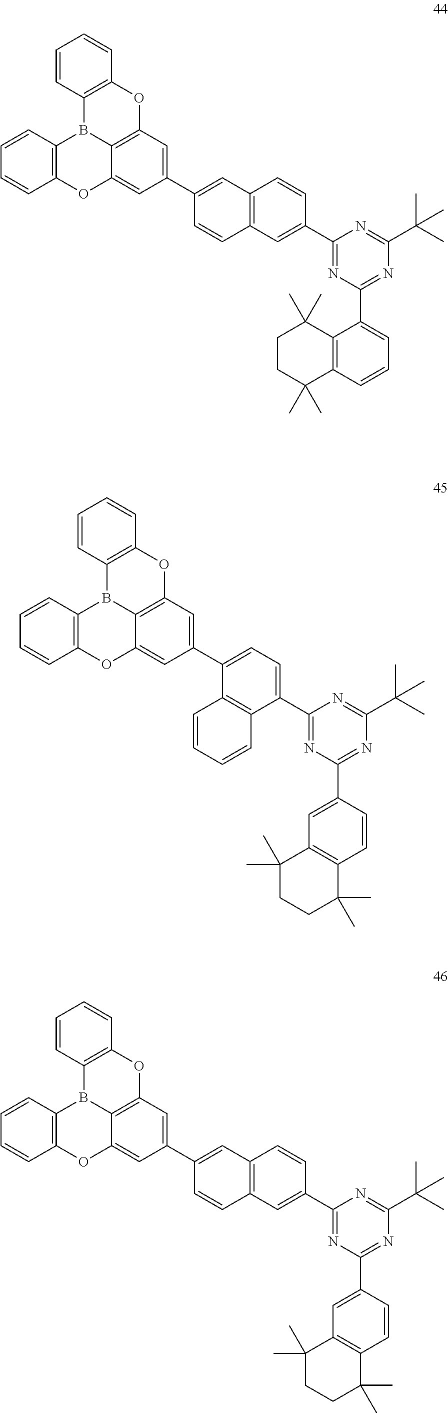 [SMILES: CC(C)(C)c1nc(-c2ccc3cc(-c4cc5c6c(c4)Oc4ccccc4B6c4ccccc4O5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Oc3ccccc3B5c3ccccc3O4)c3ccccc23)n1 ; CC(C)(C)c1nc(-c2ccc3c(c2)C(C)(C)CCC3(C)C)nc(-c2ccc3cc(-c4cc5c6c(c4)Oc4ccccc4B6c4ccccc4O5)ccc3c2)n1]

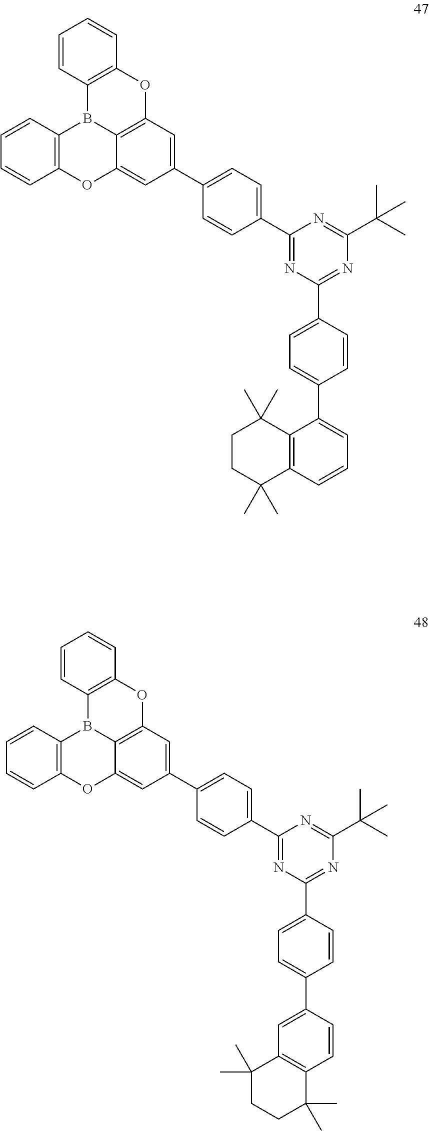 [SMILES: CC(C)(C)c1nc(-c2ccc(-c3cc4c5c(c3)Oc3ccccc3B5c3ccccc3O4)cc2)nc(-c2ccc(-c3cccc4c3C(C)(C)CCC4(C)C)cc2)n1 ; CC(C)(C)c1nc(-c2ccc(-c3cc4c5c(c3)Oc3ccccc3B5c3ccccc3O4)cc2)nc(-c2ccc(-c3ccc4c(c3)C(C)(C)CCC4(C)C)cc2)n1]

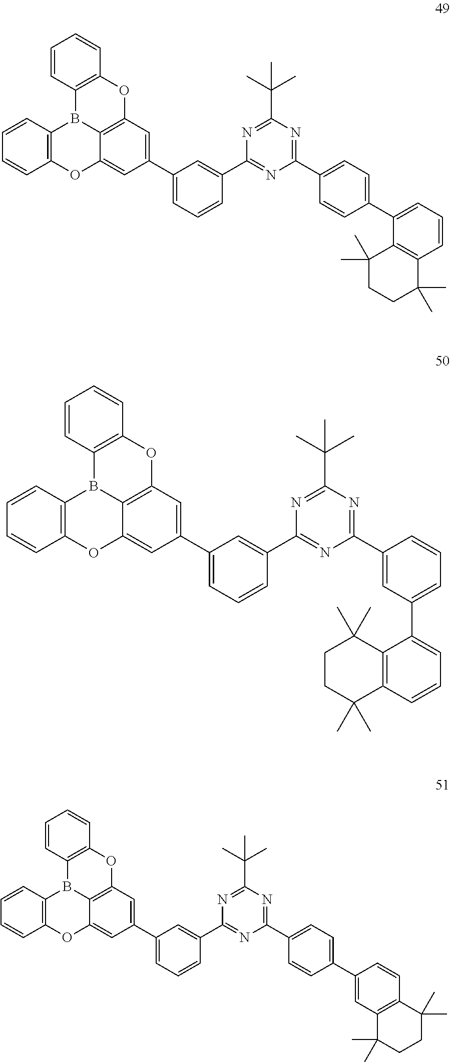 [SMILES: CC(C)(C)c1nc(-c2ccc(-c3cccc4c3C(C)(C)CCC4(C)C)cc2)nc(-c2cccc(-c3cc4c5c(c3)Oc3ccccc3B5c3ccccc3O4)c2)n1 ; CC(C)(C)c1nc(-c2cccc(-c3cc4c5c(c3)Oc3ccccc3B5c3ccccc3O4)c2)nc(-c2cccc(-c3cccc4c3C(C)(C)CCC4(C)C)c2)n1 ; CC(C)(C)c1nc(-c2ccc(-c3ccc4c(c3)C(C)(C)CCC4(C)C)cc2)nc(-c2cccc(-c3cc4c5c(c3)Oc3ccccc3B5c3ccccc3O4)c2)n1]

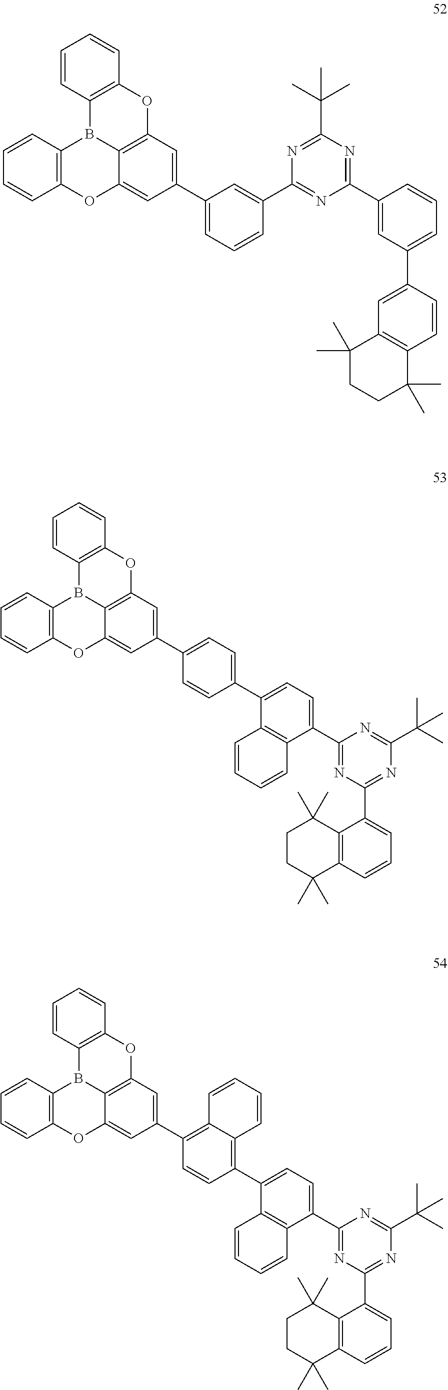 [SMILES: CC(C)(C)c1nc(-c2cccc(-c3cc4c5c(c3)Oc3ccccc3B5c3ccccc3O4)c2)nc(-c2cccc(-c3ccc4c(c3)C(C)(C)CCC4(C)C)c2)n1 ; CC(C)(C)c1nc(-c2cccc3c2C(C)(C)CCC3(C)C)nc(-c2ccc(-c3ccc(-c4cc5c6c(c4)Oc4ccccc4B6c4ccccc4O5)cc3)c3ccccc23)n1 ; CC(C)(C)c1nc(-c2cccc3c2C(C)(C)CCC3(C)C)nc(-c2ccc(-c3ccc(-c4cc5c6c(c4)Oc4ccccc4B6c4ccccc4O5)c4ccccc34)c3ccccc23)n1]

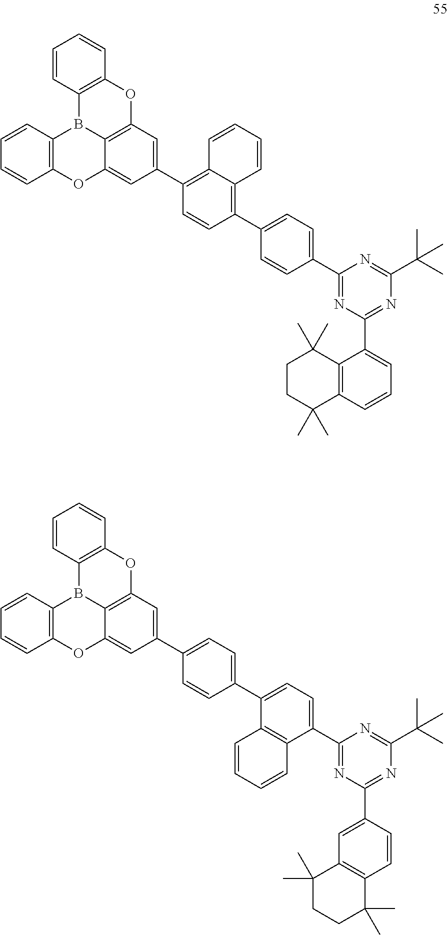 [SMILES: CC(C)(C)c1nc(-c2ccc(-c3ccc(-c4cc5c6c(c4)Oc4ccccc4B6c4ccccc4O5)c4ccccc34)cc2)nc(-c2cccc3c2C(C)(C)CCC3(C)C)n1 ; CC(C)(C)c1nc(-c2ccc3c(c2)C(C)(C)CCC3(C)C)nc(-c2ccc(-c3ccc(-c4cc5c6c(c4)Oc4ccccc4B6c4ccccc4O5)cc3)c3ccccc23)n1]

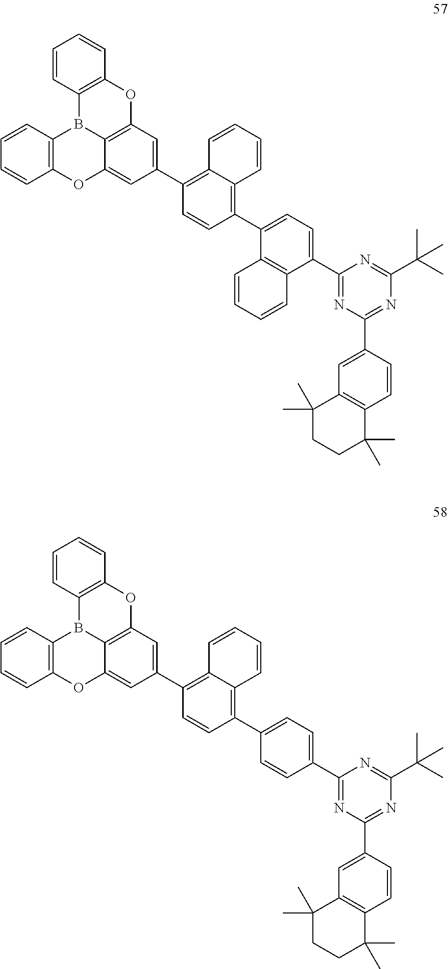 [SMILES: CC(C)(C)c1nc(-c2ccc3c(c2)C(C)(C)CCC3(C)C)nc(-c2ccc(-c3ccc(-c4cc5c6c(c4)Oc4ccccc4B6c4ccccc4O5)c4ccccc34)c3ccccc23)n1 ; CC(C)(C)c1nc(-c2ccc(-c3ccc(-c4cc5c6c(c4)Oc4ccccc4B6c4ccccc4O5)c4ccccc34)cc2)nc(-c2ccc3c(c2)C(C)(C)CCC3(C)C)n1]

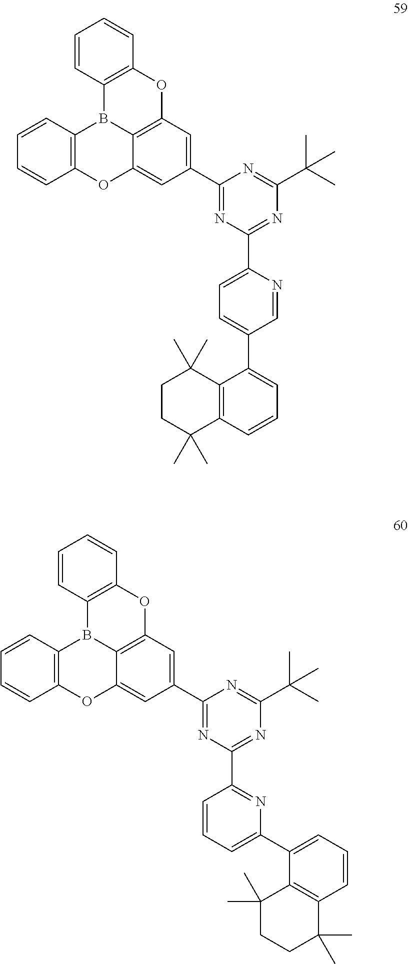 [SMILES: CC(C)(C)c1nc(-c2cc3c4c(c2)Oc2ccccc2B4c2ccccc2O3)nc(-c2ccc(-c3cccc4c3C(C)(C)CCC4(C)C)cn2)n1 ; CC(C)(C)c1nc(-c2cc3c4c(c2)Oc2ccccc2B4c2ccccc2O3)nc(-c2cccc(-c3cccc4c3C(C)(C)CCC4(C)C)n2)n1]

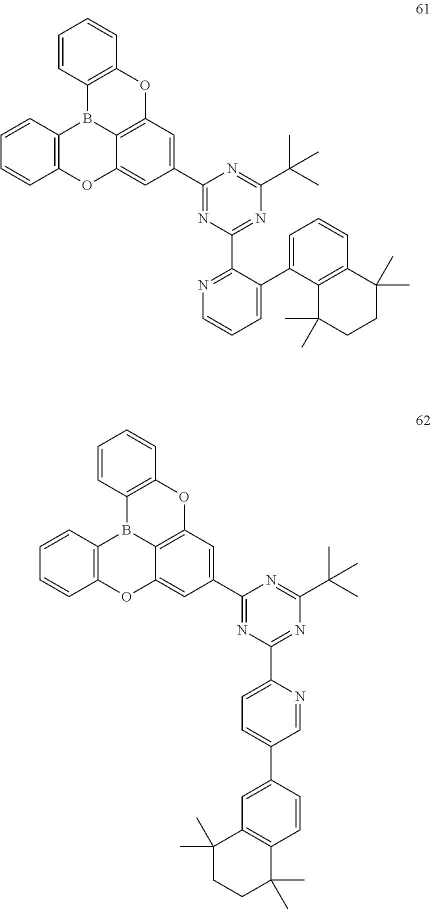 [SMILES: CC(C)(C)c1nc(-c2cc3c4c(c2)Oc2ccccc2B4c2ccccc2O3)nc(-c2ncccc2-c2cccc3c2C(C)(C)CCC3(C)C)n1 ; CC(C)(C)c1nc(-c2cc3c4c(c2)Oc2ccccc2B4c2ccccc2O3)nc(-c2ccc(-c3ccc4c(c3)C(C)(C)CCC4(C)C)cn2)n1]

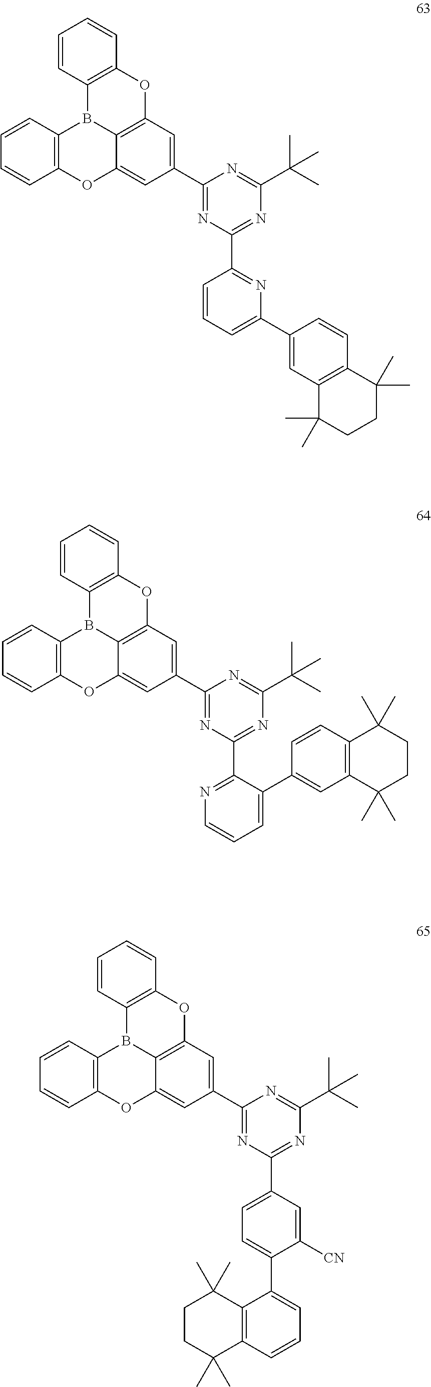 [SMILES: CC(C)(C)c1nc(-c2cc3c4c(c2)Oc2ccccc2B4c2ccccc2O3)nc(-c2cccc(-c3ccc4c(c3)C(C)(C)CCC4(C)C)n2)n1 ; CC(C)(C)c1nc(-c2cc3c4c(c2)Oc2ccccc2B4c2ccccc2O3)nc(-c2ncccc2-c2ccc3c(c2)C(C)(C)CCC3(C)C)n1 ; CC(C)(C)c1nc(-c2ccc(-c3cccc4c3C(C)(C)CCC4(C)C)c(C#N)c2)nc(-c2cc3c4c(c2)Oc2ccccc2B4c2ccccc2O3)n1]

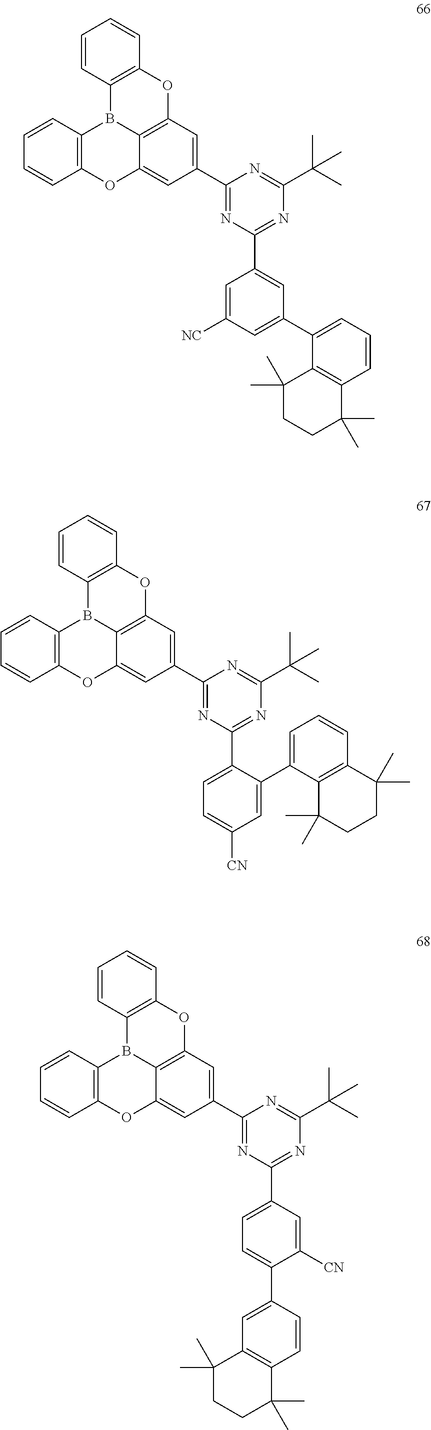 [SMILES: CC(C)(C)c1nc(-c2cc(C#N)cc(-c3cccc4c3C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(C#N)cc2-c2cccc3c2C(C)(C)CCC3(C)C)n1 ; CC(C)(C)c1nc(-c2ccc(-c3ccc4c(c3)C(C)(C)CCC4(C)C)c(C#N)c2)nc(-c2cc3c4c(c2)Oc2ccccc2B4c2ccccc2O3)n1]

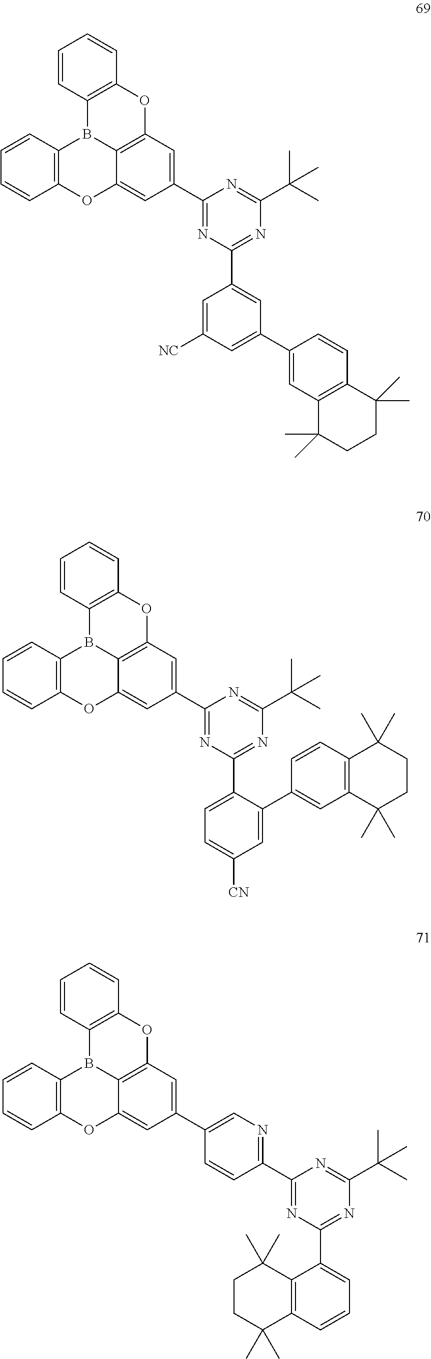 [SMILES: CC(C)(C)c1nc(-c2cc(C#N)cc(-c3ccc4c(c3)C(C)(C)CCC4(C)C)c2)nc(-c2cc3c4c(c2)Oc2ccccc2B4c2ccccc2O3)n1 ; CC(C)(C)c1nc(-c2cc3c4c(c2)Oc2ccccc2B4c2ccccc2O3)nc(-c2ccc(C#N)cc2-c2ccc3c(c2)C(C)(C)CCC3(C)C)n1 ; CC(C)(C)c1nc(-c2ccc(-c3cc4c5c(c3)Oc3ccccc3B5c3ccccc3O4)cn2)nc(-c2cccc3c2C(C)(C)CCC3(C)C)n1]

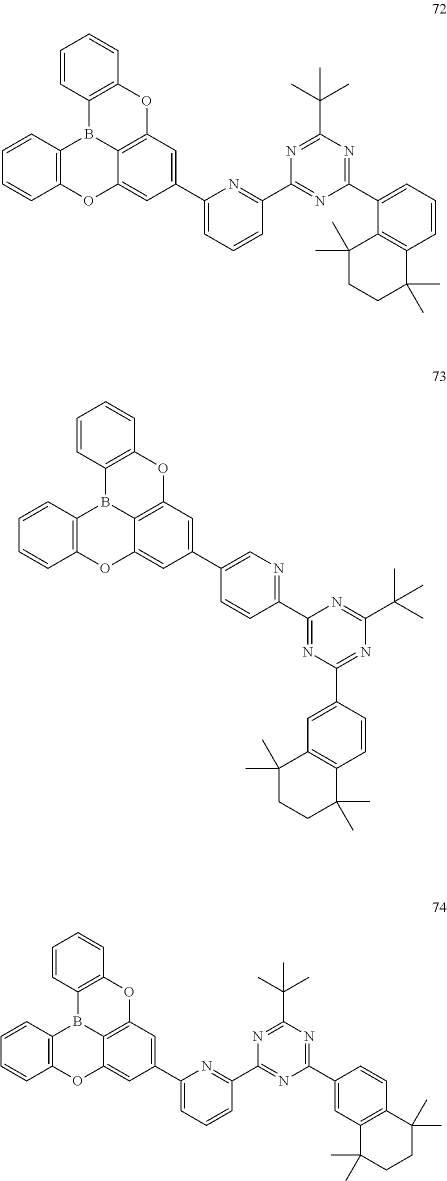 [SMILES: CC(C)(C)c1nc(-c2cccc(-c3cc4c5c(c3)Oc3ccccc3B5c3ccccc3O4)n2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Oc3ccccc3B5c3ccccc3O4)cn2)n1 ; CC(C)(C)c1nc(-c2ccc3c(c2)C(C)(C)CCC3(C)C)nc(-c2cccc(-c3cc4c5c(c3)Oc3ccccc3B5c3ccccc3O4)n2)n1]

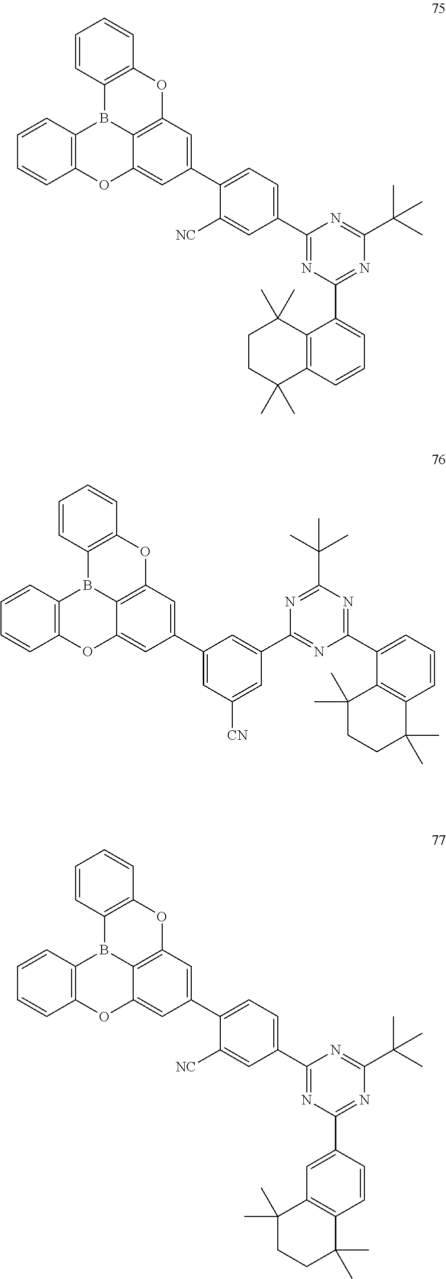 [SMILES: CC(C)(C)c1nc(-c2ccc(-c3cc4c5c(c3)Oc3ccccc3B5c3ccccc3O4)c(C#N)c2)nc(-c2cccc3c2C(C)(C)CCC3(C)C)n1 ; CC(C)(C)c1nc(-c2cc(C#N)cc(-c3cc4c5c(c3)Oc3ccccc3B5c3ccccc3O4)c2)nc(-c2cccc3c2C(C)(C)CCC3(C)C)n1 ; CC(C)(C)c1nc(-c2ccc(-c3cc4c5c(c3)Oc3ccccc3B5c3ccccc3O4)c(C#N)c2)nc(-c2ccc3c(c2)C(C)(C)CCC3(C)C)n1]

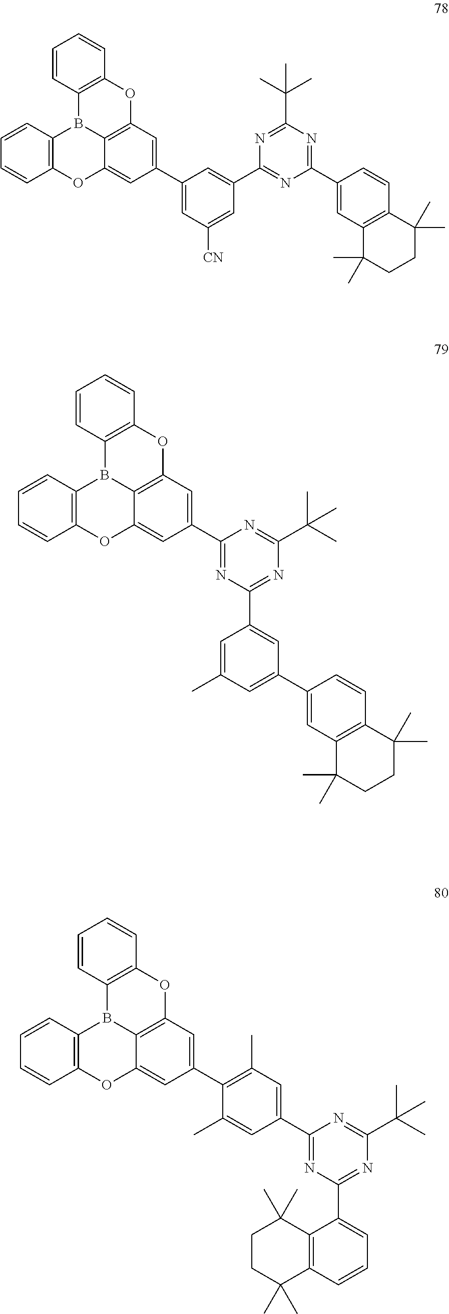 [SMILES: CC(C)(C)c1nc(-c2cc(C#N)cc(-c3cc4c5c(c3)Oc3ccccc3B5c3ccccc3O4)c2)nc(-c2ccc3c(c2)C(C)(C)CCC3(C)C)n1 ; Cc1cc(-c2ccc3c(c2)C(C)(C)CCC3(C)C)cc(-c2nc(-c3cc4c5c(c3)Oc3ccccc3B5c3ccccc3O4)nc(C(C)(C)C)n2)c1 ; Cc1cc(-c2nc(-c3cccc4c3C(C)(C)CCC4(C)C)nc(C(C)(C)C)n2)cc(C)c1-c1cc2c3c(c1)Oc1ccccc1B3c1ccccc1O2]

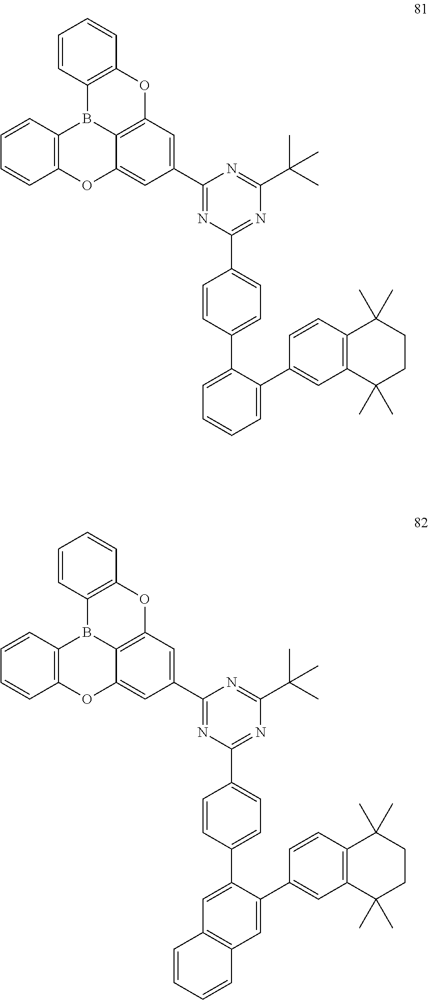 [SMILES: CC(C)(C)c1nc(-c2ccc(-c3ccccc3-c3ccc4c(c3)C(C)(C)CCC4(C)C)cc2)nc(-c2cc3c4c(c2)Oc2ccccc2B4c2ccccc2O3)n1 ; CC(C)(C)c1nc(-c2ccc(-c3cc4ccccc4cc3-c3ccc4c(c3)C(C)(C)CCC4(C)C)cc2)nc(-c2cc3c4c(c2)Oc2ccccc2B4c2ccccc2O3)n1]

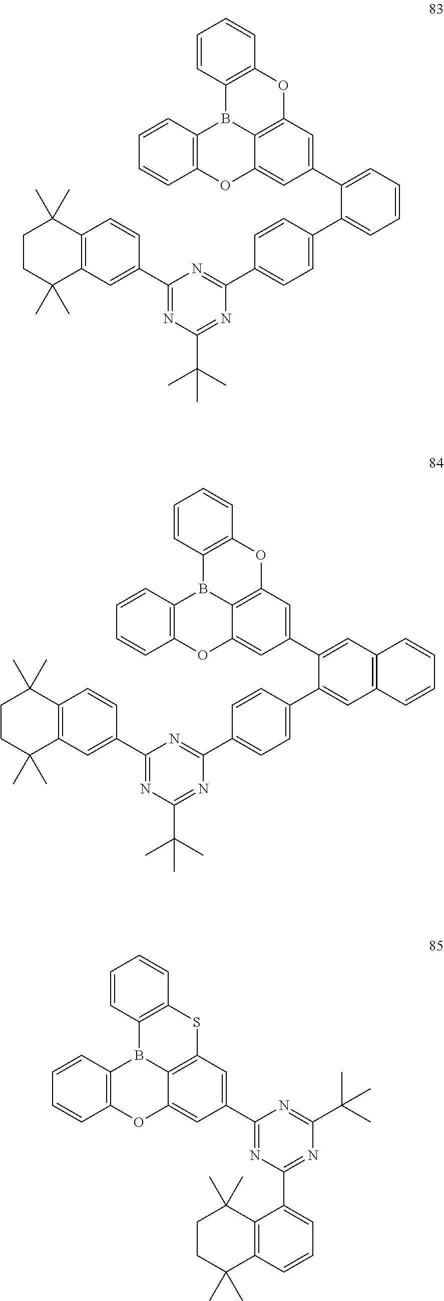 [SMILES: CC(C)(C)c1nc(-c2ccc(-c3ccccc3-c3cc4c5c(c3)Oc3ccccc3B5c3ccccc3O4)cc2)nc(-c2ccc3c(c2)C(C)(C)CCC3(C)C)n1 ; CC(C)(C)c1nc(-c2ccc(-c3cc4ccccc4cc3-c3cc4c5c(c3)Oc3ccccc3B5c3ccccc3O4)cc2)nc(-c2ccc3c(c2)C(C)(C)CCC3(C)C)n1 ; CC(C)(C)c1nc(-c2cc3c4c(c2)Sc2ccccc2B4c2ccccc2O3)nc(-c2cccc3c2C(C)(C)CCC3(C)C)n1]

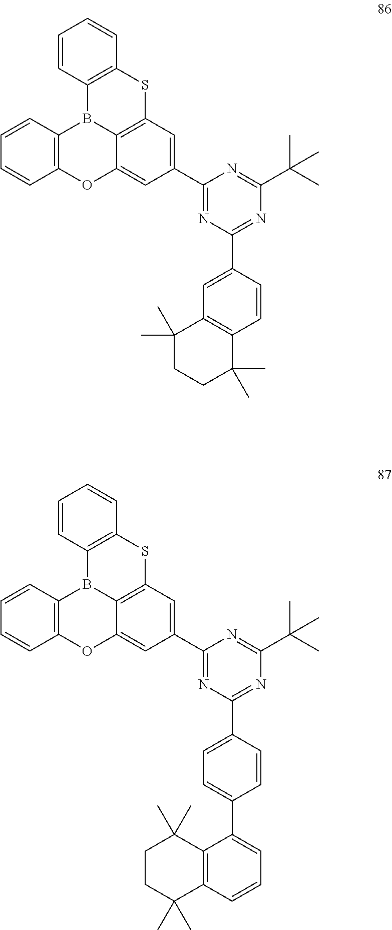 [SMILES: CC(C)(C)c1nc(-c2cc3c4c(c2)Sc2ccccc2B4c2ccccc2O3)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)Sc2ccccc2B4c2ccccc2O3)n1]

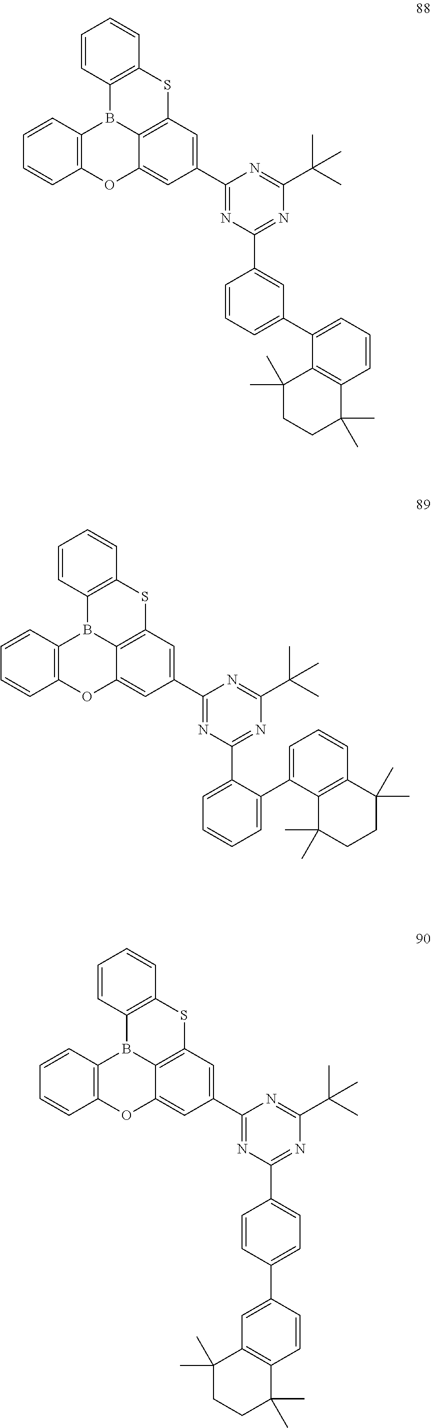 [SMILES: CC(C)(C)c1nc(-c2cccc(-c3cccc4c3C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2cccc3c2C(C)(C)CCC3(C)C)n1 ; CC(C)(C)c1nc(-c2ccc(-c3ccc4c(c3)C(C)(C)CCC4(C)C)cc2)nc(-c2cc3c4c(c2)Sc2ccccc2B4c2ccccc2O3)n1]

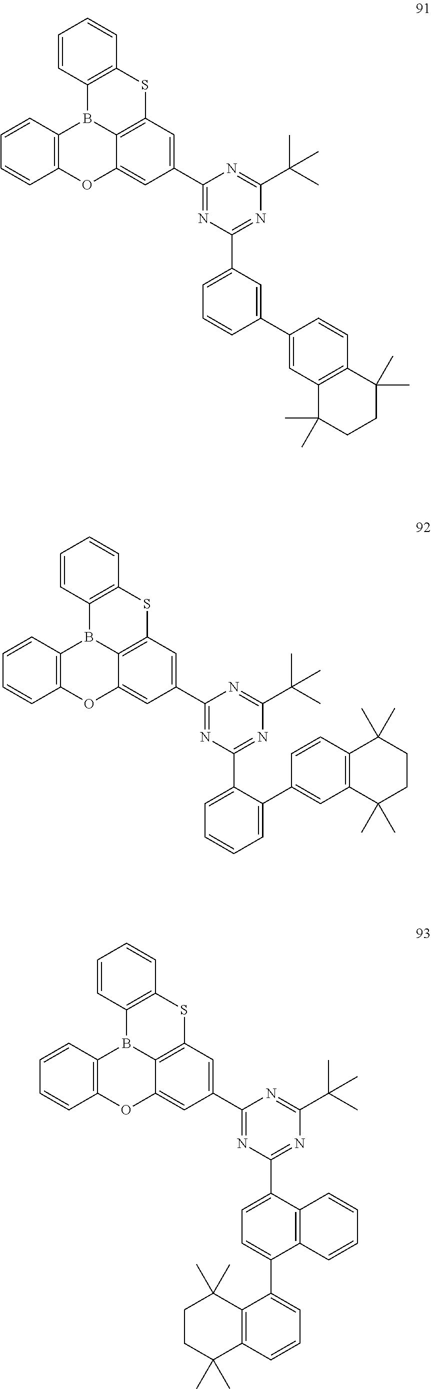 [SMILES: CC(C)(C)c1nc(-c2cccc(-c3ccc4c(c3)C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc3c(c2)C(C)(C)CCC3(C)C)n1 ; CC(C)(C)c1nc(-c2cc3c4c(c2)Sc2ccccc2B4c2ccccc2O3)nc(-c2ccc(-c3cccc4c3C(C)(C)CCC4(C)C)c3ccccc23)n1]

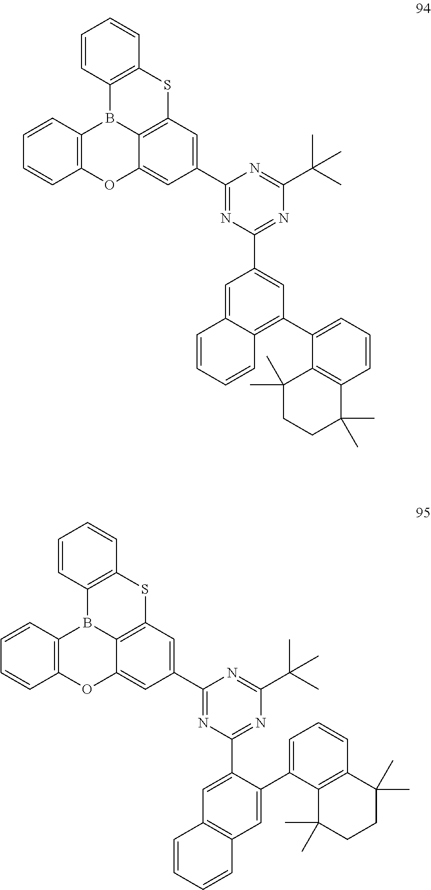 [SMILES: CC(C)(C)c1nc(-c2cc3c4c(c2)Sc2ccccc2B4c2ccccc2O3)nc(-c2cc(-c3cccc4c3C(C)(C)CCC4(C)C)c3ccccc3c2)n1 ; CC(C)(C)c1nc(-c2cc3c4c(c2)Sc2ccccc2B4c2ccccc2O3)nc(-c2cc3ccccc3cc2-c2cccc3c2C(C)(C)CCC3(C)C)n1]

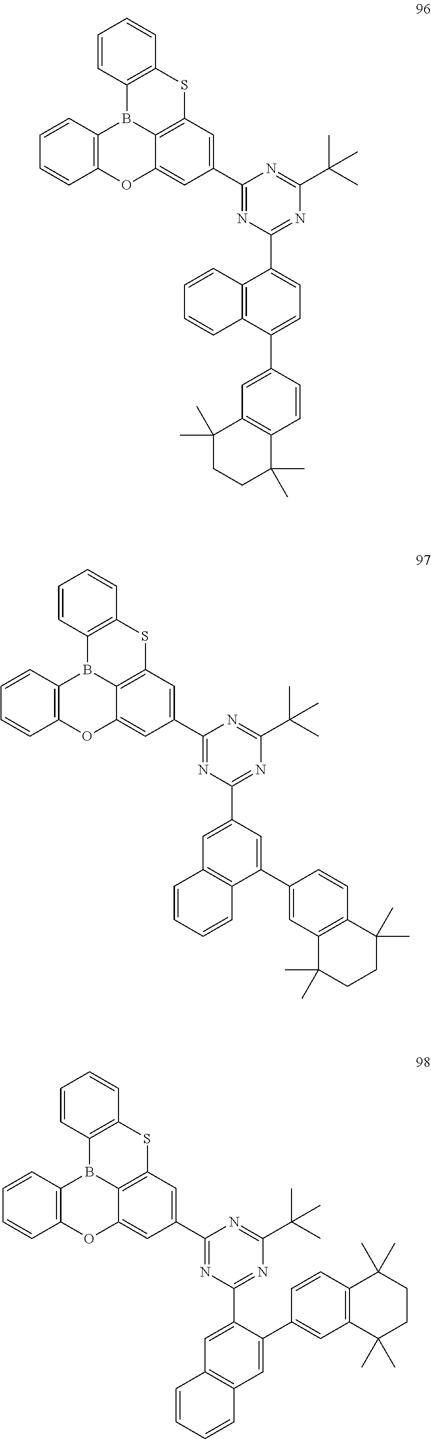 [SMILES: CC(C)(C)c1nc(-c2cc3c4c(c2)Sc2ccccc2B4c2ccccc2O3)nc(-c2ccc(-c3ccc4c(c3)C(C)(C)CCC4(C)C)c3ccccc23)n1 ; CC(C)(C)c1nc(-c2cc3c4c(c2)Sc2ccccc2B4c2ccccc2O3)nc(-c2cc(-c3ccc4c(c3)C(C)(C)CCC4(C)C)c3ccccc3c2)n1 ; CC(C)(C)c1nc(-c2cc3c4c(c2)Sc2ccccc2B4c2ccccc2O3)nc(-c2cc3ccccc3cc2-c2ccc3c(c2)C(C)(C)CCC3(C)C)n1]

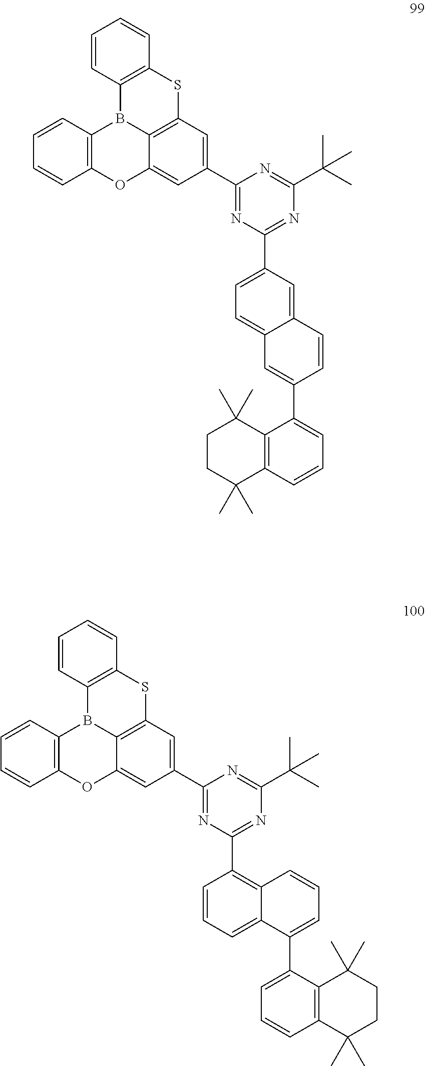 [SMILES: CC(C)(C)c1nc(-c2cc3c4c(c2)Sc2ccccc2B4c2ccccc2O3)nc(-c2ccc3cc(-c4cccc5c4C(C)(C)CCC5(C)C)ccc3c2)n1 ; CC(C)(C)c1nc(-c2cc3c4c(c2)Sc2ccccc2B4c2ccccc2O3)nc(-c2cccc3c(-c4cccc5c4C(C)(C)CCC5(C)C)cccc23)n1]

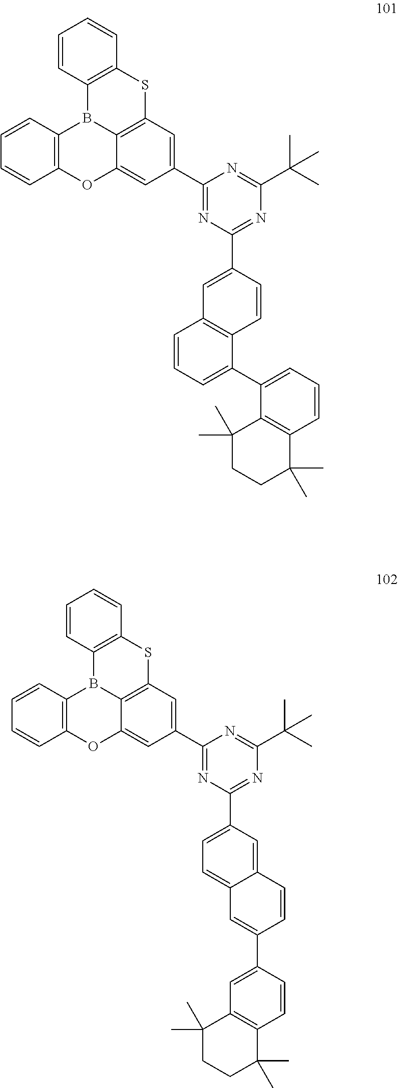 [SMILES: CC(C)(C)c1nc(-c2cc3c4c(c2)Sc2ccccc2B4c2ccccc2O3)nc(-c2ccc3c(-c4cccc5c4C(C)(C)CCC5(C)C)cccc3c2)n1 ; CC(C)(C)c1nc(-c2cc3c4c(c2)Sc2ccccc2B4c2ccccc2O3)nc(-c2ccc3cc(-c4ccc5c(c4)C(C)(C)CCC5(C)C)ccc3c2)n1]

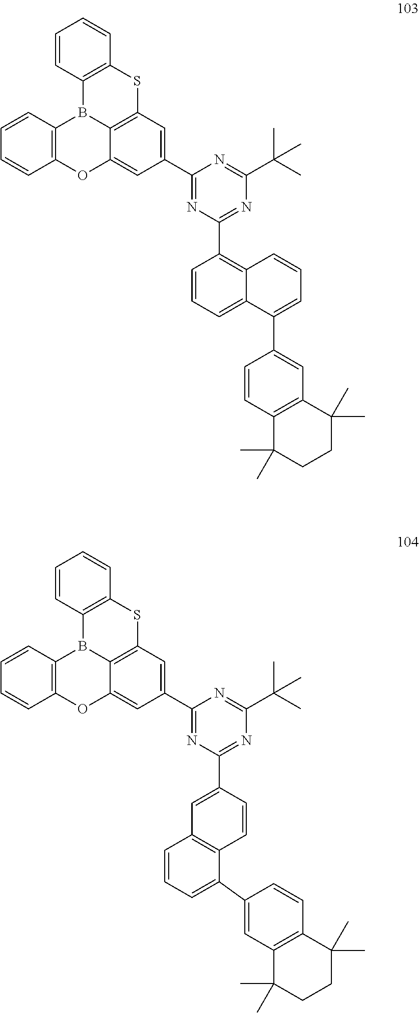 [SMILES: CC(C)(C)c1nc(-c2cc3c4c(c2)Sc2ccccc2B4c2ccccc2O3)nc(-c2cccc3c(-c4ccc5c(c4)C(C)(C)CCC5(C)C)cccc23)n1 ; CC(C)(C)c1nc(-c2cc3c4c(c2)Sc2ccccc2B4c2ccccc2O3)nc(-c2ccc3c(-c4ccc5c(c4)C(C)(C)CCC5(C)C)cccc3c2)n1]

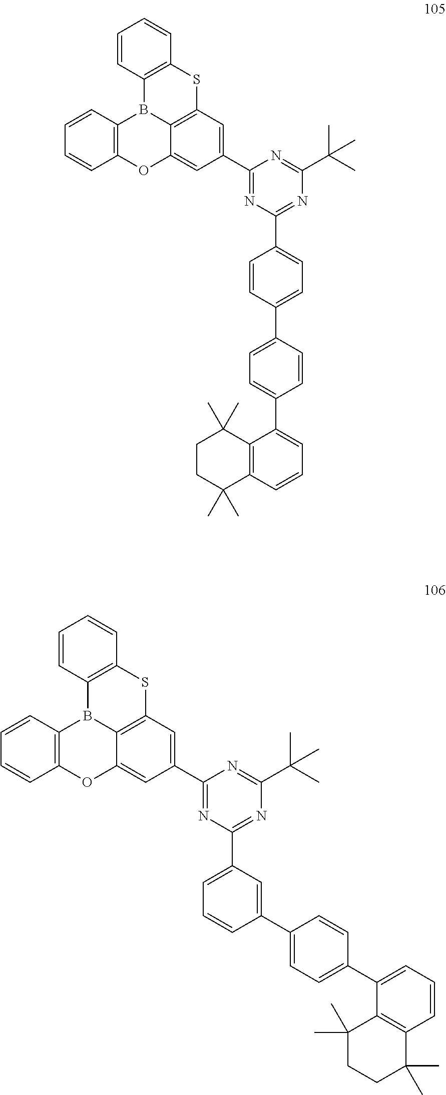 [SMILES: CC(C)(C)c1nc(-c2ccc(-c3ccc(-c4cccc5c4C(C)(C)CCC5(C)C)cc3)cc2)nc(-c2cc3c4c(c2)Sc2ccccc2B4c2ccccc2O3)n1 ; CC(C)(C)c1nc(-c2cccc(-c3ccc(-c4cccc5c4C(C)(C)CCC5(C)C)cc3)c2)nc(-c2cc3c4c(c2)Sc2ccccc2B4c2ccccc2O3)n1]

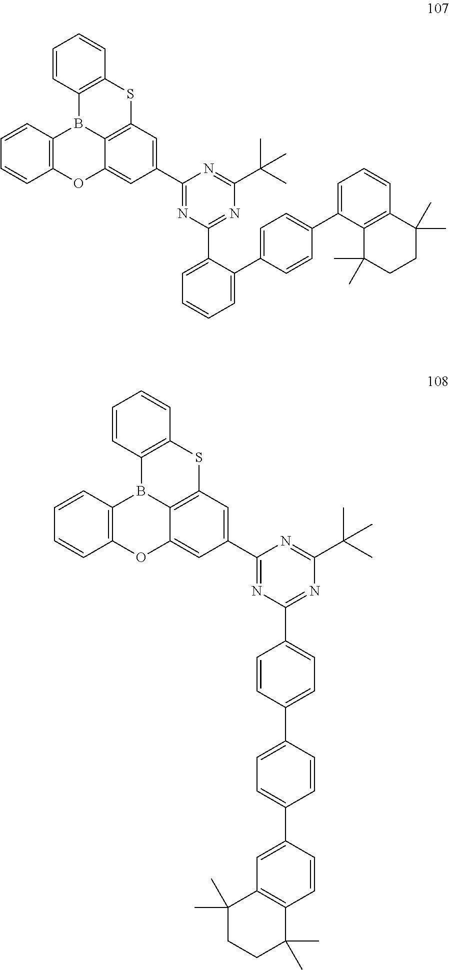 [SMILES: CC(C)(C)c1nc(-c2cc3c4c(c2)Sc2ccccc2B4c2ccccc2O3)nc(-c2ccccc2-c2ccc(-c3cccc4c3C(C)(C)CCC4(C)C)cc2)n1 ; CC(C)(C)c1nc(-c2ccc(-c3ccc(-c4ccc5c(c4)C(C)(C)CCC5(C)C)cc3)cc2)nc(-c2cc3c4c(c2)Sc2ccccc2B4c2ccccc2O3)n1]

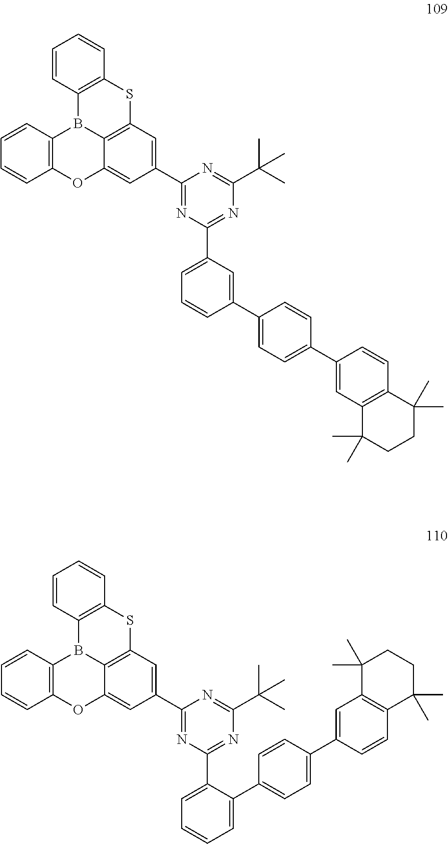 [SMILES: CC(C)(C)c1nc(-c2cccc(-c3ccc(-c4ccc5c(c4)C(C)(C)CCC5(C)C)cc3)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc(-c3ccc4c(c3)C(C)(C)CCC4(C)C)cc2)n1]

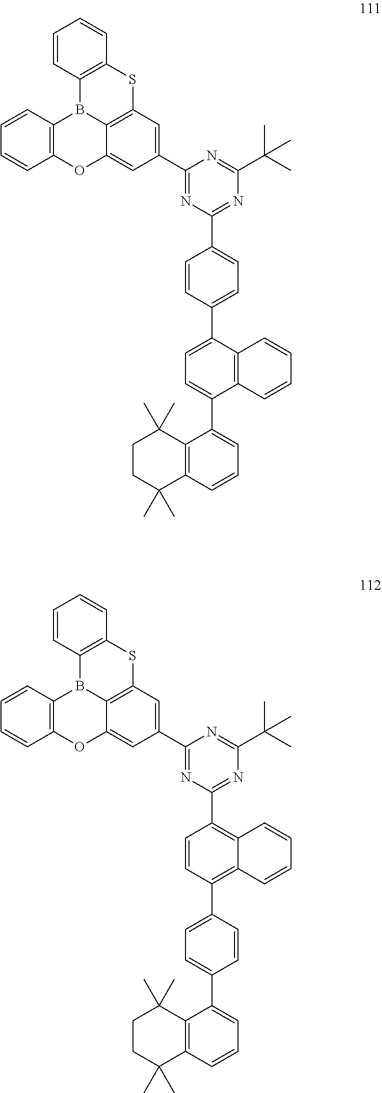 [SMILES: CC(C)(C)c1nc(-c2ccc(-c3ccc(-c4cccc5c4C(C)(C)CCC5(C)C)c4ccccc34)cc2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(-c3ccc(-c4cccc5c4C(C)(C)CCC5(C)C)cc3)c3ccccc23)n1]

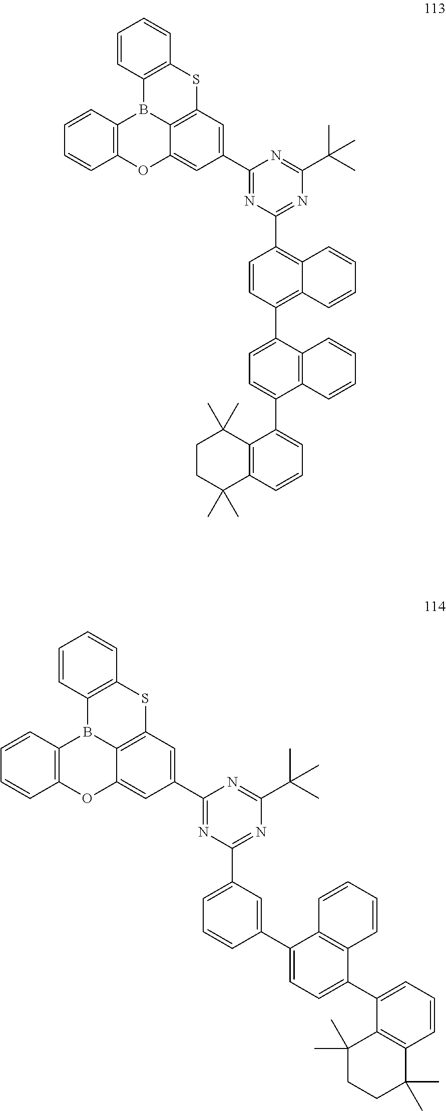 [SMILES: CC(C)(C)c1nc(-c2cc3c4c(c2)Sc2ccccc2B4c2ccccc2O3)nc(-c2ccc(-c3ccc(-c4cccc5c4C(C)(C)CCC5(C)C)c4ccccc34)c3ccccc23)n1 ; CC(C)(C)c1nc(-c2cccc(-c3ccc(-c4cccc5c4C(C)(C)CCC5(C)C)c4ccccc34)c2)nc(-c2cc3c4c(c2)Sc2ccccc2B4c2ccccc2O3)n1]

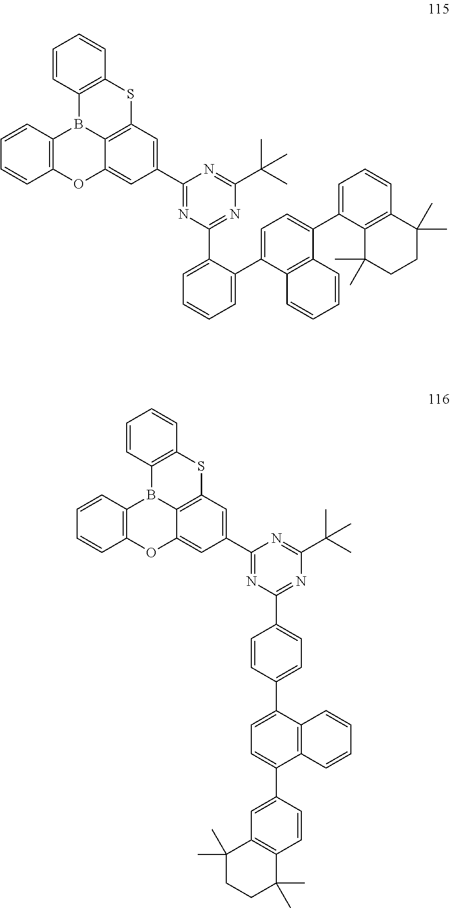 [SMILES: CC(C)(C)c1nc(-c2cc3c4c(c2)Sc2ccccc2B4c2ccccc2O3)nc(-c2ccccc2-c2ccc(-c3cccc4c3C(C)(C)CCC4(C)C)c3ccccc23)n1 ; CC(C)(C)c1nc(-c2ccc(-c3ccc(-c4ccc5c(c4)C(C)(C)CCC5(C)C)c4ccccc34)cc2)nc(-c2cc3c4c(c2)Sc2ccccc2B4c2ccccc2O3)n1]

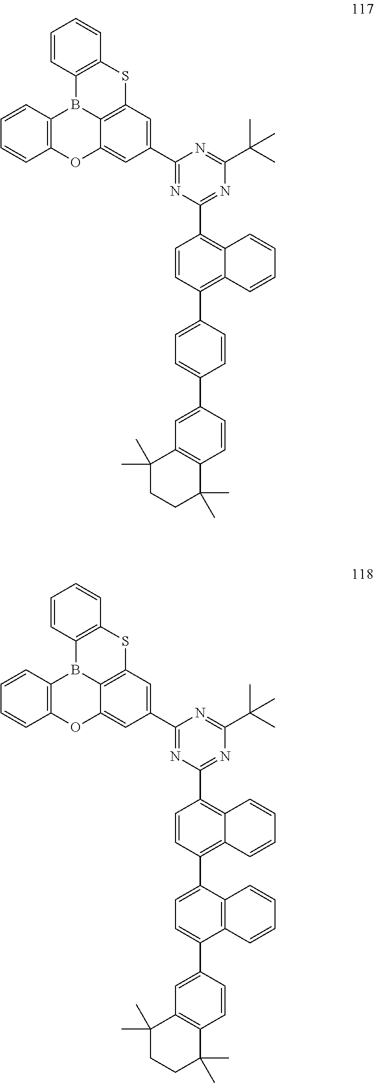 [SMILES: CC(C)(C)c1nc(-c2cc3c4c(c2)Sc2ccccc2B4c2ccccc2O3)nc(-c2ccc(-c3ccc(-c4ccc5c(c4)C(C)(C)CCC5(C)C)cc3)c3ccccc23)n1 ; CC(C)(C)c1nc(-c2cc3c4c(c2)Sc2ccccc2B4c2ccccc2O3)nc(-c2ccc(-c3ccc(-c4ccc5c(c4)C(C)(C)CCC5(C)C)c4ccccc34)c3ccccc23)n1]

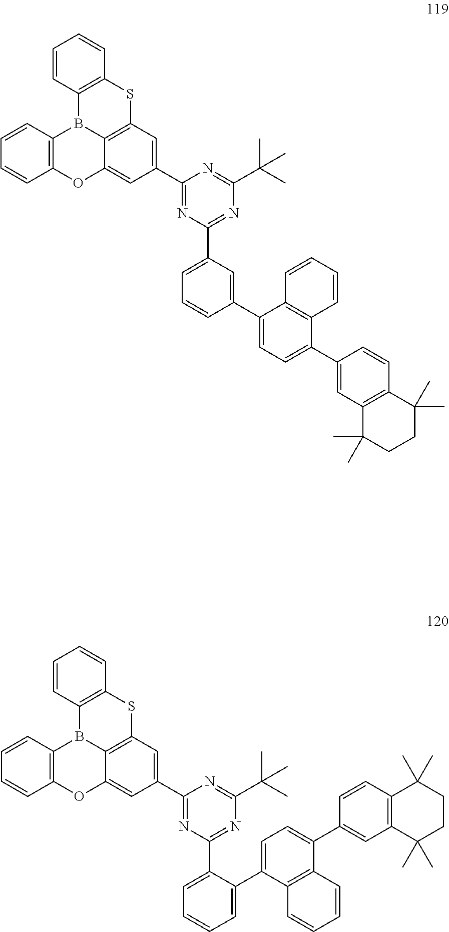 [SMILES: CC(C)(C)c1nc(-c2cccc(-c3ccc(-c4ccc5c(c4)C(C)(C)CCC5(C)C)c4ccccc34)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccccc2-c2ccc(-c3ccc4c(c3)C(C)(C)CCC4(C)C)c3ccccc23)n1]

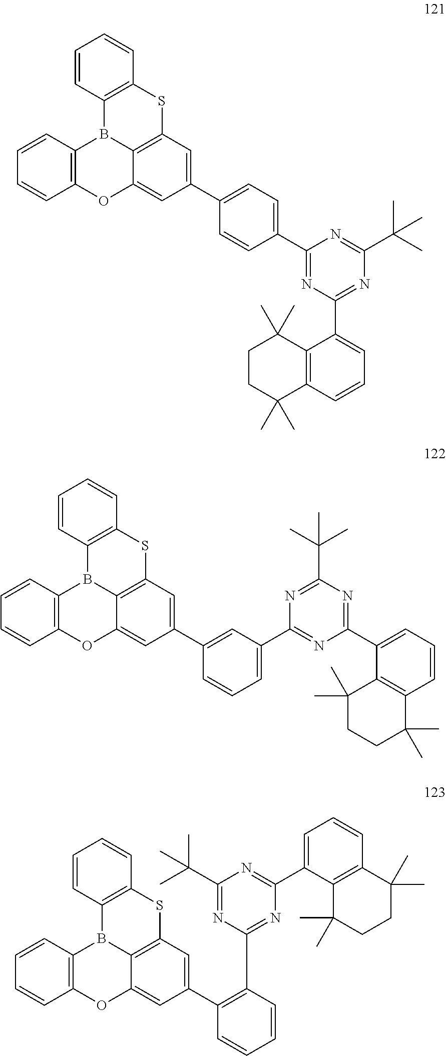 [SMILES: CC(C)(C)c1nc(-c2ccc(-c3cc4c5c(c3)Sc3ccccc3B5c3ccccc3O4)cc2)nc(-c2cccc3c2C(C)(C)CCC3(C)C)n1 ; CC(C)(C)c1nc(-c2cccc(-c3cc4c5c(c3)Sc3ccccc3B5c3ccccc3O4)c2)nc(-c2cccc3c2C(C)(C)CCC3(C)C)n1 ; CC(C)(C)c1nc(-c2ccccc2-c2cc3c4c(c2)Sc2ccccc2B4c2ccccc2O3)nc(-c2cccc3c2C(C)(C)CCC3(C)C)n1]

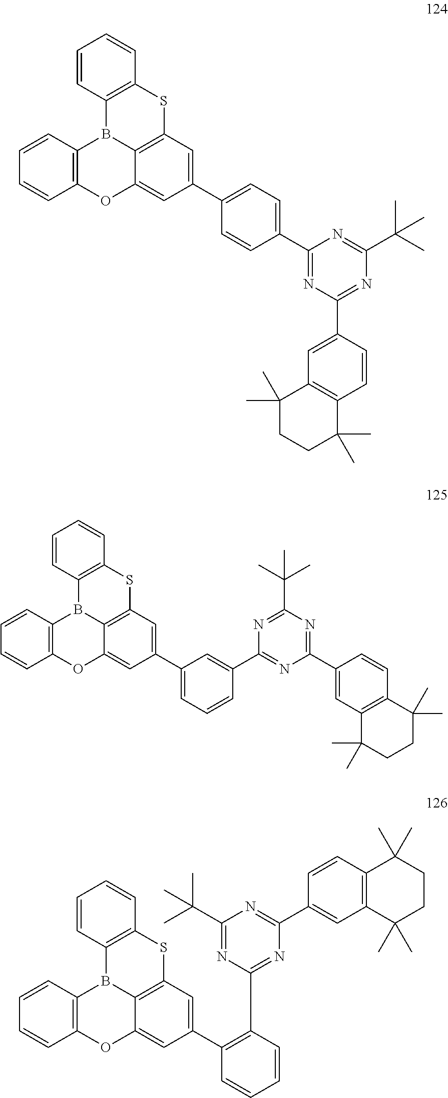 [SMILES: CC(C)(C)c1nc(-c2ccc(-c3cc4c5c(c3)Sc3ccccc3B5c3ccccc3O4)cc2)nc(-c2ccc3c(c2)C(C)(C)CCC3(C)C)n1 ; CC(C)(C)c1nc(-c2cccc(-c3cc4c5c(c3)Sc3ccccc3B5c3ccccc3O4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Sc2ccccc2B4c2ccccc2O3)n1]

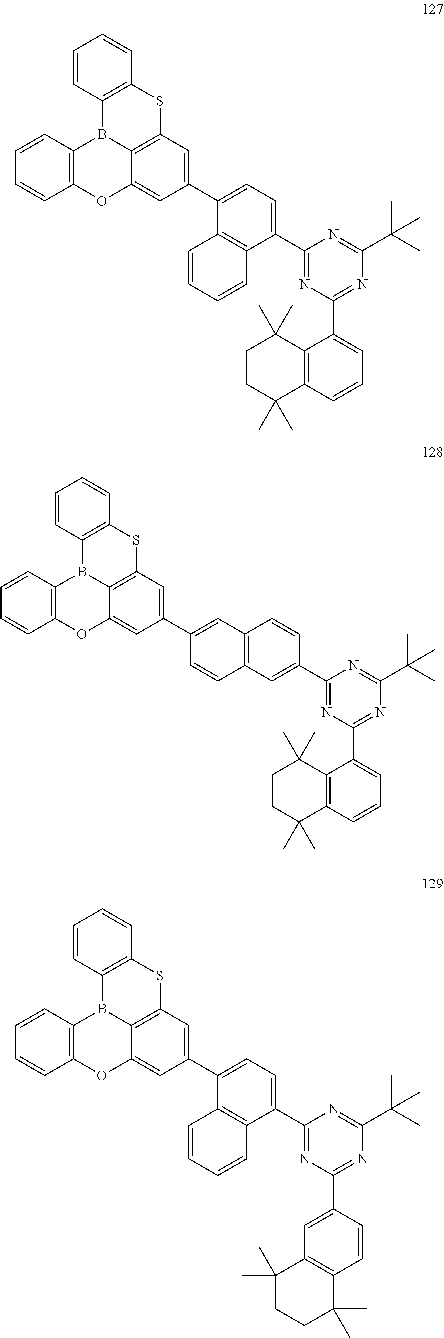 [SMILES: CC(C)(C)c1nc(-c2cccc3c2C(C)(C)CCC3(C)C)nc(-c2ccc(-c3cc4c5c(c3)Sc3ccccc3B5c3ccccc3O4)c3ccccc23)n1 ; CC(C)(C)c1nc(-c2ccc3cc(-c4cc5c6c(c4)Sc4ccccc4B6c4ccccc4O5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Sc3ccccc3B5c3ccccc3O4)c3ccccc23)n1]

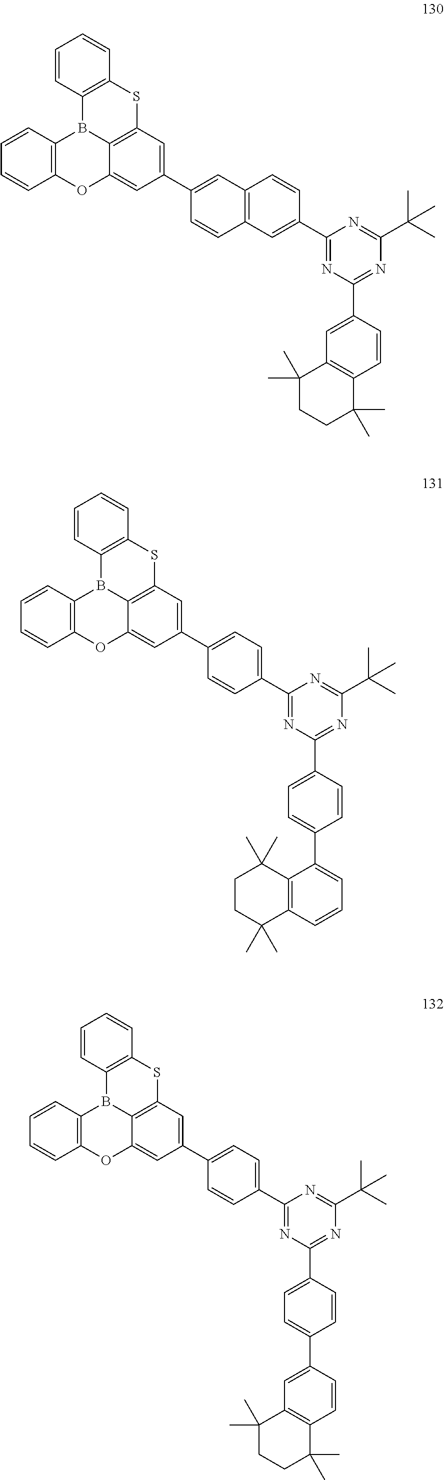 [SMILES: CC(C)(C)c1nc(-c2ccc3c(c2)C(C)(C)CCC3(C)C)nc(-c2ccc3cc(-c4cc5c6c(c4)Sc4ccccc4B6c4ccccc4O5)ccc3c2)n1 ; CC(C)(C)c1nc(-c2ccc(-c3cc4c5c(c3)Sc3ccccc3B5c3ccccc3O4)cc2)nc(-c2ccc(-c3cccc4c3C(C)(C)CCC4(C)C)cc2)n1 ; CC(C)(C)c1nc(-c2ccc(-c3cc4c5c(c3)Sc3ccccc3B5c3ccccc3O4)cc2)nc(-c2ccc(-c3ccc4c(c3)C(C)(C)CCC4(C)C)cc2)n1]

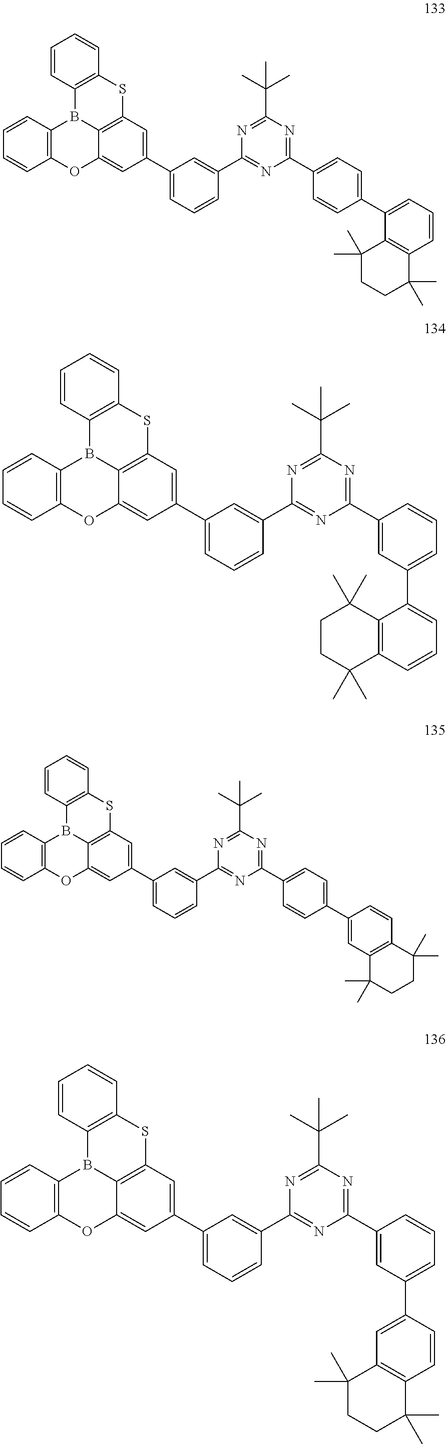 [SMILES: CC(C)(C)c1nc(-c2ccc(-c3cccc4c3C(C)(C)CCC4(C)C)cc2)nc(-c2cccc(-c3cc4c5c(c3)Sc3ccccc3B5c3ccccc3O4)c2)n1 ; CC(C)(C)c1nc(-c2cccc(-c3cc4c5c(c3)Sc3ccccc3B5c3ccccc3O4)c2)nc(-c2cccc(-c3cccc4c3C(C)(C)CCC4(C)C)c2)n1 ; CC(C)(C)c1nc(-c2ccc(-c3ccc4c(c3)C(C)(C)CCC4(C)C)cc2)nc(-c2cccc(-c3cc4c5c(c3)Sc3ccccc3B5c3ccccc3O4)c2)n1 ; CC(C)(C)c1nc(-c2cccc(-c3cc4c5c(c3)Sc3ccccc3B5c3ccccc3O4)c2)nc(-c2cccc(-c3ccc4c(c3)C(C)(C)CCC4(C)C)c2)n1]

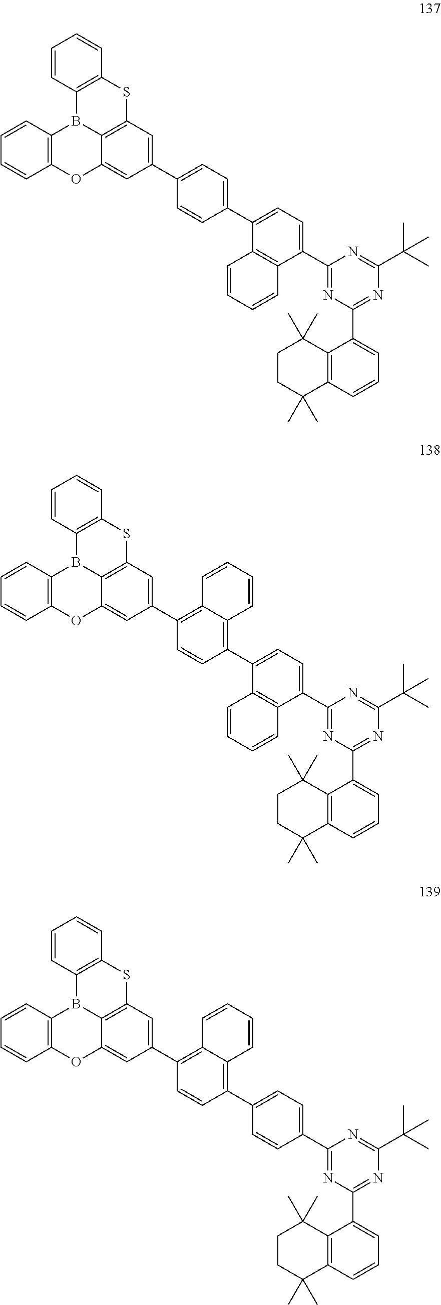 [SMILES: CC(C)(C)c1nc(-c2cccc3c2C(C)(C)CCC3(C)C)nc(-c2ccc(-c3ccc(-c4cc5c6c(c4)Sc4ccccc4B6c4ccccc4O5)cc3)c3ccccc23)n1 ; CC(C)(C)c1nc(-c2cccc3c2C(C)(C)CCC3(C)C)nc(-c2ccc(-c3ccc(-c4cc5c6c(c4)Sc4ccccc4B6c4ccccc4O5)c4ccccc34)c3ccccc23)n1 ; CC(C)(C)c1nc(-c2ccc(-c3ccc(-c4cc5c6c(c4)Sc4ccccc4B6c4ccccc4O5)c4ccccc34)cc2)nc(-c2cccc3c2C(C)(C)CCC3(C)C)n1]

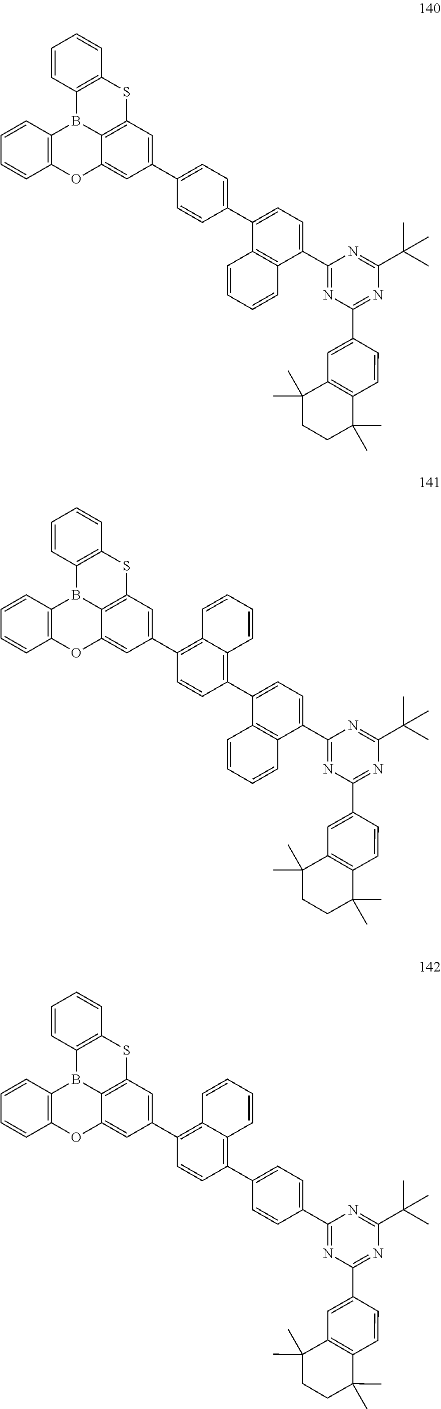 [SMILES: CC(C)(C)c1nc(-c2ccc3c(c2)C(C)(C)CCC3(C)C)nc(-c2ccc(-c3ccc(-c4cc5c6c(c4)Sc4ccccc4B6c4ccccc4O5)cc3)c3ccccc23)n1 ; CC(C)(C)c1nc(-c2ccc3c(c2)C(C)(C)CCC3(C)C)nc(-c2ccc(-c3ccc(-c4cc5c6c(c4)Sc4ccccc4B6c4ccccc4O5)c4ccccc34)c3ccccc23)n1 ; CC(C)(C)c1nc(-c2ccc(-c3ccc(-c4cc5c6c(c4)Sc4ccccc4B6c4ccccc4O5)c4ccccc34)cc2)nc(-c2ccc3c(c2)C(C)(C)CCC3(C)C)n1]

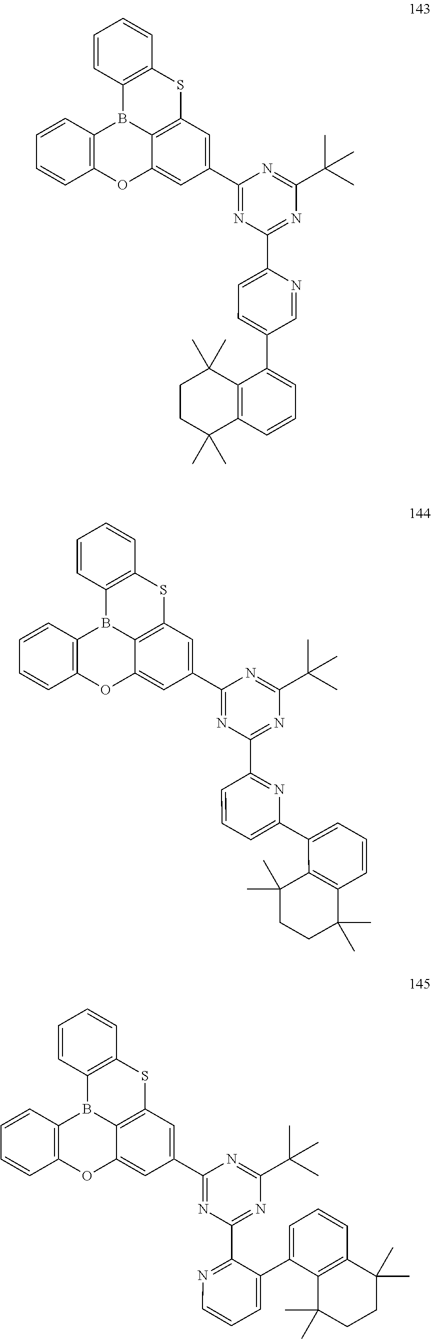 [SMILES: CC(C)(C)c1nc(-c2cc3c4c(c2)Sc2ccccc2B4c2ccccc2O3)nc(-c2ccc(-c3cccc4c3C(C)(C)CCC4(C)C)cn2)n1 ; CC(C)(C)c1nc(-c2cc3c4c(c2)Sc2ccccc2B4c2ccccc2O3)nc(-c2cccc(-c3cccc4c3C(C)(C)CCC4(C)C)n2)n1 ; CC(C)(C)c1nc(-c2cc3c4c(c2)Sc2ccccc2B4c2ccccc2O3)nc(-c2ncccc2-c2cccc3c2C(C)(C)CCC3(C)C)n1]

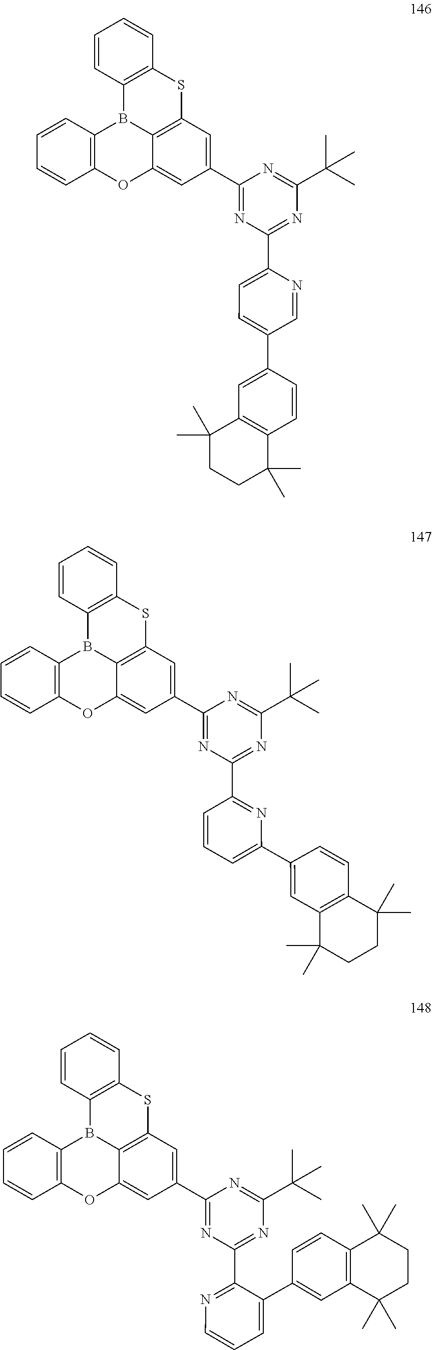 [SMILES: CC(C)(C)c1nc(-c2cc3c4c(c2)Sc2ccccc2B4c2ccccc2O3)nc(-c2ccc(-c3ccc4c(c3)C(C)(C)CCC4(C)C)cn2)n1 ; CC(C)(C)c1nc(-c2cc3c4c(c2)Sc2ccccc2B4c2ccccc2O3)nc(-c2cccc(-c3ccc4c(c3)C(C)(C)CCC4(C)C)n2)n1 ; CC(C)(C)c1nc(-c2cc3c4c(c2)Sc2ccccc2B4c2ccccc2O3)nc(-c2ncccc2-c2ccc3c(c2)C(C)(C)CCC3(C)C)n1]

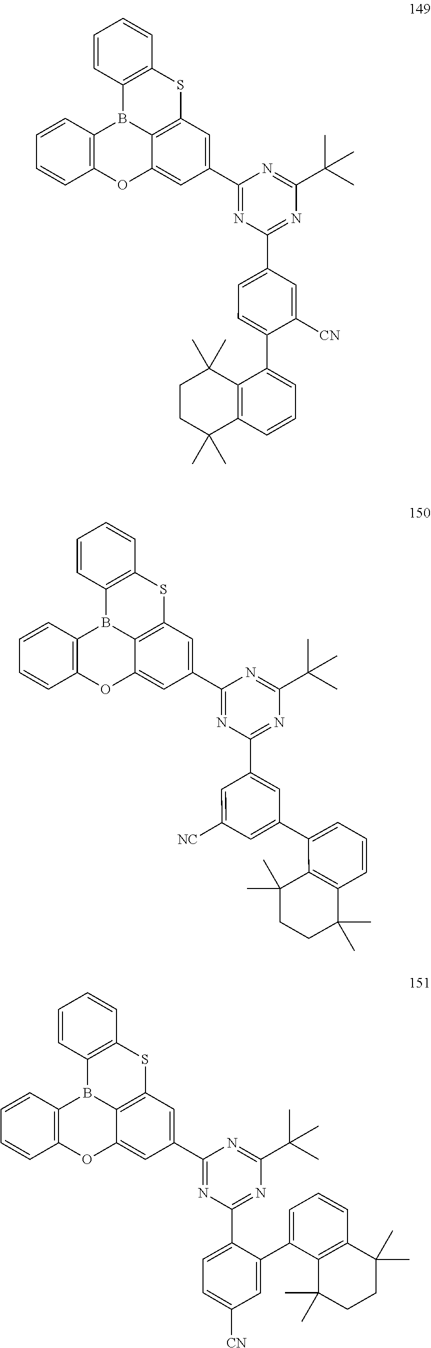 [SMILES: CC(C)(C)c1nc(-c2ccc(-c3cccc4c3C(C)(C)CCC4(C)C)c(C#N)c2)nc(-c2cc3c4c(c2)Sc2ccccc2B4c2ccccc2O3)n1 ; CC(C)(C)c1nc(-c2cc(C#N)cc(-c3cccc4c3C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(C#N)cc2-c2cccc3c2C(C)(C)CCC3(C)C)n1]

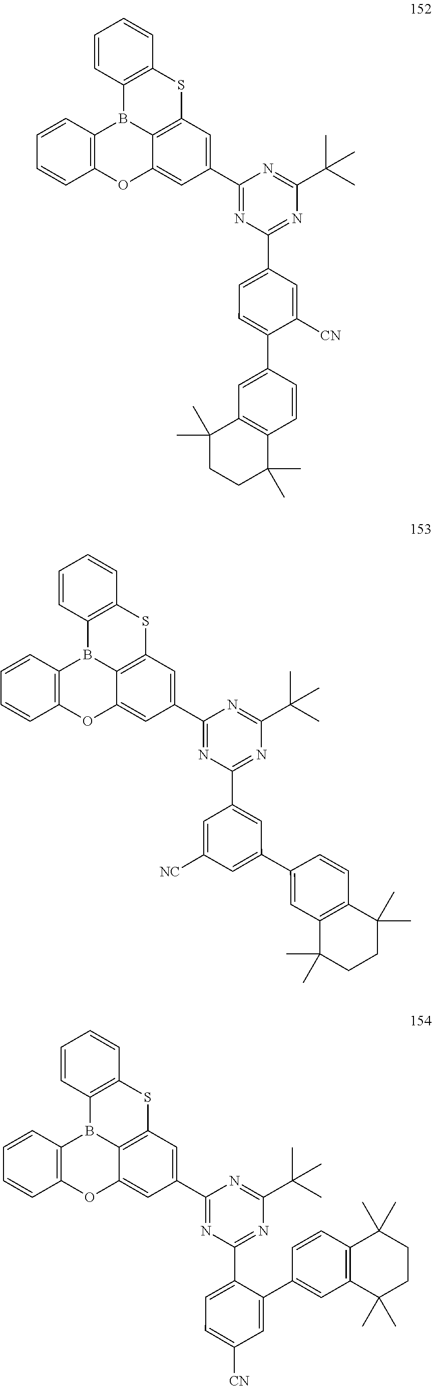 [SMILES: CC(C)(C)c1nc(-c2ccc(-c3ccc4c(c3)C(C)(C)CCC4(C)C)c(C#N)c2)nc(-c2cc3c4c(c2)Sc2ccccc2B4c2ccccc2O3)n1 ; CC(C)(C)c1nc(-c2cc(C#N)cc(-c3ccc4c(c3)C(C)(C)CCC4(C)C)c2)nc(-c2cc3c4c(c2)Sc2ccccc2B4c2ccccc2O3)n1 ; CC(C)(C)c1nc(-c2cc3c4c(c2)Sc2ccccc2B4c2ccccc2O3)nc(-c2ccc(C#N)cc2-c2ccc3c(c2)C(C)(C)CCC3(C)C)n1]

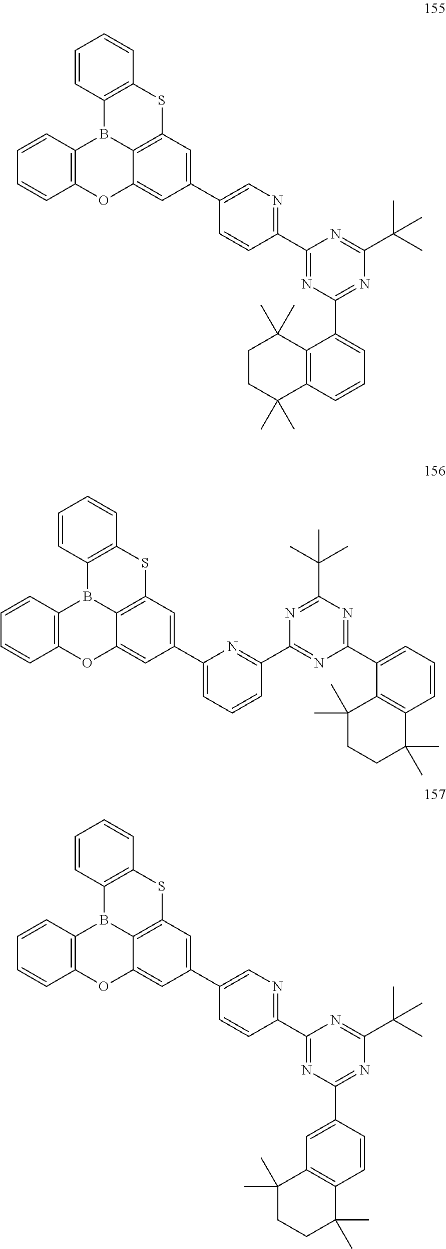 [SMILES: CC(C)(C)c1nc(-c2ccc(-c3cc4c5c(c3)Sc3ccccc3B5c3ccccc3O4)cn2)nc(-c2cccc3c2C(C)(C)CCC3(C)C)n1 ; CC(C)(C)c1nc(-c2cccc(-c3cc4c5c(c3)Sc3ccccc3B5c3ccccc3O4)n2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Sc3ccccc3B5c3ccccc3O4)cn2)n1]

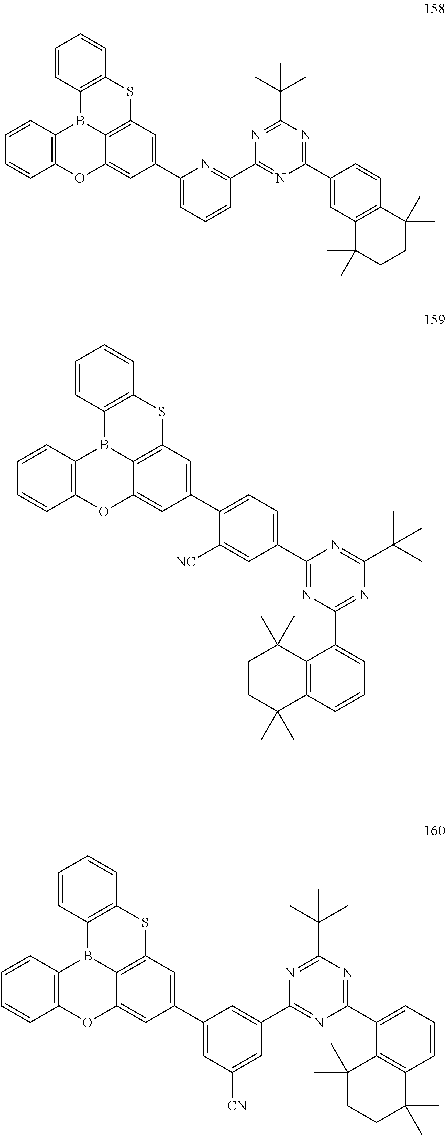 [SMILES: CC(C)(C)c1nc(-c2ccc3c(c2)C(C)(C)CCC3(C)C)nc(-c2cccc(-c3cc4c5c(c3)Sc3ccccc3B5c3ccccc3O4)n2)n1 ; CC(C)(C)c1nc(-c2ccc(-c3cc4c5c(c3)Sc3ccccc3B5c3ccccc3O4)c(C#N)c2)nc(-c2cccc3c2C(C)(C)CCC3(C)C)n1 ; CC(C)(C)c1nc(-c2cc(C#N)cc(-c3cc4c5c(c3)Sc3ccccc3B5c3ccccc3O4)c2)nc(-c2cccc3c2C(C)(C)CCC3(C)C)n1]

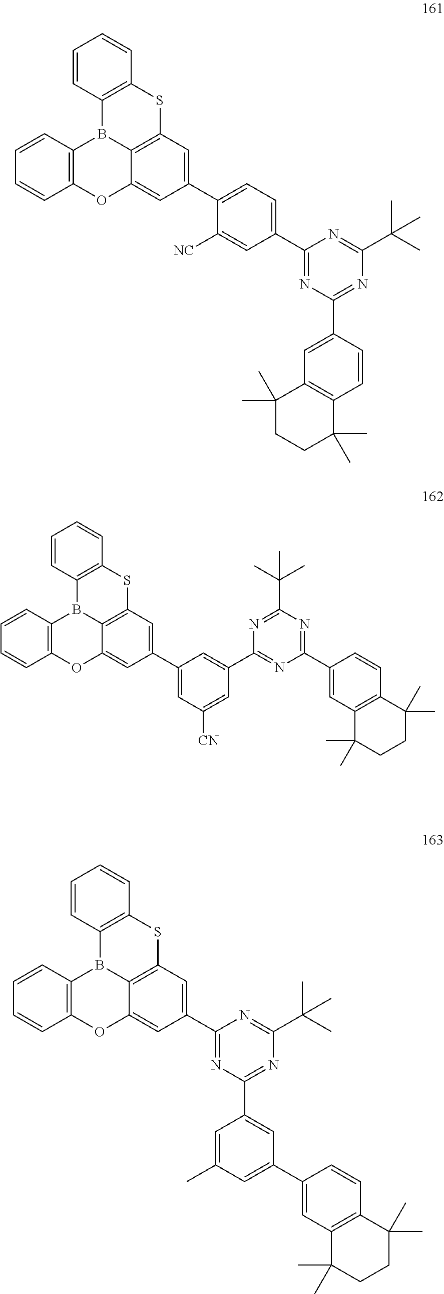 [SMILES: CC(C)(C)c1nc(-c2ccc(-c3cc4c5c(c3)Sc3ccccc3B5c3ccccc3O4)c(C#N)c2)nc(-c2ccc3c(c2)C(C)(C)CCC3(C)C)n1 ; CC(C)(C)c1nc(-c2cc(C#N)cc(-c3cc4c5c(c3)Sc3ccccc3B5c3ccccc3O4)c2)nc(-c2ccc3c(c2)C(C)(C)CCC3(C)C)n1 ; Cc1cc(-c2ccc3c(c2)C(C)(C)CCC3(C)C)cc(-c2nc(-c3cc4c5c(c3)Sc3ccccc3B5c3ccccc3O4)nc(C(C)(C)C)n2)c1]

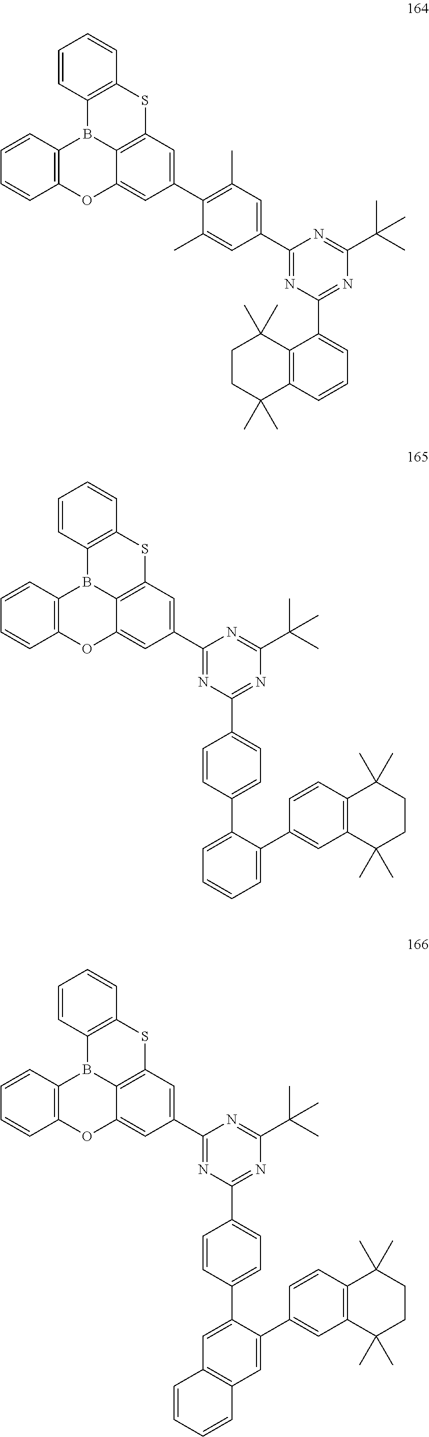 [SMILES: Cc1cc(-c2nc(-c3cccc4c3C(C)(C)CCC4(C)C)nc(C(C)(C)C)n2)cc(C)c1-c1cc2c3c(c1)Sc1ccccc1B3c1ccccc1O2 ; CC(C)(C)c1nc(-c2ccc(-c3ccccc3-c3ccc4c(c3)C(C)(C)CCC4(C)C)cc2)nc(-c2cc3c4c(c2)Sc2ccccc2B4c2ccccc2O3)n1 ; CC(C)(C)c1nc(-c2ccc(-c3cc4ccccc4cc3-c3ccc4c(c3)C(C)(C)CCC4(C)C)cc2)nc(-c2cc3c4c(c2)Sc2ccccc2B4c2ccccc2O3)n1]

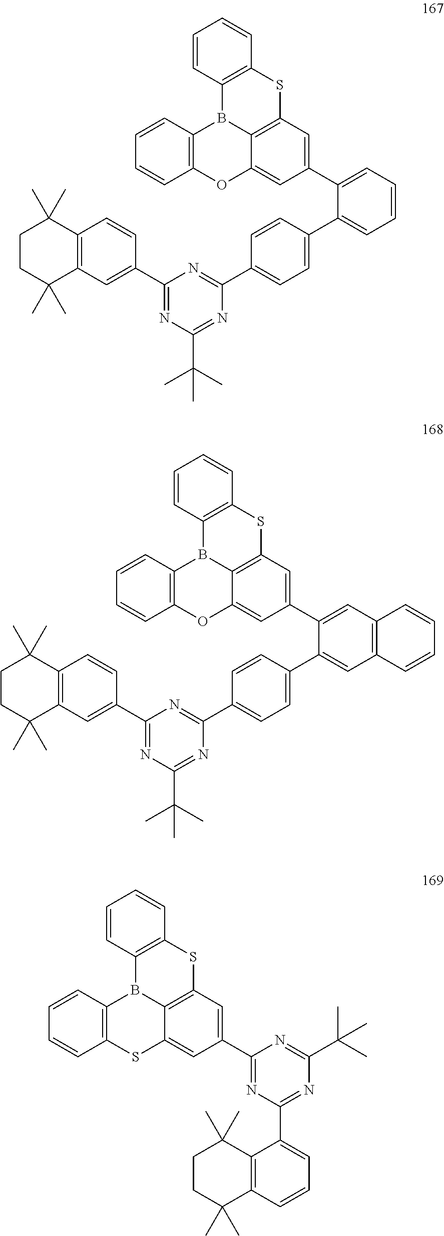 [SMILES: CC(C)(C)c1nc(-c2ccc(-c3ccccc3-c3cc4c5c(c3)Sc3ccccc3B5c3ccccc3O4)cc2)nc(-c2ccc3c(c2)C(C)(C)CCC3(C)C)n1 ; CC(C)(C)c1nc(-c2ccc(-c3cc4ccccc4cc3-c3cc4c5c(c3)Sc3ccccc3B5c3ccccc3O4)cc2)nc(-c2ccc3c(c2)C(C)(C)CCC3(C)C)n1 ; CC(C)(C)c1nc(-c2cc3c4c(c2)Sc2ccccc2B4c2ccccc2S3)nc(-c2cccc3c2C(C)(C)CCC3(C)C)n1]

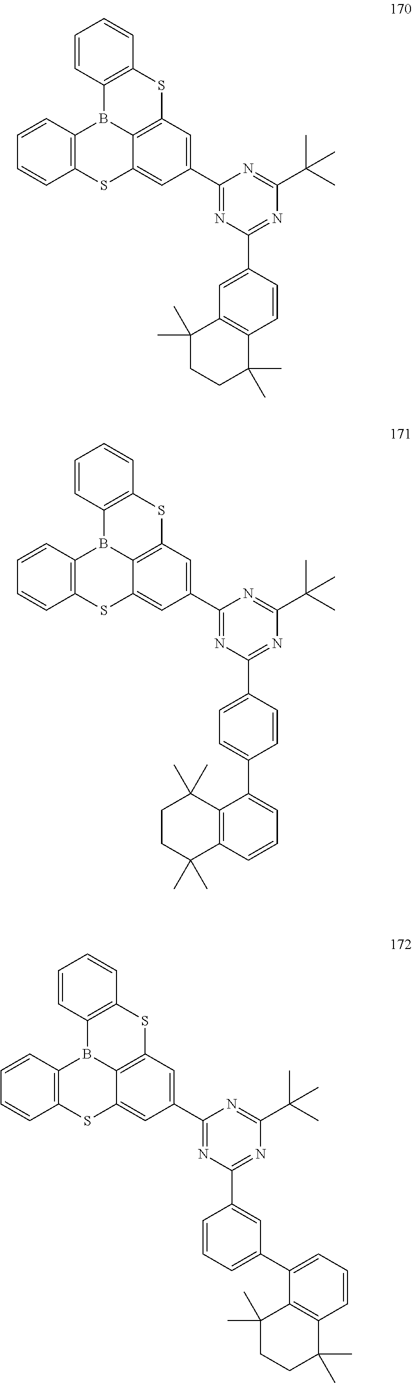 [SMILES: CC(C)(C)c1nc(-c2cc3c4c(c2)Sc2ccccc2B4c2ccccc2S3)nc(-c2ccc3c(c2)C(C)(C)CCC3(C)C)n1 ; CC(C)(C)c1nc(-c2ccc(-c3cccc4c3C(C)(C)CCC4(C)C)cc2)nc(-c2cc3c4c(c2)Sc2ccccc2B4c2ccccc2S3)n1 ; CC(C)(C)c1nc(-c2cccc(-c3cccc4c3C(C)(C)CCC4(C)C)c2)nc(-c2cc3c4c(c2)Sc2ccccc2B4c2ccccc2S3)n1]

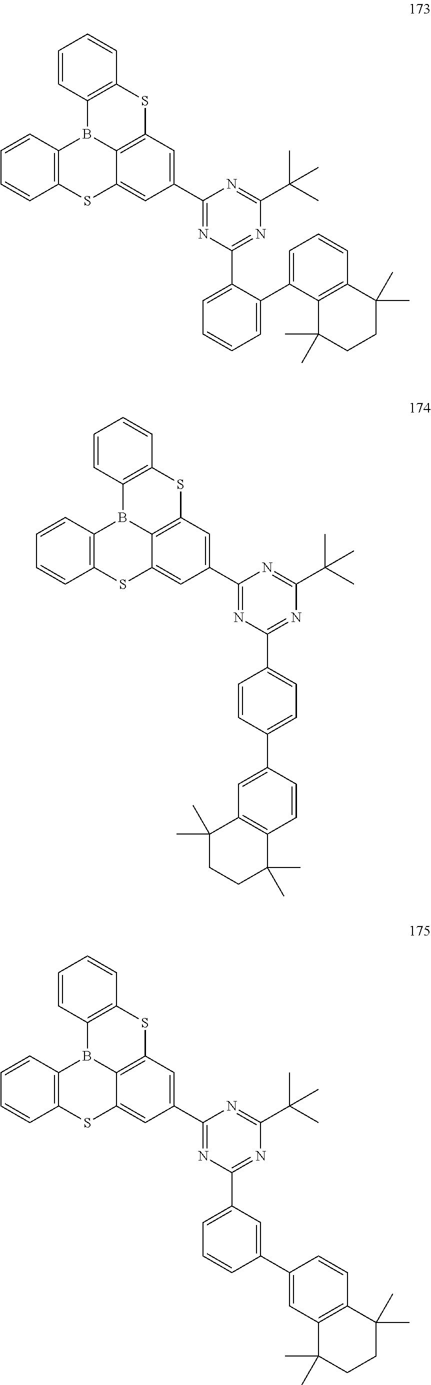 [SMILES: CC(C)(C)c1nc(-c2cc3c4c(c2)Sc2ccccc2B4c2ccccc2S3)nc(-c2ccccc2-c2cccc3c2C(C)(C)CCC3(C)C)n1 ; CC(C)(C)c1nc(-c2ccc(-c3ccc4c(c3)C(C)(C)CCC4(C)C)cc2)nc(-c2cc3c4c(c2)Sc2ccccc2B4c2ccccc2S3)n1 ; CC(C)(C)c1nc(-c2cccc(-c3ccc4c(c3)C(C)(C)CCC4(C)C)c2)nc(-c2cc3c4c(c2)Sc2ccccc2B4c2ccccc2S3)n1]

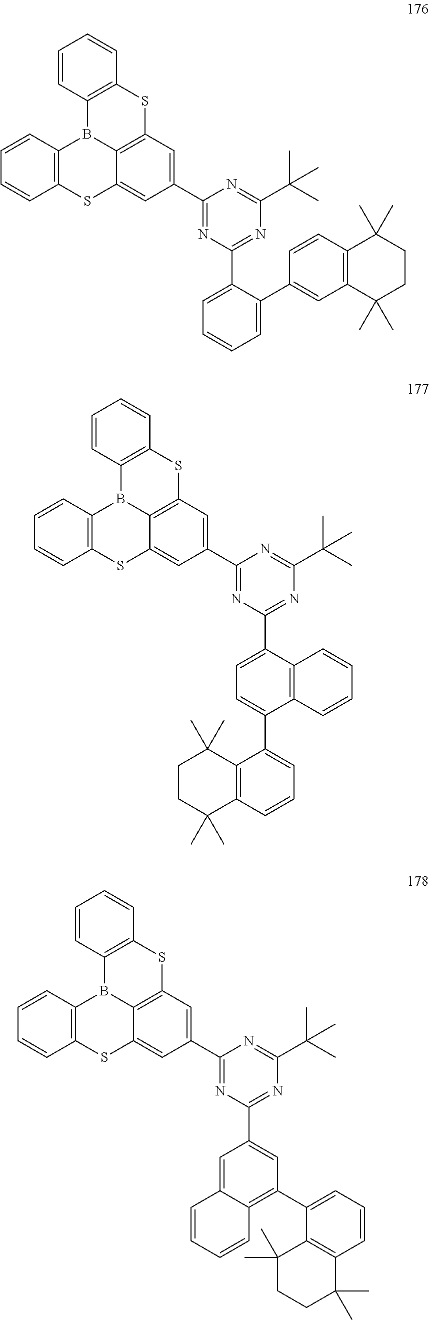 [SMILES: CC(C)(C)c1nc(-c2cc3c4c(c2)Sc2ccccc2B4c2ccccc2S3)nc(-c2ccccc2-c2ccc3c(c2)C(C)(C)CCC3(C)C)n1 ; CC(C)(C)c1nc(-c2cc3c4c(c2)Sc2ccccc2B4c2ccccc2S3)nc(-c2ccc(-c3cccc4c3C(C)(C)CCC4(C)C)c3ccccc23)n1 ; CC(C)(C)c1nc(-c2cc3c4c(c2)Sc2ccccc2B4c2ccccc2S3)nc(-c2cc(-c3cccc4c3C(C)(C)CCC4(C)C)c3ccccc3c2)n1]

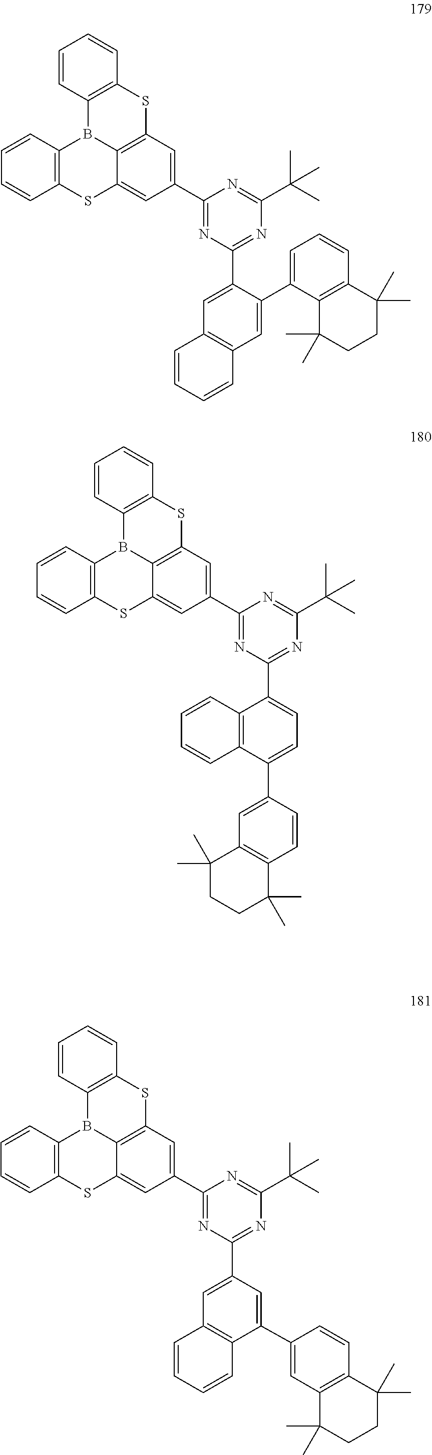 [SMILES: CC(C)(C)c1nc(-c2cc3c4c(c2)Sc2ccccc2B4c2ccccc2S3)nc(-c2cc3ccccc3cc2-c2cccc3c2C(C)(C)CCC3(C)C)n1 ; CC(C)(C)c1nc(-c2cc3c4c(c2)Sc2ccccc2B4c2ccccc2S3)nc(-c2ccc(-c3ccc4c(c3)C(C)(C)CCC4(C)C)c3ccccc23)n1 ; CC(C)(C)c1nc(-c2cc3c4c(c2)Sc2ccccc2B4c2ccccc2S3)nc(-c2cc(-c3ccc4c(c3)C(C)(C)CCC4(C)C)c3ccccc3c2)n1]

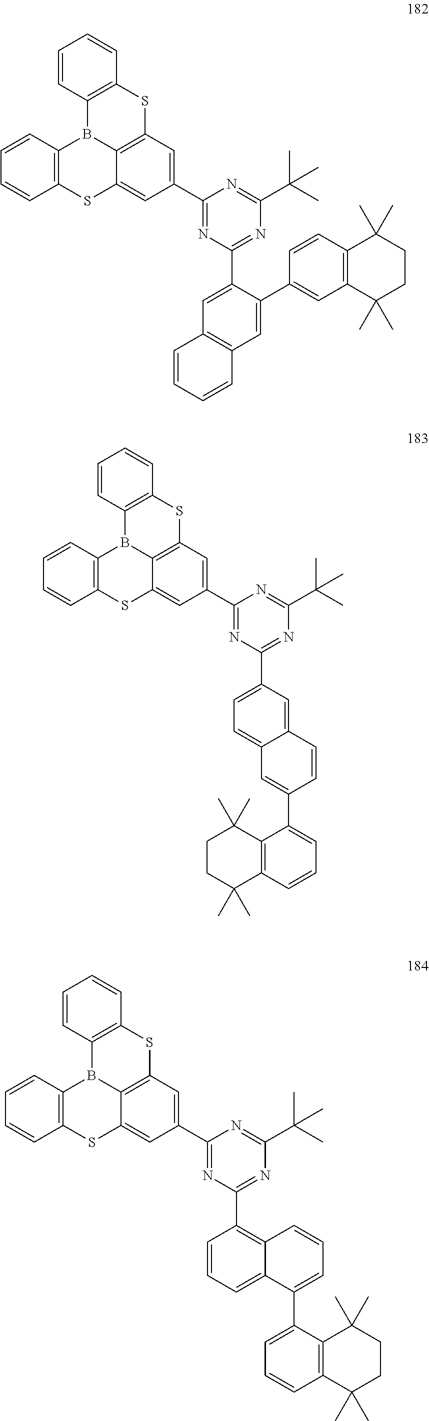 [SMILES: CC(C)(C)c1nc(-c2cc3c4c(c2)Sc2ccccc2B4c2ccccc2S3)nc(-c2cc3ccccc3cc2-c2ccc3c(c2)C(C)(C)CCC3(C)C)n1 ; CC(C)(C)c1nc(-c2cc3c4c(c2)Sc2ccccc2B4c2ccccc2S3)nc(-c2ccc3cc(-c4cccc5c4C(C)(C)CCC5(C)C)ccc3c2)n1 ; CC(C)(C)c1nc(-c2cc3c4c(c2)Sc2ccccc2B4c2ccccc2S3)nc(-c2cccc3c(-c4cccc5c4C(C)(C)CCC5(C)C)cccc23)n1]

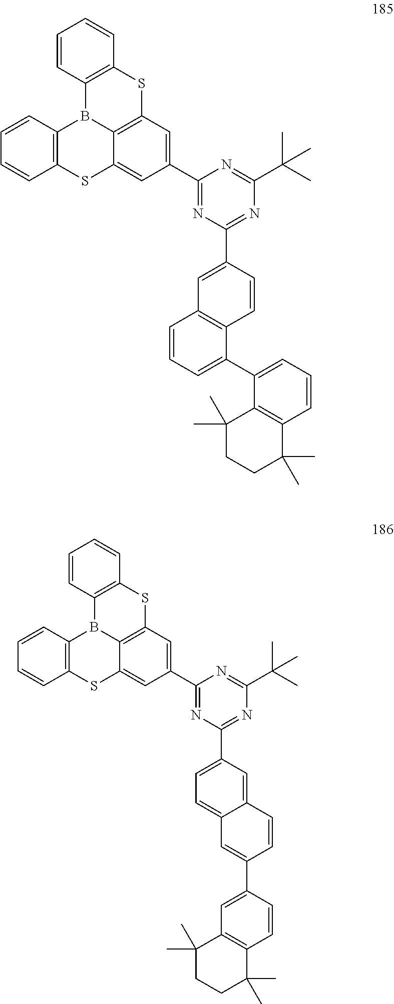 [SMILES: CC(C)(C)c1nc(-c2cc3c4c(c2)Sc2ccccc2B4c2ccccc2S3)nc(-c2ccc3c(-c4cccc5c4C(C)(C)CCC5(C)C)cccc3c2)n1 ; CC(C)(C)c1nc(-c2cc3c4c(c2)Sc2ccccc2B4c2ccccc2S3)nc(-c2ccc3cc(-c4ccc5c(c4)C(C)(C)CCC5(C)C)ccc3c2)n1]

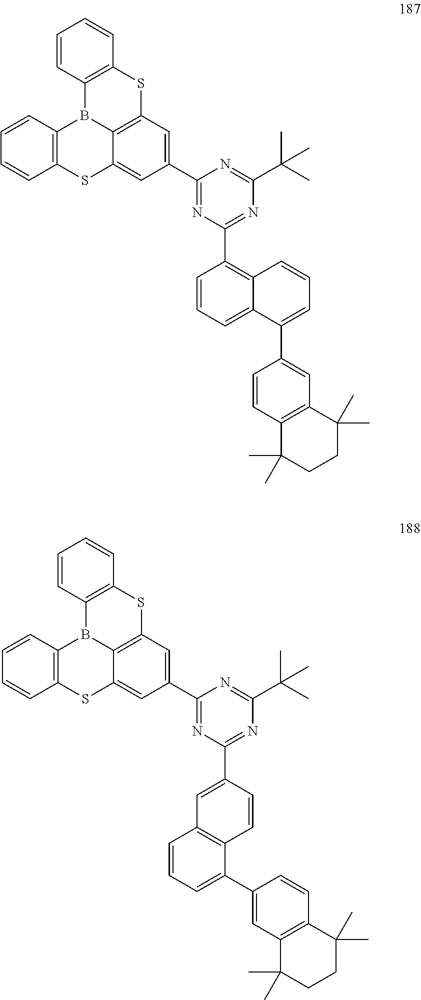 [SMILES: CC(C)(C)c1nc(-c2cc3c4c(c2)Sc2ccccc2B4c2ccccc2S3)nc(-c2cccc3c(-c4ccc5c(c4)C(C)(C)CCC5(C)C)cccc23)n1 ; CC(C)(C)c1nc(-c2cc3c4c(c2)Sc2ccccc2B4c2ccccc2S3)nc(-c2ccc3c(-c4ccc5c(c4)C(C)(C)CCC5(C)C)cccc3c2)n1]

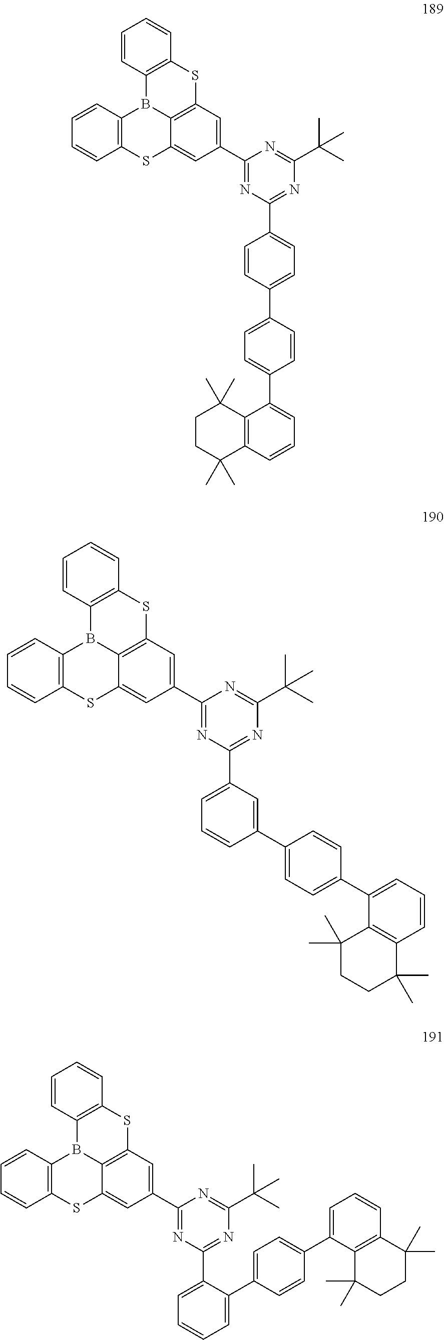 [SMILES: CC(C)(C)c1nc(-c2ccc(-c3ccc(-c4cccc5c4C(C)(C)CCC5(C)C)cc3)cc2)nc(-c2cc3c4c(c2)Sc2ccccc2B4c2ccccc2S3)n1 ; CC(C)(C)c1nc(-c2cccc(-c3ccc(-c4cccc5c4C(C)(C)CCC5(C)C)cc3)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3cccc4c3C(C)(C)CCC4(C)C)cc2)n1]

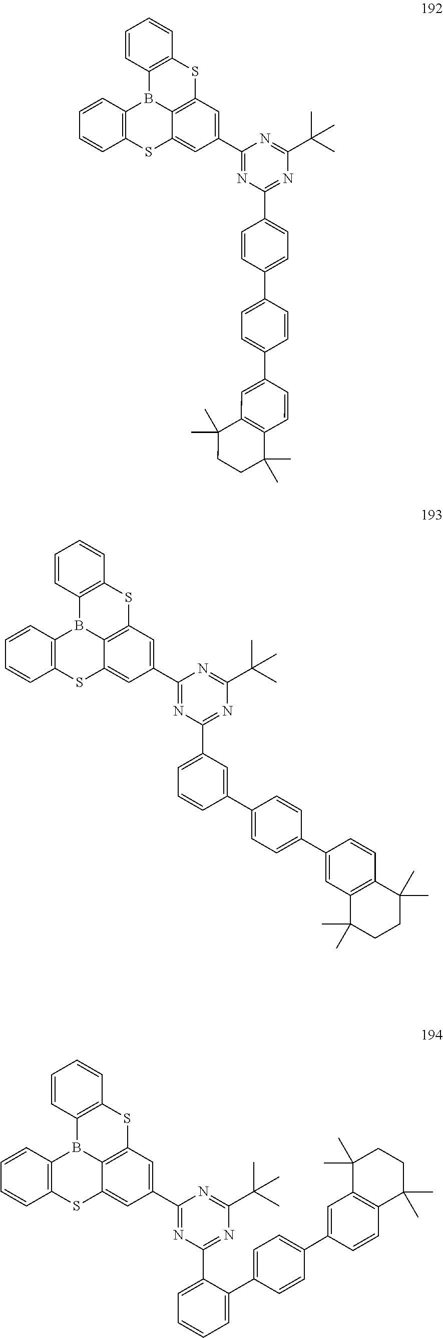 [SMILES: CC(C)(C)c1nc(-c2ccc(-c3ccc(-c4ccc5c(c4)C(C)(C)CCC5(C)C)cc3)cc2)nc(-c2cc3c4c(c2)Sc2ccccc2B4c2ccccc2S3)n1 ; CC(C)(C)c1nc(-c2cccc(-c3ccc(-c4ccc5c(c4)C(C)(C)CCC5(C)C)cc3)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3ccc4c(c3)C(C)(C)CCC4(C)C)cc2)n1]

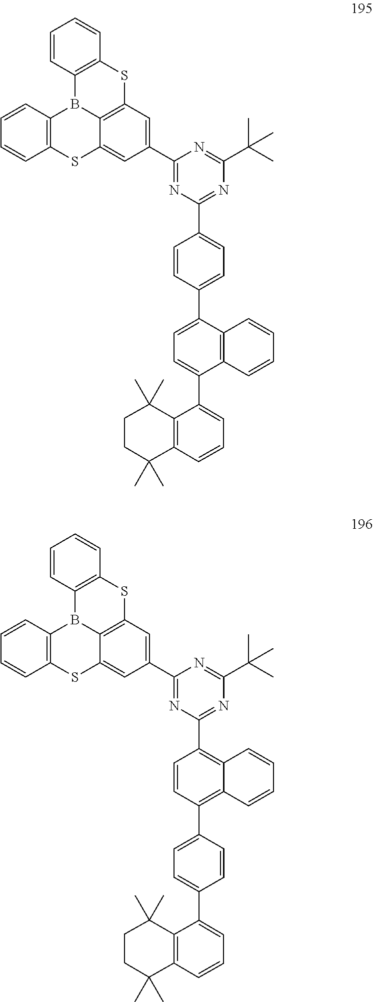 [SMILES: CC(C)(C)c1nc(-c2ccc(-c3ccc(-c4cccc5c4C(C)(C)CCC5(C)C)c4ccccc34)cc2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(-c3ccc(-c4cccc5c4C(C)(C)CCC5(C)C)cc3)c3ccccc23)n1]

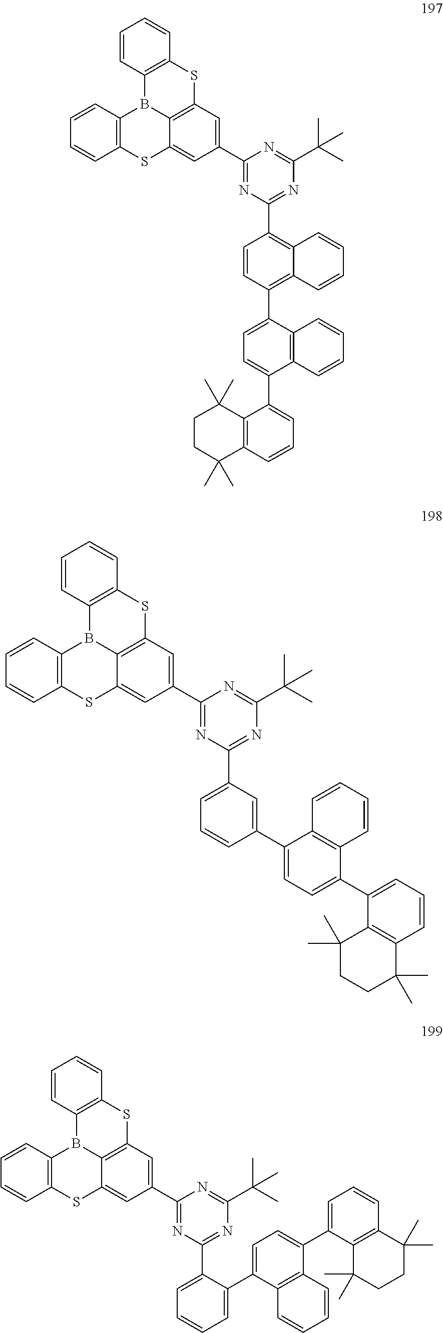 [SMILES: CC(C)(C)c1nc(-c2cc3c4c(c2)Sc2ccccc2B4c2ccccc2S3)nc(-c2ccc(-c3ccc(-c4cccc5c4C(C)(C)CCC5(C)C)c4ccccc34)c3ccccc23)n1 ; CC(C)(C)c1nc(-c2cccc(-c3ccc(-c4cccc5c4C(C)(C)CCC5(C)C)c4ccccc34)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3cccc4c3C(C)(C)CCC4(C)C)c3ccccc23)n1]

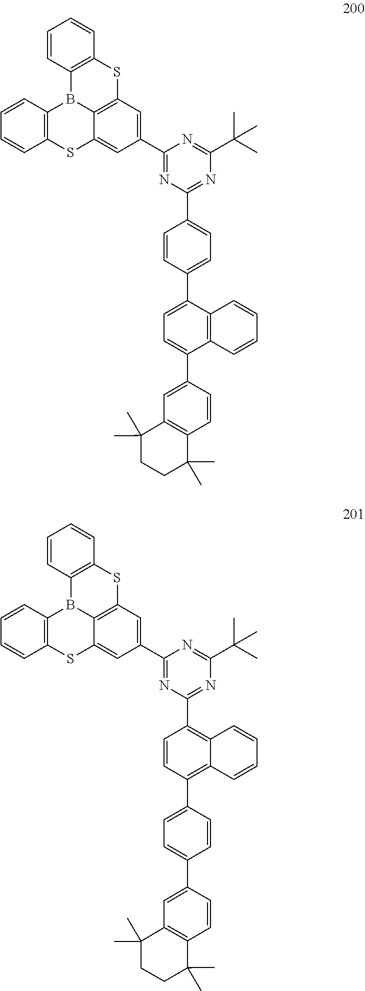 [SMILES: CC(C)(C)c1nc(-c2ccc(-c3ccc(-c4ccc5c(c4)C(C)(C)CCC5(C)C)c4ccccc34)cc2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(-c3ccc(-c4ccc5c(c4)C(C)(C)CCC5(C)C)cc3)c3ccccc23)n1]

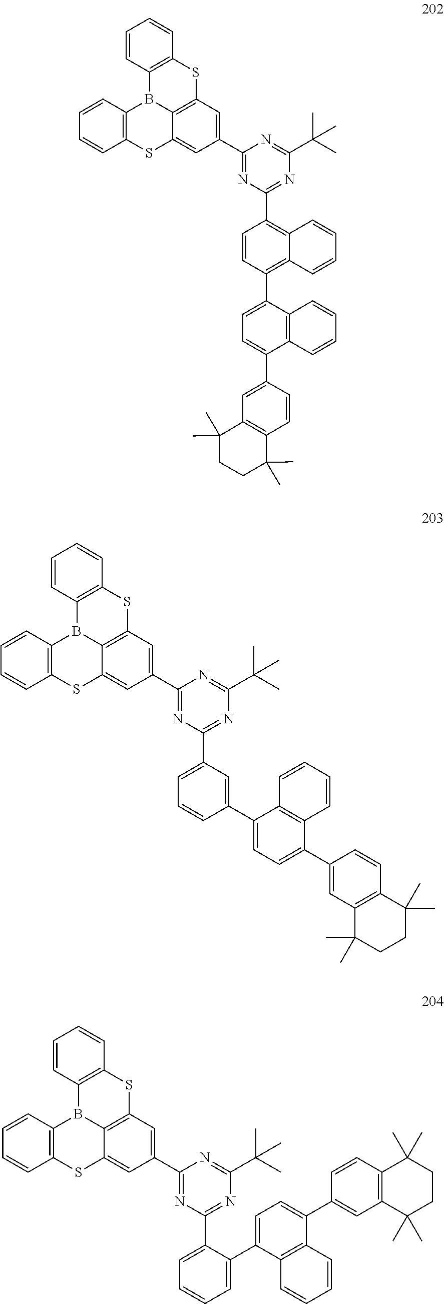 [SMILES: CC(C)(C)c1nc(-c2cc3c4c(c2)Sc2ccccc2B4c2ccccc2S3)nc(-c2ccc(-c3ccc(-c4ccc5c(c4)C(C)(C)CCC5(C)C)c4ccccc34)c3ccccc23)n1 ; CC(C)(C)c1nc(-c2cccc(-c3ccc(-c4ccc5c(c4)C(C)(C)CCC5(C)C)c4ccccc34)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccccc2-c2ccc(-c3ccc4c(c3)C(C)(C)CCC4(C)C)c3ccccc23)n1]

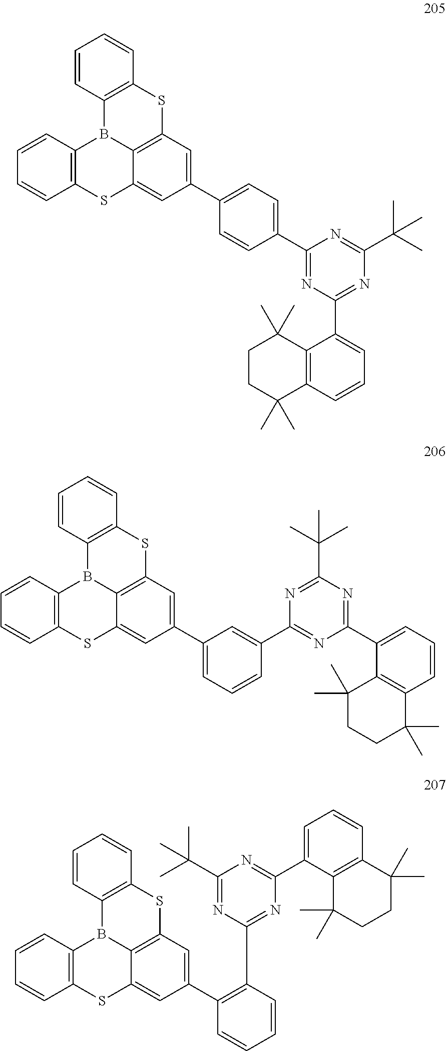 [SMILES: CC(C)(C)c1nc(-c2ccc(-c3cc4c5c(c3)Sc3ccccc3B5c3ccccc3S4)cc2)nc(-c2cccc3c2C(C)(C)CCC3(C)C)n1 ; CC(C)(C)c1nc(-c2cccc(-c3cc4c5c(c3)Sc3ccccc3B5c3ccccc3S4)c2)nc(-c2cccc3c2C(C)(C)CCC3(C)C)n1 ; CC(C)(C)c1nc(-c2ccccc2-c2cc3c4c(c2)Sc2ccccc2B4c2ccccc2S3)nc(-c2cccc3c2C(C)(C)CCC3(C)C)n1]

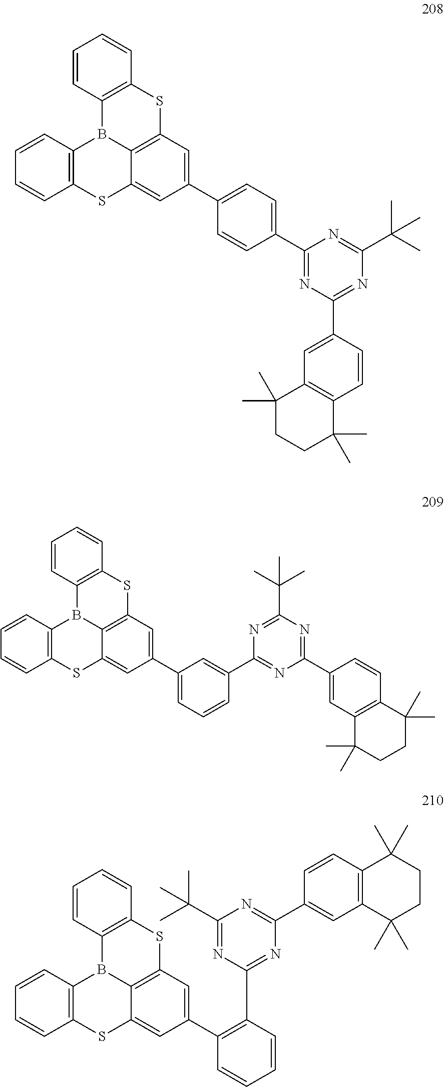 [SMILES: CC(C)(C)c1nc(-c2ccc(-c3cc4c5c(c3)Sc3ccccc3B5c3ccccc3S4)cc2)nc(-c2ccc3c(c2)C(C)(C)CCC3(C)C)n1 ; CC(C)(C)c1nc(-c2cccc(-c3cc4c5c(c3)Sc3ccccc3B5c3ccccc3S4)c2)nc(-c2ccc3c(c2)C(C)(C)CCC3(C)C)n1 ; CC(C)(C)c1nc(-c2ccc3c(c2)C(C)(C)CCC3(C)C)nc(-c2ccccc2-c2cc3c4c(c2)Sc2ccccc2B4c2ccccc2S3)n1]

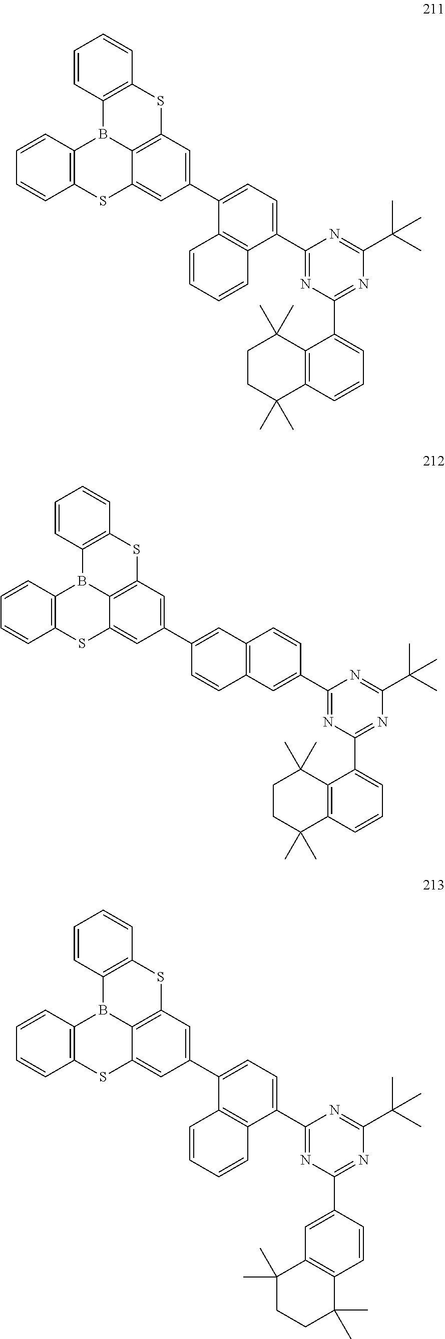 [SMILES: CC(C)(C)c1nc(-c2cccc3c2C(C)(C)CCC3(C)C)nc(-c2ccc(-c3cc4c5c(c3)Sc3ccccc3B5c3ccccc3S4)c3ccccc23)n1 ; CC(C)(C)c1nc(-c2ccc3cc(-c4cc5c6c(c4)Sc4ccccc4B6c4ccccc4S5)ccc3c2)nc(-c2cccc3c2C(C)(C)CCC3(C)C)n1 ; CC(C)(C)c1nc(-c2ccc3c(c2)C(C)(C)CCC3(C)C)nc(-c2ccc(-c3cc4c5c(c3)Sc3ccccc3B5c3ccccc3S4)c3ccccc23)n1]

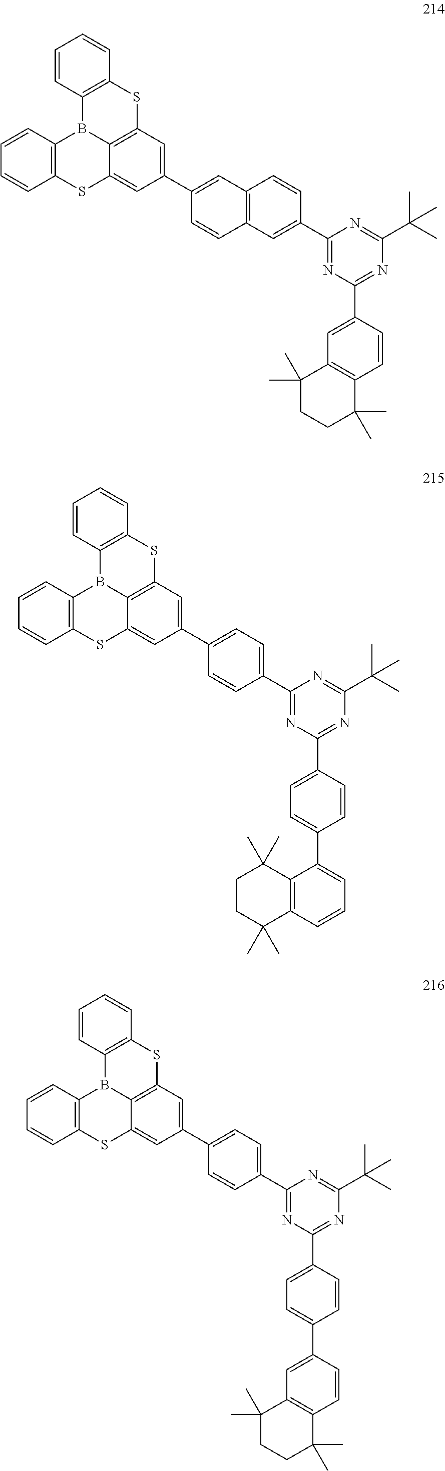 [SMILES: CC(C)(C)c1nc(-c2ccc3c(c2)C(C)(C)CCC3(C)C)nc(-c2ccc3cc(-c4cc5c6c(c4)Sc4ccccc4B6c4ccccc4S5)ccc3c2)n1 ; CC(C)(C)c1nc(-c2ccc(-c3cc4c5c(c3)Sc3ccccc3B5c3ccccc3S4)cc2)nc(-c2ccc(-c3cccc4c3C(C)(C)CCC4(C)C)cc2)n1 ; CC(C)(C)c1nc(-c2ccc(-c3cc4c5c(c3)Sc3ccccc3B5c3ccccc3S4)cc2)nc(-c2ccc(-c3ccc4c(c3)C(C)(C)CCC4(C)C)cc2)n1]

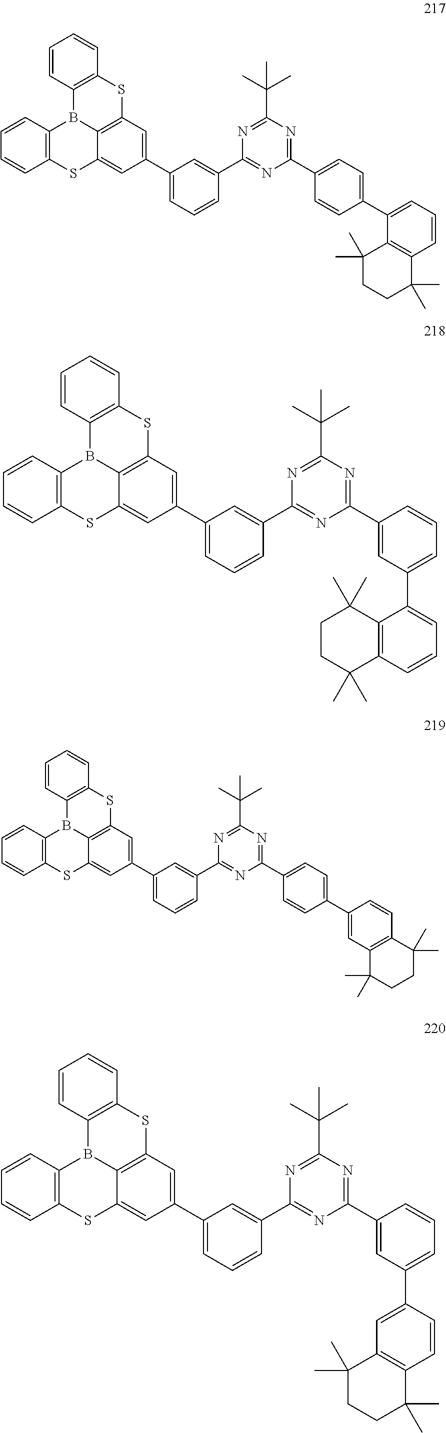 [SMILES: CC(C)(C)c1nc(-c2ccc(-c3cccc4c3C(C)(C)CCC4(C)C)cc2)nc(-c2cccc(-c3cc4c5c(c3)Sc3ccccc3B5c3ccccc3S4)c2)n1 ; CC(C)(C)c1nc(-c2cccc(-c3cc4c5c(c3)Sc3ccccc3B5c3ccccc3S4)c2)nc(-c2cccc(-c3cccc4c3C(C)(C)CCC4(C)C)c2)n1 ; CC(C)(C)c1nc(-c2ccc(-c3ccc4c(c3)C(C)(C)CCC4(C)C)cc2)nc(-c2cccc(-c3cc4c5c(c3)Sc3ccccc3B5c3ccccc3S4)c2)n1 ; CC(C)(C)c1nc(-c2cccc(-c3cc4c5c(c3)Sc3ccccc3B5c3ccccc3S4)c2)nc(-c2cccc(-c3ccc4c(c3)C(C)(C)CCC4(C)C)c2)n1]

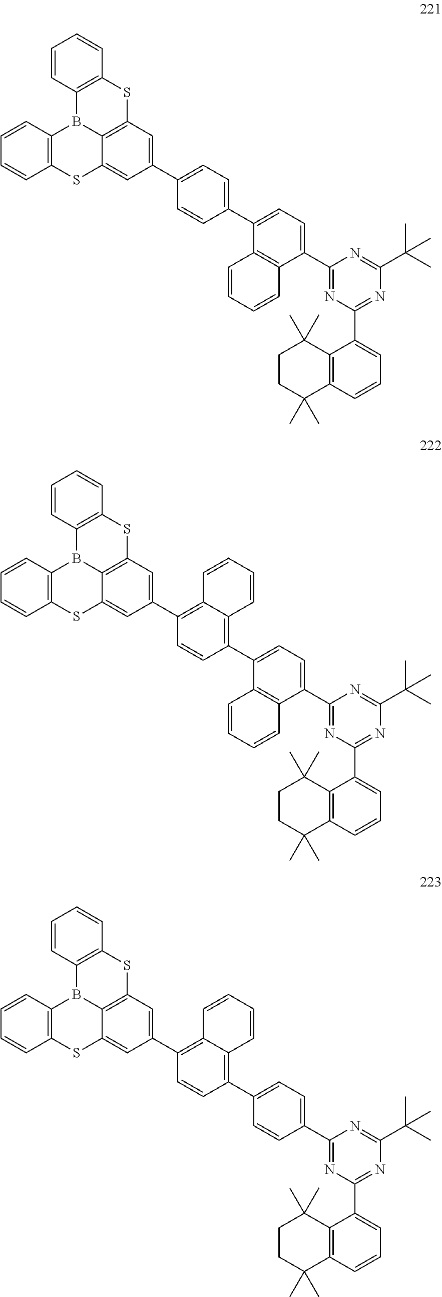 [SMILES: CC(C)(C)c1nc(-c2cccc3c2C(C)(C)CCC3(C)C)nc(-c2ccc(-c3ccc(-c4cc5c6c(c4)Sc4ccccc4B6c4ccccc4S5)cc3)c3ccccc23)n1 ; CC(C)(C)c1nc(-c2cccc3c2C(C)(C)CCC3(C)C)nc(-c2ccc(-c3ccc(-c4cc5c6c(c4)Sc4ccccc4B6c4ccccc4S5)c4ccccc34)c3ccccc23)n1 ; CC(C)(C)c1nc(-c2ccc(-c3ccc(-c4cc5c6c(c4)Sc4ccccc4B6c4ccccc4S5)c4ccccc34)cc2)nc(-c2cccc3c2C(C)(C)CCC3(C)C)n1]

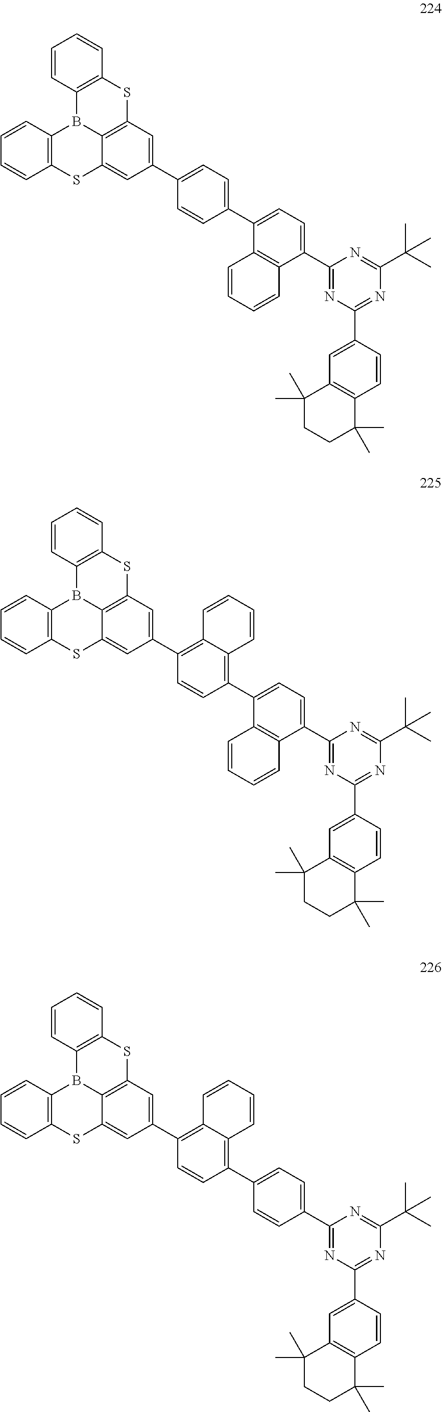 [SMILES: CC(C)(C)c1nc(-c2ccc3c(c2)C(C)(C)CCC3(C)C)nc(-c2ccc(-c3ccc(-c4cc5c6c(c4)Sc4ccccc4B6c4ccccc4S5)cc3)c3ccccc23)n1 ; CC(C)(C)c1nc(-c2ccc3c(c2)C(C)(C)CCC3(C)C)nc(-c2ccc(-c3ccc(-c4cc5c6c(c4)Sc4ccccc4B6c4ccccc4S5)c4ccccc34)c3ccccc23)n1 ; CC(C)(C)c1nc(-c2ccc(-c3ccc(-c4cc5c6c(c4)Sc4ccccc4B6c4ccccc4S5)c4ccccc34)cc2)nc(-c2ccc3c(c2)C(C)(C)CCC3(C)C)n1]

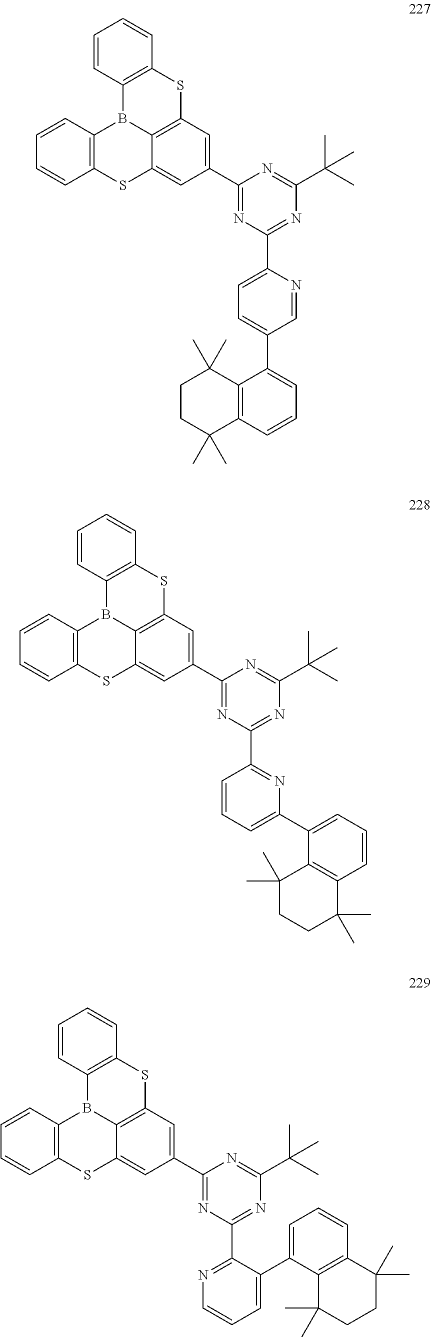 [SMILES: CC(C)(C)c1nc(-c2cc3c4c(c2)Sc2ccccc2B4c2ccccc2S3)nc(-c2ccc(-c3cccc4c3C(C)(C)CCC4(C)C)cn2)n1 ; CC(C)(C)c1nc(-c2cc3c4c(c2)Sc2ccccc2B4c2ccccc2S3)nc(-c2cccc(-c3cccc4c3C(C)(C)CCC4(C)C)n2)n1 ; CC(C)(C)c1nc(-c2cc3c4c(c2)Sc2ccccc2B4c2ccccc2S3)nc(-c2ncccc2-c2cccc3c2C(C)(C)CCC3(C)C)n1]

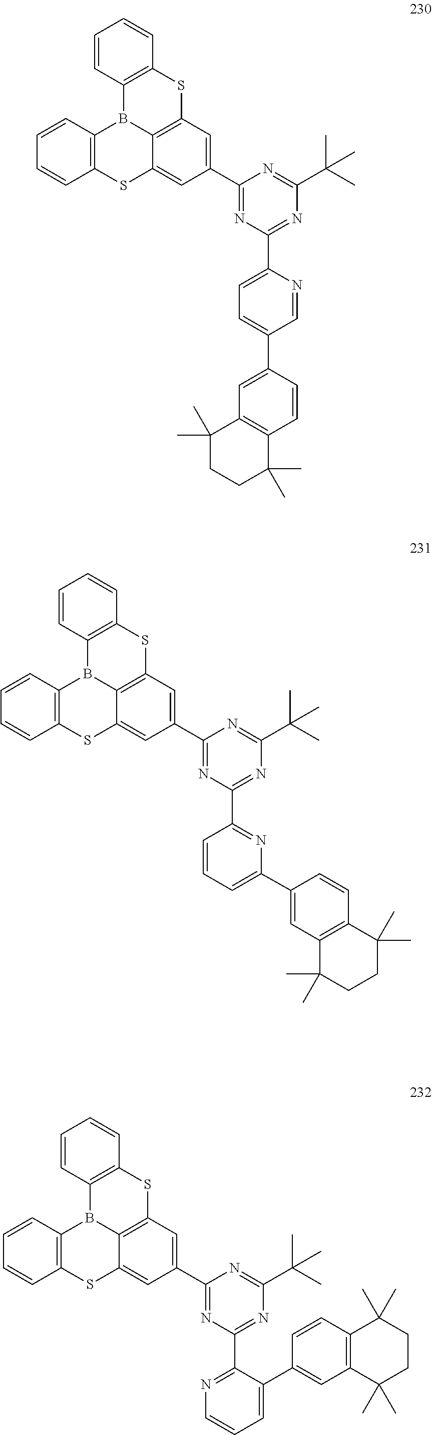 [SMILES: CC(C)(C)c1nc(-c2cc3c4c(c2)Sc2ccccc2B4c2ccccc2S3)nc(-c2ccc(-c3ccc4c(c3)C(C)(C)CCC4(C)C)cn2)n1 ; CC(C)(C)c1nc(-c2cc3c4c(c2)Sc2ccccc2B4c2ccccc2S3)nc(-c2cccc(-c3ccc4c(c3)C(C)(C)CCC4(C)C)n2)n1 ; CC(C)(C)c1nc(-c2cc3c4c(c2)Sc2ccccc2B4c2ccccc2S3)nc(-c2ncccc2-c2ccc3c(c2)C(C)(C)CCC3(C)C)n1]

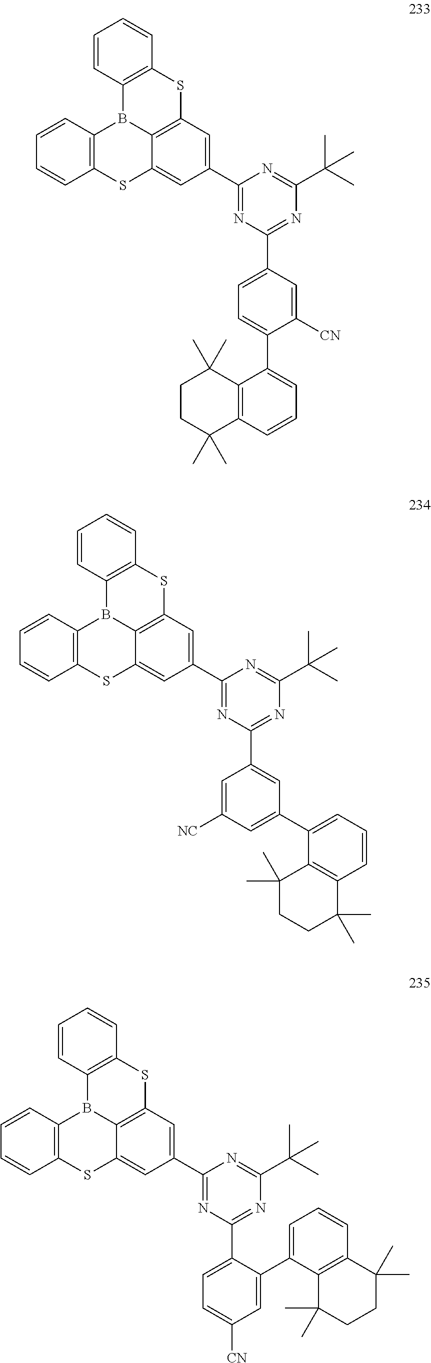 [SMILES: CC(C)(C)c1nc(-c2ccc(-c3cccc4c3C(C)(C)CCC4(C)C)c(C#N)c2)nc(-c2cc3c4c(c2)Sc2ccccc2B4c2ccccc2S3)n1 ; CC(C)(C)c1nc(-c2cc(C#N)cc(-c3cccc4c3C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(C#N)cc2-c2cccc3c2C(C)(C)CCC3(C)C)n1]

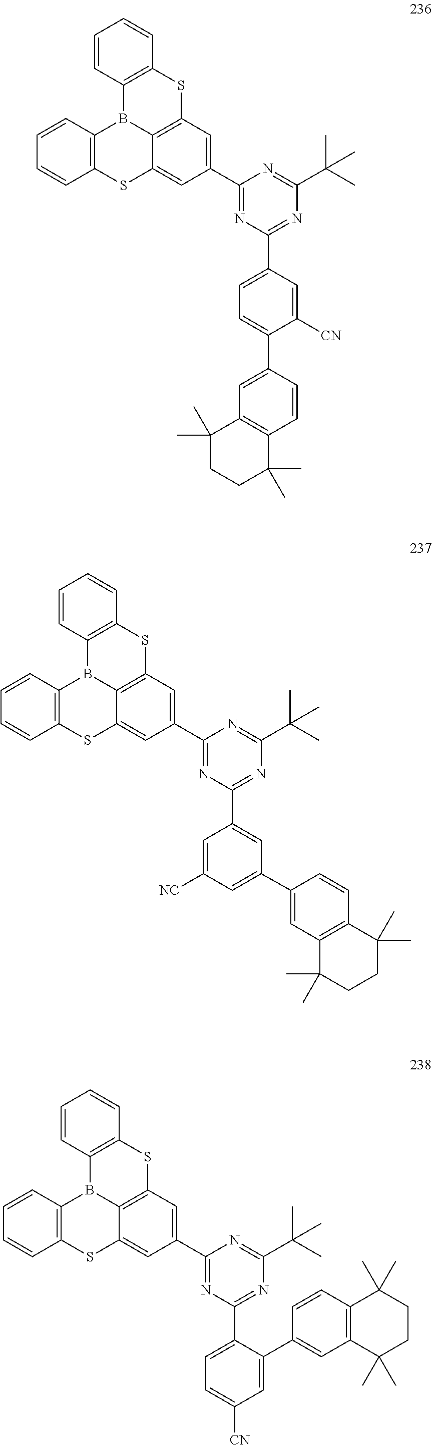 [SMILES: CC(C)(C)c1nc(-c2ccc(-c3ccc4c(c3)C(C)(C)CCC4(C)C)c(C#N)c2)nc(-c2cc3c4c(c2)Sc2ccccc2B4c2ccccc2S3)n1 ; CC(C)(C)c1nc(-c2cc(C#N)cc(-c3ccc4c(c3)C(C)(C)CCC4(C)C)c2)nc(-c2cc3c4c(c2)Sc2ccccc2B4c2ccccc2S3)n1 ; CC(C)(C)c1nc(-c2cc3c4c(c2)Sc2ccccc2B4c2ccccc2S3)nc(-c2ccc(C#N)cc2-c2ccc3c(c2)C(C)(C)CCC3(C)C)n1]

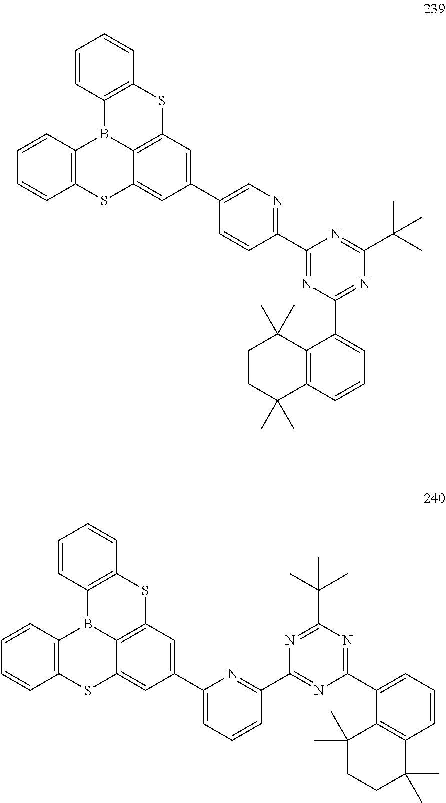 [SMILES: CC(C)(C)c1nc(-c2ccc(-c3cc4c5c(c3)Sc3ccccc3B5c3ccccc3S4)cn2)nc(-c2cccc3c2C(C)(C)CCC3(C)C)n1 ; CC(C)(C)c1nc(-c2cccc(-c3cc4c5c(c3)Sc3ccccc3B5c3ccccc3S4)n2)nc(-c2cccc3c2C(C)(C)CCC3(C)C)n1]

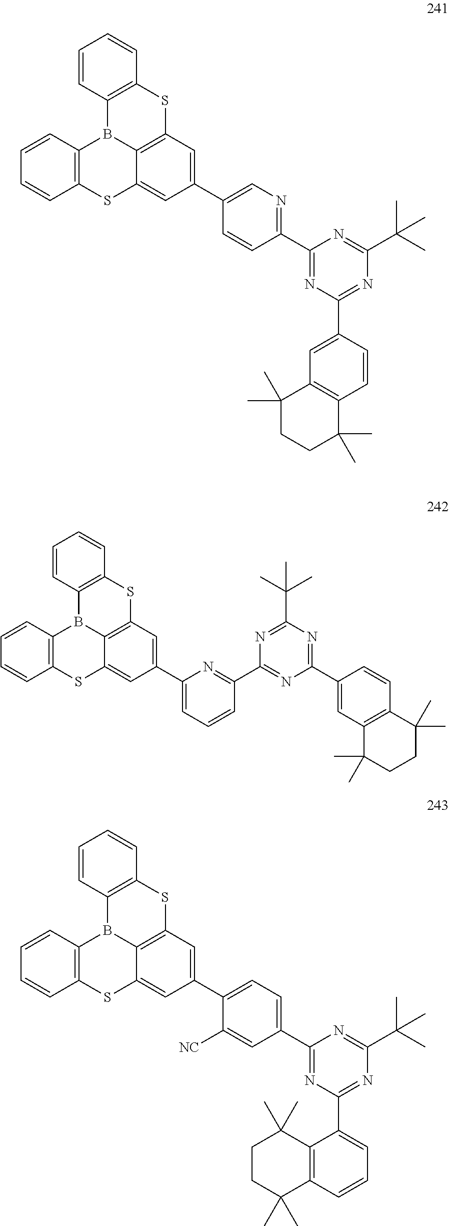 [SMILES: CC(C)(C)c1nc(-c2ccc3c(c2)C(C)(C)CCC3(C)C)nc(-c2ccc(-c3cc4c5c(c3)Sc3ccccc3B5c3ccccc3S4)cn2)n1 ; CC(C)(C)c1nc(-c2ccc3c(c2)C(C)(C)CCC3(C)C)nc(-c2cccc(-c3cc4c5c(c3)Sc3ccccc3B5c3ccccc3S4)n2)n1 ; CC(C)(C)c1nc(-c2ccc(-c3cc4c5c(c3)Sc3ccccc3B5c3ccccc3S4)c(C#N)c2)nc(-c2cccc3c2C(C)(C)CCC3(C)C)n1]

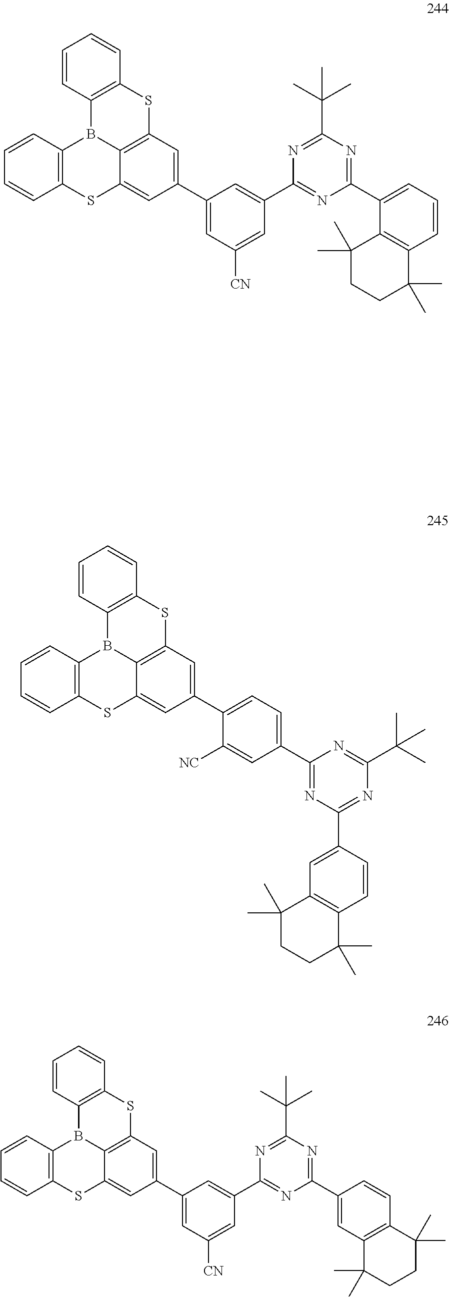 [SMILES: CC(C)(C)c1nc(-c2cc(C#N)cc(-c3cc4c5c(c3)Sc3ccccc3B5c3ccccc3S4)c2)nc(-c2cccc3c2C(C)(C)CCC3(C)C)n1 ; CC(C)(C)c1nc(-c2ccc(-c3cc4c5c(c3)Sc3ccccc3B5c3ccccc3S4)c(C#N)c2)nc(-c2ccc3c(c2)C(C)(C)CCC3(C)C)n1 ; CC(C)(C)c1nc(-c2cc(C#N)cc(-c3cc4c5c(c3)Sc3ccccc3B5c3ccccc3S4)c2)nc(-c2ccc3c(c2)C(C)(C)CCC3(C)C)n1]

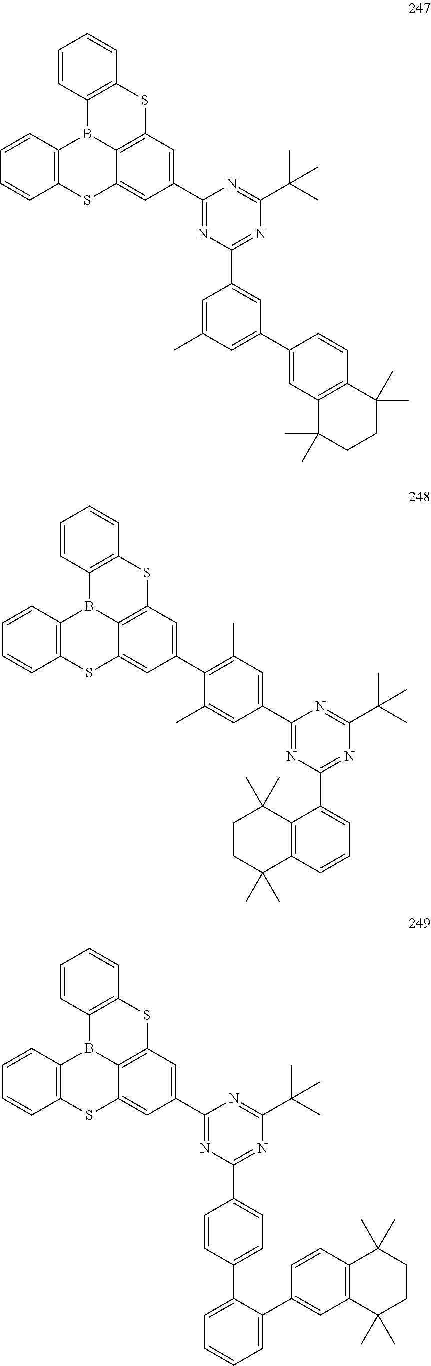 [SMILES: Cc1cc(-c2ccc3c(c2)C(C)(C)CCC3(C)C)cc(-c2nc(-c3cc4c5c(c3)Sc3ccccc3B5c3ccccc3S4)nc(C(C)(C)C)n2)c1 ; Cc1cc(-c2nc(-c3cccc4c3C(C)(C)CCC4(C)C)nc(C(C)(C)C)n2)cc(C)c1-c1cc2c3c(c1)Sc1ccccc1B3c1ccccc1S2 ; CC(C)(C)c1nc(-c2ccc(-c3ccccc3-c3ccc4c(c3)C(C)(C)CCC4(C)C)cc2)nc(-c2cc3c4c(c2)Sc2ccccc2B4c2ccccc2S3)n1]

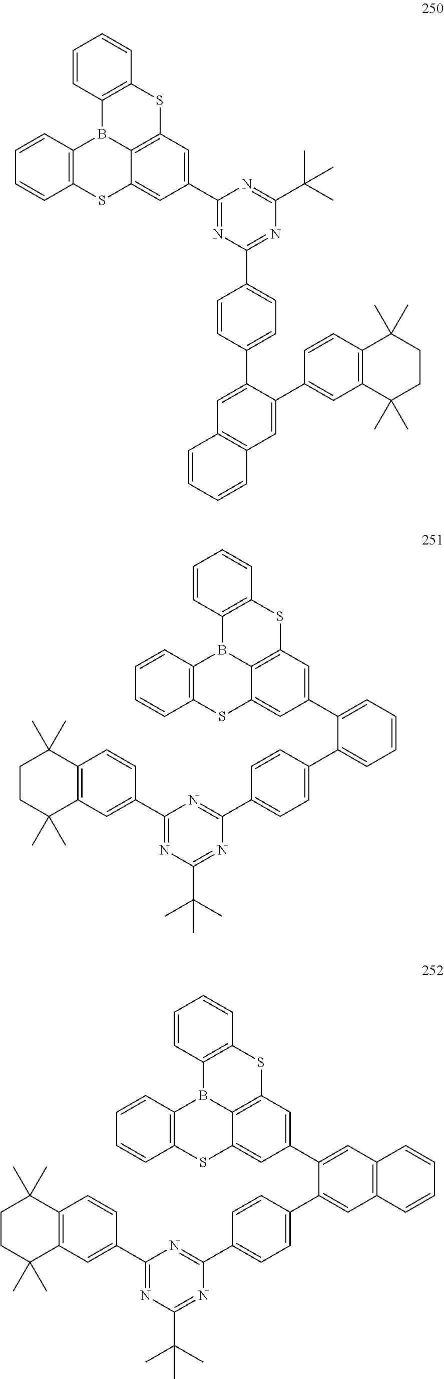 [SMILES: CC(C)(C)c1nc(-c2ccc(-c3cc4ccccc4cc3-c3ccc4c(c3)C(C)(C)CCC4(C)C)cc2)nc(-c2cc3c4c(c2)Sc2ccccc2B4c2ccccc2S3)n1 ; CC(C)(C)c1nc(-c2ccc(-c3ccccc3-c3cc4c5c(c3)Sc3ccccc3B5c3ccccc3S4)cc2)nc(-c2ccc3c(c2)C(C)(C)CCC3(C)C)n1 ; CC(C)(C)c1nc(-c2ccc(-c3cc4ccccc4cc3-c3cc4c5c(c3)Sc3ccccc3B5c3ccccc3S4)cc2)nc(-c2ccc3c(c2)C(C)(C)CCC3(C)C)n1]

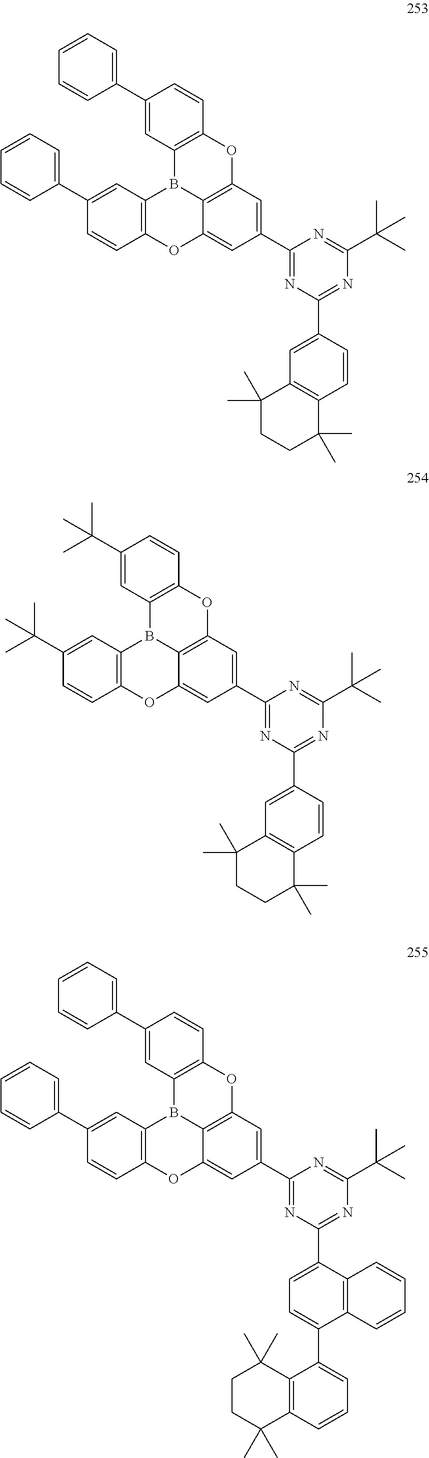

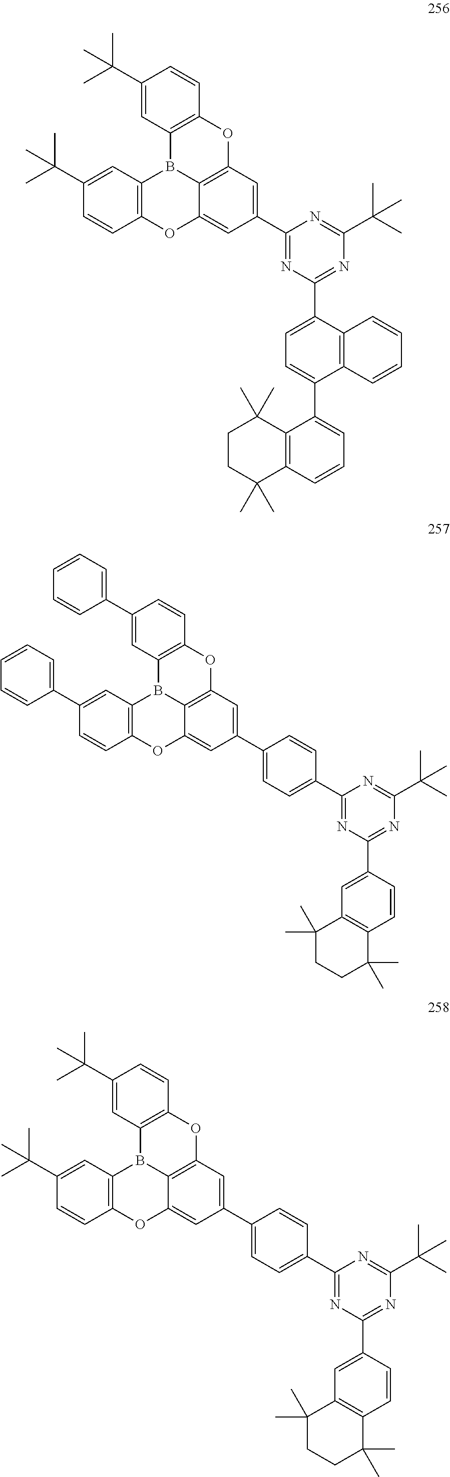

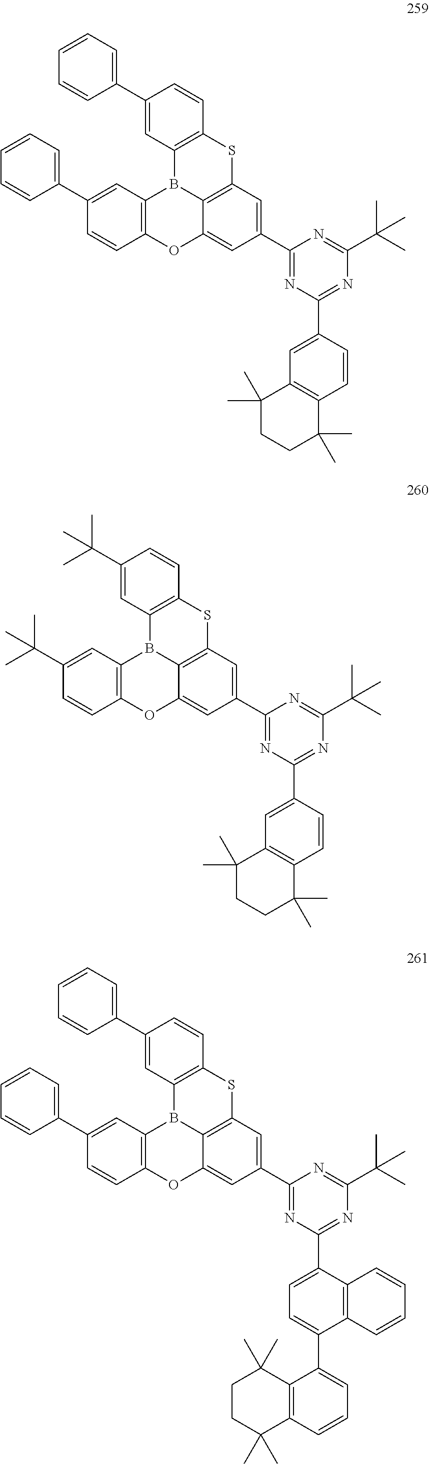

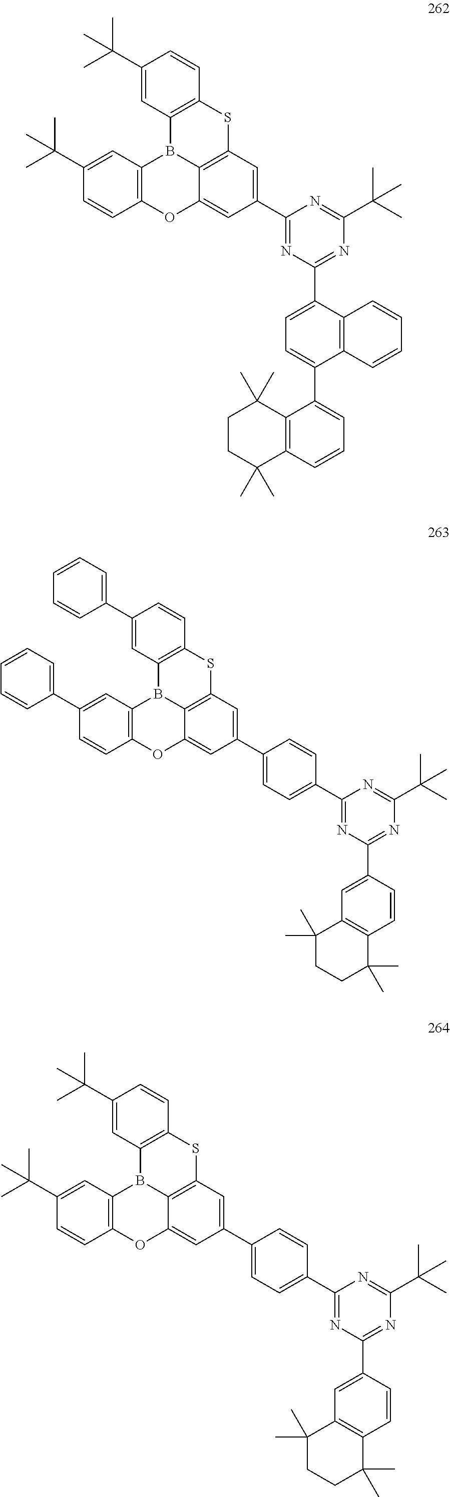

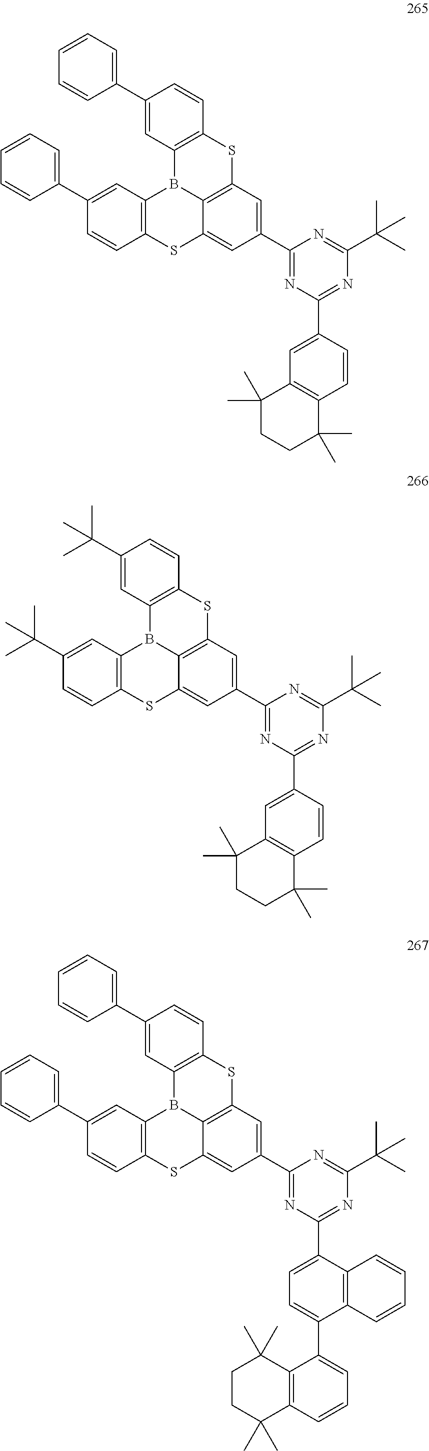

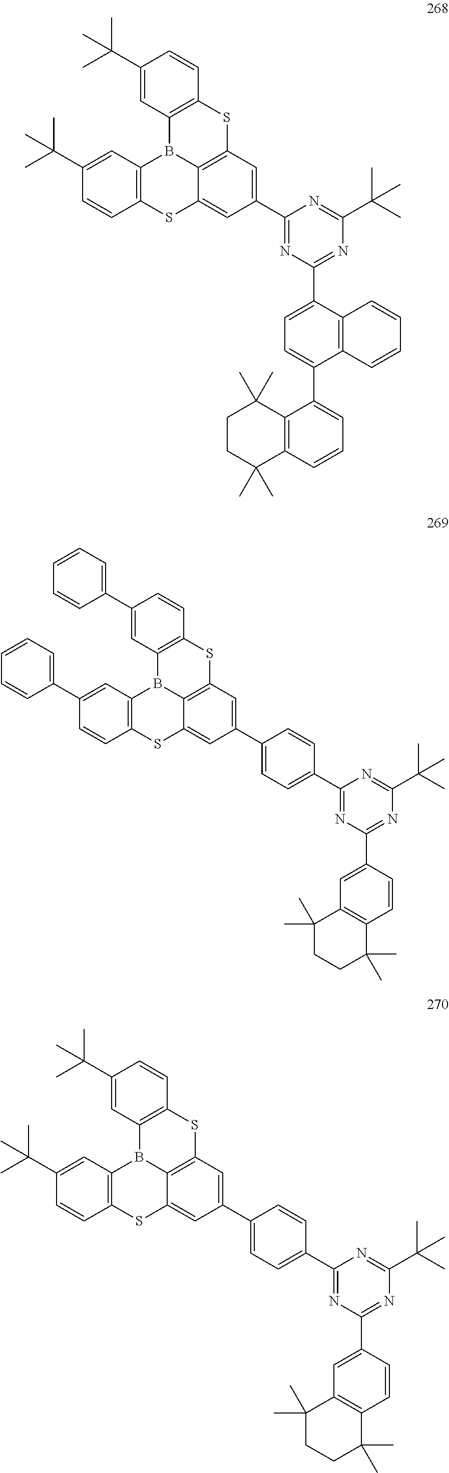

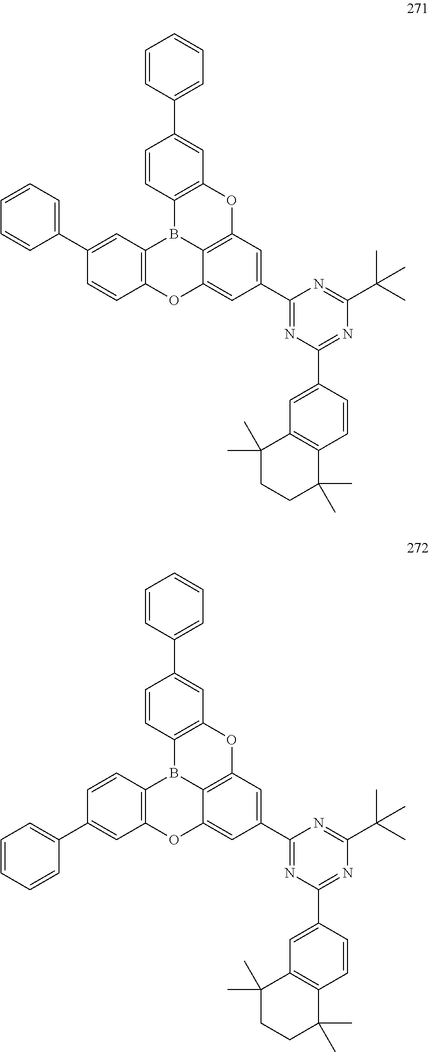 [SMILES: CC(C)(C)c1nc(-c2cc3c4c(c2)Oc2ccc(-c5ccccc5)cc2B4c2ccc(-c4ccccc4)cc2O3)nc(-c2ccc3c(c2)C(C)(C)CCC3(C)C)n1 ; CC(C)(C)c1nc(-c2cc3c4c(c2)Oc2cc(-c5ccccc5)ccc2B4c2ccc(-c4ccccc4)cc2O3)nc(-c2ccc3c(c2)C(C)(C)CCC3(C)C)n1]

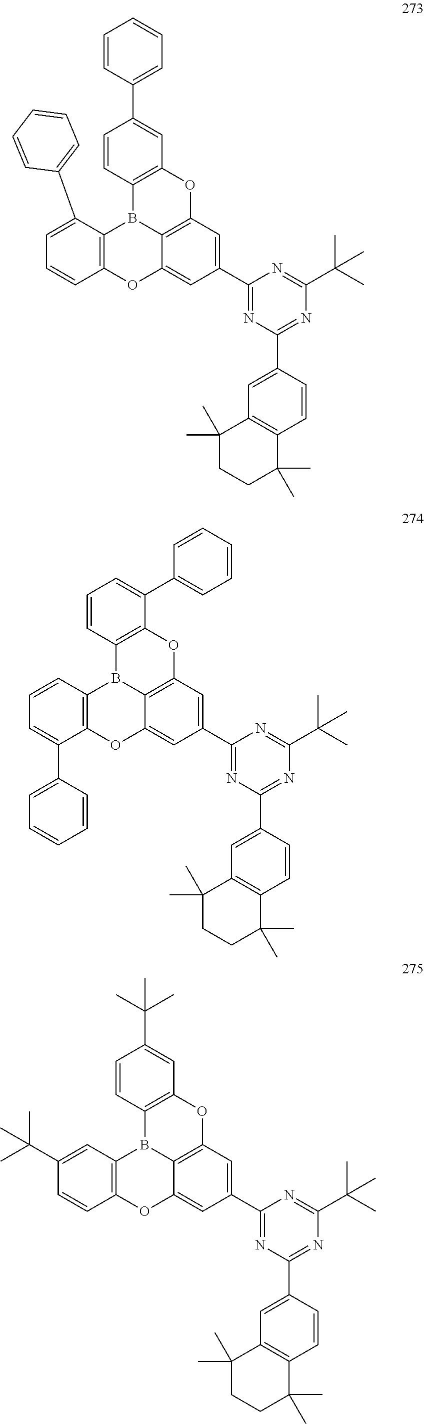

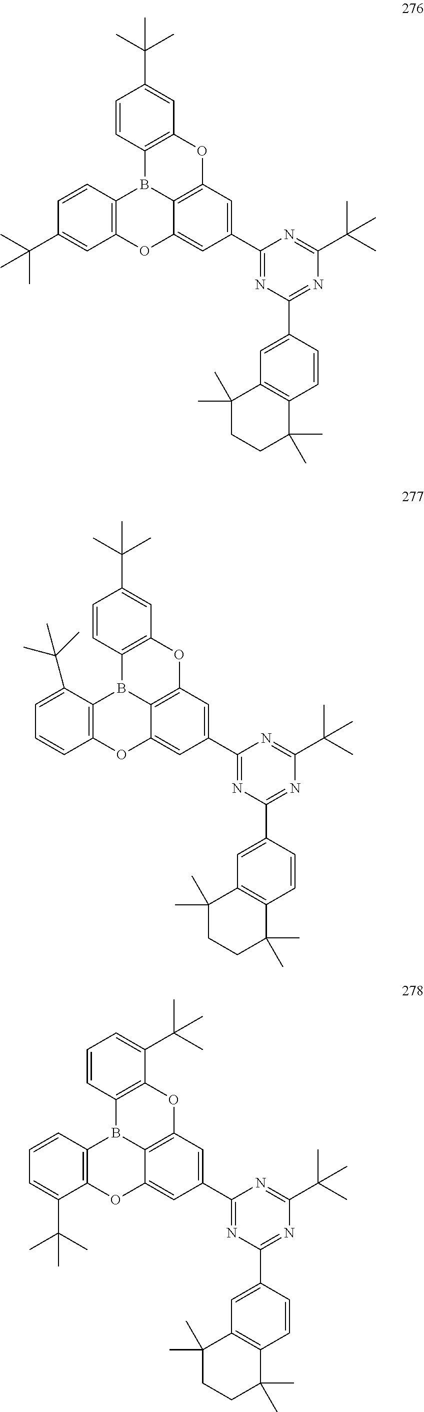

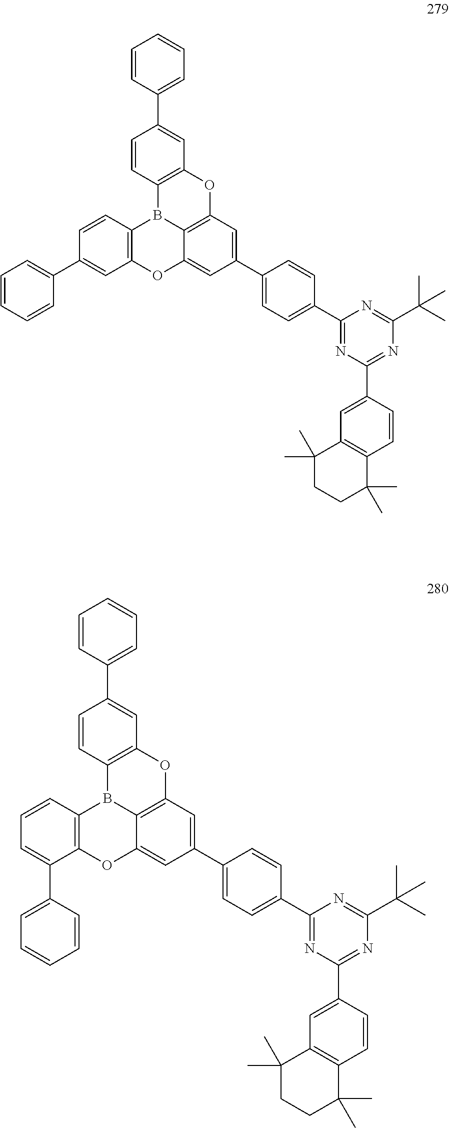 [SMILES: CC(C)(C)c1nc(-c2ccc(-c3cc4c5c(c3)Oc3cc(-c6ccccc6)ccc3B5c3ccc(-c5ccccc5)cc3O4)cc2)nc(-c2ccc3c(c2)C(C)(C)CCC3(C)C)n1 ; CC(C)(C)c1nc(-c2ccc(-c3cc4c5c(c3)Oc3c(cccc3-c3ccccc3)B5c3ccc(-c5ccccc5)cc3O4)cc2)nc(-c2ccc3c(c2)C(C)(C)CCC3(C)C)n1]

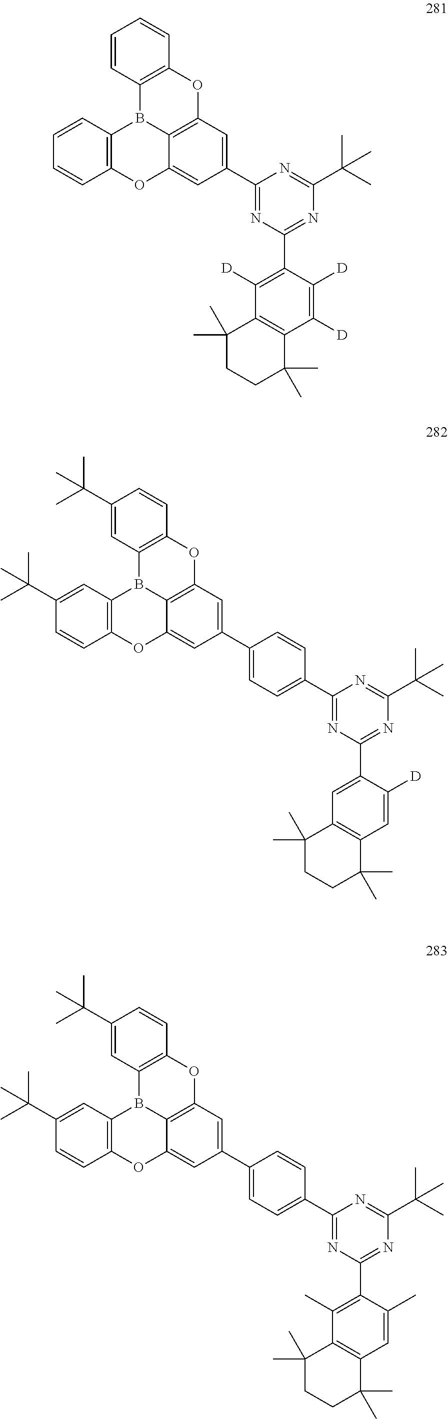

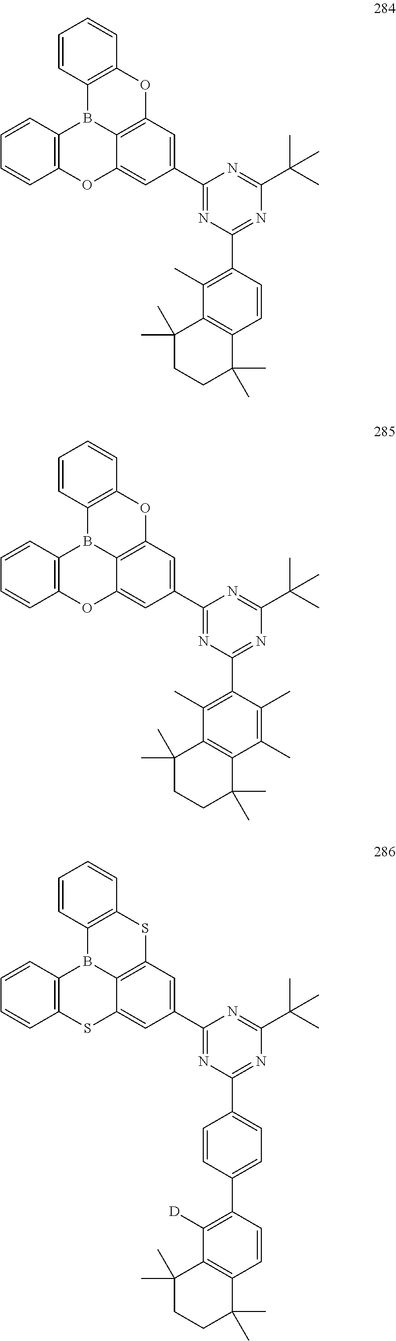 [SMILES: Cc1c(-c2nc(-c3cc4c5c(c3)Oc3ccccc3B5c3ccccc3O4)nc(C(C)(C)C)n2)ccc2c1C(C)(C)CCC2(C)C ; Cc1c(C)c2c(c(C)c1-c1nc(-c3cc4c5c(c3)Oc3ccccc3B5c3ccccc3O4)nc(C(C)(C)C)n1)C(C)(C)CCC2(C)C ; [2H]c1c(-c2ccc(-c3nc(-c4cc5c6c(c4)Sc4ccccc4B6c4ccccc4S5)nc(C(C)(C)C)n3)cc2)ccc2c1C(C)(C)CCC2(C)C]

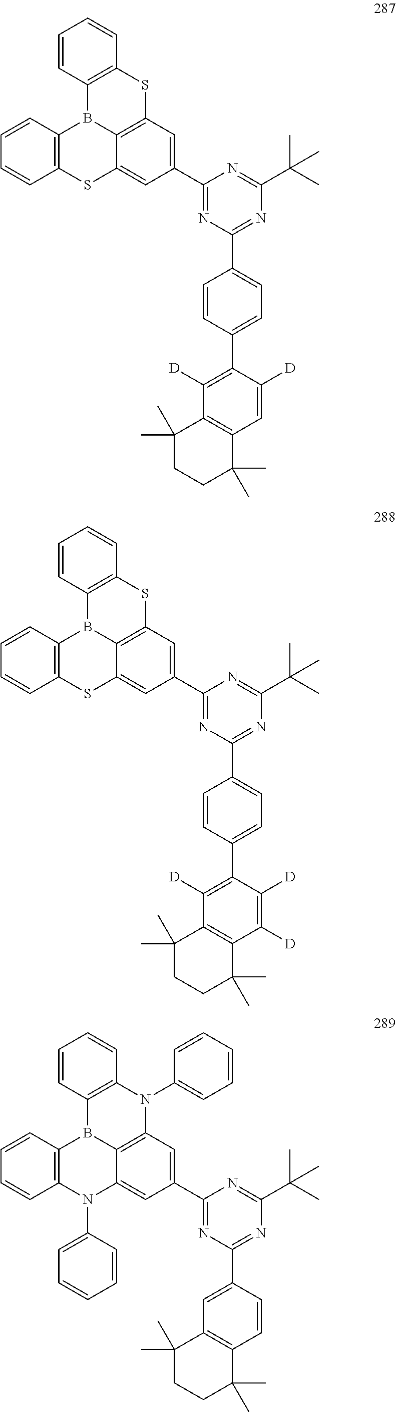

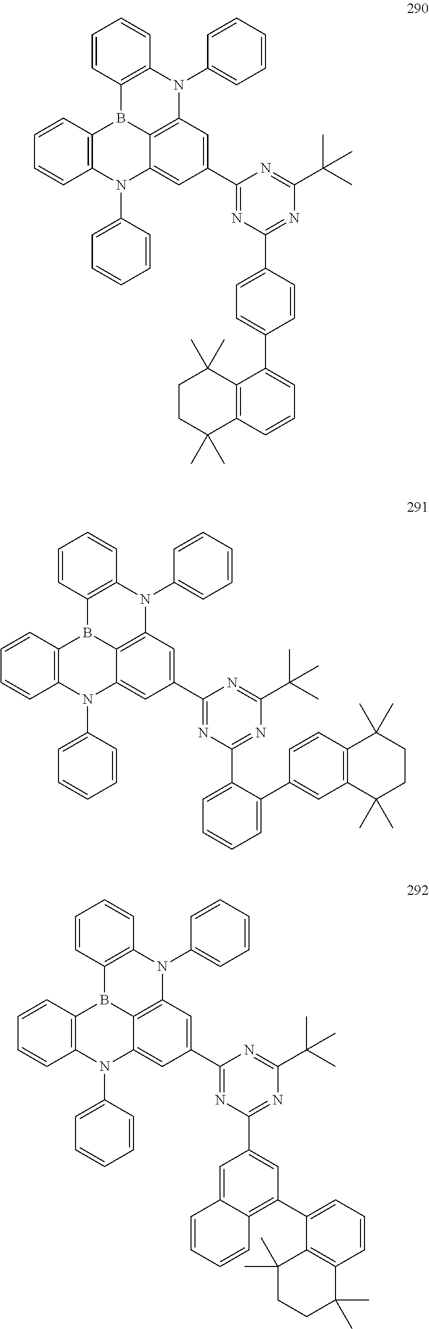 [SMILES: CC(C)(C)c1nc(-c2ccc(-c3cccc4c3C(C)(C)CCC4(C)C)cc2)nc(-c2cc3c4c(c2)N(c2ccccc2)c2ccccc2B4c2ccccc2N3c2ccccc2)n1 ; CC(C)(C)c1nc(-c2cc3c4c(c2)N(c2ccccc2)c2ccccc2B4c2ccccc2N3c2ccccc2)nc(-c2ccccc2-c2ccc3c(c2)C(C)(C)CCC3(C)C)n1 ; CC(C)(C)c1nc(-c2cc3c4c(c2)N(c2ccccc2)c2ccccc2B4c2ccccc2N3c2ccccc2)nc(-c2cc(-c3cccc4c3C(C)(C)CCC4(C)C)c3ccccc3c2)n1]

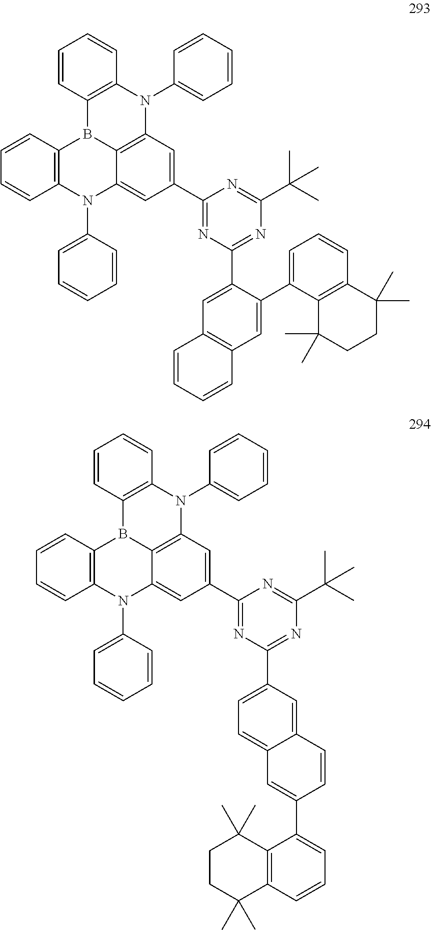 [SMILES: CC(C)(C)c1nc(-c2cc3c4c(c2)N(c2ccccc2)c2ccccc2B4c2ccccc2N3c2ccccc2)nc(-c2cc3ccccc3cc2-c2cccc3c2C(C)(C)CCC3(C)C)n1 ; CC(C)(C)c1nc(-c2cc3c4c(c2)N(c2ccccc2)c2ccccc2B4c2ccccc2N3c2ccccc2)nc(-c2ccc3cc(-c4cccc5c4C(C)(C)CCC5(C)C)ccc3c2)n1]

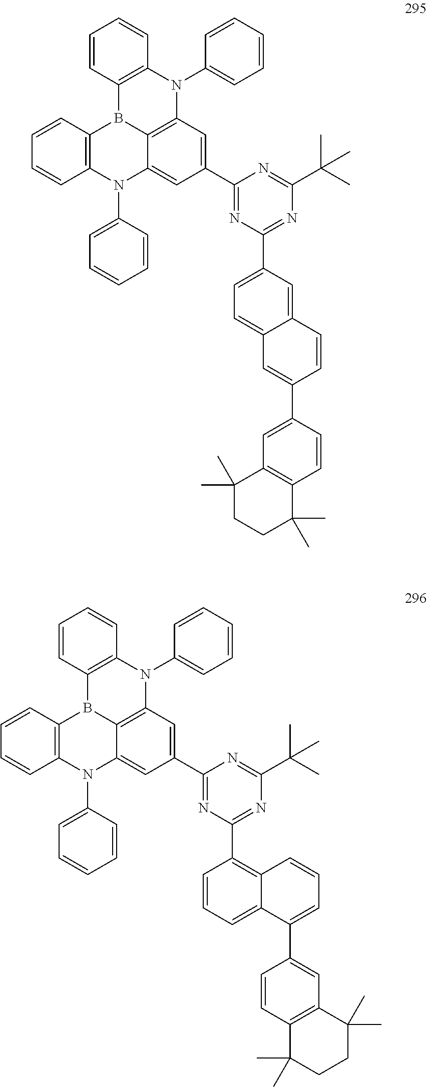 [SMILES: CC(C)(C)c1nc(-c2cc3c4c(c2)N(c2ccccc2)c2ccccc2B4c2ccccc2N3c2ccccc2)nc(-c2ccc3cc(-c4ccc5c(c4)C(C)(C)CCC5(C)C)ccc3c2)n1 ; CC(C)(C)c1nc(-c2cc3c4c(c2)N(c2ccccc2)c2ccccc2B4c2ccccc2N3c2ccccc2)nc(-c2cccc3c(-c4ccc5c(c4)C(C)(C)CCC5(C)C)cccc23)n1]

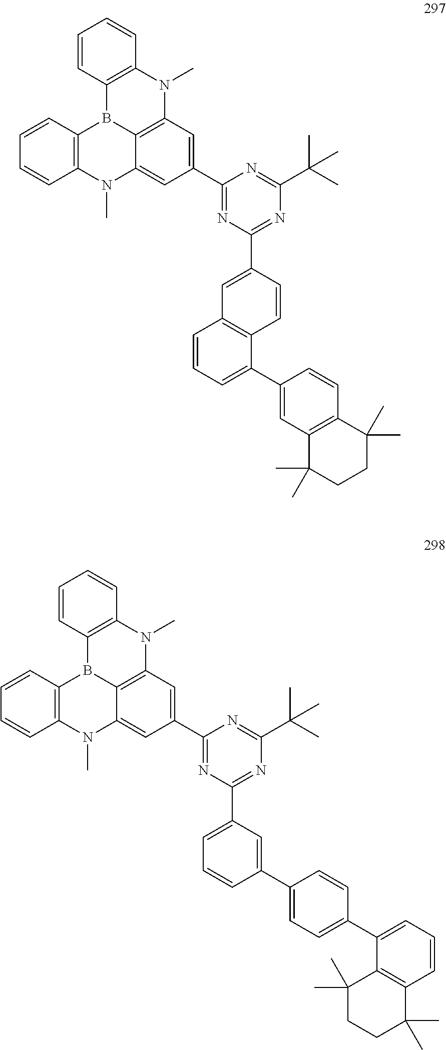 [SMILES: CN1c2ccccc2B2c3ccccc3N(C)c3cc(-c4nc(-c5ccc6c(-c7ccc8c(c7)C(C)(C)CCC8(C)C)cccc6c5)nc(C(C)(C)C)n4)cc1c32 ; CN1c2ccccc2B2c3ccccc3N(C)c3cc(-c4nc(-c5cccc(-c6ccc(-c7cccc8c7C(C)(C)CCC8(C)C)cc6)c5)nc(C(C)(C)C)n4)cc1c32]

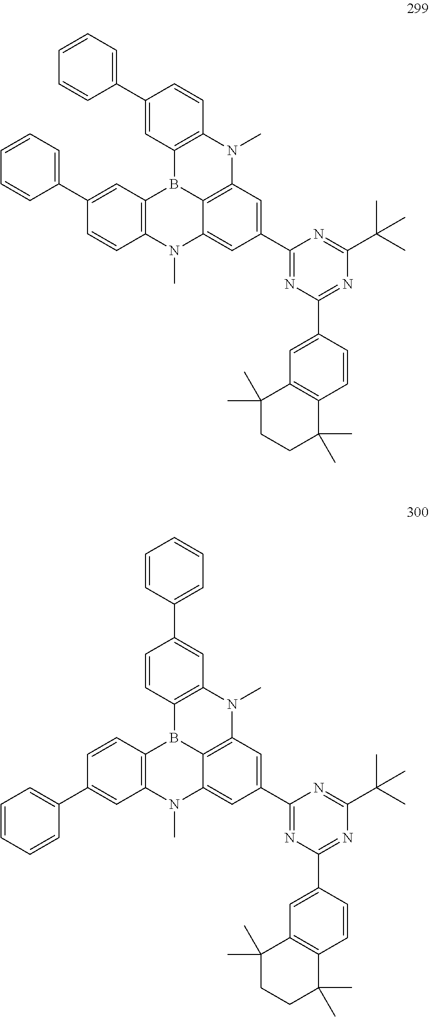 [SMILES: CN1c2ccc(-c3ccccc3)cc2B2c3cc(-c4ccccc4)ccc3N(C)c3cc(-c4nc(-c5ccc6c(c5)C(C)(C)CCC6(C)C)nc(C(C)(C)C)n4)cc1c32 ; CN1c2cc(-c3ccccc3)ccc2B2c3ccc(-c4ccccc4)cc3N(C)c3cc(-c4nc(-c5ccc6c(c5)C(C)(C)CCC6(C)C)nc(C(C)(C)C)n4)cc1c32]

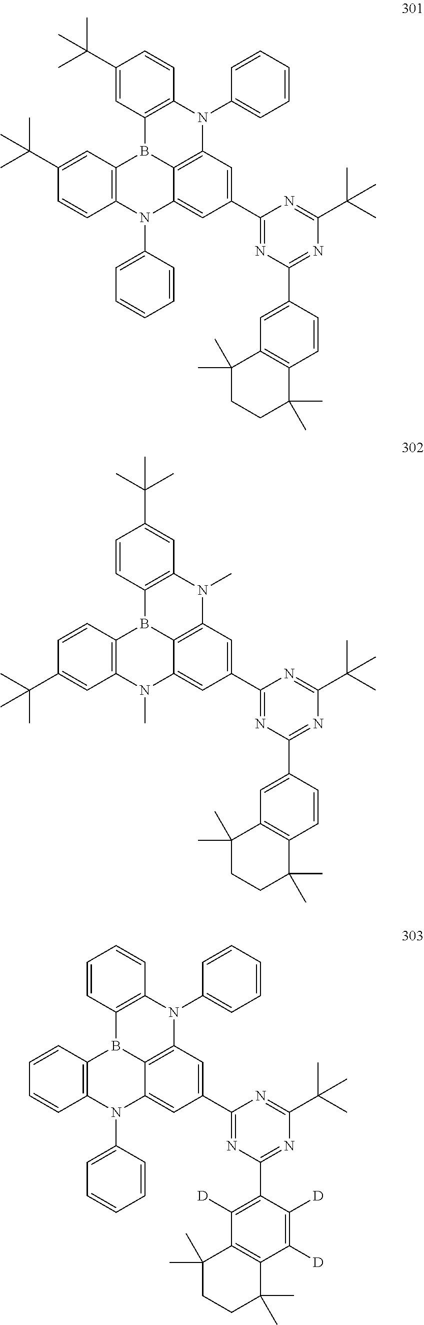

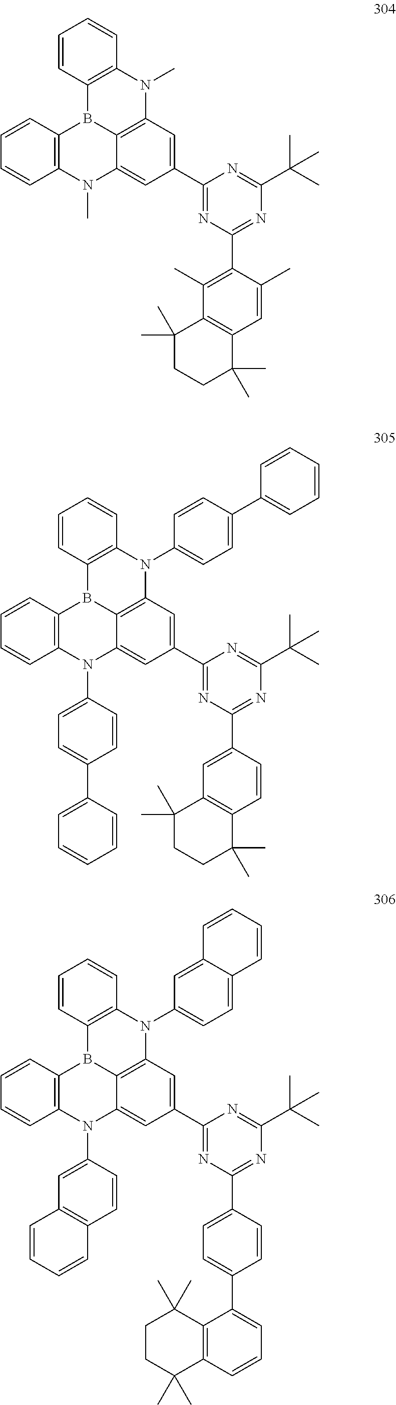

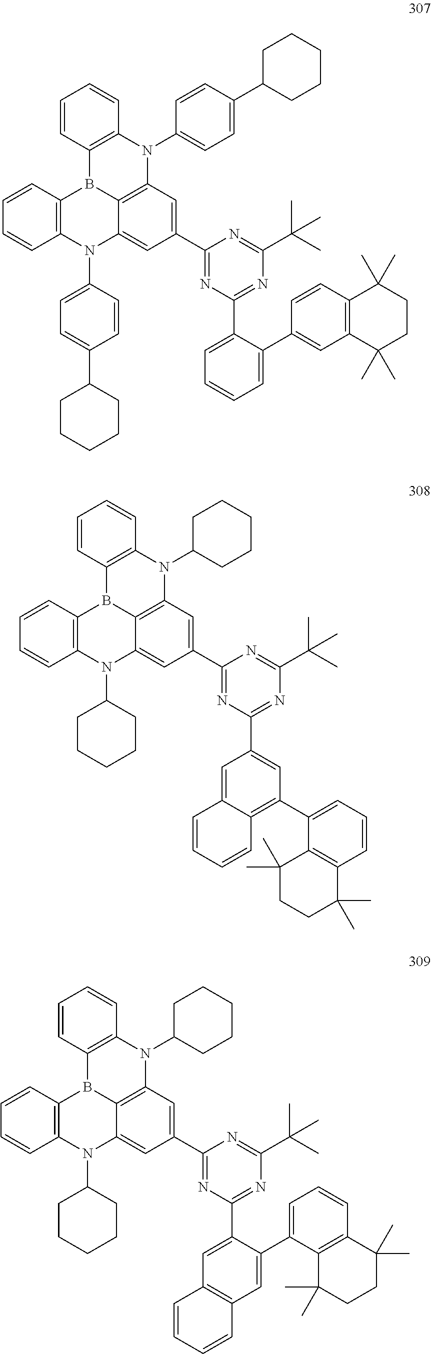

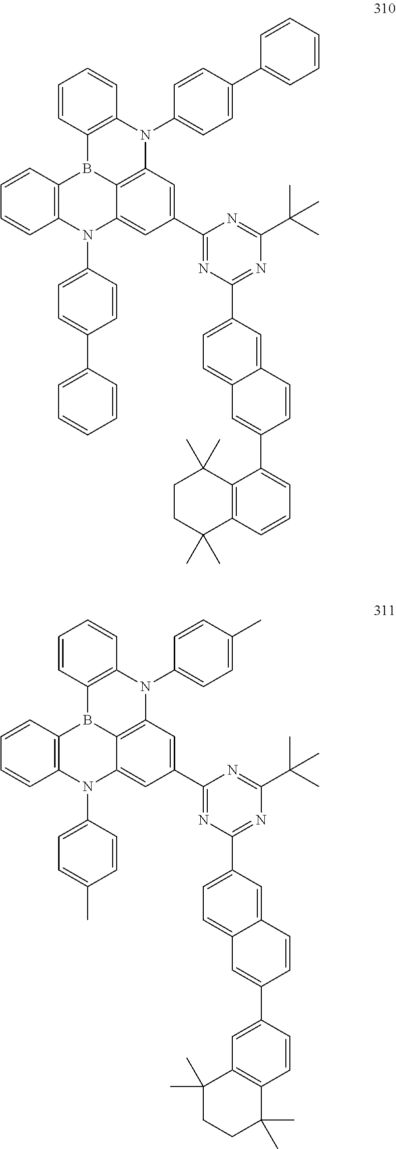 [SMILES: CC(C)(C)c1nc(-c2cc3c4c(c2)N(c2ccc(-c5ccccc5)cc2)c2ccccc2B4c2ccccc2N3c2ccc(-c3ccccc3)cc2)nc(-c2ccc3cc(-c4cccc5c4C(C)(C)CCC5(C)C)ccc3c2)n1 ; Cc1ccc(N2c3ccccc3B3c4ccccc4N(c4ccc(C)cc4)c4cc(-c5nc(-c6ccc7cc(-c8ccc9c(c8)C(C)(C)CCC9(C)C)ccc7c6)nc(C(C)(C)C)n5)cc2c43)cc1]

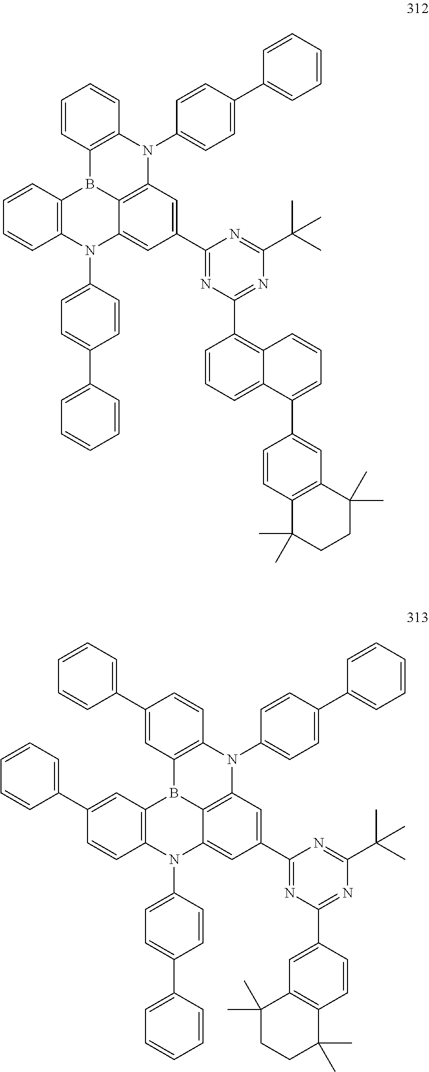 [SMILES: CC(C)(C)c1nc(-c2cc3c4c(c2)N(c2ccc(-c5ccccc5)cc2)c2ccccc2B4c2ccccc2N3c2ccc(-c3ccccc3)cc2)nc(-c2cccc3c(-c4ccc5c(c4)C(C)(C)CCC5(C)C)cccc23)n1 ; CC(C)(C)c1nc(-c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)nc(-c2ccc3c(c2)C(C)(C)CCC3(C)C)n1]

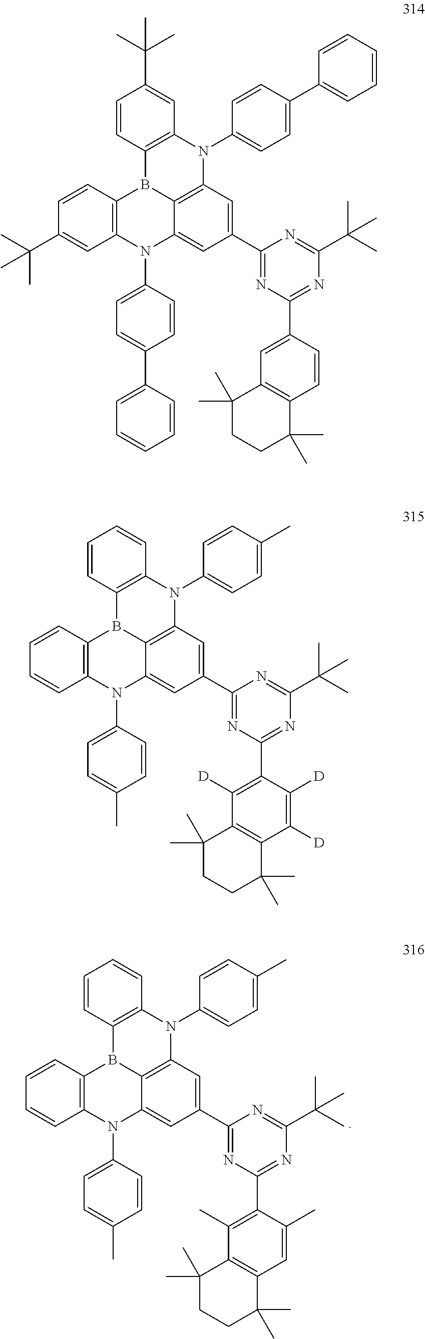 [SMILES: CC(C)(C)c1ccc2c(c1)N(c1ccc(-c3ccccc3)cc1)c1cc(-c3nc(-c4ccc5c(c4)C(C)(C)CCC5(C)C)nc(C(C)(C)C)n3)cc3c1B2c1ccc(C(C)(C)C)cc1N3c1ccc(-c2ccccc2)cc1 ; [2H]c1c([2H])c2c(c([2H])c1-c1nc(-c3cc4c5c(c3)N(c3ccc(C)cc3)c3ccccc3B5c3ccccc3N4c3ccc(C)cc3)nc(C(C)(C)C)n1)C(C)(C)CCC2(C)C ; Cc1ccc(N2c3ccccc3B3c4ccccc4N(c4ccc(C)cc4)c4cc(-c5nc(-c6c(C)cc7c(c6C)C(C)(C)CCC7(C)C)nc(C(C)(C)C)n5)cc2c43)cc1]

11. An organic light-emitting device comprising:
a first electrode;
a second electrode opposite to the first electrode;
an interlayer between the first electrode and the second electrode and comprising an emission layer; and
the heterocyclic compound of claim 1.

12. The organic light-emitting device of claim 11, wherein
the first electrode is an anode,
the second electrode is a cathode,
the interlayer further comprises a hole transport region between the first electrode and the emission layer and an electron transport region between the emission layer and the second electrode,
the hole transport region comprises at least one of a hole injection layer, a hole transport layer, a buffer layer, an emission auxiliary layer, or an electron blocking layer,
the electron transport region comprises at least one of a hole blocking layer, an electron transport layer, or an electron injection layer, and
the electron transport region comprises the heterocyclic compound.

13. The organic light-emitting device of claim 12, wherein the emission layer comprises a boron-containing compound.

14. The organic light-emitting device of claim 12, wherein
the emission layer comprises a host, a sensitizer, and a dopant,
the host comprises a first host compound and a second host compound,
the first host compound is a hole-transporting host,
the second host compound is an electron-transporting host,
the sensitizer comprises an organometallic compound,
the dopant comprises a fluorescent dopant, a phosphorescent dopant, a delayed fluorescence material, or a combination thereof, and
at least one of the host, the sensitizer, or the dopant is a boron-containing compound.

15. The organic light-emitting device of claim 11, wherein
the interlayer comprises:
m emitting units; and
m−1 charge generation layer(s) each arranged between two neighboring emitting units among the m emitting units,
m is an integer of 2 or more,
at least one of the m emitting units comprises an electron transport region, and the electron transport region comprises the heterocyclic compound.

16. The organic light-emitting device of claim 15, wherein
the m emitting units comprise a first emitting unit and a second emitting unit,
the first emitting unit comprises a first red subpixel comprising a first red emission layer, a first green subpixel comprising a first green emission layer, and a first blue subpixel comprising a first green emission layer,
the second emitting unit comprises a second red subpixel comprising a second red emission layer, a second green subpixel comprising a second green emission layer, and a second blue subpixel comprising a second blue emission layer,
at least one of the first emitting unit or the second emitting unit comprises the electron transport region,
the electron transport region comprises the heterocyclic compound.

17. The organic light-emitting device of claim 16, wherein the interlayer comprises at least three layers, and wherein the layers within the interlayer of the organic light-emitting device each comprise a boron-containing compound.

18. The organic light-emitting device of claim 11, wherein the emission layer is to emit blue light having a maximum emission wavelength of about 410 nm to about 490 nm.

19. A consumer product comprising an organic light-emitting device, wherein,
the organic light-emitting device comprises:
a first electrode;
a second electrode opposite to the first electrode;
an interlayer between the first electrode and the second electrode and comprising an emission layer; and
a heterocyclic compound represented by Formula 1: 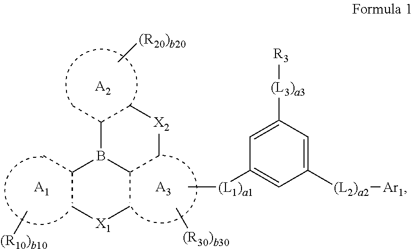
wherein, in Formula 1,
X₁ is O, S, Se, or N(R₁),
X₂ is O, S, Se, or N(R₂),
A₁ to A₃ are each independently a C₅-C₃₀ carbocyclic group or a C₁-C₃₀ heterocyclic group,
L₁ to L₃ are each independently a single bond, a C₅-C₆₀ carbocyclic group unsubstituted or substituted with at least one R₁₀ₐ, or a C₁-C₆₀ heterocyclic group unsubstituted or substituted with at least one R₁₀ₐ,
a1 to a3 are each independently 1, 2, 3, 4, or 5, and
Ar₁ is a group represented by Formula 2, 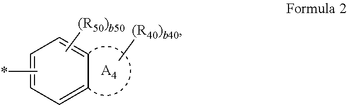
in Formula 2,
A₄ is a C₃-C₁₀ non-aromatic carbocyclic group or a C₁-C₁₀ non-aromatic heterocyclic group, and
* indicates a binding site to a neighboring atom,
in Formula 1 and Formula 2,
R₁ to R₃, R₁₀, R₂₀, R₃₀, R₄₀, and R₅₀ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
at least two neighboring groups selected from among R₁ to R₃, R₁₀, R₂₀, R₃₀, R₄₀, and R₅₀ are optionally bonded together to form a C₅-C₆₀ carbocyclic group unsubstituted or substituted with at least one R₁₀ₐ or a C₁-C₆₀ heterocyclic group unsubstituted or substituted with at least one R₁₀ₐ,
b10, b20, b30, and b40 are each independently 1, 2, 3, 4, 5, 6, 7, or 8,
b50 is 1, 2, or 3,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

20. The consumer product of claim 19, wherein the consumer product is at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant, a wearable device, a laptop computer, a digital camera, a camcorder, a viewfinder, a micro display, a three-dimension (3D) display, a virtual reality display, an augmented reality display, a vehicle, a video wall with multiple displays tiled together, a theater screen, a stadium screen, a phototherapy device, or a signboard.
